(19) United States
(12) Patent Application Publication
(10) Pub. No.: US 2026/0215149 A1
(43) Pub. Date: Jul. 23, 2026

(54) ELECTRONIC DEVICE

(71) Applicant: Merck Patent GMBH, Darmstadt (DE)

(72) Inventors: Jens Engelhart, Darmstadt (DE); You-Hyun Kim, Griesheim (DE); Leo Weegels, Darmstadt (DE)

(21) Appl. No.: 19/139,717

(22) PCT Filed: Dec. 20, 2023
(86) PCT No.: PCT/EP2023/086791

§ 371 Date: Jun. 16, 2025

(30) Foreign Application Priority Data
Dec. 23, 2022 (EP) 22216601.9
Mar. 20, 2023 (EP) 23162772.0

(51) Int. Cl. H10K 85/60; H10K 50/17; H10K 50/19; H10K 101/30; H10K 102/00

(52) U.S. Cl. CPC H10K 85/633; H10K 85/60; H10K 85/615; H10K 85/654; H10K 85/6572; H10K 50/17; H10K 50/19; H10K 85/626; H10K 2101/30; H10K 2102/351

(57) ABSTRACT

The present application relates to an electronic device, preferably an OLED, which is characterized in that it comprises two stacks of layers, where both stacks of layers share a layer. The application also applies to a method of preparing such electronic device, and to a mixture which can be used for preparing such electronic device.

The present invention relates to an electronic device, which is characterized in that it comprises at least two stacks of layers, where both stacks of layers share a layer which is common to these two stacks of layers, and which comprises a hole transporting compound, a compound with a low HOMO level, and a p-dopant. The stacks of layers are each organic electroluminescent devices and/or represent pixels of a display based on organic electroluminescent devices.

Organic electroluminescent devices are also known as organic light-emitting diodes (OLEDs). They are electronic devices which have one or more layers, at least one of them comprising an organic compound, and which emit light on application of an electrical voltage. The construction and general principle of function of OLEDs are known to those skilled in the art.

While OLEDs have been continuously further developed over the past years, leading to significant improvements in the state of the art OLEDs, compared to those of the early time, there is still a need for further improvement of their properties. In particular, lifetime, efficiency, operating voltage and color purity are performance parameters of high technical and commercial relevance. In these aspects, it has not yet been possible to find an entirely satisfactory solution.

To ensure good, i.e. sufficiently low, driving voltages, a stack design in which the OLEDs comprise a layer which comprises a p-dopant and which is a layer shared by two or more individual stacks of layers is highly beneficial and frequently used in the art. Such shared layer is typically termed common layer and is understood in the art to be a layer which extends laterally over at least two pixels or stacks of layers of an OLED, thereby covering at least two separate light emitting layers. In other words, the common layer is shared by the at least two pixels or stacks of layers.

Such shared layer comprising a p-dopant is typically a hole injection layer and/or a charge generation layer. If such shared p-doped layer is present in an OLED, it is observed that while the OLED is driven, i.e. under voltage, a current occurs in lateral direction, orthogonal to the stacking axis of the stack of layers. Such lateral current, which is also called leakage current, causes a poor color purity of an OLED display, due to unwanted illumination of neighboring stacks or pixels, when voltage is applied to a stack in order to switch it on. Such phenomenon of lateral (leakage) current occurs in particular if one or more stacks with a low threshold voltage are in close proximity to a stack with a high threshold voltage. Due to deterioration of color purity, it is highly desirable to reduce the occurrence of such lateral current.

The present invention provides a solution to this problem, by reducing the lateral current between neighboring stacks of layers or pixels. Preferably, this effect of reduction of lateral current is obtained, without compromising on other performance parameters, in particular without compromising on driving voltage, efficiency and lifetime, most importantly driving voltage. Thus, the present invention achieves to reduce lateral current in p-doped layers which are shared by two or more OLED stacks of layers or pixels, while keeping the driving voltage of the OLED stacks of layers low.

One embodiment of the invention is thus an electronic device, comprising a first stack of layers, and a second stack of layers which is in close proximity to the first stack of layers, each of the first and second stack comprising anode, cathode, and positioned between anode and cathode, a layer A and a light emitting layer, where the layer A is shared by the two stacks of layers, and where the layer A comprises
at least one compound C1, which has hole transporting property,
at least one compound C2, which has a HOMO of less than −5.1 eV, and
at least one compound C3, which is a p-dopant.

The electronic device according to the present invention is preferably an arrangement of at least two individual organic electroluminescent devices, where each of the two stacks of layers represents an individual organic electroluminescent device. The electronic device preferably does not only comprise the above-mentioned first and second stack of layers, but a multitude of such stacks, multitude meaning in the range of millions of stacks. Preferably, the layer A is shared by all stacks which are part of the display light emitting area of the electronic device according to the present application.

An organic electroluminescent device in the definition of the present application is an electronic device which has one or more layers, at least one of them comprising an organic compound, and which emits light on application of an electrical voltage between its anode and cathode. Other frequently used term for an organic electroluminescent device is organic light-emitting diode, and its acronym OLED.

“Close proximity” in the above definition means that the two stacks of layers are preferably distanced by 5-40 μm, more preferably 10-30 μm, even more preferably 15-35 μm, where the distance is measured from the side of the anode of the first stack which is closest to the second stack, to the side of the anode of the second stack which is closest to the first stack.

“HOMO” in connection with compounds in the present application means the highest occupied molecular orbital of the compound, as determined in section E) of the working examples.

“Less than” in regard to an energy level such as HOMO means, just as “lower than”, that the absolute value for the energy in eV is increased. In this sense, −5.5 eV is “less than” and “lower than” −5.4 eV. “More than” in regard to an energy level such as HOMO means, just as “higher than”, that the absolute value for the energy in eV is decreased. In this sense, −5.4 eV is “more than” and “higher than” −5.5 eV.

Stack of layers means an arrangement of multiple layers, which are parallel to each other, on top of each other. Typically and preferably, each stack of layers of the electronic device functions as a pixel of the electronic device, and the electronic device is a pixel. The pixel area is preferably the area covered by the anode. A stack of layers, in order to function as an OLED, needs to comprise at least an anode, a cathode, and a light emitting layer positioned between anode and cathode. In state of the art OLEDs, several more layers are preferably present, in particular a hole injection layer which is adjacent to the anode, a hole transporting layer which is positioned between the hole injection layer and the anode, an electron transporting layer which is positioned between the light emitting layer and the cathode, and an electron injection layer which is positioned between the electron transporting layer and the cathode and which is directly adjacent to the cathode. Several further layers can be present in the stack, the most frequently used of those being an electron blocking layer and a hole blocking layer. An electron blocking layer is a layer which is directly adjacent to the light emitting layer on the anode side of the light emitting layer. It has the purpose to keep electrons from leaving the light emitting layer on the anode side of the light emitting layer. Preferably, it has a relatively high LUMO (LUMO=lowest unoccupied molecular orbital). A hole blocking layer is a layer which is directly adjacent to the light emitting layer on the cathode side of the light emitting layer. It has the purpose to keep holes from leaving the light emitting layer on the cathode side of the light emitting layer. Typically, it has a relatively high HOMO (HOMO=highest unoccupied molecular orbital).

The first and the second stack of layers of the electronic device are preferably arranged in parallel to each other, meaning that each of the layers of the first stack of layers is parallel to the layers of the second stack of layers, and vice versa.

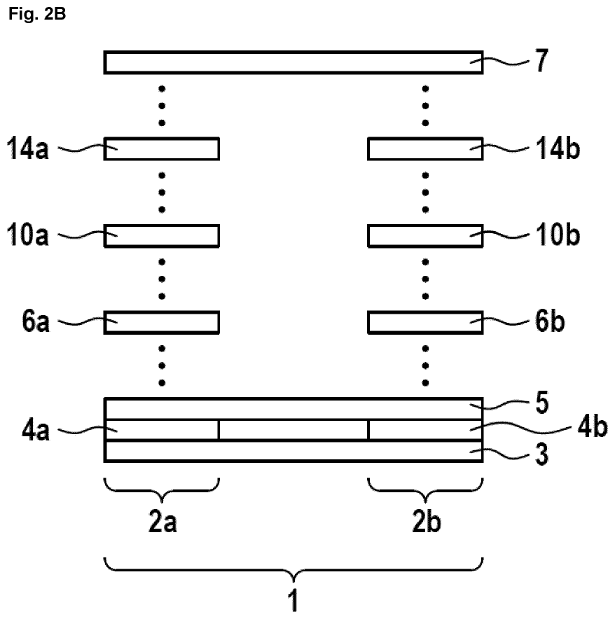

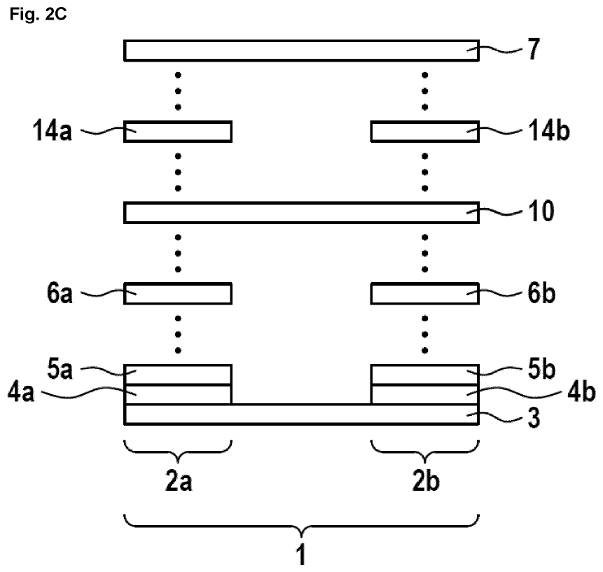

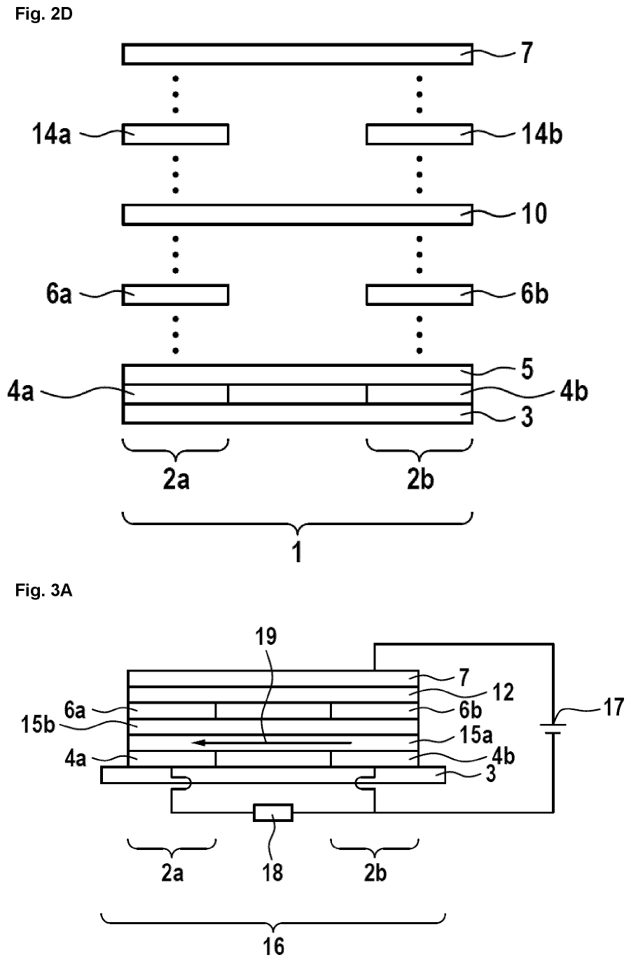

A specific embodiment of an OLED stack of layers to be used in the device of the present invention is a so-called tandem stack, which comprises two or more light emitting layers which are positioned in sequence, i.e. behind each other, in one OLED stack of layers. Tandem stacks are generally known to the skilled person in the field. Tandem stacks, preferably, are built from two or more, preferably two or three, sub-stacks of layers which are stacked on top of each other, where a charge generation layer (CGL) is positioned in each case between the respective sub-stacks, and the resulting combined stack is positioned between an anode and a cathode. The sub-stacks in this case preferably each comprise a hole injection layer, a hole transporting layer, a light emitting layer, an electron transporting layer, and an electron injection layer. A representative example of a tandem stack of layers is shown in FIG. 2A. Representative examples of an electronic device according to the present application, which comprises two stacks of layers, each of them being an OLED tandem stack of layers, are shown in FIG. 2B-2D.

According to one preferred embodiment of the present invention, at least one of the stacks of layers of the electronic device, preferably both first and second stack of layers of the electronic device, are tandem stacks, preferably as defined above.

According to an alternative preferred embodiment of the present invention, at least one, preferably both stacks of layers of the electronic device, are regular, non-tandem stacks of layers. Regular, non-tandem stacks of layers here means that they comprise a single light emitting layer positioned between anode and cathode.

In a state of the art display, a multitude of OLED stacks of layers are positioned in close proximity to each other and preferably have layers which are parallel to each other. These stacks of layers must be driven, i.e. switched on and off, independently from each other, in order for the display to function properly. In a preferred embodiment, each of the individual stacks of layers represents a pixel of a display. In each of the above-mentioned stacks of layers, at least one electrode and the light emitting layer are separate from the corresponding electrode and light emitting layer of the other stacks of layers. Further layers can be separate as well from the respective layer which corresponds to them in function in the other stacks of layers. In particular, it is preferred that the respective light emitting layer of each of the stacks of layers is separate from each light emitting layer of each of the other stacks of layers of the electronic device. However, in state of the art OLEDs, not all layers of individual stacks of layers are separate from each other. Besides one of the electrodes, which is preferably shared by the stacks of layers, there is preferably also a hole injection layer which is shared by the stacks of layers. Further layers are preferably shared as well, such as a hole transporting layer, an electron transporting layer, and an electron injection layer. In tandem stacks, it is preferred that the charge generation layer (CGL) is a shared layer.

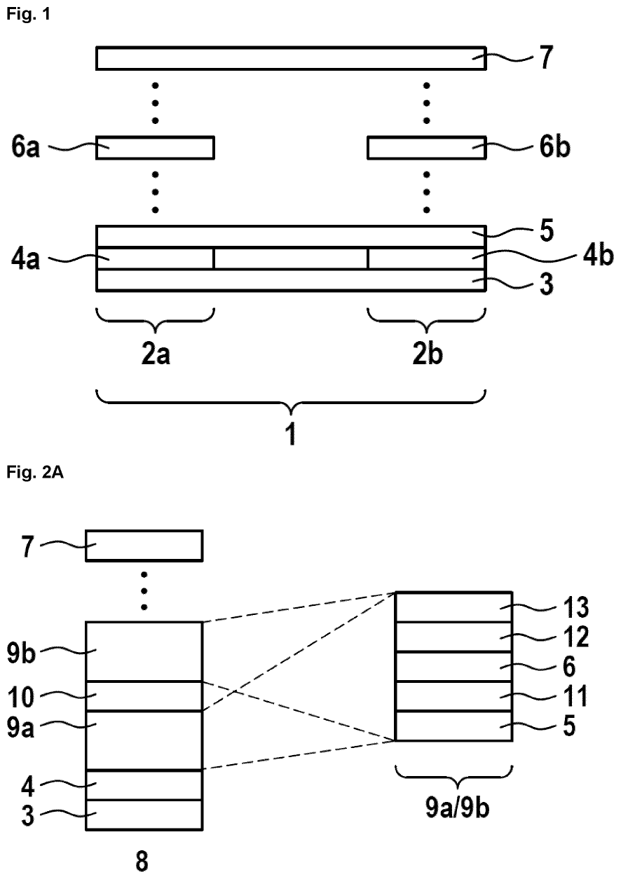

A representative electronic device in which the shared layer is a hole injection layer is shown in FIG. 1 for the case that the stacks of layers are non-tandem stacks of layers, and in FIGS. 2B and 2D for the case that the stacks of layers are tandem stacks of layers.

A representative electronic device in which the shared layer is a charge generation layer is shown in FIGS. 2C and 2D for the case that the stacks of layers are tandem stacks of layers.

According to a preferred embodiment, the layer A is selected from a layer A1, which is adjacent to the anode, and a layer A2, which is positioned between the light emitting layer of one of the stacks and a further light emitting layer, which is stacked on top of this light emitting layer in the same stack. The layer A2 is preferably part of a tandem stack, in particular it is the charge generation layer of a tandem stack, or a sub-layer of a charge generation layer of a tandem stack. The layer A1 is preferably a hole injection layer. According to a further preferred embodiment, there are two layers A in the electronic device, one layer being a layer A1, preferably a hole injection layer, and the other being a layer A2, preferably being a charge generation layer or a sub-layer of a charge generation layer of a tandem stack.

According to one preferred embodiment, the electronic device has a structure as illustrated in FIG. 1.

In this structure, 2a and 2b are the two stacks of layers of the electronic device 1, which are in close proximity and preferably have layers which are parallel to each other. The stacks of layers 2a and 2b are positioned on a common substrate layer 3. Layer 4a (anode of first stack of layers) and Layer 6a (light emitting layer of first stack of layer) are the separate layers of the first stack of layers 2a. Layer 4b (anode of second stack of layers) and Layer 6b (light emitting layer of second stack of layer) are the separate layers of the second stack of layers 2b. The cathode 7 is shared by both stacks of layers 2a and 2b. Layer 5 is the HIL and is shared by both stacks of layers. Layer 5 is preferably the layer A according to the present application. The dots stand for optional further layers, which may be present between the layers which are explicitly shown.

The structure of a single tandem OLED stack of layers is illustrated in FIG. 2A. The stack of layers 8 comprises the light emitting units 9a and 9b which are stacked on top of each other between anode 4 and cathode 7, and which are separated by a charge generation layer 10. The light emitting units 9a and 9b themselves are composed like regular OLED stacks of layers, however without anode and cathode. They typically comprise a hole injection layer 5, followed by a hole transporting layer 11, followed by a light emitting layer 6, followed by an electron transporting layer 12 and an electron injection layer 13. Note that further layers may be present in the light emitting units, in addition to the ones shown. The charge generation layer may in a preferred embodiment, function as electron injection layer and hole injection layer, respectively, for the adjacent sub-stacks, so that there is no hole injection layer on the cathode side of the charge generation layer, and no electron injection layer on the anode side of the charge generation layer. The two light emitting units of the tandem stack preferably comprise the same functional layers in the same sequence, but may also have different functional layers and/or different sequence of functional layers. Each of the light emitting units preferably has a composition of its light emitting layer which is different from the composition of the light emitting layer of the other light emitting unit(s). For example, one light emitting unit may have a light emitting layer which emits red color, and the other light emitting unit may have a light emitting layer which emits blue color. The dots stand for optional further layers, which may be present between the layers which are explicitly shown. According to one preferred embodiment, the tandem stack of layers comprises a third light emitting unit, in addition to the light emitting units 9a and 9b.

According to an alternative preferred embodiment, the electronic device has a structure as illustrated in FIG. 2B. According to this structure, the two stacks of layers 2a and 2b of the device are each tandem stacks, i.e. stacks comprising two or more light emitting layers. In the electronic device 1 of FIG. 2B, the hole injection layer 5 is a shared layer. The device further comprises, in addition to the substrate 3, two separated anodes 4a and 4b, a shared cathode 7, two first light emitting layers 6a, 6b which are separate between the two stacks, two second light emitting layers 14a, 14b which are separate between the two stacks, and two charge generation layers 10a, 10b which are separate between the two stacks. The shared hole injection layer 5 is preferably a layer A. The dots stand for optional further layers, which may be present between the layers which are explicitly shown.

According to an alternative preferred embodiment, the electronic device has a structure as illustrated in FIG. 2C. According to this structure, the two stacks of layers 2a and 2b of the device are each tandem stacks, i.e. stacks comprising two or more light emitting layers in sequence in the stack. In the electronic device 1 of FIG. 2C, there are two separated hole injection layers 5a, 5b: layer 5a for the first stack of layers, and layer 5b for the second stack of layers. The device further comprises, in addition to the substrate 3, two separated anodes 4a and 4b, a shared cathode 7, two first light emitting layers 6a, 6b which are separate between the two stacks, two second light emitting layers 14a, 14b which are separate between the two stacks, and a shared charge generation layer 10, which is preferably a layer A. The dots stand for optional further layers, which may be present between the layers which are explicitly shown.

According to an alternative preferred embodiment, the electronic device has a structure as illustrated in FIG. 2D. According to this structure, the two stacks of layers 2a and 2b of the device are each tandem stacks, i.e. stacks comprising two or more light emitting layers. In the electronic device 1 of FIG. 2D, there is a shared hole injection layer 5, which is preferably a layer A. The device further comprises, in addition to the substrate 3, two separated anodes 4a and 4b, a shared cathode 7, two first light emitting layers 6a, 6b which are separate between the two stacks, two second light emitting layers 14a, 14b which are separate between the two stacks, and a shared charge generation layer 10, which is preferably a layer A. The dots stand for optional further layers, which may be present between the layers which are explicitly shown.

### Detailed Description of Electronic Device Comprising Side-by-Side Stacks of Different Color of Emitted Light

Such embodiment is also termed RGB-side-by-side design. It preferably comprises three stacks of layers, whose layers are preferably parallel to each other, and which are in close proximity to each other in the electronic device, where a first one of these stacks has a blue light emitting layer, a second one of these stacks has a green light emitting layer, and a third one of these stacks has a red light emitting layer. Each of the stacks of layers of such electronic device only has a single light emitting layer, is thus not a tandem stack. An example for an electronic device of such design is shown in FIG. 1, where however only two stacks of layers are depicted, not all three which are part of a RGB-side-by-side design of electronic device. The following preferred embodiments apply to this case of design:

Layer A as a layer A1, preferably as a hole injection layer, preferably has a thickness of 5 nm to 20 nm. Further, it is preferred that layer A as a layer A1, preferably as a hole injection layer, consists of the compounds C1, C2 and C3. Consists here means that there are no further compounds present in the layer, except for impurities at very low amounts, which necessarily occur in the processes of synthesis and application of the compounds.

The compounds of the layer A as a layer A1 are preferably all small molecule compounds, in particular no polymeric compounds. Compounds C1, C2, C3 are preferably small molecule compounds, in particular no polymeric compounds. Small molecule compounds are preferably understood to have a molecular weight of less than 2000 g/mol, more preferably less than 1000 g/mol.

Compound C1 preferably has a HOMO of more than −5.0 eV, more preferably a HOMO of more than −4.9 eV, most preferably of more than −4.85 eV. HOMO values are in each case measured as described in section E) of the working examples.

It is understood that the compound C1 itself, if put in a layer, has either a high or a low lateral current. Generally, it is preferred that the compound C1 has a low lateral current. The technical effect of the present invention is achieved regardless of whether the compound C1 alone has, if present in a layer, a high or a low lateral current. However, the absolute value of the lateral current exhibited by the device is generally lower if the compound C1 has a low lateral current, which is why it is generally preferable to select a compound C1 having a low lateral current, if obtaining the lowest possible lateral current is of high priority in designing the device.

Compound C1 is preferably selected from triarylamines, in particular mono-triarylamines and di-triarylamines, and carbazole amines. A mono-triarylamine is understood to be a compound which comprises a single amine group, where to the nitrogen atom of the amine group, three groups selected from aromatic and heteroaromatic ring systems are bonded. A di-triarylamine is understood to be a compound which comprises a two and no more amine groups, where to each of the nitrogen atoms of the two amine groups, three groups selected from aromatic and heteroaromatic ring systems are bonded. A carbazole amine is understood to be a compound, which comprises a carbazole group, and an amine group, where the amine group is preferably a triarylamine group. A triarylamine group is understood to be an amine group, where to the nitrogen atom of the amine group, three groups selected from aromatic and heteroaromatic ring systems are bonded.

Preferred embodiments of compound C1 conform to one of formulae (1-1) and (1-2)

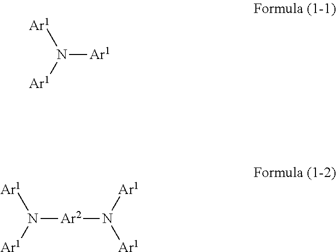

where the variables are defined as follows:
Ar¹ is at each occurrence, identically or differently, selected from aromatic ring systems having 6 to 50 aromatic ring atoms, which are substituted by radicals R¹, and heteroaromatic ring systems having 5 to 40 aromatic ring atoms, which are substituted by radicals R¹;
Ar² is at each occurrence, identically or differently, selected from aromatic ring systems having 6 to 50 aromatic ring atoms, which are substituted by radicals R¹, and heteroaromatic ring systems having 5 to 40 aromatic ring atoms, which are substituted by radicals R¹;
R¹ is selected, identically or differently at each occurrence, from H, D, F, C(═O)R², CN, Si(R²)₃, N(R²)₂, P(═O)(R²)₂, OR², S(═O)R², S(═O)₂R², straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms; where two or more radicals R¹ may be connected to each other to form a ring; where the said alkyl, alkoxy, alkenyl and alkynyl groups and the said aromatic and heteroaromatic ring systems are substituted by radicals R², and where one or more CH₂ groups in the said alkyl, alkoxy, alkenyl and alkynyl groups may in each case be replaced by —R²C═CR²—, —C≡C—, Si(R²)₂, C═O, C═NR², —C(═O)O—, —C(═O)NR²—, NR², P(═O)(R²), —O—, —S—, SO or SO₂;
R² is selected, identically or differently at each occurrence, from H, D, F, C(═O)R³, CN, Si(R³)₃, N(R³)₂, P(═O)(R³)₂, OR³, S(═O)R³, S(═O)₂R³, straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms; where two or more radicals R² may be connected to each other to form a ring; where the said alkyl, alkoxy, alkenyl and alkynyl groups and the said aromatic and heteroaromatic ring systems are substituted by radicals R³, and where one or more CH₂ groups in the said alkyl, alkoxy, alkenyl and alkynyl groups may in each case be replaced by —R³C═CR³—, —C≡C—, Si(R³)₂, C═O, C═NR³, —C(═O)O—, —C(═O)NR³—, NR³, P(═O)(R³), —O—, —S—, SO or SO₂;
R³ is selected, identically or differently at each occurrence, from H, D, F, Cl, Br, I, CN, alkyl groups having 1 to 20 C atoms, aromatic ring systems having 6 to 40 C atoms, and heteroaromatic ring systems having 5 to 40 aromatic ring atoms; where two or more radicals R³ may be connected to each other to form a ring; and where the said alkyl groups, aromatic ring systems and heteroaromatic ring systems may be substituted by one or more radicals selected from F and CN.

Preferred groups Ar¹ are selected, identically or differently at each occurrence, from monovalent groups derived from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, benzocarbazole, carbazole, benzofuran, benzothiophene, indole, quinoline, pyridine, pyrimidine, pyrazine, pyridazine, and triazine, where each of the groups is substituted with radicals R¹. Preferably, groups Ar¹ are selected, identically or differently on each occurrence, from monovalent groups which represent combinations of 2 to 4 groups, which are selected from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, benzocarbazole, carbazole, benzofuran, benzothiophene, indole, quinoline, pyridine, pyrimidine, pyrazine, pyridazine, and triazine, where each of the groups is substituted with radicals R¹.

More preferred groups Ar¹ are selected, identically or differently on each occurrence, from monovalent groups derived from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, carbazole, benzofuran, benzothiophene, benzo-condensed dibenzofuranyl, benzo-condensed dibenzothiophenyl, and phenyl which is substituted with a group selected from naphthyl, phenanthrenyl, fluorenyl, spirobifluorenyl, dibenzofuranyl, dibenzothiophenyl, carbazolyl, pyridyl, pyrimidyl and triazinyl, where each of the above groups is substituted with radicals R¹.

Preferred groups Ar² are selected, identically or differently at each occurrence, from divalent groups derived from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, benzocarbazole, carbazole, benzofuran, benzothiophene, indole, quinoline, pyridine, pyrimidine, pyrazine, pyridazine, and triazine, where each of the groups is substituted with radicals R¹. More preferably, groups Ar¹ are selected, identically or differently on each occurrence, from divalent groups which represent combinations of 2 to 4 groups, which are selected from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, benzocarbazole, carbazole, benzofuran, benzothiophene, indole, quinoline, pyridine, pyrimidine, pyrazine, pyridazine, and triazine, where each of the groups is substituted with radicals R¹.

Even more preferred groups Ar² are selected, identically or differently on each occurrence, from divalent groups derived from benzene, biphenyl, terphenyl, quaterphenyl, naphthalene, phenanthrene, fluorene, in particular 9,9′-dimethylfluorene and 9,9′-diphenylfluorene, benzofluorene, spirobifluorene, indenofluorene, indenocarbazole, dibenzofuran, dibenzothiophene, carbazole, benzofuran, benzothiophene, benzo-condensed dibenzofuranyl, and benzo-condensed dibenzothiophenyl, where each of the above groups is substituted with radicals R¹.

Preferably, R¹ is selected, identically or differently, from H, D, F, CN, Si(R²)₃, N(R²)₂, straight-chain alkyl or alkoxy groups having 1 to 20 C atoms, branched or cyclic alkyl or alkoxy groups having 3 to 20 C atoms, aromatic ring systems having 6 to 40 aromatic ring atoms, and heteroaromatic ring systems having 5 to 40 aromatic ring atoms; where the said alkyl and alkoxy groups and the said aromatic and heteroaromatic ring systems are substituted by radicals R².

Preferably, R² is selected, identically or differently, from H, D, F, CN, Si(R³)₃, N(R³)₂, straight-chain alkyl or alkoxy groups having 1 to 20 C atoms, branched or cyclic alkyl or alkoxy groups having 3 to 20 C atoms, aromatic ring systems having 6 to 40 aromatic ring atoms, and heteroaromatic ring systems having 5 to 40 aromatic ring atoms; where the said alkyl and alkoxy groups and the said aromatic and heteroaromatic ring systems are substituted by radicals R³.

Preferably, R³ is selected, identically or differently at each occurrence, from H, D, F, CN, alkyl groups having 1 to 20 C atoms, aromatic ring systems having 6 to 40 C atoms, and heteroaromatic ring systems having 5 to 40 aromatic ring atoms.

Particularly preferred embodiments of formula (1-1) conform to the following formulae

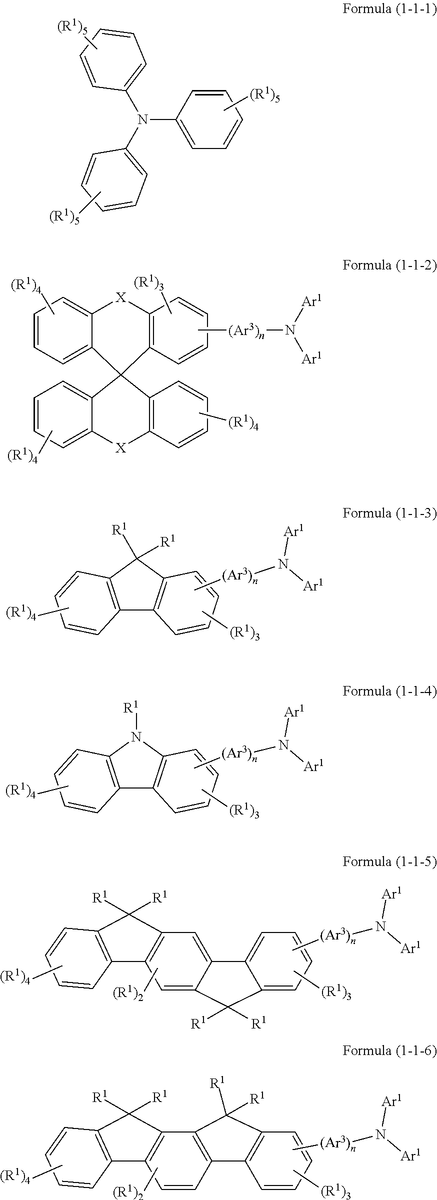

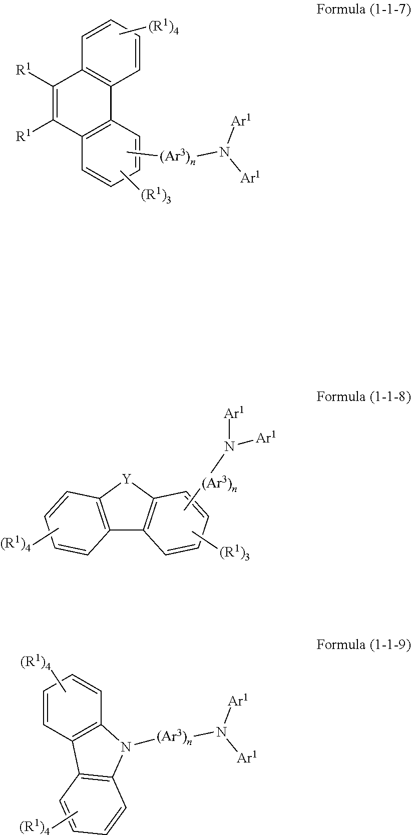

where the variable groups and indices are defined as follows:
Ar¹, R¹, R² and R³ are defined as above, and preferably conform to the preferred embodiments listed above;
Ar³ is selected from aromatic ring systems having 6 to 13 aromatic ring atoms, which are substituted with radicals R¹, and heteroaromatic ring systems having 5 to 13 aromatic ring atoms, which are substituted with radicals R¹;
X is selected, identically or differently on each occurrence, from a bond, O, S, NR¹, and C(R¹)₂;
Y is selected from O and S;
n is 0 or 1, where for n=0, the group with index n is not present, and the groups bonded to the group with index n are directly connected to each other, with the proviso that n is not 0 in the case of formula (1-1-9).

Preferably, Ar³ is selected from divalent groups derived from benzene, biphenyl, naphthalene, and fluorene, in particular 9,9′-dimethylfluorene, where each of the groups is substituted with radicals R¹.

Particularly preferred are formulae (1-1-2) and (1-1-3), where the formula (1-1-2-1) below is particularly preferred as embodiment of formula (1-1-2):

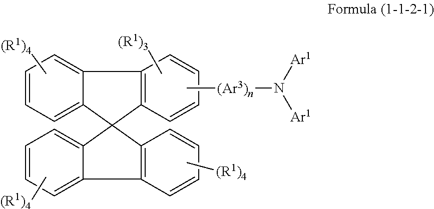

where the variable groups and indices are defined as above, and preferably correspond to their preferred embodiments mentioned above.

Preferred embodiments of compound C1 conform to the following formulae

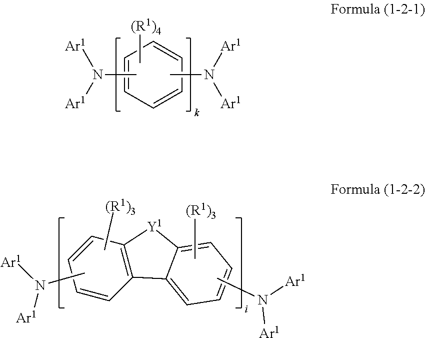

where Ar¹, R¹, R² and R³ are defined as above and preferably conform to their preferred embodiments mentioned above. Y¹ is identically or differently selected from O, S, NR¹ and C(R¹)₂. Index k is 1, 2, 3 or 4, and is preferably 1 or 2. Index i is 1, 2 or 3, preferably 1 or 2, most preferably 1.

Preferred specific compounds which can be used as compound C1 according to the present application are shown in the following table:

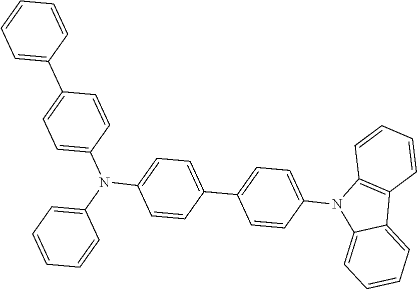 [SMILES: c1ccc(-c2ccc(N(c3ccccc3)c3ccc(-c4ccc(-n5c6ccccc6c6ccccc65)cc4)cc3)cc2)cc1]

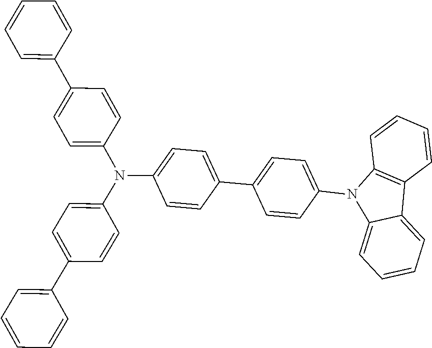 [SMILES: c1ccc(-c2ccc(N(c3ccc(-c4ccccc4)cc3)c3ccc(-c4ccc(-n5c6ccccc6c6ccccc65)cc4)cc3)cc2)cc1]

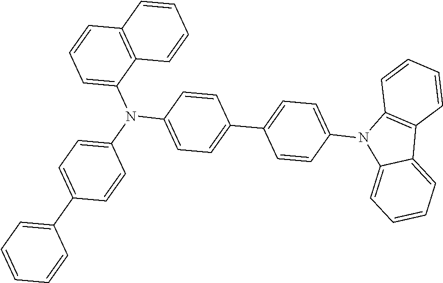 [SMILES: c1ccc(-c2ccc(N(c3ccc(-c4ccc(-n5c6ccccc6c6ccccc65)cc4)cc3)c3cccc4ccccc34)cc2)cc1]

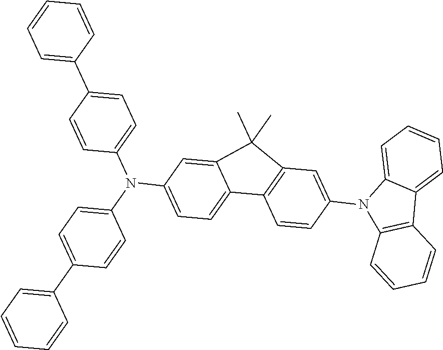 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21]

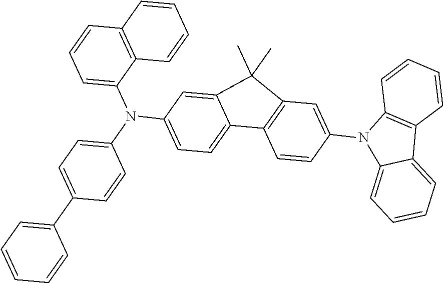 [SMILES: CC1(C)c2cc(N(c3ccc(-c4ccccc4)cc3)c3cccc4ccccc34)ccc2-c2ccc(-n3c4ccccc4c4ccccc43)cc21]

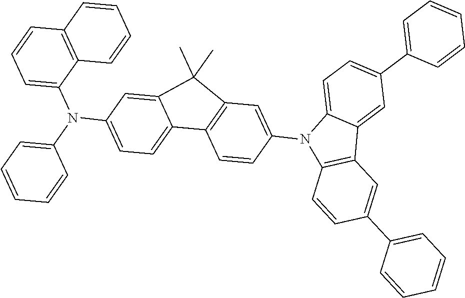 [SMILES: CC1(C)c2cc(N(c3ccccc3)c3cccc4ccccc34)ccc2-c2ccc(-n3c4ccc(-c5ccccc5)cc4c4cc(-c5ccccc5)ccc43)cc21]

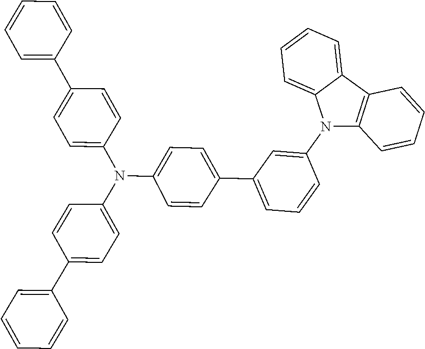 [SMILES: c1ccc(-c2ccc(N(c3ccc(-c4ccccc4)cc3)c3ccc(-c4cccc(-n5c6ccccc6c6ccccc65)c4)cc3)cc2)cc1]

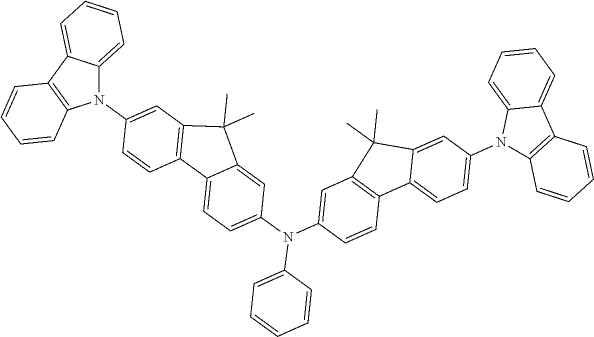 [SMILES: CC1(C)c2cc(N(c3ccccc3)c3ccc4c(c3)C(C)(C)c3cc(-n5c6ccccc6c6ccccc65)ccc3-4)ccc2-c2ccc(-n3c4ccccc4c4ccccc43)cc21]

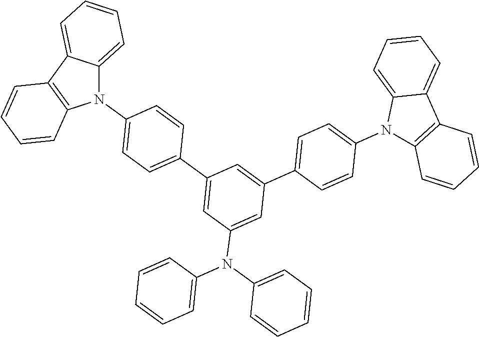 [SMILES: c1ccc(N(c2ccccc2)c2cc(-c3ccc(-n4c5ccccc5c5ccccc54)cc3)cc(-c3ccc(-n4c5ccccc5c5ccccc54)cc3)c2)cc1]

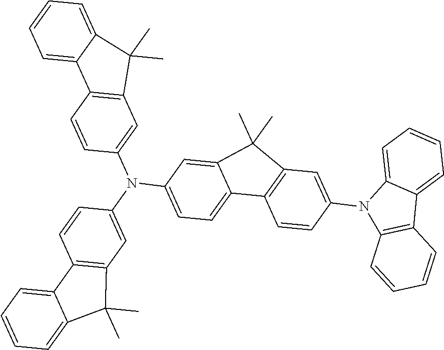 [SMILES: CC1(C)c2ccccc2-c2ccc(N(c3ccc4c(c3)C(C)(C)c3ccccc3-4)c3ccc4c(c3)C(C)(C)c3cc(-n5c6ccccc6c6ccccc65)ccc3-4)cc21]

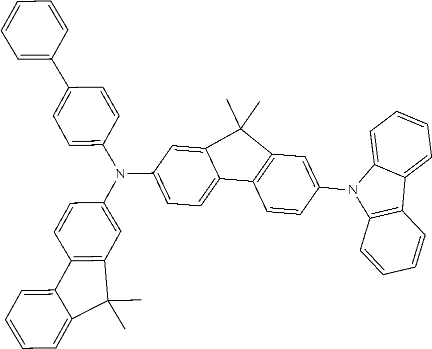 [SMILES: CC1(C)c2ccccc2-c2ccc(N(c3ccc(-c4ccccc4)cc3)c3ccc4c(c3)C(C)(C)c3cc(-n5c6ccccc6c6ccccc65)ccc3-4)cc21]

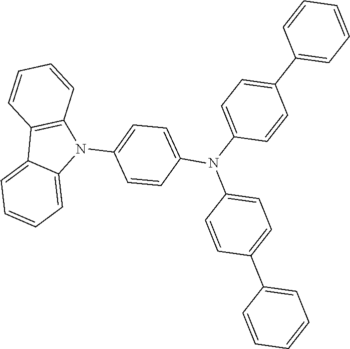 [SMILES: c1ccc(-c2ccc(N(c3ccc(-c4ccccc4)cc3)c3ccc(-n4c5ccccc5c5ccccc54)cc3)cc2)cc1]

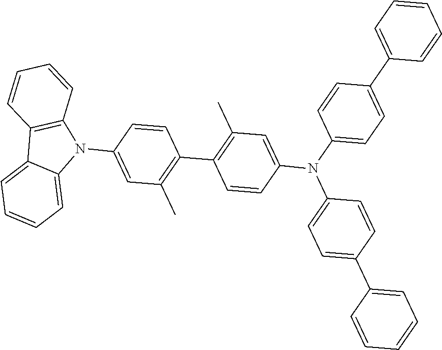 [SMILES: Cc1cc(N(c2ccc(-c3ccccc3)cc2)c2ccc(-c3ccccc3)cc2)ccc1-c1ccc(-n2c3ccccc3c3ccccc32)cc1C]

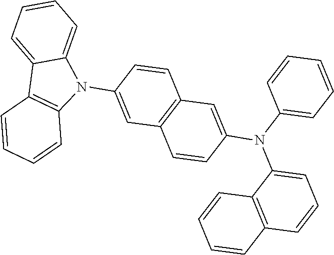 [SMILES: c1ccc(N(c2ccc3cc(-n4c5ccccc5c5ccccc54)ccc3c2)c2cccc3ccccc23)cc1]

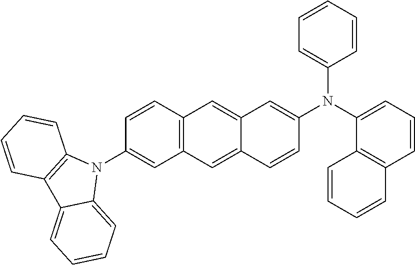 [SMILES: c1ccc(N(c2ccc3cc4cc(-n5c6ccccc6c6ccccc65)ccc4cc3c2)c2cccc3ccccc23)cc1]

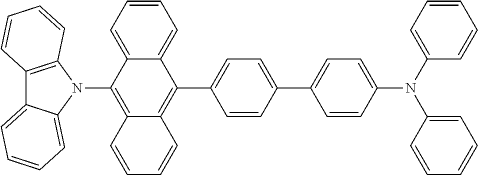 [SMILES: c1ccc(N(c2ccccc2)c2ccc(-c3ccc(-c4c5ccccc5c(-n5c6ccccc6c6ccccc65)c5ccccc45)cc3)cc2)cc1]

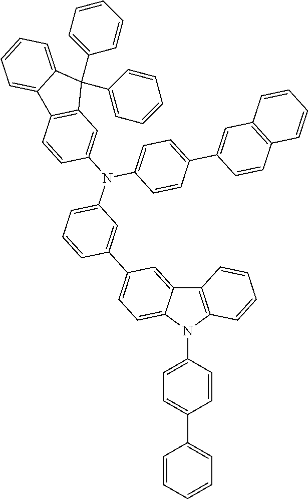 [SMILES: c1ccc(-c2ccc(-n3c4ccccc4c4cc(-c5cccc(N(c6ccc(-c7ccc8ccccc8c7)cc6)c6ccc7c(c6)C(c6ccccc6)(c6ccccc6)c6ccccc6-7)c5)ccc43)cc2)cc1]

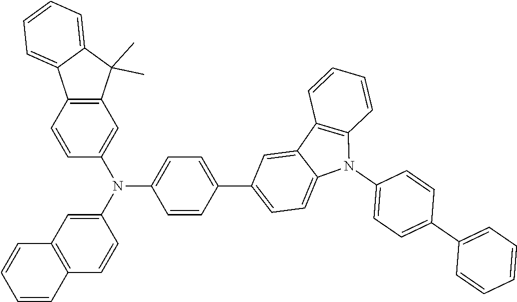 [SMILES: CC1(C)c2ccccc2-c2ccc(N(c3ccc(-c4ccc5c(c4)c4ccccc4n5-c4ccc(-c5ccccc5)cc4)cc3)c3ccc4ccccc4c3)cc21]

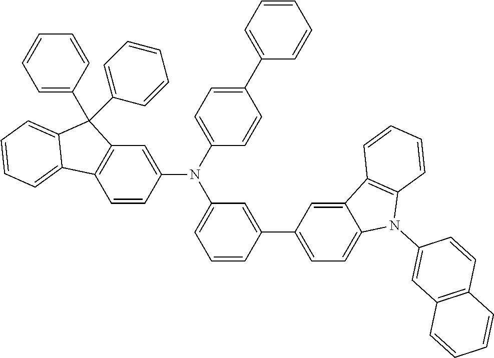 [SMILES: c1ccc(-c2ccc(N(c3cccc(-c4ccc5c(c4)c4ccccc4n5-c4ccc5ccccc5c4)c3)c3ccc4c(c3)C(c3ccccc3)(c3ccccc3)c3ccccc3-4)cc2)cc1]

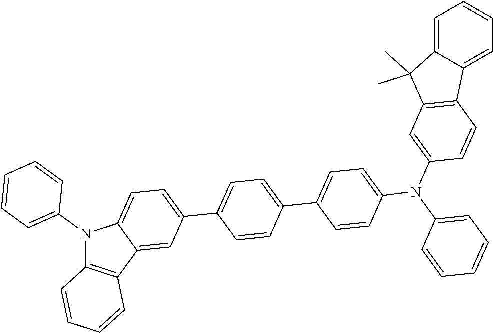 [SMILES: CC1(C)c2ccccc2-c2ccc(N(c3ccccc3)c3ccc(-c4ccc(-c5ccc6c(c5)c5ccccc5n6-c5ccccc5)cc4)cc3)cc21]

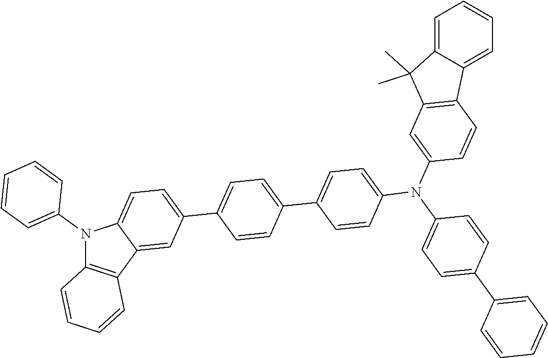 [SMILES: CC1(C)c2ccccc2-c2ccc(N(c3ccc(-c4ccccc4)cc3)c3ccc(-c4ccc(-c5ccc6c(c5)c5ccccc5n6-c5ccccc5)cc4)cc3)cc21]

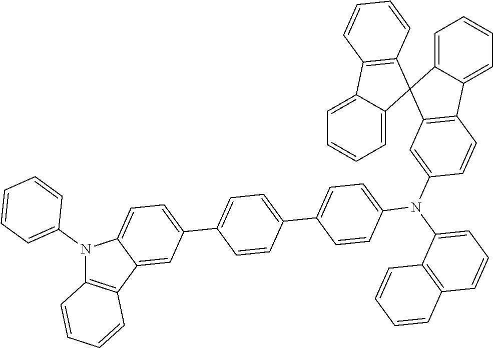 [SMILES: c1ccc(-n2c3ccccc3c3cc(-c4ccc(-c5ccc(N(c6ccc7c(c6)C6(c8ccccc8-c8ccccc86)c6ccccc6-7)c6cccc7ccccc67)cc5)cc4)ccc32)cc1]

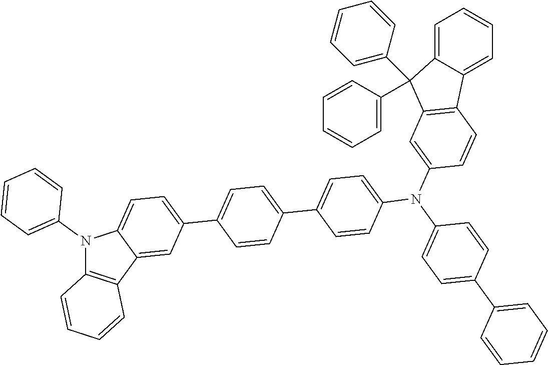 [SMILES: c1ccc(-c2ccc(N(c3ccc(-c4ccc(-c5ccc6c(c5)c5ccccc5n6-c5ccccc5)cc4)cc3)c3ccc4c(c3)C(c3ccccc3)(c3ccccc3)c3ccccc3-4)cc2)cc1]

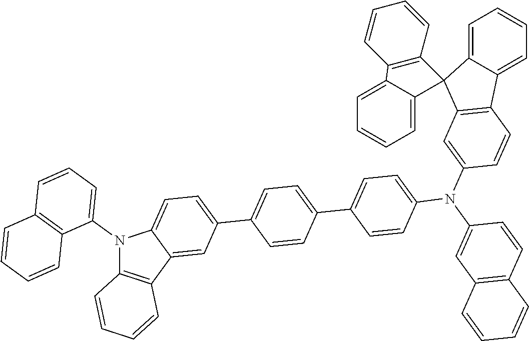 [SMILES: c1ccc2c(c1)-c1ccccc1C21c2ccccc2-c2ccc(N(c3ccc(-c4ccc(-c5ccc6c(c5)c5ccccc5n6-c5cccc6ccccc56)cc4)cc3)c3ccc4ccccc4c3)cc21]

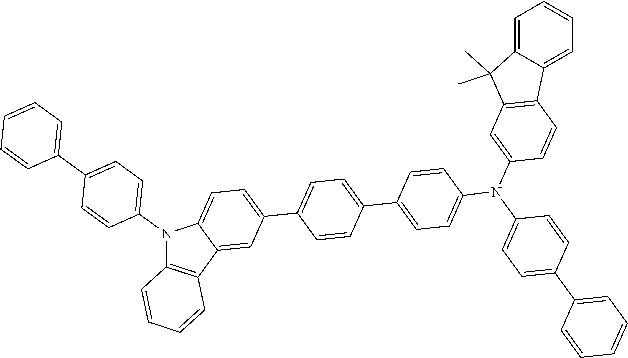 [SMILES: CC1(C)c2ccccc2-c2ccc(N(c3ccc(-c4ccccc4)cc3)c3ccc(-c4ccc(-c5ccc6c(c5)c5ccccc5n6-c5ccc(-c6ccccc6)cc5)cc4)cc3)cc21]

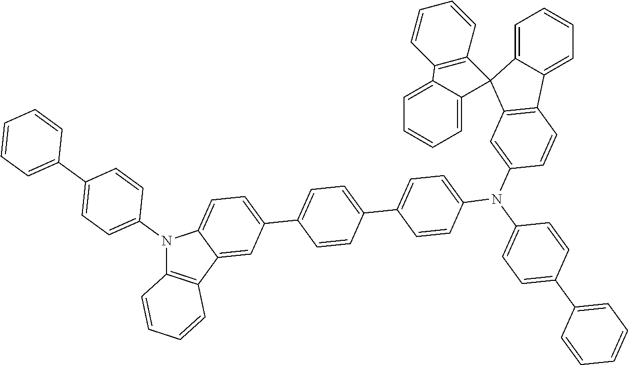 [SMILES: c1ccc(-c2ccc(N(c3ccc(-c4ccc(-c5ccc6c(c5)c5ccccc5n6-c5ccc(-c6ccccc6)cc5)cc4)cc3)c3ccc4c(c3)C3(c5ccccc5-c5ccccc53)c3ccccc3-4)cc2)cc1]

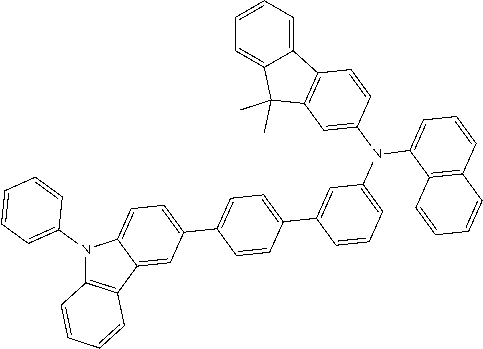 [SMILES: CC1(C)c2ccccc2-c2ccc(N(c3cccc(-c4ccc(-c5ccc6c(c5)c5ccccc5n6-c5ccccc5)cc4)c3)c3cccc4ccccc34)cc21]

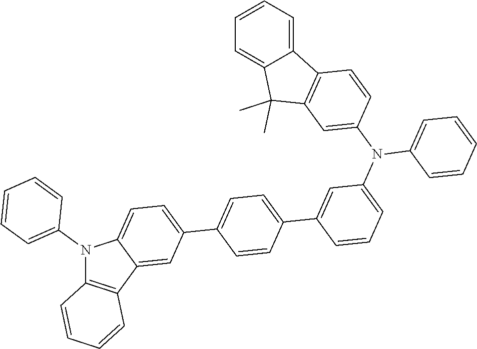 [SMILES: CC1(C)c2ccccc2-c2ccc(N(c3ccccc3)c3cccc(-c4ccc(-c5ccc6c(c5)c5ccccc5n6-c5ccccc5)cc4)c3)cc21]

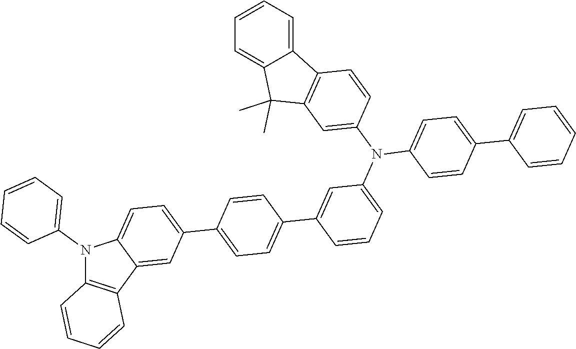 [SMILES: CC1(C)c2ccccc2-c2ccc(N(c3ccc(-c4ccccc4)cc3)c3cccc(-c4ccc(-c5ccc6c(c5)c5ccccc5n6-c5ccccc5)cc4)c3)cc21]

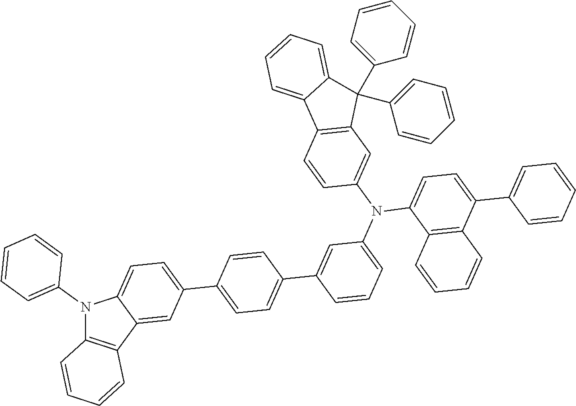 [SMILES: c1ccc(-c2ccc(N(c3cccc(-c4ccc(-c5ccc6c(c5)c5ccccc5n6-c5ccccc5)cc4)c3)c3ccc4c(c3)C(c3ccccc3)(c3ccccc3)c3ccccc3-4)c3ccccc23)cc1]

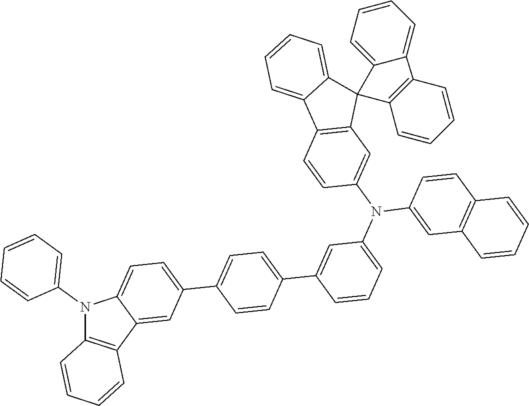 [SMILES: c1ccc(-n2c3ccccc3c3cc(-c4ccc(-c5cccc(N(c6ccc7c(c6)C6(c8ccccc8-c8ccccc86)c6ccccc6-7)c6ccc7ccccc7c6)c5)cc4)ccc32)cc1]

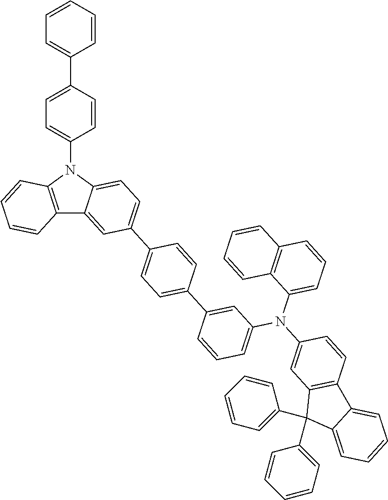 [SMILES: c1ccc(-c2ccc(-n3c4ccccc4c4cc(-c5ccc(-c6cccc(N(c7ccc8c(c7)C(c7ccccc7)(c7ccccc7)c7ccccc7-8)c7cccc8ccccc78)c6)cc5)ccc43)cc2)cc1]

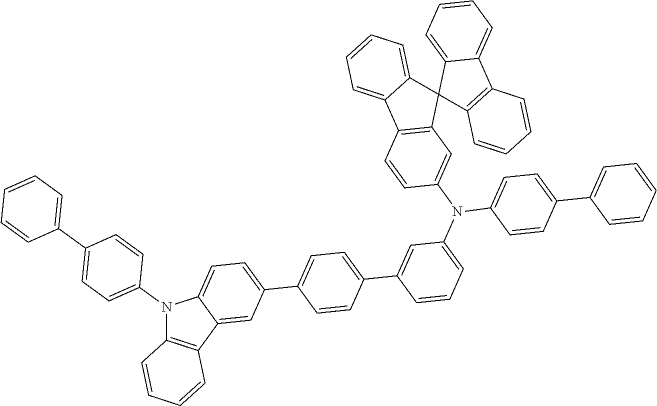 [SMILES: c1ccc(-c2ccc(N(c3cccc(-c4ccc(-c5ccc6c(c5)c5ccccc5n6-c5ccc(-c6ccccc6)cc5)cc4)c3)c3ccc4c(c3)C3(c5ccccc5-c5ccccc53)c3ccccc3-4)cc2)cc1]

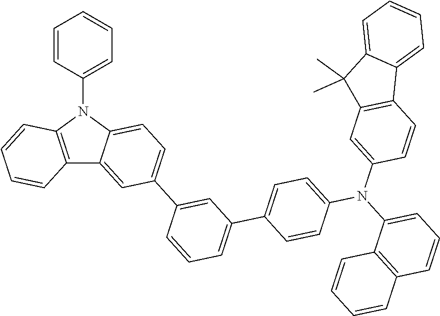 [SMILES: CC1(C)c2ccccc2-c2ccc(N(c3ccc(-c4cccc(-c5ccc6c(c5)c5ccccc5n6-c5ccccc5)c4)cc3)c3cccc4ccccc34)cc21]

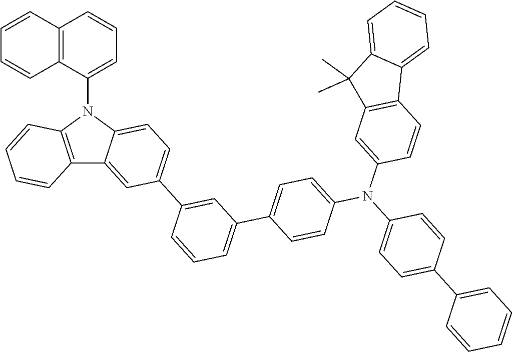 [SMILES: CC1(C)c2ccccc2-c2ccc(N(c3ccc(-c4ccccc4)cc3)c3ccc(-c4cccc(-c5ccc6c(c5)c5ccccc5n6-c5cccc6ccccc56)c4)cc3)cc21]

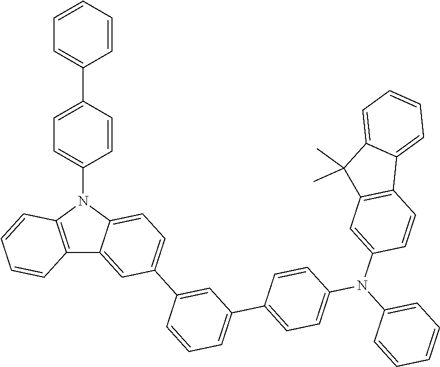 [SMILES: CC1(C)c2ccccc2-c2ccc(N(c3ccccc3)c3ccc(-c4cccc(-c5ccc6c(c5)c5ccccc5n6-c5ccc(-c6ccccc6)cc5)c4)cc3)cc21]

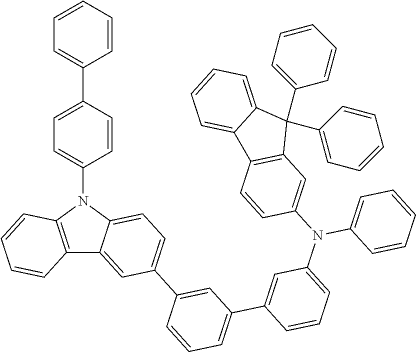 [SMILES: c1ccc(-c2ccc(-n3c4ccccc4c4cc(-c5cccc(-c6cccc(N(c7ccccc7)c7ccc8c(c7)C(c7ccccc7)(c7ccccc7)c7ccccc7-8)c6)c5)ccc43)cc2)cc1]

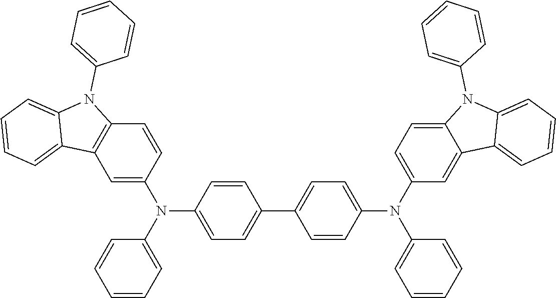 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

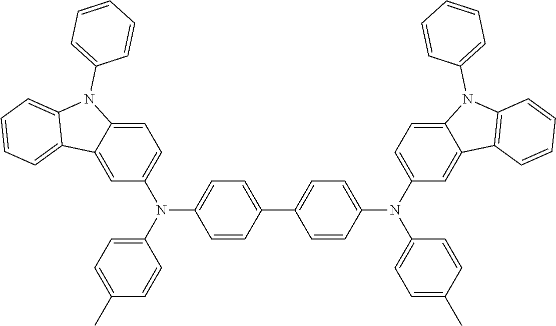 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

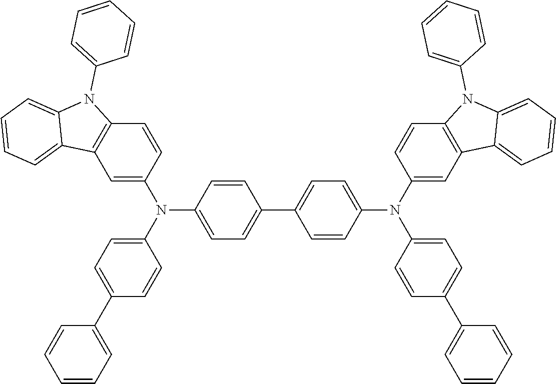 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

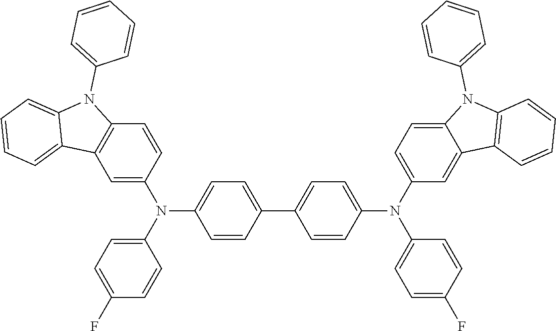 [SMILES: Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

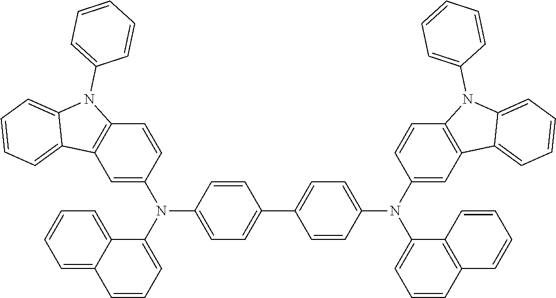 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

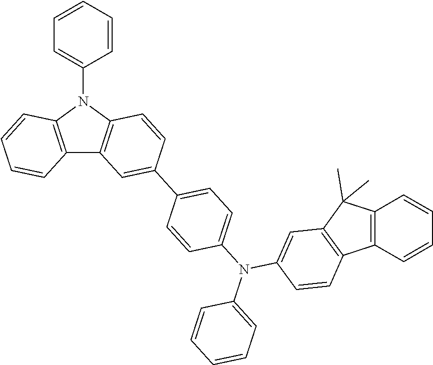 [SMILES: CC1(C)c2ccccc2-c2ccc(N(c3ccccc3)c3ccc(-c4ccc5c(c4)c4ccccc4n5-c4ccccc4)cc3)cc21]

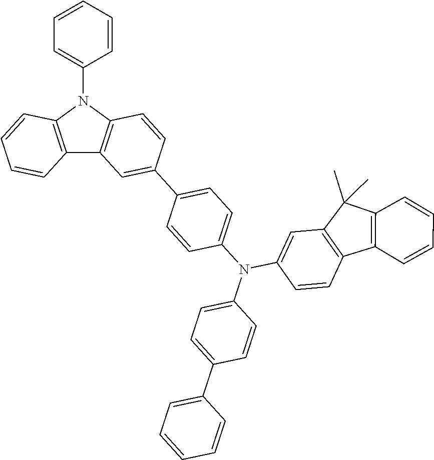 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

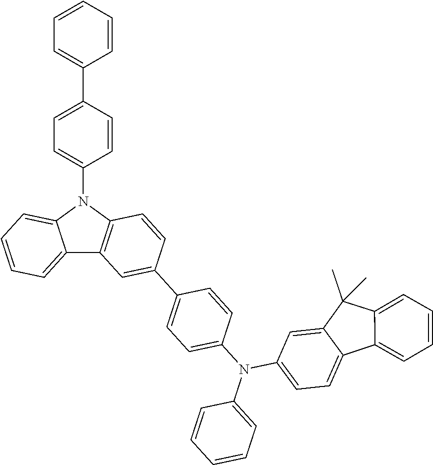 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21]

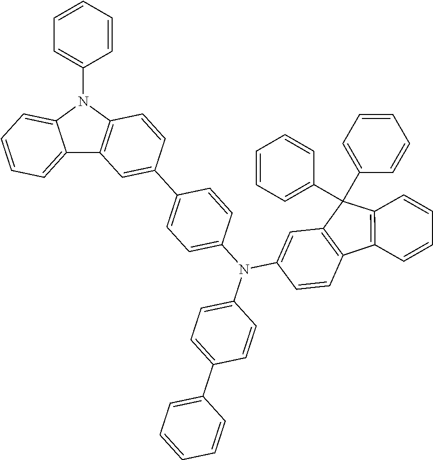 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

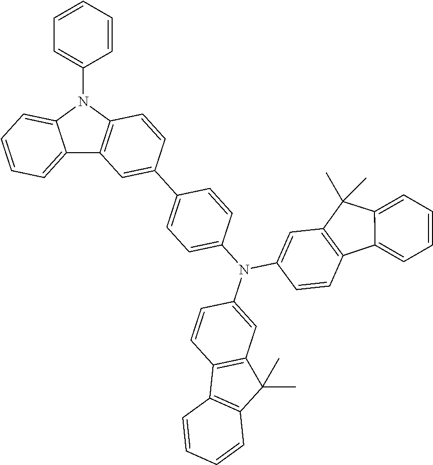 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

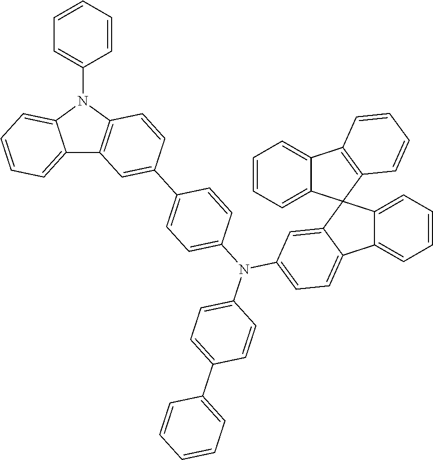 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

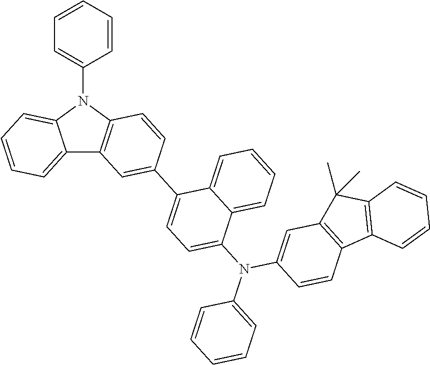 [SMILES: CC1(C)c2ccccc2-c2ccc(N(c3ccccc3)c3ccc(-c4ccc5c(c4)c4ccccc4n5-c4ccccc4)c4ccccc34)cc21]

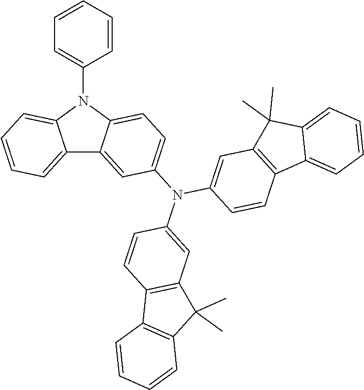 [SMILES: CC1(C)c2ccccc2-c2ccc(N(c3ccc4c(c3)C(C)(C)c3ccccc3-4)c3ccc4c(c3)c3ccccc3n4-c3ccccc3)cc21]

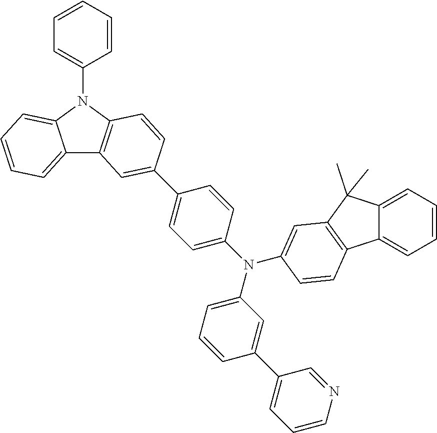 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21]

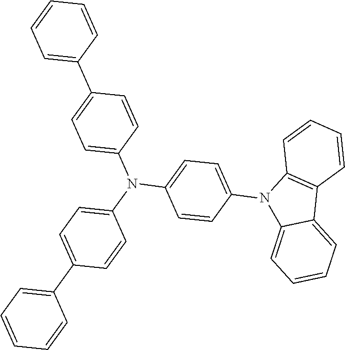 [SMILES: c1ccc(-c2ccc(N(c3ccc(-c4ccccc4)cc3)c3ccc(-n4c5ccccc5c5ccccc54)cc3)cc2)cc1]

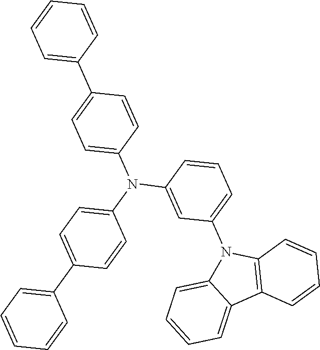 [SMILES: c1ccc(-c2ccc(N(c3ccc(-c4ccccc4)cc3)c3cccc(-n4c5ccccc5c5ccccc54)c3)cc2)cc1]

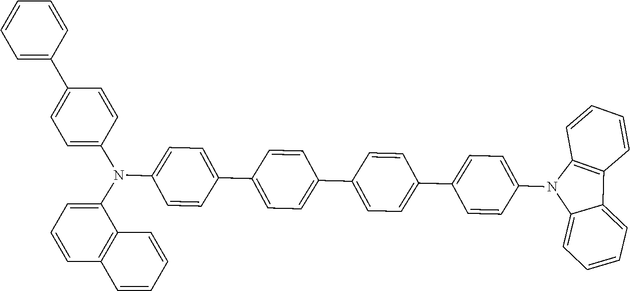 [SMILES: c1ccc(-c2ccc(N(c3ccc(-c4ccc(-c5ccc(-c6ccc(-n7c8ccccc8c8ccccc87)cc6)cc5)cc4)cc3)c3cccc4ccccc34)cc2)cc1]

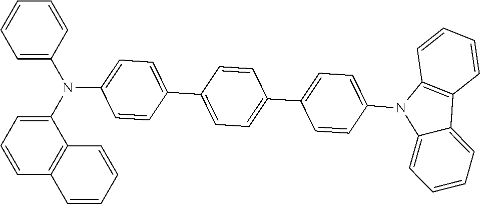 [SMILES: c1ccc(N(c2ccc(-c3ccc(-c4ccc(-n5c6ccccc6c6ccccc65)cc4)cc3)cc2)c2cccc3ccccc23)cc1]

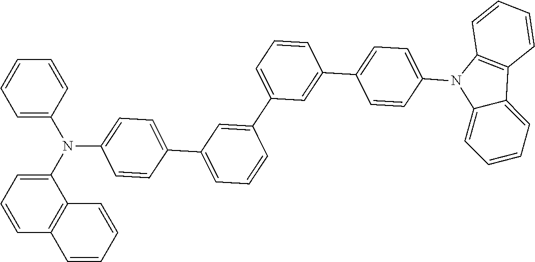 [SMILES: c1ccc(N(c2ccc(-c3cccc(-c4cccc(-c5ccc(-n6c7ccccc7c7ccccc76)cc5)c4)c3)cc2)c2cccc3ccccc23)cc1]

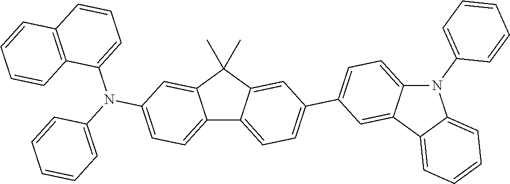 [SMILES: CC1(C)c2cc(-c3ccc4c(c3)c3ccccc3n4-c3ccccc3)ccc2-c2ccc(N(c3ccccc3)c3cccc4ccccc34)cc21]

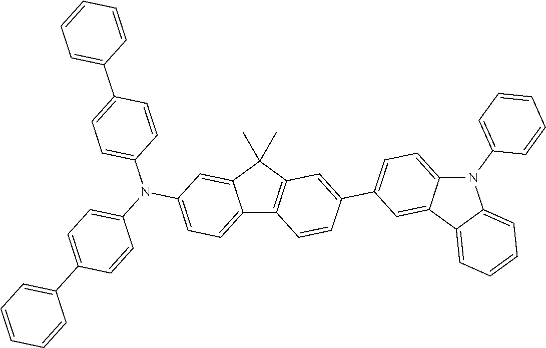 [SMILES: CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21]

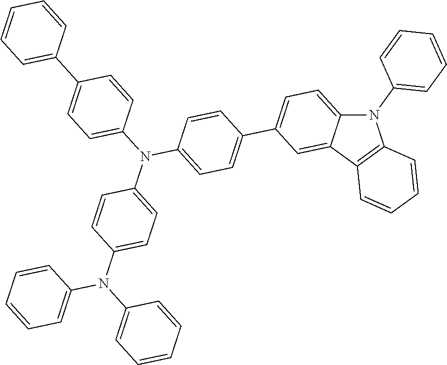 [SMILES: c1ccc(-c2ccc(N(c3ccc(-c4ccc5c(c4)c4ccccc4n5-c4ccccc4)cc3)c3ccc(N(c4ccccc4)c4ccccc4)cc3)cc2)cc1]

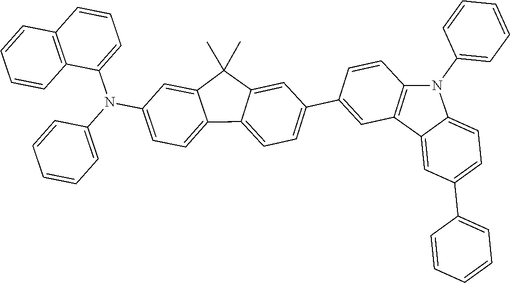 [SMILES: CC1(C)c2cc(-c3ccc4c(c3)c3cc(-c5ccccc5)ccc3n4-c3ccccc3)ccc2-c2ccc(N(c3ccccc3)c3cccc4ccccc34)cc21]

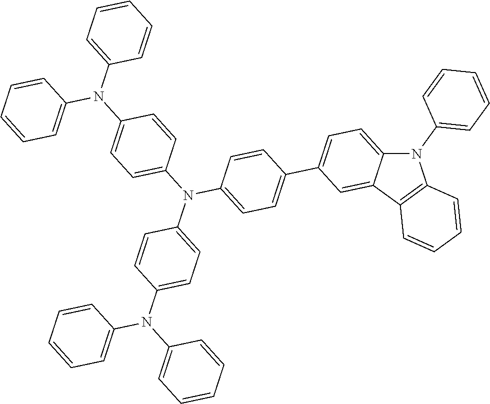 [SMILES: c1ccc(N(c2ccccc2)c2ccc(N(c3ccc(-c4ccc5c(c4)c4ccccc4n5-c4ccccc4)cc3)c3ccc(N(c4ccccc4)c4ccccc4)cc3)cc2)cc1]

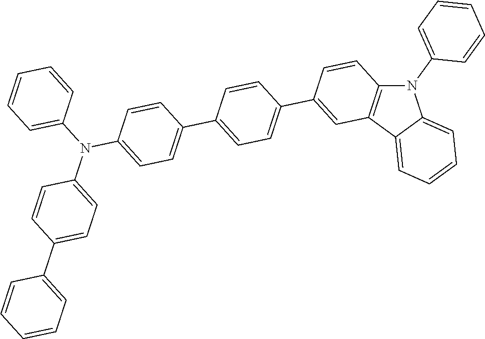 [SMILES: c1ccc(-c2ccc(N(c3ccccc3)c3ccc(-c4ccc(-c5ccc6c(c5)c5ccccc5n6-c5ccccc5)cc4)cc3)cc2)cc1]

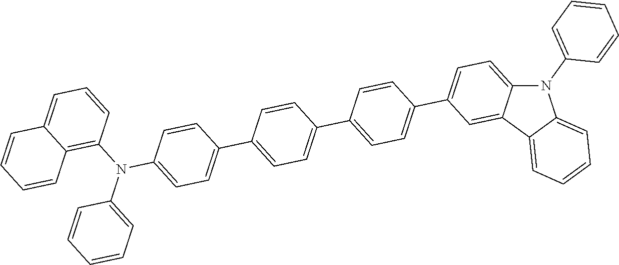 [SMILES: c1ccc(N(c2ccc(-c3ccc(-c4ccc(-c5ccc6c(c5)c5ccccc5n6-c5ccccc5)cc4)cc3)cc2)c2cccc3ccccc23)cc1]

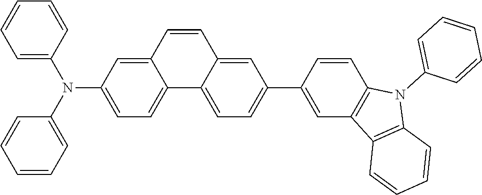 [SMILES: c1ccc(N(c2ccccc2)c2ccc3c(ccc4cc(-c5ccc6c(c5)c5ccccc5n6-c5ccccc5)ccc43)c2)cc1]

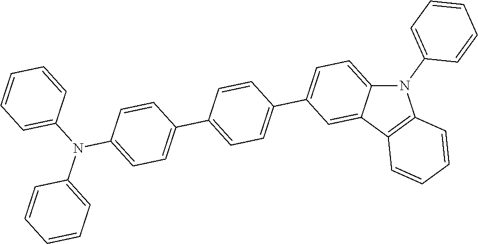 [SMILES: c1ccc(N(c2ccccc2)c2ccc(-c3ccc(-c4ccc5c(c4)c4ccccc4n5-c4ccccc4)cc3)cc2)cc1]

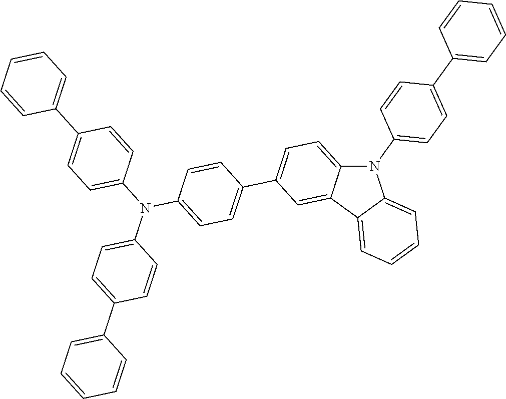 [SMILES: c1ccc(-c2ccc(N(c3ccc(-c4ccccc4)cc3)c3ccc(-c4ccc5c(c4)c4ccccc4n5-c4ccc(-c5ccccc5)cc4)cc3)cc2)cc1]

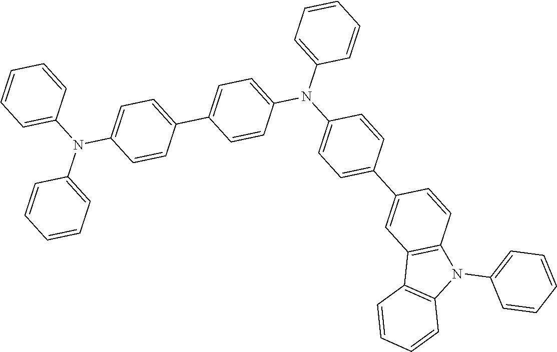 [SMILES: c1ccc(N(c2ccccc2)c2ccc(-c3ccc(N(c4ccccc4)c4ccc(-c5ccc6c(c5)c5ccccc5n6-c5ccccc5)cc4)cc3)cc2)cc1]

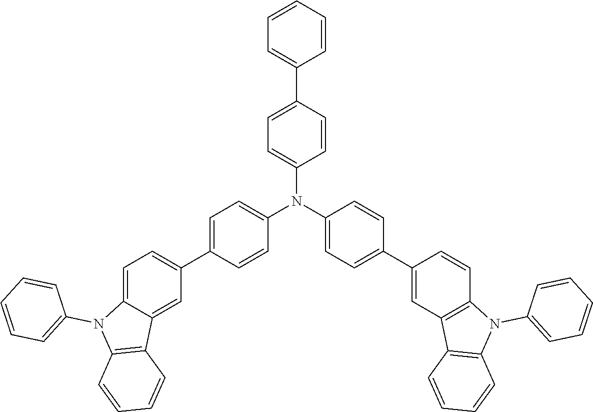 [SMILES: c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc2)cc1]

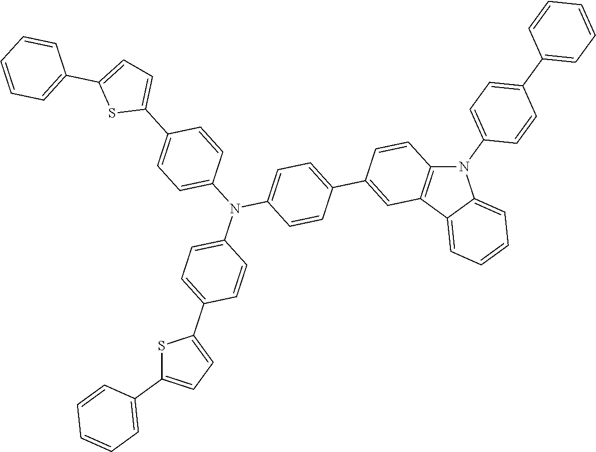 [SMILES: c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1]

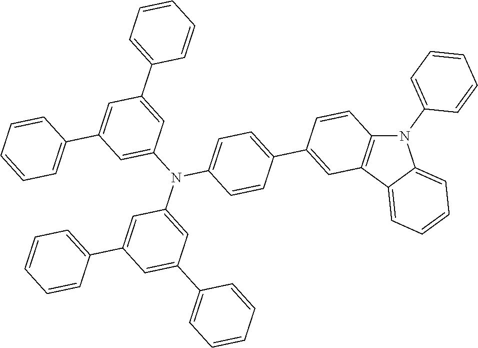 [SMILES: c1ccc(-c2cc(-c3ccccc3)cc(N(c3ccc(-c4ccc5c(c4)c4ccccc4n5-c4ccccc4)cc3)c3cc(-c4ccccc4)cc(-c4ccccc4)c3)c2)cc1]

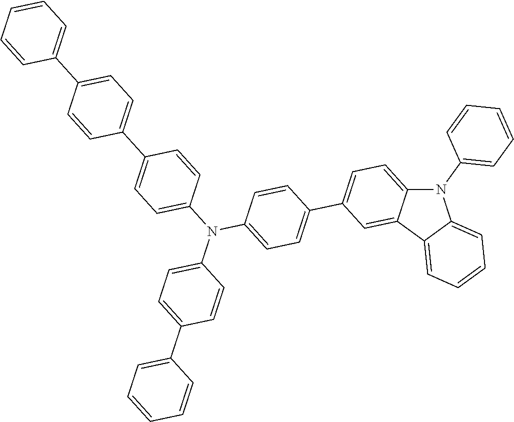 [SMILES: c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

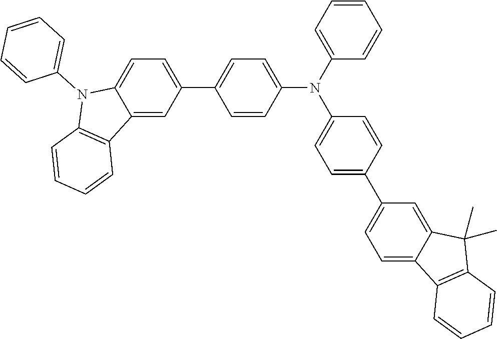 [SMILES: CC1(C)c2ccccc2-c2ccc(-c3ccc(N(c4ccccc4)c4ccc(-c5ccc6c(c5)c5ccccc5n6-c5ccccc5)cc4)cc3)cc21]

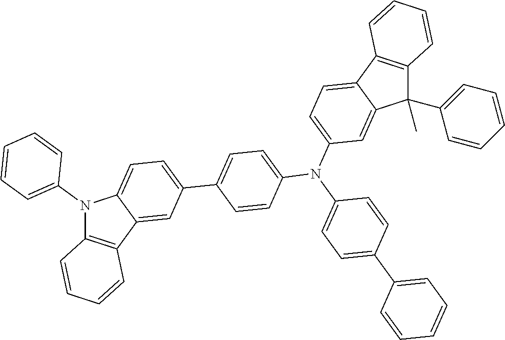 [SMILES: CC1(c2ccccc2)c2ccccc2-c2ccc(N(c3ccc(-c4ccccc4)cc3)c3ccc(-c4ccc5c(c4)c4ccccc4n5-c4ccccc4)cc3)cc21]

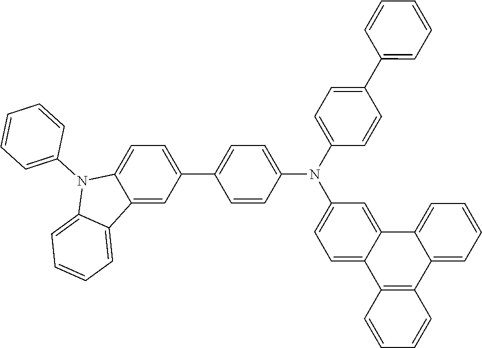 [SMILES: c1ccc(-c2ccc(N(c3ccc(-c4ccc5c(c4)c4ccccc4n5-c4ccccc4)cc3)c3ccc4c5ccccc5c5ccccc5c4c3)cc2)cc1]

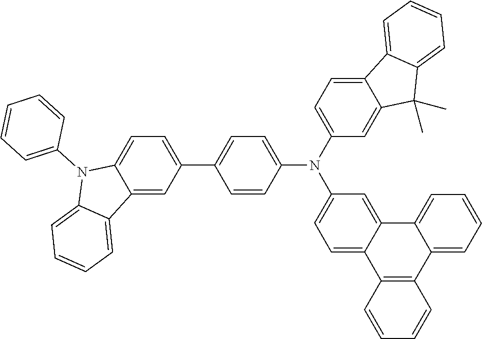 [SMILES: CC1(C)c2ccccc2-c2ccc(N(c3ccc(-c4ccc5c(c4)c4ccccc4n5-c4ccccc4)cc3)c3ccc4c5ccccc5c5ccccc5c4c3)cc21]

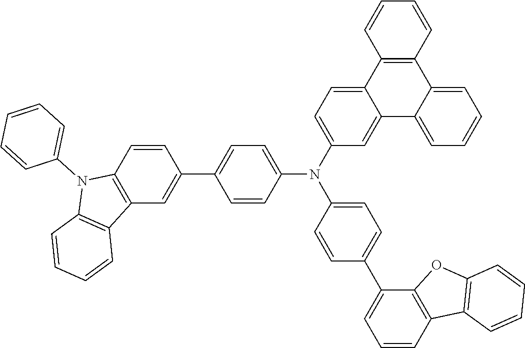 [SMILES: c1ccc(-n2c3ccccc3c3cc(-c4ccc(N(c5ccc(-c6cccc7c6oc6ccccc67)cc5)c5ccc6c7ccccc7c7ccccc7c6c5)cc4)ccc32)cc1]

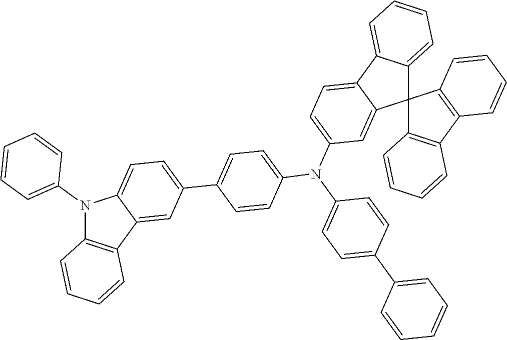 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

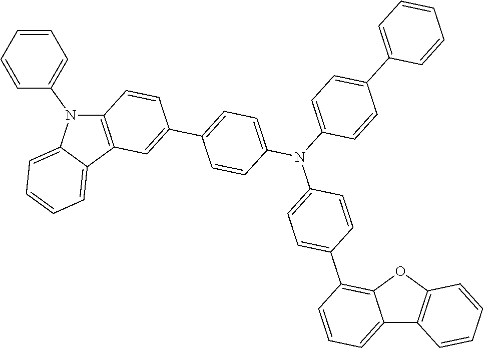 [SMILES: c1ccc(-c2ccc(N(c3ccc(-c4ccc5c(c4)c4ccccc4n5-c4ccccc4)cc3)c3ccc(-c4cccc5c4oc4ccccc45)cc3)cc2)cc1]

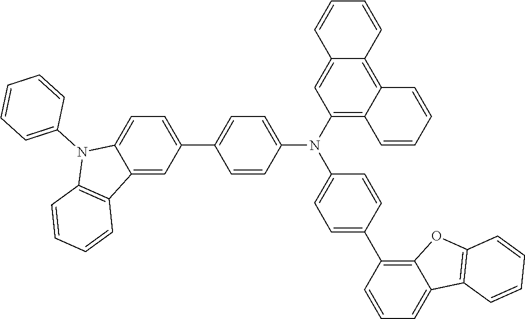 [SMILES: c1ccc(-n2c3ccccc3c3cc(-c4ccc(N(c5ccc(-c6cccc7c6oc6ccccc67)cc5)c5cc6ccccc6c6ccccc56)cc4)ccc32)cc1]

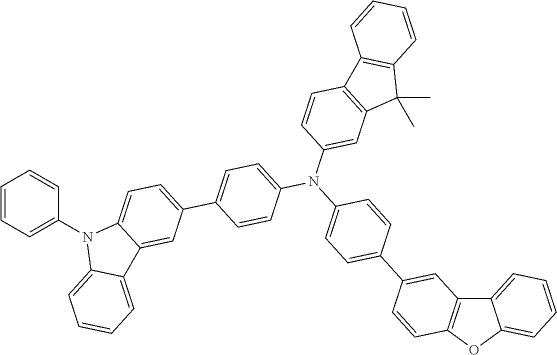 [SMILES: CC1(C)c2ccccc2-c2ccc(N(c3ccc(-c4ccc5oc6ccccc6c5c4)cc3)c3ccc(-c4ccc5c(c4)c4ccccc4n5-c4ccccc4)cc3)cc21]

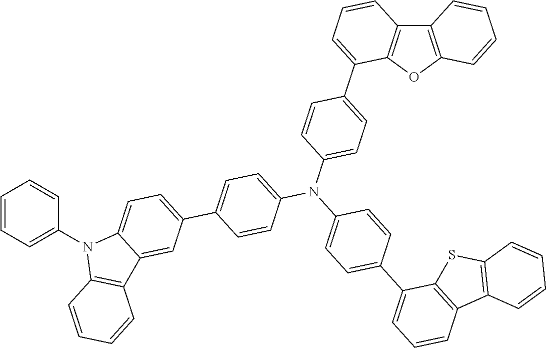 [SMILES: c1ccc(-n2c3ccccc3c3cc(-c4ccc(N(c5ccc(-c6cccc7c6oc6ccccc67)cc5)c5ccc(-c6cccc7c6sc6ccccc67)cc5)cc4)ccc32)cc1]

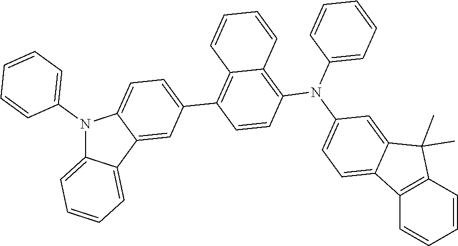 [SMILES: CC1(C)c2ccccc2-c2ccc(N(c3ccccc3)c3ccc(-c4ccc5c(c4)c4ccccc4n5-c4ccccc4)c4ccccc34)cc21]

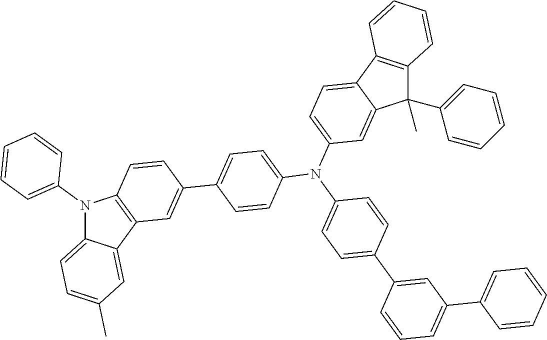 [SMILES: Cc1ccc2c(c1)c1cc(-c3ccc(N(c4ccc(-c5cccc(-c6ccccc6)c5)cc4)c4ccc5c(c4)C(C)(c4ccccc4)c4ccccc4-5)cc3)ccc1n2-c1ccccc1]

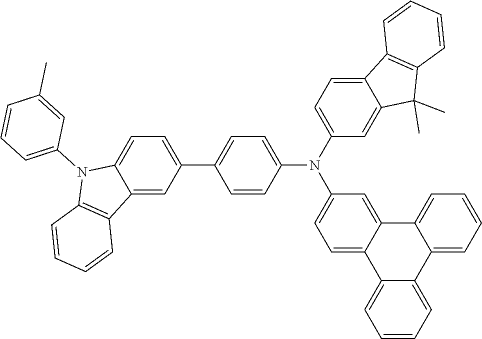 [SMILES: Cc1cccc(-n2c3ccccc3c3cc(-c4ccc(N(c5ccc6c(c5)C(C)(C)c5ccccc5-6)c5ccc6c7ccccc7c7ccccc7c6c5)cc4)ccc32)c1]

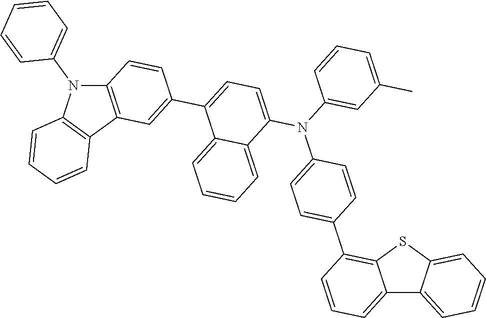 [SMILES: Cc1cccc(N(c2ccc(-c3cccc4c3sc3ccccc34)cc2)c2ccc(-c3ccc4c(c3)c3ccccc3n4-c3ccccc3)c3ccccc23)c1]

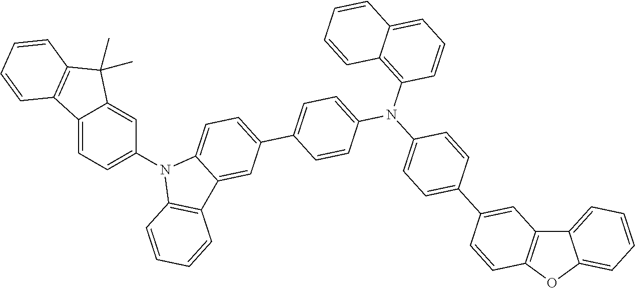 [SMILES: CC1(C)c2ccccc2-c2ccc(-n3c4ccccc4c4cc(-c5ccc(N(c6ccc(-c7ccc8oc9ccccc9c8c7)cc6)c6cccc7ccccc67)cc5)ccc43)cc21]

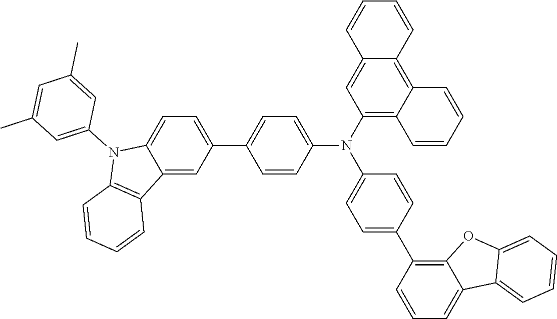 [SMILES: Cc1cc(C)cc(-n2c3ccccc3c3cc(-c4ccc(N(c5ccc(-c6cccc7c6oc6ccccc67)cc5)c5cc6ccccc6c6ccccc56)cc4)ccc32)c1]

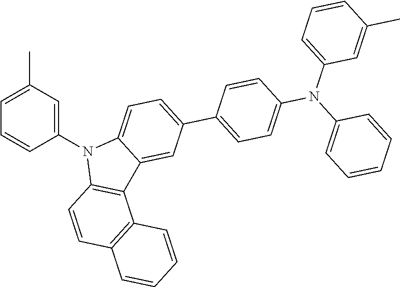 [SMILES: Cc1cccc(N(c2ccccc2)c2ccc(-c3ccc4c(c3)c3c5ccccc5ccc3n4-c3cccc(C)c3)cc2)c1]

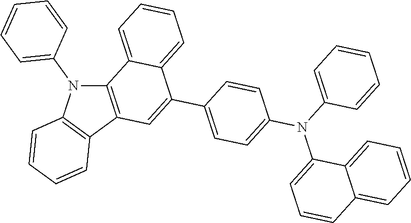 [SMILES: c1ccc(N(c2ccc(-c3cc4c5ccccc5n(-c5ccccc5)c4c4ccccc34)cc2)c2cccc3ccccc23)cc1]

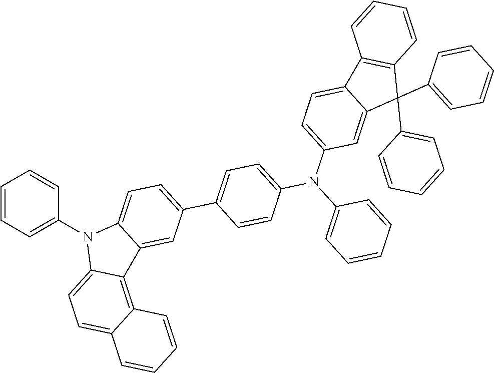 [SMILES: c1ccc(N(c2ccc(-c3ccc4c(c3)c3c5ccccc5ccc3n4-c3ccccc3)cc2)c2ccc3c(c2)C(c2ccccc2)(c2ccccc2)c2ccccc2-3)cc1]

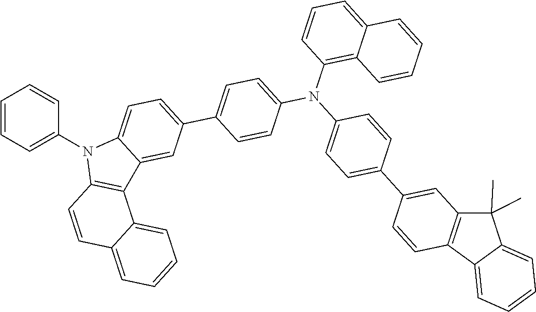 [SMILES: CC1(C)c2ccccc2-c2ccc(-c3ccc(N(c4ccc(-c5ccc6c(c5)c5c7ccccc7ccc5n6-c5ccccc5)cc4)c4cccc5ccccc45)cc3)cc21]

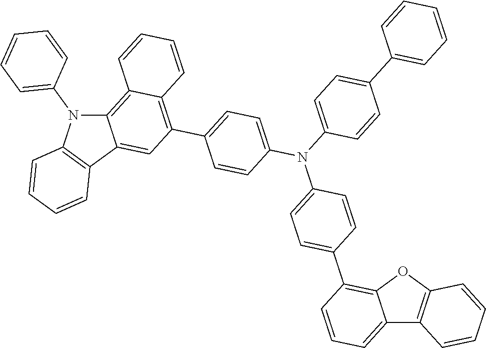 [SMILES: c1ccc(-c2ccc(N(c3ccc(-c4cc5c6ccccc6n(-c6ccccc6)c5c5ccccc45)cc3)c3ccc(-c4cccc5c4oc4ccccc45)cc3)cc2)cc1]

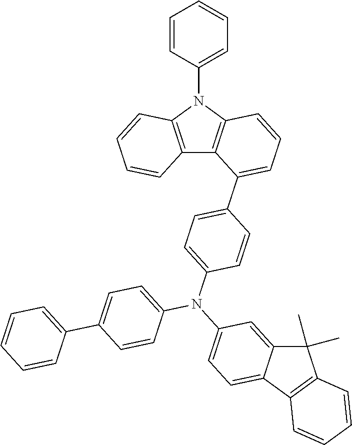 [SMILES: CC1(C)c2ccccc2-c2ccc(N(c3ccc(-c4ccccc4)cc3)c3ccc(-c4cccc5c4c4ccccc4n5-c4ccccc4)cc3)cc21]

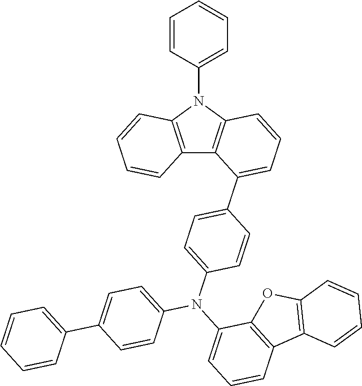 [SMILES: c1ccc(-c2ccc(N(c3ccc(-c4cccc5c4c4ccccc4n5-c4ccccc4)cc3)c3cccc4c3oc3ccccc34)cc2)cc1]

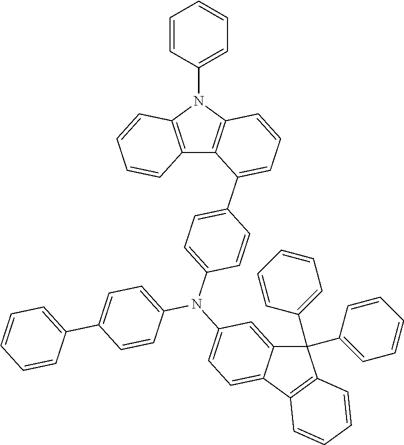 [SMILES: c1ccc(-c2ccc(N(c3ccc(-c4cccc5c4c4ccccc4n5-c4ccccc4)cc3)c3ccc4c(c3)C(c3ccccc3)(c3ccccc3)c3ccccc3-4)cc2)cc1]

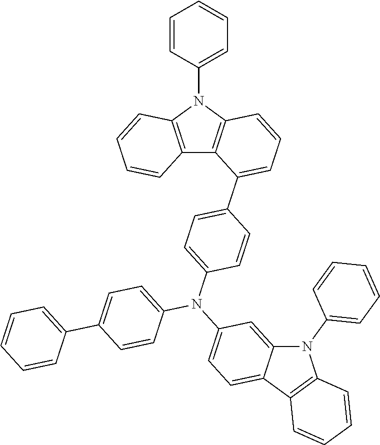 [SMILES: c1ccc(-c2ccc(N(c3ccc(-c4cccc5c4c4ccccc4n5-c4ccccc4)cc3)c3ccc4c5ccccc5n(-c5ccccc5)c4c3)cc2)cc1]

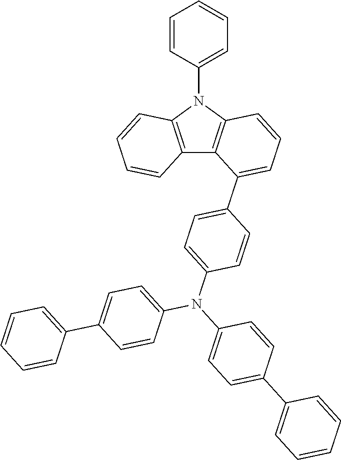 [SMILES: c1ccc(-c2ccc(N(c3ccc(-c4ccccc4)cc3)c3ccc(-c4cccc5c4c4ccccc4n5-c4ccccc4)cc3)cc2)cc1]

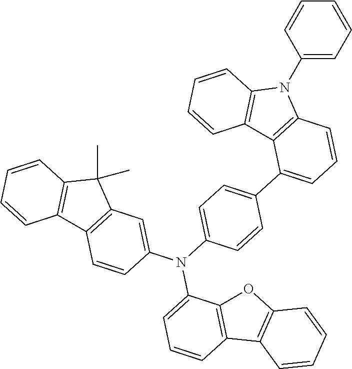 [SMILES: CC1(C)c2ccccc2-c2ccc(N(c3ccc(-c4cccc5c4c4ccccc4n5-c4ccccc4)cc3)c3cccc4c3oc3ccccc34)cc21]

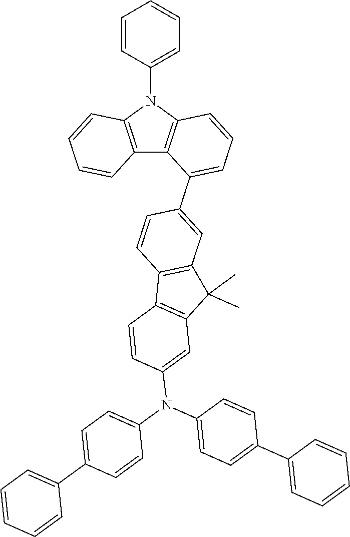 [SMILES: CC1(C)c2cc(-c3cccc4c3c3ccccc3n4-c3ccccc3)ccc2-c2ccc(N(c3ccc(-c4ccccc4)cc3)c3ccc(-c4ccccc4)cc3)cc21]

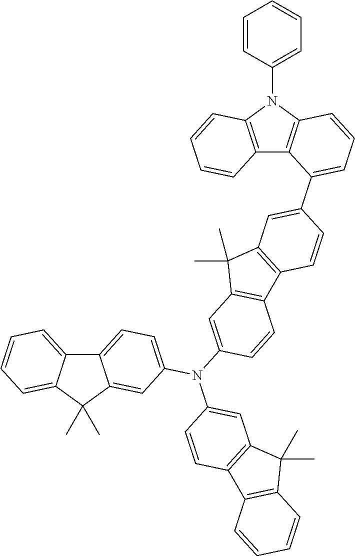 [SMILES: CC1(C)c2ccccc2-c2ccc(N(c3ccc4c(c3)C(C)(C)c3ccccc3-4)c3ccc4c(c3)C(C)(C)c3cc(-c5cccc6c5c5ccccc5n6-c5ccccc5)ccc3-4)cc21]

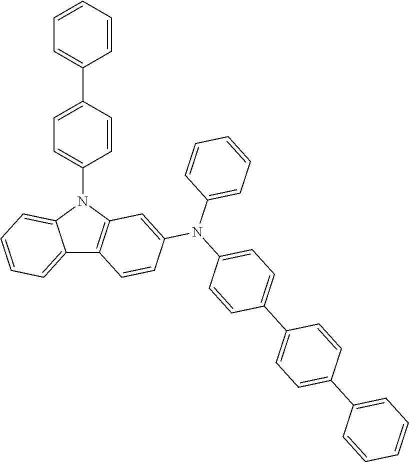 [SMILES: c1ccc(-c2ccc(-c3ccc(N(c4ccccc4)c4ccc5c6ccccc6n(-c6ccc(-c7ccccc7)cc6)c5c4)cc3)cc2)cc1]

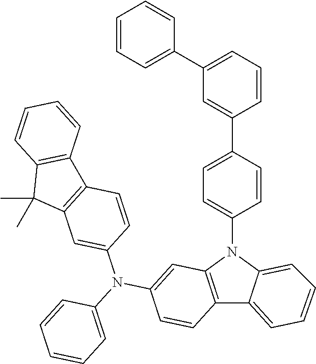 [SMILES: CC1(C)c2ccccc2-c2ccc(N(c3ccccc3)c3ccc4c5ccccc5n(-c5ccc(-c6cccc(-c7ccccc7)c6)cc5)c4c3)cc21]

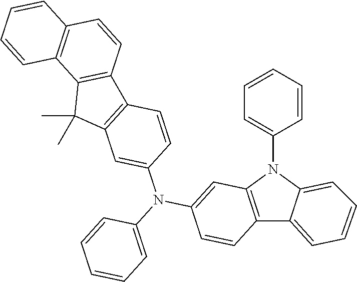 [SMILES: CC1(C)c2cc(N(c3ccccc3)c3ccc4c5ccccc5n(-c5ccccc5)c4c3)ccc2-c2ccc3ccccc3c21]

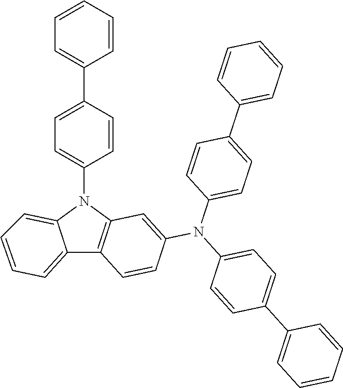 [SMILES: c1ccc(-c2ccc(N(c3ccc(-c4ccccc4)cc3)c3ccc4c5ccccc5n(-c5ccc(-c6ccccc6)cc5)c4c3)cc2)cc1]

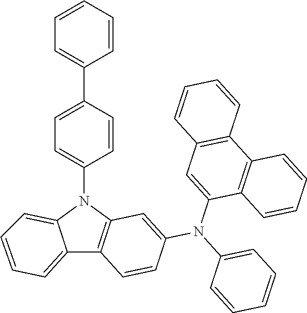 [SMILES: c1ccc(-c2ccc(-n3c4ccccc4c4ccc(N(c5ccccc5)c5cc6ccccc6c6ccccc56)cc43)cc2)cc1]

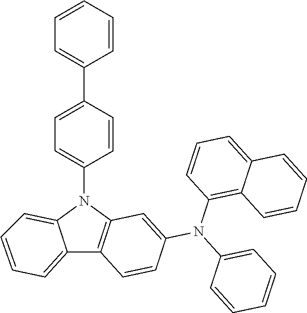 [SMILES: c1ccc(-c2ccc(-n3c4ccccc4c4ccc(N(c5ccccc5)c5cccc6ccccc56)cc43)cc2)cc1]

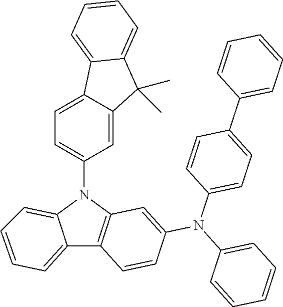 [SMILES: CC1(C)c2ccccc2-c2ccc(-n3c4ccccc4c4ccc(N(c5ccccc5)c5ccc(-c6ccccc6)cc5)cc43)cc21]

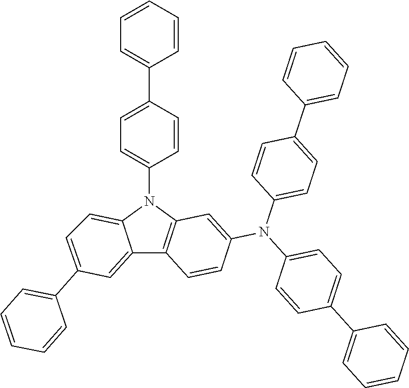 [SMILES: c1ccc(-c2ccc(N(c3ccc(-c4ccccc4)cc3)c3ccc4c5cc(-c6ccccc6)ccc5n(-c5ccc(-c6ccccc6)cc5)c4c3)cc2)cc1]

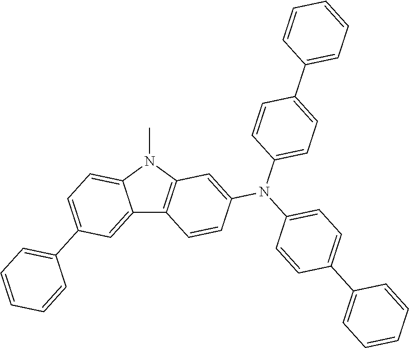 [SMILES: Cn1c2ccc(-c3ccccc3)cc2c2ccc(N(c3ccc(-c4ccccc4)cc3)c3ccc(-c4ccccc4)cc3)cc21]

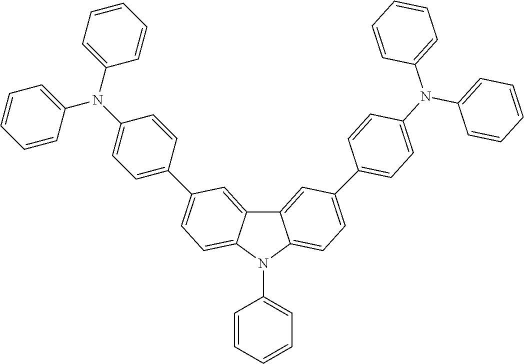 [SMILES: c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1]

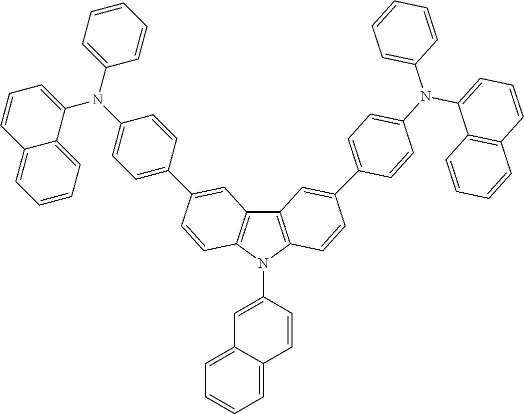 [SMILES: c1ccc(N(c2ccc(-c3ccc4c(c3)c3cc(-c5ccc(N(c6ccccc6)c6cccc7ccccc67)cc5)ccc3n4-c3ccc4ccccc4c3)cc2)c2cccc3ccccc23)cc1]

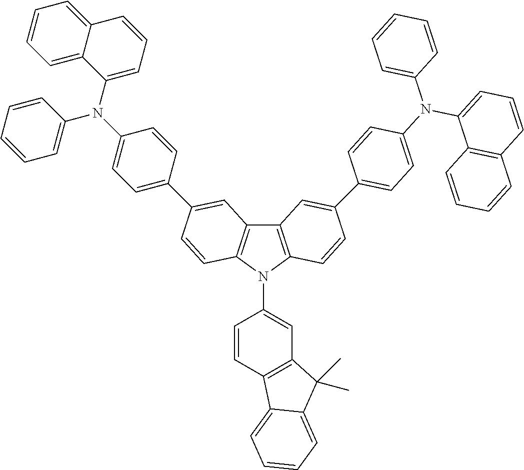 [SMILES: CC1(C)c2ccccc2-c2ccc(-n3c4ccc(-c5ccc(N(c6ccccc6)c6cccc7ccccc67)cc5)cc4c4cc(-c5ccc(N(c6ccccc6)c6cccc7ccccc67)cc5)ccc43)cc21]

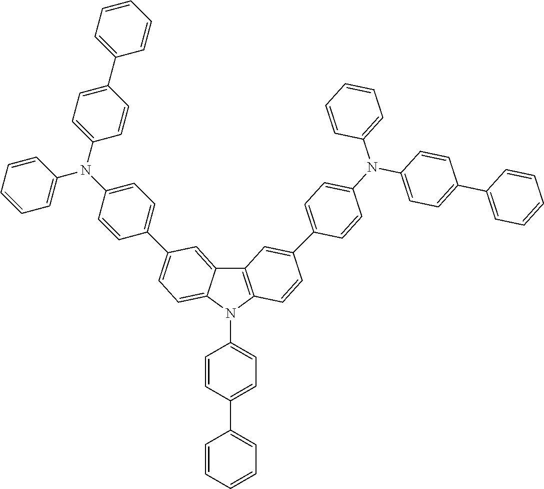 [SMILES: c1ccc(-c2ccc(N(c3ccccc3)c3ccc(-c4ccc5c(c4)c4cc(-c6ccc(N(c7ccccc7)c7ccc(-c8ccccc8)cc7)cc6)ccc4n5-c4ccc(-c5ccccc5)cc4)cc3)cc2)cc1]

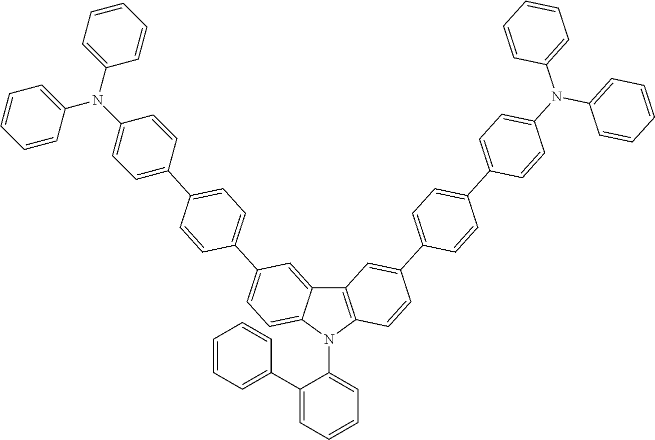 [SMILES: c1ccc(-c2ccccc2-n2c3ccc(-c4ccc(-c5ccc(N(c6ccccc6)c6ccccc6)cc5)cc4)cc3c3cc(-c4ccc(-c5ccc(N(c6ccccc6)c6ccccc6)cc5)cc4)ccc32)cc1]

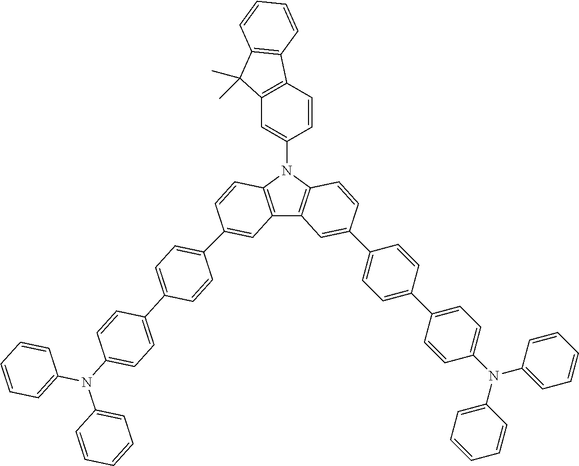 [SMILES: CC1(C)c2ccccc2-c2ccc(-n3c4ccc(-c5ccc(-c6ccc(N(c7ccccc7)c7ccccc7)cc6)cc5)cc4c4cc(-c5ccc(-c6ccc(N(c7ccccc7)c7ccccc7)cc6)cc5)ccc43)cc21]

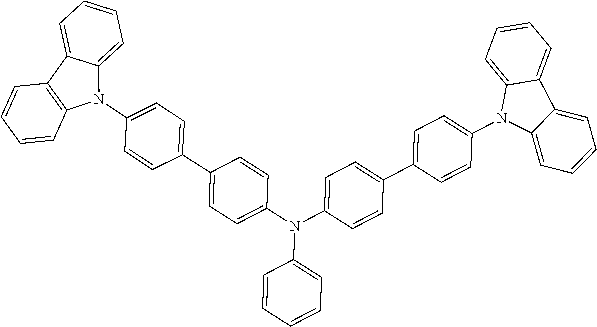 [SMILES: c1ccc(N(c2ccc(-c3ccc(-n4c5ccccc5c5ccccc54)cc3)cc2)c2ccc(-c3ccc(-n4c5ccccc5c5ccccc54)cc3)cc2)cc1]

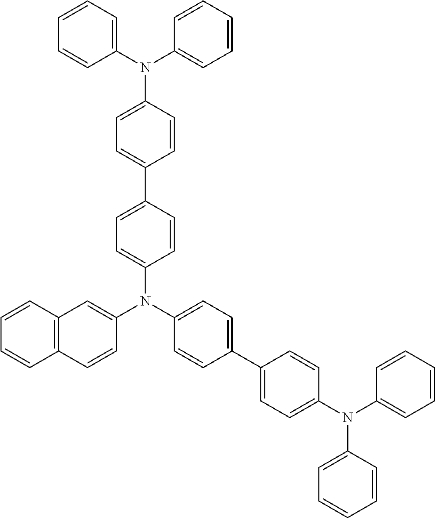 [SMILES: c1ccc(N(c2ccccc2)c2ccc(-c3ccc(N(c4ccc(-c5ccc(N(c6ccccc6)c6ccccc6)cc5)cc4)c4ccc5ccccc5c4)cc3)cc2)cc1]

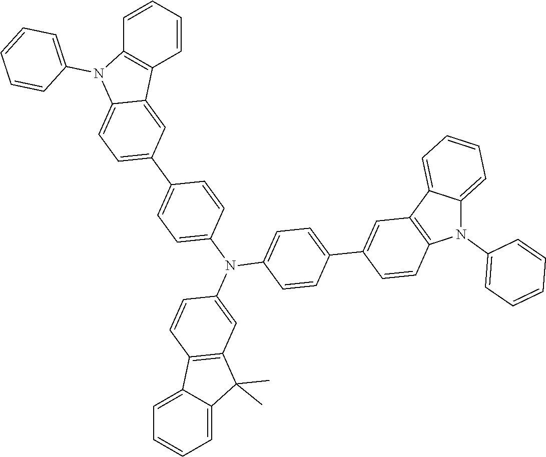 [SMILES: CC1(C)c2ccccc2-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc21]

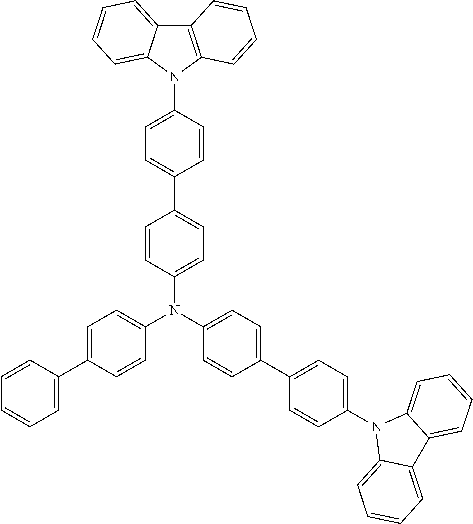 [SMILES: c1ccc(-c2ccc(N(c3ccc(-c4ccc(-n5c6ccccc6c6ccccc65)cc4)cc3)c3ccc(-c4ccc(-n5c6ccccc6c6ccccc65)cc4)cc3)cc2)cc1]

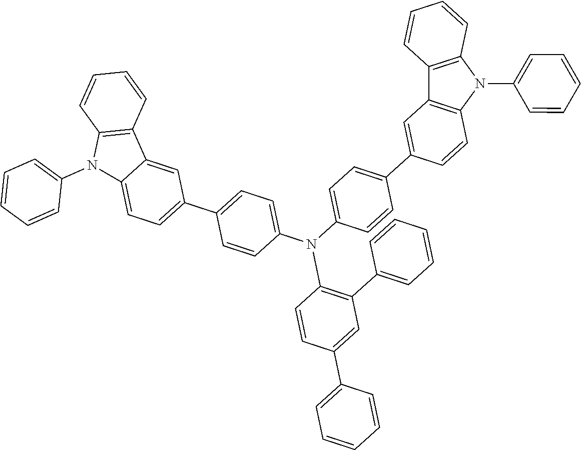 [SMILES: c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)c(-c3ccccc3)c2)cc1]

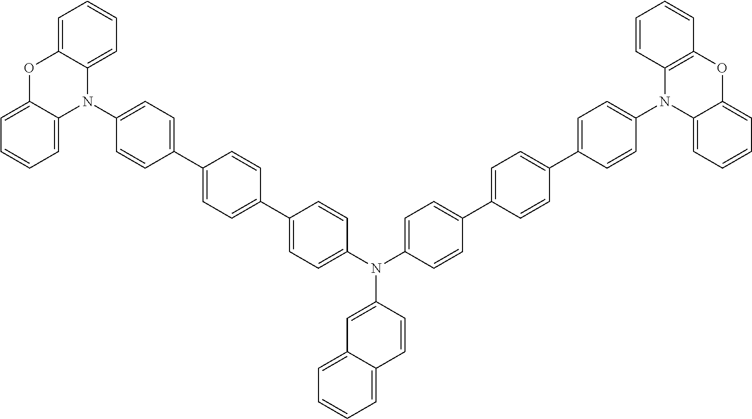 [SMILES: c1ccc2c(c1)Oc1ccccc1N2c1ccc(-c2ccc(-c3ccc(N(c4ccc(-c5ccc(-c6ccc(N7c8ccccc8Oc8ccccc87)cc6)cc5)cc4)c4ccc5ccccc5c4)cc3)cc2)cc1]

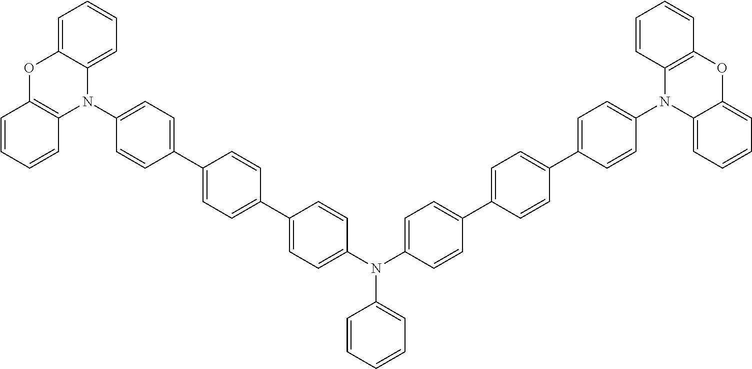 [SMILES: c1ccc(N(c2ccc(-c3ccc(-c4ccc(N5c6ccccc6Oc6ccccc65)cc4)cc3)cc2)c2ccc(-c3ccc(-c4ccc(N5c6ccccc6Oc6ccccc65)cc4)cc3)cc2)cc1]

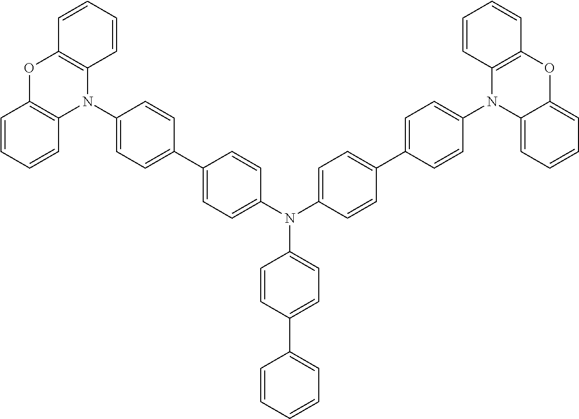 [SMILES: c1ccc(-c2ccc(N(c3ccc(-c4ccc(N5c6ccccc6Oc6ccccc65)cc4)cc3)c3ccc(-c4ccc(N5c6ccccc6Oc6ccccc65)cc4)cc3)cc2)cc1]

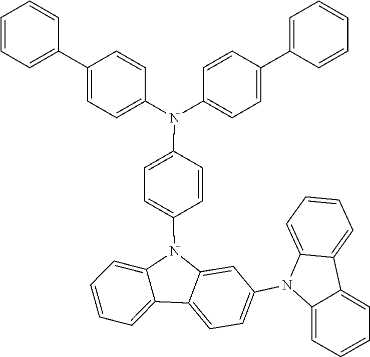 [SMILES: c1ccc(-c2ccc(N(c3ccc(-c4ccccc4)cc3)c3ccc(-n4c5ccccc5c5ccc(-n6c7ccccc7c7ccccc76)cc54)cc3)cc2)cc1]

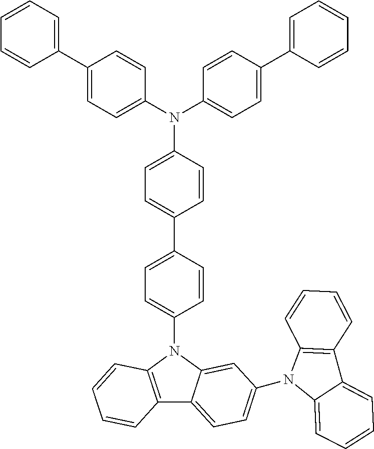 [SMILES: c1ccc(-c2ccc(N(c3ccc(-c4ccccc4)cc3)c3ccc(-c4ccc(-n5c6ccccc6c6ccc(-n7c8ccccc8c8ccccc87)cc65)cc4)cc3)cc2)cc1]

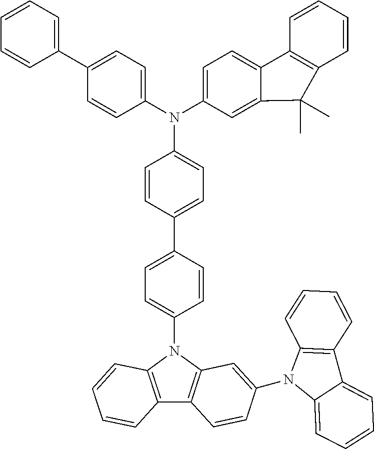 [SMILES: CC1(C)c2ccccc2-c2ccc(N(c3ccc(-c4ccccc4)cc3)c3ccc(-c4ccc(-n5c6ccccc6c6ccc(-n7c8ccccc8c8ccccc87)cc65)cc4)cc3)cc21]

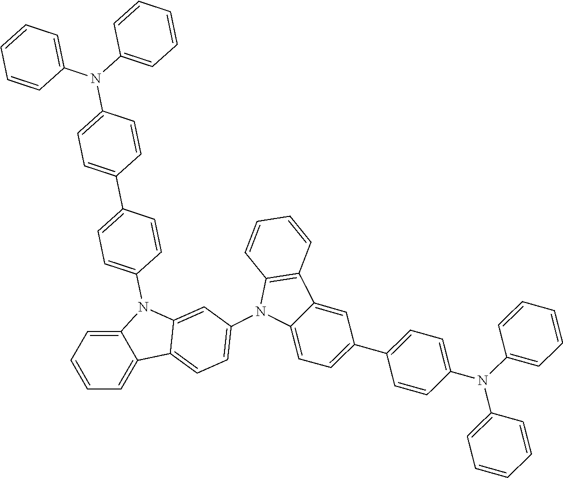 [SMILES: c1ccc(N(c2ccccc2)c2ccc(-c3ccc(-n4c5ccccc5c5ccc(-n6c7ccccc7c7cc(-c8ccc(N(c9ccccc9)c9ccccc9)cc8)ccc76)cc54)cc3)cc2)cc1]

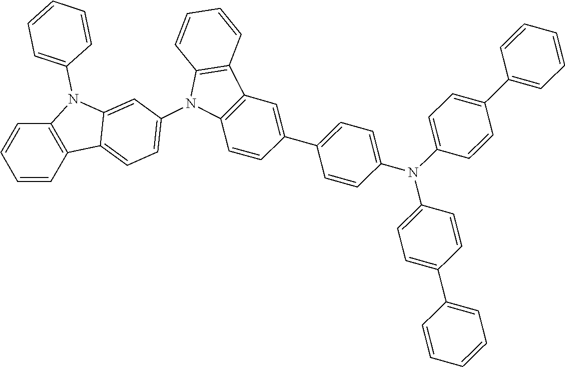 [SMILES: c1ccc(-c2ccc(N(c3ccc(-c4ccccc4)cc3)c3ccc(-c4ccc5c(c4)c4ccccc4n5-c4ccc5c6ccccc6n(-c6ccccc6)c5c4)cc3)cc2)cc1]

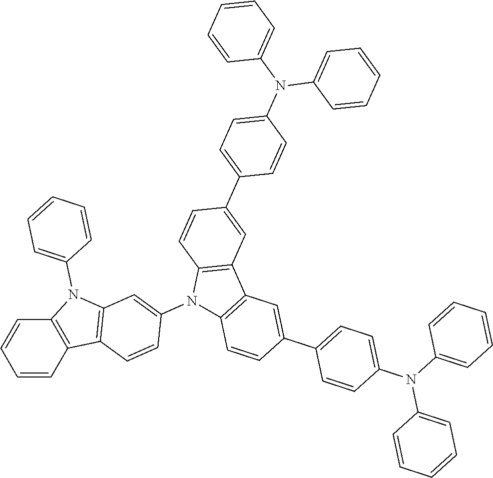 [SMILES: c1ccc(N(c2ccccc2)c2ccc(-c3ccc4c(c3)c3cc(-c5ccc(N(c6ccccc6)c6ccccc6)cc5)ccc3n4-c3ccc4c5ccccc5n(-c5ccccc5)c4c3)cc2)cc1]

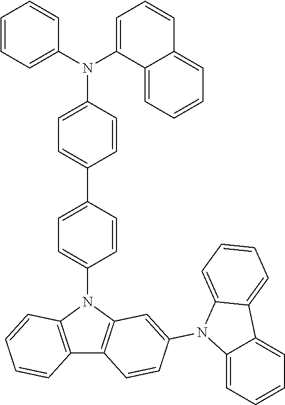 [SMILES: c1ccc(N(c2ccc(-c3ccc(-n4c5ccccc5c5ccc(-n6c7ccccc7c7ccccc76)cc54)cc3)cc2)c2cccc3ccccc23)cc1]

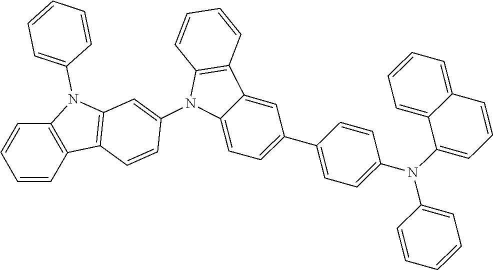 [SMILES: c1ccc(N(c2ccc(-c3ccc4c(c3)c3ccccc3n4-c3ccc4c5ccccc5n(-c5ccccc5)c4c3)cc2)c2cccc3ccccc23)cc1]

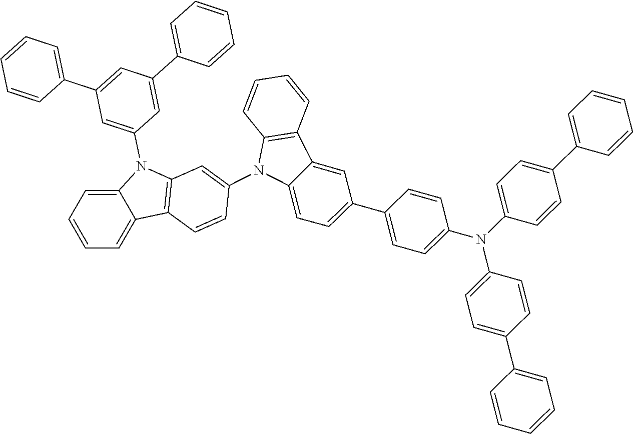 [SMILES: c1ccc(-c2ccc(N(c3ccc(-c4ccccc4)cc3)c3ccc(-c4ccc5c(c4)c4ccccc4n5-c4ccc5c6ccccc6n(-c6cc(-c7ccccc7)cc(-c7ccccc7)c6)c5c4)cc3)cc2)cc1]

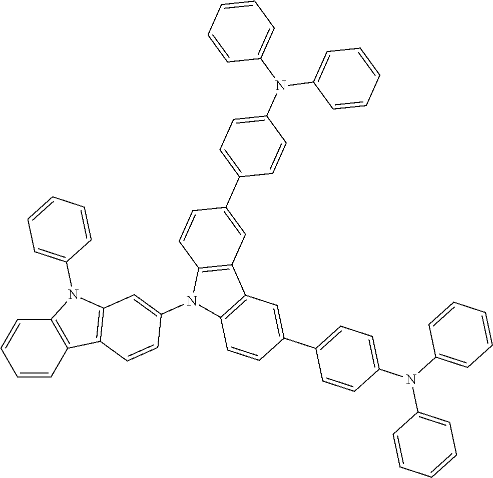 [SMILES: c1ccc(N(c2ccccc2)c2ccc(-c3ccc4c(c3)c3cc(-c5ccc(N(c6ccccc6)c6ccccc6)cc5)ccc3n4-c3ccc4c5ccccc5n(-c5ccccc5)c4c3)cc2)cc1]

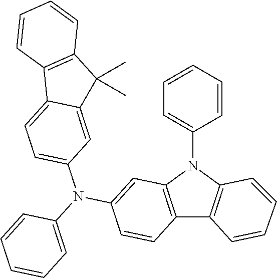 [SMILES: CC1(C)c2ccccc2-c2ccc(N(c3ccccc3)c3ccc4c5ccccc5n(-c5ccccc5)c4c3)cc21]

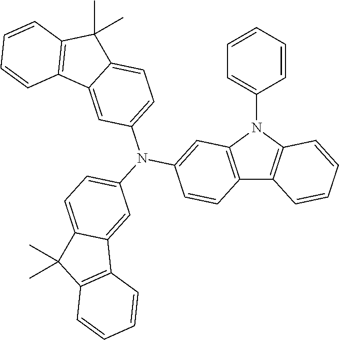 [SMILES: CC1(C)c2ccccc2-c2cc(N(c3ccc4c(c3)-c3ccccc3C4(C)C)c3ccc4c5ccccc5n(-c5ccccc5)c4c3)ccc21]

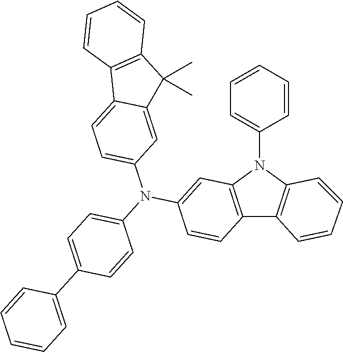 [SMILES: CC1(C)c2ccccc2-c2ccc(N(c3ccc(-c4ccccc4)cc3)c3ccc4c5ccccc5n(-c5ccccc5)c4c3)cc21]

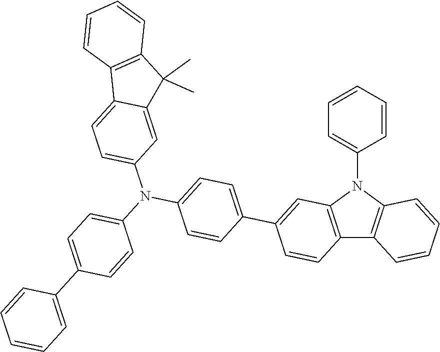 [SMILES: CC1(C)c2ccccc2-c2ccc(N(c3ccc(-c4ccccc4)cc3)c3ccc(-c4ccc5c6ccccc6n(-c6ccccc6)c5c4)cc3)cc21]

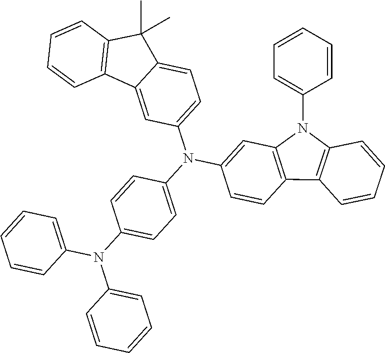 [SMILES: CC1(C)c2ccccc2-c2cc(N(c3ccc(N(c4ccccc4)c4ccccc4)cc3)c3ccc4c5ccccc5n(-c5ccccc5)c4c3)ccc21]

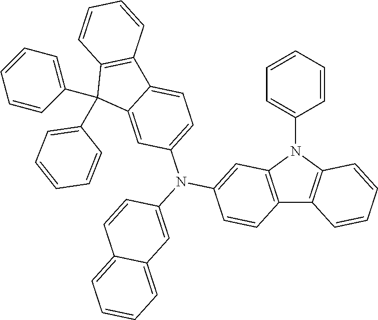 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

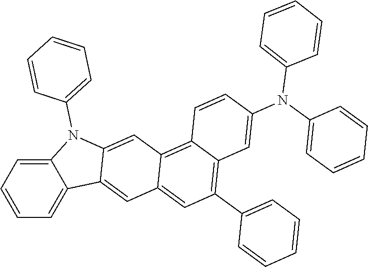 [SMILES: c1ccc(-c2cc3cc4c5ccccc5n(-c5ccccc5)c4cc3c3ccc(N(c4ccccc4)c4ccccc4)cc23)cc1]

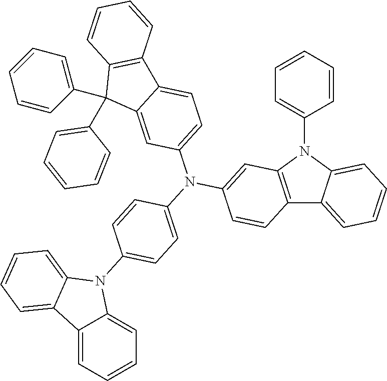 [SMILES: c1ccc(-n2c3ccccc3c3ccc(N(c4ccc(-n5c6ccccc6c6ccccc65)cc4)c4ccc5c(c4)C(c4ccccc4)(c4ccccc4)c4ccccc4-5)cc32)cc1]

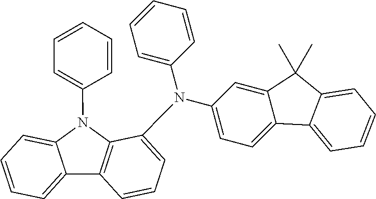 [SMILES: CC1(C)c2ccccc2-c2ccc(N(c3ccccc3)c3cccc4c5ccccc5n(-c5ccccc5)c34)cc21]

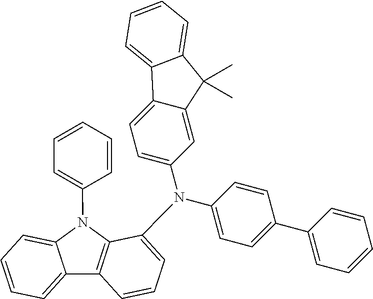 [SMILES: CC1(C)c2ccccc2-c2ccc(N(c3ccc(-c4ccccc4)cc3)c3cccc4c5ccccc5n(-c5ccccc5)c34)cc21]

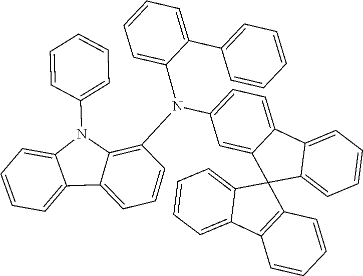 [SMILES: c1ccc(-c2ccccc2N(c2ccc3c(c2)C2(c4ccccc4-c4ccccc42)c2ccccc2-3)c2cccc3c4ccccc4n(-c4ccccc4)c23)cc1]

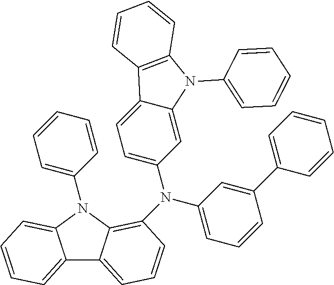 [SMILES: c1ccc(-c2cccc(N(c3ccc4c5ccccc5n(-c5ccccc5)c4c3)c3cccc4c5ccccc5n(-c5ccccc5)c34)c2)cc1]

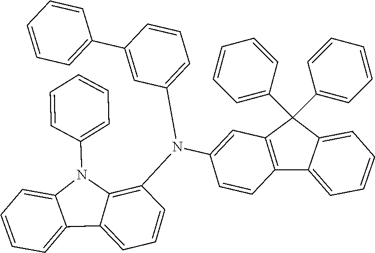 [SMILES: c1ccc(-c2cccc(N(c3ccc4c(c3)C(c3ccccc3)(c3ccccc3)c3ccccc3-4)c3cccc4c5ccccc5n(-c5ccccc5)c34)c2)cc1]

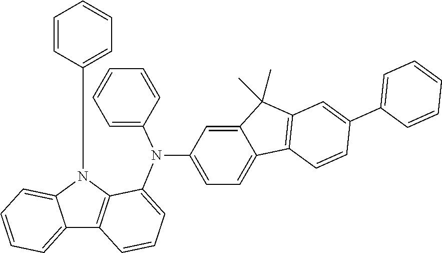 [SMILES: CC1(C)c2cc(-c3ccccc3)ccc2-c2ccc(N(c3ccccc3)c3cccc4c5ccccc5n(-c5ccccc5)c34)cc21]

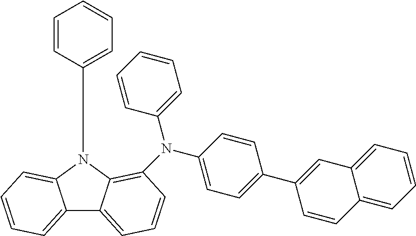 [SMILES: c1ccc(N(c2ccc(-c3ccc4ccccc4c3)cc2)c2cccc3c4ccccc4n(-c4ccccc4)c23)cc1]

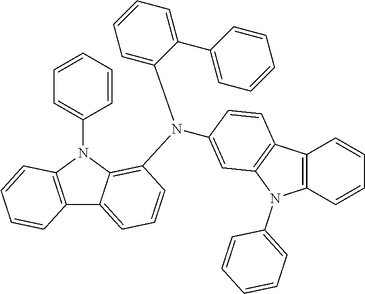 [SMILES: c1ccc(-c2ccccc2N(c2ccc3c4ccccc4n(-c4ccccc4)c3c2)c2cccc3c4ccccc4n(-c4ccccc4)c23)cc1]

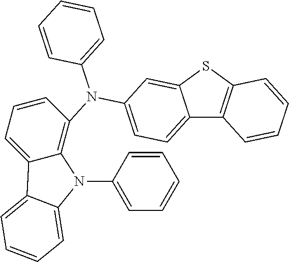 [SMILES: c1ccc(N(c2ccc3c(c2)sc2ccccc23)c2cccc3c4ccccc4n(-c4ccccc4)c23)cc1]

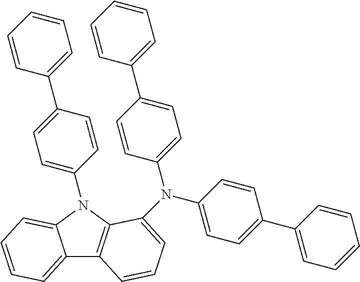 [SMILES: c1ccc(-c2ccc(N(c3ccc(-c4ccccc4)cc3)c3cccc4c5ccccc5n(-c5ccc(-c6ccccc6)cc5)c34)cc2)cc1]

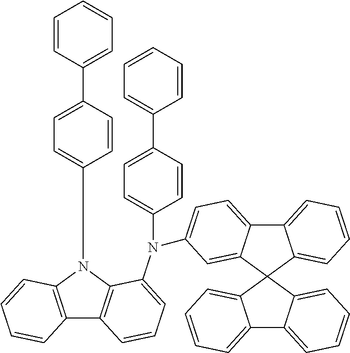 [SMILES: c1ccc(-c2ccc(N(c3ccc4c(c3)C3(c5ccccc5-c5ccccc53)c3ccccc3-4)c3cccc4c5ccccc5n(-c5ccc(-c6ccccc6)cc5)c34)cc2)cc1]

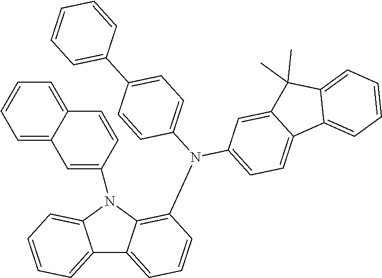 [SMILES: CC1(C)c2ccccc2-c2ccc(N(c3ccc(-c4ccccc4)cc3)c3cccc4c5ccccc5n(-c5ccc6ccccc6c5)c34)cc21]

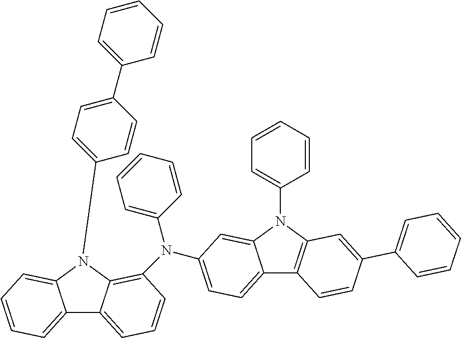 [SMILES: c1ccc(-c2ccc(-n3c4ccccc4c4cccc(N(c5ccccc5)c5ccc6c7ccc(-c8ccccc8)cc7n(-c7ccccc7)c6c5)c43)cc2)cc1]

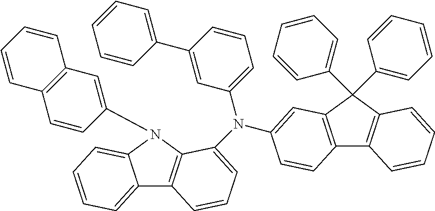 [SMILES: c1ccc(-c2cccc(N(c3ccc4c(c3)C(c3ccccc3)(c3ccccc3)c3ccccc3-4)c3cccc4c5ccccc5n(-c5ccc6ccccc6c5)c34)c2)cc1]

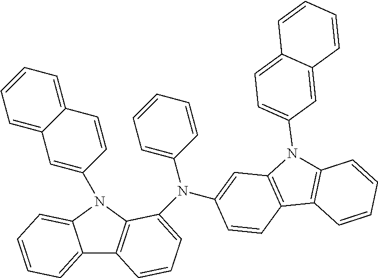 [SMILES: c1ccc(N(c2ccc3c4ccccc4n(-c4ccc5ccccc5c4)c3c2)c2cccc3c4ccccc4n(-c4ccc5ccccc5c4)c23)cc1]

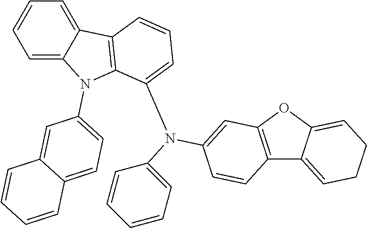 [SMILES: C1=c2oc3cc(N(c4ccccc4)c4cccc5c6ccccc6n(-c6ccc7ccccc7c6)c45)ccc3c2=CCC1]

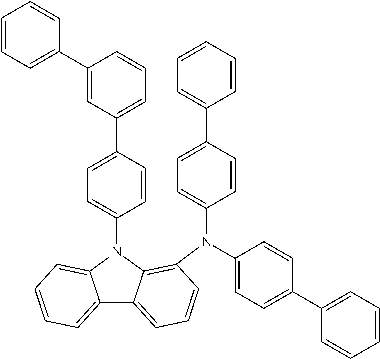 [SMILES: c1ccc(-c2ccc(N(c3ccc(-c4ccccc4)cc3)c3cccc4c5ccccc5n(-c5ccc(-c6cccc(-c7ccccc7)c6)cc5)c34)cc2)cc1]

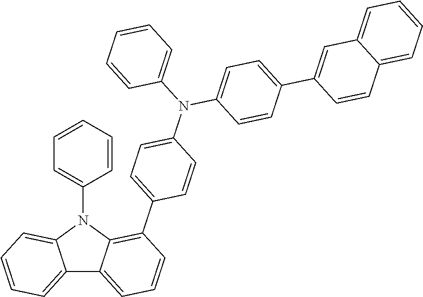 [SMILES: c1ccc(N(c2ccc(-c3ccc4ccccc4c3)cc2)c2ccc(-c3cccc4c5ccccc5n(-c5ccccc5)c34)cc2)cc1]

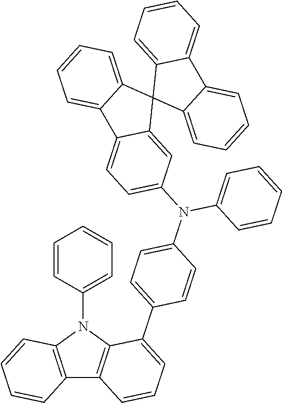 [SMILES: c1ccc(N(c2ccc(-c3cccc4c5ccccc5n(-c5ccccc5)c34)cc2)c2ccc3c(c2)C2(c4ccccc4-c4ccccc42)c2ccccc2-3)cc1]

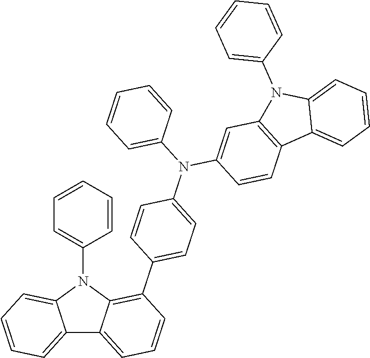 [SMILES: c1ccc(N(c2ccc(-c3cccc4c5ccccc5n(-c5ccccc5)c34)cc2)c2ccc3c4ccccc4n(-c4ccccc4)c3c2)cc1]

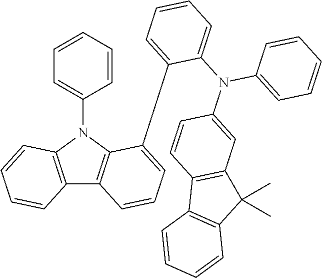 [SMILES: CC1(C)c2ccccc2-c2ccc(N(c3ccccc3)c3ccccc3-c3cccc4c5ccccc5n(-c5ccccc5)c34)cc21]

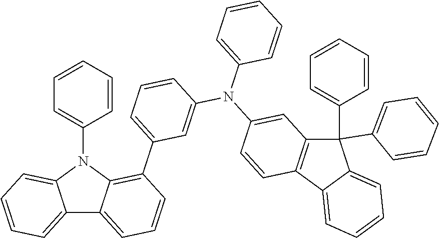 [SMILES: c1ccc(N(c2cccc(-c3cccc4c5ccccc5n(-c5ccccc5)c34)c2)c2ccc3c(c2)C(c2ccccc2)(c2ccccc2)c2ccccc2-3)cc1]

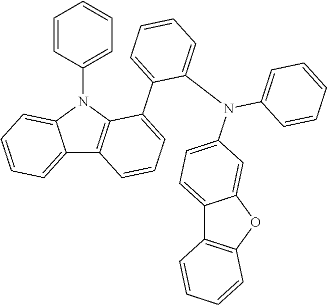 [SMILES: c1ccc(N(c2ccc3c(c2)oc2ccccc23)c2ccccc2-c2cccc3c4ccccc4n(-c4ccccc4)c23)cc1]

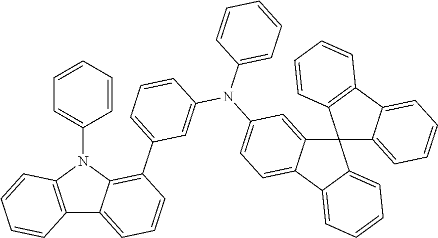 [SMILES: c1ccc(N(c2cccc(-c3cccc4c5ccccc5n(-c5ccccc5)c34)c2)c2ccc3c(c2)C2(c4ccccc4-c4ccccc42)c2ccccc2-3)cc1]

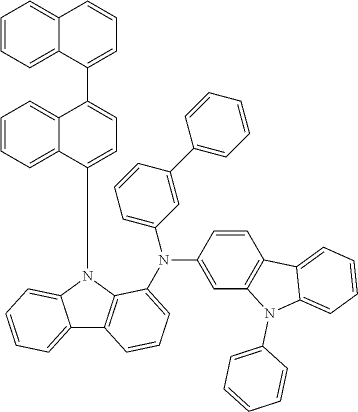 [SMILES: c1ccc(-c2cccc(N(c3ccc4c5ccccc5n(-c5ccccc5)c4c3)c3cccc4c5ccccc5n(-c5ccc(-c6cccc7ccccc67)c6ccccc56)c34)c2)cc1]

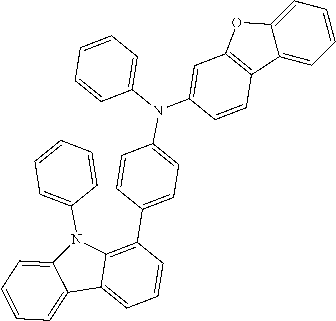 [SMILES: c1ccc(N(c2ccc(-c3cccc4c5ccccc5n(-c5ccccc5)c34)cc2)c2ccc3c(c2)oc2ccccc23)cc1]

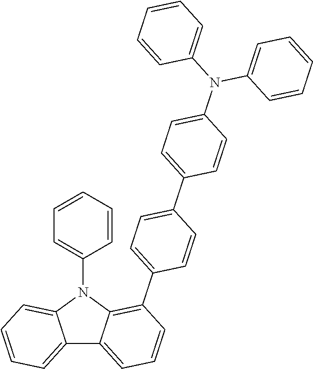 [SMILES: c1ccc(N(c2ccccc2)c2ccc(-c3ccc(-c4cccc5c6ccccc6n(-c6ccccc6)c45)cc3)cc2)cc1]

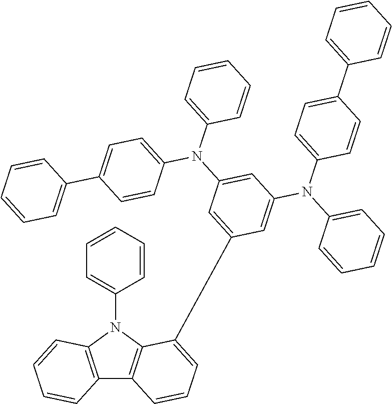 [SMILES: c1ccc(-c2ccc(N(c3ccccc3)c3cc(-c4cccc5c6ccccc6n(-c6ccccc6)c45)cc(N(c4ccccc4)c4ccc(-c5ccccc5)cc4)c3)cc2)cc1]

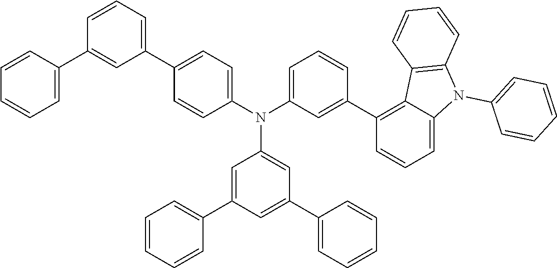 [SMILES: c1ccc(-c2cccc(-c3ccc(N(c4cc(-c5ccccc5)cc(-c5ccccc5)c4)c4cccc(-c5cccc6c5c5ccccc5n6-c5ccccc5)c4)cc3)c2)cc1]

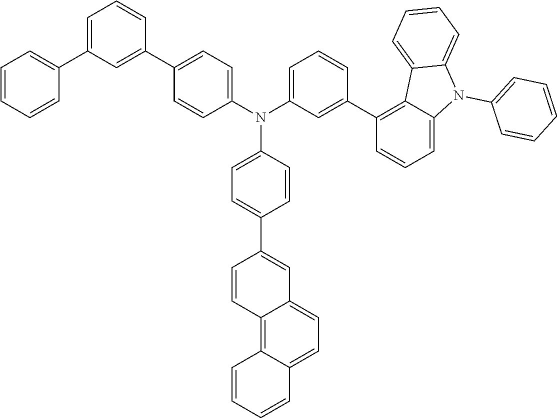 [SMILES: c1ccc(-c2cccc(-c3ccc(N(c4ccc(-c5ccc6c(ccc7ccccc76)c5)cc4)c4cccc(-c5cccc6c5c5ccccc5n6-c5ccccc5)c4)cc3)c2)cc1]

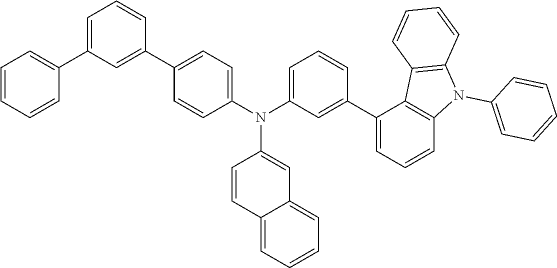 [SMILES: c1ccc(-c2cccc(-c3ccc(N(c4cccc(-c5cccc6c5c5ccccc5n6-c5ccccc5)c4)c4ccc5ccccc5c4)cc3)c2)cc1]

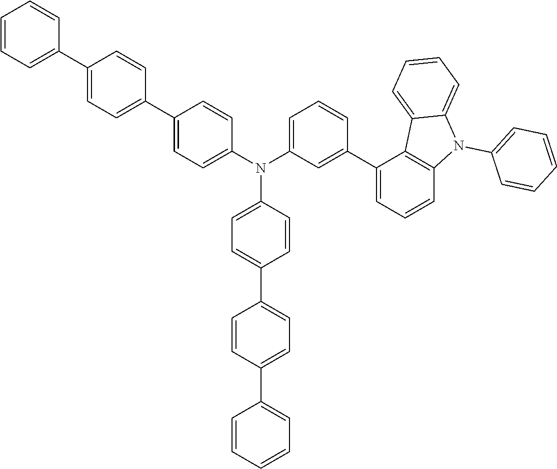 [SMILES: c1ccc(-c2ccc(-c3ccc(N(c4ccc(-c5ccc(-c6ccccc6)cc5)cc4)c4cccc(-c5cccc6c5c5ccccc5n6-c5ccccc5)c4)cc3)cc2)cc1]

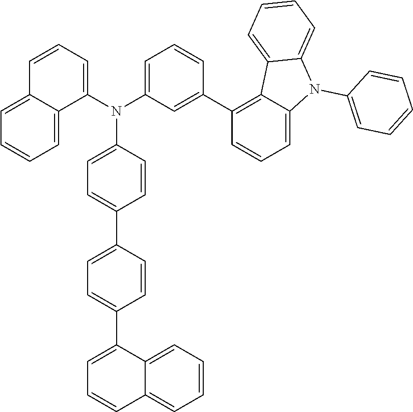 [SMILES: c1ccc(-n2c3ccccc3c3c(-c4cccc(N(c5ccc(-c6ccc(-c7cccc8ccccc78)cc6)cc5)c5cccc6ccccc56)c4)cccc32)cc1]

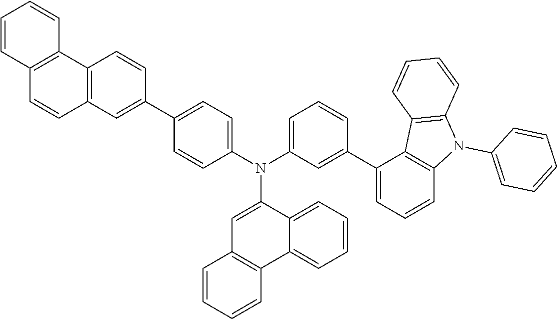 [SMILES: c1ccc(-n2c3ccccc3c3c(-c4cccc(N(c5ccc(-c6ccc7c(ccc8ccccc87)c6)cc5)c5cc6ccccc6c6ccccc56)c4)cccc32)cc1]

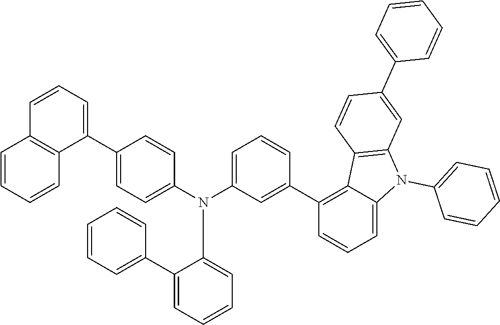 [SMILES: c1ccc(-c2ccc3c4c(-c5cccc(N(c6ccc(-c7cccc8ccccc78)cc6)c6ccccc6-c6ccccc6)c5)cccc4n(-c4ccccc4)c3c2)cc1]

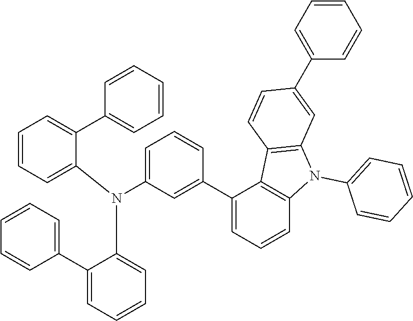 [SMILES: c1ccc(-c2ccc3c4c(-c5cccc(N(c6ccccc6-c6ccccc6)c6ccccc6-c6ccccc6)c5)cccc4n(-c4ccccc4)c3c2)cc1]

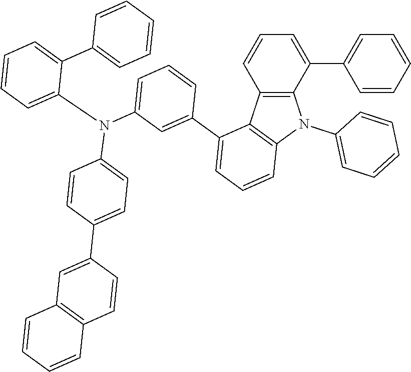 [SMILES: c1ccc(-c2ccccc2N(c2ccc(-c3ccc4ccccc4c3)cc2)c2cccc(-c3cccc4c3c3cccc(-c5ccccc5)c3n4-c3ccccc3)c2)cc1]

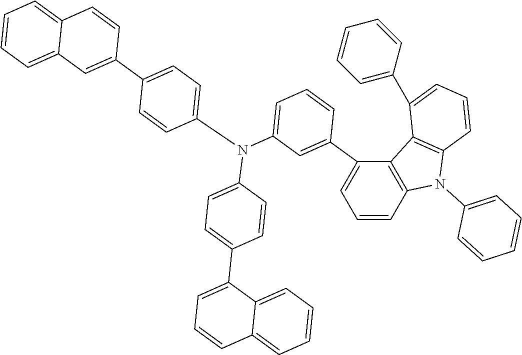 [SMILES: c1ccc(-c2cccc3c2c2c(-c4cccc(N(c5ccc(-c6ccc7ccccc7c6)cc5)c5ccc(-c6cccc7ccccc67)cc5)c4)cccc2n3-c2ccccc2)cc1]

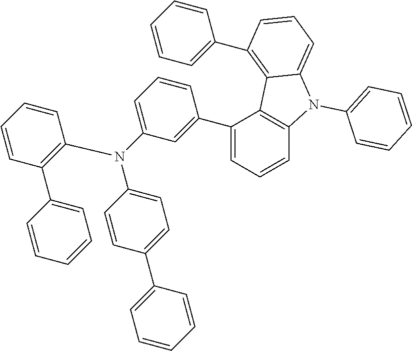 [SMILES: c1ccc(-c2ccc(N(c3cccc(-c4cccc5c4c4c(-c6ccccc6)cccc4n5-c4ccccc4)c3)c3ccccc3-c3ccccc3)cc2)cc1]

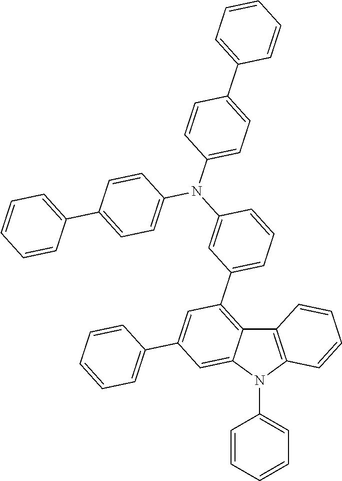 [SMILES: c1ccc(-c2ccc(N(c3ccc(-c4ccccc4)cc3)c3cccc(-c4cc(-c5ccccc5)cc5c4c4ccccc4n5-c4ccccc4)c3)cc2)cc1]

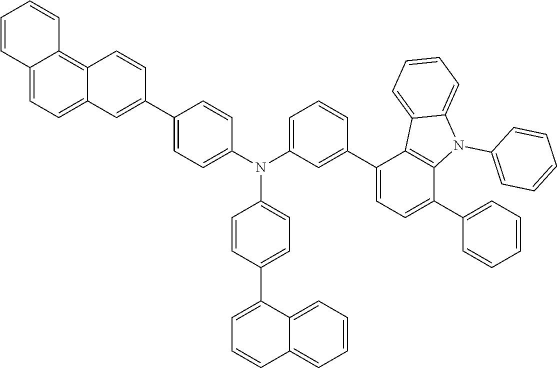 [SMILES: c1ccc(-c2ccc(-c3cccc(N(c4ccc(-c5ccc6c(ccc7ccccc76)c5)cc4)c4ccc(-c5cccc6ccccc56)cc4)c3)c3c4ccccc4n(-c4ccccc4)c23)cc1]

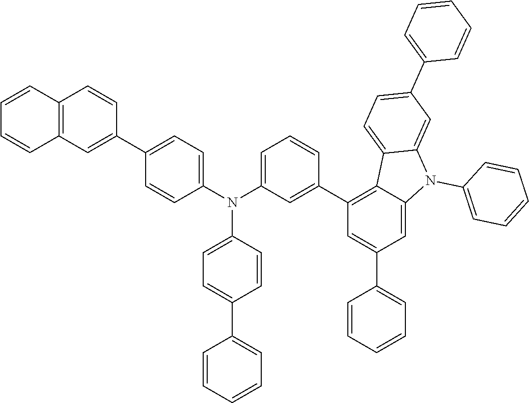 [SMILES: c1ccc(-c2ccc(N(c3ccc(-c4ccc5ccccc5c4)cc3)c3cccc(-c4cc(-c5ccccc5)cc5c4c4ccc(-c6ccccc6)cc4n5-c4ccccc4)c3)cc2)cc1]

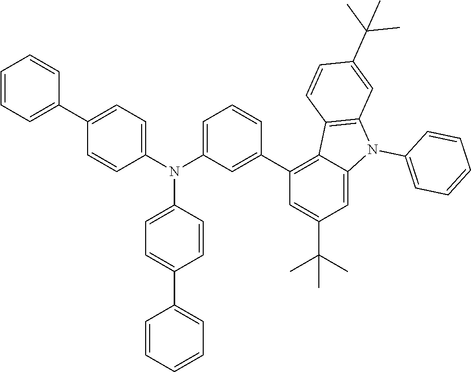 [SMILES: CC(C)(C)c1ccc2c3c(-c4cccc(N(c5ccc(-c6ccccc6)cc5)c5ccc(-c6ccccc6)cc5)c4)cc(C(C)(C)C)cc3n(-c3ccccc3)c2c1]

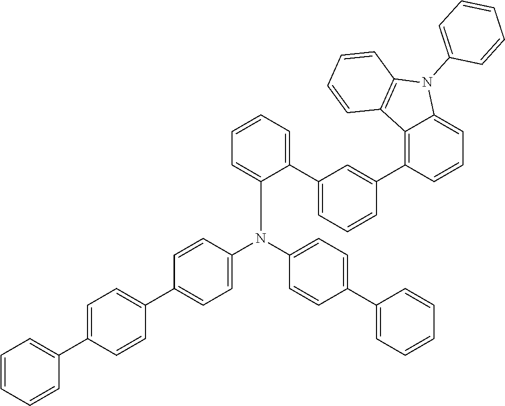 [SMILES: c1ccc(-c2ccc(-c3ccc(N(c4ccc(-c5ccccc5)cc4)c4ccccc4-c4cccc(-c5cccc6c5c5ccccc5n6-c5ccccc5)c4)cc3)cc2)cc1]

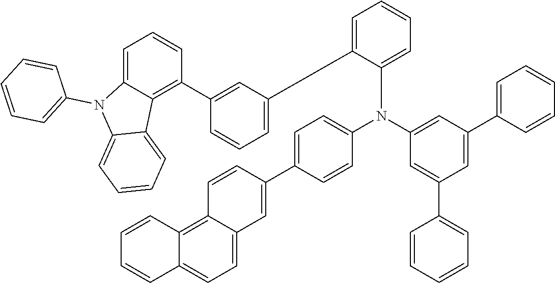 [SMILES: c1ccc(-c2cc(-c3ccccc3)cc(N(c3ccc(-c4ccc5c(ccc6ccccc65)c4)cc3)c3ccccc3-c3cccc(-c4cccc5c4c4ccccc4n5-c4ccccc4)c3)c2)cc1]

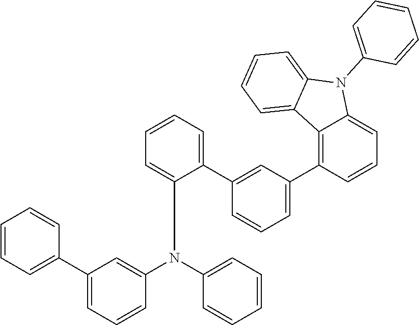 [SMILES: c1ccc(-c2cccc(N(c3ccccc3)c3ccccc3-c3cccc(-c4cccc5c4c4ccccc4n5-c4ccccc4)c3)c2)cc1]

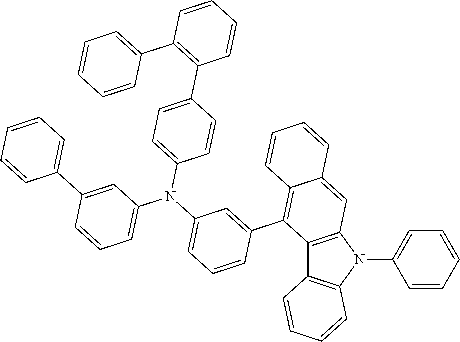 [SMILES: c1ccc(-c2cccc(N(c3ccc(-c4ccccc4-c4ccccc4)cc3)c3cccc(-c4c5ccccc5cc5c4c4ccccc4n5-c4ccccc4)c3)c2)cc1]

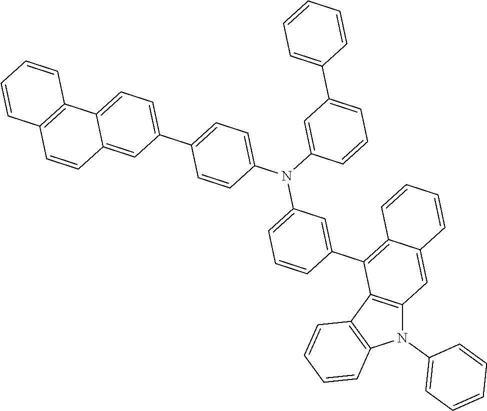 [SMILES: c1ccc(-c2cccc(N(c3ccc(-c4ccc5c(ccc6ccccc65)c4)cc3)c3cccc(-c4c5ccccc5cc5c4c4ccccc4n5-c4ccccc4)c3)c2)cc1]

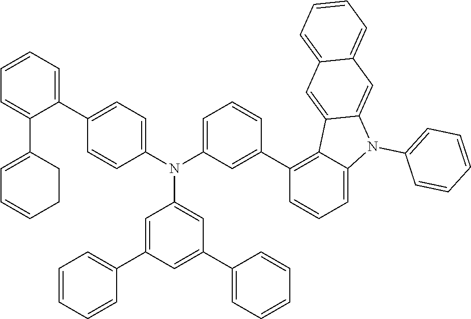 [SMILES: C1=CCCC(c2ccccc2-c2ccc(N(c3cc(-c4ccccc4)cc(-c4ccccc4)c3)c3cccc(-c4cccc5c4c4cc6ccccc6cc4n5-c4ccccc4)c3)cc2)=C1]

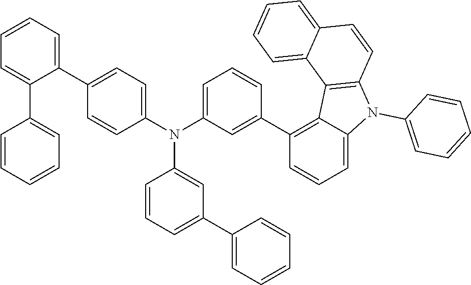 [SMILES: c1ccc(-c2cccc(N(c3ccc(-c4ccccc4-c4ccccc4)cc3)c3cccc(-c4cccc5c4c4c6ccccc6ccc4n5-c4ccccc4)c3)c2)cc1]

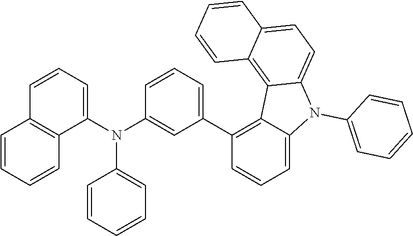 [SMILES: c1ccc(N(c2cccc(-c3cccc4c3c3c5ccccc5ccc3n4-c3ccccc3)c2)c2cccc3ccccc23)cc1]

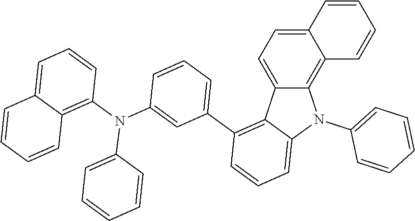 [SMILES: c1ccc(N(c2cccc(-c3cccc4c3c3ccc5ccccc5c3n4-c3ccccc3)c2)c2cccc3ccccc23)cc1]

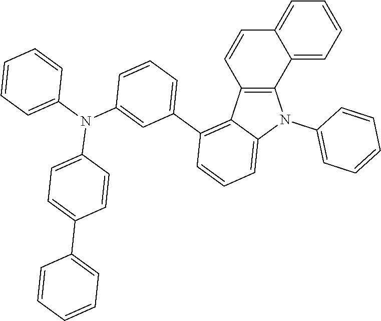 [SMILES: c1ccc(-c2ccc(N(c3ccccc3)c3cccc(-c4cccc5c4c4ccc6ccccc6c4n5-c4ccccc4)c3)cc2)cc1]

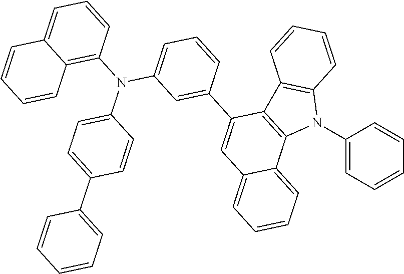 [SMILES: c1ccc(-c2ccc(N(c3cccc(-c4cc5ccccc5c5c4c4ccccc4n5-c4ccccc4)c3)c3cccc4ccccc34)cc2)cc1]

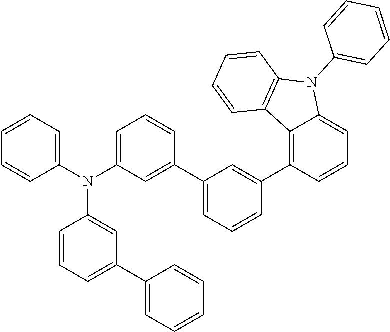 [SMILES: c1ccc(-c2cccc(N(c3ccccc3)c3cccc(-c4cccc(-c5cccc6c5c5ccccc5n6-c5ccccc5)c4)c3)c2)cc1]

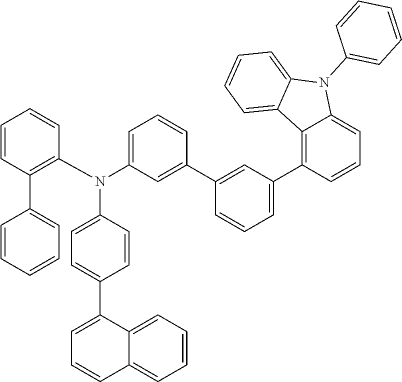 [SMILES: c1ccc(-c2ccccc2N(c2ccc(-c3cccc4ccccc34)cc2)c2cccc(-c3cccc(-c4cccc5c4c4ccccc4n5-c4ccccc4)c3)c2)cc1]

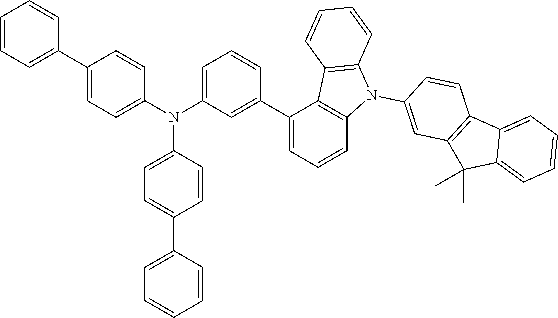 [SMILES: CC1(C)c2ccccc2-c2ccc(-n3c4ccccc4c4c(-c5cccc(N(c6ccc(-c7ccccc7)cc6)c6ccc(-c7ccccc7)cc6)c5)cccc43)cc21]

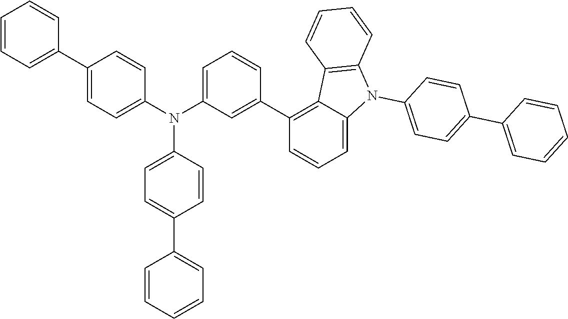 [SMILES: c1ccc(-c2ccc(N(c3ccc(-c4ccccc4)cc3)c3cccc(-c4cccc5c4c4ccccc4n5-c4ccc(-c5ccccc5)cc4)c3)cc2)cc1]

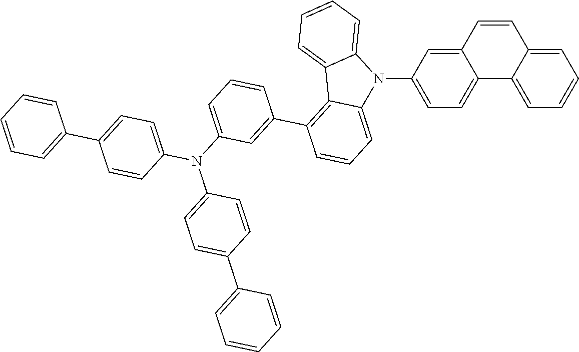 [SMILES: c1ccc(-c2ccc(N(c3ccc(-c4ccccc4)cc3)c3cccc(-c4cccc5c4c4ccccc4n5-c4ccc5c(ccc6ccccc65)c4)c3)cc2)cc1]

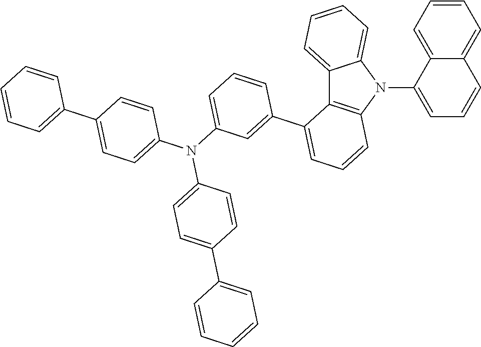 [SMILES: c1ccc(-c2ccc(N(c3ccc(-c4ccccc4)cc3)c3cccc(-c4cccc5c4c4ccccc4n5-c4cccc5ccccc45)c3)cc2)cc1]

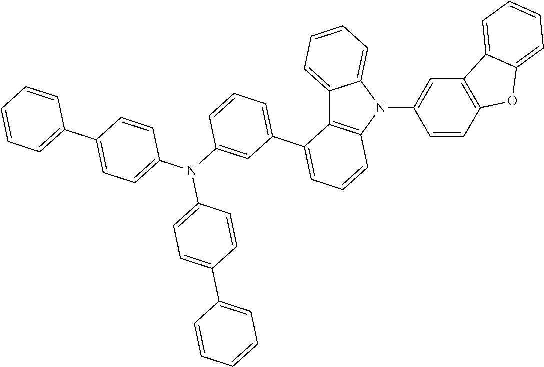 [SMILES: c1ccc(-c2ccc(N(c3ccc(-c4ccccc4)cc3)c3cccc(-c4cccc5c4c4ccccc4n5-c4ccc5oc6ccccc6c5c4)c3)cc2)cc1]

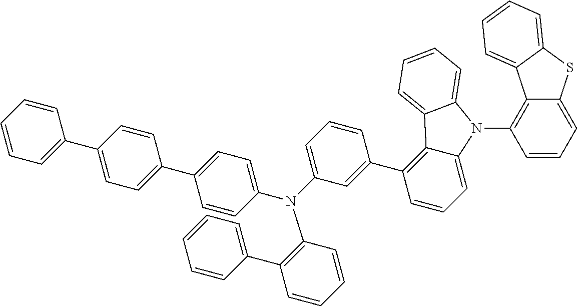 [SMILES: c1ccc(-c2ccc(-c3ccc(N(c4cccc(-c5cccc6c5c5ccccc5n6-c5cccc6sc7ccccc7c56)c4)c4ccccc4-c4ccccc4)cc3)cc2)cc1]

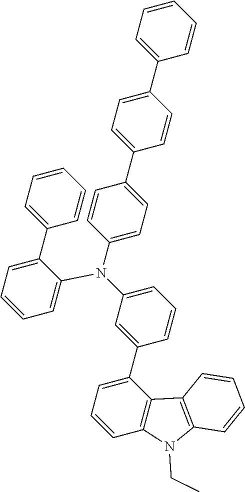 [SMILES: CCn1c2ccccc2c2c(-c3cccc(N(c4ccc(-c5ccc(-c6ccccc6)cc5)cc4)c4ccccc4-c4ccccc4)c3)cccc21]

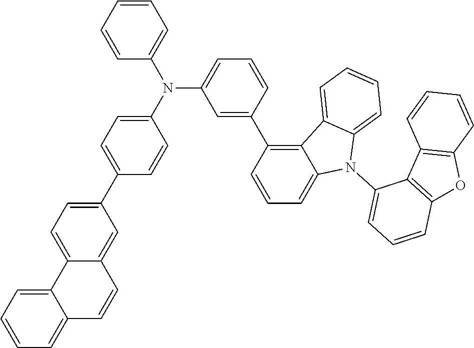 [SMILES: c1ccc(N(c2ccc(-c3ccc4c(ccc5ccccc54)c3)cc2)c2cccc(-c3cccc4c3c3ccccc3n4-c3cccc4oc5ccccc5c34)c2)cc1]

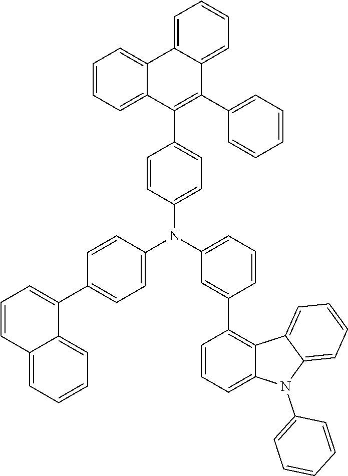 [SMILES: c1ccc(-c2c(-c3ccc(N(c4ccc(-c5cccc6ccccc56)cc4)c4cccc(-c5cccc6c5c5ccccc5n6-c5ccccc5)c4)cc3)c3ccccc3c3ccccc23)cc1]

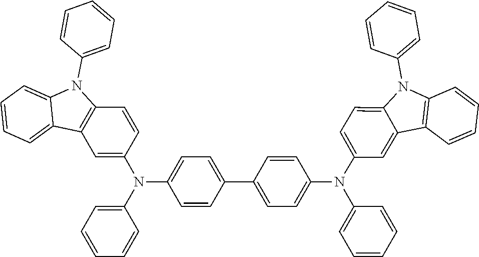 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

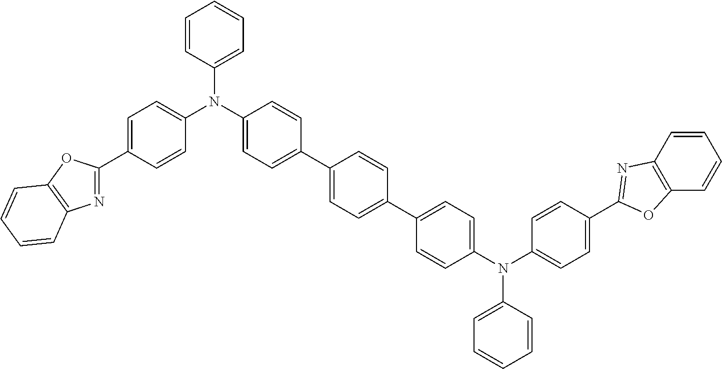 [SMILES: c1ccc(N(c2ccc(-c3ccc(-c4ccc(N(c5ccccc5)c5ccc(-c6nc7ccccc7o6)cc5)cc4)cc3)cc2)c2ccc(-c3nc4ccccc4o3)cc2)cc1]

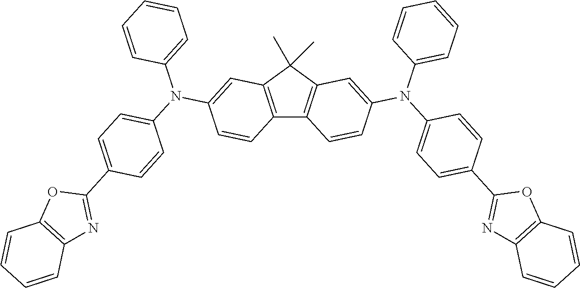 [SMILES: CC1(C)c2cc(N(c3ccccc3)c3ccc(-c4nc5ccccc5o4)cc3)ccc2-c2ccc(N(c3ccccc3)c3ccc(-c4nc5ccccc5o4)cc3)cc21]

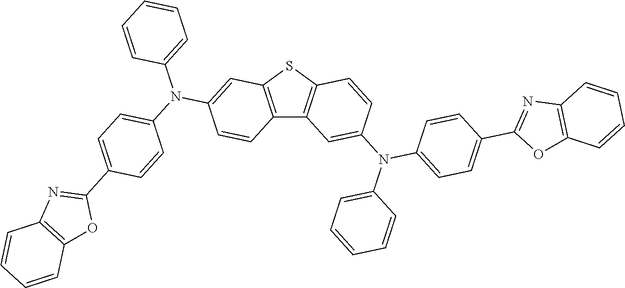 [SMILES: c1ccc(N(c2ccc(-c3nc4ccccc4o3)cc2)c2ccc3c(c2)sc2ccc(N(c4ccccc4)c4ccc(-c5nc6ccccc6o5)cc4)cc23)cc1]

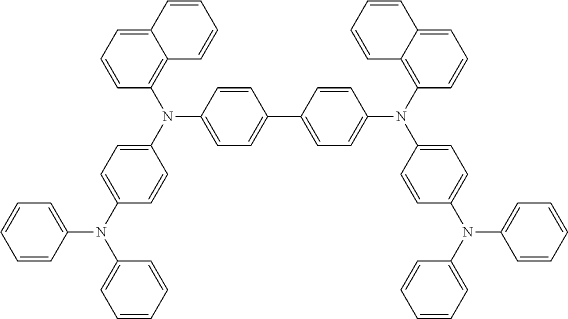 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1]

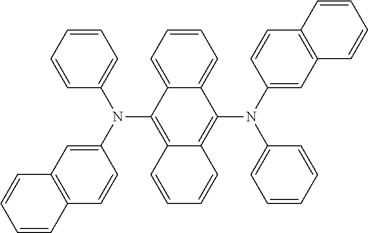 [SMILES: c1ccc(N(c2ccc3ccccc3c2)c2c3ccccc3c(N(c3ccccc3)c3ccc4ccccc4c3)c3ccccc23)cc1]

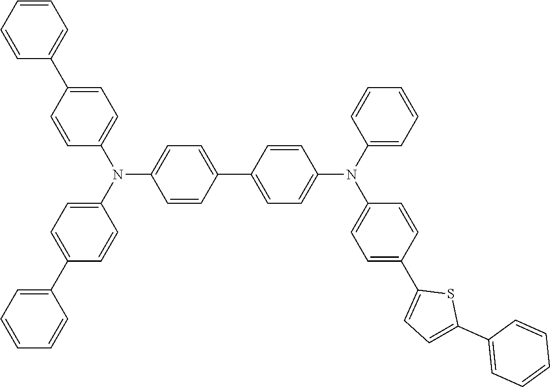 [SMILES: c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1]

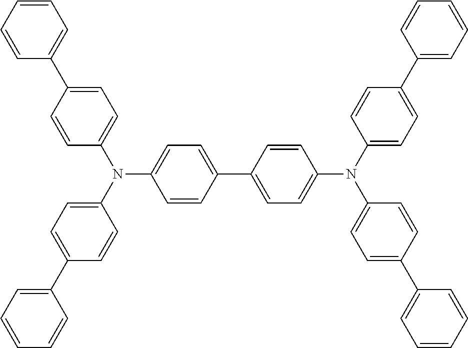 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

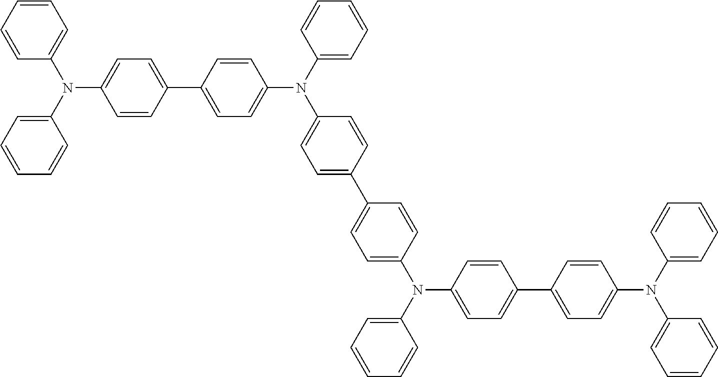 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

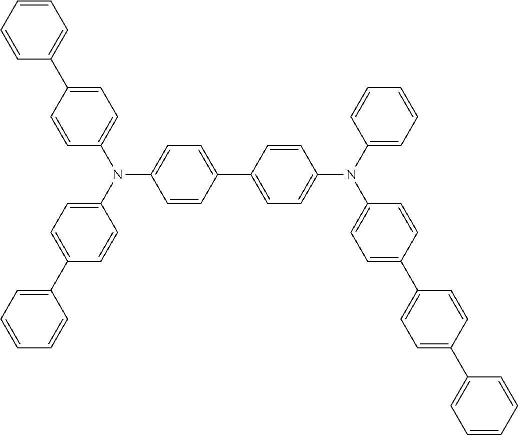 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

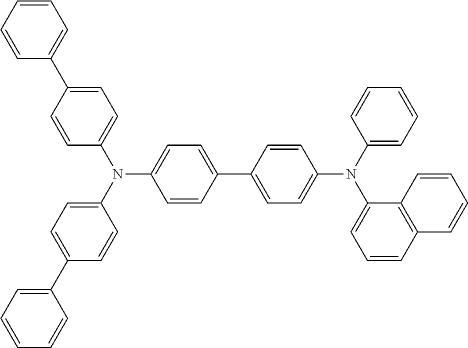 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1]

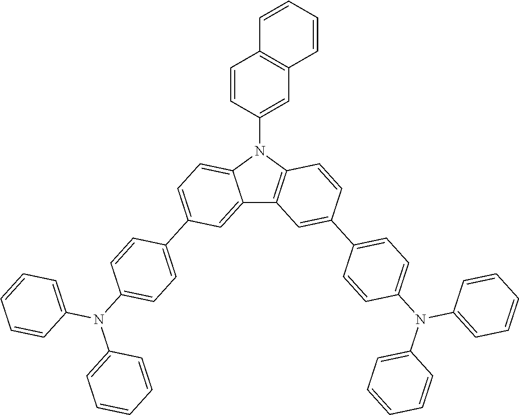 [SMILES: c1ccc(N(c2ccccc2)c2ccc(-c3ccc4c(c3)c3cc(-c5ccc(N(c6ccccc6)c6ccccc6)cc5)ccc3n4-c3ccc4ccccc4c3)cc2)cc1]

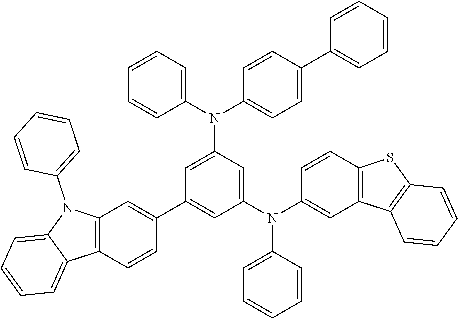 [SMILES: c1ccc(-c2ccc(N(c3ccccc3)c3cc(-c4ccc5c6ccccc6n(-c6ccccc6)c5c4)cc(N(c4ccccc4)c4ccc5sc6ccccc6c5c4)c3)cc2)cc1]

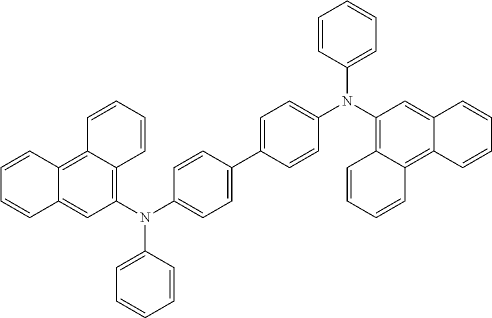 [SMILES: c1ccc(N(c2ccc(-c3ccc(N(c4ccccc4)c4cc5ccccc5c5ccccc45)cc3)cc2)c2cc3ccccc3c3ccccc23)cc1]

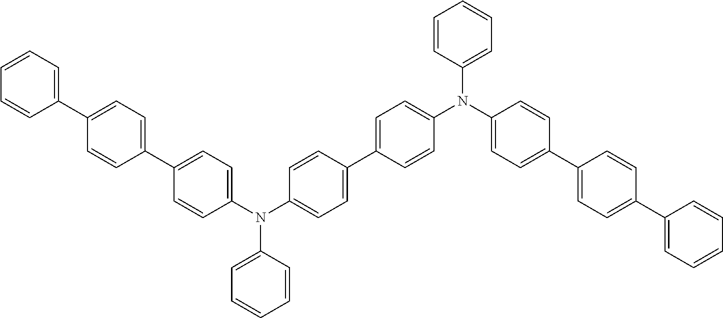 [SMILES: c1ccc(-c2ccc(-c3ccc(N(c4ccccc4)c4ccc(-c5ccc(N(c6ccccc6)c6ccc(-c7ccc(-c8ccccc8)cc7)cc6)cc5)cc4)cc3)cc2)cc1]

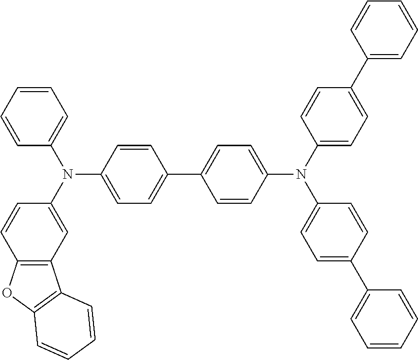 [SMILES: c1ccc(-c2ccc(N(c3ccc(-c4ccccc4)cc3)c3ccc(-c4ccc(N(c5ccccc5)c5ccc6oc7ccccc7c6c5)cc4)cc3)cc2)cc1]

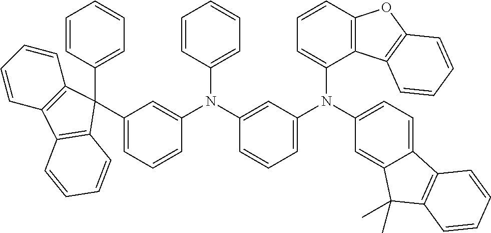 [SMILES: CC1(C)c2ccccc2-c2ccc(N(c3cccc(N(c4ccccc4)c4cccc(C5(c6ccccc6)c6ccccc6-c6ccccc65)c4)c3)c3cccc4oc5ccccc5c34)cc21]

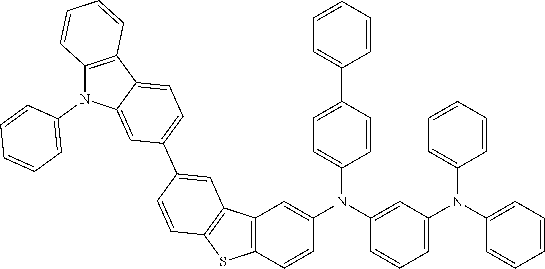 [SMILES: c1ccc(-c2ccc(N(c3cccc(N(c4ccccc4)c4ccccc4)c3)c3ccc4sc5ccc(-c6ccc7c8ccccc8n(-c8ccccc8)c7c6)cc5c4c3)cc2)cc1]

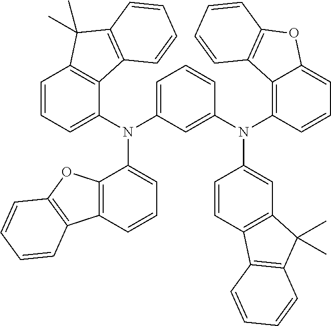 [SMILES: CC1(C)c2ccccc2-c2ccc(N(c3cccc(N(c4cccc5c4-c4ccccc4C5(C)C)c4cccc5c4oc4ccccc45)c3)c3cccc4oc5ccccc5c34)cc21]

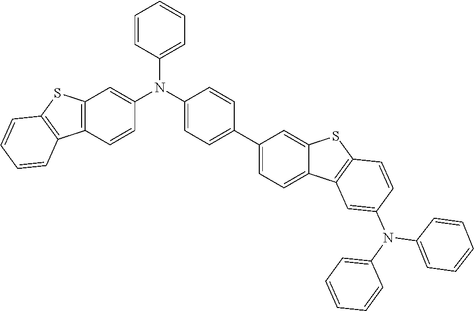 [SMILES: c1ccc(N(c2ccc(-c3ccc4c(c3)sc3ccc(N(c5ccccc5)c5ccccc5)cc34)cc2)c2ccc3c(c2)sc2ccccc23)cc1]

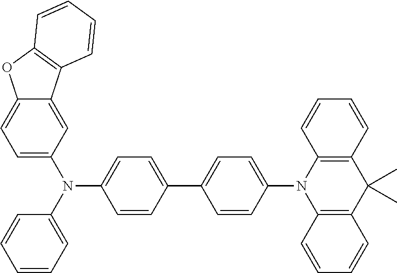 [SMILES: CC1(C)c2ccccc2N(c2ccc(-c3ccc(N(c4ccccc4)c4ccc5oc6ccccc6c5c4)cc3)cc2)c2ccccc21]

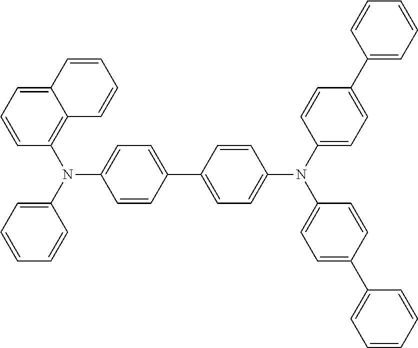 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1]

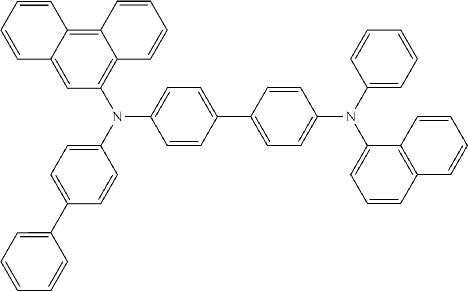 [SMILES: c1ccc(-c2ccc(N(c3ccc(-c4ccc(N(c5ccccc5)c5cccc6ccccc56)cc4)cc3)c3cc4ccccc4c4ccccc34)cc2)cc1]

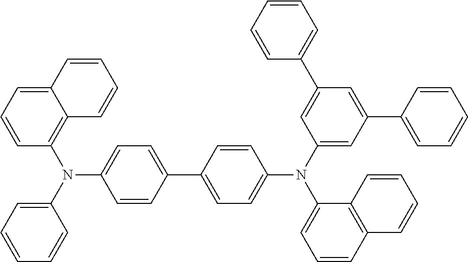 [SMILES: c1ccc(-c2cc(-c3ccccc3)cc(N(c3ccc(-c4ccc(N(c5ccccc5)c5cccc6ccccc56)cc4)cc3)c3cccc4ccccc34)c2)cc1]

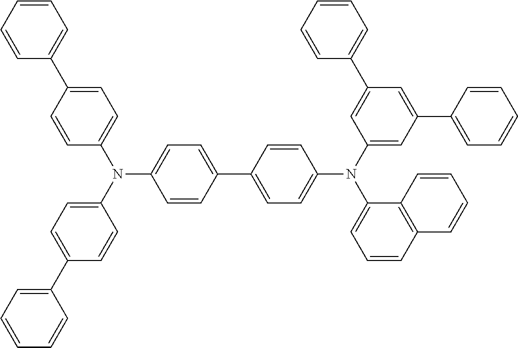 [SMILES: c1ccc(-c2ccc(N(c3ccc(-c4ccccc4)cc3)c3ccc(-c4ccc(N(c5cc(-c6ccccc6)cc(-c6ccccc6)c5)c5cccc6ccccc56)cc4)cc3)cc2)cc1]

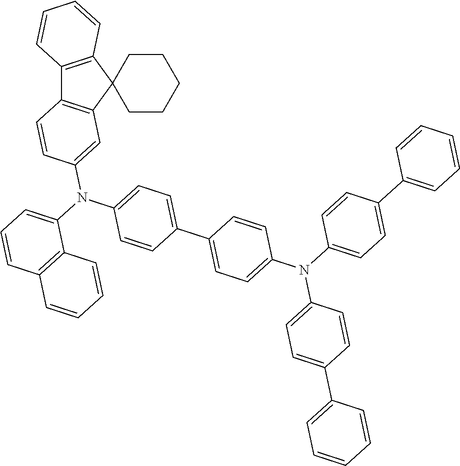 [SMILES: c1ccc(-c2ccc(N(c3ccc(-c4ccccc4)cc3)c3ccc(-c4ccc(N(c5ccc6c(c5)C5(CCCCC5)c5ccccc5-6)c5cccc6ccccc56)cc4)cc3)cc2)cc1]

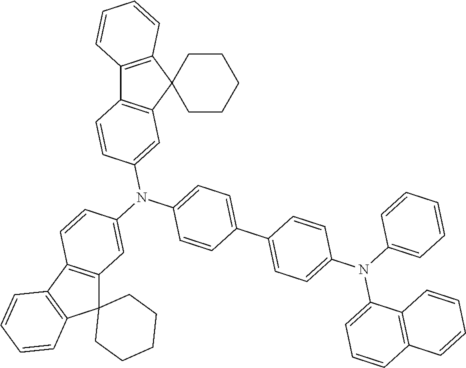 [SMILES: c1ccc(N(c2ccc(-c3ccc(N(c4ccc5c(c4)C4(CCCCC4)c4ccccc4-5)c4ccc5c(c4)C4(CCCCC4)c4ccccc4-5)cc3)cc2)c2cccc3ccccc23)cc1]

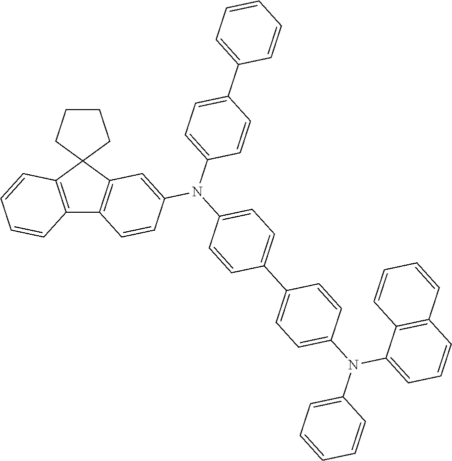 [SMILES: c1ccc(-c2ccc(N(c3ccc(-c4ccc(N(c5ccccc5)c5cccc6ccccc56)cc4)cc3)c3ccc4c(c3)C3(CCCC3)c3ccccc3-4)cc2)cc1]

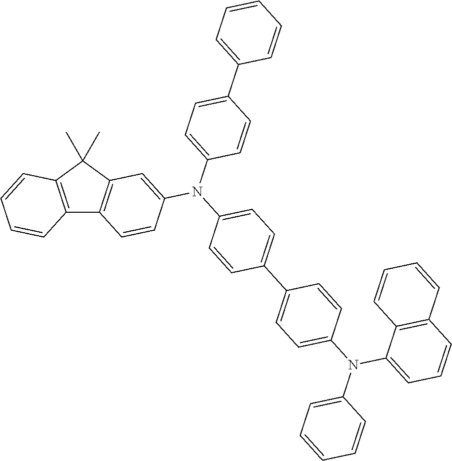 [SMILES: CC1(C)c2ccccc2-c2ccc(N(c3ccc(-c4ccccc4)cc3)c3ccc(-c4ccc(N(c5ccccc5)c5cccc6ccccc56)cc4)cc3)cc21]

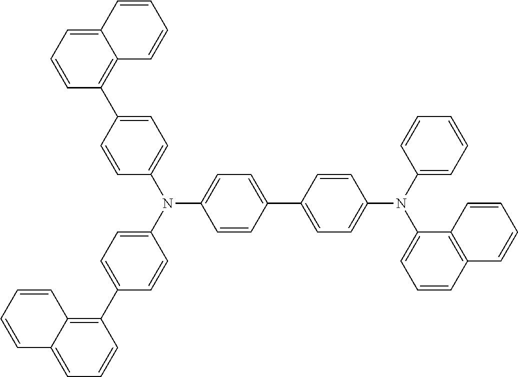 [SMILES: c1ccc(N(c2ccc(-c3ccc(N(c4ccc(-c5cccc6ccccc56)cc4)c4ccc(-c5cccc6ccccc56)cc4)cc3)cc2)c2cccc3ccccc23)cc1]

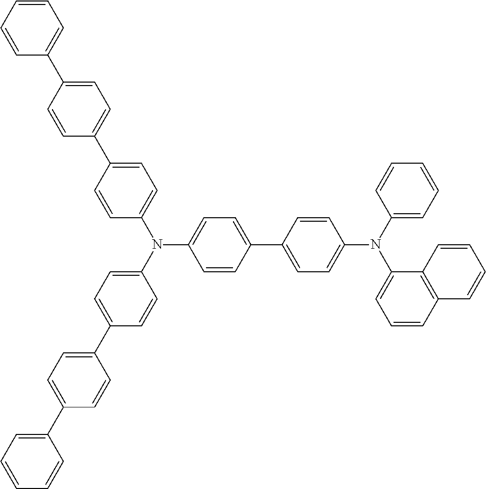 [SMILES: c1ccc(-c2ccc(-c3ccc(N(c4ccc(-c5ccc(-c6ccccc6)cc5)cc4)c4ccc(-c5ccc(N(c6ccccc6)c6cccc7ccccc67)cc5)cc4)cc3)cc2)cc1]

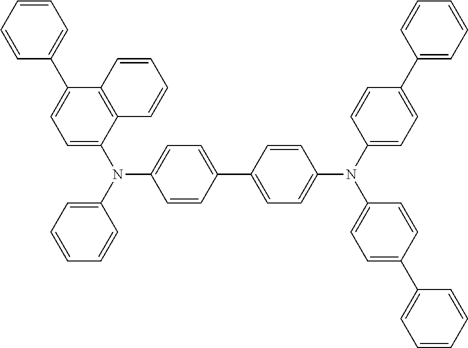 [SMILES: c1ccc(-c2ccc(N(c3ccc(-c4ccccc4)cc3)c3ccc(-c4ccc(N(c5ccccc5)c5ccc(-c6ccccc6)c6ccccc56)cc4)cc3)cc2)cc1]

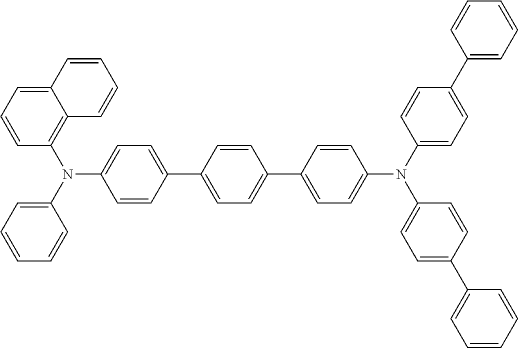 [SMILES: c1ccc(-c2ccc(N(c3ccc(-c4ccccc4)cc3)c3ccc(-c4ccc(-c5ccc(N(c6ccccc6)c6cccc7ccccc67)cc5)cc4)cc3)cc2)cc1]

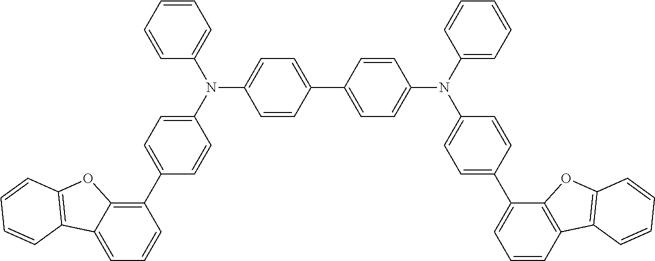 [SMILES: c1ccc(N(c2ccc(-c3ccc(N(c4ccccc4)c4ccc(-c5cccc6c5oc5ccccc56)cc4)cc3)cc2)c2ccc(-c3cccc4c3oc3ccccc34)cc2)cc1]

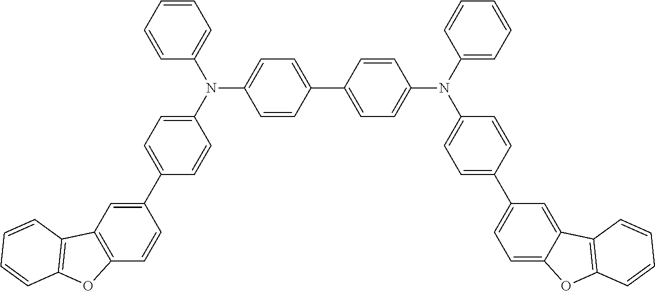 [SMILES: c1ccc(N(c2ccc(-c3ccc(N(c4ccccc4)c4ccc(-c5ccc6oc7ccccc7c6c5)cc4)cc3)cc2)c2ccc(-c3ccc4oc5ccccc5c4c3)cc2)cc1]

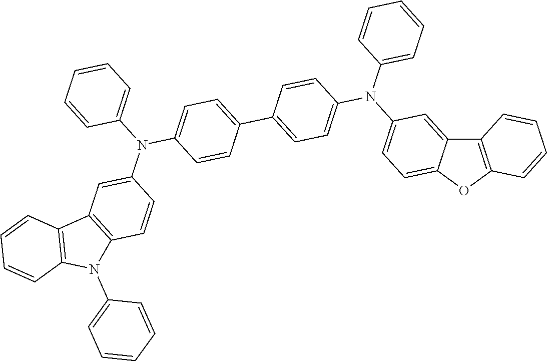 [SMILES: c1ccc(N(c2ccc(-c3ccc(N(c4ccccc4)c4ccc5c(c4)c4ccccc4n5-c4ccccc4)cc3)cc2)c2ccc3oc4ccccc4c3c2)cc1]

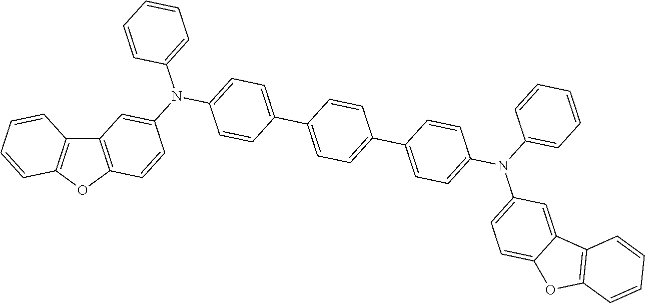 [SMILES: c1ccc(N(c2ccc(-c3ccc(-c4ccc(N(c5ccccc5)c5ccc6oc7ccccc7c6c5)cc4)cc3)cc2)c2ccc3oc4ccccc4c3c2)cc1]

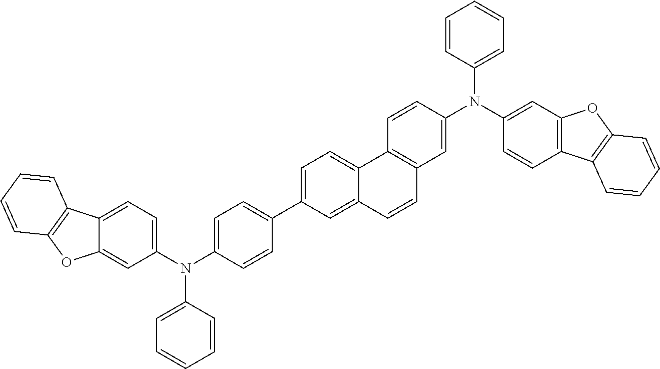 [SMILES: c1ccc(N(c2ccc(-c3ccc4c(ccc5cc(N(c6ccccc6)c6ccc7c(c6)oc6ccccc67)ccc54)c3)cc2)c2ccc3c(c2)oc2ccccc23)cc1]

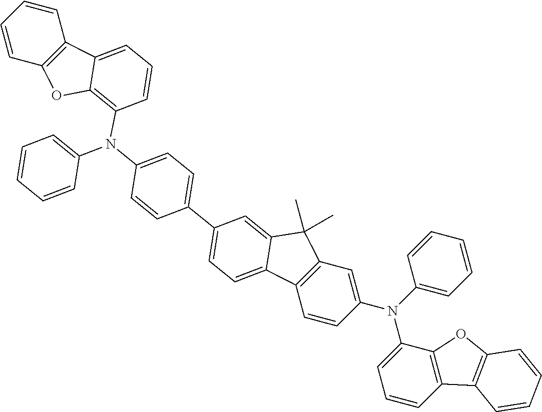 [SMILES: CC1(C)c2cc(-c3ccc(N(c4ccccc4)c4cccc5c4oc4ccccc45)cc3)ccc2-c2ccc(N(c3ccccc3)c3cccc4c3oc3ccccc34)cc21]

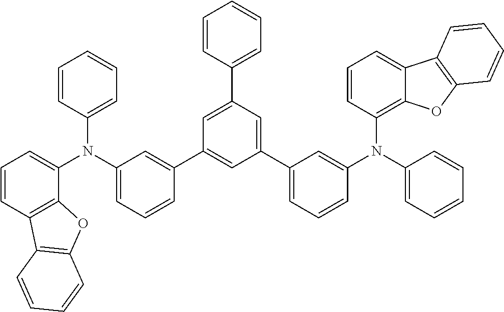 [SMILES: c1ccc(-c2cc(-c3cccc(N(c4ccccc4)c4cccc5c4oc4ccccc45)c3)cc(-c3cccc(N(c4ccccc4)c4cccc5c4oc4ccccc45)c3)c2)cc1]

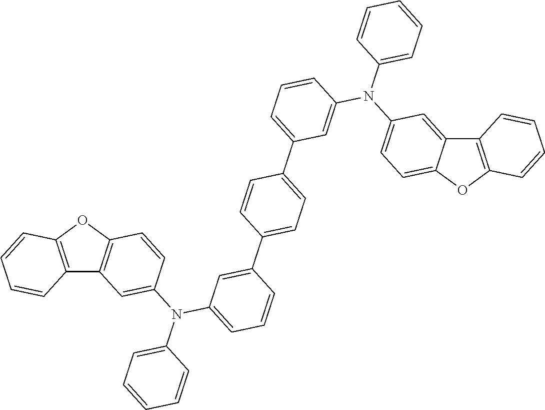 [SMILES: c1ccc(N(c2cccc(-c3ccc(-c4cccc(N(c5ccccc5)c5ccc6oc7ccccc7c6c5)c4)cc3)c2)c2ccc3oc4ccccc4c3c2)cc1]

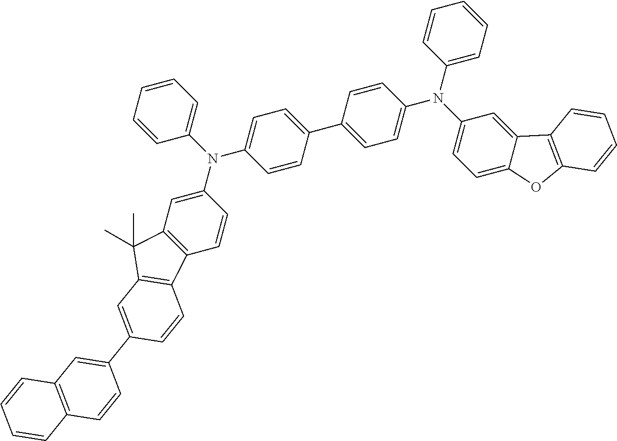 [SMILES: CC1(C)c2cc(-c3ccc4ccccc4c3)ccc2-c2ccc(N(c3ccccc3)c3ccc(-c4ccc(N(c5ccccc5)c5ccc6oc7ccccc7c6c5)cc4)cc3)cc21]

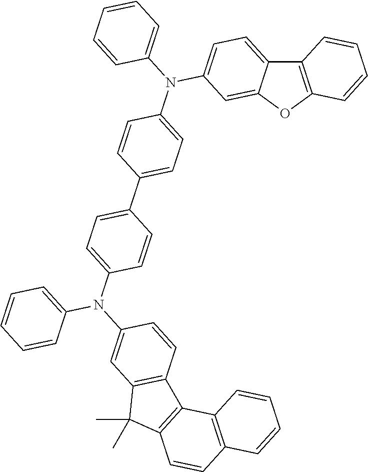 [SMILES: CC1(C)c2cc(N(c3ccccc3)c3ccc(-c4ccc(N(c5ccccc5)c5ccc6c(c5)oc5ccccc56)cc4)cc3)ccc2-c2c1ccc1ccccc21]

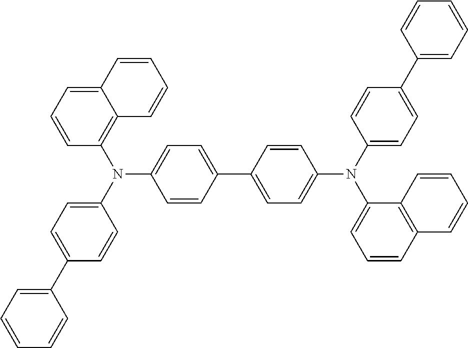 [SMILES: c1ccc(-c2ccc(N(c3ccc(-c4ccc(N(c5ccc(-c6ccccc6)cc5)c5cccc6ccccc56)cc4)cc3)c3cccc4ccccc34)cc2)cc1]

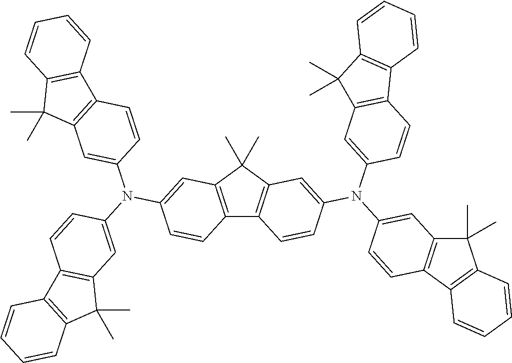 [SMILES: CC1(C)c2ccccc2-c2ccc(N(c3ccc4c(c3)C(C)(C)c3ccccc3-4)c3ccc4c(c3)C(C)(C)c3cc(N(c5ccc6c(c5)C(C)(C)c5ccccc5-6)c5ccc6c(c5)C(C)(C)c5ccccc5-6)ccc3-4)cc21]

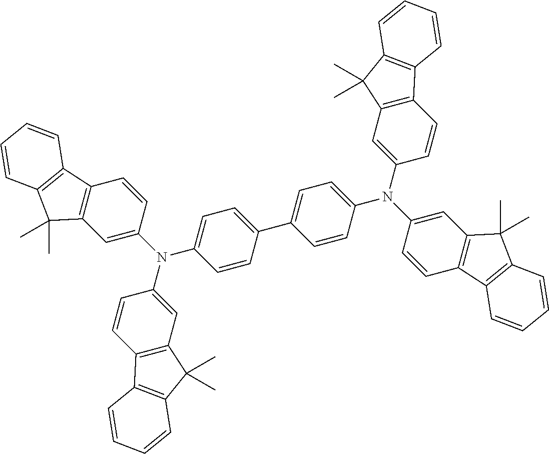 [SMILES: CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21]

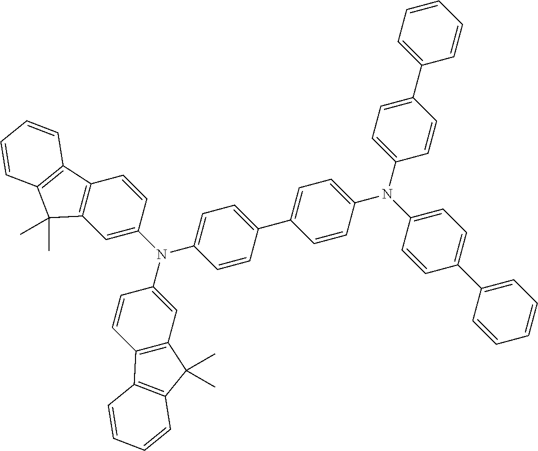 [SMILES: CC1(C)c2ccccc2-c2ccc(N(c3ccc(-c4ccc(N(c5ccc(-c6ccccc6)cc5)c5ccc(-c6ccccc6)cc5)cc4)cc3)c3ccc4c(c3)C(C)(C)c3ccccc3-4)cc21]

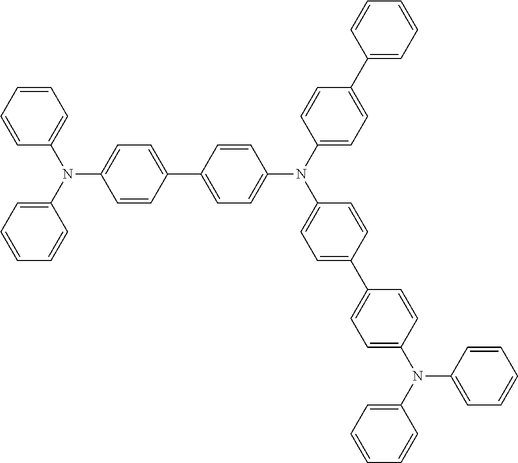 [SMILES: c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1]

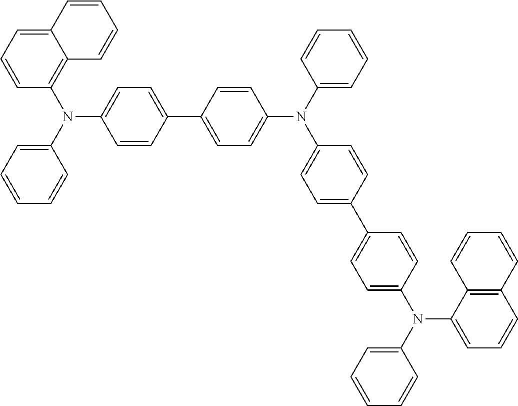 [SMILES: c1ccc(N(c2ccc(-c3ccc(N(c4ccccc4)c4cccc5ccccc45)cc3)cc2)c2ccc(-c3ccc(N(c4ccccc4)c4cccc5ccccc45)cc3)cc2)cc1]

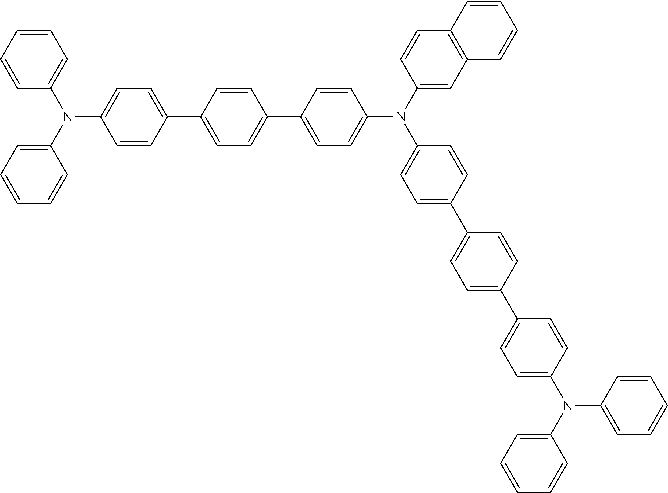 [SMILES: c1ccc(N(c2ccccc2)c2ccc(-c3ccc(-c4ccc(N(c5ccc(-c6ccc(-c7ccc(N(c8ccccc8)c8ccccc8)cc7)cc6)cc5)c5ccc6ccccc6c5)cc4)cc3)cc2)cc1]

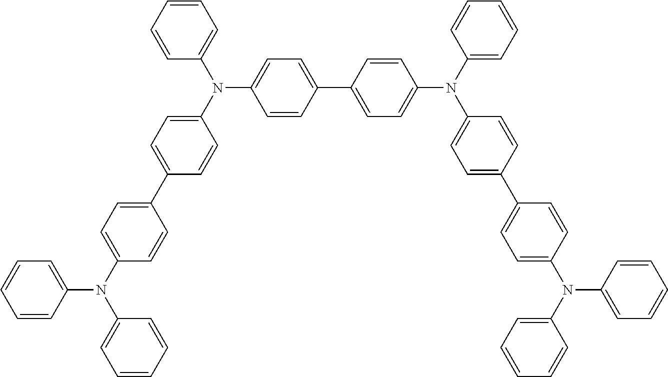 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

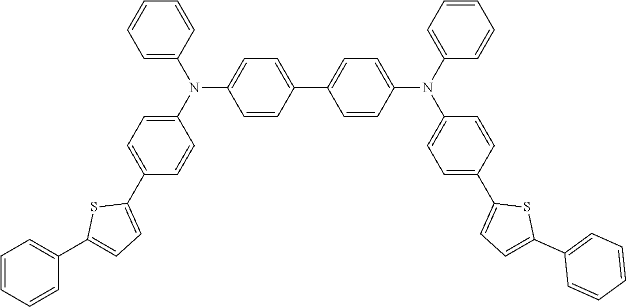 [SMILES: c1ccc(-c2ccc(-c3ccc(N(c4ccccc4)c4ccc(-c5ccc(N(c6ccccc6)c6ccc(-c7ccc(-c8ccccc8)s7)cc6)cc5)cc4)cc3)s2)cc1]

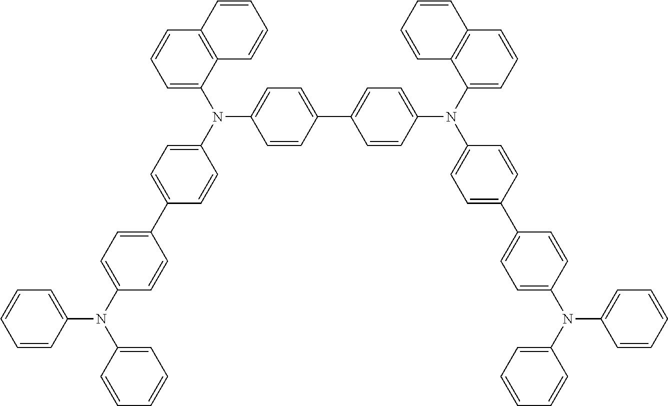 [SMILES: c1ccc(N(c2ccccc2)c2ccc(-c3ccc(N(c4ccc(-c5ccc(N(c6ccc(-c7ccc(N(c8ccccc8)c8ccccc8)cc7)cc6)c6cccc7ccccc67)cc5)cc4)c4cccc5ccccc45)cc3)cc2)cc1]

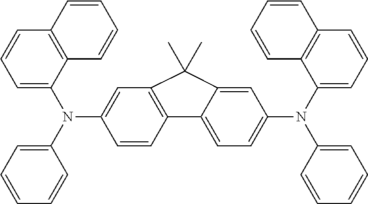 [SMILES: CC1(C)c2cc(N(c3ccccc3)c3cccc4ccccc34)ccc2-c2ccc(N(c3ccccc3)c3cccc4ccccc34)cc21]

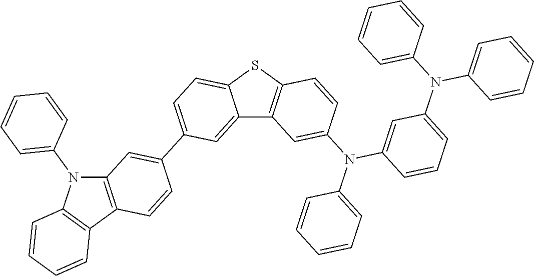 [SMILES: c1ccc(N(c2ccccc2)c2cccc(N(c3ccccc3)c3ccc4sc5ccc(-c6ccc7c8ccccc8n(-c8ccccc8)c7c6)cc5c4c3)c2)cc1]

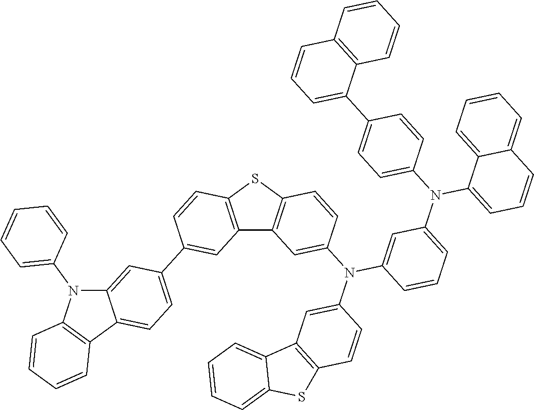 [SMILES: c1ccc(-n2c3ccccc3c3ccc(-c4ccc5sc6ccc(N(c7cccc(N(c8ccc(-c9cccc%10ccccc9%10)cc8)c8cccc9ccccc89)c7)c7ccc8sc9ccccc9c8c7)cc6c5c4)cc32)cc1]

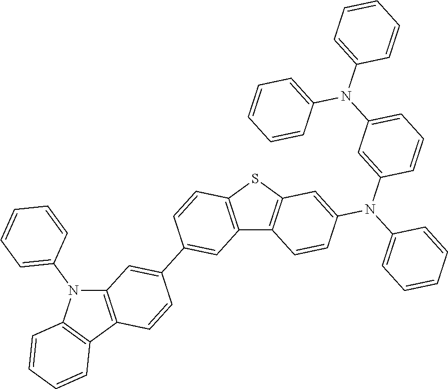 [SMILES: c1ccc(N(c2ccccc2)c2cccc(N(c3ccccc3)c3ccc4c(c3)sc3ccc(-c5ccc6c7ccccc7n(-c7ccccc7)c6c5)cc34)c2)cc1]

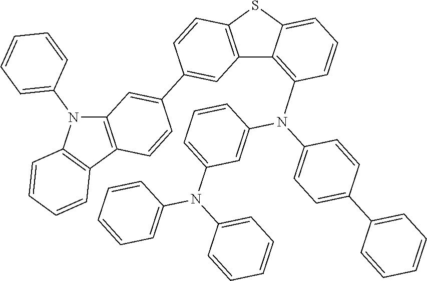 [SMILES: c1ccc(-c2ccc(N(c3cccc(N(c4ccccc4)c4ccccc4)c3)c3cccc4sc5ccc(-c6ccc7c8ccccc8n(-c8ccccc8)c7c6)cc5c34)cc2)cc1]

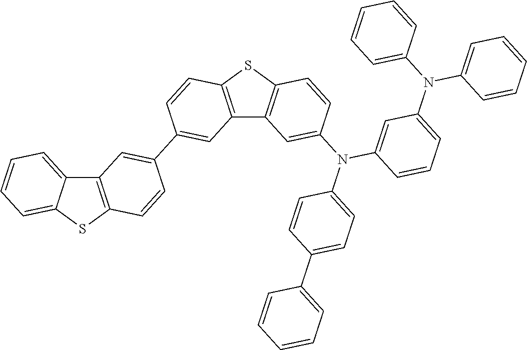 [SMILES: c1ccc(-c2ccc(N(c3cccc(N(c4ccccc4)c4ccccc4)c3)c3ccc4sc5ccc(-c6ccc7sc8ccccc8c7c6)cc5c4c3)cc2)cc1]

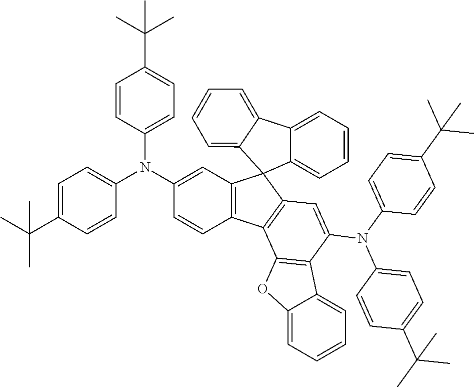 [SMILES: CC(C)(C)c1ccc(N(c2ccc(C(C)(C)C)cc2)c2ccc3c(c2)C2(c4ccccc4-c4ccccc42)c2cc(N(c4ccc(C(C)(C)C)cc4)c4ccc(C(C)(C)C)cc4)c4c(oc5ccccc54)c2-3)cc1]

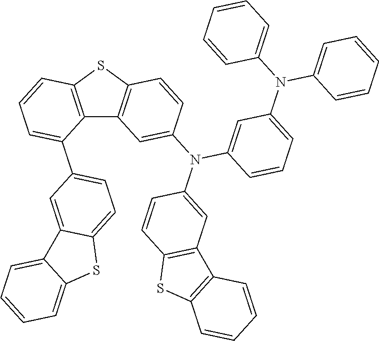 [SMILES: c1ccc(N(c2ccccc2)c2cccc(N(c3ccc4sc5ccccc5c4c3)c3ccc4sc5cccc(-c6ccc7sc8ccccc8c7c6)c5c4c3)c2)cc1]

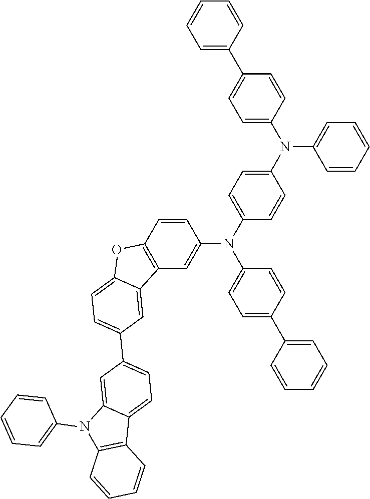 [SMILES: c1ccc(-c2ccc(N(c3ccccc3)c3ccc(N(c4ccc(-c5ccccc5)cc4)c4ccc5oc6ccc(-c7ccc8c9ccccc9n(-c9ccccc9)c8c7)cc6c5c4)cc3)cc2)cc1]

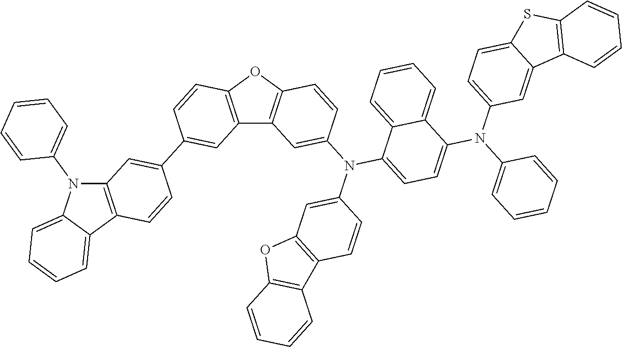 [SMILES: c1ccc(N(c2ccc3sc4ccccc4c3c2)c2ccc(N(c3ccc4c(c3)oc3ccccc34)c3ccc4oc5ccc(-c6ccc7c8ccccc8n(-c8ccccc8)c7c6)cc5c4c3)c3ccccc23)cc1]

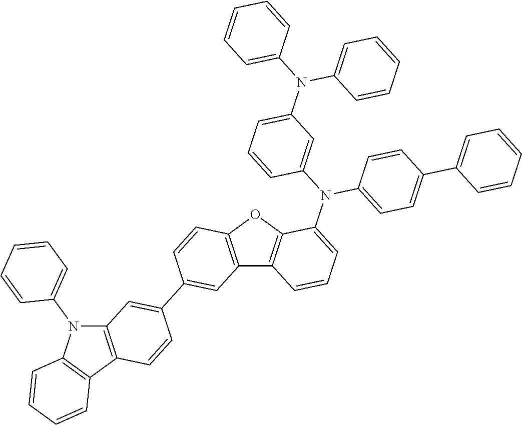 [SMILES: c1ccc(-c2ccc(N(c3cccc(N(c4ccccc4)c4ccccc4)c3)c3cccc4c3oc3ccc(-c5ccc6c7ccccc7n(-c7ccccc7)c6c5)cc34)cc2)cc1]

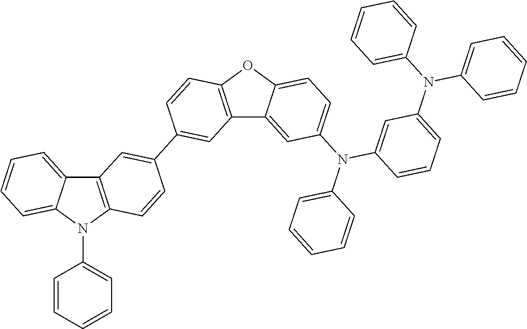 [SMILES: c1ccc(N(c2ccccc2)c2cccc(N(c3ccccc3)c3ccc4oc5ccc(-c6ccc7c(c6)c6ccccc6n7-c6ccccc6)cc5c4c3)c2)cc1]

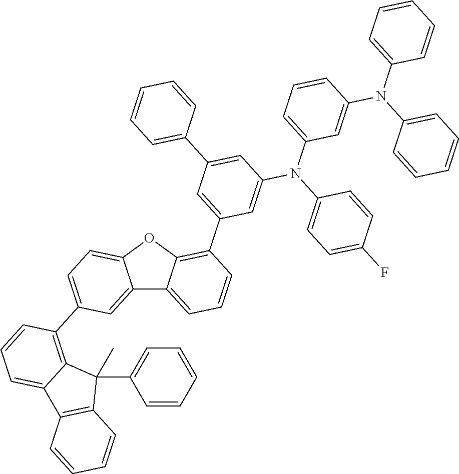 [SMILES: CC1(c2ccccc2)c2ccccc2-c2cccc(-c3ccc4oc5c(-c6cc(-c7ccccc7)cc(N(c7ccc(F)cc7)c7cccc(N(c8ccccc8)c8ccccc8)c7)c6)cccc5c4c3)c21]

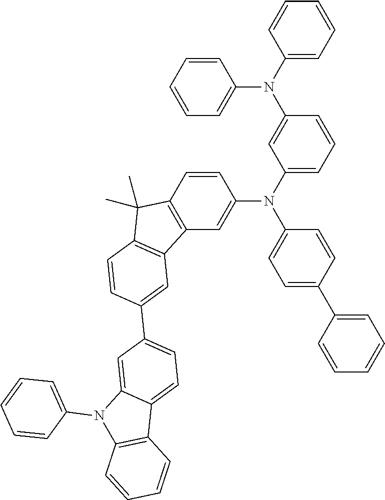 [SMILES: CC1(C)c2ccc(-c3ccc4c5ccccc5n(-c5ccccc5)c4c3)cc2-c2cc(N(c3ccc(-c4ccccc4)cc3)c3cccc(N(c4ccccc4)c4ccccc4)c3)ccc21]

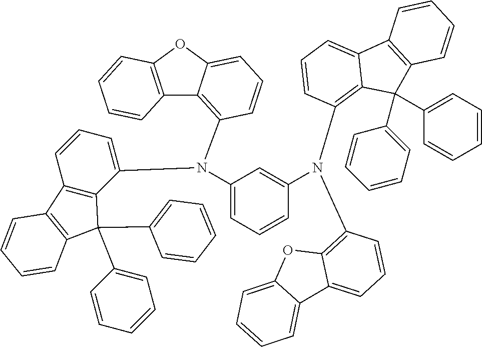 [SMILES: c1ccc(C2(c3ccccc3)c3ccccc3-c3cccc(N(c4cccc(N(c5cccc6c5C(c5ccccc5)(c5ccccc5)c5ccccc5-6)c5cccc6oc7ccccc7c56)c4)c4cccc5c4oc4ccccc45)c32)cc1]

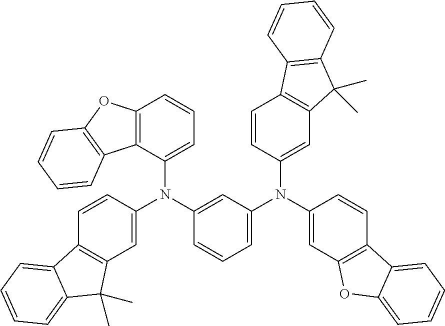 [SMILES: CC1(C)c2ccccc2-c2ccc(N(c3cccc(N(c4ccc5c(c4)C(C)(C)c4ccccc4-5)c4cccc5oc6ccccc6c45)c3)c3ccc4c(c3)oc3ccccc34)cc21]

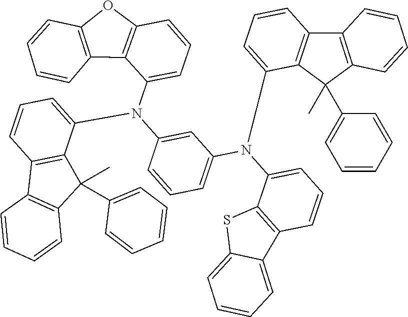 [SMILES: CC1(c2ccccc2)c2ccccc2-c2cccc(N(c3cccc(N(c4cccc5c4C(C)(c4ccccc4)c4ccccc4-5)c4cccc5oc6ccccc6c45)c3)c3cccc4c3sc3ccccc34)c21]

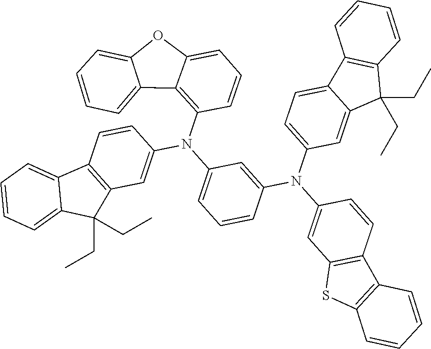 [SMILES: CCC1(CC)c2ccccc2-c2ccc(N(c3cccc(N(c4ccc5c(c4)C(CC)(CC)c4ccccc4-5)c4cccc5oc6ccccc6c45)c3)c3ccc4c(c3)sc3ccccc34)cc21]

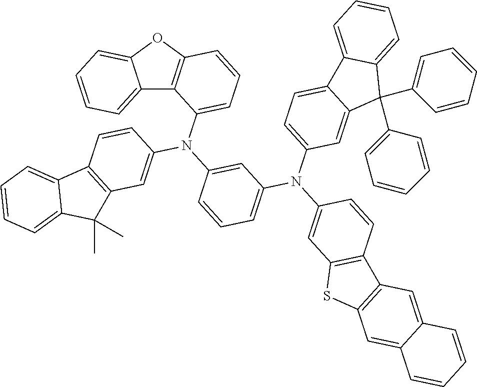 [SMILES: CC1(C)c2ccccc2-c2ccc(N(c3cccc(N(c4ccc5c(c4)C(c4ccccc4)(c4ccccc4)c4ccccc4-5)c4ccc5c(c4)sc4cc6ccccc6cc45)c3)c3cccc4oc5ccccc5c34)cc21]

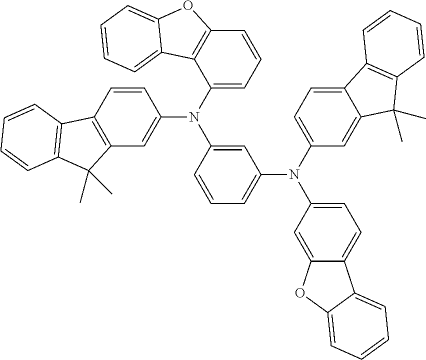 [SMILES: CC1(C)c2ccccc2-c2ccc(N(c3cccc(N(c4ccc5c(c4)C(C)(C)c4ccccc4-5)c4cccc5oc6ccccc6c45)c3)c3ccc4c(c3)oc3ccccc34)cc21]

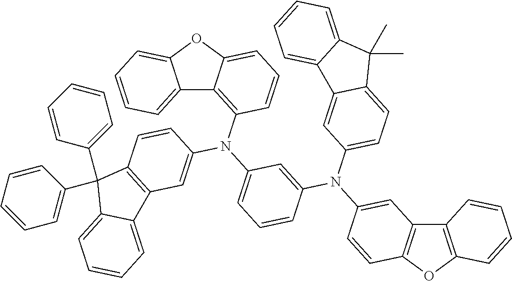 [SMILES: CC1(C)c2ccccc2-c2cc(N(c3cccc(N(c4ccc5c(c4)-c4ccccc4C5(c4ccccc4)c4ccccc4)c4cccc5oc6ccccc6c45)c3)c3ccc4oc5ccccc5c4c3)ccc21]

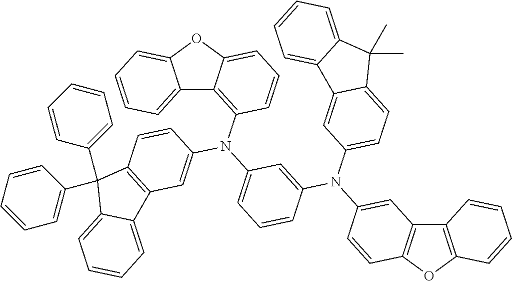 [SMILES: CC1(C)c2ccccc2-c2cc(N(c3cccc(N(c4ccc5c(c4)-c4ccccc4C5(c4ccccc4)c4ccccc4)c4cccc5oc6ccccc6c45)c3)c3ccc4oc5ccccc5c4c3)ccc21]

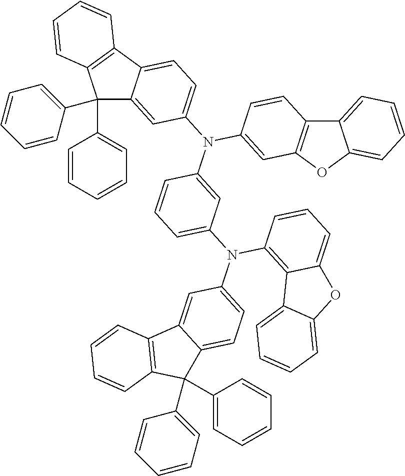 [SMILES: c1ccc(C2(c3ccccc3)c3ccccc3-c3cc(N(c4cccc(N(c5ccc6c(c5)C(c5ccccc5)(c5ccccc5)c5ccccc5-6)c5ccc6c(c5)oc5ccccc56)c4)c4cccc5oc6ccccc6c45)ccc32)cc1]

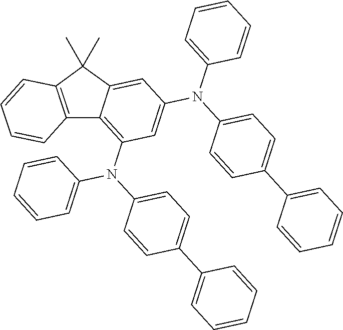 [SMILES: CC1(C)c2ccccc2-c2c(N(c3ccccc3)c3ccc(-c4ccccc4)cc3)cc(N(c3ccccc3)c3ccc(-c4ccccc4)cc3)cc21]

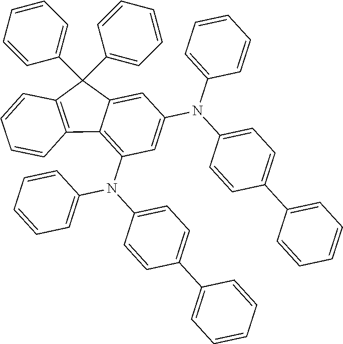 [SMILES: c1ccc(-c2ccc(N(c3ccccc3)c3cc(N(c4ccccc4)c4ccc(-c5ccccc5)cc4)c4c(c3)C(c3ccccc3)(c3ccccc3)c3ccccc3-4)cc2)cc1]

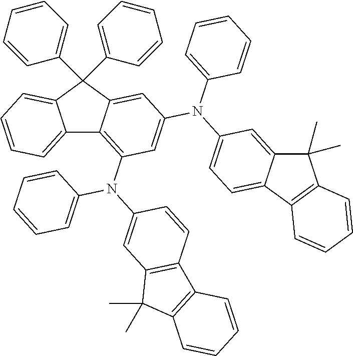 [SMILES: CC1(C)c2ccccc2-c2ccc(N(c3ccccc3)c3cc(N(c4ccccc4)c4ccc5c(c4)C(C)(C)c4ccccc4-5)c4c(c3)C(c3ccccc3)(c3ccccc3)c3ccccc3-4)cc21]

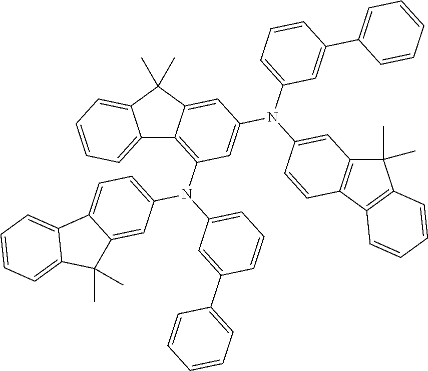 [SMILES: CC1(C)c2ccccc2-c2ccc(N(c3cccc(-c4ccccc4)c3)c3cc(N(c4cccc(-c5ccccc5)c4)c4ccc5c(c4)C(C)(C)c4ccccc4-5)c4c(c3)C(C)(C)c3ccccc3-4)cc21]

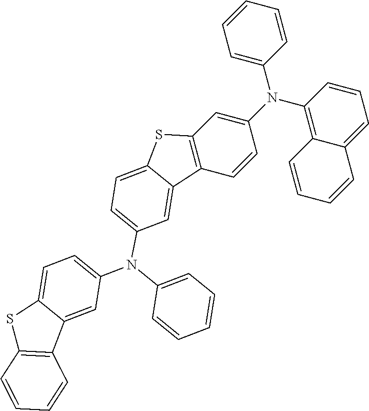 [SMILES: c1ccc(N(c2ccc3sc4ccccc4c3c2)c2ccc3sc4cc(N(c5ccccc5)c5cccc6ccccc56)ccc4c3c2)cc1]

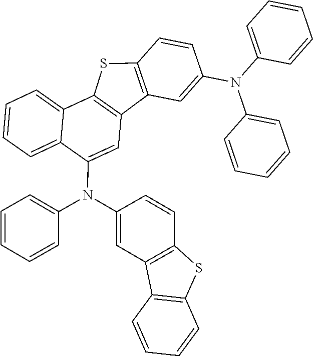 [SMILES: c1ccc(N(c2ccccc2)c2ccc3sc4c5ccccc5c(N(c5ccccc5)c5ccc6sc7ccccc7c6c5)cc4c3c2)cc1]

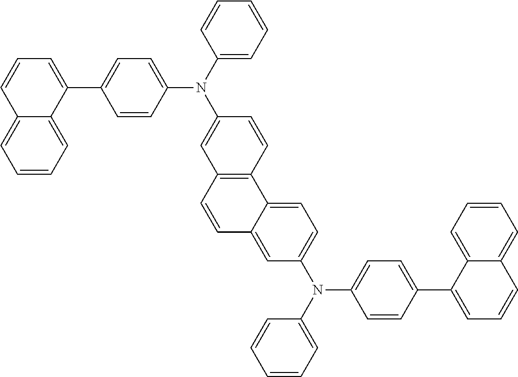 [SMILES: c1ccc(N(c2ccc(-c3cccc4ccccc34)cc2)c2ccc3c(ccc4cc(N(c5ccccc5)c5ccc(-c6cccc7ccccc67)cc5)ccc43)c2)cc1]

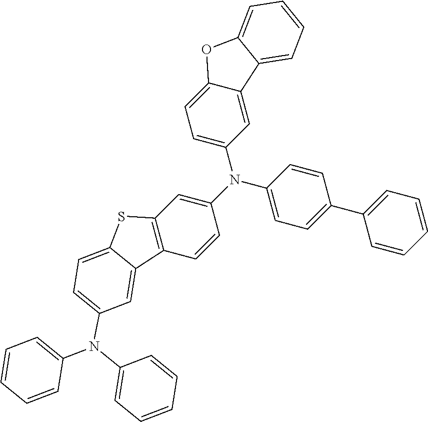 [SMILES: c1ccc(-c2ccc(N(c3ccc4c(c3)sc3ccc(N(c5ccccc5)c5ccccc5)cc34)c3ccc4oc5ccccc5c4c3)cc2)cc1]

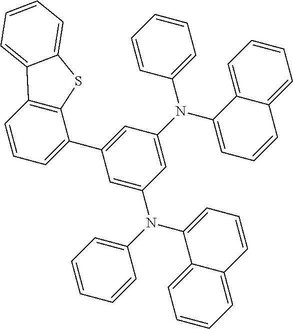 [SMILES: c1ccc(N(c2cc(-c3cccc4c3sc3ccccc34)cc(N(c3ccccc3)c3cccc4ccccc34)c2)c2cccc3ccccc23)cc1]

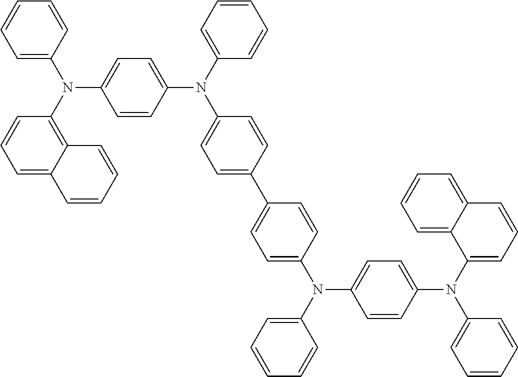 [SMILES: c1ccc(N(c2ccc(-c3ccc(N(c4ccccc4)c4ccc(N(c5ccccc5)c5cccc6ccccc56)cc4)cc3)cc2)c2ccc(N(c3ccccc3)c3cccc4ccccc34)cc2)cc1]

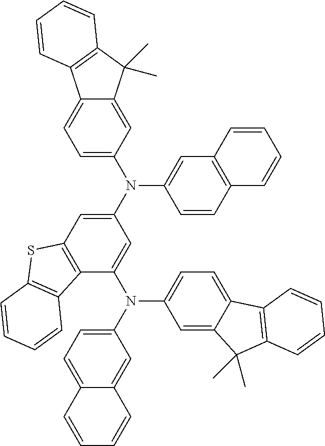 [SMILES: CC1(C)c2ccccc2-c2ccc(N(c3ccc4ccccc4c3)c3cc(N(c4ccc5c(c4)C(C)(C)c4ccccc4-5)c4ccc5ccccc5c4)c4c(c3)sc3ccccc34)cc21]

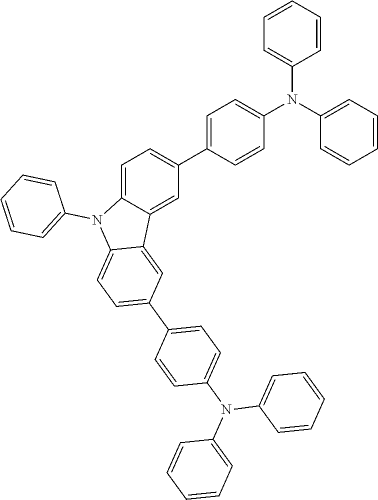 [SMILES: c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1]

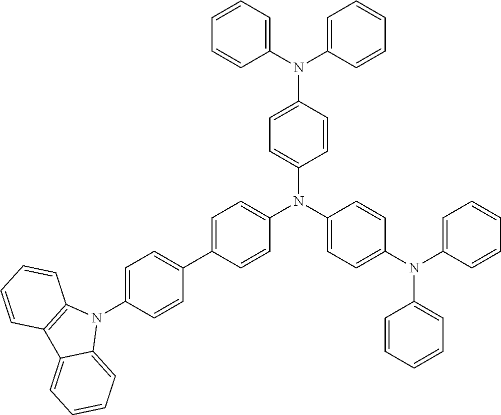 [SMILES: c1ccc(N(c2ccccc2)c2ccc(N(c3ccc(-c4ccc(-n5c6ccccc6c6ccccc65)cc4)cc3)c3ccc(N(c4ccccc4)c4ccccc4)cc3)cc2)cc1]

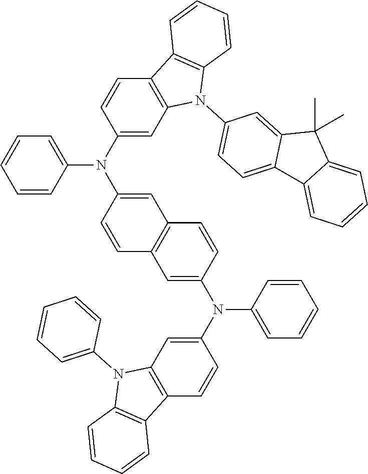 [SMILES: CC1(C)c2ccccc2-c2ccc(-n3c4ccccc4c4ccc(N(c5ccccc5)c5ccc6cc(N(c7ccccc7)c7ccc8c9ccccc9n(-c9ccccc9)c8c7)ccc6c5)cc43)cc21]

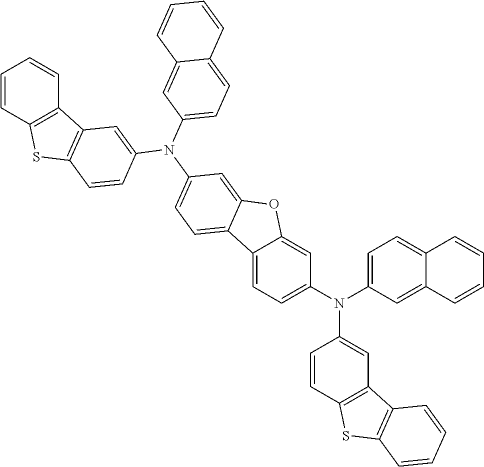 [SMILES: c1ccc2cc(N(c3ccc4c(c3)oc3cc(N(c5ccc6ccccc6c5)c5ccc6sc7ccccc7c6c5)ccc34)c3ccc4sc5ccccc5c4c3)ccc2c1]

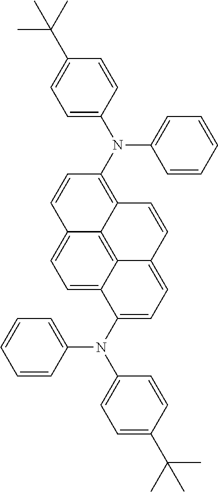 [SMILES: CC(C)(C)c1ccc(N(c2ccccc2)c2ccc3ccc4c(N(c5ccccc5)c5ccc(C(C)(C)C)cc5)ccc5ccc2c3c54)cc1]

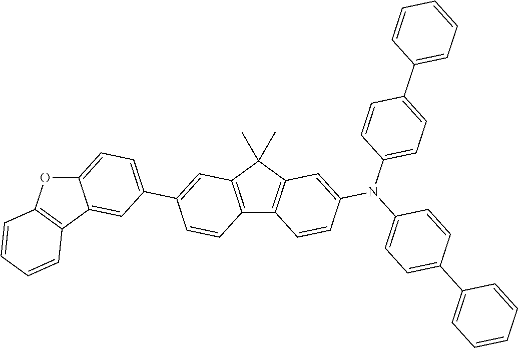 [SMILES: CC1(C)c2cc(-c3ccc4oc5ccccc5c4c3)ccc2-c2ccc(N(c3ccc(-c4ccccc4)cc3)c3ccc(-c4ccccc4)cc3)cc21]

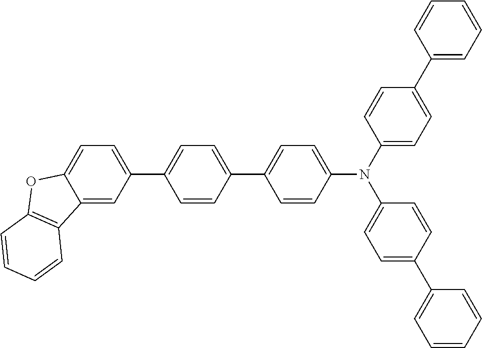 [SMILES: c1ccc(-c2ccc(N(c3ccc(-c4ccccc4)cc3)c3ccc(-c4ccc(-c5ccc6oc7ccccc7c6c5)cc4)cc3)cc2)cc1]

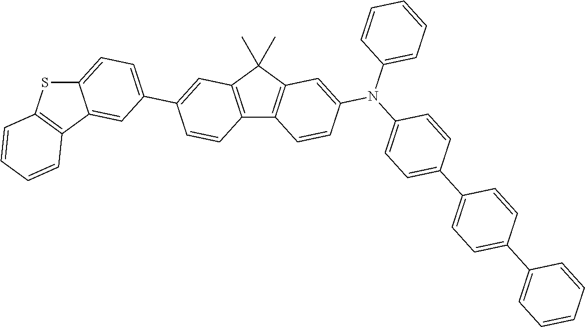 [SMILES: CC1(C)c2cc(-c3ccc4sc5ccccc5c4c3)ccc2-c2ccc(N(c3ccccc3)c3ccc(-c4ccc(-c5ccccc5)cc4)cc3)cc21]

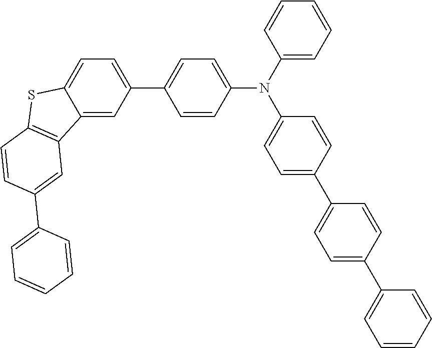 [SMILES: c1ccc(-c2ccc(-c3ccc(N(c4ccccc4)c4ccc(-c5ccc6sc7ccc(-c8ccccc8)cc7c6c5)cc4)cc3)cc2)cc1]

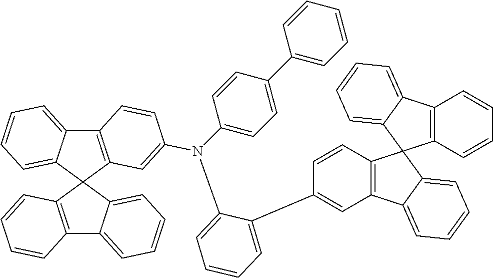 [SMILES: c1ccc(-c2ccc(N(c3ccc4c(c3)C3(c5ccccc5-c5ccccc53)c3ccccc3-4)c3ccccc3-c3ccc4c(c3)-c3ccccc3C43c4ccccc4-c4ccccc43)cc2)cc1]

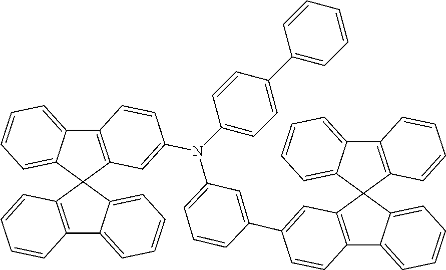 [SMILES: c1ccc(-c2ccc(N(c3cccc(-c4ccc5c(c4)C4(c6ccccc6-c6ccccc64)c4ccccc4-5)c3)c3ccc4c(c3)C3(c5ccccc5-c5ccccc53)c3ccccc3-4)cc2)cc1]

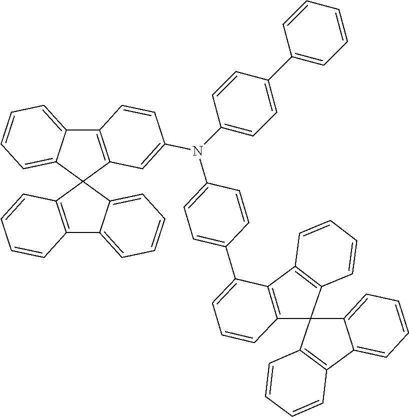 [SMILES: c1ccc(-c2ccc(N(c3ccc(-c4cccc5c4-c4ccccc4C54c5ccccc5-c5ccccc54)cc3)c3ccc4c(c3)C3(c5ccccc5-c5ccccc53)c3ccccc3-4)cc2)cc1]

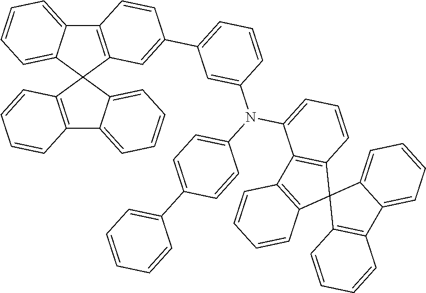 [SMILES: c1ccc(-c2ccc(N(c3cccc(-c4ccc5c(c4)C4(c6ccccc6-c6ccccc64)c4ccccc4-5)c3)c3cccc4c3-c3ccccc3C43c4ccccc4-c4ccccc43)cc2)cc1]

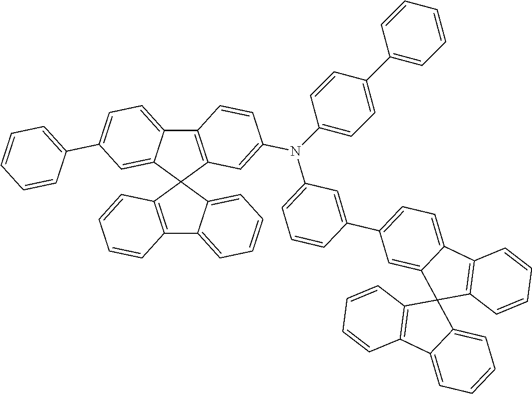 [SMILES: c1ccc(-c2ccc(N(c3cccc(-c4ccc5c(c4)C4(c6ccccc6-c6ccccc64)c4ccccc4-5)c3)c3ccc4c(c3)C3(c5ccccc5-c5ccccc53)c3cc(-c5ccccc5)ccc3-4)cc2)cc1]

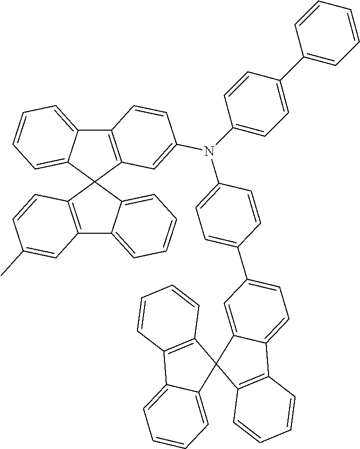 [SMILES: Cc1ccc2c(c1)-c1ccccc1C21c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

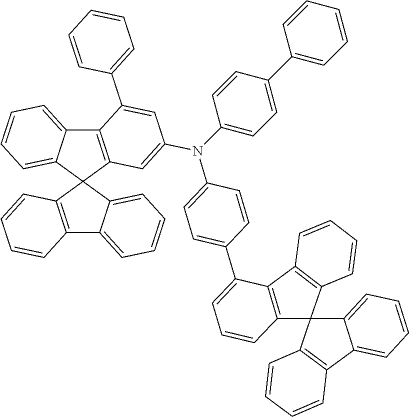 [SMILES: c1ccc(-c2ccc(N(c3ccc(-c4cccc5c4-c4ccccc4C54c5ccccc5-c5ccccc54)cc3)c3cc(-c4ccccc4)c4c(c3)C3(c5ccccc5-c5ccccc53)c3ccccc3-4)cc2)cc1]

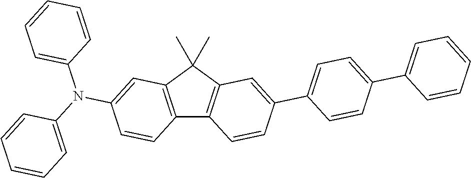 [SMILES: CC1(C)c2cc(-c3ccc(-c4ccccc4)cc3)ccc2-c2ccc(N(c3ccccc3)c3ccccc3)cc21]

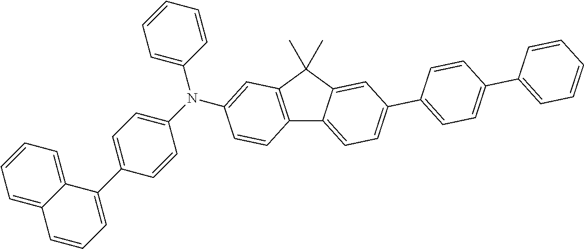 [SMILES: CC1(C)c2cc(-c3ccc(-c4ccccc4)cc3)ccc2-c2ccc(N(c3ccccc3)c3ccc(-c4cccc5ccccc45)cc3)cc21]

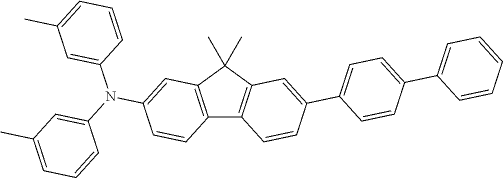 [SMILES: Cc1cccc(N(c2cccc(C)c2)c2ccc3c(c2)C(C)(C)c2cc(-c4ccc(-c5ccccc5)cc4)ccc2-3)c1]

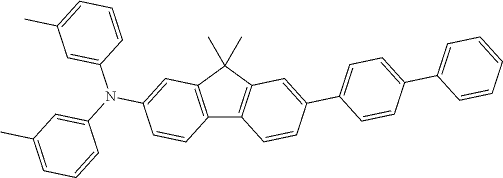 [SMILES: Cc1cccc(N(c2cccc(C)c2)c2ccc3c(c2)C(C)(C)c2cc(-c4ccc(-c5ccccc5)cc4)ccc2-3)c1]

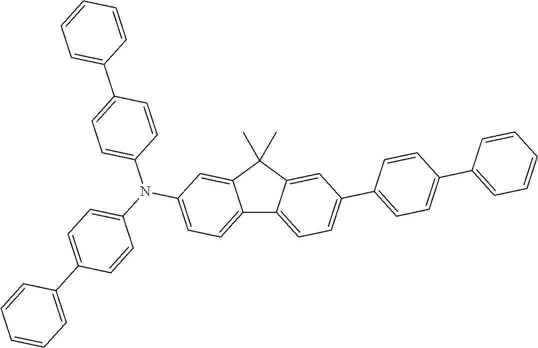 [SMILES: CC1(C)c2cc(-c3ccc(-c4ccccc4)cc3)ccc2-c2ccc(N(c3ccc(-c4ccccc4)cc3)c3ccc(-c4ccccc4)cc3)cc21]

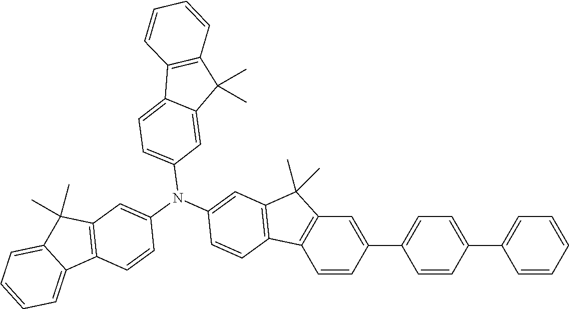 [SMILES: CC1(C)c2ccccc2-c2ccc(N(c3ccc4c(c3)C(C)(C)c3ccccc3-4)c3ccc4c(c3)C(C)(C)c3cc(-c5ccc(-c6ccccc6)cc5)ccc3-4)cc21]

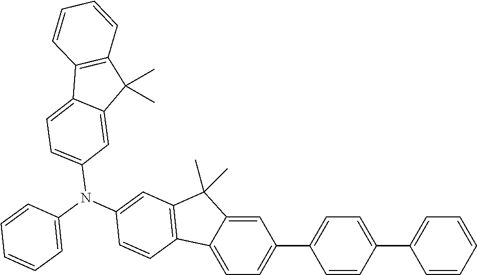 [SMILES: CC1(C)c2ccccc2-c2ccc(N(c3ccccc3)c3ccc4c(c3)C(C)(C)c3cc(-c5ccc(-c6ccccc6)cc5)ccc3-4)cc21]

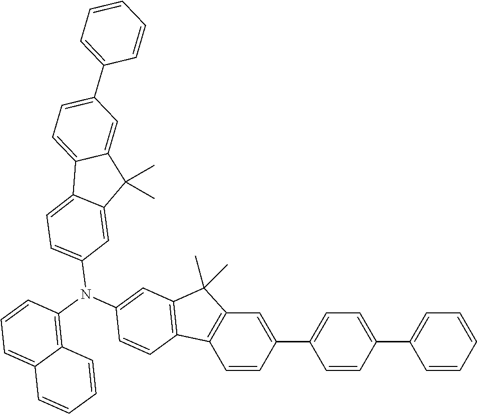 [SMILES: CC1(C)c2cc(-c3ccccc3)ccc2-c2ccc(N(c3ccc4c(c3)C(C)(C)c3cc(-c5ccc(-c6ccccc6)cc5)ccc3-4)c3cccc4ccccc34)cc21]

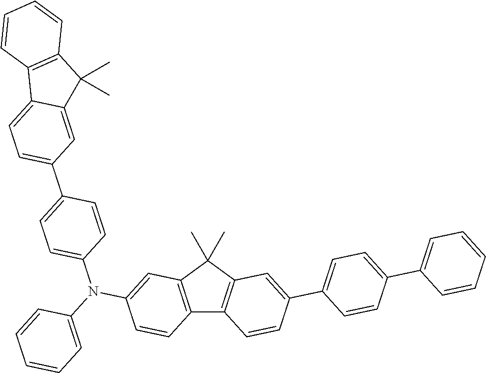 [SMILES: CC1(C)c2ccccc2-c2ccc(-c3ccc(N(c4ccccc4)c4ccc5c(c4)C(C)(C)c4cc(-c6ccc(-c7ccccc7)cc6)ccc4-5)cc3)cc21]

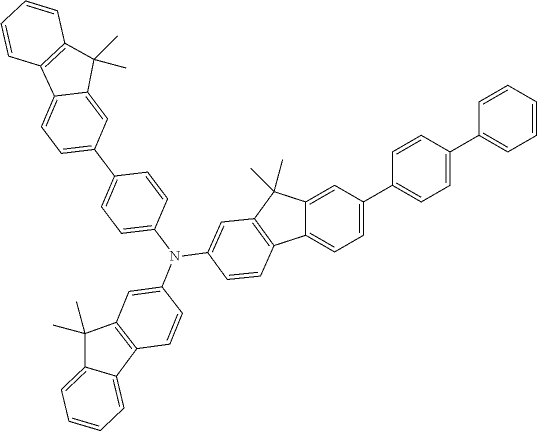 [SMILES: CC1(C)c2ccccc2-c2ccc(-c3ccc(N(c4ccc5c(c4)C(C)(C)c4ccccc4-5)c4ccc5c(c4)C(C)(C)c4cc(-c6ccc(-c7ccccc7)cc6)ccc4-5)cc3)cc21]

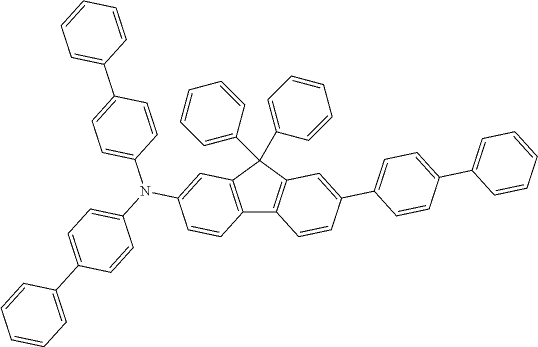 [SMILES: c1ccc(-c2ccc(-c3ccc4c(c3)C(c3ccccc3)(c3ccccc3)c3cc(N(c5ccc(-c6ccccc6)cc5)c5ccc(-c6ccccc6)cc5)ccc3-4)cc2)cc1]

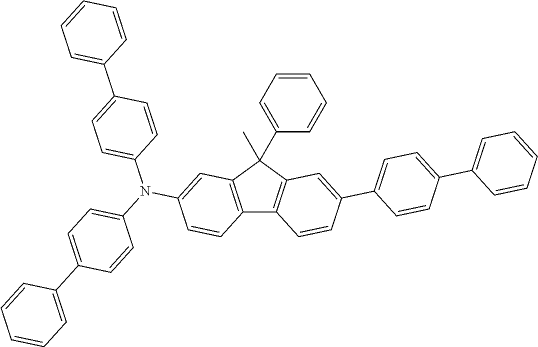 [SMILES: CC1(c2ccccc2)c2cc(-c3ccc(-c4ccccc4)cc3)ccc2-c2ccc(N(c3ccc(-c4ccccc4)cc3)c3ccc(-c4ccccc4)cc3)cc21]

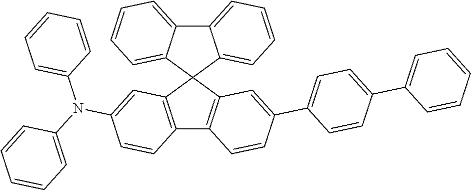 [SMILES: c1ccc(-c2ccc(-c3ccc4c(c3)C3(c5ccccc5-c5ccccc53)c3cc(N(c5ccccc5)c5ccccc5)ccc3-4)cc2)cc1]

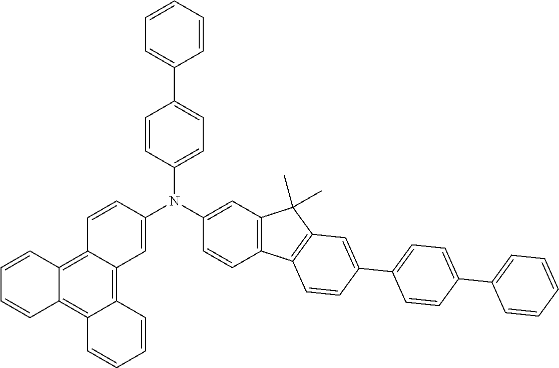 [SMILES: CC1(C)c2cc(-c3ccc(-c4ccccc4)cc3)ccc2-c2ccc(N(c3ccc(-c4ccccc4)cc3)c3ccc4c5ccccc5c5ccccc5c4c3)cc21]

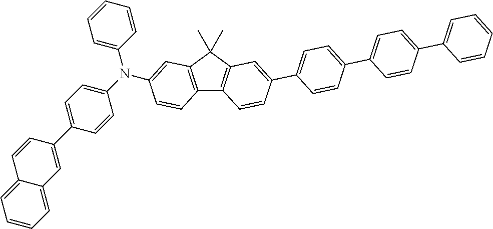 [SMILES: CC1(C)c2cc(-c3ccc(-c4ccc(-c5ccccc5)cc4)cc3)ccc2-c2ccc(N(c3ccccc3)c3ccc(-c4ccc5ccccc5c4)cc3)cc21]

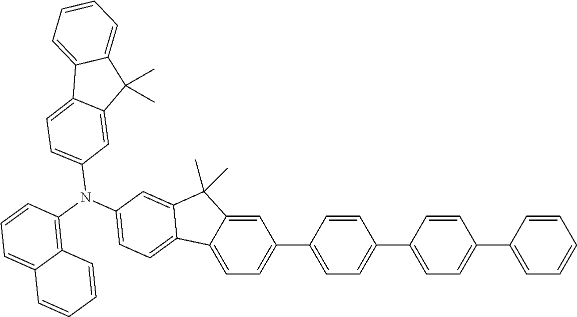 [SMILES: CC1(C)c2ccccc2-c2ccc(N(c3ccc4c(c3)C(C)(C)c3cc(-c5ccc(-c6ccc(-c7ccccc7)cc6)cc5)ccc3-4)c3cccc4ccccc34)cc21]

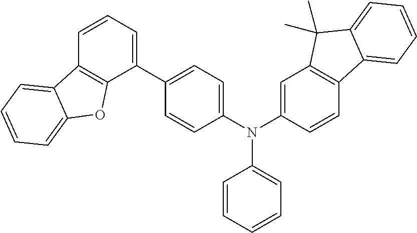 [SMILES: CC1(C)c2ccccc2-c2ccc(N(c3ccccc3)c3ccc(-c4cccc5c4oc4ccccc45)cc3)cc21]

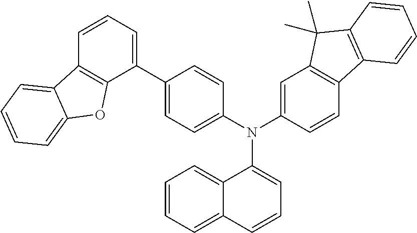 [SMILES: CC1(C)c2ccccc2-c2ccc(N(c3ccc(-c4cccc5c4oc4ccccc45)cc3)c3cccc4ccccc34)cc21]

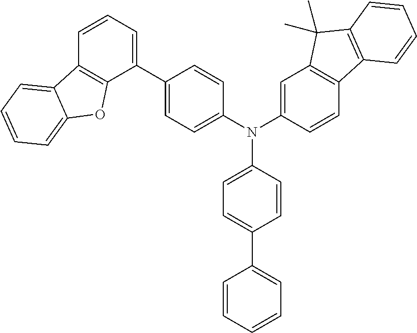 [SMILES: CC1(C)c2ccccc2-c2ccc(N(c3ccc(-c4ccccc4)cc3)c3ccc(-c4cccc5c4oc4ccccc45)cc3)cc21]

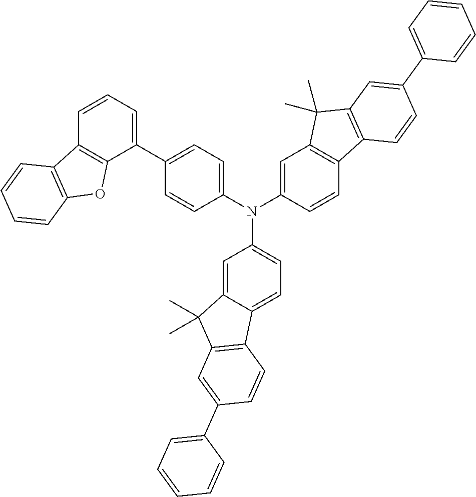 [SMILES: CC1(C)c2cc(-c3ccccc3)ccc2-c2ccc(N(c3ccc(-c4cccc5c4oc4ccccc45)cc3)c3ccc4c(c3)C(C)(C)c3cc(-c5ccccc5)ccc3-4)cc21]

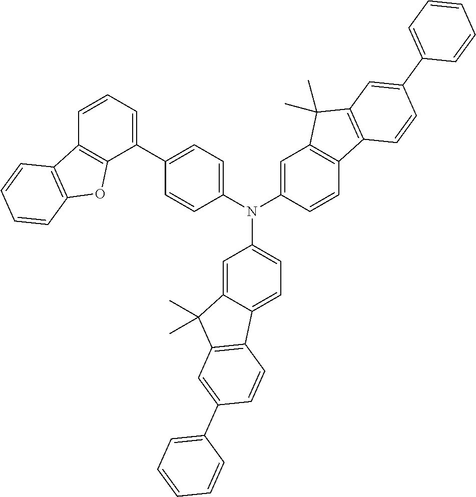 [SMILES: CC1(C)c2cc(-c3ccccc3)ccc2-c2ccc(N(c3ccc(-c4cccc5c4oc4ccccc45)cc3)c3ccc4c(c3)C(C)(C)c3cc(-c5ccccc5)ccc3-4)cc21]

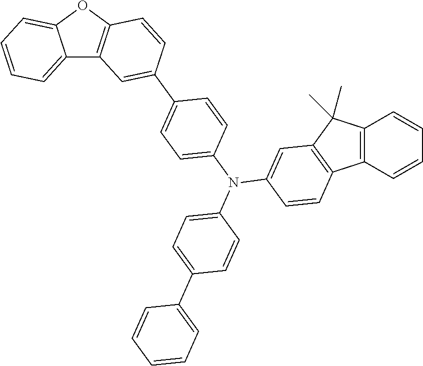 [SMILES: CC1(C)c2ccccc2-c2ccc(N(c3ccc(-c4ccccc4)cc3)c3ccc(-c4ccc5oc6ccccc6c5c4)cc3)cc21]

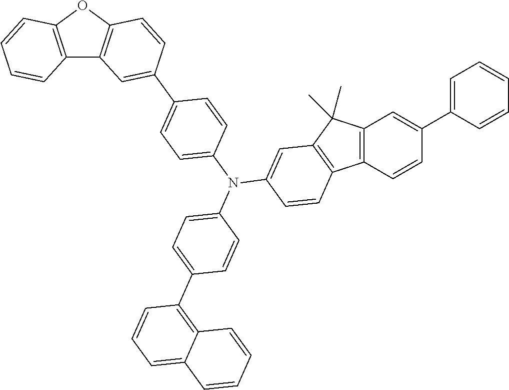 [SMILES: CC1(C)c2cc(-c3ccccc3)ccc2-c2ccc(N(c3ccc(-c4ccc5oc6ccccc6c5c4)cc3)c3ccc(-c4cccc5ccccc45)cc3)cc21]

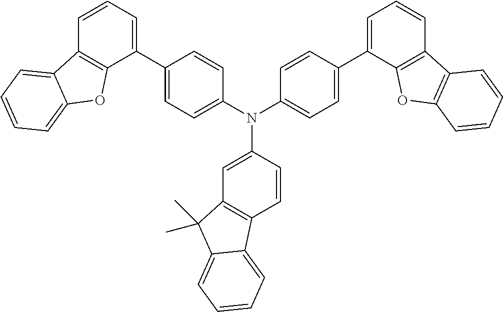 [SMILES: CC1(C)c2ccccc2-c2ccc(N(c3ccc(-c4cccc5c4oc4ccccc45)cc3)c3ccc(-c4cccc5c4oc4ccccc45)cc3)cc21]

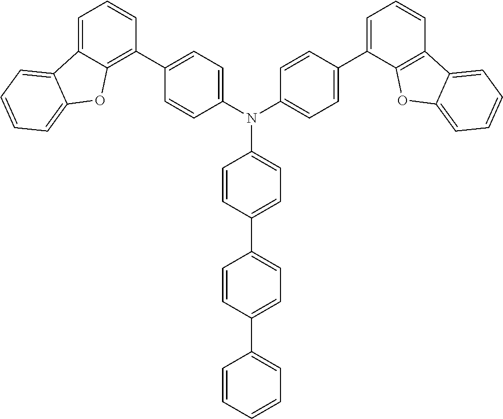 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

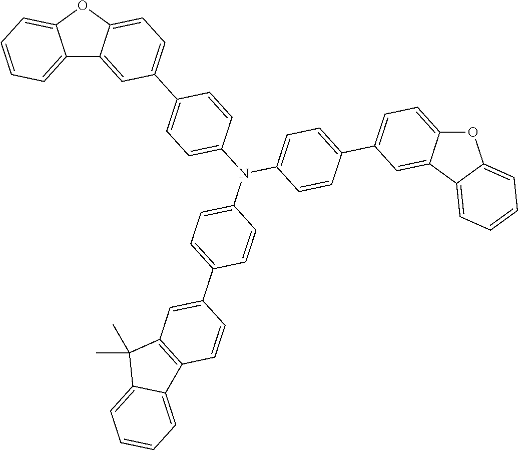 [SMILES: CC1(C)c2ccccc2-c2ccc(-c3ccc(N(c4ccc(-c5ccc6oc7ccccc7c6c5)cc4)c4ccc(-c5ccc6oc7ccccc7c6c5)cc4)cc3)cc21]

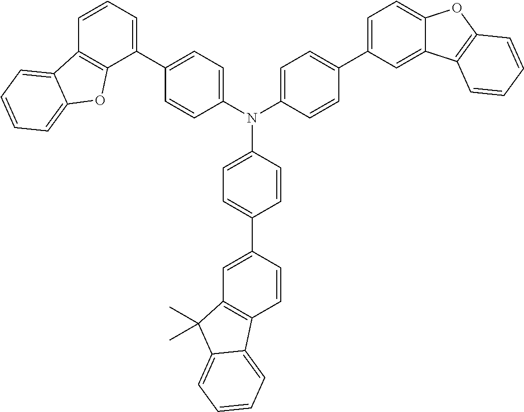 [SMILES: CC1(C)c2ccccc2-c2ccc(-c3ccc(N(c4ccc(-c5ccc6oc7ccccc7c6c5)cc4)c4ccc(-c5cccc6c5oc5ccccc56)cc4)cc3)cc21]

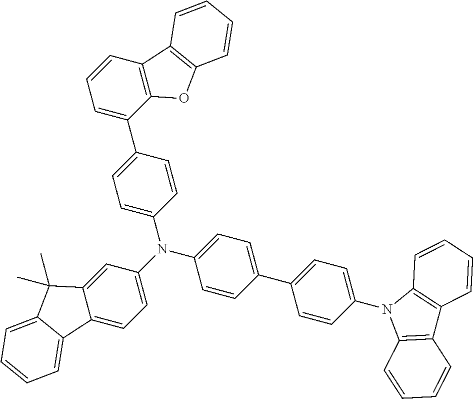 [SMILES: CC1(C)c2ccccc2-c2ccc(N(c3ccc(-c4ccc(-n5c6ccccc6c6ccccc65)cc4)cc3)c3ccc(-c4cccc5c4oc4ccccc45)cc3)cc21]

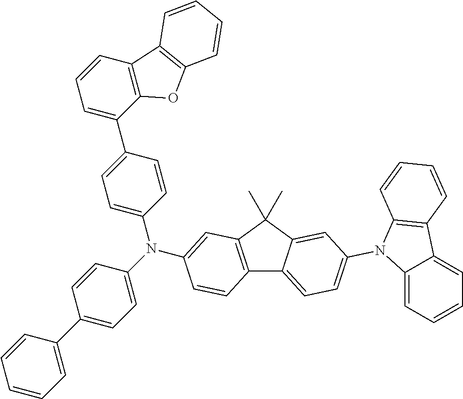 [SMILES: CC1(C)c2cc(N(c3ccc(-c4ccccc4)cc3)c3ccc(-c4cccc5c4oc4ccccc45)cc3)ccc2-c2ccc(-n3c4ccccc4c4ccccc43)cc21]

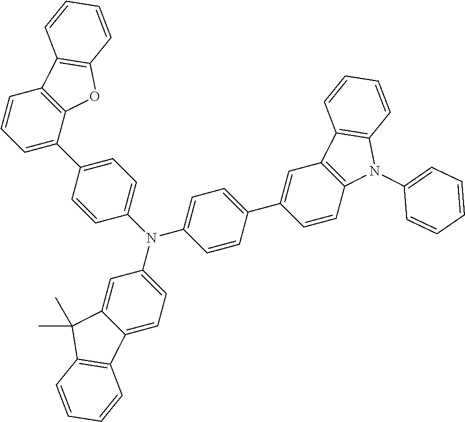 [SMILES: CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21]

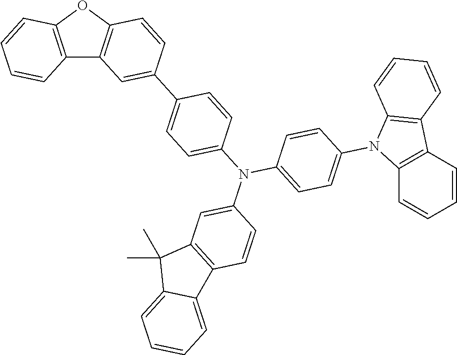 [SMILES: CC1(C)c2ccccc2-c2ccc(N(c3ccc(-c4ccc5oc6ccccc6c5c4)cc3)c3ccc(-n4c5ccccc5c5ccccc54)cc3)cc21]

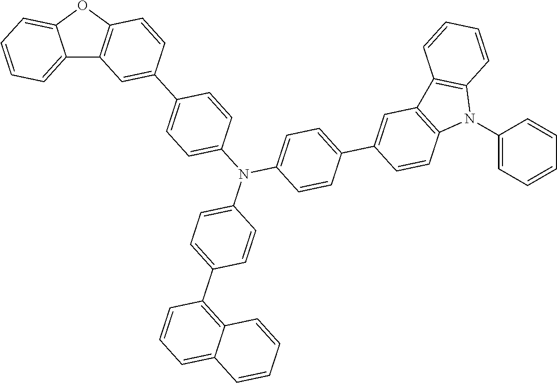 [SMILES: c1ccc(-n2c3ccccc3c3cc(-c4ccc(N(c5ccc(-c6ccc7oc8ccccc8c7c6)cc5)c5ccc(-c6cccc7ccccc67)cc5)cc4)ccc32)cc1]

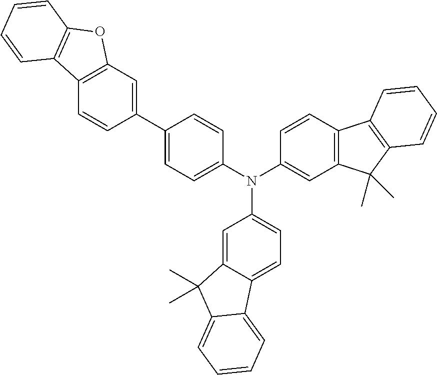 [SMILES: CC1(C)c2ccccc2-c2ccc(N(c3ccc(-c4ccc5c(c4)oc4ccccc45)cc3)c3ccc4c(c3)C(C)(C)c3ccccc3-4)cc21]

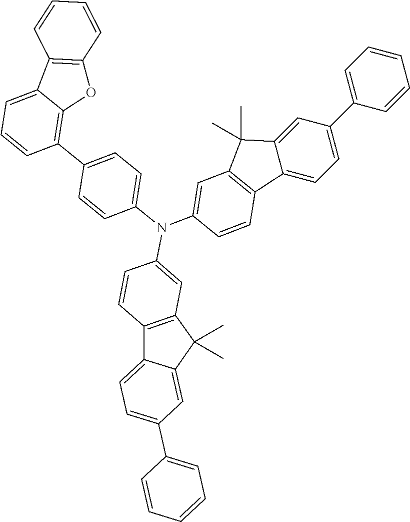 [SMILES: CC1(C)c2cc(-c3ccccc3)ccc2-c2ccc(N(c3ccc(-c4cccc5c4oc4ccccc45)cc3)c3ccc4c(c3)C(C)(C)c3cc(-c5ccccc5)ccc3-4)cc21]

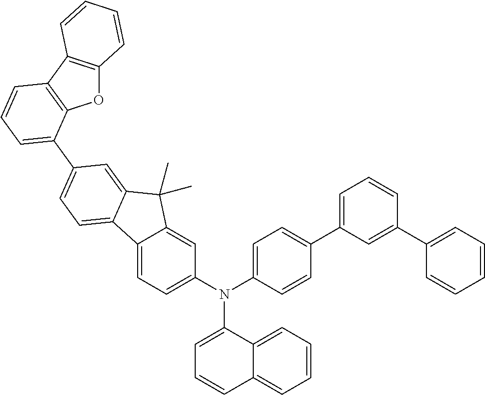 [SMILES: CC1(C)c2cc(-c3cccc4c3oc3ccccc34)ccc2-c2ccc(N(c3ccc(-c4cccc(-c5ccccc5)c4)cc3)c3cccc4ccccc34)cc21]

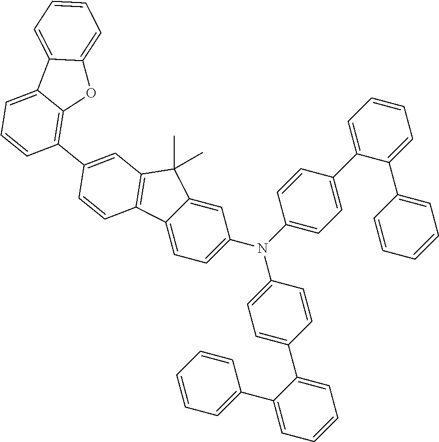 [SMILES: CC1(C)c2cc(-c3cccc4c3oc3ccccc34)ccc2-c2ccc(N(c3ccc(-c4ccccc4-c4ccccc4)cc3)c3ccc(-c4ccccc4-c4ccccc4)cc3)cc21]

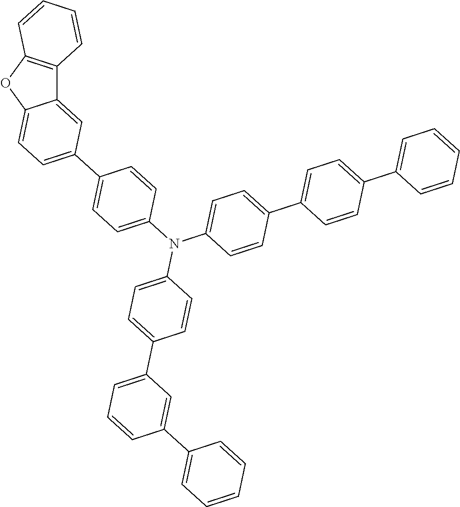 [SMILES: c1ccc(-c2ccc(-c3ccc(N(c4ccc(-c5cccc(-c6ccccc6)c5)cc4)c4ccc(-c5ccc6oc7ccccc7c6c5)cc4)cc3)cc2)cc1]

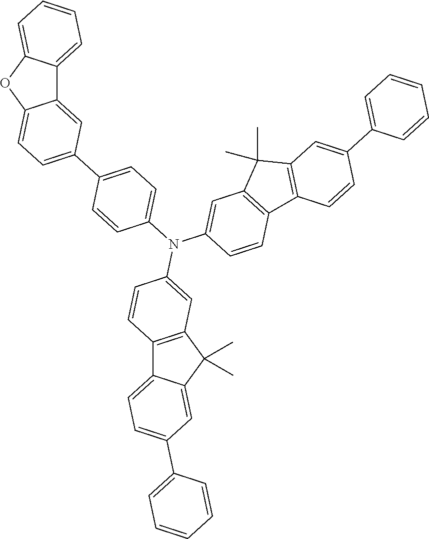 [SMILES: CC1(C)c2cc(-c3ccccc3)ccc2-c2ccc(N(c3ccc(-c4ccc5oc6ccccc6c5c4)cc3)c3ccc4c(c3)C(C)(C)c3cc(-c5ccccc5)ccc3-4)cc21]

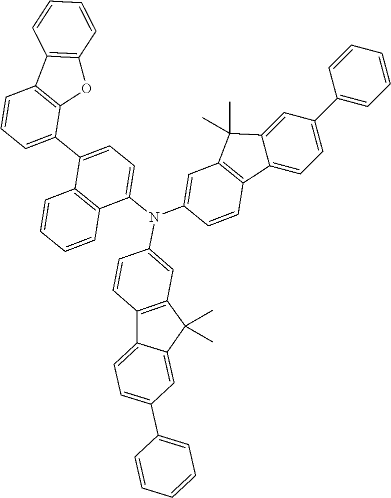 [SMILES: CC1(C)c2cc(-c3ccccc3)ccc2-c2ccc(N(c3ccc4c(c3)C(C)(C)c3cc(-c5ccccc5)ccc3-4)c3ccc(-c4cccc5c4oc4ccccc45)c4ccccc34)cc21]

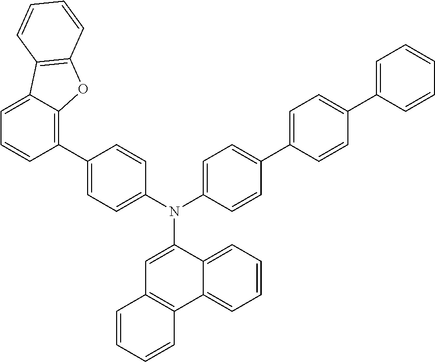 [SMILES: c1ccc(-c2ccc(-c3ccc(N(c4ccc(-c5cccc6c5oc5ccccc56)cc4)c4cc5ccccc5c5ccccc45)cc3)cc2)cc1]

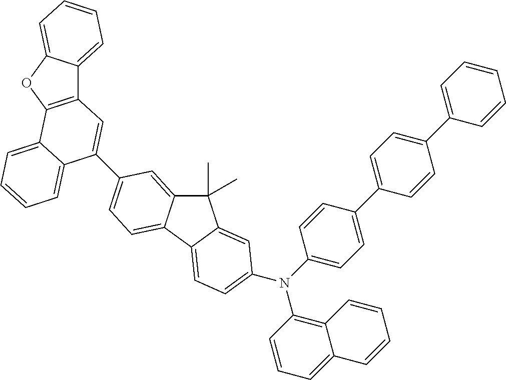 [SMILES: CC1(C)c2cc(-c3cc4c5ccccc5oc4c4ccccc34)ccc2-c2ccc(N(c3ccc(-c4ccc(-c5ccccc5)cc4)cc3)c3cccc4ccccc34)cc21]

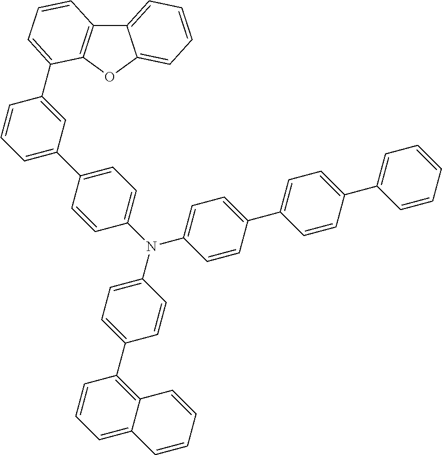 [SMILES: c1ccc(-c2ccc(-c3ccc(N(c4ccc(-c5cccc(-c6cccc7c6oc6ccccc67)c5)cc4)c4ccc(-c5cccc6ccccc56)cc4)cc3)cc2)cc1]

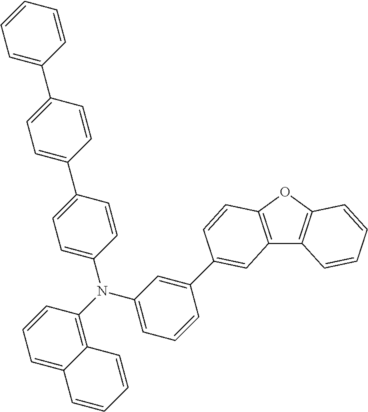 [SMILES: c1ccc(-c2ccc(-c3ccc(N(c4cccc(-c5ccc6oc7ccccc7c6c5)c4)c4cccc5ccccc45)cc3)cc2)cc1]

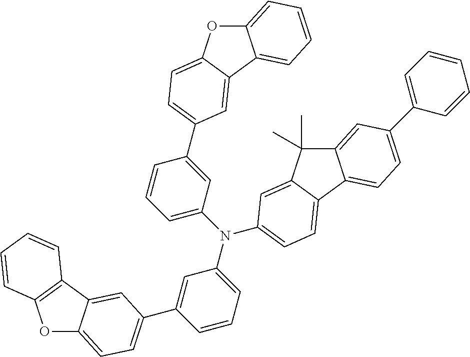 [SMILES: CC1(C)c2cc(-c3ccccc3)ccc2-c2ccc(N(c3cccc(-c4ccc5oc6ccccc6c5c4)c3)c3cccc(-c4ccc5oc6ccccc6c5c4)c3)cc21]

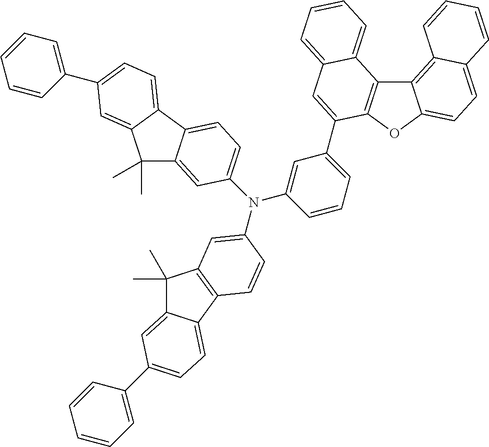 [SMILES: CC1(C)c2cc(-c3ccccc3)ccc2-c2ccc(N(c3cccc(-c4cc5ccccc5c5c4oc4ccc6ccccc6c45)c3)c3ccc4c(c3)C(C)(C)c3cc(-c5ccccc5)ccc3-4)cc21]

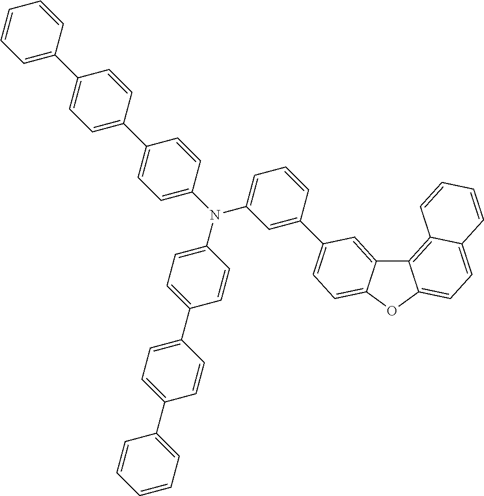 [SMILES: c1ccc(-c2ccc(-c3ccc(N(c4ccc(-c5ccc(-c6ccccc6)cc5)cc4)c4cccc(-c5ccc6oc7ccc8ccccc8c7c6c5)c4)cc3)cc2)cc1]

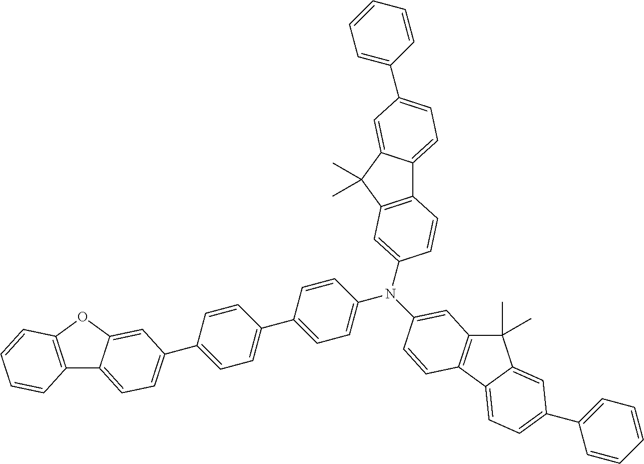 [SMILES: CC1(C)c2cc(-c3ccccc3)ccc2-c2ccc(N(c3ccc(-c4ccc(-c5ccc6c(c5)oc5ccccc56)cc4)cc3)c3ccc4c(c3)C(C)(C)c3cc(-c5ccccc5)ccc3-4)cc21]

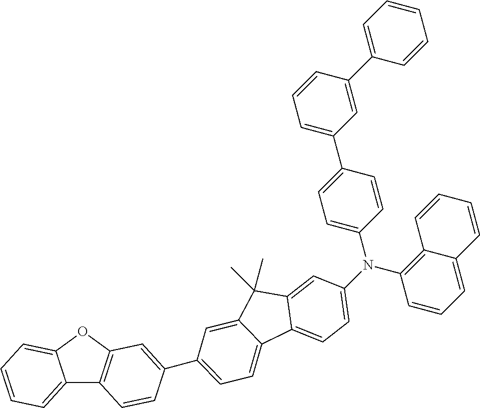 [SMILES: CC1(C)c2cc(-c3ccc4c(c3)oc3ccccc34)ccc2-c2ccc(N(c3ccc(-c4cccc(-c5ccccc5)c4)cc3)c3cccc4ccccc34)cc21]

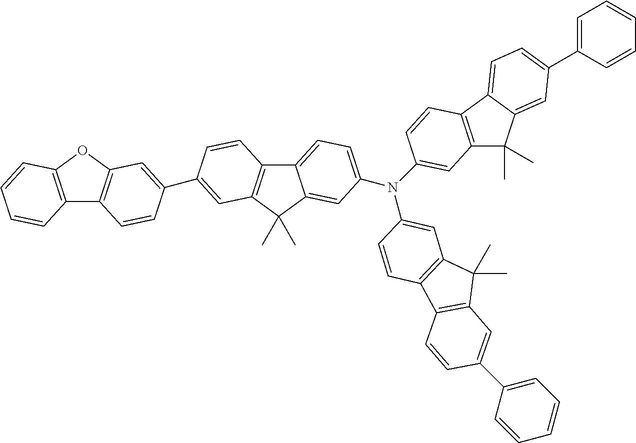 [SMILES: CC1(C)c2cc(-c3ccccc3)ccc2-c2ccc(N(c3ccc4c(c3)C(C)(C)c3cc(-c5ccccc5)ccc3-4)c3ccc4c(c3)C(C)(C)c3cc(-c5ccc6c(c5)oc5ccccc56)ccc3-4)cc21]

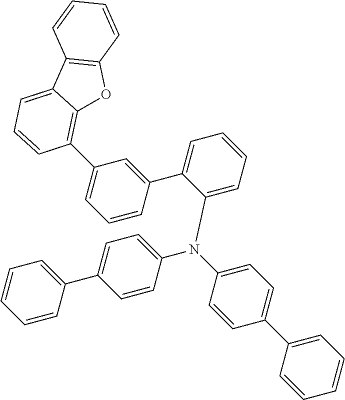 [SMILES: c1ccc(-c2ccc(N(c3ccc(-c4ccccc4)cc3)c3ccccc3-c3cccc(-c4cccc5c4oc4ccccc45)c3)cc2)cc1]

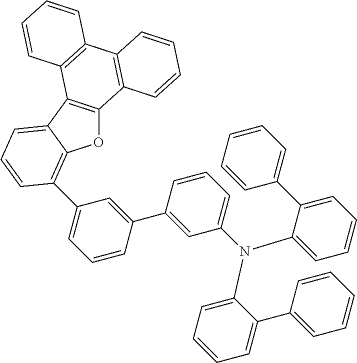 [SMILES: c1ccc(-c2ccccc2N(c2cccc(-c3cccc(-c4cccc5c4oc4c6ccccc6c6ccccc6c54)c3)c2)c2ccccc2-c2ccccc2)cc1]

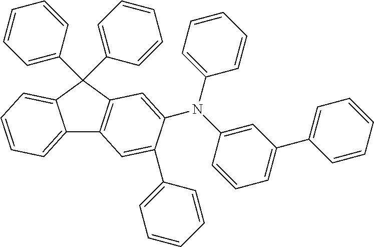 [SMILES: c1ccc(-c2cccc(N(c3ccccc3)c3cc4c(cc3-c3ccccc3)-c3ccccc3C4(c3ccccc3)c3ccccc3)c2)cc1]

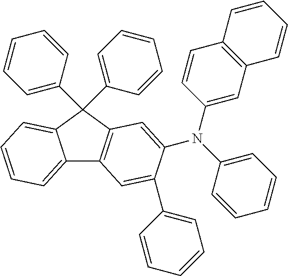 [SMILES: c1ccc(-c2cc3c(cc2N(c2ccccc2)c2ccc4ccccc4c2)C(c2ccccc2)(c2ccccc2)c2ccccc2-3)cc1]

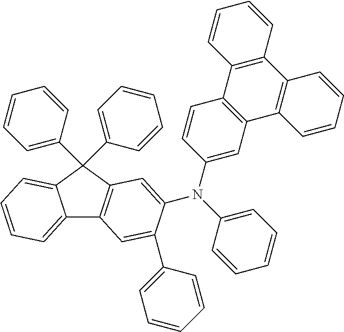 [SMILES: c1ccc(-c2cc3c(cc2N(c2ccccc2)c2ccc4c5ccccc5c5ccccc5c4c2)C(c2ccccc2)(c2ccccc2)c2ccccc2-3)cc1]

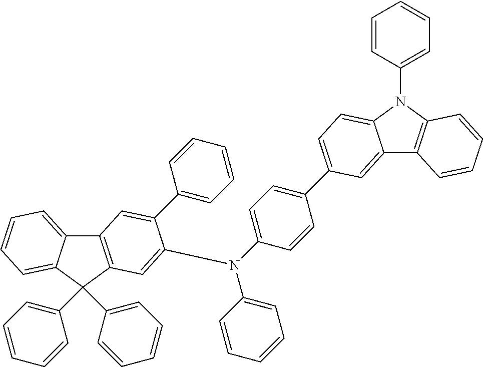 [SMILES: c1ccc(-c2cc3c(cc2N(c2ccccc2)c2ccc(-c4ccc5c(c4)c4ccccc4n5-c4ccccc4)cc2)C(c2ccccc2)(c2ccccc2)c2ccccc2-3)cc1]

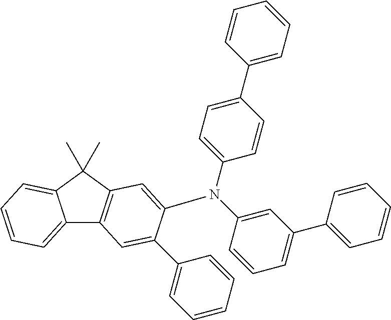 [SMILES: CC1(C)c2ccccc2-c2cc(-c3ccccc3)c(N(c3ccc(-c4ccccc4)cc3)c3cccc(-c4ccccc4)c3)cc21]

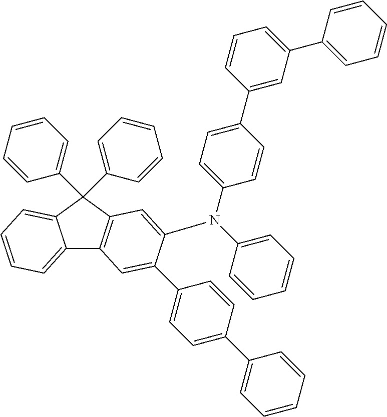 [SMILES: c1ccc(-c2ccc(-c3cc4c(cc3N(c3ccccc3)c3ccc(-c5cccc(-c6ccccc6)c5)cc3)C(c3ccccc3)(c3ccccc3)c3ccccc3-4)cc2)cc1]

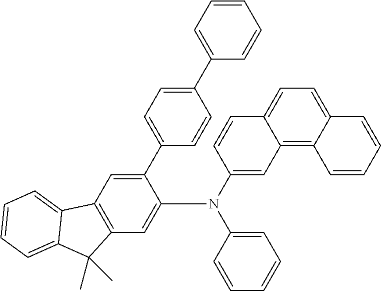 [SMILES: CC1(C)c2ccccc2-c2cc(-c3ccc(-c4ccccc4)cc3)c(N(c3ccccc3)c3ccc4ccc5ccccc5c4c3)cc21]

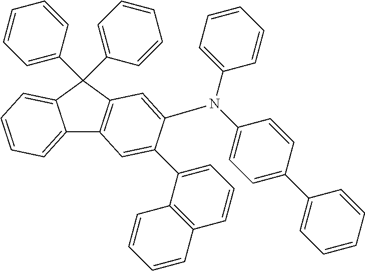 [SMILES: c1ccc(-c2ccc(N(c3ccccc3)c3cc4c(cc3-c3cccc5ccccc35)-c3ccccc3C4(c3ccccc3)c3ccccc3)cc2)cc1]

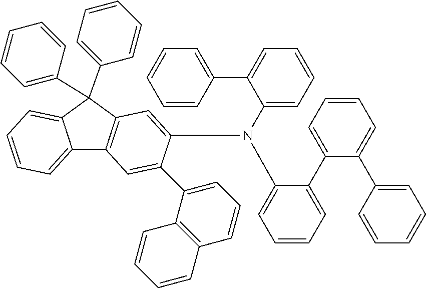 [SMILES: c1ccc(-c2ccccc2-c2ccccc2N(c2ccccc2-c2ccccc2)c2cc3c(cc2-c2cccc4ccccc24)-c2ccccc2C3(c2ccccc2)c2ccccc2)cc1]

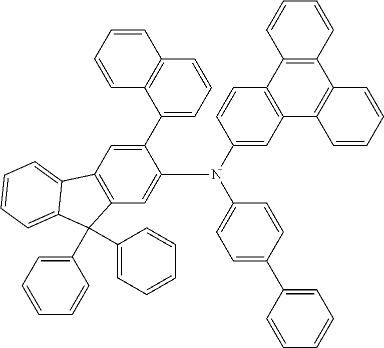 [SMILES: c1ccc(-c2ccc(N(c3ccc4c5ccccc5c5ccccc5c4c3)c3cc4c(cc3-c3cccc5ccccc35)-c3ccccc3C4(c3ccccc3)c3ccccc3)cc2)cc1]

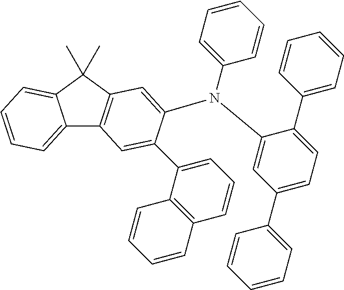 [SMILES: CC1(C)c2ccccc2-c2cc(-c3cccc4ccccc34)c(N(c3ccccc3)c3cc(-c4ccccc4)ccc3-c3ccccc3)cc21]

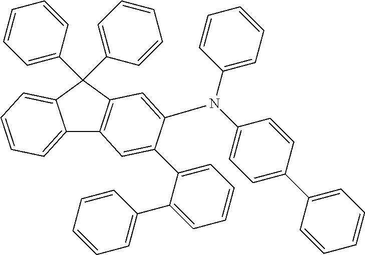 [SMILES: c1ccc(-c2ccc(N(c3ccccc3)c3cc4c(cc3-c3ccccc3-c3ccccc3)-c3ccccc3C4(c3ccccc3)c3ccccc3)cc2)cc1]

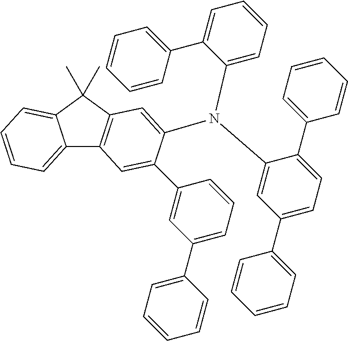 [SMILES: CC1(C)c2ccccc2-c2cc(-c3cccc(-c4ccccc4)c3)c(N(c3ccccc3-c3ccccc3)c3cc(-c4ccccc4)ccc3-c3ccccc3)cc21]

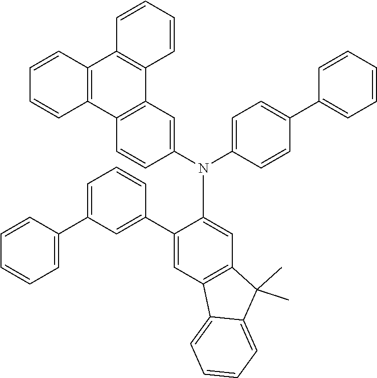 [SMILES: CC1(C)c2ccccc2-c2cc(-c3cccc(-c4ccccc4)c3)c(N(c3ccc(-c4ccccc4)cc3)c3ccc4c5ccccc5c5ccccc5c4c3)cc21]

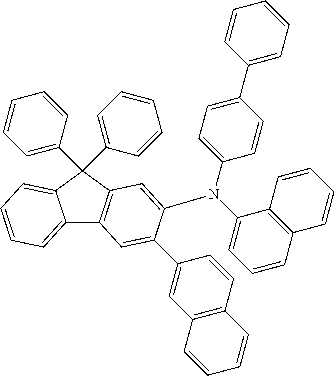 [SMILES: c1ccc(-c2ccc(N(c3cc4c(cc3-c3ccc5ccccc5c3)-c3ccccc3C4(c3ccccc3)c3ccccc3)c3cccc4ccccc34)cc2)cc1]

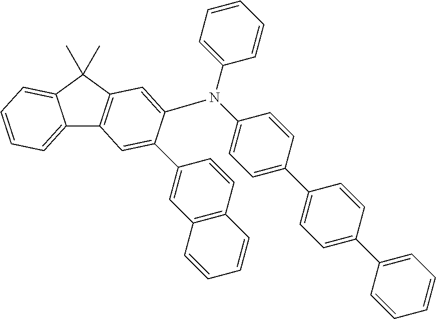 [SMILES: CC1(C)c2ccccc2-c2cc(-c3ccc4ccccc4c3)c(N(c3ccccc3)c3ccc(-c4ccc(-c5ccccc5)cc4)cc3)cc21]

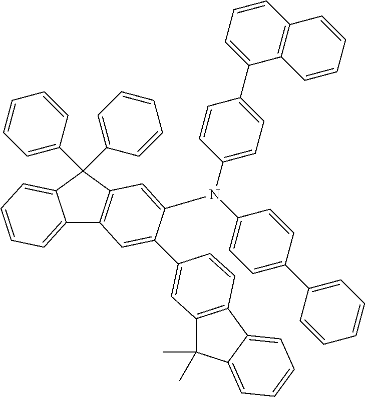 [SMILES: CC1(C)c2ccccc2-c2ccc(-c3cc4c(cc3N(c3ccc(-c5ccccc5)cc3)c3ccc(-c5cccc6ccccc56)cc3)C(c3ccccc3)(c3ccccc3)c3ccccc3-4)cc21]

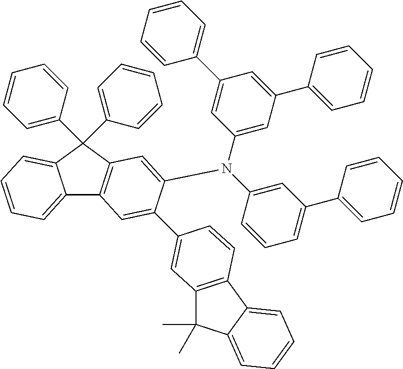 [SMILES: CC1(C)c2ccccc2-c2ccc(-c3cc4c(cc3N(c3cccc(-c5ccccc5)c3)c3cc(-c5ccccc5)cc(-c5ccccc5)c3)C(c3ccccc3)(c3ccccc3)c3ccccc3-4)cc21]

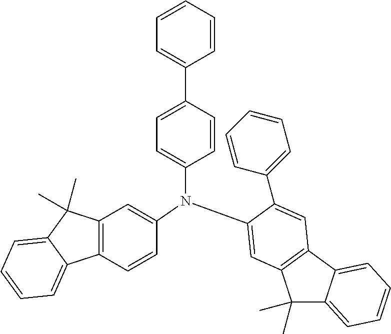 [SMILES: CC1(C)c2ccccc2-c2ccc(N(c3ccc(-c4ccccc4)cc3)c3cc4c(cc3-c3ccccc3)-c3ccccc3C4(C)C)cc21]

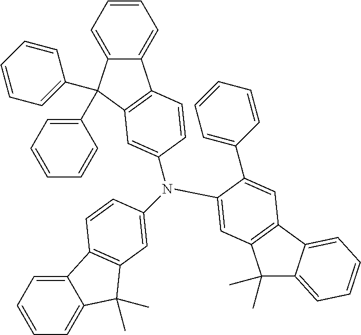 [SMILES: CC1(C)c2ccccc2-c2ccc(N(c3ccc4c(c3)C(c3ccccc3)(c3ccccc3)c3ccccc3-4)c3cc4c(cc3-c3ccccc3)-c3ccccc3C4(C)C)cc21]

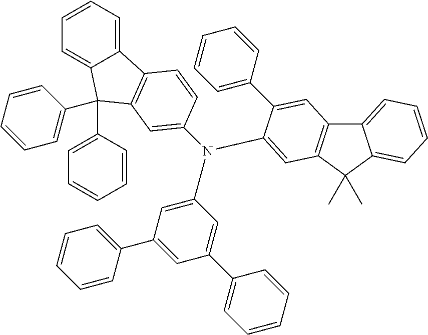 [SMILES: CC1(C)c2ccccc2-c2cc(-c3ccccc3)c(N(c3cc(-c4ccccc4)cc(-c4ccccc4)c3)c3ccc4c(c3)C(c3ccccc3)(c3ccccc3)c3ccccc3-4)cc21]

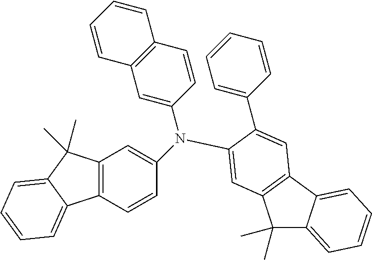 [SMILES: CC1(C)c2ccccc2-c2ccc(N(c3ccc4ccccc4c3)c3cc4c(cc3-c3ccccc3)-c3ccccc3C4(C)C)cc21]

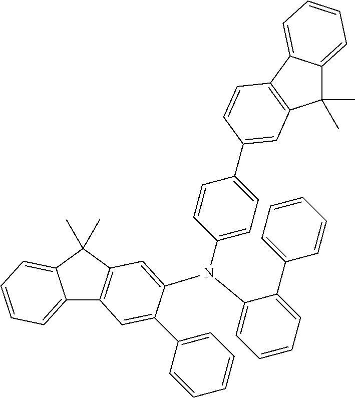 [SMILES: CC1(C)c2ccccc2-c2ccc(-c3ccc(N(c4ccccc4-c4ccccc4)c4cc5c(cc4-c4ccccc4)-c4ccccc4C5(C)C)cc3)cc21]

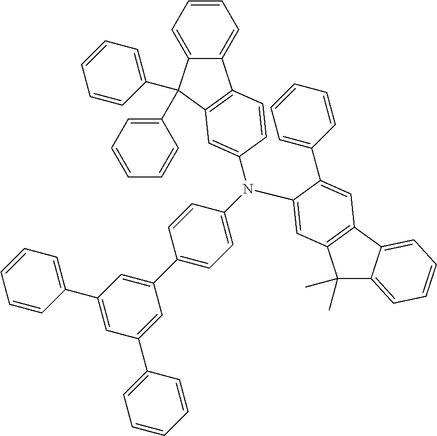 [SMILES: CC1(C)c2ccccc2-c2cc(-c3ccccc3)c(N(c3ccc(-c4cc(-c5ccccc5)cc(-c5ccccc5)c4)cc3)c3ccc4c(c3)C(c3ccccc3)(c3ccccc3)c3ccccc3-4)cc21]

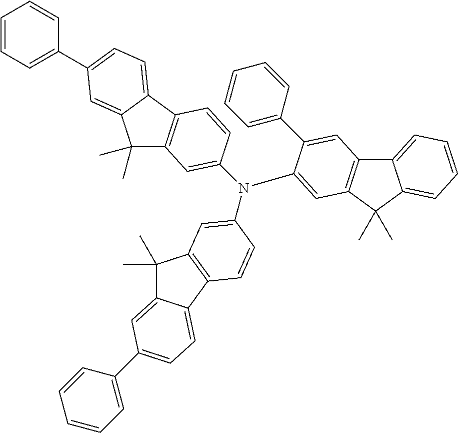 [SMILES: CC1(C)c2cc(-c3ccccc3)ccc2-c2ccc(N(c3ccc4c(c3)C(C)(C)c3cc(-c5ccccc5)ccc3-4)c3cc4c(cc3-c3ccccc3)-c3ccccc3C4(C)C)cc21]

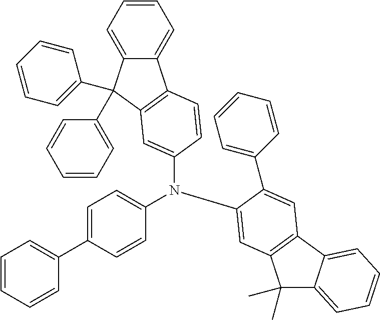 [SMILES: CC1(C)c2ccccc2-c2cc(-c3ccccc3)c(N(c3ccc(-c4ccccc4)cc3)c3ccc4c(c3)C(c3ccccc3)(c3ccccc3)c3ccccc3-4)cc21]

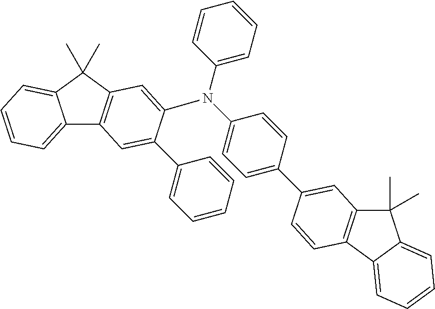 [SMILES: CC1(C)c2ccccc2-c2ccc(-c3ccc(N(c4ccccc4)c4cc5c(cc4-c4ccccc4)-c4ccccc4C5(C)C)cc3)cc21]

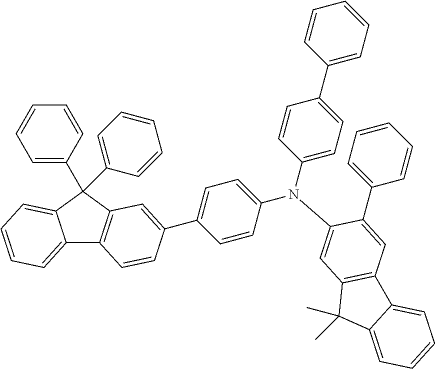 [SMILES: CC1(C)c2ccccc2-c2cc(-c3ccccc3)c(N(c3ccc(-c4ccccc4)cc3)c3ccc(-c4ccc5c(c4)C(c4ccccc4)(c4ccccc4)c4ccccc4-5)cc3)cc21]

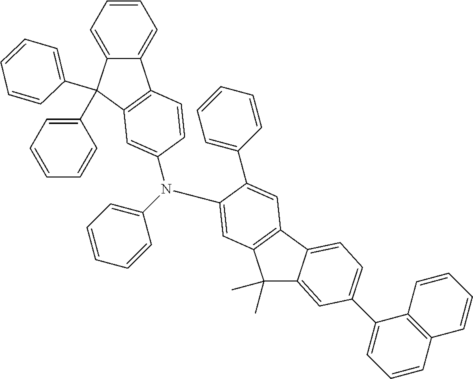 [SMILES: CC1(C)c2cc(-c3cccc4ccccc34)ccc2-c2cc(-c3ccccc3)c(N(c3ccccc3)c3ccc4c(c3)C(c3ccccc3)(c3ccccc3)c3ccccc3-4)cc21]

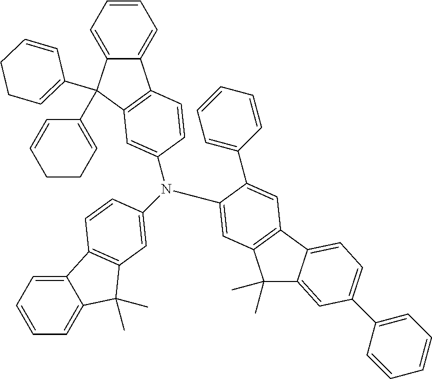 [SMILES: CC1(C)c2ccccc2-c2ccc(N(c3ccc4c(c3)C(C3=CCCC=C3)(C3=CCCC=C3)c3ccccc3-4)c3cc4c(cc3-c3ccccc3)-c3ccc(-c5ccccc5)cc3C4(C)C)cc21]

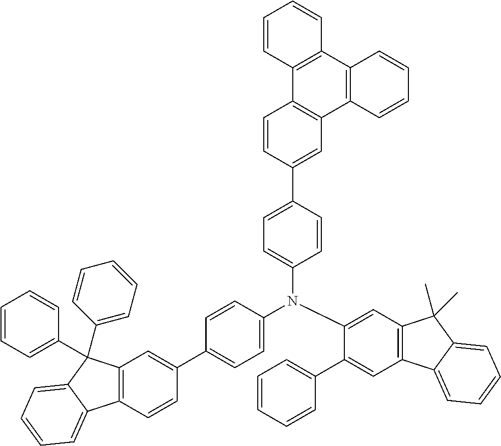 [SMILES: CC1(C)c2ccccc2-c2cc(-c3ccccc3)c(N(c3ccc(-c4ccc5c(c4)C(c4ccccc4)(c4ccccc4)c4ccccc4-5)cc3)c3ccc(-c4ccc5c6ccccc6c6ccccc6c5c4)cc3)cc21]

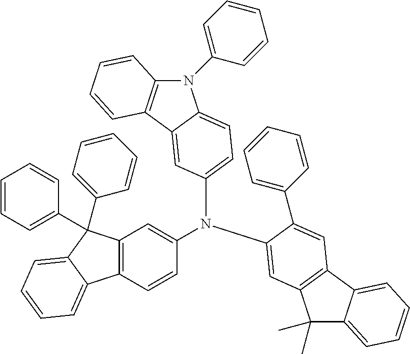 [SMILES: CC1(C)c2ccccc2-c2cc(-c3ccccc3)c(N(c3ccc4c(c3)C(c3ccccc3)(c3ccccc3)c3ccccc3-4)c3ccc4c(c3)c3ccccc3n4-c3ccccc3)cc21]

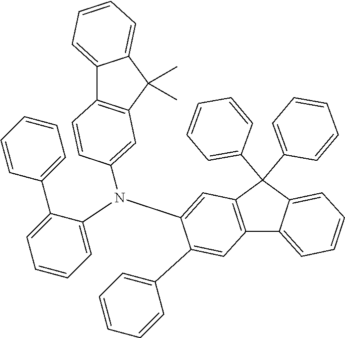 [SMILES: CC1(C)c2ccccc2-c2ccc(N(c3ccccc3-c3ccccc3)c3cc4c(cc3-c3ccccc3)-c3ccccc3C4(c3ccccc3)c3ccccc3)cc21]

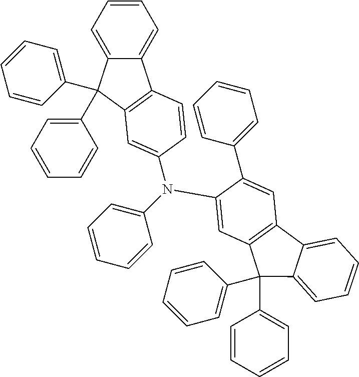 [SMILES: c1ccc(-c2cc3c(cc2N(c2ccccc2)c2ccc4c(c2)C(c2ccccc2)(c2ccccc2)c2ccccc2-4)C(c2ccccc2)(c2ccccc2)c2ccccc2-3)cc1]

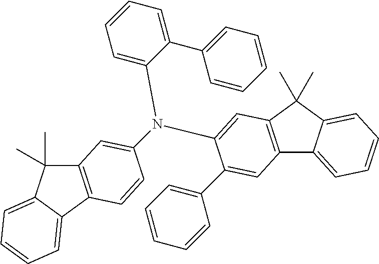 [SMILES: CC1(C)c2ccccc2-c2ccc(N(c3ccccc3-c3ccccc3)c3cc4c(cc3-c3ccccc3)-c3ccccc3C4(C)C)cc21]

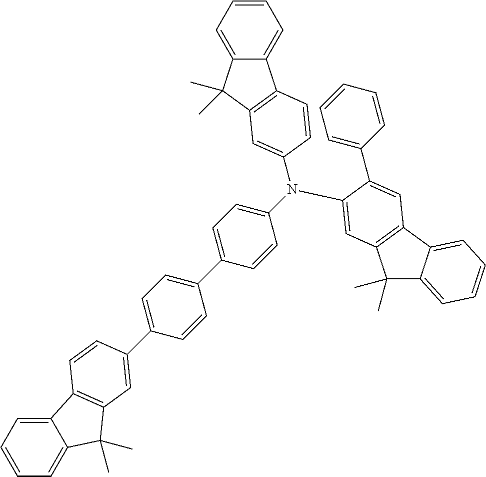 [SMILES: CC1(C)c2ccccc2-c2ccc(-c3ccc(-c4ccc(N(c5ccc6c(c5)C(C)(C)c5ccccc5-6)c5cc6c(cc5-c5ccccc5)-c5ccccc5C6(C)C)cc4)cc3)cc21]

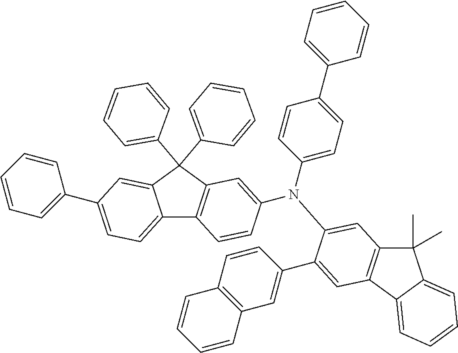 [SMILES: CC1(C)c2ccccc2-c2cc(-c3ccc4ccccc4c3)c(N(c3ccc(-c4ccccc4)cc3)c3ccc4c(c3)C(c3ccccc3)(c3ccccc3)c3cc(-c5ccccc5)ccc3-4)cc21]

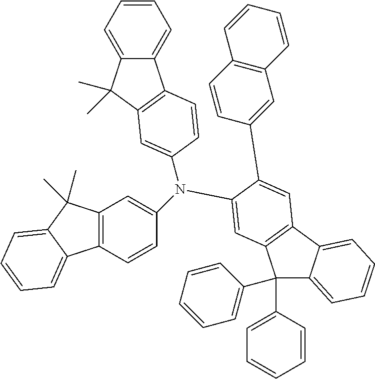 [SMILES: CC1(C)c2ccccc2-c2ccc(N(c3ccc4c(c3)C(C)(C)c3ccccc3-4)c3cc4c(cc3-c3ccc5ccccc5c3)-c3ccccc3C4(c3ccccc3)c3ccccc3)cc21]

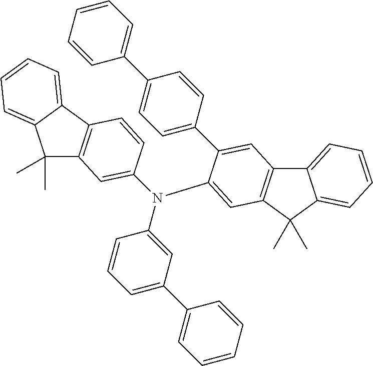 [SMILES: CC1(C)c2ccccc2-c2ccc(N(c3cccc(-c4ccccc4)c3)c3cc4c(cc3-c3ccc(-c5ccccc5)cc3)-c3ccccc3C4(C)C)cc21]

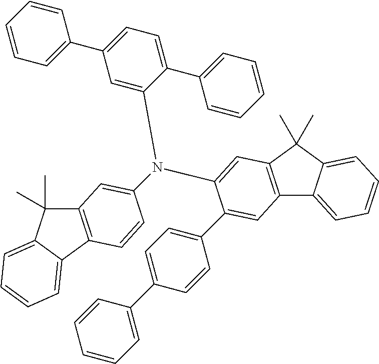 [SMILES: CC1(C)c2ccccc2-c2ccc(N(c3cc(-c4ccccc4)ccc3-c3ccccc3)c3cc4c(cc3-c3ccc(-c5ccccc5)cc3)-c3ccccc3C4(C)C)cc21]

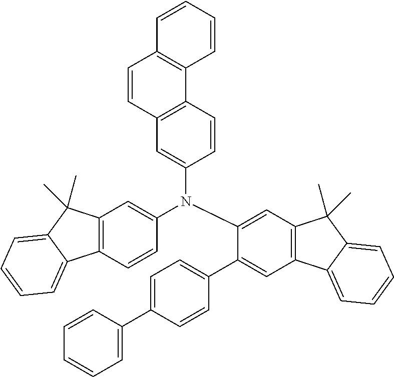 [SMILES: CC1(C)c2ccccc2-c2ccc(N(c3ccc4c(ccc5ccccc54)c3)c3cc4c(cc3-c3ccc(-c5ccccc5)cc3)-c3ccccc3C4(C)C)cc21]

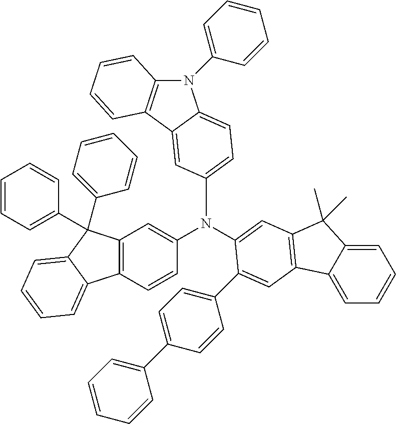 [SMILES: CC1(C)c2ccccc2-c2cc(-c3ccc(-c4ccccc4)cc3)c(N(c3ccc4c(c3)C(c3ccccc3)(c3ccccc3)c3ccccc3-4)c3ccc4c(c3)c3ccccc3n4-c3ccccc3)cc21]

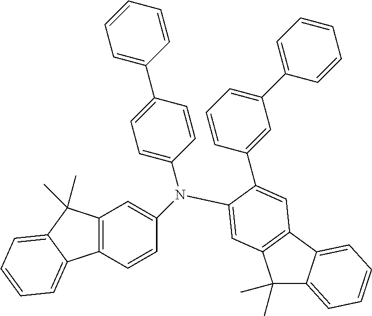 [SMILES: CC1(C)c2ccccc2-c2ccc(N(c3ccc(-c4ccccc4)cc3)c3cc4c(cc3-c3cccc(-c5ccccc5)c3)-c3ccccc3C4(C)C)cc21]

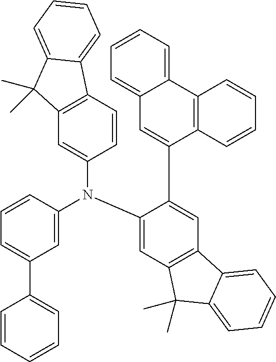 [SMILES: CC1(C)c2ccccc2-c2ccc(N(c3cccc(-c4ccccc4)c3)c3cc4c(cc3-c3cc5ccccc5c5ccccc35)-c3ccccc3C4(C)C)cc21]

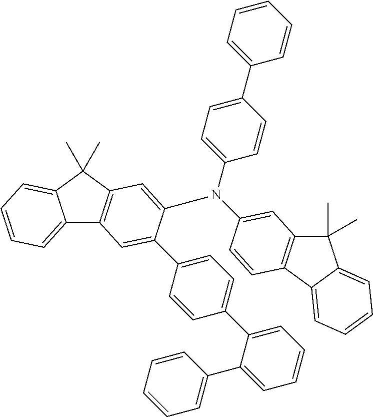 [SMILES: CC1(C)c2ccccc2-c2ccc(N(c3ccc(-c4ccccc4)cc3)c3cc4c(cc3-c3ccc(-c5ccccc5-c5ccccc5)cc3)-c3ccccc3C4(C)C)cc21]

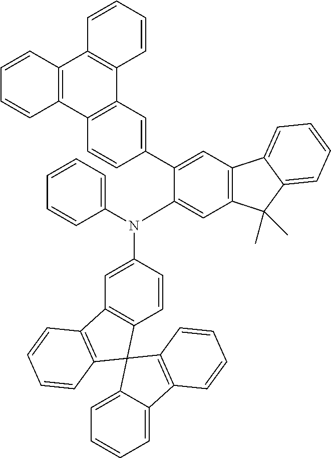 [SMILES: CC1(C)c2ccccc2-c2cc(-c3ccc4c5ccccc5c5ccccc5c4c3)c(N(c3ccccc3)c3ccc4c(c3)-c3ccccc3C43c4ccccc4-c4ccccc43)cc21]

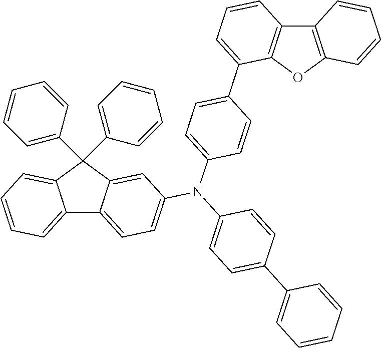 [SMILES: c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

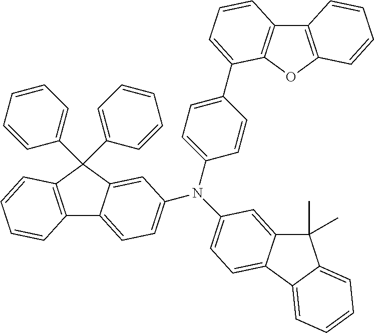 [SMILES: CC1(C)c2ccccc2-c2ccc(N(c3ccc(-c4cccc5c4oc4ccccc45)cc3)c3ccc4c(c3)C(c3ccccc3)(c3ccccc3)c3ccccc3-4)cc21]

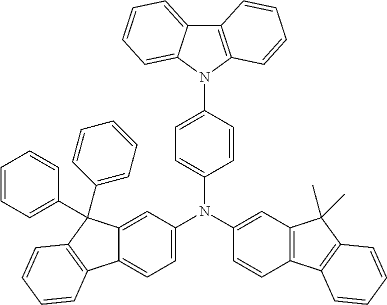 [SMILES: CC1(C)c2ccccc2-c2ccc(N(c3ccc(-n4c5ccccc5c5ccccc54)cc3)c3ccc4c(c3)C(c3ccccc3)(c3ccccc3)c3ccccc3-4)cc21]

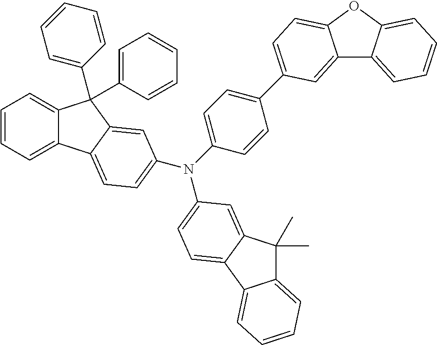 [SMILES: CC1(C)c2ccccc2-c2ccc(N(c3ccc(-c4ccc5oc6ccccc6c5c4)cc3)c3ccc4c(c3)C(c3ccccc3)(c3ccccc3)c3ccccc3-4)cc21]

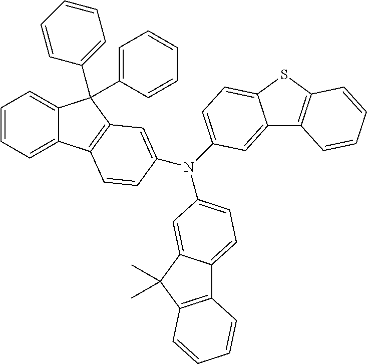 [SMILES: CC1(C)c2ccccc2-c2ccc(N(c3ccc4c(c3)C(c3ccccc3)(c3ccccc3)c3ccccc3-4)c3ccc4sc5ccccc5c4c3)cc21]

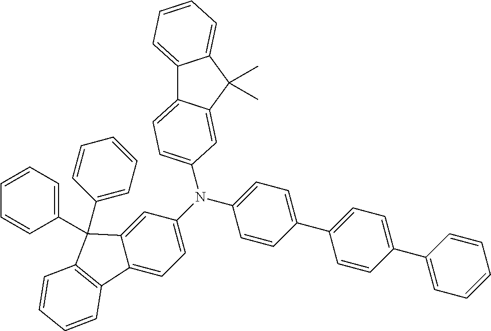 [SMILES: CC1(C)c2ccccc2-c2ccc(N(c3ccc(-c4ccc(-c5ccccc5)cc4)cc3)c3ccc4c(c3)C(c3ccccc3)(c3ccccc3)c3ccccc3-4)cc21]

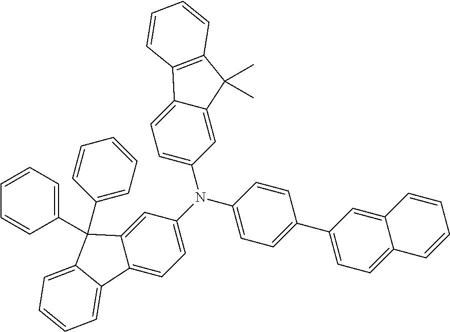 [SMILES: CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21]

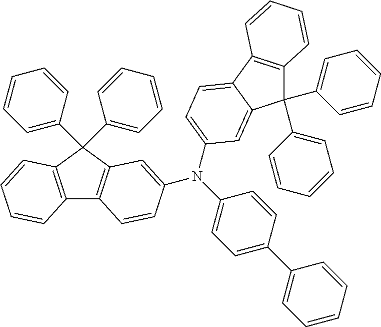 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

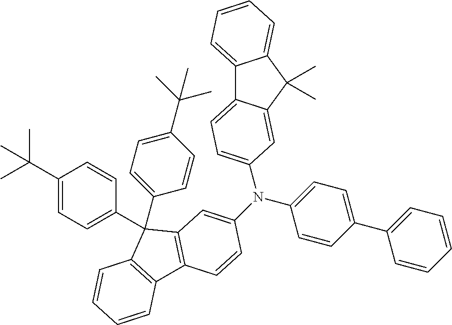 [SMILES: CC(C)(C)c1ccc(C2(c3ccc(C(C)(C)C)cc3)c3ccccc3-c3ccc(N(c4ccc(-c5ccccc5)cc4)c4ccc5c(c4)C(C)(C)c4ccccc4-5)cc32)cc1]

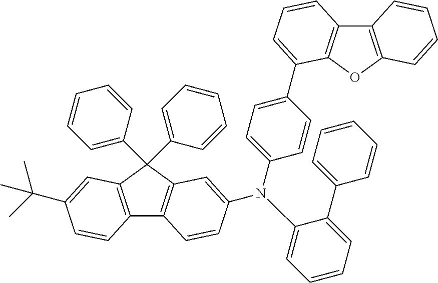 [SMILES: CC(C)(C)c1ccc2c(c1)C(c1ccccc1)(c1ccccc1)c1cc(N(c3ccc(-c4cccc5c4oc4ccccc45)cc3)c3ccccc3-c3ccccc3)ccc1-2]

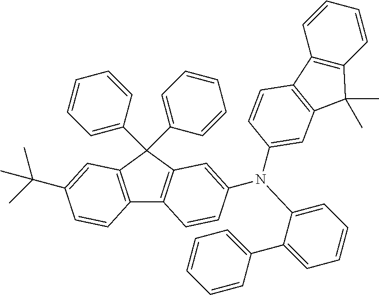 [SMILES: CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2]

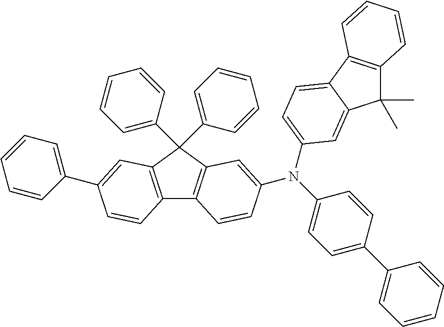 [SMILES: CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21]

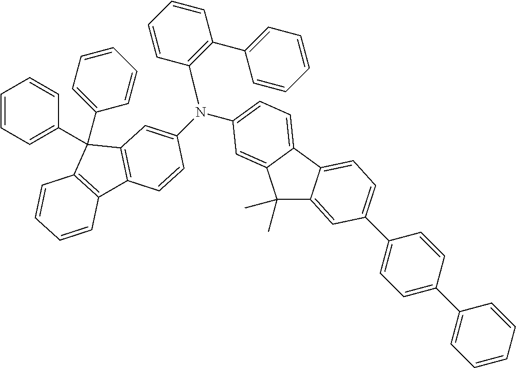 [SMILES: CC1(C)c2cc(-c3ccc(-c4ccccc4)cc3)ccc2-c2ccc(N(c3ccc4c(c3)C(c3ccccc3)(c3ccccc3)c3ccccc3-4)c3ccccc3-c3ccccc3)cc21]

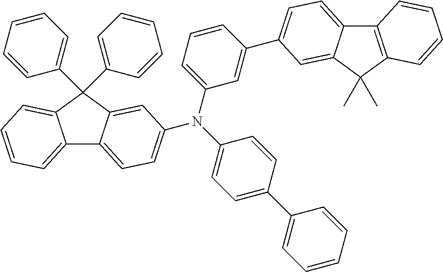 [SMILES: CC1(C)c2ccccc2-c2ccc(-c3cccc(N(c4ccc(-c5ccccc5)cc4)c4ccc5c(c4)C(c4ccccc4)(c4ccccc4)c4ccccc4-5)c3)cc21]

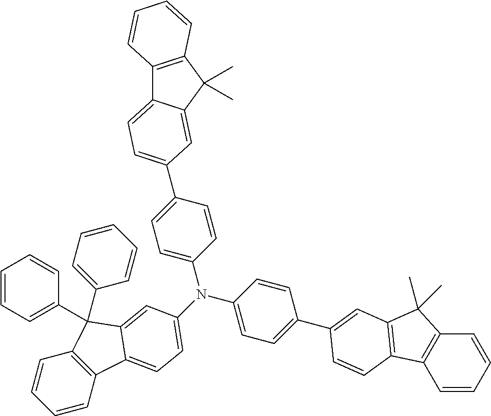 [SMILES: CC1(C)c2ccccc2-c2ccc(-c3ccc(N(c4ccc(-c5ccc6c(c5)C(C)(C)c5ccccc5-6)cc4)c4ccc5c(c4)C(c4ccccc4)(c4ccccc4)c4ccccc4-5)cc3)cc21]

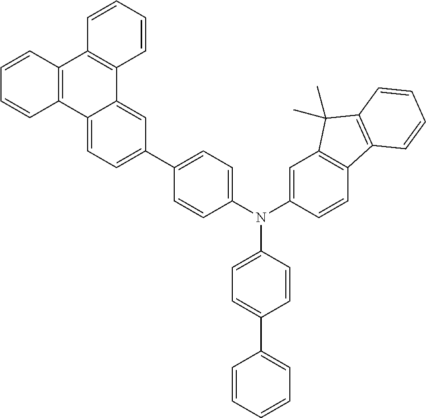 [SMILES: CC1(C)c2ccccc2-c2ccc(N(c3ccc(-c4ccccc4)cc3)c3ccc(-c4ccc5c6ccccc6c6ccccc6c5c4)cc3)cc21]

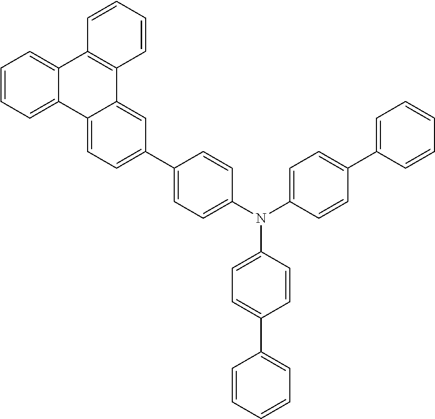 [SMILES: c1ccc(-c2ccc(N(c3ccc(-c4ccccc4)cc3)c3ccc(-c4ccc5c6ccccc6c6ccccc6c5c4)cc3)cc2)cc1]

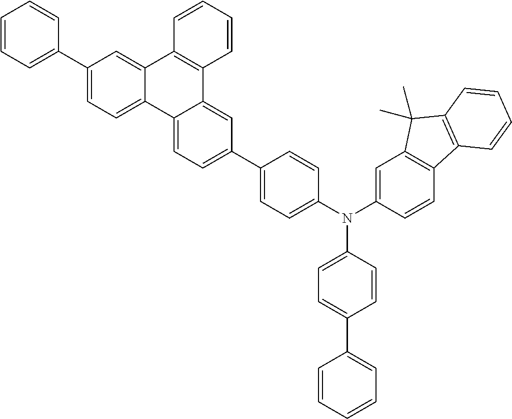 [SMILES: CC1(C)c2ccccc2-c2ccc(N(c3ccc(-c4ccccc4)cc3)c3ccc(-c4ccc5c6ccc(-c7ccccc7)cc6c6ccccc6c5c4)cc3)cc21]

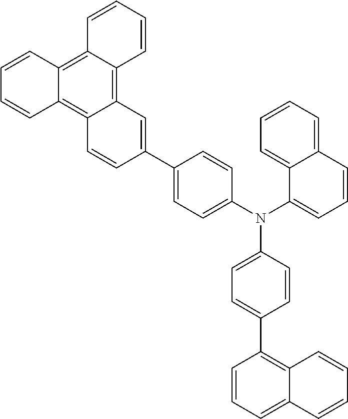 [SMILES: c1ccc2c(-c3ccc(N(c4ccc(-c5ccc6c7ccccc7c7ccccc7c6c5)cc4)c4cccc5ccccc45)cc3)cccc2c1]

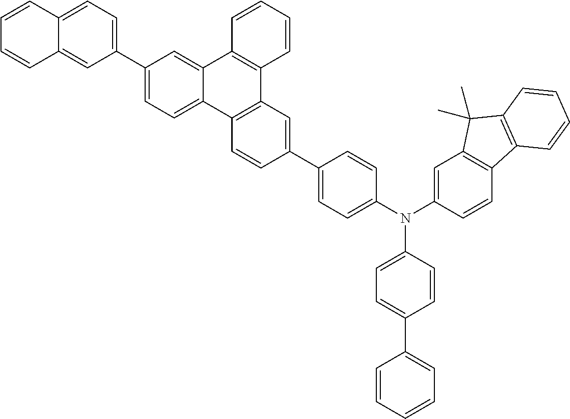 [SMILES: CC1(C)c2ccccc2-c2ccc(N(c3ccc(-c4ccccc4)cc3)c3ccc(-c4ccc5c6ccc(-c7ccc8ccccc8c7)cc6c6ccccc6c5c4)cc3)cc21]

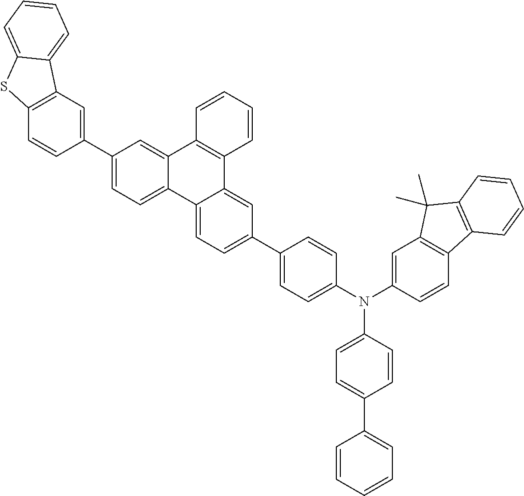 [SMILES: CC1(C)c2ccccc2-c2ccc(N(c3ccc(-c4ccccc4)cc3)c3ccc(-c4ccc5c6ccc(-c7ccc8sc9ccccc9c8c7)cc6c6ccccc6c5c4)cc3)cc21]

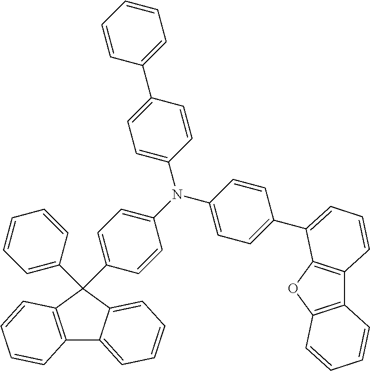 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1]

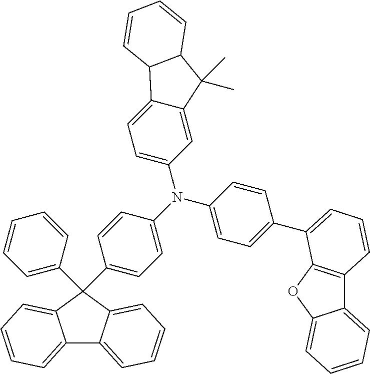 [SMILES: CC1(C)c2cc(N(c3ccc(-c4cccc5c4oc4ccccc45)cc3)c3ccc(C4(c5ccccc5)c5ccccc5-c5ccccc54)cc3)ccc2C2C=CC=CC21]

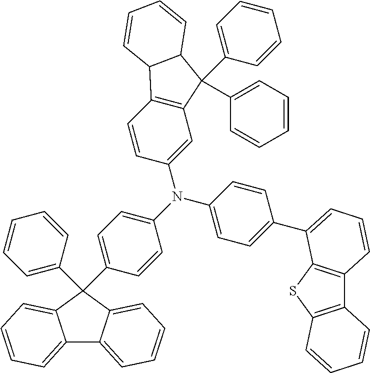 [SMILES: C1=CC2c3ccc(N(c4ccc(-c5cccc6c5sc5ccccc56)cc4)c4ccc(C5(c6ccccc6)c6ccccc6-c6ccccc65)cc4)cc3C(c3ccccc3)(c3ccccc3)C2C=C1]

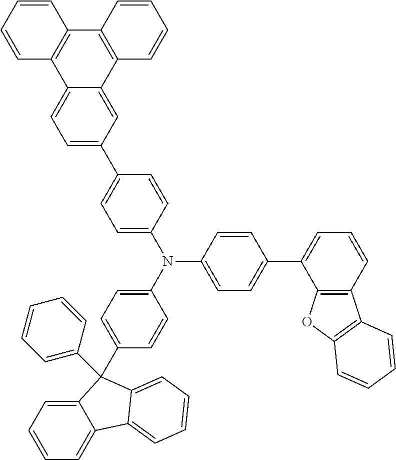 [SMILES: c1ccc(C2(c3ccc(N(c4ccc(-c5ccc6c7ccccc7c7ccccc7c6c5)cc4)c4ccc(-c5cccc6c5oc5ccccc56)cc4)cc3)c3ccccc3-c3ccccc32)cc1]

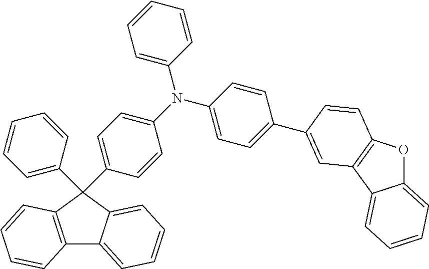 [SMILES: c1ccc(N(c2ccc(-c3ccc4oc5ccccc5c4c3)cc2)c2ccc(C3(c4ccccc4)c4ccccc4-c4ccccc43)cc2)cc1]

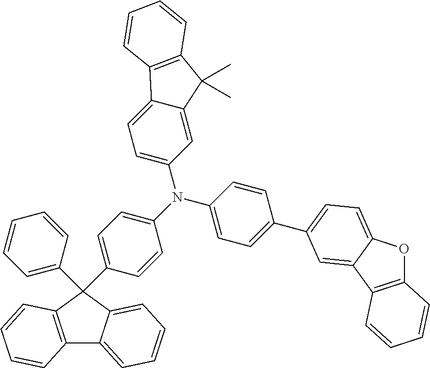 [SMILES: CC1(C)c2ccccc2-c2ccc(N(c3ccc(-c4ccc5oc6ccccc6c5c4)cc3)c3ccc(C4(c5ccccc5)c5ccccc5-c5ccccc54)cc3)cc21]

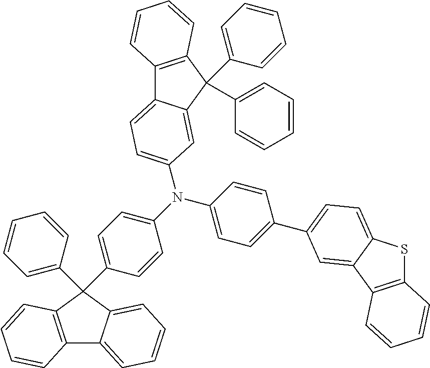 [SMILES: c1ccc(C2(c3ccc(N(c4ccc(-c5ccc6sc7ccccc7c6c5)cc4)c4ccc5c(c4)C(c4ccccc4)(c4ccccc4)c4ccccc4-5)cc3)c3ccccc3-c3ccccc32)cc1]

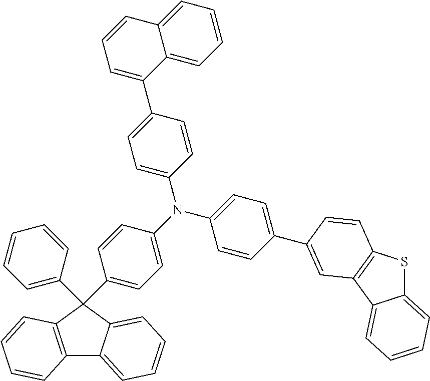 [SMILES: c1ccc(C2(c3ccc(N(c4ccc(-c5ccc6sc7ccccc7c6c5)cc4)c4ccc(-c5cccc6ccccc56)cc4)cc3)c3ccccc3-c3ccccc32)cc1]

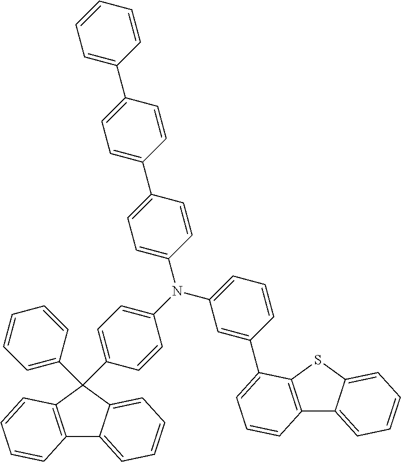 [SMILES: c1ccc(-c2ccc(-c3ccc(N(c4ccc(C5(c6ccccc6)c6ccccc6-c6ccccc65)cc4)c4cccc(-c5cccc6c5sc5ccccc56)c4)cc3)cc2)cc1]

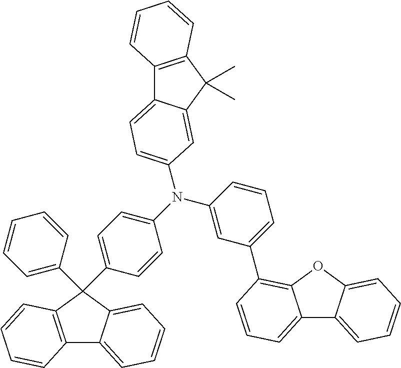 [SMILES: CC1(C)c2ccccc2-c2ccc(N(c3ccc(C4(c5ccccc5)c5ccccc5-c5ccccc54)cc3)c3cccc(-c4cccc5c4oc4ccccc45)c3)cc21]

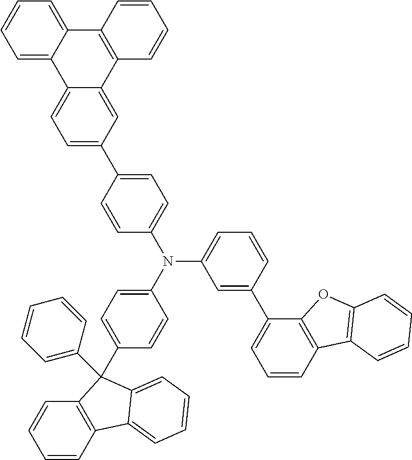 [SMILES: c1ccc(C2(c3ccc(N(c4ccc(-c5ccc6c7ccccc7c7ccccc7c6c5)cc4)c4cccc(-c5cccc6c5oc5ccccc56)c4)cc3)c3ccccc3-c3ccccc32)cc1]

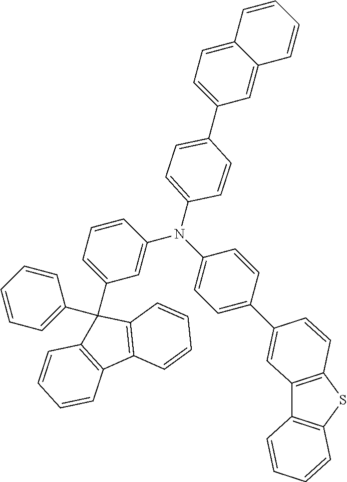 [SMILES: c1ccc(C2(c3cccc(N(c4ccc(-c5ccc6ccccc6c5)cc4)c4ccc(-c5ccc6sc7ccccc7c6c5)cc4)c3)c3ccccc3-c3ccccc32)cc1]

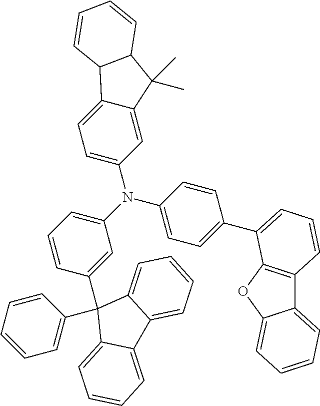 [SMILES: CC1(C)c2cc(N(c3ccc(-c4cccc5c4oc4ccccc45)cc3)c3cccc(C4(c5ccccc5)c5ccccc5-c5ccccc54)c3)ccc2C2C=CC=CC21]

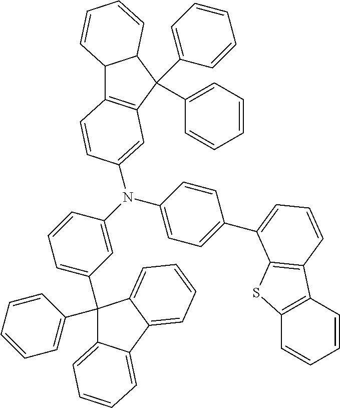 [SMILES: C1=CC2c3ccc(N(c4ccc(-c5cccc6c5sc5ccccc56)cc4)c4cccc(C5(c6ccccc6)c6ccccc6-c6ccccc65)c4)cc3C(c3ccccc3)(c3ccccc3)C2C=C1]

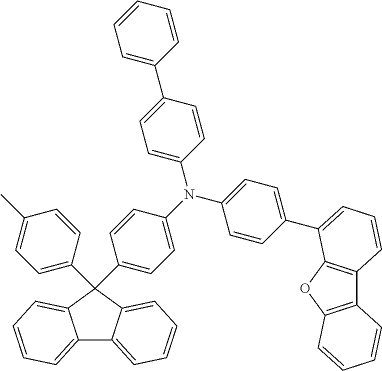 [SMILES: Cc1ccc(C2(c3ccc(N(c4ccc(-c5ccccc5)cc4)c4ccc(-c5cccc6c5oc5ccccc56)cc4)cc3)c3ccccc3-c3ccccc32)cc1]

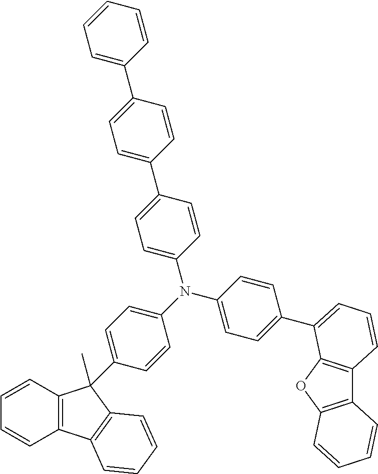 [SMILES: CC1(c2ccc(N(c3ccc(-c4ccc(-c5ccccc5)cc4)cc3)c3ccc(-c4cccc5c4oc4ccccc45)cc3)cc2)c2ccccc2-c2ccccc21]

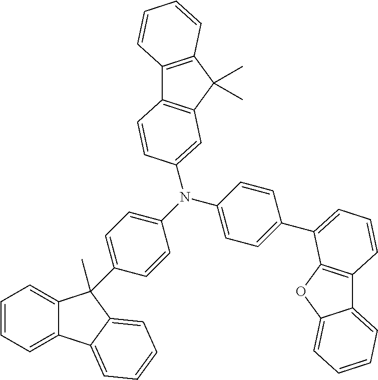 [SMILES: CC1(C)c2ccccc2-c2ccc(N(c3ccc(-c4cccc5c4oc4ccccc45)cc3)c3ccc(C4(C)c5ccccc5-c5ccccc54)cc3)cc21]

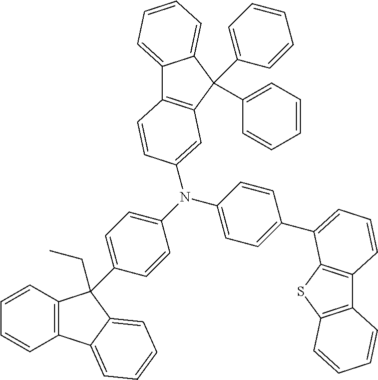 [SMILES: CCC1(c2ccc(N(c3ccc(-c4cccc5c4sc4ccccc45)cc3)c3ccc4c(c3)C(c3ccccc3)(c3ccccc3)c3ccccc3-4)cc2)c2ccccc2-c2ccccc21]

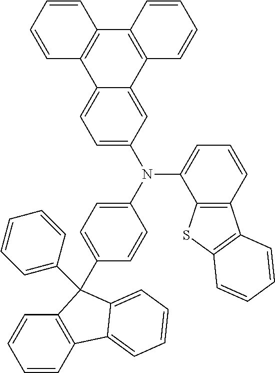 [SMILES: c1ccc(C2(c3ccc(N(c4ccc5c6ccccc6c6ccccc6c5c4)c4cccc5c4sc4ccccc45)cc3)c3ccccc3-c3ccccc32)cc1]

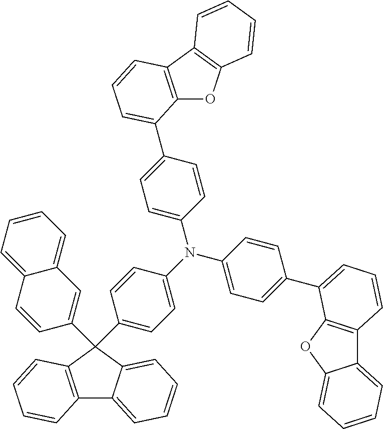 [SMILES: c1ccc2c(c1)-c1ccccc1C2(c1ccc(N(c2ccc(-c3cccc4c3oc3ccccc34)cc2)c2ccc(-c3cccc4c3oc3ccccc34)cc2)cc1)c1ccc2ccccc2c1]

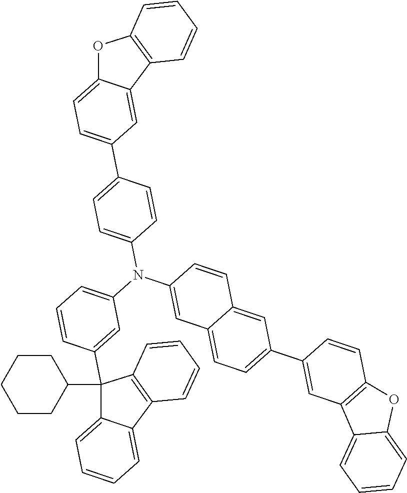 [SMILES: c1cc(N(c2ccc(-c3ccc4oc5ccccc5c4c3)cc2)c2ccc3cc(-c4ccc5oc6ccccc6c5c4)ccc3c2)cc(C2(C3CCCCC3)c3ccccc3-c3ccccc32)c1]

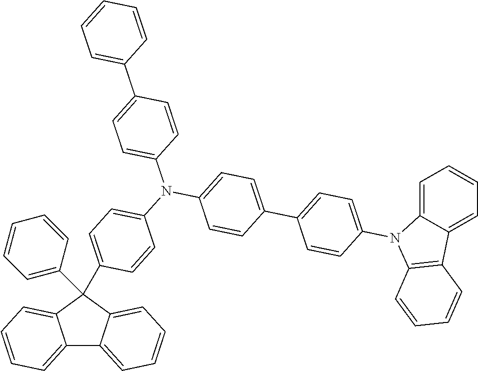 [SMILES: c1ccc(-c2ccc(N(c3ccc(-c4ccc(-n5c6ccccc6c6ccccc65)cc4)cc3)c3ccc(C4(c5ccccc5)c5ccccc5-c5ccccc54)cc3)cc2)cc1]

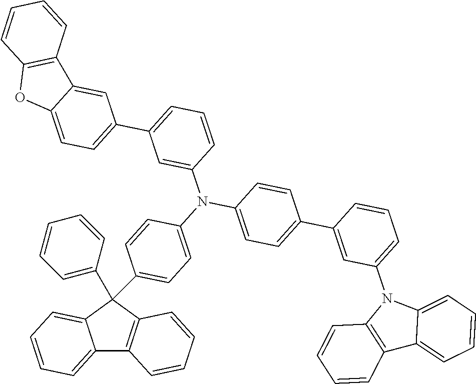 [SMILES: c1ccc(C2(c3ccc(N(c4ccc(-c5cccc(-n6c7ccccc7c7ccccc76)c5)cc4)c4cccc(-c5ccc6oc7ccccc7c6c5)c4)cc3)c3ccccc3-c3ccccc32)cc1]

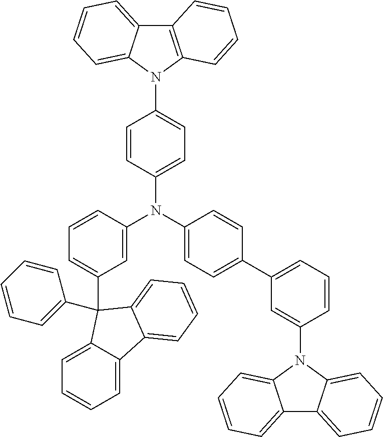 [SMILES: c1ccc(C2(c3cccc(N(c4ccc(-c5cccc(-n6c7ccccc7c7ccccc76)c5)cc4)c4ccc(-n5c6ccccc6c6ccccc65)cc4)c3)c3ccccc3-c3ccccc32)cc1]

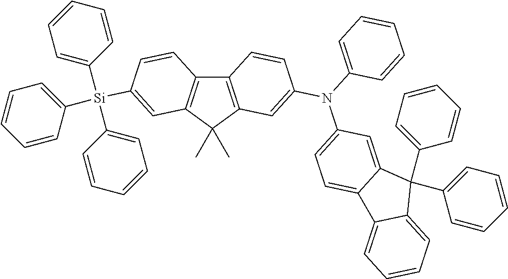 [SMILES: CC1(C)c2cc(N(c3ccccc3)c3ccc4c(c3)C(c3ccccc3)(c3ccccc3)c3ccccc3-4)ccc2-c2ccc([Si](c3ccccc3)(c3ccccc3)c3ccccc3)cc21]

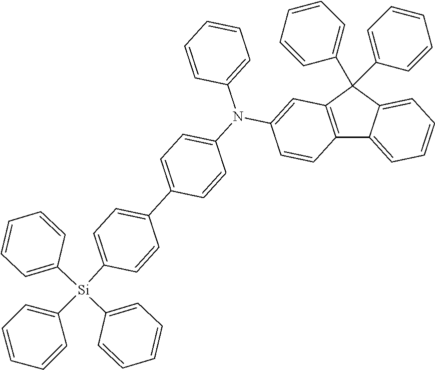 [SMILES: c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1]

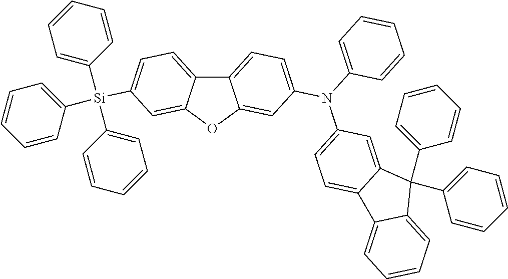 [SMILES: c1ccc(N(c2ccc3c(c2)C(c2ccccc2)(c2ccccc2)c2ccccc2-3)c2ccc3c(c2)oc2cc([Si](c4ccccc4)(c4ccccc4)c4ccccc4)ccc23)cc1]

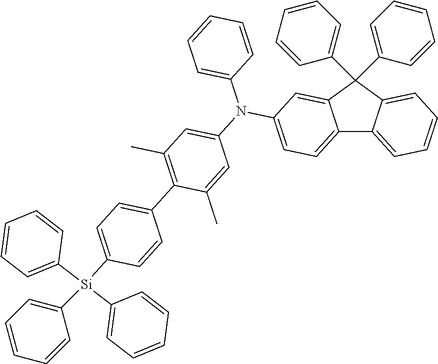 [SMILES: Cc1cc(N(c2ccccc2)c2ccc3c(c2)C(c2ccccc2)(c2ccccc2)c2ccccc2-3)cc(C)c1-c1ccc([Si](c2ccccc2)(c2ccccc2)c2ccccc2)cc1]

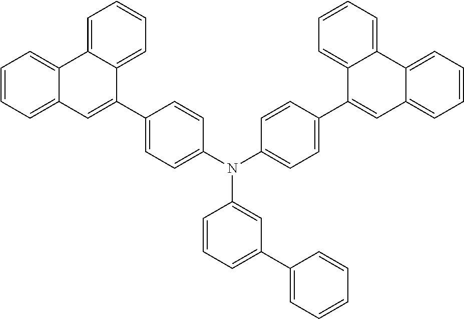 [SMILES: c1ccc(-c2cccc(N(c3ccc(-c4cc5ccccc5c5ccccc45)cc3)c3ccc(-c4cc5ccccc5c5ccccc45)cc3)c2)cc1]

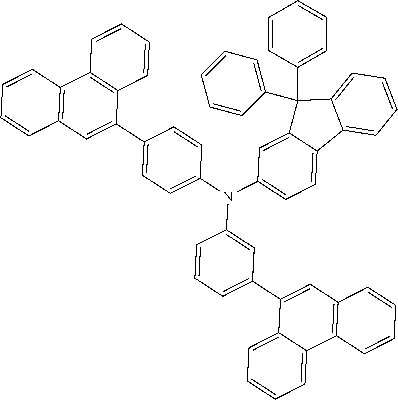 [SMILES: c1ccc(C2(c3ccccc3)c3ccccc3-c3ccc(N(c4ccc(-c5cc6ccccc6c6ccccc56)cc4)c4cccc(-c5cc6ccccc6c6ccccc56)c4)cc32)cc1]

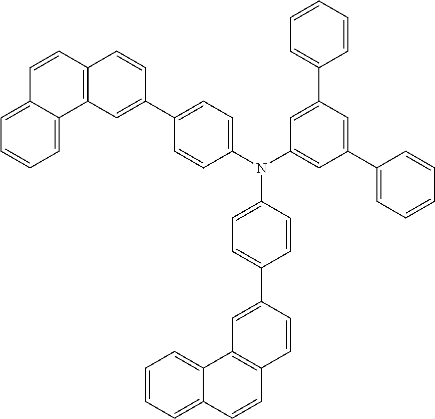 [SMILES: c1ccc(-c2cc(-c3ccccc3)cc(N(c3ccc(-c4ccc5ccc6ccccc6c5c4)cc3)c3ccc(-c4ccc5ccc6ccccc6c5c4)cc3)c2)cc1]

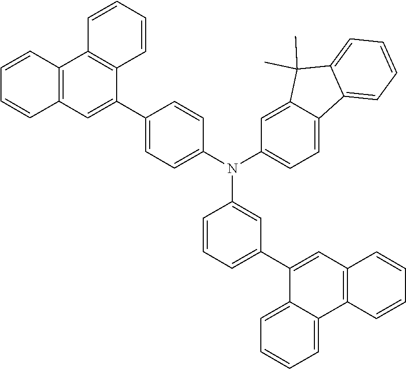 [SMILES: CC1(C)c2ccccc2-c2ccc(N(c3ccc(-c4cc5ccccc5c5ccccc45)cc3)c3cccc(-c4cc5ccccc5c5ccccc45)c3)cc21]

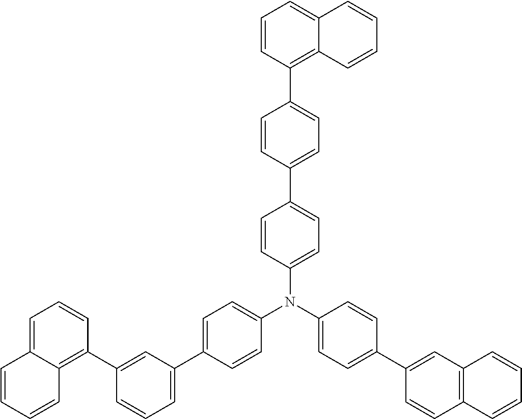 [SMILES: c1cc(-c2ccc(N(c3ccc(-c4ccc(-c5cccc6ccccc56)cc4)cc3)c3ccc(-c4ccc5ccccc5c4)cc3)cc2)cc(-c2cccc3ccccc23)c1]

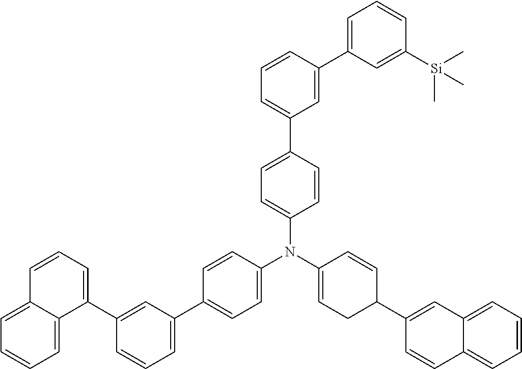 [SMILES: C[Si](C)(C)c1cccc(-c2cccc(-c3ccc(N(C4=CCC(c5ccc6ccccc6c5)C=C4)c4ccc(-c5cccc(-c6cccc7ccccc67)c5)cc4)cc3)c2)c1]

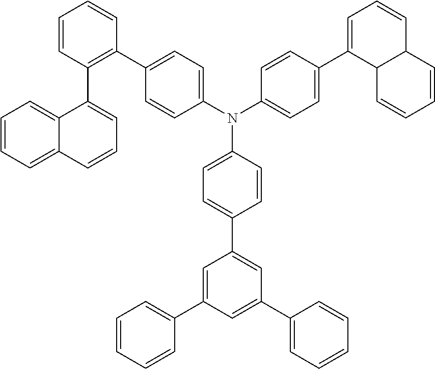 [SMILES: C1=CC2C=CC=C(c3ccc(N(c4ccc(-c5cc(-c6ccccc6)cc(-c6ccccc6)c5)cc4)c4ccc(-c5ccccc5-c5cccc6ccccc56)cc4)cc3)C2C=C1]

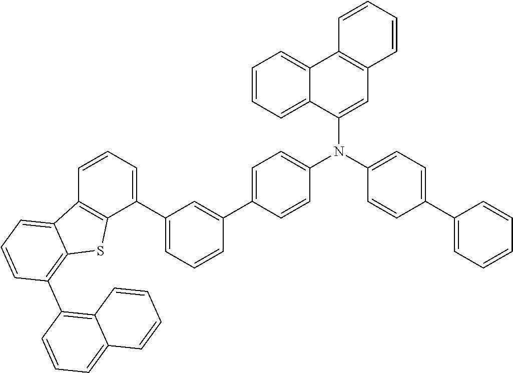 [SMILES: c1ccc(-c2ccc(N(c3ccc(-c4cccc(-c5cccc6c5sc5c(-c7cccc8ccccc78)cccc56)c4)cc3)c3cc4ccccc4c4ccccc34)cc2)cc1]

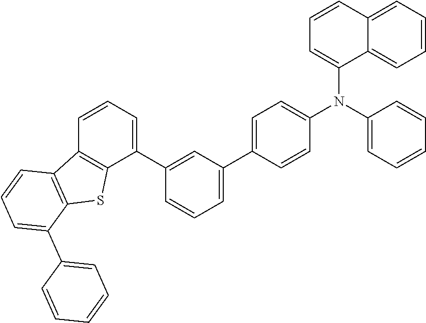 [SMILES: c1ccc(-c2cccc3c2sc2c(-c4cccc(-c5ccc(N(c6ccccc6)c6cccc7ccccc67)cc5)c4)cccc23)cc1]

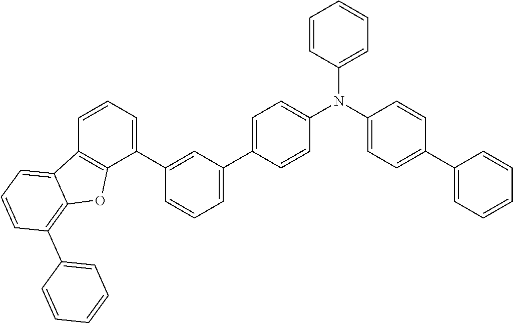 [SMILES: c1ccc(-c2ccc(N(c3ccccc3)c3ccc(-c4cccc(-c5cccc6c5oc5c(-c7ccccc7)cccc56)c4)cc3)cc2)cc1]

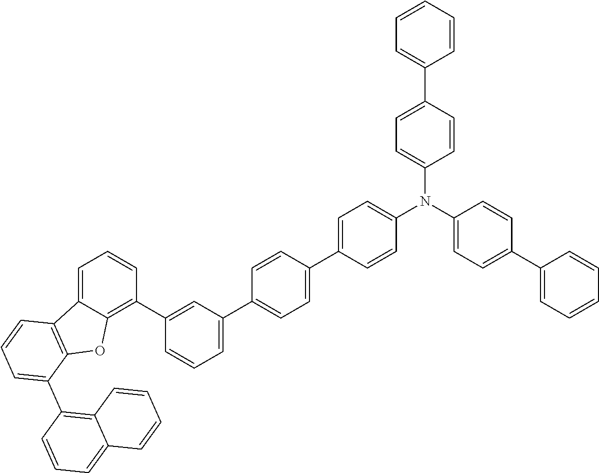 [SMILES: c1ccc(-c2ccc(N(c3ccc(-c4ccccc4)cc3)c3ccc(-c4ccc(-c5cccc(-c6cccc7c6oc6c(-c8cccc9ccccc89)cccc67)c5)cc4)cc3)cc2)cc1]

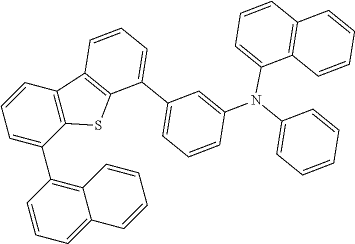 [SMILES: c1ccc(N(c2cccc(-c3cccc4c3sc3c(-c5cccc6ccccc56)cccc34)c2)c2cccc3ccccc23)cc1]

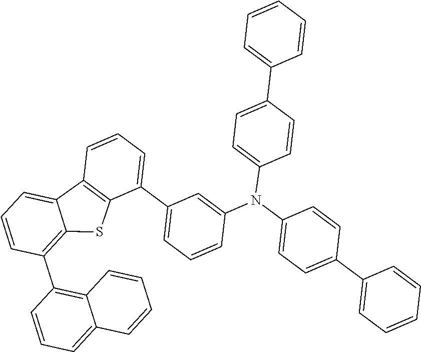 [SMILES: c1ccc(-c2ccc(N(c3ccc(-c4ccccc4)cc3)c3cccc(-c4cccc5c4sc4c(-c6cccc7ccccc67)cccc45)c3)cc2)cc1]

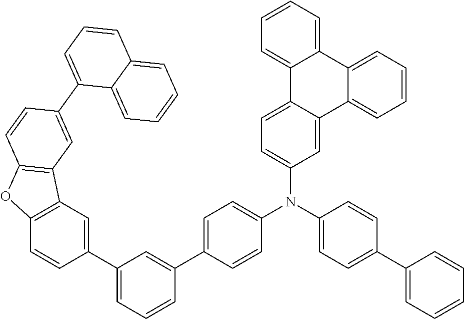 [SMILES: c1ccc(-c2ccc(N(c3ccc(-c4cccc(-c5ccc6oc7ccc(-c8cccc9ccccc89)cc7c6c5)c4)cc3)c3ccc4c5ccccc5c5ccccc5c4c3)cc2)cc1]

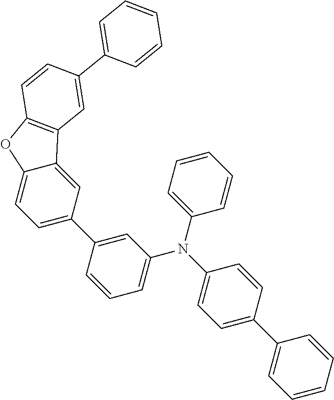 [SMILES: c1ccc(-c2ccc(N(c3ccccc3)c3cccc(-c4ccc5oc6ccc(-c7ccccc7)cc6c5c4)c3)cc2)cc1]

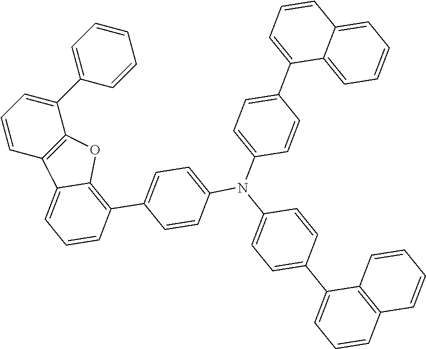 [SMILES: c1ccc(-c2cccc3c2oc2c(-c4ccc(N(c5ccc(-c6cccc7ccccc67)cc5)c5ccc(-c6cccc7ccccc67)cc5)cc4)cccc23)cc1]

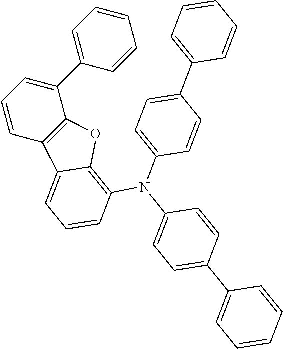 [SMILES: c1ccc(-c2ccc(N(c3ccc(-c4ccccc4)cc3)c3cccc4c3oc3c(-c5ccccc5)cccc34)cc2)cc1]

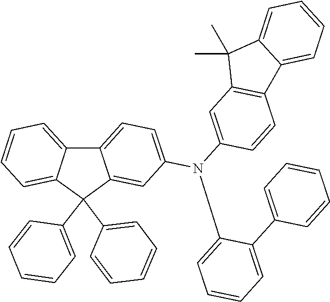 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

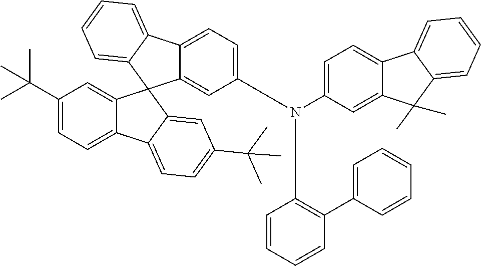 [SMILES: CC(C)(C)c1ccc2c(c1)C1(c3ccccc3-c3ccc(CN(Cc4ccccc4-c4ccccc4)c4ccc5c(c4)C(C)(C)c4ccccc4-5)cc31)c1cc(C(C)(C)C)ccc1-2]

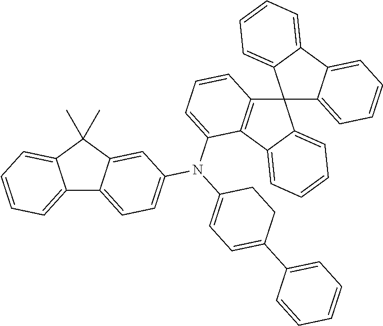 [SMILES: CC1(C)c2ccccc2-c2ccc(N(C3=CC=C(c4ccccc4)CC3)c3cccc4c3-c3ccccc3C43c4ccccc4-c4ccccc43)cc21]

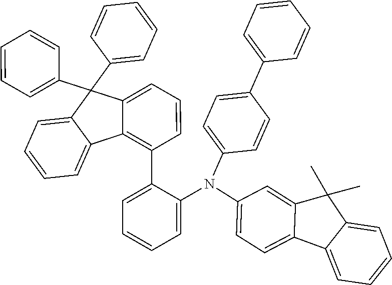 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21]

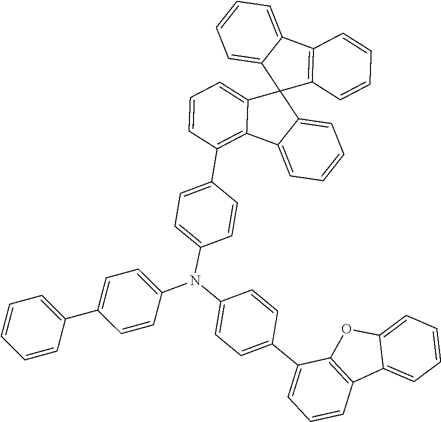 [SMILES: c1ccc(-c2ccc(N(c3ccc(-c4cccc5c4-c4ccccc4C54c5ccccc5-c5ccccc54)cc3)c3ccc(-c4cccc5c4oc4ccccc45)cc3)cc2)cc1]

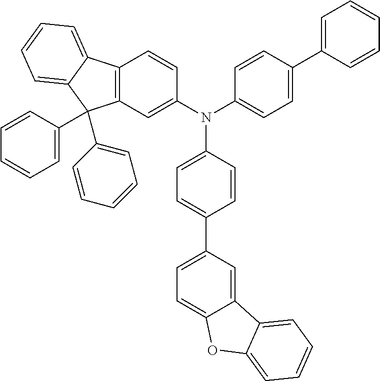 [SMILES: c1ccc(-c2ccc(N(c3ccc(-c4ccc5oc6ccccc6c5c4)cc3)c3ccc4c(c3)C(c3ccccc3)(c3ccccc3)c3ccccc3-4)cc2)cc1]

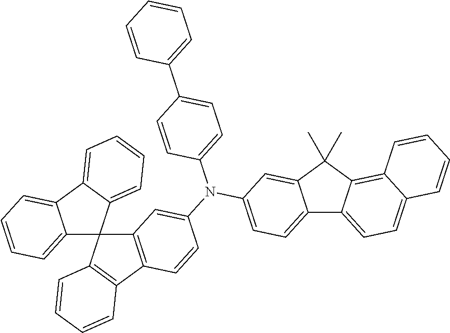 [SMILES: CC1(C)c2cc(N(c3ccc(-c4ccccc4)cc3)c3ccc4c(c3)C3(c5ccccc5-c5ccccc53)c3ccccc3-4)ccc2-c2ccc3ccccc3c21]

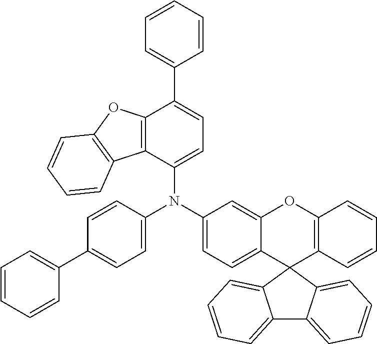 [SMILES: c1ccc(-c2ccc(N(c3ccc4c(c3)Oc3ccccc3C43c4ccccc4-c4ccccc43)c3ccc(-c4ccccc4)c4oc5ccccc5c34)cc2)cc1]

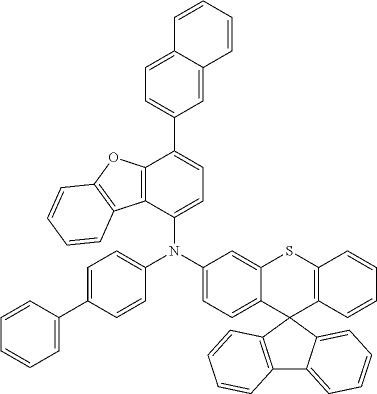 [SMILES: c1ccc(-c2ccc(N(c3ccc4c(c3)Sc3ccccc3C43c4ccccc4-c4ccccc43)c3ccc(-c4ccc5ccccc5c4)c4oc5ccccc5c34)cc2)cc1]

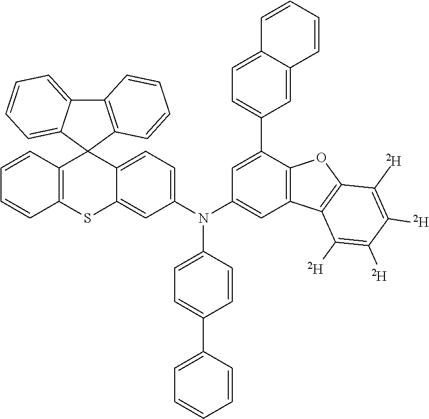 [SMILES: [2H]c1c([2H])c([2H])c2c(oc3c(-c4ccc5ccccc5c4)cc(N(c4ccc(-c5ccccc5)cc4)c4ccc5c(c4)Sc4ccccc4C54c5ccccc5-c5ccccc54)cc32)c1[2H]]

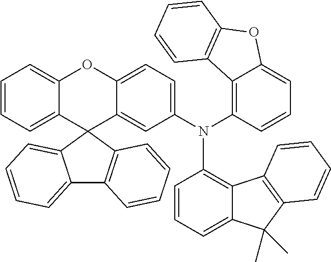 [SMILES: CC1(C)c2ccccc2-c2c(N(c3ccc4c(c3)C3(c5ccccc5O4)c4ccccc4-c4ccccc43)c3cccc4oc5ccccc5c34)cccc21]

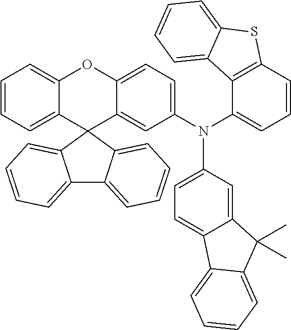 [SMILES: CC1(C)c2ccccc2-c2ccc(N(c3ccc4c(c3)C3(c5ccccc5O4)c4ccccc4-c4ccccc43)c3cccc4sc5ccccc5c34)cc21]

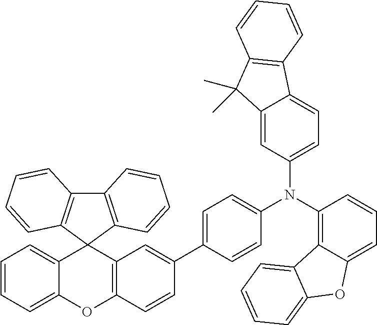 [SMILES: CC1(C)c2ccccc2-c2ccc(N(c3ccc(-c4ccc5c(c4)C4(c6ccccc6O5)c5ccccc5-c5ccccc54)cc3)c3cccc4oc5ccccc5c34)cc21]

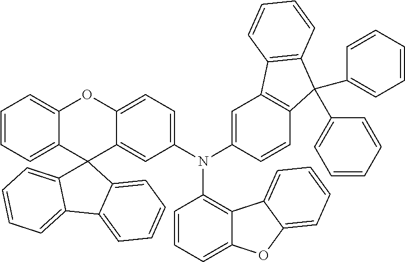 [SMILES: c1ccc(C2(c3ccccc3)c3ccccc3-c3cc(N(c4ccc5c(c4)C4(c6ccccc6O5)c5ccccc5-c5ccccc54)c4cccc5oc6ccccc6c45)ccc32)cc1]

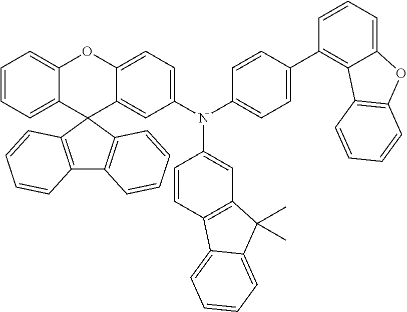 [SMILES: CC1(C)c2ccccc2-c2ccc(N(c3ccc(-c4cccc5oc6ccccc6c45)cc3)c3ccc4c(c3)C3(c5ccccc5O4)c4ccccc4-c4ccccc43)cc21]

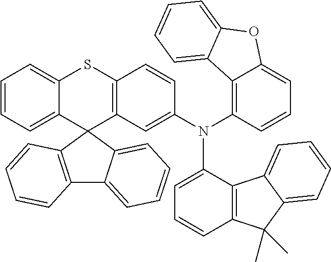 [SMILES: CC1(C)c2ccccc2-c2c(N(c3ccc4c(c3)C3(c5ccccc5S4)c4ccccc4-c4ccccc43)c3cccc4oc5ccccc5c34)cccc21]

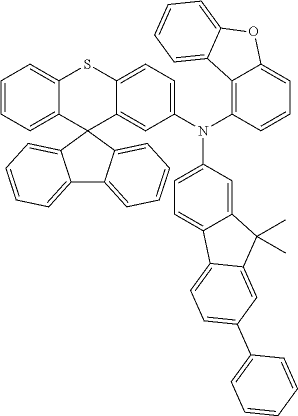 [SMILES: CC1(C)c2cc(-c3ccccc3)ccc2-c2ccc(N(c3ccc4c(c3)C3(c5ccccc5S4)c4ccccc4-c4ccccc43)c3cccc4oc5ccccc5c34)cc21]

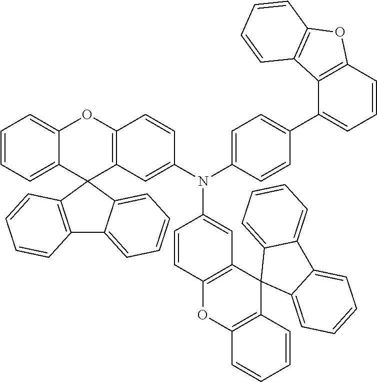 [SMILES: c1ccc2c(c1)Oc1ccc(N(c3ccc(-c4cccc5oc6ccccc6c45)cc3)c3ccc4c(c3)C3(c5ccccc5O4)c4ccccc4-c4ccccc43)cc1C21c2ccccc2-c2ccccc21]

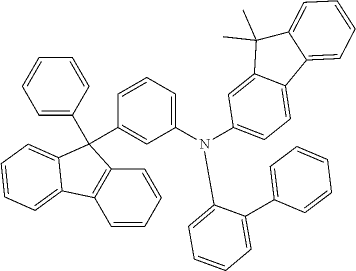 [SMILES: CC1(C)c2ccccc2-c2ccc(N(c3cccc(C4(c5ccccc5)c5ccccc5-c5ccccc54)c3)c3ccccc3-c3ccccc3)cc21]

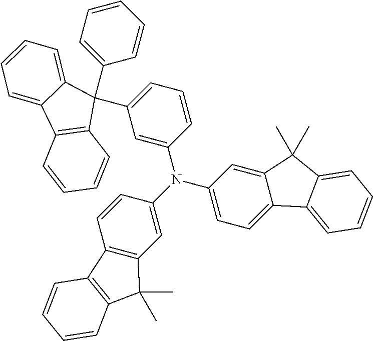 [SMILES: CC1(C)c2ccccc2-c2ccc(N(c3cccc(C4(c5ccccc5)c5ccccc5-c5ccccc54)c3)c3ccc4c(c3)C(C)(C)c3ccccc3-4)cc21]

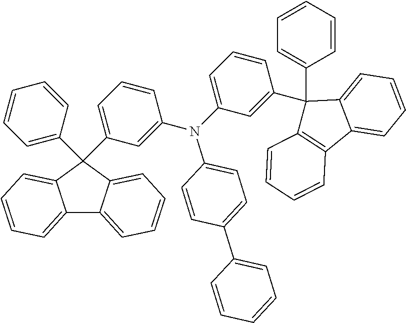 [SMILES: c1ccc(-c2ccc(N(c3cccc(C4(c5ccccc5)c5ccccc5-c5ccccc54)c3)c3cccc(C4(c5ccccc5)c5ccccc5-c5ccccc54)c3)cc2)cc1]

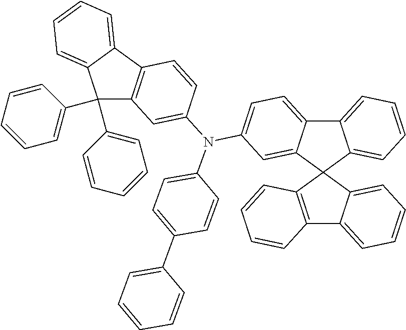 [SMILES: c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1]

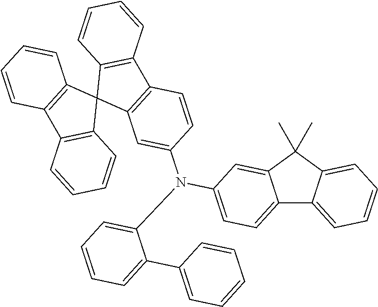 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

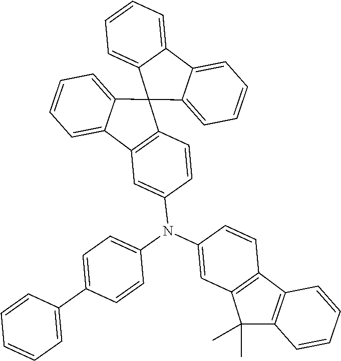 [SMILES: CC1(C)c2ccccc2-c2ccc(N(c3ccc(-c4ccccc4)cc3)c3ccc4c(c3)-c3ccccc3C43c4ccccc4-c4ccccc43)cc21]

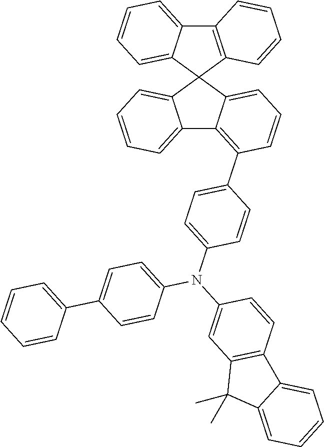 [SMILES: CC1(C)c2ccccc2-c2ccc(N(c3ccc(-c4ccccc4)cc3)c3ccc(-c4cccc5c4-c4ccccc4C54c5ccccc5-c5ccccc54)cc3)cc21]

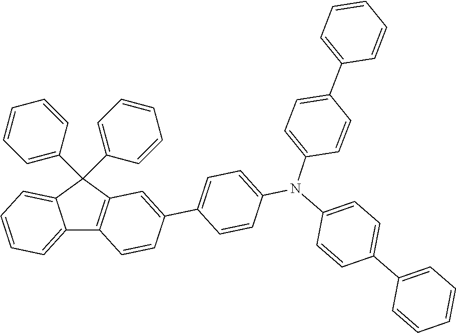 [SMILES: c1ccc(-c2ccc(N(c3ccc(-c4ccccc4)cc3)c3ccc(-c4ccc5c(c4)C(c4ccccc4)(c4ccccc4)c4ccccc4-5)cc3)cc2)cc1]

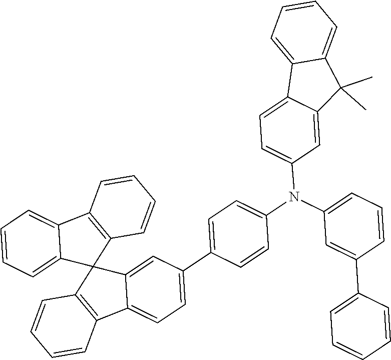 [SMILES: CC1(C)c2ccccc2-c2ccc(N(c3ccc(-c4ccc5c(c4)C4(c6ccccc6-c6ccccc64)c4ccccc4-5)cc3)c3cccc(-c4ccccc4)c3)cc21]

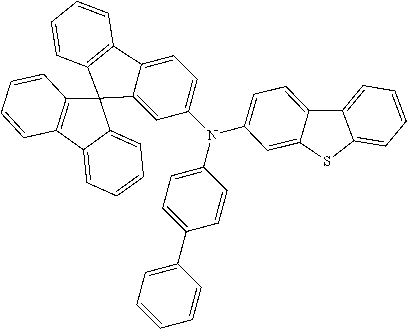 [SMILES: c1ccc(-c2ccc(N(c3ccc4c(c3)C3(c5ccccc5-c5ccccc53)c3ccccc3-4)c3ccc4c(c3)sc3ccccc34)cc2)cc1]

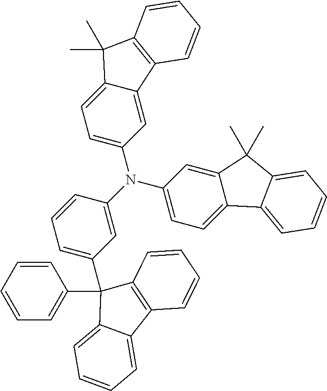 [SMILES: CC1(C)c2ccccc2-c2cc(N(c3cccc(C4(c5ccccc5)c5ccccc5-c5ccccc54)c3)c3ccc4c(c3)C(C)(C)c3ccccc3-4)ccc21]

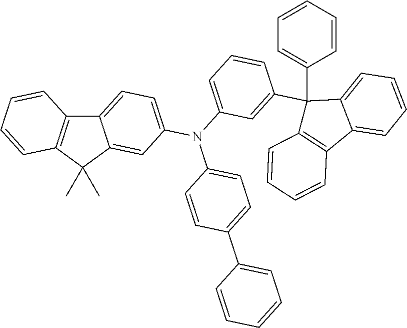 [SMILES: CC1(C)c2ccccc2-c2ccc(N(c3ccc(-c4ccccc4)cc3)c3cccc(C4(c5ccccc5)c5ccccc5-c5ccccc54)c3)cc21]

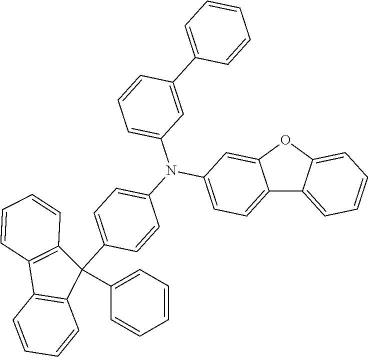 [SMILES: c1ccc(-c2cccc(N(c3ccc(C4(c5ccccc5)c5ccccc5-c5ccccc54)cc3)c3ccc4c(c3)oc3ccccc34)c2)cc1]

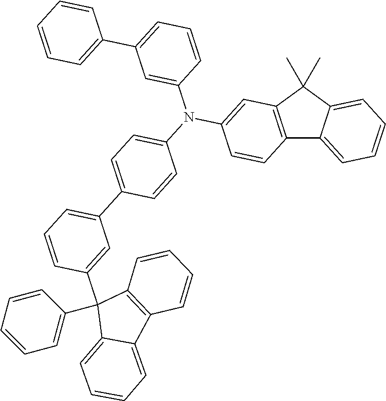 [SMILES: CC1(C)c2ccccc2-c2ccc(N(c3ccc(-c4cccc(C5(c6ccccc6)c6ccccc6-c6ccccc65)c4)cc3)c3cccc(-c4ccccc4)c3)cc21]

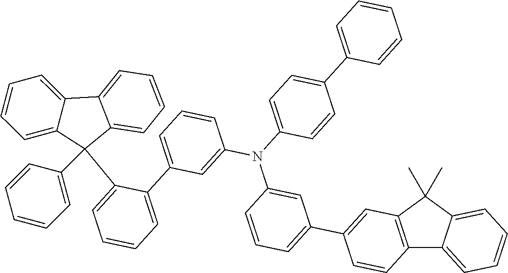 [SMILES: CC1(C)c2ccccc2-c2ccc(-c3cccc(N(c4ccc(-c5ccccc5)cc4)c4cccc(-c5ccccc5C5(c6ccccc6)c6ccccc6-c6ccccc65)c4)c3)cc21]

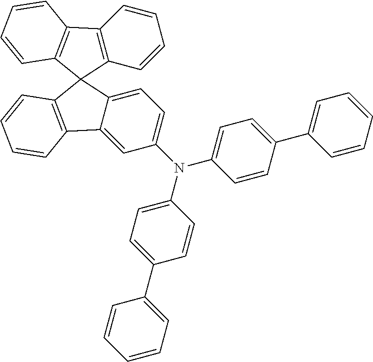 [SMILES: c1ccc(-c2ccc(N(c3ccc(-c4ccccc4)cc3)c3ccc4c(c3)-c3ccccc3C43c4ccccc4-c4ccccc43)cc2)cc1]

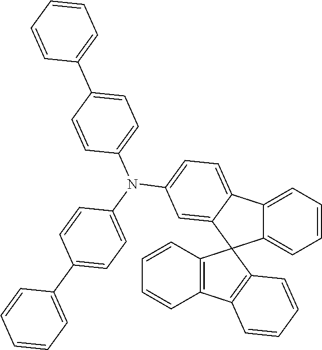 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

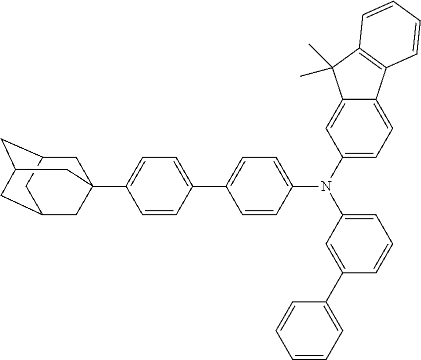 [SMILES: CC1(C)c2ccccc2-c2ccc(N(c3ccc(-c4ccc(C56CC7CC(CC(C7)C5)C6)cc4)cc3)c3cccc(-c4ccccc4)c3)cc21]

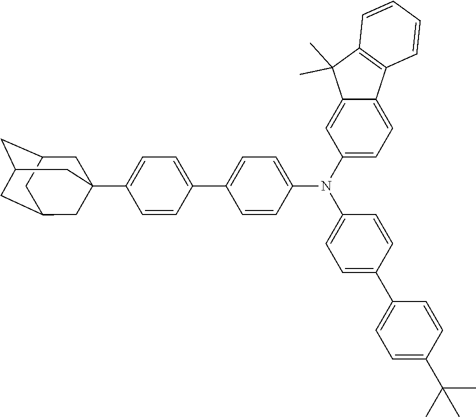 [SMILES: CC(C)(C)c1ccc(-c2ccc(N(c3ccc(-c4ccc(C56CC7CC(CC(C7)C5)C6)cc4)cc3)c3ccc4c(c3)C(C)(C)c3ccccc3-4)cc2)cc1]

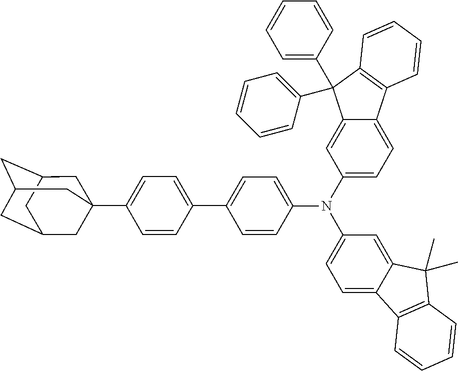 [SMILES: CC1(C)c2ccccc2-c2ccc(N(c3ccc(-c4ccc(C56CC7CC(CC(C7)C5)C6)cc4)cc3)c3ccc4c(c3)C(c3ccccc3)(c3ccccc3)c3ccccc3-4)cc21]

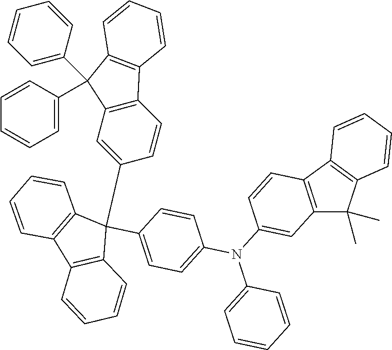 [SMILES: CC1(C)c2ccccc2-c2ccc(N(c3ccccc3)c3ccc(C4(c5ccc6c(c5)C(c5ccccc5)(c5ccccc5)c5ccccc5-6)c5ccccc5-c5ccccc54)cc3)cc21]

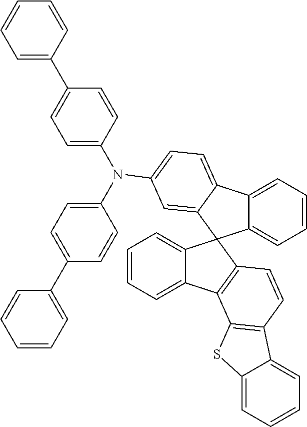 [SMILES: c1ccc(-c2ccc(N(c3ccc(-c4ccccc4)cc3)c3ccc4c(c3)C3(c5ccccc5-4)c4ccccc4-c4c3ccc3c4sc4ccccc43)cc2)cc1]

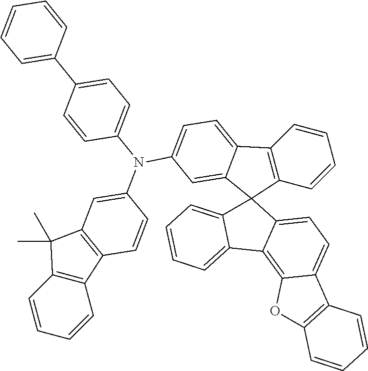 [SMILES: CC1(C)c2ccccc2-c2ccc(N(c3ccc(-c4ccccc4)cc3)c3ccc4c(c3)C3(c5ccccc5-4)c4ccccc4-c4c3ccc3c4oc4ccccc43)cc21]

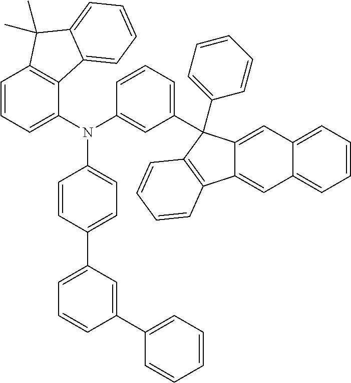 [SMILES: CC1(C)c2ccccc2-c2c(N(c3ccc(-c4cccc(-c5ccccc5)c4)cc3)c3cccc(C4(c5ccccc5)c5ccccc5-c5cc6ccccc6cc54)c3)cccc21]

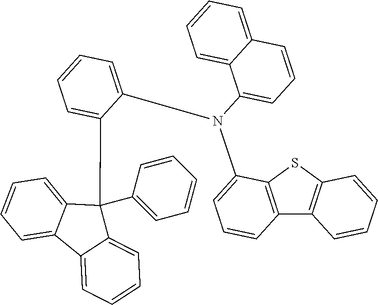 [SMILES: c1ccc(C2(c3ccccc3N(c3cccc4ccccc34)c3cccc4c3sc3ccccc34)c3ccccc3-c3ccccc32)cc1]

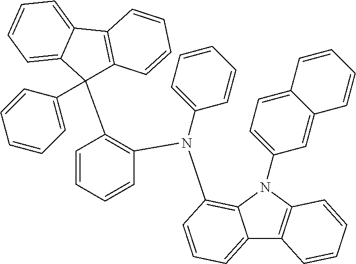 [SMILES: c1ccc(N(c2ccccc2C2(c3ccccc3)c3ccccc3-c3ccccc32)c2cccc3c4ccccc4n(-c4ccc5ccccc5c4)c23)cc1]

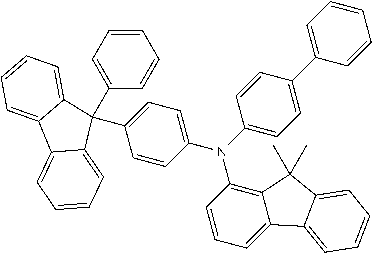 [SMILES: CC1(C)c2ccccc2-c2cccc(N(c3ccc(-c4ccccc4)cc3)c3ccc(C4(c5ccccc5)c5ccccc5-c5ccccc54)cc3)c21]

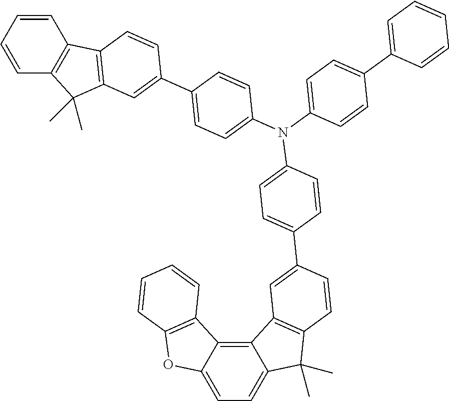 [SMILES: CC1(C)c2ccccc2-c2ccc(-c3ccc(N(c4ccc(-c5ccccc5)cc4)c4ccc(-c5ccc6c(c5)-c5c(ccc7oc8ccccc8c57)C6(C)C)cc4)cc3)cc21]

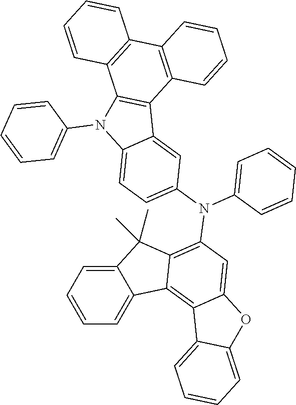 [SMILES: CC1(C)c2ccccc2-c2c1c(N(c1ccccc1)c1ccc3c(c1)c1c4ccccc4c4ccccc4c1n3-c1ccccc1)cc1oc3ccccc3c21]

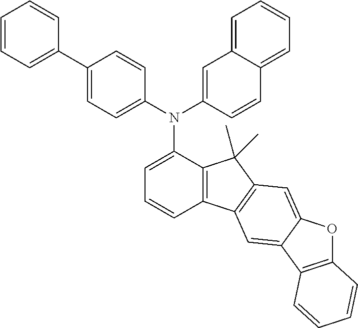 [SMILES: CC1(C)c2cc3oc4ccccc4c3cc2-c2cccc(N(c3ccc(-c4ccccc4)cc3)c3ccc4ccccc4c3)c21]

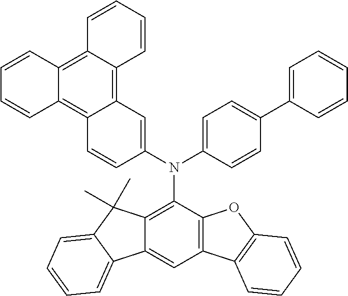 [SMILES: CC1(C)c2ccccc2-c2cc3c(oc4ccccc43)c(N(c3ccc(-c4ccccc4)cc3)c3ccc4c5ccccc5c5ccccc5c4c3)c21]

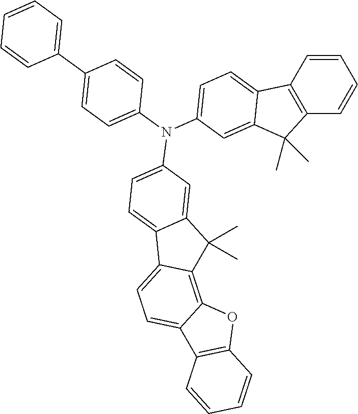 [SMILES: CC1(C)c2ccccc2-c2ccc(N(c3ccc(-c4ccccc4)cc3)c3ccc4c(c3)C(C)(C)c3c-4ccc4c3oc3ccccc34)cc21]

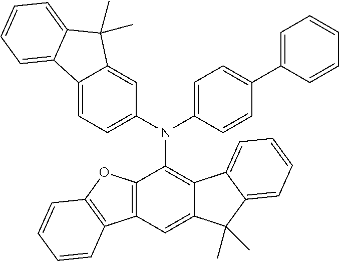 [SMILES: CC1(C)c2ccccc2-c2ccc(N(c3ccc(-c4ccccc4)cc3)c3c4c(cc5c3oc3ccccc35)C(C)(C)c3ccccc3-4)cc21]

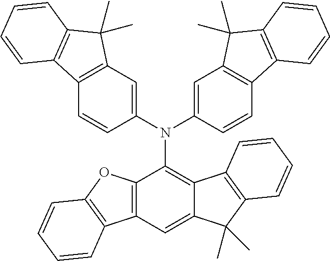 [SMILES: CC1(C)c2ccccc2-c2ccc(N(c3ccc4c(c3)C(C)(C)c3ccccc3-4)c3c4c(cc5c3oc3ccccc35)C(C)(C)c3ccccc3-4)cc21]

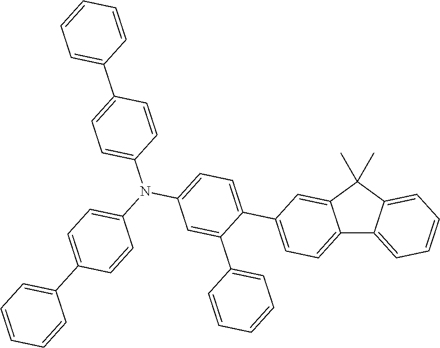 [SMILES: CC1(C)c2ccccc2-c2ccc(-c3ccc(N(c4ccc(-c5ccccc5)cc4)c4ccc(-c5ccccc5)cc4)cc3-c3ccccc3)cc21]

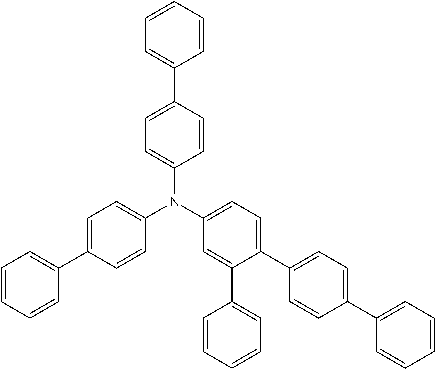 [SMILES: c1ccc(-c2ccc(-c3ccc(N(c4ccc(-c5ccccc5)cc4)c4ccc(-c5ccccc5)cc4)cc3-c3ccccc3)cc2)cc1]

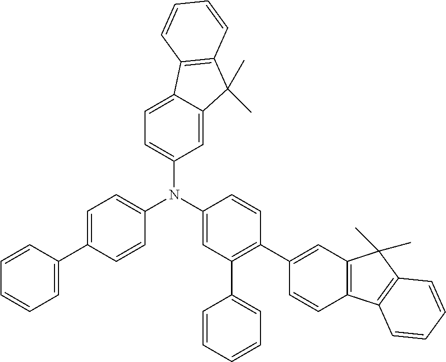 [SMILES: CC1(C)c2ccccc2-c2ccc(-c3ccc(N(c4ccc(-c5ccccc5)cc4)c4ccc5c(c4)C(C)(C)c4ccccc4-5)cc3-c3ccccc3)cc21]

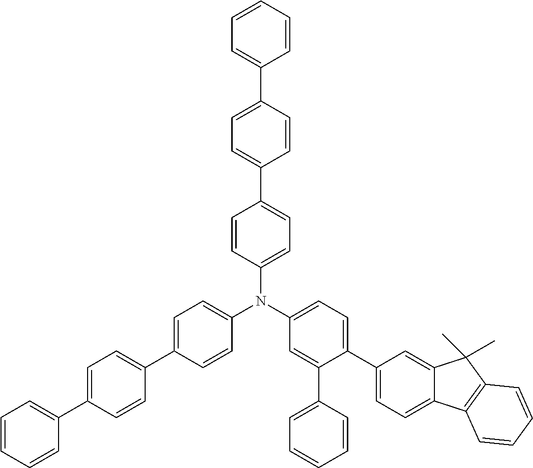 [SMILES: CC1(C)c2ccccc2-c2ccc(-c3ccc(N(c4ccc(-c5ccc(-c6ccccc6)cc5)cc4)c4ccc(-c5ccc(-c6ccccc6)cc5)cc4)cc3-c3ccccc3)cc21]

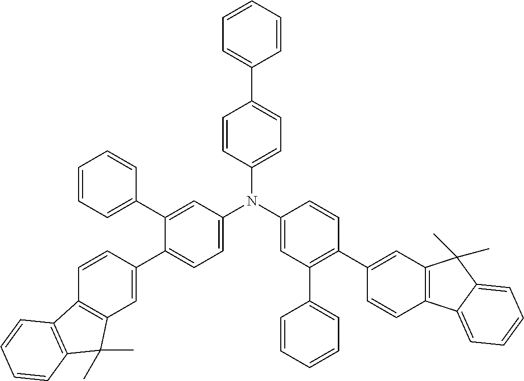 [SMILES: CC1(C)c2ccccc2-c2ccc(-c3ccc(N(c4ccc(-c5ccccc5)cc4)c4ccc(-c5ccc6c(c5)C(C)(C)c5ccccc5-6)c(-c5ccccc5)c4)cc3-c3ccccc3)cc21]

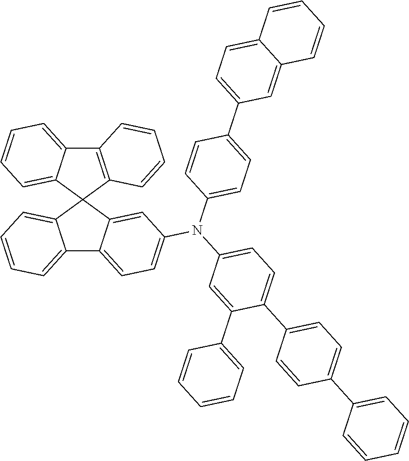 [SMILES: c1ccc(-c2ccc(-c3ccc(N(c4ccc(-c5ccc6ccccc6c5)cc4)c4ccc5c(c4)C4(c6ccccc6-c6ccccc64)c4ccccc4-5)cc3-c3ccccc3)cc2)cc1]

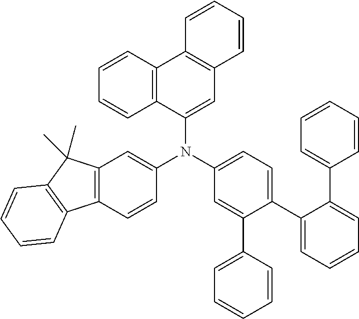 [SMILES: CC1(C)c2ccccc2-c2ccc(N(c3ccc(-c4ccccc4-c4ccccc4)c(-c4ccccc4)c3)c3cc4ccccc4c4ccccc34)cc21]

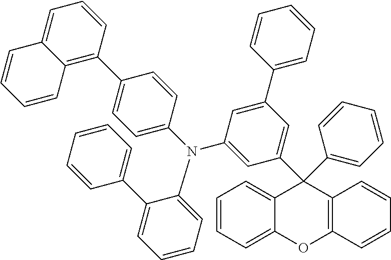 [SMILES: c1ccc(-c2cc(N(c3ccc(-c4cccc5ccccc45)cc3)c3ccccc3-c3ccccc3)cc(C3(c4ccccc4)c4ccccc4Oc4ccccc43)c2)cc1]

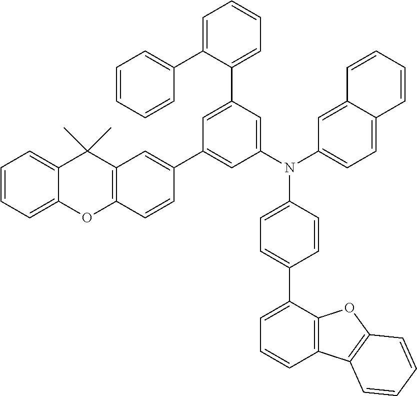 [SMILES: CC1(C)c2ccccc2Oc2ccc(-c3cc(-c4ccccc4-c4ccccc4)cc(N(c4ccc(-c5cccc6c5oc5ccccc56)cc4)c4ccc5ccccc5c4)c3)cc21]

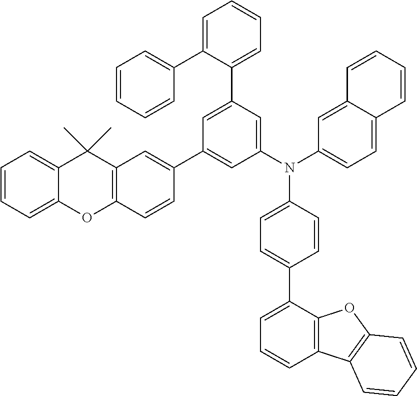 [SMILES: CC1(C)c2ccccc2Oc2ccc(-c3cc(-c4ccccc4-c4ccccc4)cc(N(c4ccc(-c5cccc6c5oc5ccccc56)cc4)c4ccc5ccccc5c4)c3)cc21]

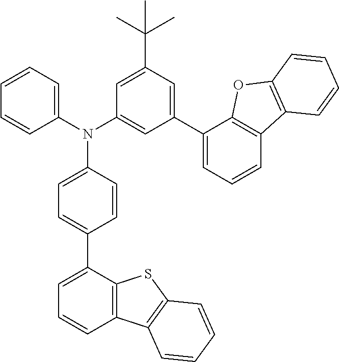 [SMILES: CC(C)(C)c1cc(-c2cccc3c2oc2ccccc23)cc(N(c2ccccc2)c2ccc(-c3cccc4c3sc3ccccc34)cc2)c1]

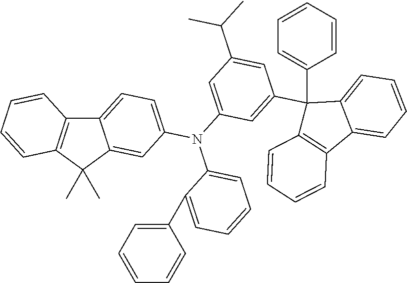 [SMILES: CC(C)c1cc(N(c2ccc3c(c2)C(C)(C)c2ccccc2-3)c2ccccc2-c2ccccc2)cc(C2(c3ccccc3)c3ccccc3-c3ccccc32)c1]

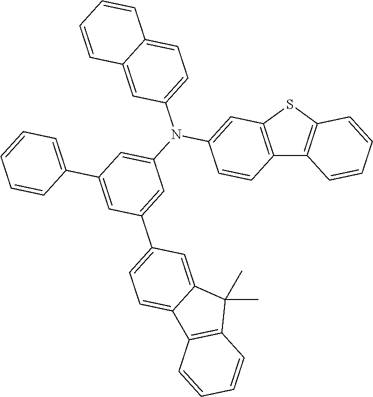 [SMILES: CC1(C)c2ccccc2-c2ccc(-c3cc(-c4ccccc4)cc(N(c4ccc5ccccc5c4)c4ccc5c(c4)sc4ccccc45)c3)cc21]

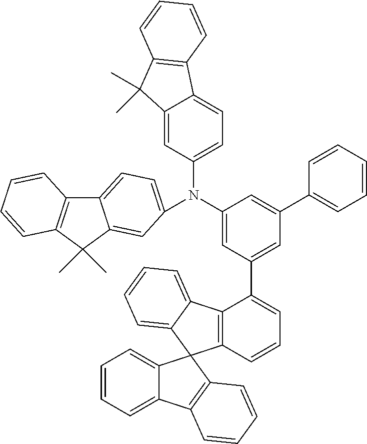 [SMILES: CC1(C)c2ccccc2-c2ccc(N(c3cc(-c4ccccc4)cc(-c4cccc5c4-c4ccccc4C54c5ccccc5-c5ccccc54)c3)c3ccc4c(c3)C(C)(C)c3ccccc3-4)cc21]

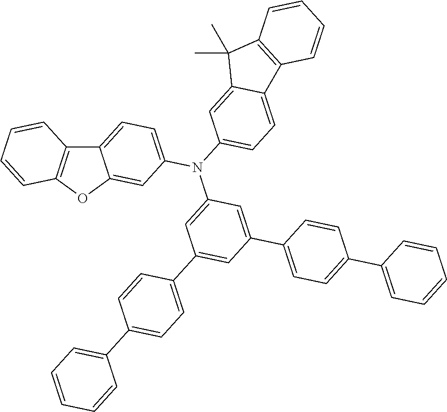 [SMILES: CC1(C)c2ccccc2-c2ccc(N(c3cc(-c4ccc(-c5ccccc5)cc4)cc(-c4ccc(-c5ccccc5)cc4)c3)c3ccc4c(c3)oc3ccccc34)cc21]

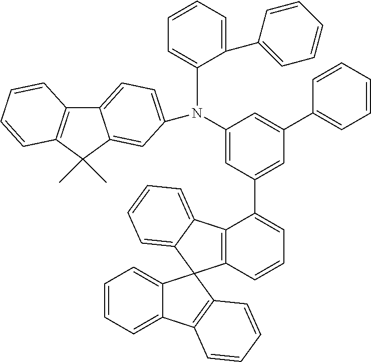 [SMILES: CC1(C)c2ccccc2-c2ccc(N(c3cc(-c4ccccc4)cc(-c4cccc5c4-c4ccccc4C54c5ccccc5-c5ccccc54)c3)c3ccccc3-c3ccccc3)cc21]

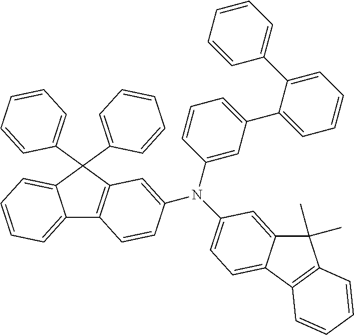 [SMILES: CC1(C)c2ccccc2-c2ccc(N(c3cccc(-c4ccccc4-c4ccccc4)c3)c3ccc4c(c3)C(c3ccccc3)(c3ccccc3)c3ccccc3-4)cc21]

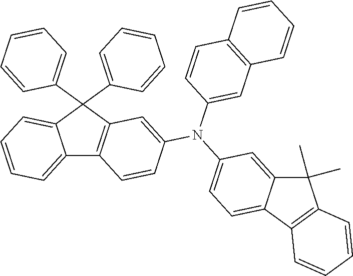 [SMILES: CC1(C)c2ccccc2-c2ccc(N(c3ccc4c(c3)C(c3ccccc3)(c3ccccc3)c3ccccc3-4)c3ccc4ccccc4c3)cc21]

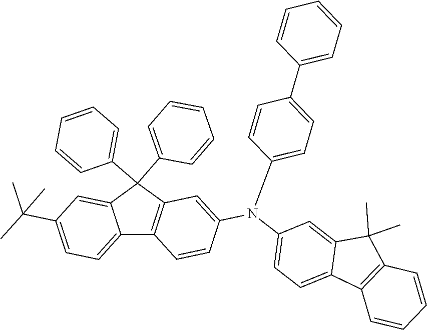 [SMILES: CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2]

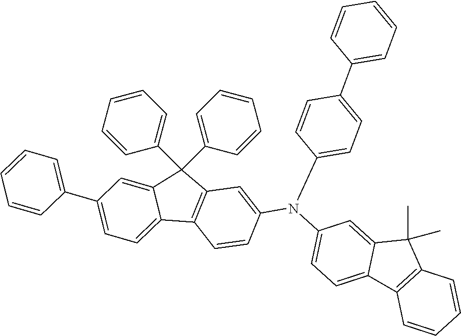 [SMILES: CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21]

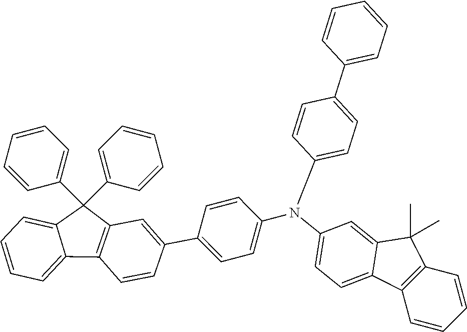 [SMILES: CC1(C)c2ccccc2-c2ccc(N(c3ccc(-c4ccccc4)cc3)c3ccc(-c4ccc5c(c4)C(c4ccccc4)(c4ccccc4)c4ccccc4-5)cc3)cc21]

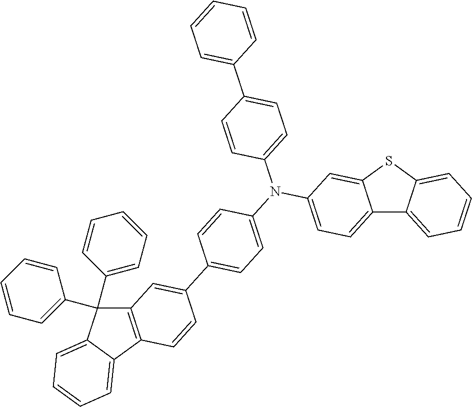 [SMILES: c1ccc(-c2ccc(N(c3ccc(-c4ccc5c(c4)C(c4ccccc4)(c4ccccc4)c4ccccc4-5)cc3)c3ccc4c(c3)sc3ccccc34)cc2)cc1]

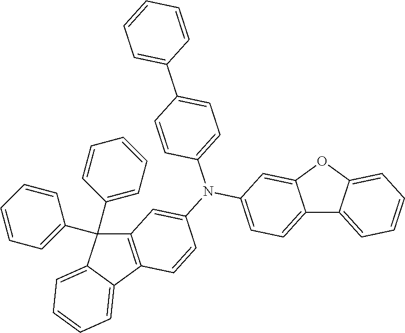 [SMILES: c1ccc(-c2ccc(N(c3ccc4c(c3)C(c3ccccc3)(c3ccccc3)c3ccccc3-4)c3ccc4c(c3)oc3ccccc34)cc2)cc1]

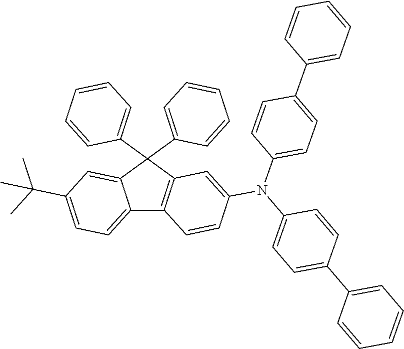 [SMILES: CC(C)(C)c1ccc2c(c1)C(c1ccccc1)(c1ccccc1)c1cc(N(c3ccc(-c4ccccc4)cc3)c3ccc(-c4ccccc4)cc3)ccc1-2]

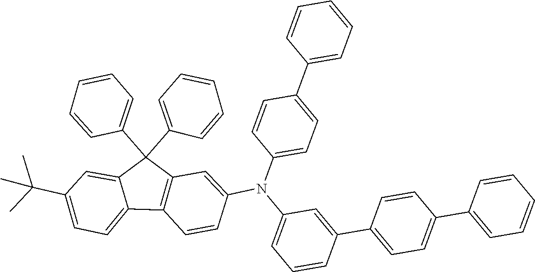 [SMILES: CC(C)(C)c1ccc2c(c1)C(c1ccccc1)(c1ccccc1)c1cc(N(c3ccc(-c4ccccc4)cc3)c3cccc(-c4ccc(-c5ccccc5)cc4)c3)ccc1-2]

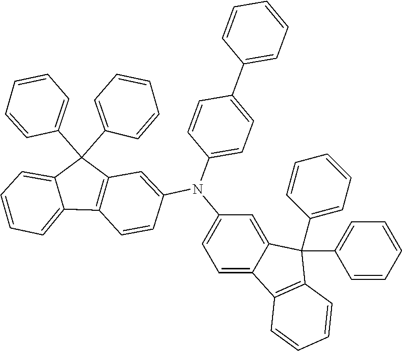 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

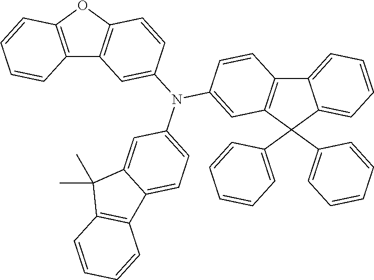 [SMILES: CC1(C)c2ccccc2-c2ccc(N(c3ccc4c(c3)C(c3ccccc3)(c3ccccc3)c3ccccc3-4)c3ccc4oc5ccccc5c4c3)cc21]

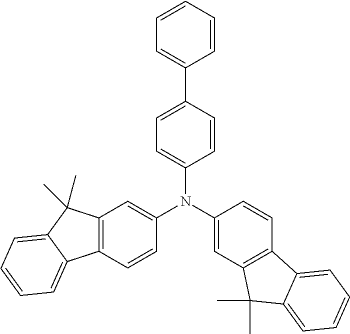 [SMILES: CC1(C)c2ccccc2-c2ccc(N(c3ccc(-c4ccccc4)cc3)c3ccc4c(c3)C(C)(C)c3ccccc3-4)cc21]

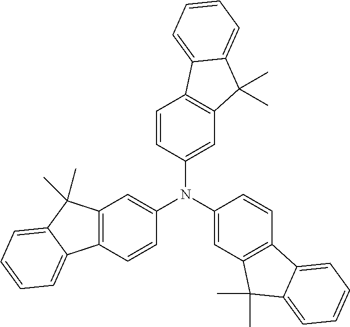 [SMILES: CC1(C)c2ccccc2-c2ccc(N(c3ccc4c(c3)C(C)(C)c3ccccc3-4)c3ccc4c(c3)C(C)(C)c3ccccc3-4)cc21]

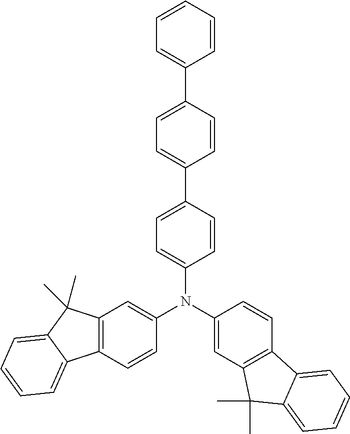 [SMILES: CC1(C)c2ccccc2-c2ccc(N(c3ccc(-c4ccc(-c5ccccc5)cc4)cc3)c3ccc4c(c3)C(C)(C)c3ccccc3-4)cc21]

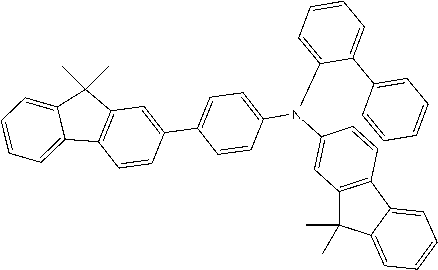 [SMILES: CC1(C)c2ccccc2-c2ccc(-c3ccc(N(c4ccc5c(c4)C(C)(C)c4ccccc4-5)c4ccccc4-c4ccccc4)cc3)cc21]

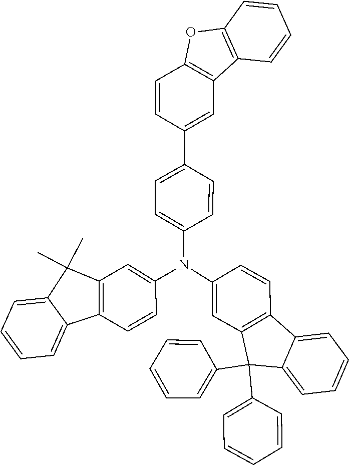 [SMILES: CC1(C)c2ccccc2-c2ccc(N(c3ccc(-c4ccc5oc6ccccc6c5c4)cc3)c3ccc4c(c3)C(c3ccccc3)(c3ccccc3)c3ccccc3-4)cc21]

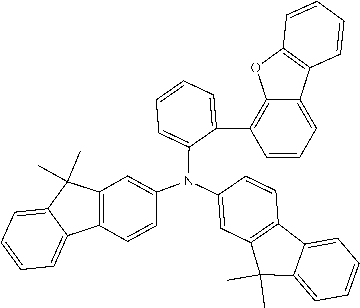 [SMILES: CC1(C)c2ccccc2-c2ccc(N(c3ccc4c(c3)C(C)(C)c3ccccc3-4)c3ccccc3-c3cccc4c3oc3ccccc34)cc21]

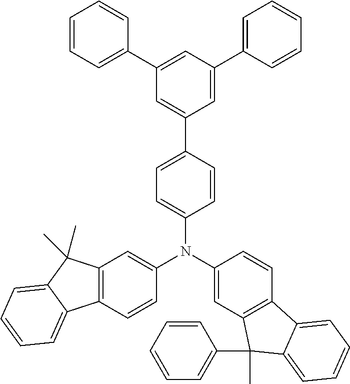 [SMILES: CC1(C)c2ccccc2-c2ccc(N(c3ccc(-c4cc(-c5ccccc5)cc(-c5ccccc5)c4)cc3)c3ccc4c(c3)C(C)(c3ccccc3)c3ccccc3-4)cc21]

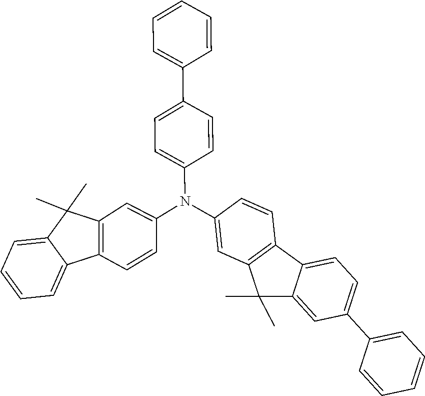 [SMILES: CC1(C)c2ccccc2-c2ccc(N(c3ccc(-c4ccccc4)cc3)c3ccc4c(c3)C(C)(C)c3cc(-c5ccccc5)ccc3-4)cc21]

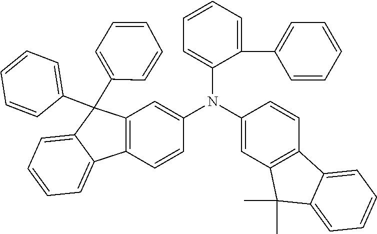 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

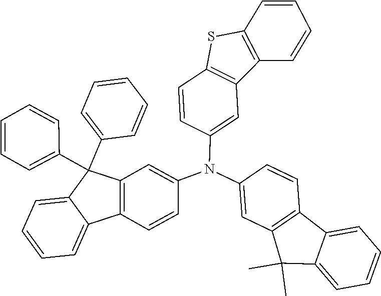 [SMILES: CC1(C)c2ccccc2-c2ccc(N(c3ccc4c(c3)C(c3ccccc3)(c3ccccc3)c3ccccc3-4)c3ccc4sc5ccccc5c4c3)cc21]

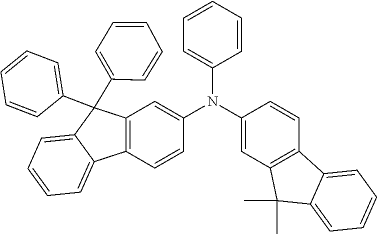 [SMILES: CC1(C)c2ccccc2-c2ccc(N(c3ccccc3)c3ccc4c(c3)C(c3ccccc3)(c3ccccc3)c3ccccc3-4)cc21]

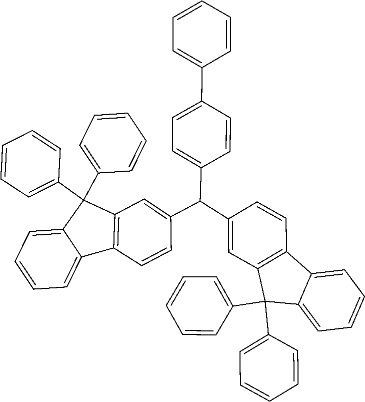 [SMILES: c1ccc(-c2ccc(C(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

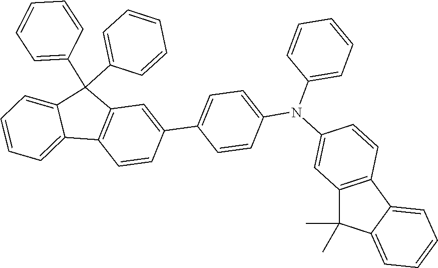 [SMILES: CC1(C)c2ccccc2-c2ccc(N(c3ccccc3)c3ccc(-c4ccc5c(c4)C(c4ccccc4)(c4ccccc4)c4ccccc4-5)cc3)cc21]

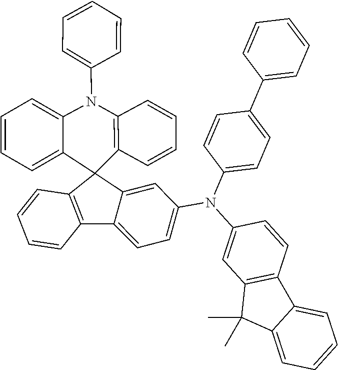 [SMILES: CC1(C)c2ccccc2-c2ccc(N(c3ccc(-c4ccccc4)cc3)c3ccc4c(c3)C3(c5ccccc5-4)c4ccccc4N(c4ccccc4)c4ccccc43)cc21]

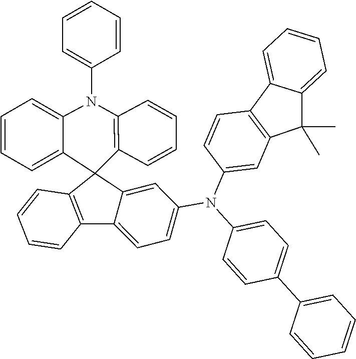 [SMILES: CC1(C)c2ccccc2-c2ccc(N(c3ccc(-c4ccccc4)cc3)c3ccc4c(c3)C3(c5ccccc5-4)c4ccccc4N(c4ccccc4)c4ccccc43)cc21]

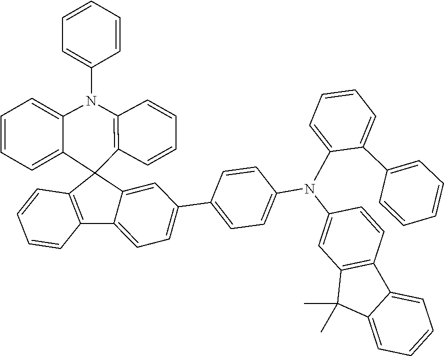 [SMILES: CC1(C)c2ccccc2-c2ccc(N(c3ccc(-c4ccc5c(c4)C4(c6ccccc6-5)c5ccccc5N(c5ccccc5)c5ccccc54)cc3)c3ccccc3-c3ccccc3)cc21]

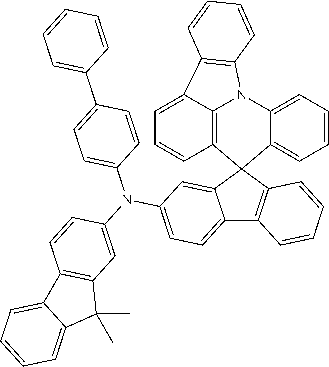 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21]

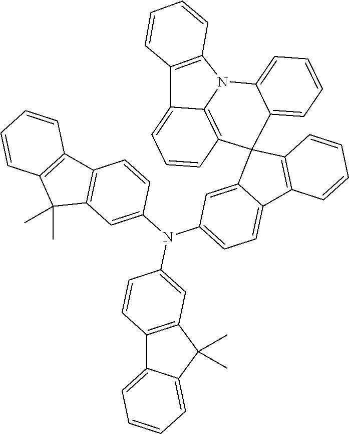 [SMILES: CC1(C)c2ccccc2-c2ccc(N(c3ccc4c(c3)C(C)(C)c3ccccc3-4)c3ccc4c(c3)C3(c5ccccc5-4)c4ccccc4-n4c5ccccc5c5cccc3c54)cc21]

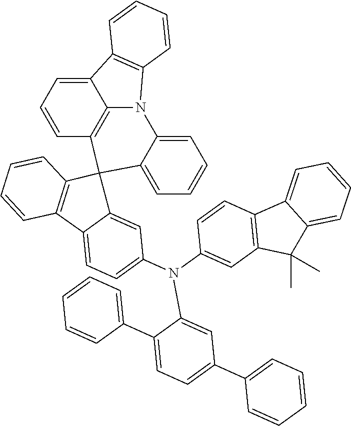 [SMILES: CC1(C)c2ccccc2-c2ccc(N(c3ccc4c(c3)C3(c5ccccc5-4)c4ccccc4-n4c5ccccc5c5cccc3c54)c3cc(-c4ccccc4)ccc3-c3ccccc3)cc21]

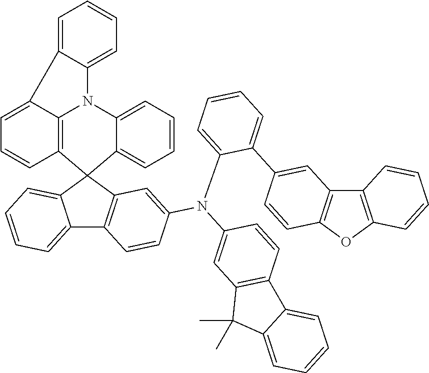 [SMILES: CC1(C)c2ccccc2-c2ccc(N(c3ccc4c(c3)C3(c5ccccc5-4)c4ccccc4-n4c5ccccc5c5cccc3c54)c3ccccc3-c3ccc4oc5ccccc5c4c3)cc21]

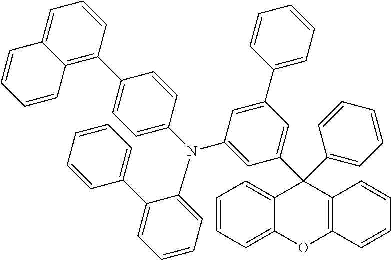 [SMILES: c1ccc(-c2cc(N(c3ccc(-c4cccc5ccccc45)cc3)c3ccccc3-c3ccccc3)cc(C3(c4ccccc4)c4ccccc4Oc4ccccc43)c2)cc1]

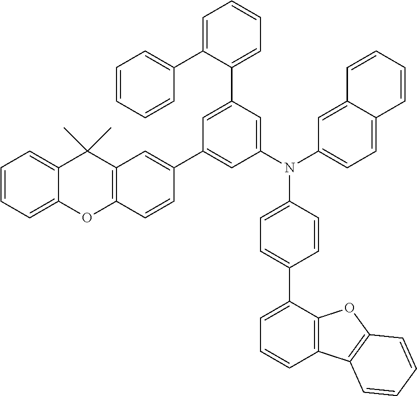 [SMILES: CC1(C)c2ccccc2Oc2ccc(-c3cc(-c4ccccc4-c4ccccc4)cc(N(c4ccc(-c5cccc6c5oc5ccccc56)cc4)c4ccc5ccccc5c4)c3)cc21]

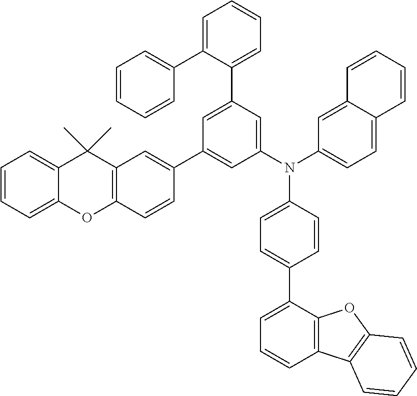 [SMILES: CC1(C)c2ccccc2Oc2ccc(-c3cc(-c4ccccc4-c4ccccc4)cc(N(c4ccc(-c5cccc6c5oc5ccccc56)cc4)c4ccc5ccccc5c4)c3)cc21]

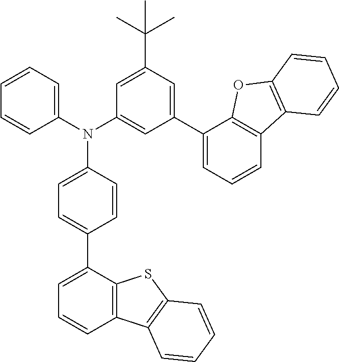 [SMILES: CC(C)(C)c1cc(-c2cccc3c2oc2ccccc23)cc(N(c2ccccc2)c2ccc(-c3cccc4c3sc3ccccc34)cc2)c1]

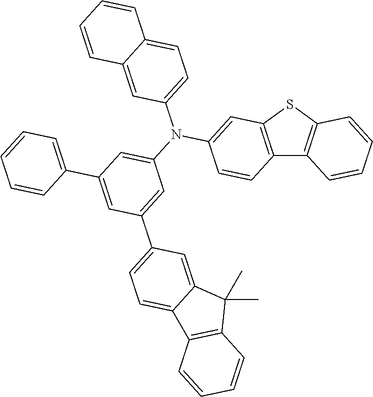 [SMILES: CC1(C)c2ccccc2-c2ccc(-c3cc(-c4ccccc4)cc(N(c4ccc5ccccc5c4)c4ccc5c(c4)sc4ccccc45)c3)cc21]

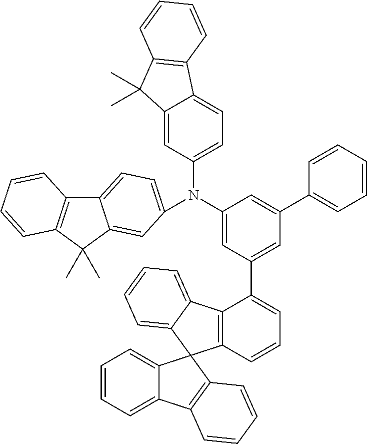 [SMILES: CC1(C)c2ccccc2-c2ccc(N(c3cc(-c4ccccc4)cc(-c4cccc5c4-c4ccccc4C54c5ccccc5-c5ccccc54)c3)c3ccc4c(c3)C(C)(C)c3ccccc3-4)cc21]

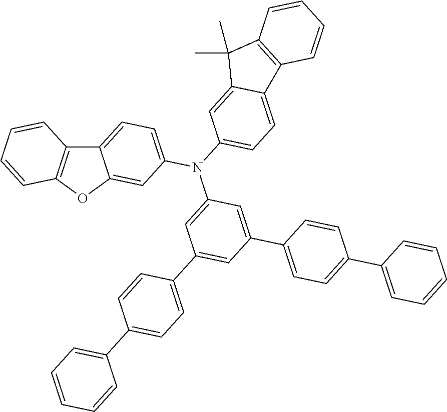 [SMILES: CC1(C)c2ccccc2-c2ccc(N(c3cc(-c4ccc(-c5ccccc5)cc4)cc(-c4ccc(-c5ccccc5)cc4)c3)c3ccc4c(c3)oc3ccccc34)cc21]

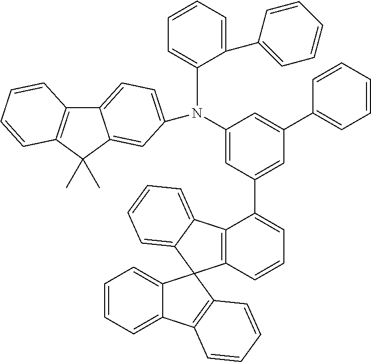 [SMILES: CC1(C)c2ccccc2-c2ccc(N(c3cc(-c4ccccc4)cc(-c4cccc5c4-c4ccccc4C54c5ccccc5-c5ccccc54)c3)c3ccccc3-c3ccccc3)cc21]

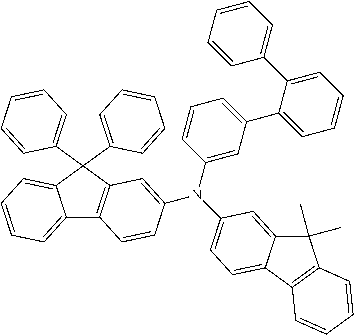 [SMILES: CC1(C)c2ccccc2-c2ccc(N(c3cccc(-c4ccccc4-c4ccccc4)c3)c3ccc4c(c3)C(c3ccccc3)(c3ccccc3)c3ccccc3-4)cc21]

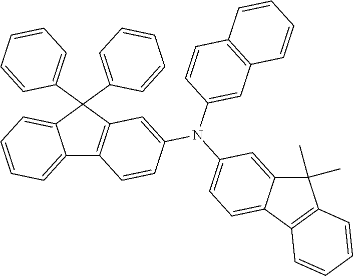 [SMILES: CC1(C)c2ccccc2-c2ccc(N(c3ccc4c(c3)C(c3ccccc3)(c3ccccc3)c3ccccc3-4)c3ccc4ccccc4c3)cc21]

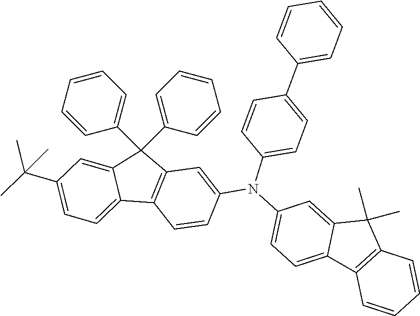 [SMILES: CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2]

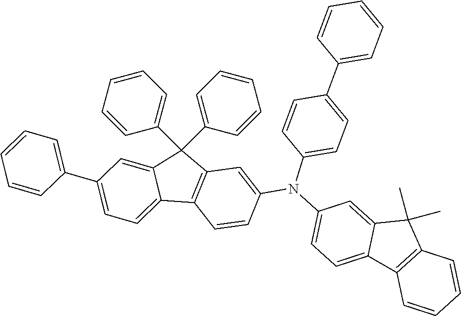 [SMILES: CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21]

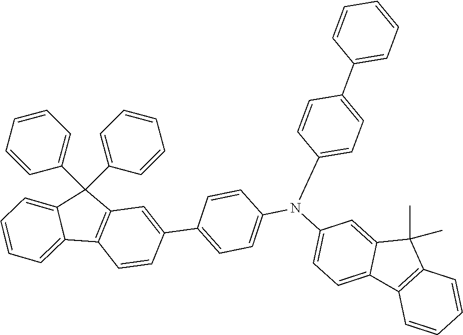 [SMILES: CC1(C)c2ccccc2-c2ccc(N(c3ccc(-c4ccccc4)cc3)c3ccc(-c4ccc5c(c4)C(c4ccccc4)(c4ccccc4)c4ccccc4-5)cc3)cc21]

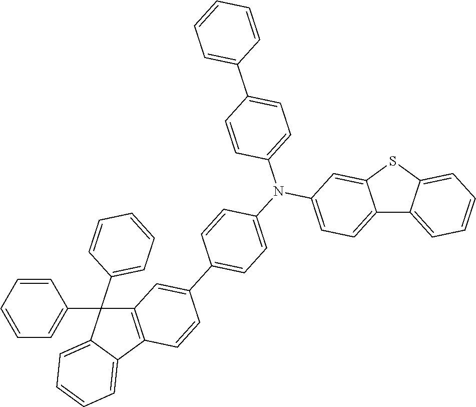 [SMILES: c1ccc(-c2ccc(N(c3ccc(-c4ccc5c(c4)C(c4ccccc4)(c4ccccc4)c4ccccc4-5)cc3)c3ccc4c(c3)sc3ccccc34)cc2)cc1]

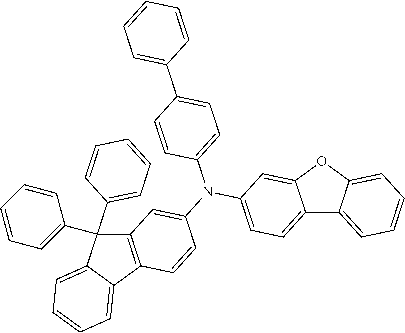 [SMILES: c1ccc(-c2ccc(N(c3ccc4c(c3)C(c3ccccc3)(c3ccccc3)c3ccccc3-4)c3ccc4c(c3)oc3ccccc34)cc2)cc1]

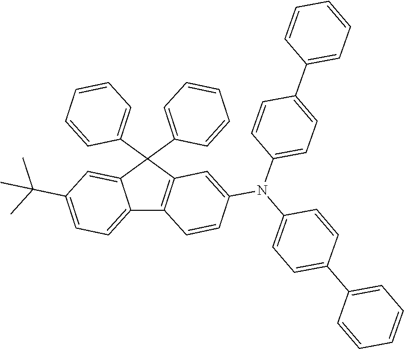 [SMILES: CC(C)(C)c1ccc2c(c1)C(c1ccccc1)(c1ccccc1)c1cc(N(c3ccc(-c4ccccc4)cc3)c3ccc(-c4ccccc4)cc3)ccc1-2]

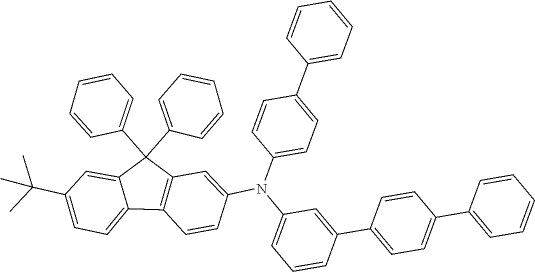 [SMILES: CC(C)(C)c1ccc2c(c1)C(c1ccccc1)(c1ccccc1)c1cc(N(c3ccc(-c4ccccc4)cc3)c3cccc(-c4ccc(-c5ccccc5)cc4)c3)ccc1-2]

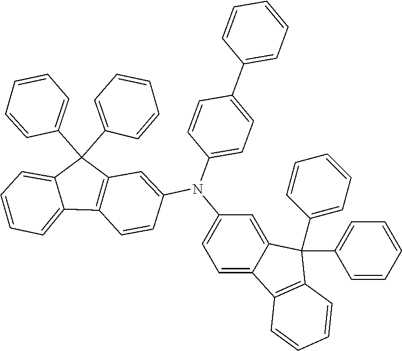 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

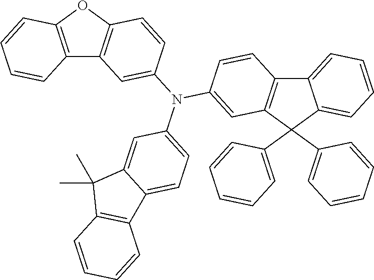 [SMILES: CC1(C)c2ccccc2-c2ccc(N(c3ccc4c(c3)C(c3ccccc3)(c3ccccc3)c3ccccc3-4)c3ccc4oc5ccccc5c4c3)cc21]

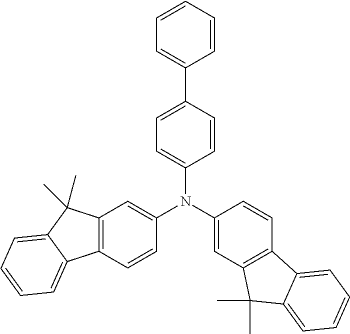 [SMILES: CC1(C)c2ccccc2-c2ccc(N(c3ccc(-c4ccccc4)cc3)c3ccc4c(c3)C(C)(C)c3ccccc3-4)cc21]

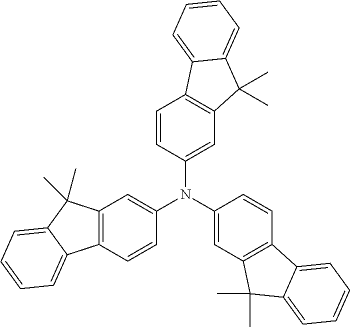 [SMILES: CC1(C)c2ccccc2-c2ccc(N(c3ccc4c(c3)C(C)(C)c3ccccc3-4)c3ccc4c(c3)C(C)(C)c3ccccc3-4)cc21]

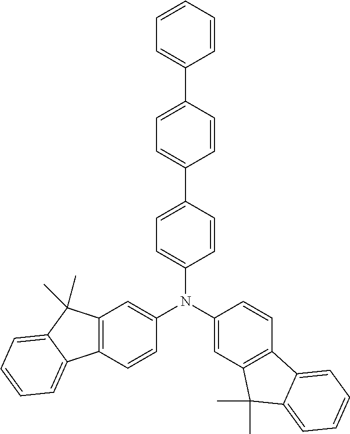 [SMILES: CC1(C)c2ccccc2-c2ccc(N(c3ccc(-c4ccc(-c5ccccc5)cc4)cc3)c3ccc4c(c3)C(C)(C)c3ccccc3-4)cc21]

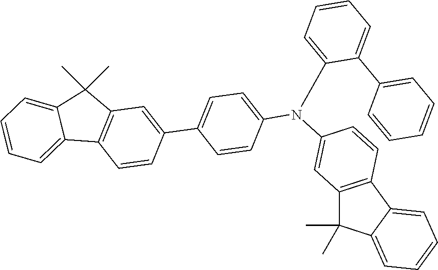 [SMILES: CC1(C)c2ccccc2-c2ccc(-c3ccc(N(c4ccc5c(c4)C(C)(C)c4ccccc4-5)c4ccccc4-c4ccccc4)cc3)cc21]

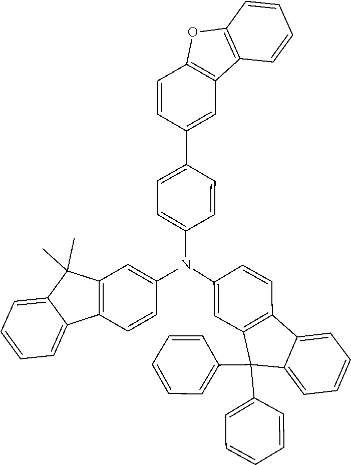 [SMILES: CC1(C)c2ccccc2-c2ccc(N(c3ccc(-c4ccc5oc6ccccc6c5c4)cc3)c3ccc4c(c3)C(c3ccccc3)(c3ccccc3)c3ccccc3-4)cc21]

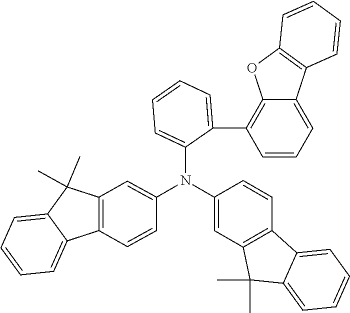 [SMILES: CC1(C)c2ccccc2-c2ccc(N(c3ccc4c(c3)C(C)(C)c3ccccc3-4)c3ccccc3-c3cccc4c3oc3ccccc34)cc21]

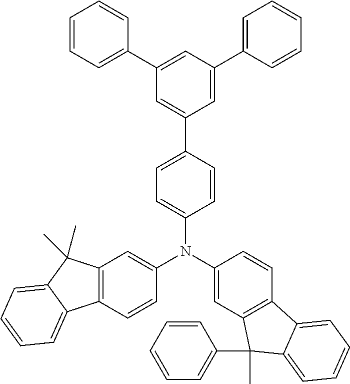 [SMILES: CC1(C)c2ccccc2-c2ccc(N(c3ccc(-c4cc(-c5ccccc5)cc(-c5ccccc5)c4)cc3)c3ccc4c(c3)C(C)(c3ccccc3)c3ccccc3-4)cc21]

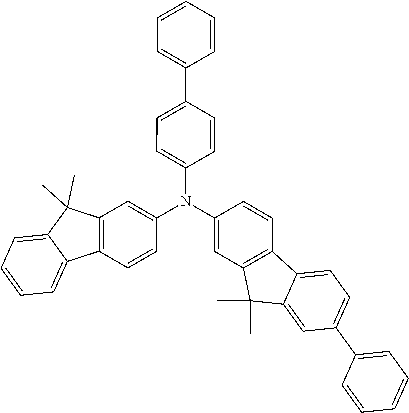 [SMILES: CC1(C)c2ccccc2-c2ccc(N(c3ccc(-c4ccccc4)cc3)c3ccc4c(c3)C(C)(C)c3cc(-c5ccccc5)ccc3-4)cc21]

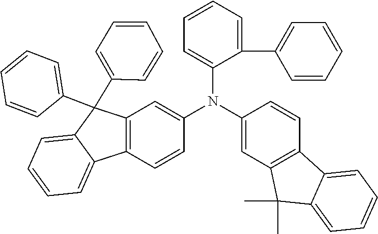 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

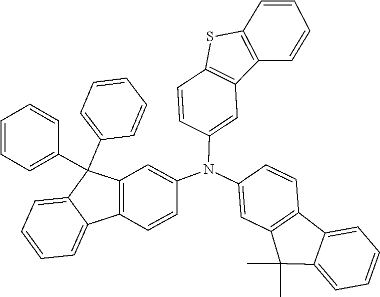 [SMILES: CC1(C)c2ccccc2-c2ccc(N(c3ccc4c(c3)C(c3ccccc3)(c3ccccc3)c3ccccc3-4)c3ccc4sc5ccccc5c4c3)cc21]

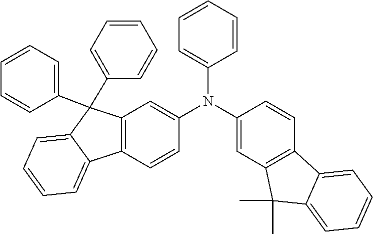 [SMILES: CC1(C)c2ccccc2-c2ccc(N(c3ccccc3)c3ccc4c(c3)C(c3ccccc3)(c3ccccc3)c3ccccc3-4)cc21]

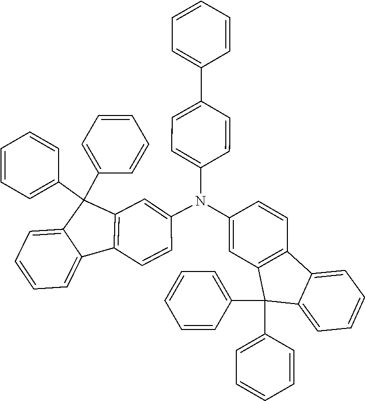 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

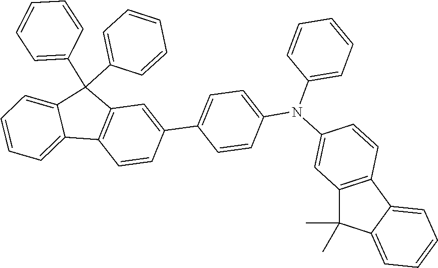 [SMILES: CC1(C)c2ccccc2-c2ccc(N(c3ccccc3)c3ccc(-c4ccc5c(c4)C(c4ccccc4)(c4ccccc4)c4ccccc4-5)cc3)cc21]

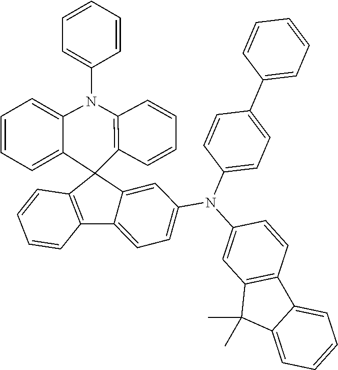 [SMILES: CC1(C)c2ccccc2-c2ccc(N(c3ccc(-c4ccccc4)cc3)c3ccc4c(c3)C3(c5ccccc5-4)c4ccccc4N(c4ccccc4)c4ccccc43)cc21]

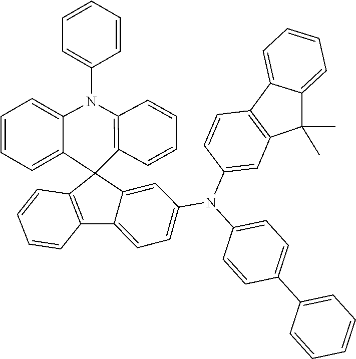 [SMILES: CC1(C)c2ccccc2-c2ccc(N(c3ccc(-c4ccccc4)cc3)c3ccc4c(c3)C3(c5ccccc5-4)c4ccccc4N(c4ccccc4)c4ccccc43)cc21]

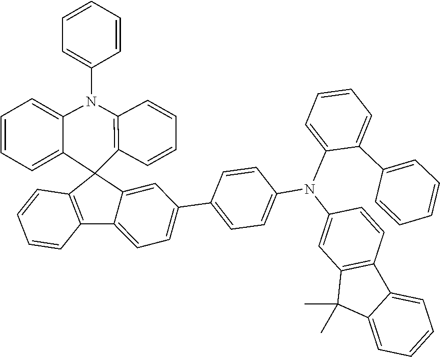 [SMILES: CC1(C)c2ccccc2-c2ccc(N(c3ccc(-c4ccc5c(c4)C4(c6ccccc6-5)c5ccccc5N(c5ccccc5)c5ccccc54)cc3)c3ccccc3-c3ccccc3)cc21]

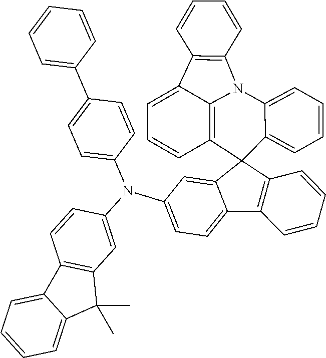 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21]

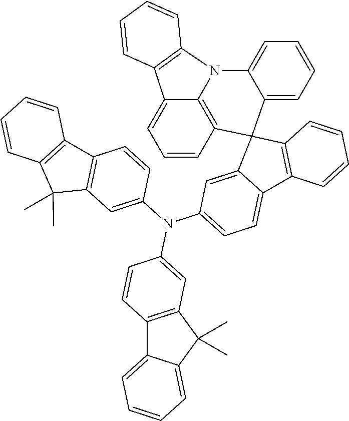 [SMILES: CC1(C)c2ccccc2-c2ccc(N(c3ccc4c(c3)C(C)(C)c3ccccc3-4)c3ccc4c(c3)C3(c5ccccc5-4)c4ccccc4-n4c5ccccc5c5cccc3c54)cc21]

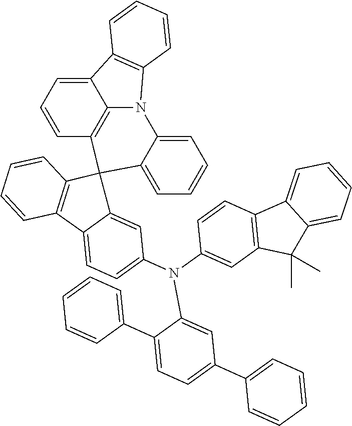 [SMILES: CC1(C)c2ccccc2-c2ccc(N(c3ccc4c(c3)C3(c5ccccc5-4)c4ccccc4-n4c5ccccc5c5cccc3c54)c3cc(-c4ccccc4)ccc3-c3ccccc3)cc21]

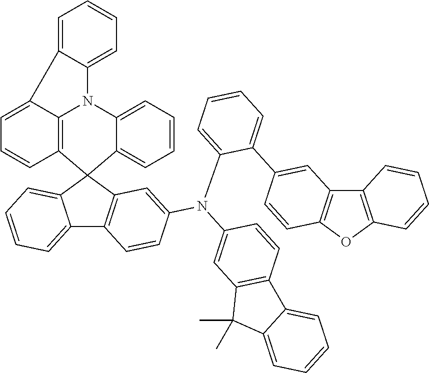 [SMILES: CC1(C)c2ccccc2-c2ccc(N(c3ccc4c(c3)C3(c5ccccc5-4)c4ccccc4-n4c5ccccc5c5cccc3c54)c3ccccc3-c3ccc4oc5ccccc5c4c3)cc21]

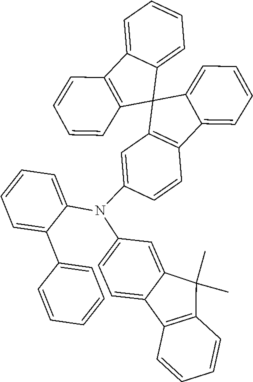 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

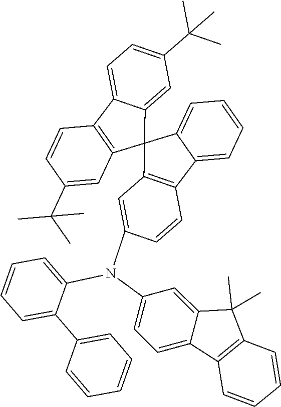 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

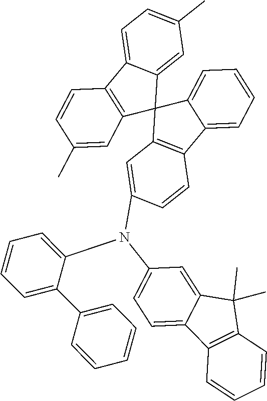 [SMILES: Cc1ccc2c(c1)C1(c3ccccc3-c3ccc(N(c4ccc5c(c4)C(C)(C)c4ccccc4-5)c4ccccc4-c4ccccc4)cc31)c1cc(C)ccc1-2]

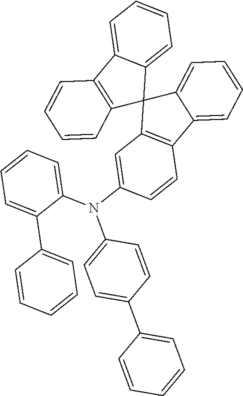 [SMILES: c1ccc(-c2ccc(N(c3ccc4c(c3)C3(c5ccccc5-c5ccccc53)c3ccccc3-4)c3ccccc3-c3ccccc3)cc2)cc1]

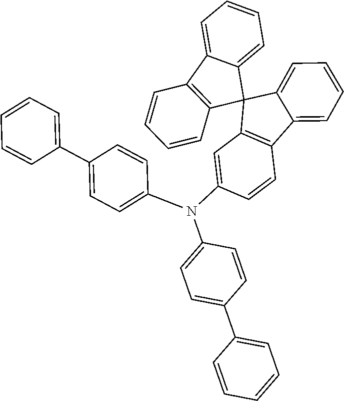 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

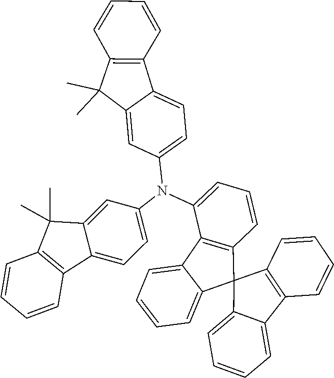 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

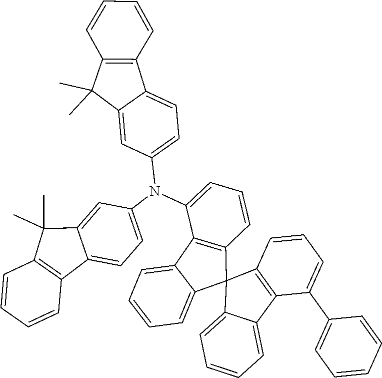 [SMILES: CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21]

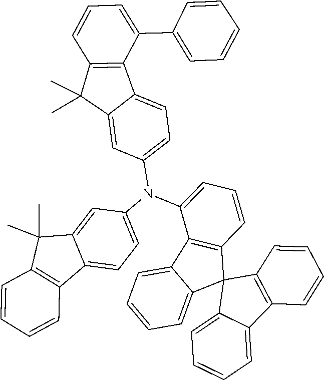 [SMILES: CC1(C)c2ccccc2-c2ccc(N(c3ccc4c(c3)C(C)(C)c3cccc(-c5ccccc5)c3-4)c3cccc4c3-c3ccccc3C43c4ccccc4-c4ccccc43)cc21]

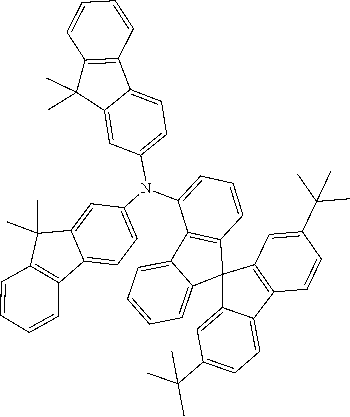 [SMILES: CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21]

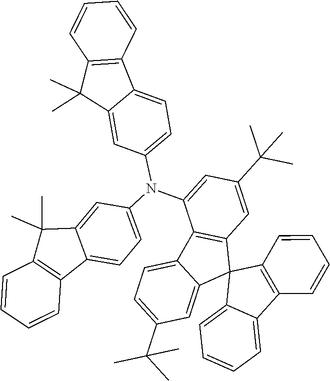 [SMILES: CC(C)(C)c1ccc2c(c1)C1(c3ccccc3-c3ccccc31)c1cc(C(C)(C)C)cc(N(c3ccc4c(c3)C(C)(C)c3ccccc3-4)c3ccc4c(c3)C(C)(C)c3ccccc3-4)c1-2]

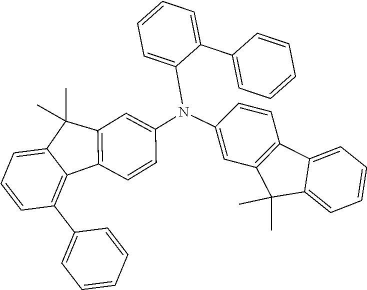 [SMILES: CC1(C)c2ccccc2-c2ccc(N(c3ccc4c(c3)C(C)(C)c3cccc(-c5ccccc5)c3-4)c3ccccc3-c3ccccc3)cc21]

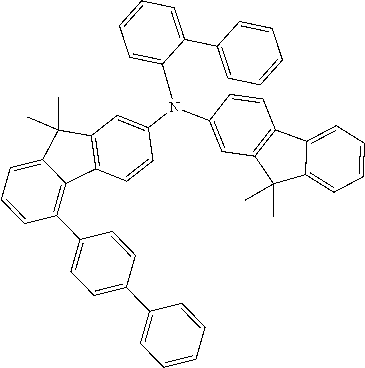 [SMILES: CC1(C)c2ccccc2-c2ccc(N(c3ccc4c(c3)C(C)(C)c3cccc(-c5ccc(-c6ccccc6)cc5)c3-4)c3ccccc3-c3ccccc3)cc21]

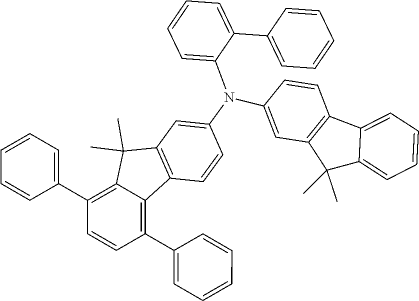 [SMILES: CC1(C)c2ccccc2-c2ccc(N(c3ccc4c(c3)C(C)(C)c3c(-c5ccccc5)ccc(-c5ccccc5)c3-4)c3ccccc3-c3ccccc3)cc21]

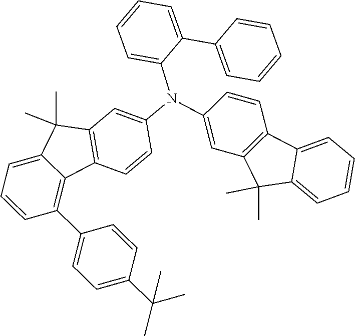 [SMILES: CC(C)(C)c1ccc(-c2cccc3c2-c2ccc(N(c4ccc5c(c4)C(C)(C)c4ccccc4-5)c4ccccc4-c4ccccc4)cc2C3(C)C)cc1]

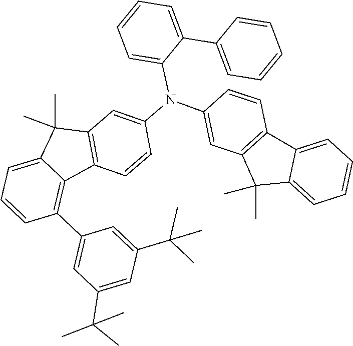 [SMILES: CC(C)(C)c1cc(-c2cccc3c2-c2ccc(N(c4ccc5c(c4)C(C)(C)c4ccccc4-5)c4ccccc4-c4ccccc4)cc2C3(C)C)cc(C(C)(C)C)c1]

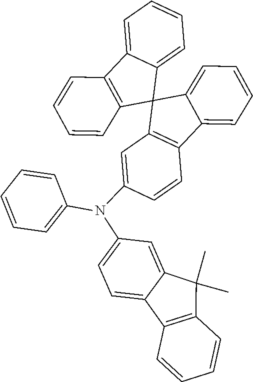 [SMILES: CC1(C)c2ccccc2-c2ccc(N(c3ccccc3)c3ccc4c(c3)C3(c5ccccc5-c5ccccc53)c3ccccc3-4)cc21]

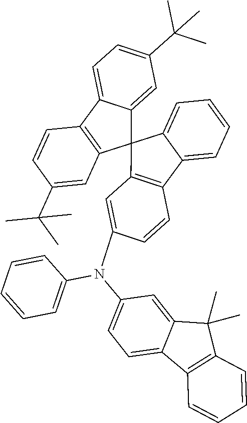 [SMILES: CC(C)(C)c1ccc2c(c1)C1(c3ccccc3-c3ccc(N(c4ccccc4)c4ccc5c(c4)C(C)(C)c4ccccc4-5)cc31)c1cc(C(C)(C)C)ccc1-2]

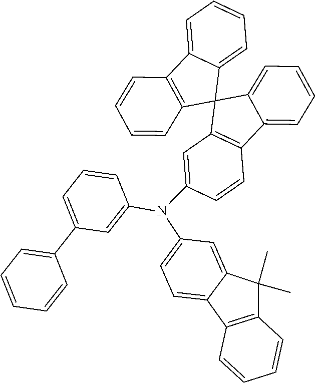 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21]

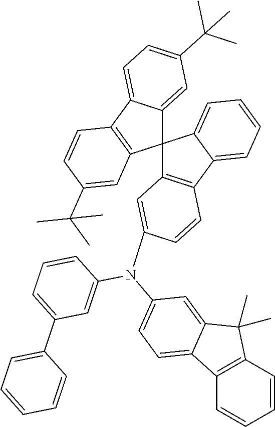 [SMILES: CC(C)(C)c1ccc2c(c1)C1(c3ccccc3-c3ccc(N(c4cccc(-c5ccccc5)c4)c4ccc5c(c4)C(C)(C)c4ccccc4-5)cc31)c1cc(C(C)(C)C)ccc1-2]

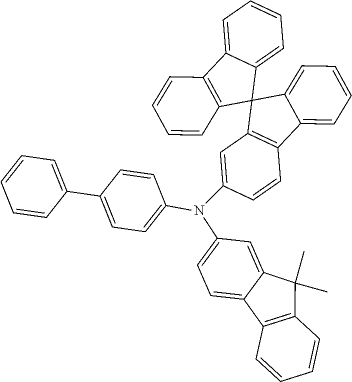 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]

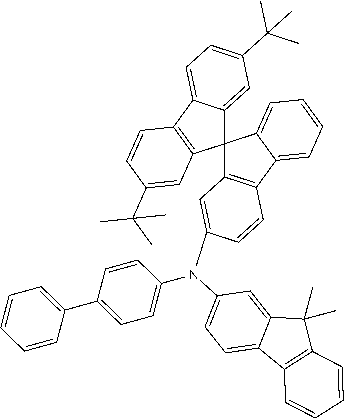 [SMILES: CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

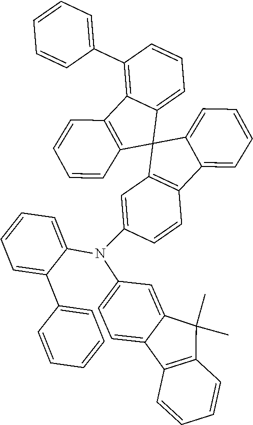 [SMILES: CC1(C)c2ccccc2-c2ccc(N(c3ccc4c(c3)C3(c5ccccc5-4)c4ccccc4-c4c(-c5ccccc5)cccc43)c3ccccc3-c3ccccc3)cc21]

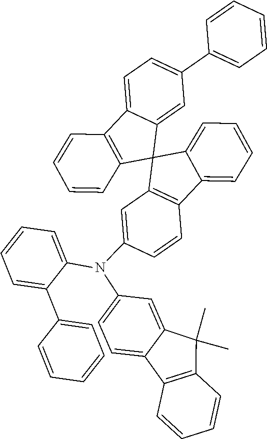 [SMILES: CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21]

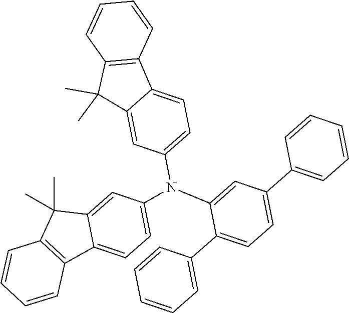 [SMILES: CC1(C)c2ccccc2-c2ccc(N(c3ccc4c(c3)C(C)(C)c3ccccc3-4)c3cc(-c4ccccc4)ccc3-c3ccccc3)cc21]

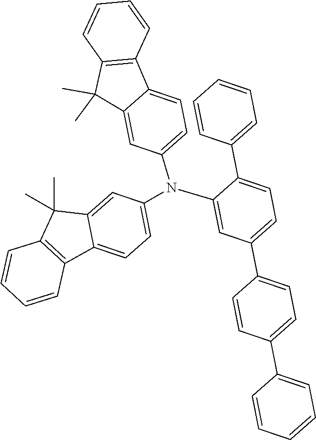 [SMILES: CC1(C)c2ccccc2-c2ccc(N(c3ccc4c(c3)C(C)(C)c3ccccc3-4)c3cc(-c4ccc(-c5ccccc5)cc4)ccc3-c3ccccc3)cc21]

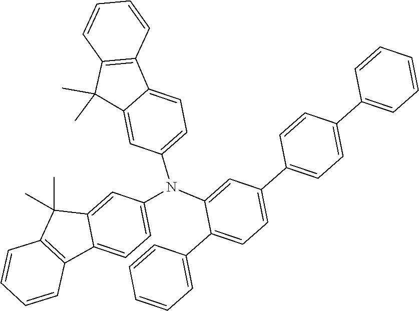 [SMILES: CC1(C)c2ccccc2-c2ccc(N(c3ccc4c(c3)C(C)(C)c3ccccc3-4)c3cc(-c4ccc(-c5ccccc5)cc4)ccc3-c3ccccc3)cc21]

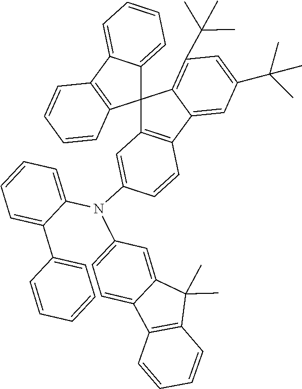 [SMILES: CC(C)(C)c1cc2c(c(C(C)(C)C)c1)C1(c3ccccc3-c3ccccc31)c1cc(N(c3ccc4c(c3)C(C)(C)c3ccccc3-4)c3ccccc3-c3ccccc3)ccc1-2]

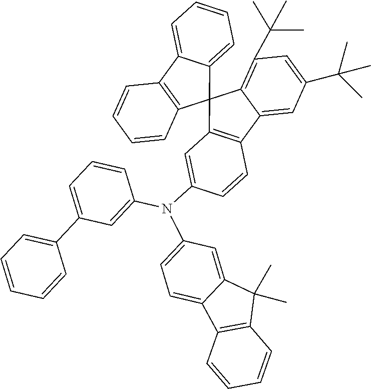 [SMILES: CC(C)(C)c1cc2c(c(C(C)(C)C)c1)C1(c3ccccc3-c3ccccc31)c1cc(N(c3cccc(-c4ccccc4)c3)c3ccc4c(c3)C(C)(C)c3ccccc3-4)ccc1-2]

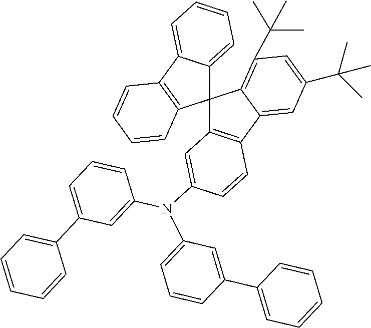 [SMILES: CC(C)(C)c1cc2c(c(C(C)(C)C)c1)C1(c3ccccc3-c3ccccc31)c1cc(N(c3cccc(-c4ccccc4)c3)c3cccc(-c4ccccc4)c3)ccc1-2]

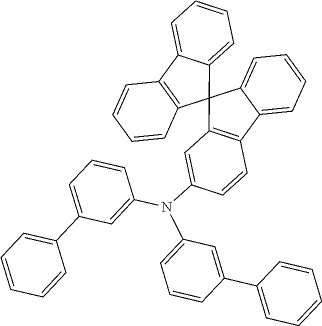 [SMILES: c1ccc(-c2cccc(N(c3cccc(-c4ccccc4)c3)c3ccc4c(c3)C3(c5ccccc5-c5ccccc53)c3ccccc3-4)c2)cc1]

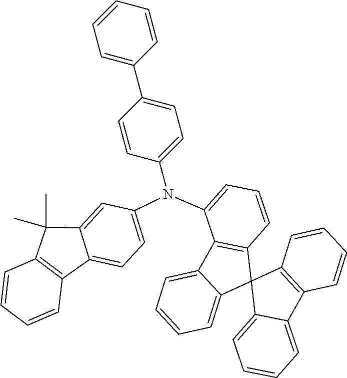 [SMILES: CC1(C)c2ccccc2-c2ccc(N(c3ccc(-c4ccccc4)cc3)c3cccc4c3-c3ccccc3C43c4ccccc4-c4ccccc43)cc21]

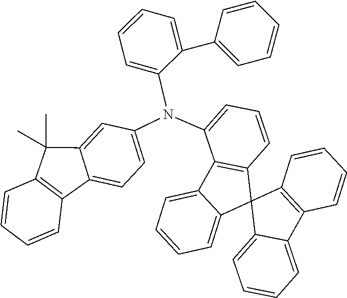 [SMILES: CC1(C)c2ccccc2-c2ccc(N(c3ccccc3-c3ccccc3)c3cccc4c3-c3ccccc3C43c4ccccc4-c4ccccc43)cc21]

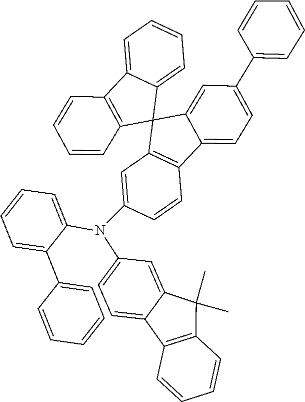 [SMILES: CC1(C)c2ccccc2-c2ccc(N(c3ccc4c(c3)C3(c5ccccc5-c5ccccc53)c3cc(-c5ccccc5)ccc3-4)c3ccccc3-c3ccccc3)cc21]

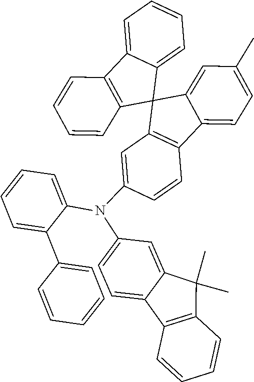 [SMILES: Cc1ccc2c(c1)C1(c3ccccc3-c3ccccc31)c1cc(N(c3ccc4c(c3)C(C)(C)c3ccccc3-4)c3ccccc3-c3ccccc3)ccc1-2]

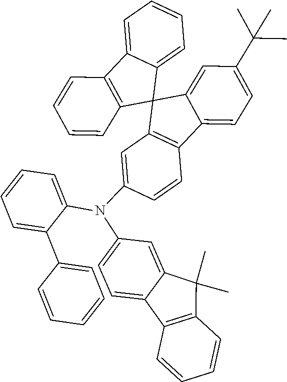 [SMILES: CC(C)(C)c1ccc2c(c1)C1(c3ccccc3-c3ccccc31)c1cc(N(c3ccc4c(c3)C(C)(C)c3ccccc3-4)c3ccccc3-c3ccccc3)ccc1-2]

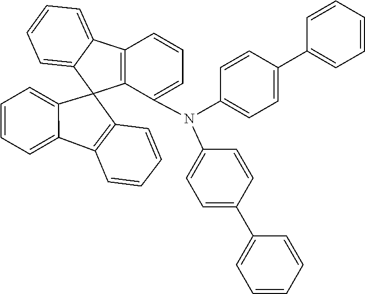 [SMILES: c1ccc(-c2ccc(N(c3ccc(-c4ccccc4)cc3)c3cccc4c3C3(c5ccccc5-c5ccccc53)c3ccccc3-4)cc2)cc1]

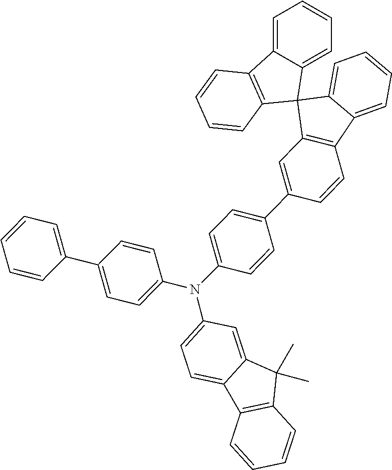 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

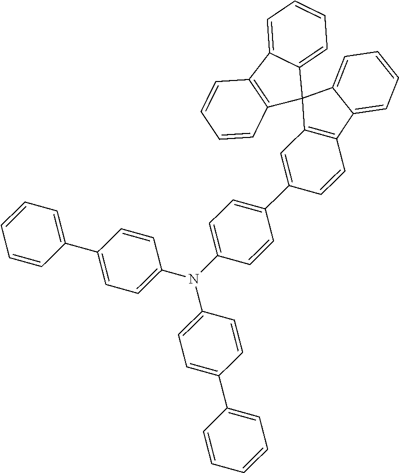 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1]

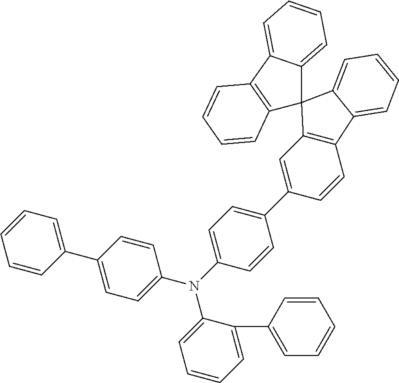 [SMILES: c1ccc(-c2ccc(N(c3ccc(-c4ccc5c(c4)C4(c6ccccc6-c6ccccc64)c4ccccc4-5)cc3)c3ccccc3-c3ccccc3)cc2)cc1]

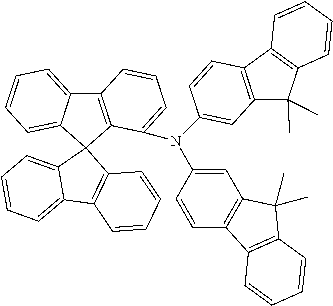 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21]

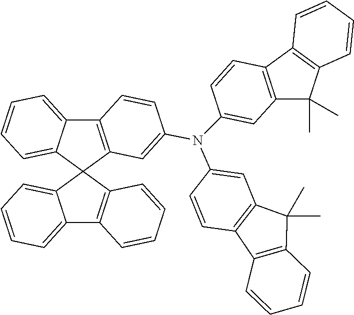 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21]

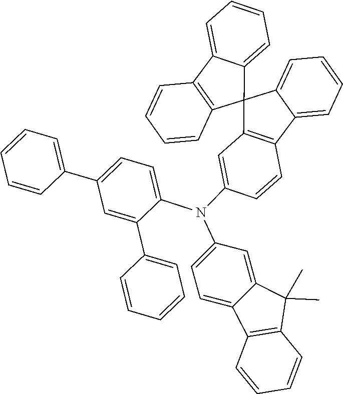 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21]

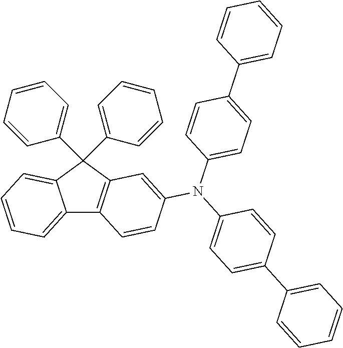 [SMILES: c1ccc(-c2ccc(N(c3ccc(-c4ccccc4)cc3)c3ccc4c(c3)C(c3ccccc3)(c3ccccc3)c3ccccc3-4)cc2)cc1]

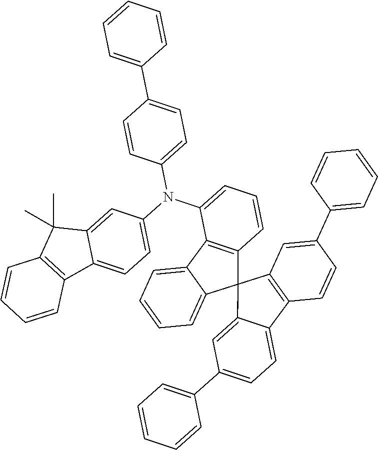 [SMILES: CC1(C)c2ccccc2-c2ccc(N(c3ccc(-c4ccccc4)cc3)c3cccc4c3-c3ccccc3C43c4cc(-c5ccccc5)ccc4-c4ccc(-c5ccccc5)cc43)cc21]

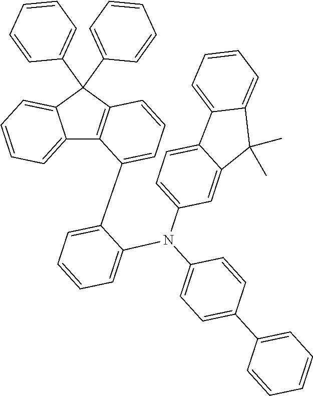 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21]

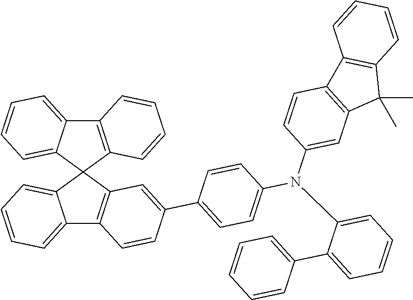 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21]

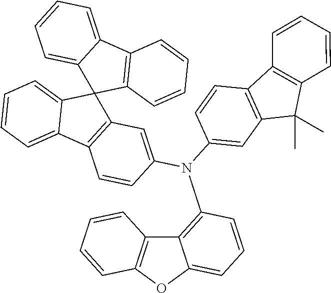 [SMILES: CC1(C)c2ccccc2-c2ccc(N(c3ccc4c(c3)C3(c5ccccc5-c5ccccc53)c3ccccc3-4)c3cccc4oc5ccccc5c34)cc21]

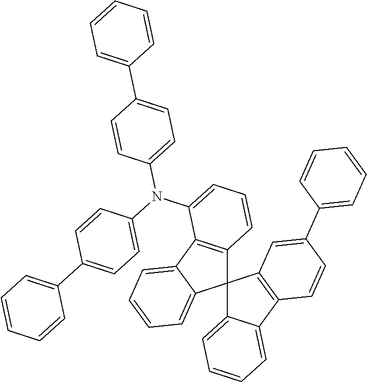 [SMILES: c1ccc(-c2ccc(N(c3ccc(-c4ccccc4)cc3)c3cccc4c3-c3ccccc3C43c4ccccc4-c4ccc(-c5ccccc5)cc43)cc2)cc1]

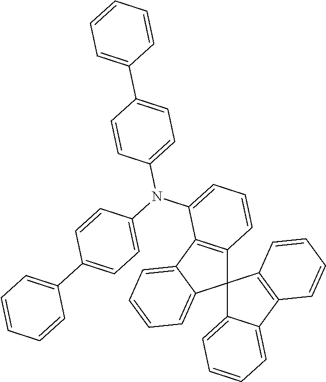 [SMILES: c1ccc(-c2ccc(N(c3ccc(-c4ccccc4)cc3)c3cccc4c3-c3ccccc3C43c4ccccc4-c4ccccc43)cc2)cc1]

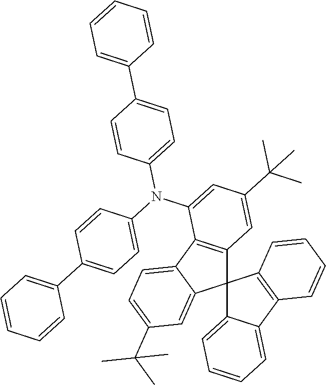 [SMILES: CC(C)(C)c1ccc2c(c1)C1(c3ccccc3-c3ccccc31)c1cc(C(C)(C)C)cc(N(c3ccc(-c4ccccc4)cc3)c3ccc(-c4ccccc4)cc3)c1-2]

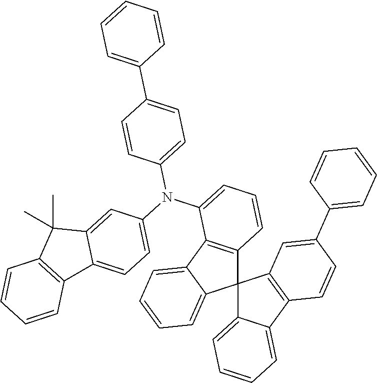 [SMILES: CC1(C)c2ccccc2-c2ccc(N(c3ccc(-c4ccccc4)cc3)c3cccc4c3-c3ccccc3C43c4ccccc4-c4ccc(-c5ccccc5)cc43)cc21]

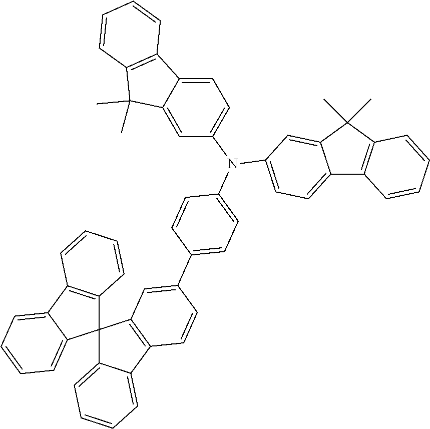 [SMILES: CC1(C)c2ccccc2-c2ccc(N(c3ccc(-c4ccc5c(c4)C4(c6ccccc6-c6ccccc64)c4ccccc4-5)cc3)c3ccc4c(c3)C(C)(C)c3ccccc3-4)cc21]

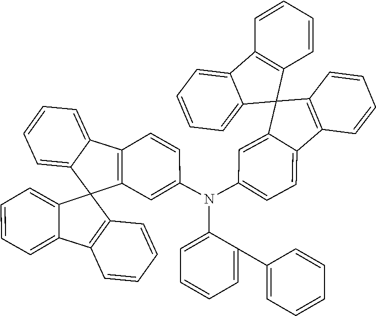 [SMILES: c1ccc(-c2ccccc2N(c2ccc3c(c2)C2(c4ccccc4-c4ccccc42)c2ccccc2-3)c2ccc3c(c2)C2(c4ccccc4-c4ccccc42)c2ccccc2-3)cc1]

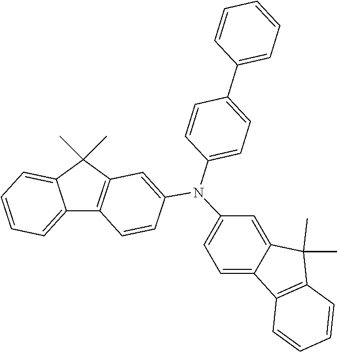 [SMILES: CC1(C)c2ccccc2-c2ccc(N(c3ccc(-c4ccccc4)cc3)c3ccc4c(c3)C(C)(C)c3ccccc3-4)cc21]

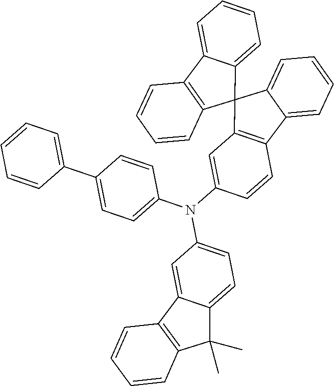 [SMILES: CC1(C)c2ccccc2-c2cc(N(c3ccc(-c4ccccc4)cc3)c3ccc4c(c3)C3(c5ccccc5-c5ccccc53)c3ccccc3-4)ccc21]

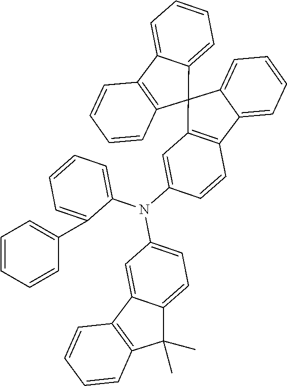 [SMILES: CC1(C)c2ccccc2-c2cc(N(c3ccc4c(c3)C3(c5ccccc5-c5ccccc53)c3ccccc3-4)c3ccccc3-c3ccccc3)ccc21]

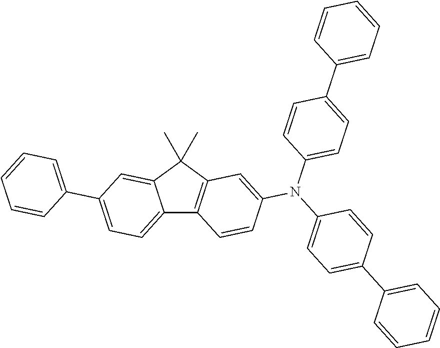 [SMILES: CC1(C)c2cc(-c3ccccc3)ccc2-c2ccc(N(c3ccc(-c4ccccc4)cc3)c3ccc(-c4ccccc4)cc3)cc21]

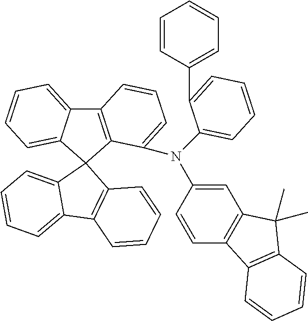 [SMILES: CC1(C)c2ccccc2-c2ccc(N(c3ccccc3-c3ccccc3)c3cccc4c3C3(c5ccccc5-c5ccccc53)c3ccccc3-4)cc21]

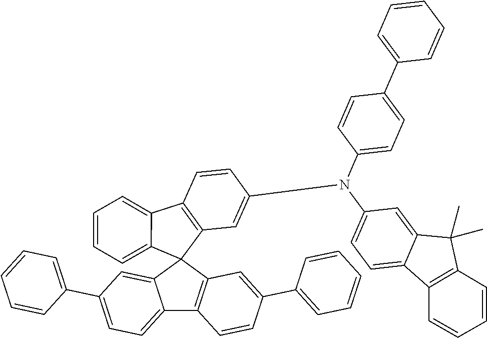 [SMILES: CC1(C)c2ccccc2-c2ccc(N(c3ccc(-c4ccccc4)cc3)c3ccc4c(c3)C3(c5ccccc5-4)c4cc(-c5ccccc5)ccc4-c4ccc(-c5ccccc5)cc43)cc21]

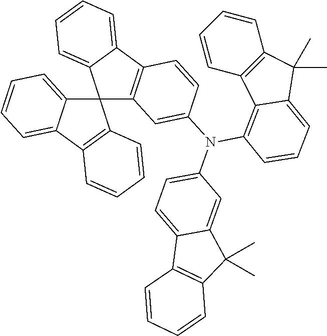 [SMILES: CC1(C)c2ccccc2-c2ccc(N(c3ccc4c(c3)C3(c5ccccc5-c5ccccc53)c3ccccc3-4)c3cccc4c3-c3ccccc3C4(C)C)cc21]

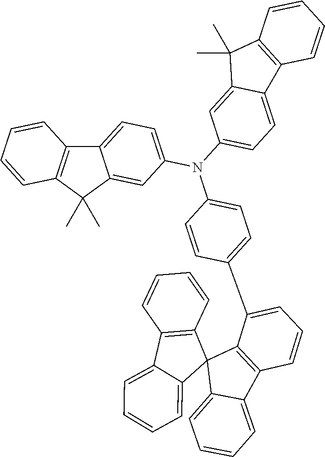 [SMILES: CC1(C)c2ccccc2-c2ccc(N(c3ccc(-c4cccc5c4C4(c6ccccc6-c6ccccc64)c4ccccc4-5)cc3)c3ccc4c(c3)C(C)(C)c3ccccc3-4)cc21]

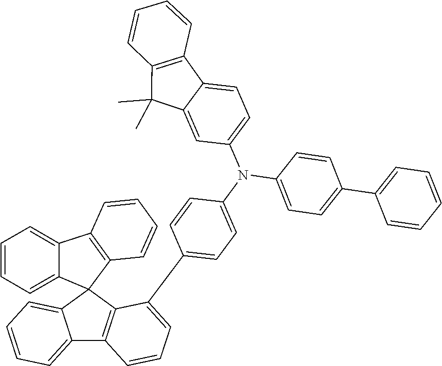 [SMILES: CC1(C)c2ccccc2-c2ccc(N(c3ccc(-c4ccccc4)cc3)c3ccc(-c4cccc5c4C4(c6ccccc6-c6ccccc64)c4ccccc4-5)cc3)cc21]

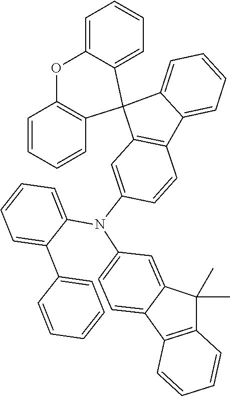 [SMILES: CC1(C)c2ccccc2-c2ccc(N(c3ccc4c(c3)C3(c5ccccc5Oc5ccccc53)c3ccccc3-4)c3ccccc3-c3ccccc3)cc21]

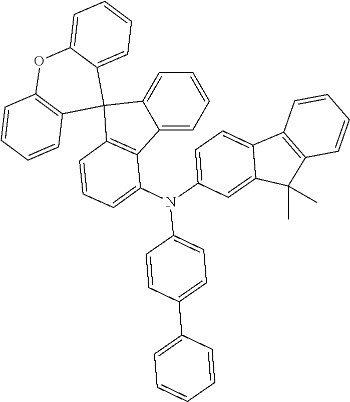 [SMILES: CC1(C)c2ccccc2-c2ccc(N(c3ccc(-c4ccccc4)cc3)c3cccc4c3-c3ccccc3C43c4ccccc4Oc4ccccc43)cc21]

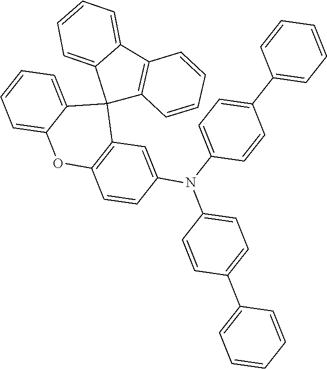 [SMILES: c1ccc(-c2ccc(N(c3ccc(-c4ccccc4)cc3)c3ccc4c(c3)C3(c5ccccc5O4)c4ccccc4-c4ccccc43)cc2)cc1]

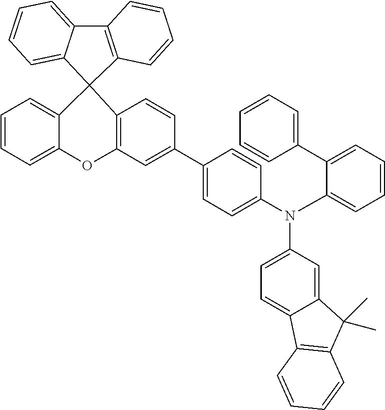 [SMILES: CC1(C)c2ccccc2-c2ccc(N(c3ccc(-c4ccc5c(c4)Oc4ccccc4C54c5ccccc5-c5ccccc54)cc3)c3ccccc3-c3ccccc3)cc21]

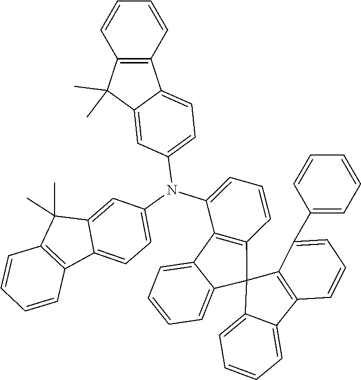 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21]

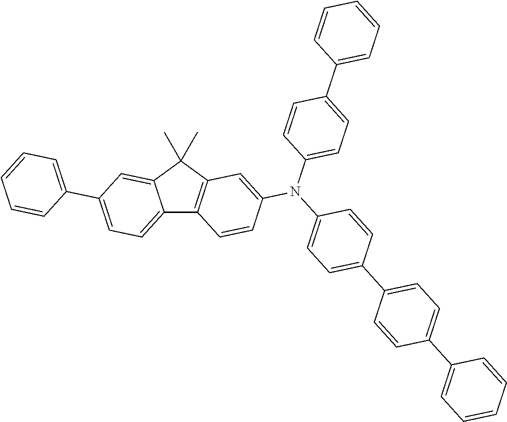 [SMILES: CC1(C)c2cc(-c3ccccc3)ccc2-c2ccc(N(c3ccc(-c4ccccc4)cc3)c3ccc(-c4ccc(-c5ccccc5)cc4)cc3)cc21]

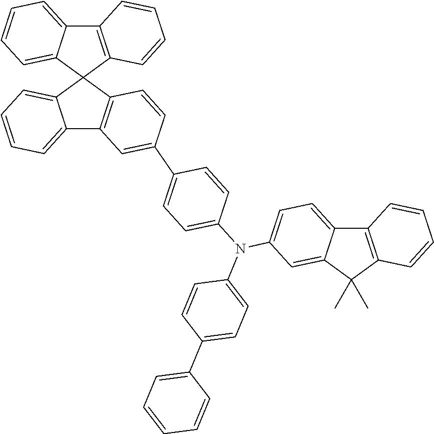 [SMILES: CC1(C)c2ccccc2-c2ccc(N(c3ccc(-c4ccccc4)cc3)c3ccc(-c4ccc5c(c4)-c4ccccc4C54c5ccccc5-c5ccccc54)cc3)cc21]

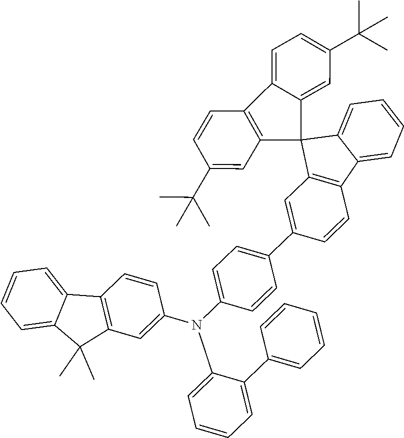 [SMILES: CC(C)(C)c1ccc2c(c1)C1(c3ccccc3-c3ccc(-c4ccc(N(c5ccc6c(c5)C(C)(C)c5ccccc5-6)c5ccccc5-c5ccccc5)cc4)cc31)c1cc(C(C)(C)C)ccc1-2]

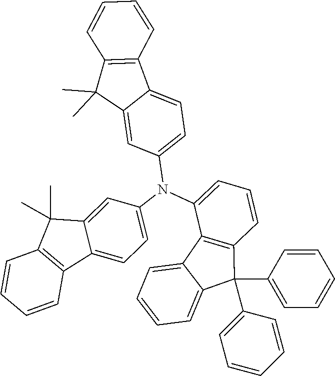 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21]

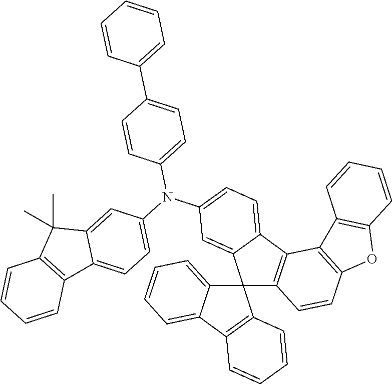 [SMILES: CC1(C)c2ccccc2-c2ccc(N(c3ccc(-c4ccccc4)cc3)c3ccc4c(c3)C3(c5ccccc5-c5ccccc53)c3ccc5oc6ccccc6c5c3-4)cc21]

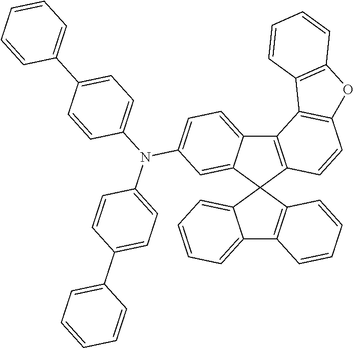 [SMILES: c1ccc(-c2ccc(N(c3ccc(-c4ccccc4)cc3)c3ccc4c(c3)C3(c5ccccc5-c5ccccc53)c3ccc5oc6ccccc6c5c3-4)cc2)cc1]

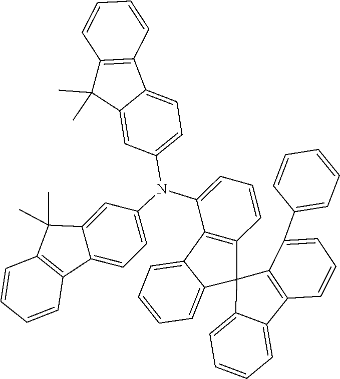 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21]

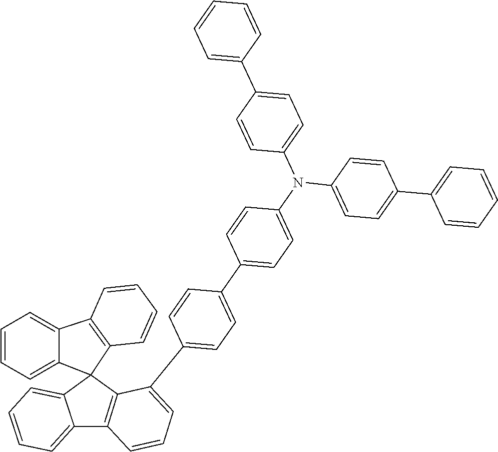 [SMILES: c1ccc(-c2ccc(N(c3ccc(-c4ccccc4)cc3)c3ccc(-c4ccc(-c5cccc6c5C5(c7ccccc7-c7ccccc75)c5ccccc5-6)cc4)cc3)cc2)cc1]

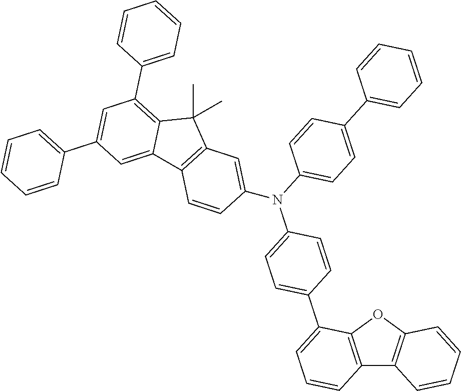 [SMILES: CC1(C)c2cc(N(c3ccc(-c4ccccc4)cc3)c3ccc(-c4cccc5c4oc4ccccc45)cc3)ccc2-c2cc(-c3ccccc3)cc(-c3ccccc3)c21]

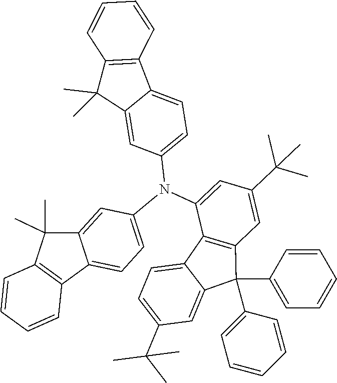 [SMILES: CC(C)(C)c1ccc2c(c1)C(c1ccccc1)(c1ccccc1)c1cc(C(C)(C)C)cc(N(c3ccc4c(c3)C(C)(C)c3ccccc3-4)c3ccc4c(c3)C(C)(C)c3ccccc3-4)c1-2]

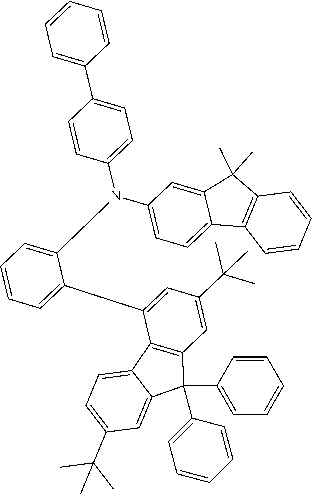 [SMILES: CC(C)(C)c1ccc2c(c1)C(c1ccccc1)(c1ccccc1)c1cc(C(C)(C)C)cc(-c3ccccc3N(c3ccc(-c4ccccc4)cc3)c3ccc4c(c3)C(C)(C)c3ccccc3-4)c1-2]

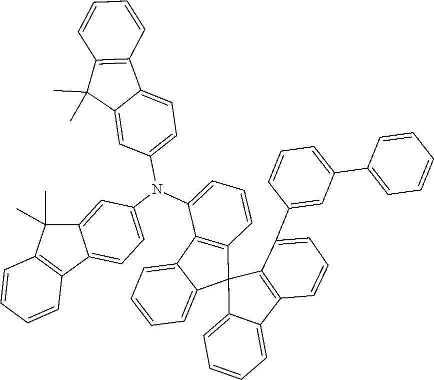 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5cccc(-c6ccccc6)c5)c43)cc21]

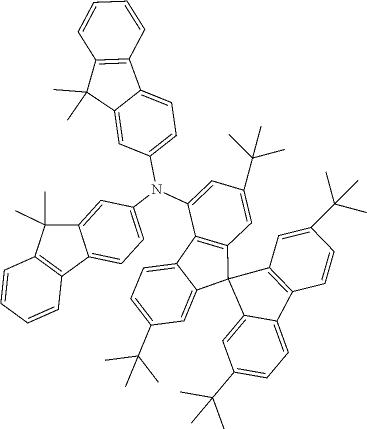 [SMILES: CC(C)(C)c1ccc2c(c1)C1(c3cc(C(C)(C)C)ccc3-2)c2cc(C(C)(C)C)ccc2-c2c(N(c3ccc4c(c3)C(C)(C)c3ccccc3-4)c3ccc4c(c3)C(C)(C)c3ccccc3-4)cc(C(C)(C)C)cc21]

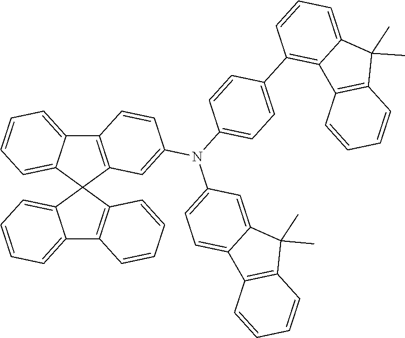 [SMILES: CC1(C)c2ccccc2-c2ccc(N(c3ccc(-c4cccc5c4-c4ccccc4C5(C)C)cc3)c3ccc4c(c3)C3(c5ccccc5-c5ccccc53)c3ccccc3-4)cc21]

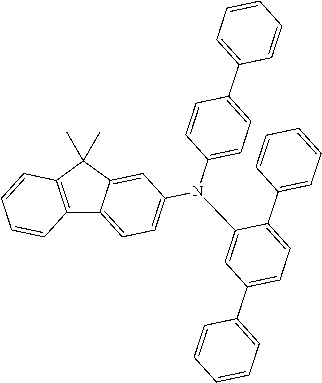 [SMILES: CC1(C)c2ccccc2-c2ccc(N(c3ccc(-c4ccccc4)cc3)c3cc(-c4ccccc4)ccc3-c3ccccc3)cc21]

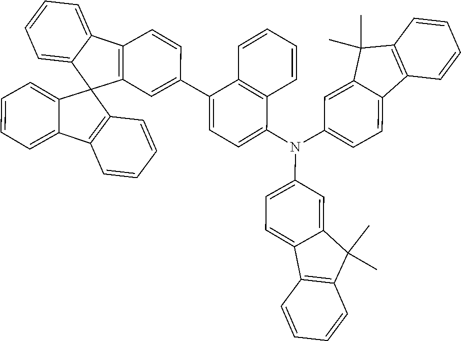 [SMILES: CC1(C)c2ccccc2-c2ccc(N(c3ccc4c(c3)C(C)(C)c3ccccc3-4)c3ccc(-c4ccc5c(c4)C4(c6ccccc6-c6ccccc64)c4ccccc4-5)c4ccccc34)cc21]

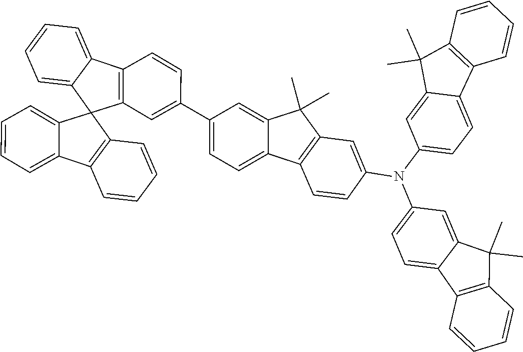 [SMILES: CC1(C)c2ccccc2-c2ccc(N(c3ccc4c(c3)C(C)(C)c3ccccc3-4)c3ccc4c(c3)C(C)(C)c3cc(-c5ccc6c(c5)C5(c7ccccc7-c7ccccc75)c5ccccc5-6)ccc3-4)cc21]

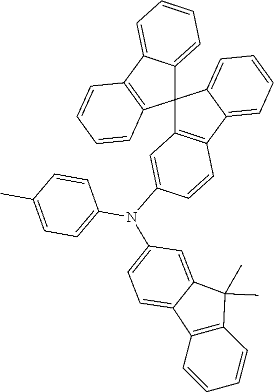 [SMILES: Cc1ccc(N(c2ccc3c(c2)C(C)(C)c2ccccc2-3)c2ccc3c(c2)C2(c4ccccc4-c4ccccc42)c2ccccc2-3)cc1]

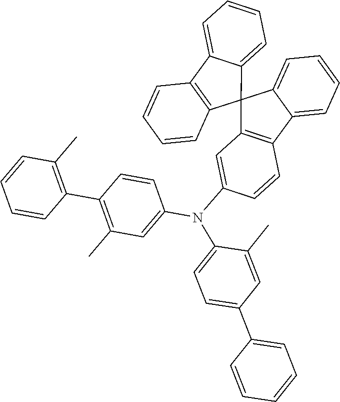 [SMILES: Cc1ccccc1-c1ccc(N(c2ccc3c(c2)C2(c4ccccc4-c4ccccc42)c2ccccc2-3)c2ccc(-c3ccccc3)cc2C)cc1C]

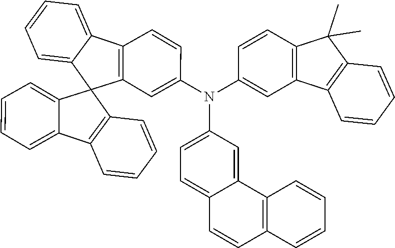 [SMILES: CC1(C)c2ccccc2-c2cc(N(c3ccc4c(c3)C3(c5ccccc5-c5ccccc53)c3ccccc3-4)c3ccc4ccc5ccccc5c4c3)ccc21]

Certain of the above compounds, and further compounds which are suitable for use as compound C1 according to the present application are disclosed in the following publications, together with methods for making the compounds and their use in OLED devices: WO95/09147, WO2010/098458, WO2014/034795, KR2017-0136391, US2014-225073, US2022-115596, WO2012/034627, WO2013/120577, WO2014/015938, WO2019/115577, and in Prior Art Publishing, Prior Art Journal, 2016, No. 6, p. 46-251.

The following definitions apply to the chemical groups used as general definitions. They apply insofar as no more specific definitions are given.

An aryl group here is taken to mean either a single aromatic ring, for example benzene, or a condensed aromatic polycycle, for example naphthalene, phenanthrene, or anthracene. A condensed aromatic polycycle in the sense of the present application consists of two or more single aromatic rings which are condensed with one another. An aryl group in the sense of this invention contains 6 to 40 aromatic ring atoms. An aryl group does not contain any heteroatoms as aromatic ring atoms, but only carbon atoms.

A heteroaryl group here is taken to mean either a single heteroaromatic ring, such as pyridine, pyrimidine or thiophene, or a condensed heteroaromatic polycycle, such as quinoline or carbazole. A condensed heteroaromatic polycycle in the sense of the present application consists of two or more single aromatic or heteroaromatic rings, which are condensed with one another, where at least one of the two or more single aromatic or heteroaromatic rings is a heteroaromatic ring. A heteroaryl group in the sense of this invention contains 5 to 40 aromatic ring atoms, at least one of which is a heteroatom. The heteroatoms are preferably selected from N, O and S.

An aryl or heteroaryl group, which may in each case be substituted by the above-mentioned radicals, is taken to mean, in particular, a group derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, benzimidazolo[1,2-a]benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-tri-azole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-tri-azine, tetrazole, 1,2,4,5-tetrazine, 1,2,3,4-tetrazine, 1,2,3,5-tetrazine, purine, pteridine, indolizine and benzothiadiazole.

An aromatic ring system in the sense of this invention is a system which does not necessarily contain only aryl groups, but which may additionally contain one or more non-aromatic rings, which are condensed with at least one aryl group. Such non-aromatic rings contain exclusively carbon atoms as ring atoms. Examples of groups embraced by such definition are tetrahydronaphthalene, fluorene, and spirobifluorene. Furthermore, the term aromatic ring system is understood to embrace systems consisting of two or more aromatic ring systems which are connected to each other via single bonds, such as biphenyl, terphenyl, 7-phenyl-2-fluorenyl and quaterphenyl. An aromatic ring system in the sense of this invention contains 6 to 40 C atoms and no heteroatoms as ring atoms of the ring system. An aromatic ring system in the sense of this application does not comprise any heteroaryl groups, as defined above.

A heteroaromatic ring system is defined in analogy to the aromatic ring system above, but with the difference that it must obtain at least one heteroatom as one of the ring atoms. As it is the case for the aromatic ring system, it does not necessarily contain only aryl and heteroaryl groups, but it may additionally contain one or more non-aromatic rings, which are condensed with at least one aryl or heteroaryl group. The non-aromatic rings may contain only carbon atoms as ring atoms, or they may contain additionally one or more heteroatoms, where the heteroatoms are preferably selected from N, O and S. An example for such a heteroaromatic ring system is benzpyranyl. Furthermore, the term heteroaromatic ring system is understood to embrace systems consisting of two or more aromatic or heteroaromatic ring systems, which are connected to each other via single bonds, such as 4,6-diphenyl-2-triazinyl. A heteroaromatic ring system in the sense of this invention contains 5 to 40 ring atoms, which are selected from carbon and heteroatoms, where at least one of the ring atoms is a heteroatom. The heteroatoms are preferably selected from N, O or S.

The terms “heteroaromatic ring system” and “aromatic ring system” according to the definition of the present application differ from each other by the fact that the aromatic ring system cannot comprise any heteroatom as ring atom, whereas the heteroaromatic ring system must comprise at least one heteroatom as ring atom. Such heteroatom may be present as a ring atom of a non-aromatic heterocyclic ring of the system, or as a ring atom of an aromatic heterocyclic ring of the system.

According to the above, any aryl group, as defined above, is embraced by the term “aromatic ring system”, as defined above, and any heteroaryl group, as defined above, is embraced by the term “heteroaromatic ring system”, as defined above.

An aromatic ring system having 6 to 40 aromatic ring atoms or a heteroaro-matic ring system having 5 to 40 aromatic ring atoms is in particular a group which is derived from the above-mentioned aryl or heteroaryl groups, or from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, and indenocarbazole, or from any combinations of these groups.

For the purposes of the present invention, a straight-chain alkyl group having 1 to 20 C atoms or a branched or cyclic alkyl group having 3 to 20 C atoms or an alkenyl or alkynyl group having 2 to 20 C atoms, in which, in addition, individual H atoms or CH₂ groups may be substituted by the groups mentioned above under the definition of the radicals, is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl.

An alkoxy or thioalkyl group having 1 to 20 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyl-oxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptyl-thio, cycloheptylthio, n-octylthio, cyclooctylthio, 2-ethylhexylthio, trifluoro-methylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenyl-thio, ethynylthio, propynylthio, butynylthio, pentynylthio, hexynylthio, heptynylthio or octynylthio.

The phrase “two or more radicals may be connected to each other to form a ring” shall be understood to include the case that the two radicals are connected by a chemical bond. Additionally, the phrase shall be understood to include the case that one of the two radicals is H, this radical H is removed, and the other of the two radicals forms a ring by being connected to the position, to which this radical H was initially bonded.

The drawing of a group as follows

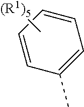

is understood to mean that the indexed number of radicals R¹ (here five), where the radicals R¹ can be identical or different at each occurrence, is bonded to the benzene ring, as shown below:

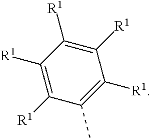

This manner of drawing is used elsewhere in this application as well, and is to be understood in each case in analogy to the above.

Compound C2 preferably has a HOMO of less than −5.2 eV, preferably of less than −5.3 eV, determined as stated in section E) of the working examples below.

Compound C2 preferably is a compound which does not transport holes in the layer A of the stack of layers of the electronic device. Hole conductivity of the layer A is therefore reduced by the addition of higher amounts of compound C2.

Compound C2 is preferably selected from triazine derivatives, pyrimidine derivatives, pyridine derivatives, quinoxaline derivatives, phosphine oxide derivatives, imidazole derivatives, oxazole derivatives, triphenylene derivatives, phenanthrene derivatives, phenanthroline derivatives, fluorene derivatives, spirobifluorene derivatives, xanthene derivatives, anthracene derivatives, naphthalene derivatives, dibenzofurane derivatives, indolocarbazole derivatives, indenocarbazole derivatives, and carbazole derivatives.

Preferred compounds C2 are selected from compounds of the following formulae:

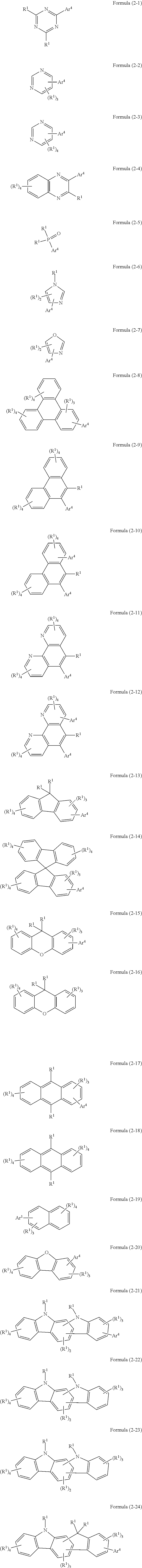

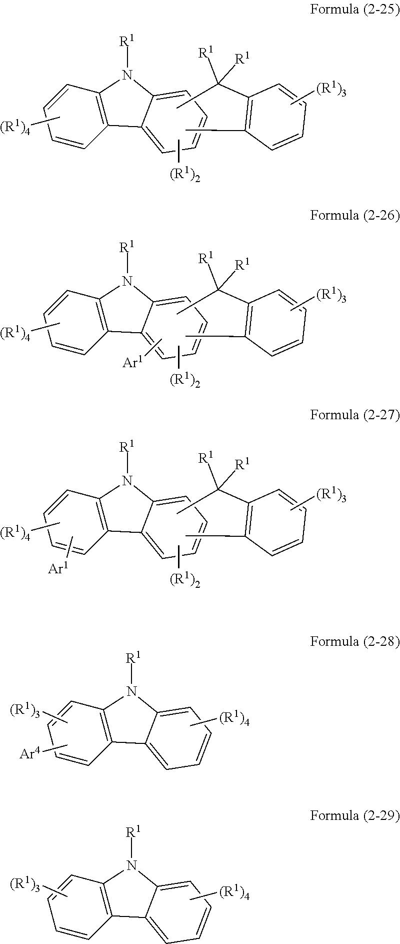

where R¹, R² and R³ are defined as above, and preferably correspond to their preferred embodiments, and where
Ar⁴ is selected from aromatic ring systems having 6 to 50 aromatic ring atoms, which are substituted with radicals R¹, and heteroaromatic ring systems having 5 to 50 aromatic ring atoms, which are substituted with radicals R¹.

Particularly preferred among the formulae above are formulae (2-1) to (2-3), and (2-8).

According to a preferred embodiment of the invention, compound C2 corresponds to a formula selected from the following formulae

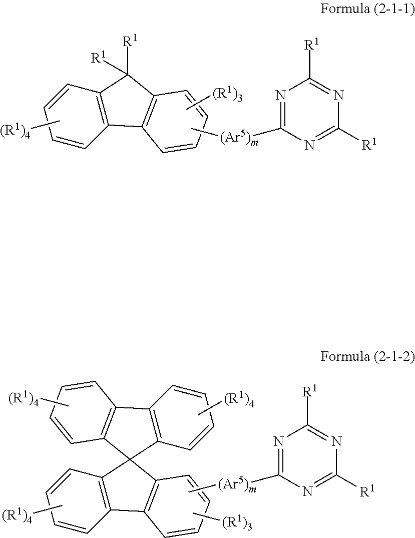

where R¹, R² and R³ are defined as above, and preferably correspond to their preferred embodiments mentioned above, and Ar⁵ is selected from aromatic ring systems having 6 to 20 aromatic ring atoms, which are substituted with radicals R¹, and heteroaromatic ring systems having 5 to 20 aromatic ring atoms, which are substituted with radicals R¹, and index m is 0 or 1, where m=0 means that the group Ar⁵ is not present and the two groups bonding to (Ar⁵)ₘ are directly bonded to each other.

In the structures (1-21) to (1-27), there are two bonds which are drawn into the middle ring, where the exact location of their attachment to the middle ring is not specified. This is to be understood to mean that indenocarbazole and indolocarbazole groups, respectively, are formed, as any of their positional isomers. The two bonds therefore can be attached at any position on the middle ring, where preferably, the attachment positions of the two bonds are ortho to each other on the middle ring.

Preferably, compound C2 does not comprise any carbazole group. Further, preferably, compound C2 does not comprise any triarylamine group, more preferably no amino group.

Preferred specific compounds which can be used as compound C2 according to the present application are shown in the following table:

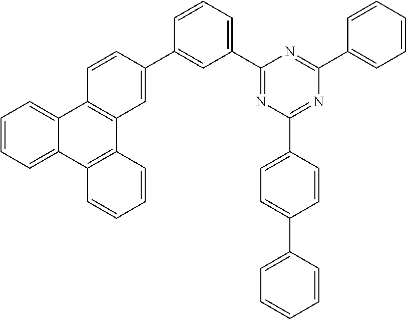 [SMILES: c1ccc(-c2ccc(-c3nc(-c4ccccc4)nc(-c4cccc(-c5ccc6c7ccccc7c7ccccc7c6c5)c4)n3)cc2)cc1]

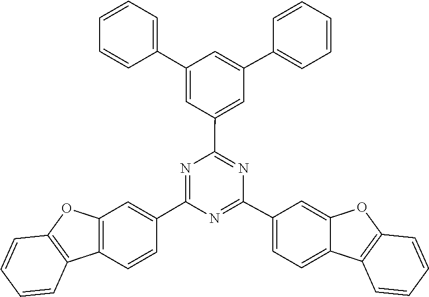 [SMILES: c1ccc(-c2cc(-c3ccccc3)cc(-c3nc(-c4ccc5c(c4)oc4ccccc45)nc(-c4ccc5c(c4)oc4ccccc45)n3)c2)cc1]

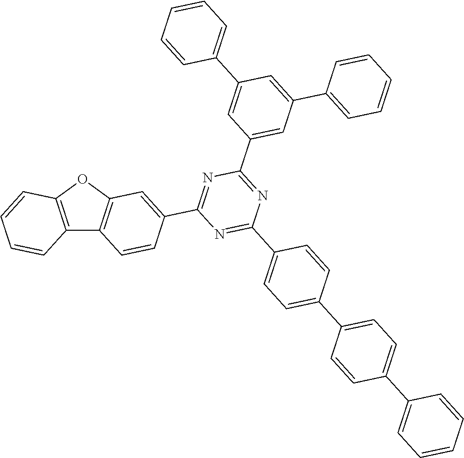 [SMILES: c1ccc(-c2ccc(-c3ccc(-c4nc(-c5cc(-c6ccccc6)cc(-c6ccccc6)c5)nc(-c5ccc6c(c5)oc5ccccc56)n4)cc3)cc2)cc1]

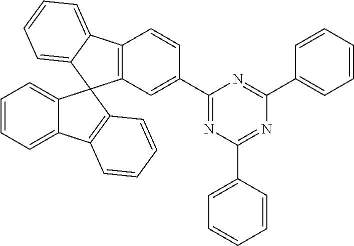 [SMILES: c1ccc(-c2nc(-c3ccccc3)nc(-c3ccc4c(c3)C3(c5ccccc5-c5ccccc53)c3ccccc3-4)n2)cc1]

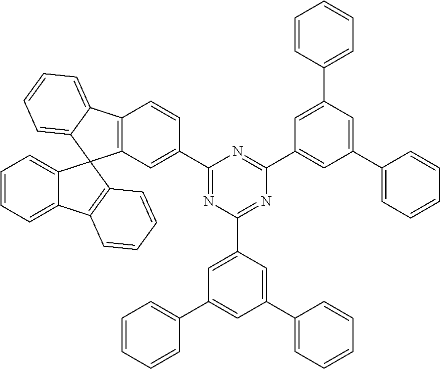 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

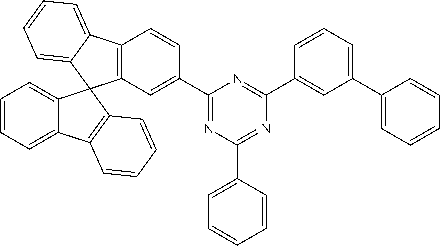 [SMILES: c1ccc(-c2cccc(-c3nc(-c4ccccc4)nc(-c4ccc5c(c4)C4(c6ccccc6-c6ccccc64)c4ccccc4-5)n3)c2)cc1]

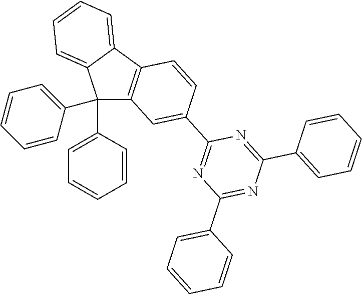 [SMILES: c1ccc(-c2nc(-c3ccccc3)nc(-c3ccc4c(c3)C(c3ccccc3)(c3ccccc3)c3ccccc3-4)n2)cc1]

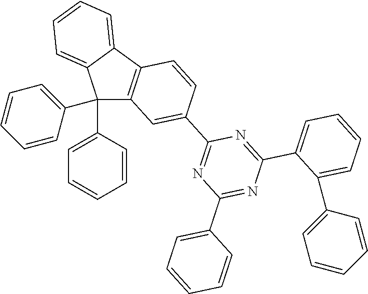 [SMILES: c1ccc(-c2nc(-c3ccc4c(c3)C(c3ccccc3)(c3ccccc3)c3ccccc3-4)nc(-c3ccccc3-c3ccccc3)n2)cc1]

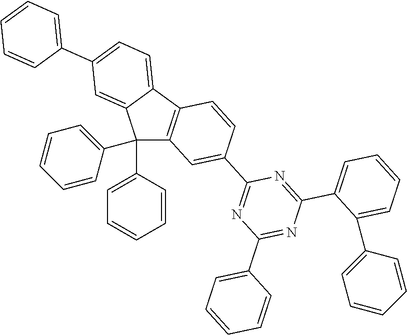 [SMILES: c1ccc(-c2ccc3c(c2)C(c2ccccc2)(c2ccccc2)c2cc(-c4nc(-c5ccccc5)nc(-c5ccccc5-c5ccccc5)n4)ccc2-3)cc1]

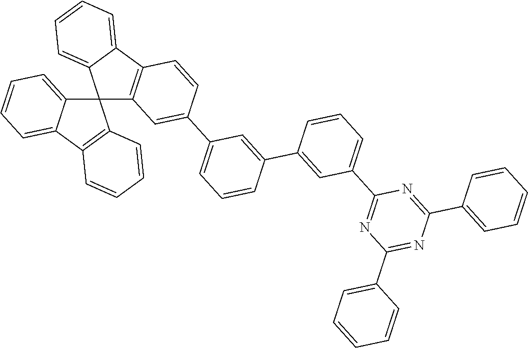 [SMILES: c1ccc(-c2nc(-c3ccccc3)nc(-c3cccc(-c4cccc(-c5ccc6c(c5)C5(c7ccccc7-c7ccccc75)c5ccccc5-6)c4)c3)n2)cc1]

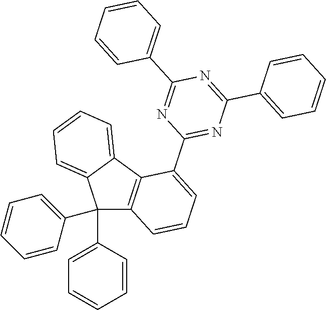 [SMILES: c1ccc(-c2nc(-c3ccccc3)nc(-c3cccc4c3-c3ccccc3C4(c3ccccc3)c3ccccc3)n2)cc1]

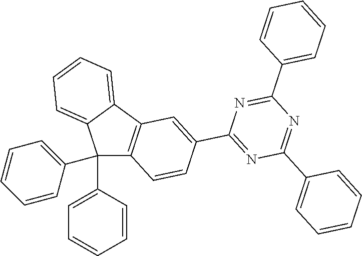 [SMILES: c1ccc(-c2nc(-c3ccccc3)nc(-c3ccc4c(c3)-c3ccccc3C4(c3ccccc3)c3ccccc3)n2)cc1]

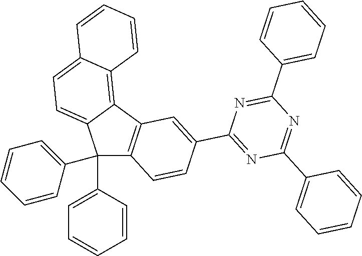 [SMILES: c1ccc(-c2nc(-c3ccccc3)nc(-c3ccc4c(c3)-c3c(ccc5ccccc35)C4(c3ccccc3)c3ccccc3)n2)cc1]

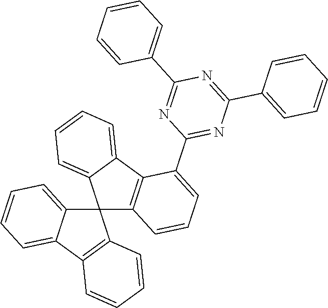 [SMILES: c1ccc(-c2nc(-c3ccccc3)nc(-c3cccc4c3-c3ccccc3C43c4ccccc4-c4ccccc43)n2)cc1]

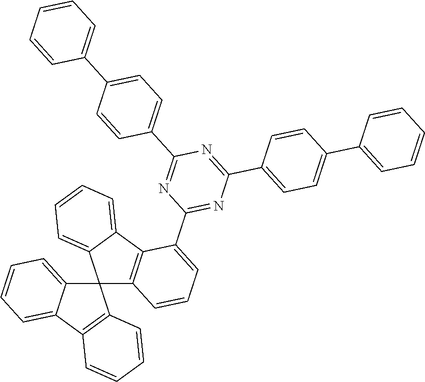 [SMILES: c1ccc(-c2ccc(-c3nc(-c4ccc(-c5ccccc5)cc4)nc(-c4cccc5c4-c4ccccc4C54c5ccccc5-c5ccccc54)n3)cc2)cc1]

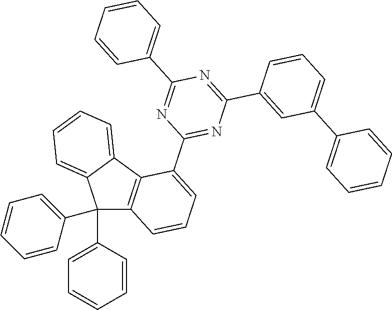 [SMILES: c1ccc(-c2cccc(-c3nc(-c4ccccc4)nc(-c4cccc5c4-c4ccccc4C5(c4ccccc4)c4ccccc4)n3)c2)cc1]

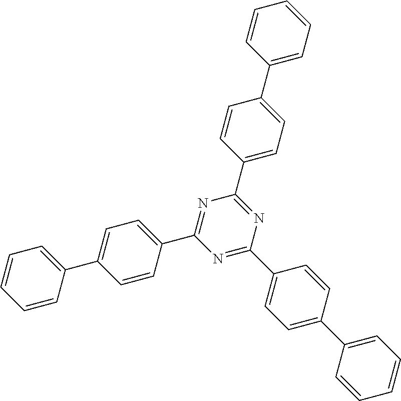 [SMILES: c1ccc(-c2ccc(-c3nc(-c4ccc(-c5ccccc5)cc4)nc(-c4ccc(-c5ccccc5)cc4)n3)cc2)cc1]

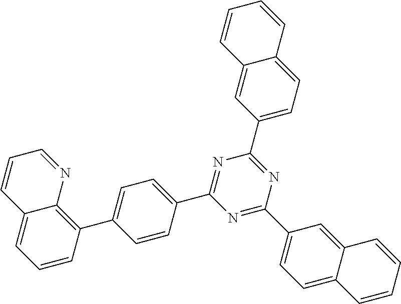 [SMILES: c1ccc2cc(-c3nc(-c4ccc(-c5cccc6cccnc56)cc4)nc(-c4ccc5ccccc5c4)n3)ccc2c1]

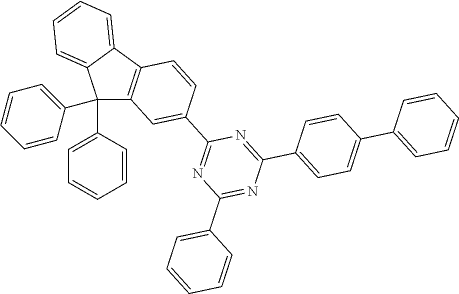 [SMILES: c1ccc(-c2ccc(-c3nc(-c4ccccc4)nc(-c4ccc5c(c4)C(c4ccccc4)(c4ccccc4)c4ccccc4-5)n3)cc2)cc1]

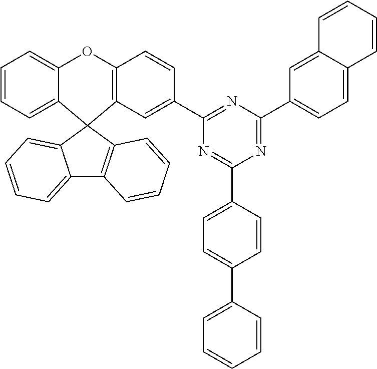 [SMILES: c1ccc(-c2ccc(-c3nc(-c4ccc5c(c4)C4(c6ccccc6O5)c5ccccc5-c5ccccc54)nc(-c4ccc5ccccc5c4)n3)cc2)cc1]

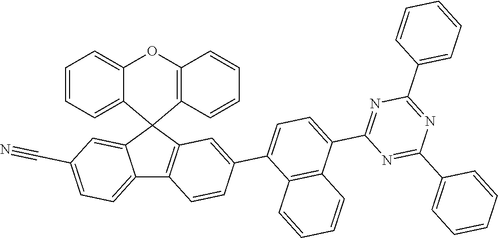 [SMILES: N#Cc1ccc2c(c1)C1(c3ccccc3Oc3ccccc31)c1cc(-c3ccc(-c4nc(-c5ccccc5)nc(-c5ccccc5)n4)c4ccccc34)ccc1-2]

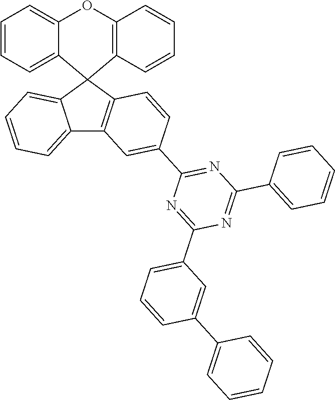 [SMILES: c1ccc(-c2cccc(-c3nc(-c4ccccc4)nc(-c4ccc5c(c4)-c4ccccc4C54c5ccccc5Oc5ccccc54)n3)c2)cc1]

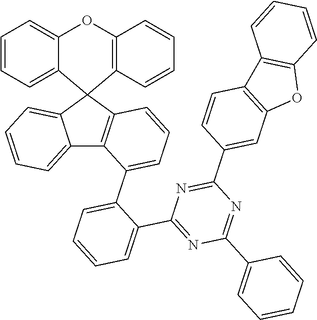 [SMILES: c1ccc(-c2nc(-c3ccc4c(c3)oc3ccccc34)nc(-c3ccccc3-c3cccc4c3-c3ccccc3C43c4ccccc4Oc4ccccc43)n2)cc1]

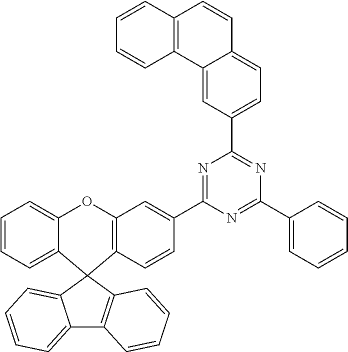 [SMILES: c1ccc(-c2nc(-c3ccc4c(c3)Oc3ccccc3C43c4ccccc4-c4ccccc43)nc(-c3ccc4ccc5ccccc5c4c3)n2)cc1]

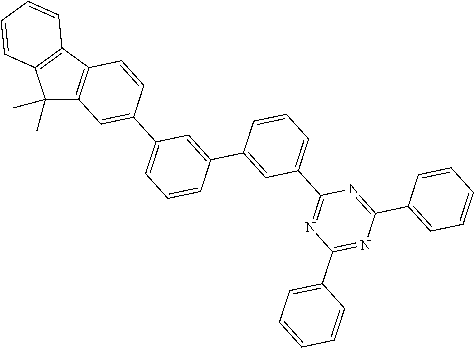 [SMILES: CC1(C)c2ccccc2-c2ccc(-c3cccc(-c4cccc(-c5nc(-c6ccccc6)nc(-c6ccccc6)n5)c4)c3)cc21]

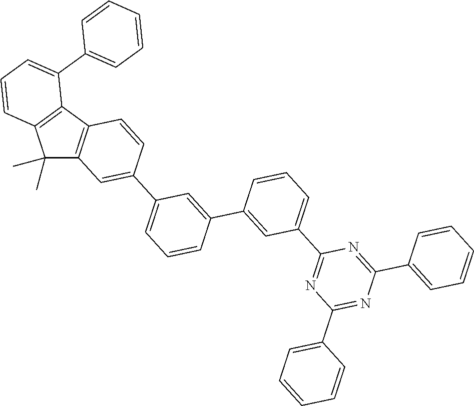 [SMILES: CC1(C)c2cc(-c3cccc(-c4cccc(-c5nc(-c6ccccc6)nc(-c6ccccc6)n5)c4)c3)ccc2-c2c(-c3ccccc3)cccc21]

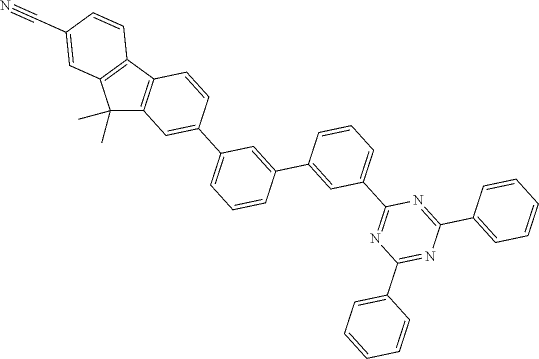 [SMILES: CC1(C)c2cc(C#N)ccc2-c2ccc(-c3cccc(-c4cccc(-c5nc(-c6ccccc6)nc(-c6ccccc6)n5)c4)c3)cc21]

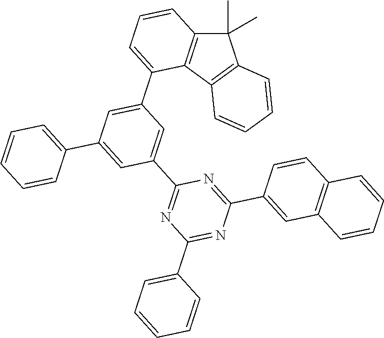 [SMILES: CC1(C)c2ccccc2-c2c(-c3cc(-c4ccccc4)cc(-c4nc(-c5ccccc5)nc(-c5ccc6ccccc6c5)n4)c3)cccc21]

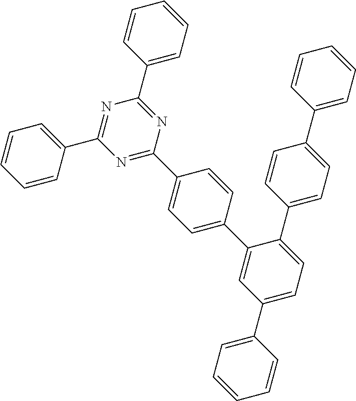 [SMILES: c1ccc(-c2ccc(-c3ccc(-c4ccccc4)cc3-c3ccc(-c4nc(-c5ccccc5)nc(-c5ccccc5)n4)cc3)cc2)cc1]

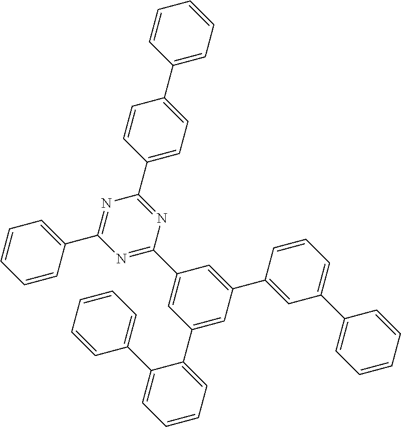 [SMILES: c1ccc(-c2ccc(-c3nc(-c4ccccc4)nc(-c4cc(-c5cccc(-c6ccccc6)c5)cc(-c5ccccc5-c5ccccc5)c4)n3)cc2)cc1]

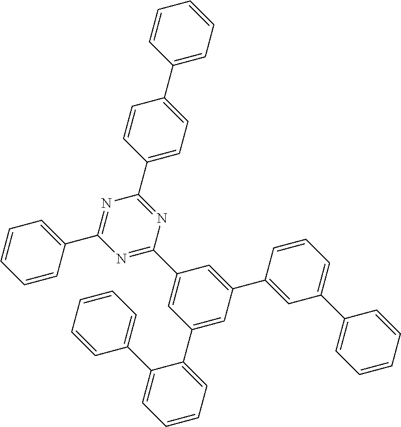 [SMILES: c1ccc(-c2ccc(-c3nc(-c4ccccc4)nc(-c4cc(-c5cccc(-c6ccccc6)c5)cc(-c5ccccc5-c5ccccc5)c4)n3)cc2)cc1]

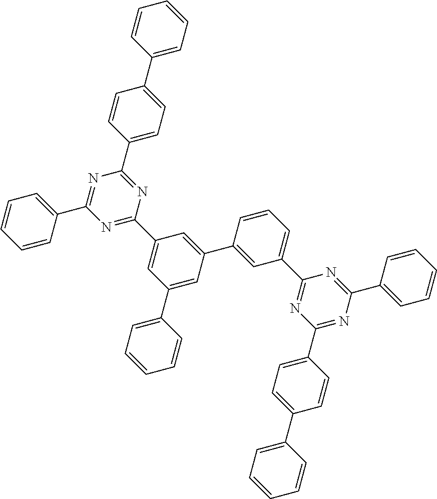 [SMILES: c1ccc(-c2ccc(-c3nc(-c4ccccc4)nc(-c4cccc(-c5cc(-c6ccccc6)cc(-c6nc(-c7ccccc7)nc(-c7ccc(-c8ccccc8)cc7)n6)c5)c4)n3)cc2)cc1]

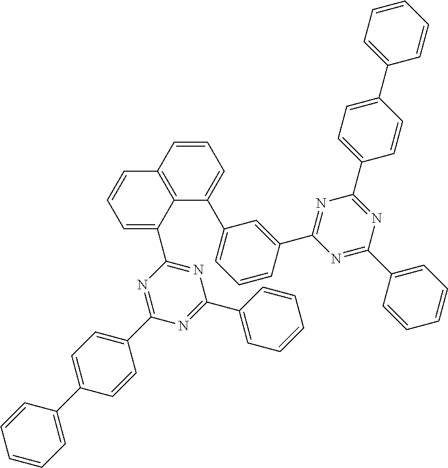 [SMILES: c1ccc(-c2ccc(-c3nc(-c4ccccc4)nc(-c4cccc(-c5cccc6cccc(-c7nc(-c8ccccc8)nc(-c8ccc(-c9ccccc9)cc8)n7)c56)c4)n3)cc2)cc1]

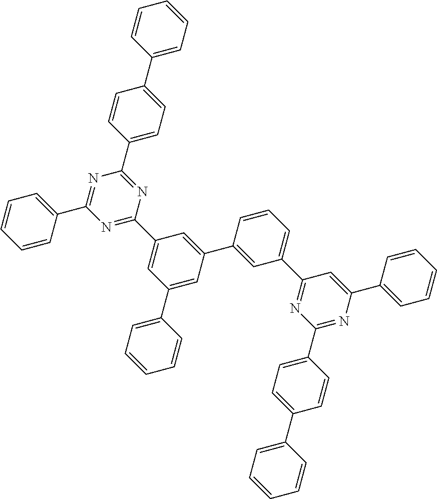 [SMILES: c1ccc(-c2ccc(-c3nc(-c4ccccc4)cc(-c4cccc(-c5cc(-c6ccccc6)cc(-c6nc(-c7ccccc7)nc(-c7ccc(-c8ccccc8)cc7)n6)c5)c4)n3)cc2)cc1]

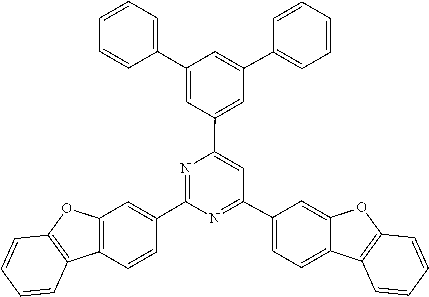 [SMILES: c1ccc(-c2cc(-c3ccccc3)cc(-c3cc(-c4ccc5c(c4)oc4ccccc45)nc(-c4ccc5c(c4)oc4ccccc45)n3)c2)cc1]

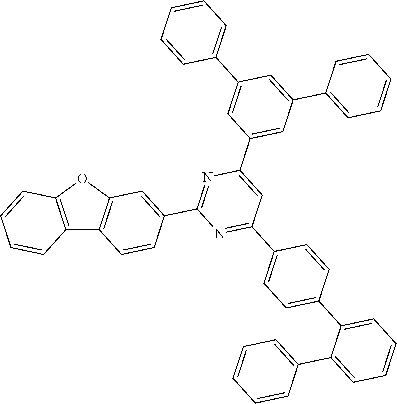 [SMILES: c1ccc(-c2cc(-c3ccccc3)cc(-c3cc(-c4ccc(-c5ccccc5-c5ccccc5)cc4)nc(-c4ccc5c(c4)oc4ccccc45)n3)c2)cc1]

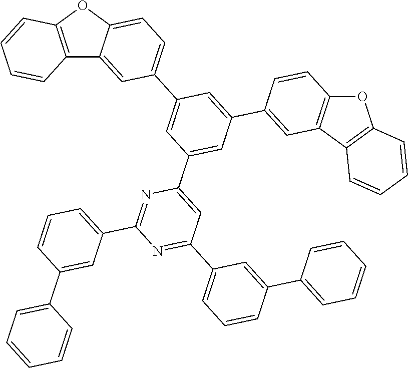 [SMILES: c1ccc(-c2cccc(-c3cc(-c4cc(-c5ccc6oc7ccccc7c6c5)cc(-c5ccc6oc7ccccc7c6c5)c4)nc(-c4cccc(-c5ccccc5)c4)n3)c2)cc1]

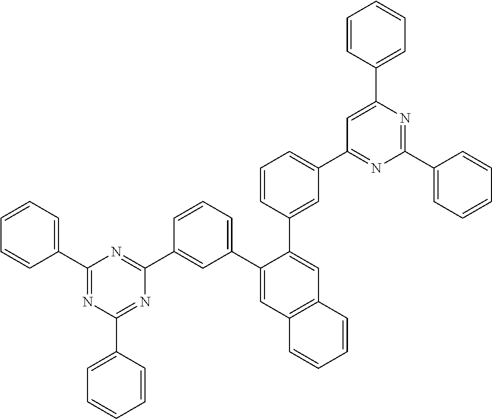 [SMILES: c1ccc(-c2cc(-c3cccc(-c4cc5ccccc5cc4-c4cccc(-c5nc(-c6ccccc6)nc(-c6ccccc6)n5)c4)c3)nc(-c3ccccc3)n2)cc1]

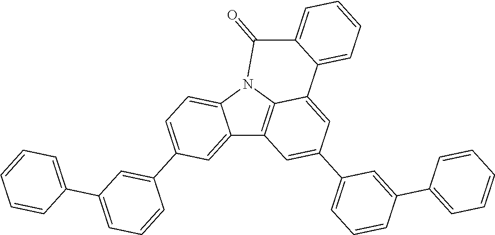 [SMILES: O=c1c2ccccc2c2cc(-c3cccc(-c4ccccc4)c3)cc3c4cc(-c5cccc(-c6ccccc6)c5)ccc4n1c23]

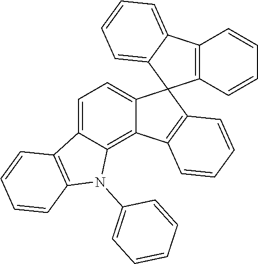 [SMILES: c1ccc(-n2c3ccccc3c3ccc4c(c32)-c2ccccc2C42c3ccccc3-c3ccccc32)cc1]

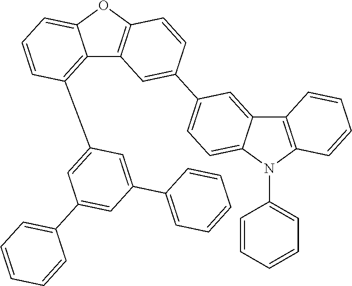 [SMILES: c1ccc(-c2cc(-c3ccccc3)cc(-c3cccc4oc5ccc(-c6ccc7c(c6)c6ccccc6n7-c6ccccc6)cc5c34)c2)cc1]

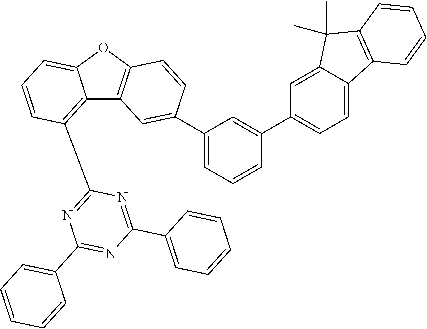 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21]

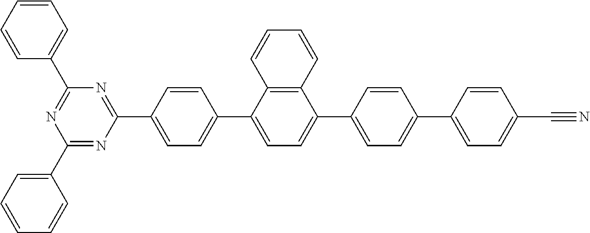 [SMILES: N#Cc1ccc(-c2ccc(-c3ccc(-c4ccc(-c5nc(-c6ccccc6)nc(-c6ccccc6)n5)cc4)c4ccccc34)cc2)cc1]

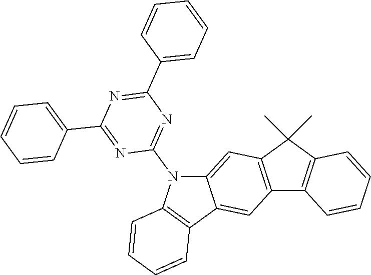 [SMILES: CC1(C)c2ccccc2-c2cc3c4ccccc4n(-c4nc(-c5ccccc5)nc(-c5ccccc5)n4)c3cc21]

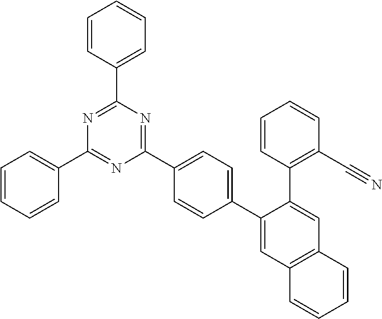 [SMILES: N#Cc1ccccc1-c1cc2ccccc2cc1-c1ccc(-c2nc(-c3ccccc3)nc(-c3ccccc3)n2)cc1]

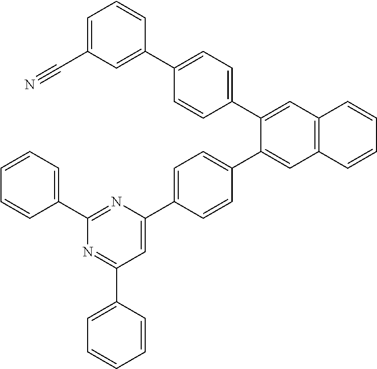 [SMILES: N#Cc1cccc(-c2ccc(-c3cc4ccccc4cc3-c3ccc(-c4cc(-c5ccccc5)nc(-c5ccccc5)n4)cc3)cc2)c1]

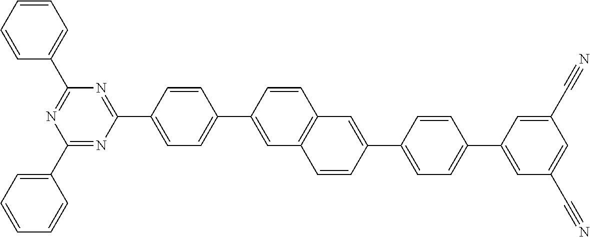 [SMILES: N#Cc1cc(C#N)cc(-c2ccc(-c3ccc4cc(-c5ccc(-c6nc(-c7ccccc7)nc(-c7ccccc7)n6)cc5)ccc4c3)cc2)c1]

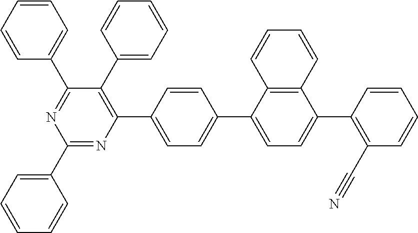 [SMILES: N#Cc1ccccc1-c1ccc(-c2ccc(-c3nc(-c4ccccc4)nc(-c4ccccc4)c3-c3ccccc3)cc2)c2ccccc12]

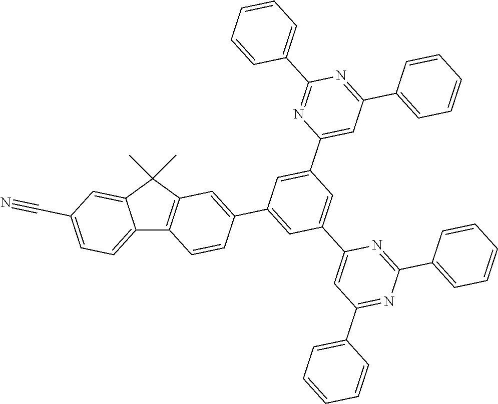 [SMILES: CC1(C)c2cc(C#N)ccc2-c2ccc(-c3cc(-c4cc(-c5ccccc5)nc(-c5ccccc5)n4)cc(-c4cc(-c5ccccc5)nc(-c5ccccc5)n4)c3)cc21]

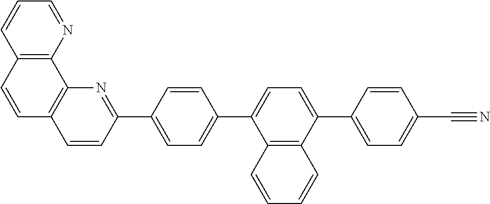 [SMILES: N#Cc1ccc(-c2ccc(-c3ccc(-c4ccc5ccc6cccnc6c5n4)cc3)c3ccccc23)cc1]

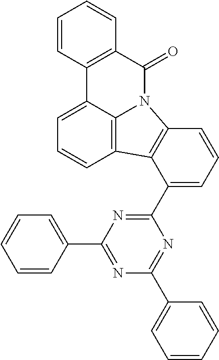 [SMILES: O=c1c2ccccc2c2cccc3c4c(-c5nc(-c6ccccc6)nc(-c6ccccc6)n5)cccc4n1c23]

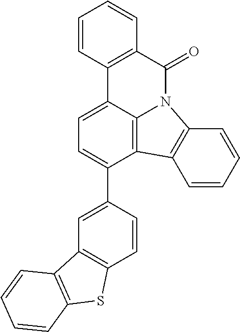 [SMILES: O=c1c2ccccc2c2ccc(-c3ccc4sc5ccccc5c4c3)c3c4ccccc4n1c23]

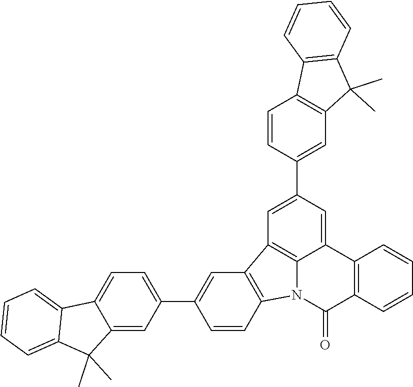 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

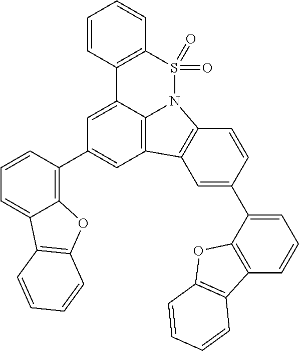 [SMILES: O=S1(=O)c2ccccc2-c2cc(-c3cccc4c3oc3ccccc34)cc3c4cc(-c5cccc6c5oc5ccccc56)ccc4n1c23]

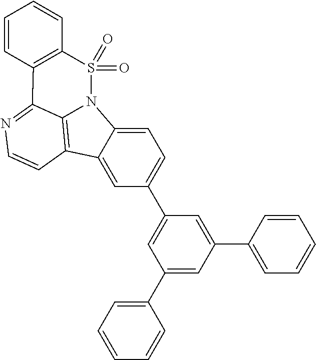 [SMILES: O=S1(=O)c2ccccc2-c2nccc3c4cc(-c5cc(-c6ccccc6)cc(-c6ccccc6)c5)ccc4n1c23]

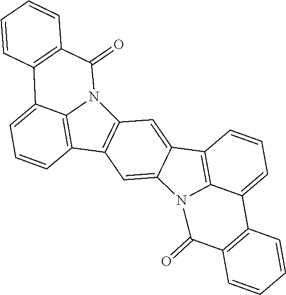 [SMILES: O=c1c2ccccc2c2cccc3c4cc5c(cc4n1c23)c1cccc2c3ccccc3c(=O)n5c21]

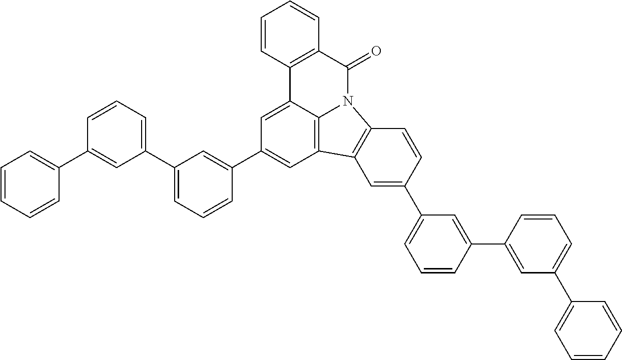 [SMILES: O=c1c2ccccc2c2cc(-c3cccc(-c4cccc(-c5ccccc5)c4)c3)cc3c4cc(-c5cccc(-c6cccc(-c7ccccc7)c6)c5)ccc4n1c23]

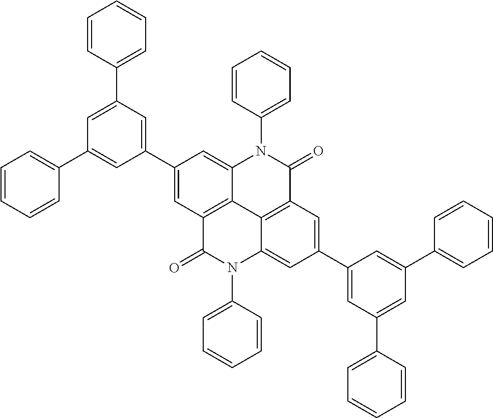 [SMILES: O=c1c2cc(-c3cc(-c4ccccc4)cc(-c4ccccc4)c3)cc3c2c2c(cc(-c4cc(-c5ccccc5)cc(-c5ccccc5)c4)cc2n1-c1ccccc1)c(=O)n3-c1ccccc1]

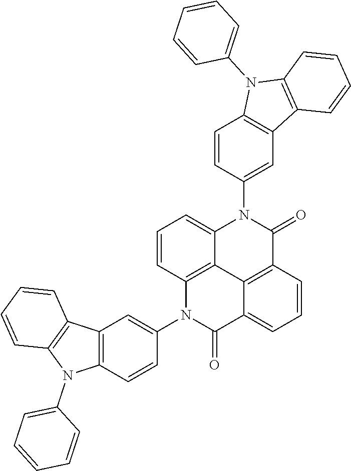 [SMILES: O=c1c2cccc3c(=O)n(-c4ccc5c(c4)c4ccccc4n5-c4ccccc4)c4cccc(c4c23)n1-c1ccc2c(c1)c1ccccc1n2-c1ccccc1]

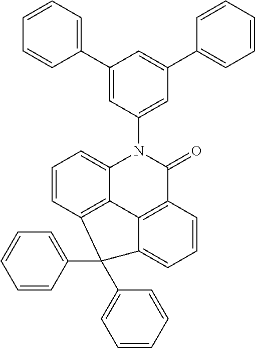 [SMILES: O=c1c2cccc3c2c2c(cccc2n1-c1cc(-c2ccccc2)cc(-c2ccccc2)c1)C3(c1ccccc1)c1ccccc1]

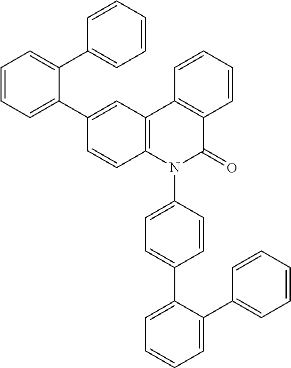 [SMILES: O=c1c2ccccc2c2cc(-c3ccccc3-c3ccccc3)ccc2n1-c1ccc(-c2ccccc2-c2ccccc2)cc1]

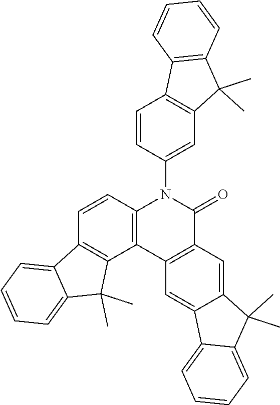 [SMILES: CC1(C)c2ccccc2-c2ccc(-n3c(=O)c4cc5c(cc4c4c6c(ccc43)-c3ccccc3C6(C)C)-c3ccccc3C5(C)C)cc21]

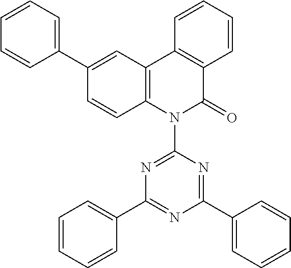 [SMILES: O=c1c2ccccc2c2cc(-c3ccccc3)ccc2n1-c1nc(-c2ccccc2)nc(-c2ccccc2)n1]

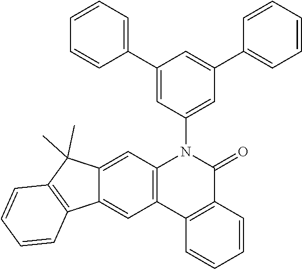 [SMILES: CC1(C)c2ccccc2-c2cc3c4ccccc4c(=O)n(-c4cc(-c5ccccc5)cc(-c5ccccc5)c4)c3cc21]

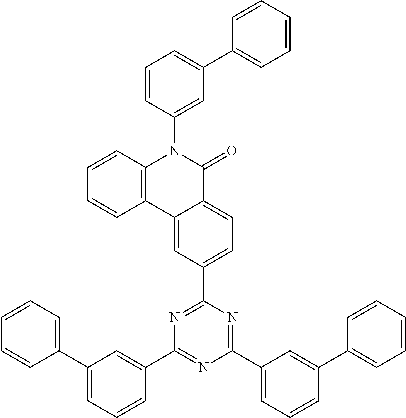 [SMILES: O=c1c2ccc(-c3nc(-c4cccc(-c5ccccc5)c4)nc(-c4cccc(-c5ccccc5)c4)n3)cc2c2ccccc2n1-c1cccc(-c2ccccc2)c1]

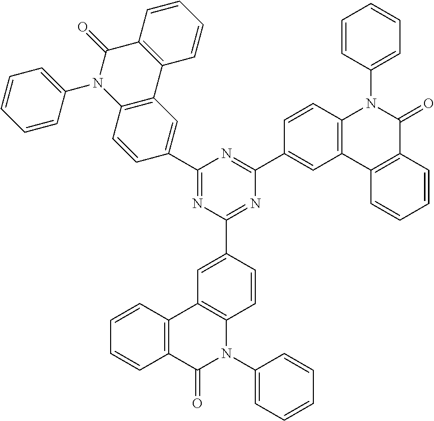 [SMILES: O=c1c2ccccc2c2cc(-c3nc(-c4ccc5c(c4)c4ccccc4c(=O)n5-c4ccccc4)nc(-c4ccc5c(c4)c4ccccc4c(=O)n5-c4ccccc4)n3)ccc2n1-c1ccccc1]

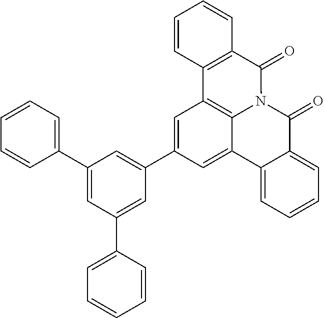 [SMILES: O=c1c2ccccc2c2cc(-c3cc(-c4ccccc4)cc(-c4ccccc4)c3)cc3c4ccccc4c(=O)n1c23]

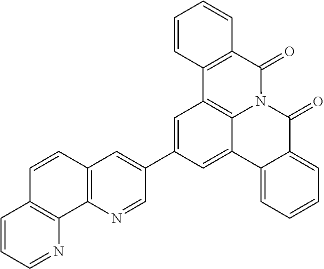 [SMILES: O=c1c2ccccc2c2cc(-c3cnc4c(ccc5cccnc54)c3)cc3c4ccccc4c(=O)n1c23]

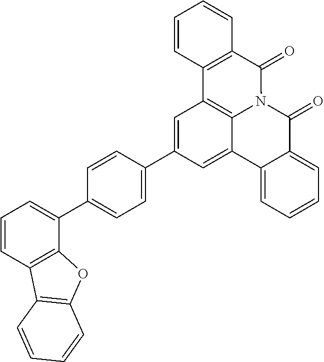 [SMILES: O=c1c2ccccc2c2cc(-c3ccc(-c4cccc5c4oc4ccccc45)cc3)cc3c4ccccc4c(=O)n1c23]

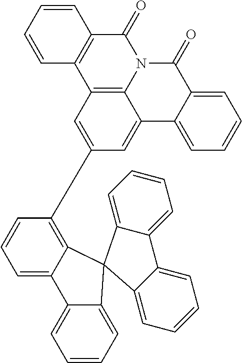 [SMILES: O=c1c2ccccc2c2cc(-c3cccc4c3C3(c5ccccc5-c5ccccc53)c3ccccc3-4)cc3c4ccccc4c(=O)n1c23]

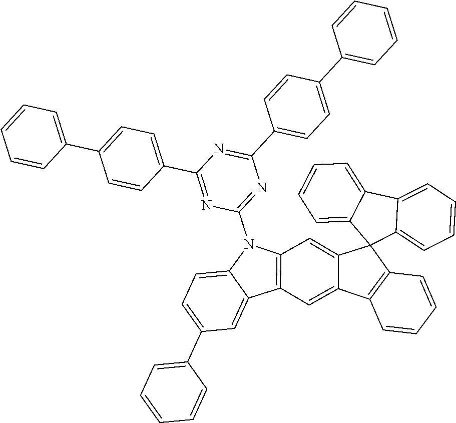 [SMILES: c1ccc(-c2ccc(-c3nc(-c4ccc(-c5ccccc5)cc4)nc(-n4c5ccc(-c6ccccc6)cc5c5cc6c(cc54)C4(c5ccccc5-c5ccccc54)c4ccccc4-6)n3)cc2)cc1]

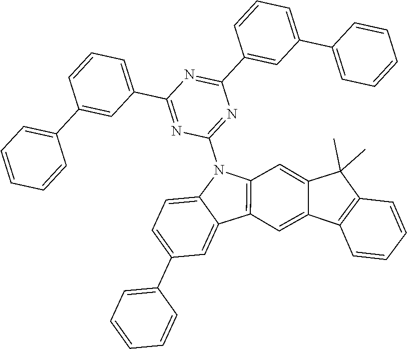 [SMILES: CC1(C)c2ccccc2-c2cc3c4cc(-c5ccccc5)ccc4n(-c4nc(-c5cccc(-c6ccccc6)c5)nc(-c5cccc(-c6ccccc6)c5)n4)c3cc21]

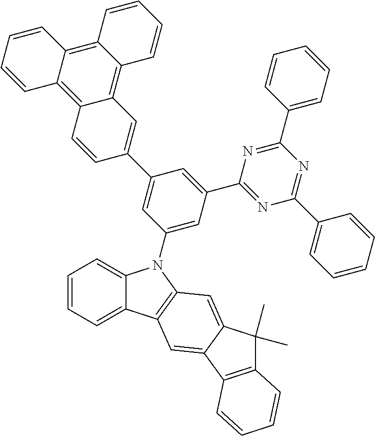 [SMILES: CC1(C)c2ccccc2-c2cc3c4ccccc4n(-c4cc(-c5ccc6c7ccccc7c7ccccc7c6c5)cc(-c5nc(-c6ccccc6)nc(-c6ccccc6)n5)c4)c3cc21]

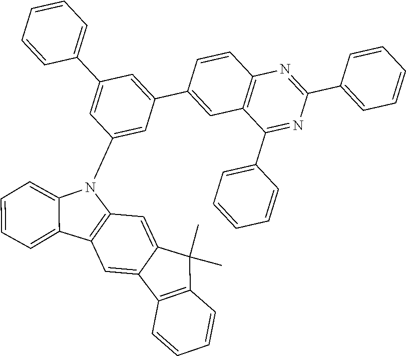 [SMILES: CC1(C)c2ccccc2-c2cc3c4ccccc4n(-c4cc(-c5ccccc5)cc(-c5ccc6nc(-c7ccccc7)nc(-c7ccccc7)c6c5)c4)c3cc21]

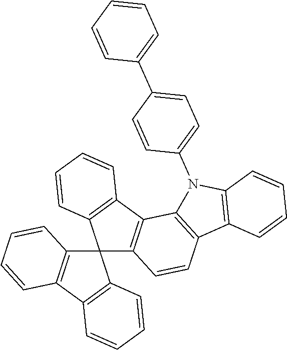 [SMILES: c1ccc(-c2ccc(-n3c4ccccc4c4ccc5c(c43)-c3ccccc3C53c4ccccc4-c4ccccc43)cc2)cc1]

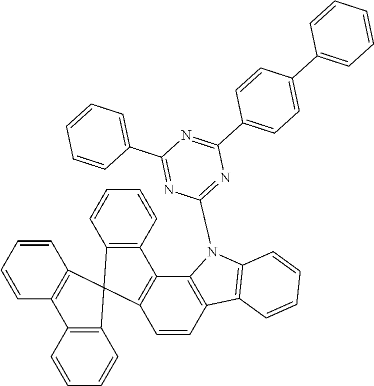 [SMILES: c1ccc(-c2ccc(-c3nc(-c4ccccc4)nc(-n4c5ccccc5c5ccc6c(c54)-c4ccccc4C64c5ccccc5-c5ccccc54)n3)cc2)cc1]

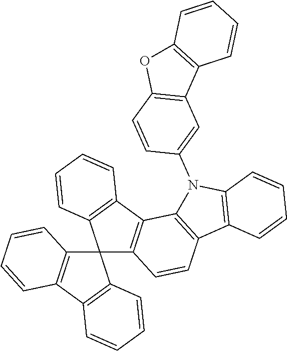 [SMILES: c1ccc2c(c1)-c1ccccc1C21c2ccccc2-c2c1ccc1c3ccccc3n(-c3ccc4oc5ccccc5c4c3)c21]

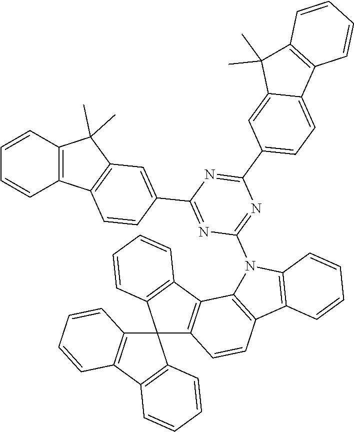 [SMILES: CC1(C)c2ccccc2-c2ccc(-c3nc(-c4ccc5c(c4)C(C)(C)c4ccccc4-5)nc(-n4c5ccccc5c5ccc6c(c54)-c4ccccc4C64c5ccccc5-c5ccccc54)n3)cc21]

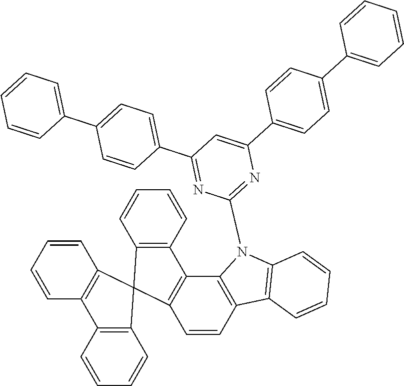 [SMILES: c1ccc(-c2ccc(-c3cc(-c4ccc(-c5ccccc5)cc4)nc(-n4c5ccccc5c5ccc6c(c54)-c4ccccc4C64c5ccccc5-c5ccccc54)n3)cc2)cc1]

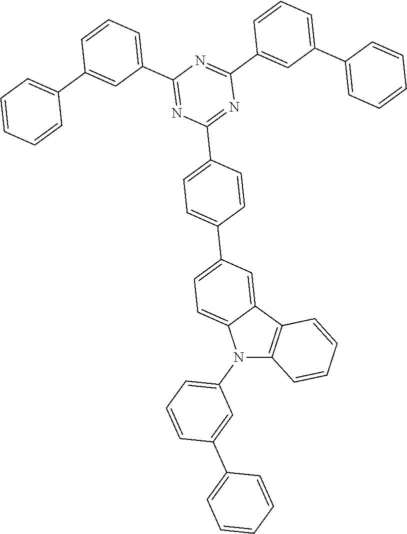 [SMILES: c1ccc(-c2cccc(-c3nc(-c4ccc(-c5ccc6c(c5)c5ccccc5n6-c5cccc(-c6ccccc6)c5)cc4)nc(-c4cccc(-c5ccccc5)c4)n3)c2)cc1]

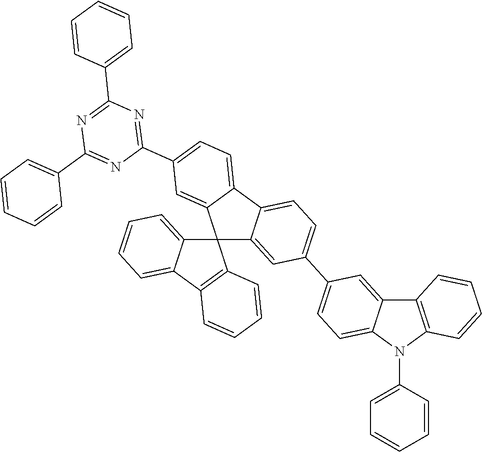 [SMILES: c1ccc(-c2nc(-c3ccccc3)nc(-c3ccc4c(c3)C3(c5ccccc5-c5ccccc53)c3cc(-c5ccc6c(c5)c5ccccc5n6-c5ccccc5)ccc3-4)n2)cc1]

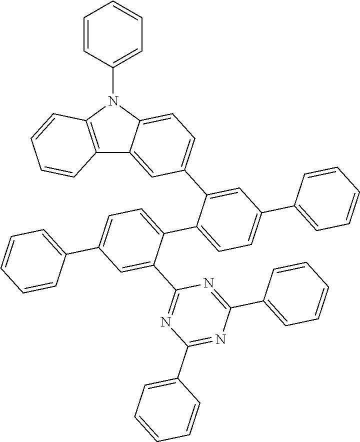 [SMILES: c1ccc(-c2ccc(-c3ccc(-c4ccccc4)cc3-c3nc(-c4ccccc4)nc(-c4ccccc4)n3)c(-c3ccc4c(c3)c3ccccc3n4-c3ccccc3)c2)cc1]

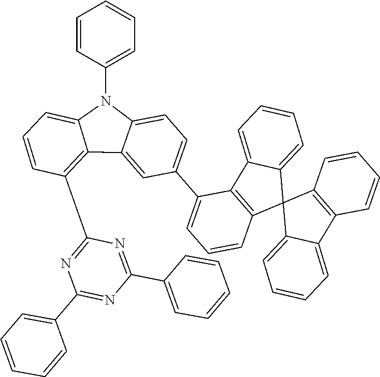 [SMILES: c1ccc(-c2nc(-c3ccccc3)nc(-c3cccc4c3c3cc(-c5cccc6c5-c5ccccc5C65c6ccccc6-c6ccccc65)ccc3n4-c3ccccc3)n2)cc1]

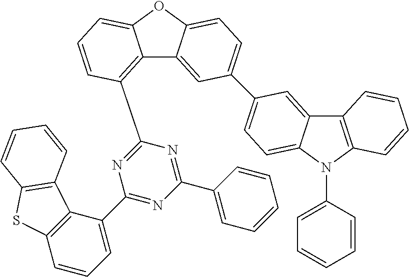 [SMILES: c1ccc(-c2nc(-c3cccc4oc5ccc(-c6ccc7c(c6)c6ccccc6n7-c6ccccc6)cc5c34)nc(-c3cccc4sc5ccccc5c34)n2)cc1]

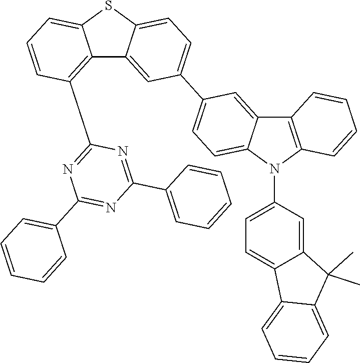 [SMILES: CC1(C)c2ccccc2-c2ccc(-n3c4ccccc4c4cc(-c5ccc6sc7cccc(-c8nc(-c9ccccc9)nc(-c9ccccc9)n8)c7c6c5)ccc43)cc21]

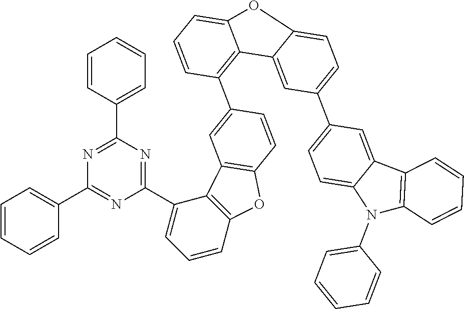 [SMILES: c1ccc(-c2nc(-c3ccccc3)nc(-c3cccc4oc5ccc(-c6cccc7oc8ccc(-c9ccc%10c(c9)c9ccccc9n%10-c9ccccc9)cc8c67)cc5c34)n2)cc1]

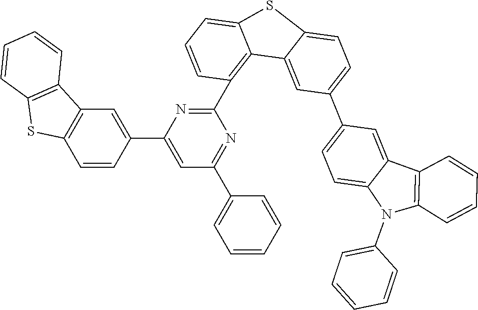 [SMILES: c1ccc(-c2cc(-c3ccc4sc5ccccc5c4c3)nc(-c3cccc4sc5ccc(-c6ccc7c(c6)c6ccccc6n7-c6ccccc6)cc5c34)n2)cc1]

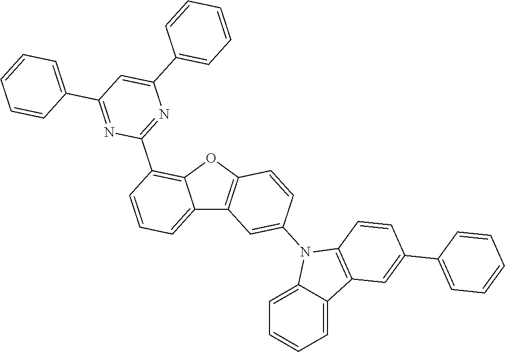 [SMILES: c1ccc(-c2ccc3c(c2)c2ccccc2n3-c2ccc3oc4c(-c5nc(-c6ccccc6)cc(-c6ccccc6)n5)cccc4c3c2)cc1]

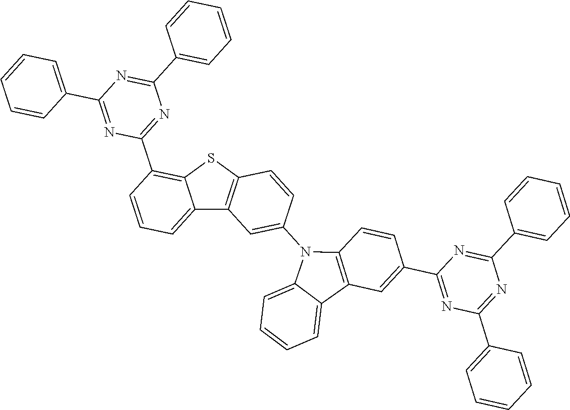 [SMILES: c1ccc(-c2nc(-c3ccccc3)nc(-c3ccc4c(c3)c3ccccc3n4-c3ccc4sc5c(-c6nc(-c7ccccc7)nc(-c7ccccc7)n6)cccc5c4c3)n2)cc1]

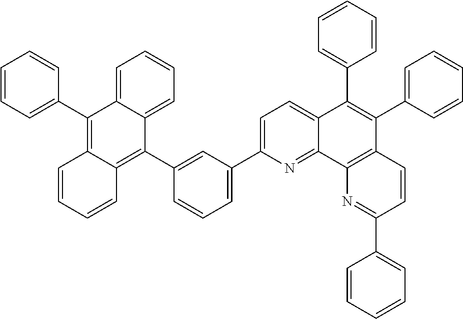 [SMILES: c1ccc(-c2ccc3c(-c4ccccc4)c(-c4ccccc4)c4ccc(-c5cccc(-c6c7ccccc7c(-c7ccccc7)c7ccccc67)c5)nc4c3n2)cc1]

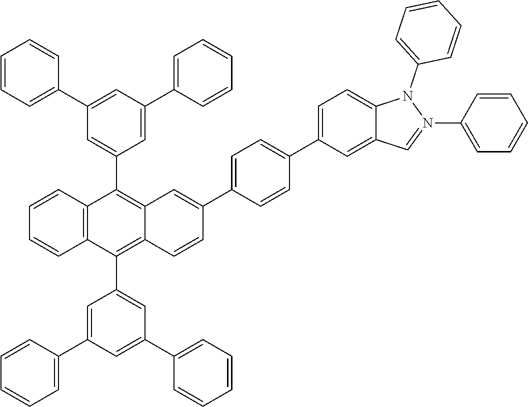

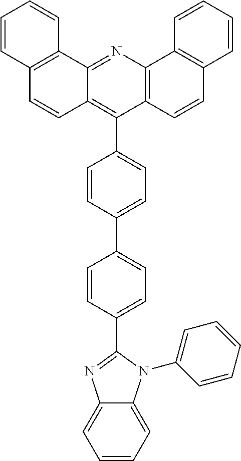 [SMILES: c1ccc(-n2c(-c3ccc(-c4ccc(-c5c6ccc7ccccc7c6nc6c5ccc5ccccc56)cc4)cc3)nc3ccccc32)cc1]

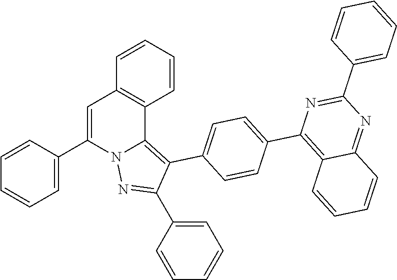 [SMILES: c1ccc(-c2nc(-c3ccc(-c4c(-c5ccccc5)nn5c(-c6ccccc6)cc6ccccc6c45)cc3)c3ccccc3n2)cc1]

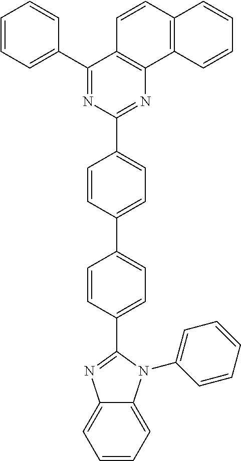 [SMILES: c1ccc(-c2nc(-c3ccc(-c4ccc(-c5nc6ccccc6n5-c5ccccc5)cc4)cc3)nc3c2ccc2ccccc23)cc1]

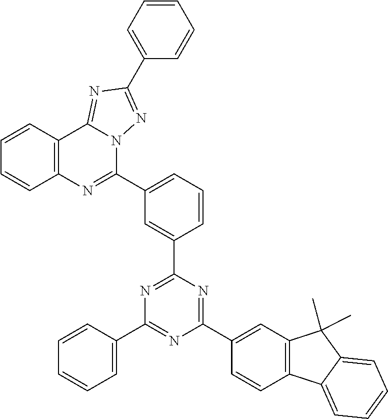 [SMILES: CC1(C)c2ccccc2-c2ccc(-c3nc(-c4ccccc4)nc(-c4cccc(-c5nc6ccccc6c6nc(-c7ccccc7)nn56)c4)n3)cc21]

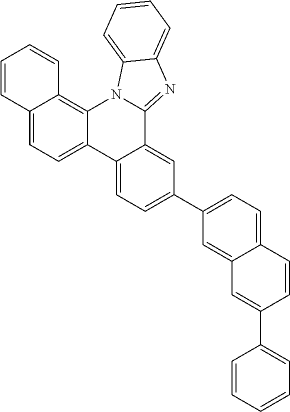 [SMILES: c1ccc(-c2ccc3ccc(-c4ccc5c(c4)c4nc6ccccc6n4c4c6ccccc6ccc54)cc3c2)cc1]

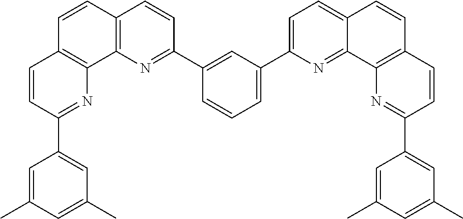

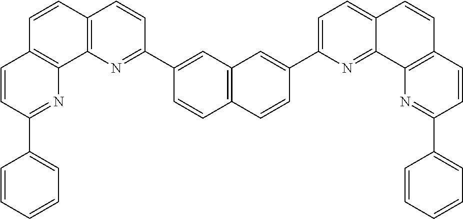 [SMILES: c1ccc(-c2ccc3ccc4ccc(-c5ccc6ccc(-c7ccc8ccc9ccc(-c%10ccccc%10)nc9c8n7)cc6c5)nc4c3n2)cc1]

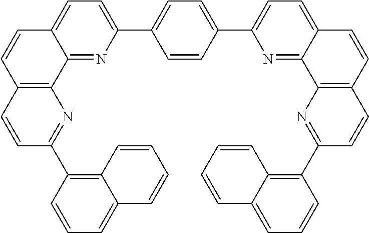 [SMILES: c1ccc2c(-c3ccc4ccc5ccc(-c6ccc(-c7ccc8ccc9ccc(-c%10cccc%11ccccc%10%11)nc9c8n7)cc6)nc5c4n3)cccc2c1]

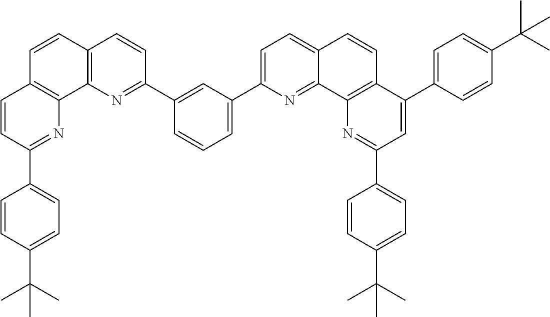 [SMILES: CC(C)(C)c1ccc(-c2ccc3ccc4ccc(-c5cccc(-c6ccc7ccc8c(-c9ccc(C(C)(C)C)cc9)cc(-c9ccc(C(C)(C)C)cc9)nc8c7n6)c5)nc4c3n2)cc1]

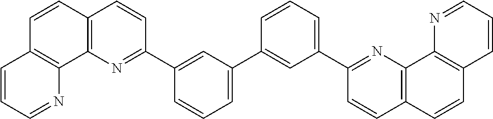 [SMILES: c1cc(-c2cccc(-c3ccc4ccc5cccnc5c4n3)c2)cc(-c2ccc3ccc4cccnc4c3n2)c1]

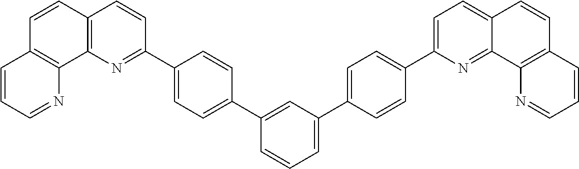 [SMILES: c1cc(-c2ccc(-c3ccc4ccc5cccnc5c4n3)cc2)cc(-c2ccc(-c3ccc4ccc5cccnc5c4n3)cc2)c1]

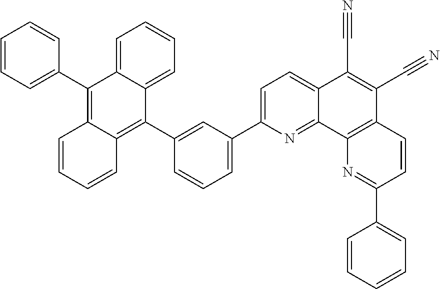 [SMILES: N#Cc1c(C#N)c2ccc(-c3cccc(-c4c5ccccc5c(-c5ccccc5)c5ccccc45)c3)nc2c2nc(-c3ccccc3)ccc12]

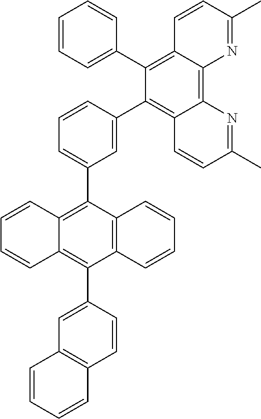 [SMILES: Cc1ccc2c(-c3ccccc3)c(-c3cccc(-c4c5ccccc5c(-c5ccc6ccccc6c5)c5ccccc45)c3)c3ccc(C)nc3c2n1]

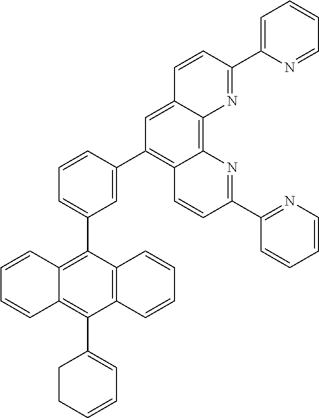 [SMILES: C1=CCCC(c2c3ccccc3c(-c3cccc(-c4cc5ccc(-c6ccccn6)nc5c5nc(-c6ccccn6)ccc45)c3)c3ccccc23)=C1]

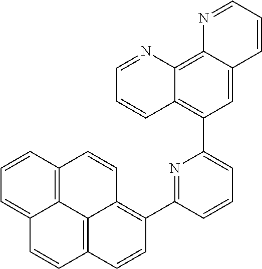 [SMILES: c1cc(-c2cc3cccnc3c3ncccc23)nc(-c2ccc3ccc4cccc5ccc2c3c45)c1]

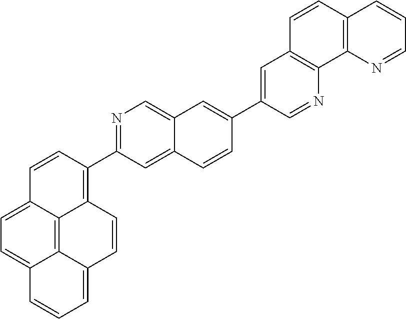 [SMILES: c1cnc2c(c1)ccc1cc(-c3ccc4cc(-c5ccc6ccc7cccc8ccc5c6c78)ncc4c3)cnc12]

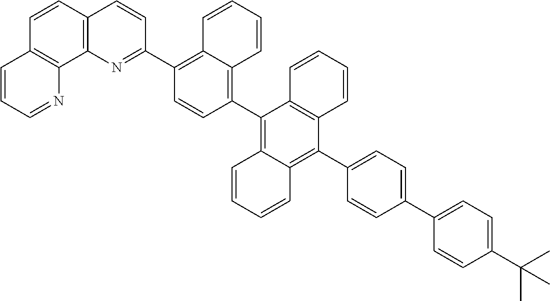 [SMILES: CC(C)(C)c1ccc(-c2ccc(-c3c4ccccc4c(-c4ccc(-c5ccc6ccc7cccnc7c6n5)c5ccccc45)c4ccccc34)cc2)cc1]

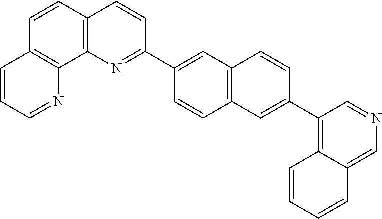 [SMILES: c1ccc2c(-c3ccc4cc(-c5ccc6ccc7cccnc7c6n5)ccc4c3)cncc2c1]

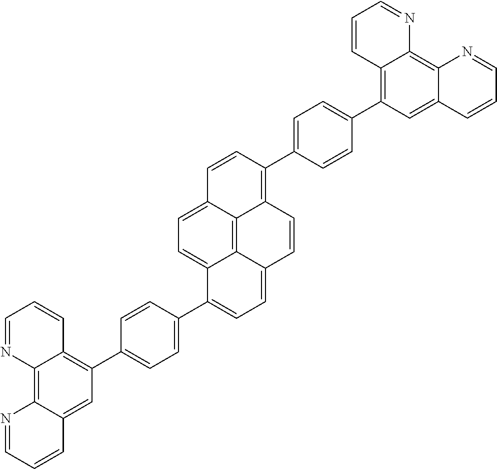 [SMILES: c1cnc2c(c1)cc(-c1ccc(-c3ccc4ccc5c(-c6ccc(-c7cc8cccnc8c8ncccc78)cc6)ccc6ccc3c4c65)cc1)c1cccnc12]

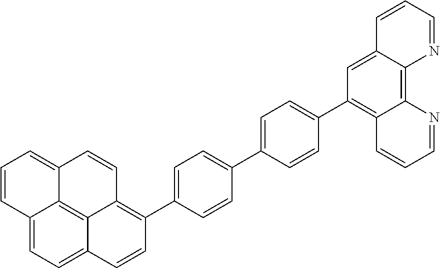 [SMILES: c1cnc2c(c1)cc(-c1ccc(-c3ccc(-c4ccc5ccc6cccc7ccc4c5c67)cc3)cc1)c1cccnc12]

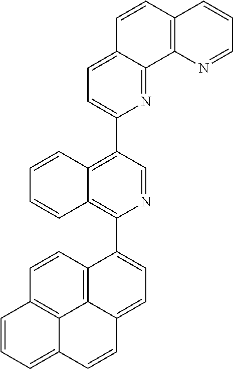 [SMILES: c1cnc2c(c1)ccc1ccc(-c3cnc(-c4ccc5ccc6cccc7ccc4c5c67)c4ccccc34)nc12]

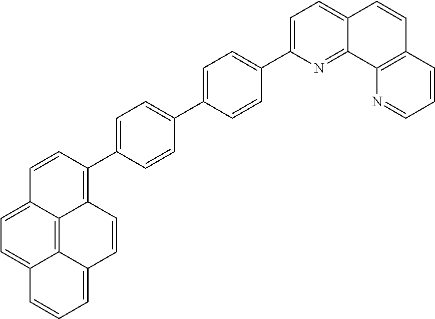 [SMILES: c1cnc2c(c1)ccc1ccc(-c3ccc(-c4ccc(-c5ccc6ccc7cccc8ccc5c6c78)cc4)cc3)nc12]

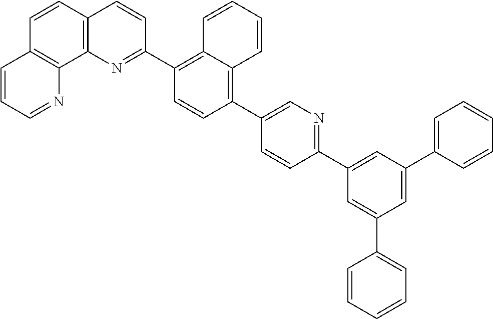 [SMILES: c1ccc(-c2cc(-c3ccccc3)cc(-c3ccc(-c4ccc(-c5ccc6ccc7cccnc7c6n5)c5ccccc45)cn3)c2)cc1]

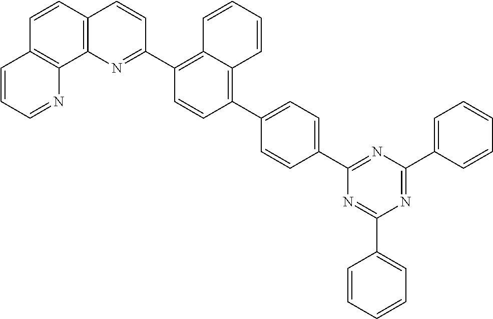 [SMILES: c1ccc(-c2nc(-c3ccccc3)nc(-c3ccc(-c4ccc(-c5ccc6ccc7cccnc7c6n5)c5ccccc45)cc3)n2)cc1]

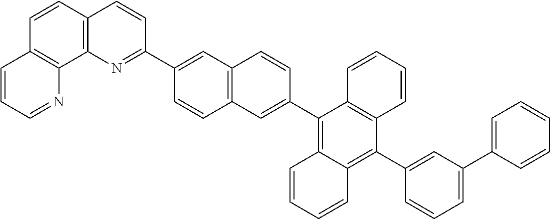 [SMILES: c1ccc(-c2cccc(-c3c4ccccc4c(-c4ccc5cc(-c6ccc7ccc8cccnc8c7n6)ccc5c4)c4ccccc34)c2)cc1]

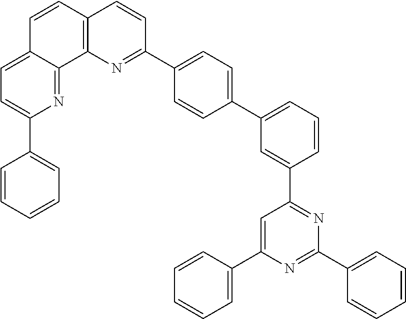 [SMILES: c1ccc(-c2cc(-c3cccc(-c4ccc(-c5ccc6ccc7ccc(-c8ccccc8)nc7c6n5)cc4)c3)nc(-c3ccccc3)n2)cc1]

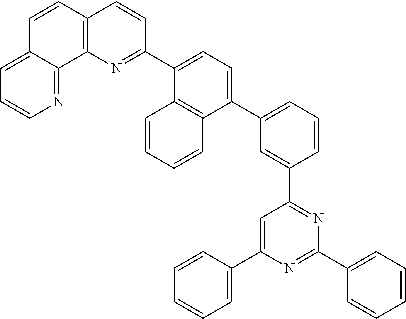 [SMILES: c1ccc(-c2cc(-c3cccc(-c4ccc(-c5ccc6ccc7cccnc7c6n5)c5ccccc45)c3)nc(-c3ccccc3)n2)cc1]

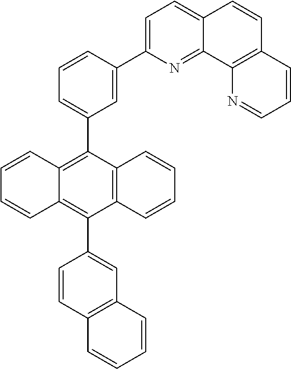 [SMILES: c1cc(-c2ccc3ccc4cccnc4c3n2)cc(-c2c3ccccc3c(-c3ccc4ccccc4c3)c3ccccc23)c1]

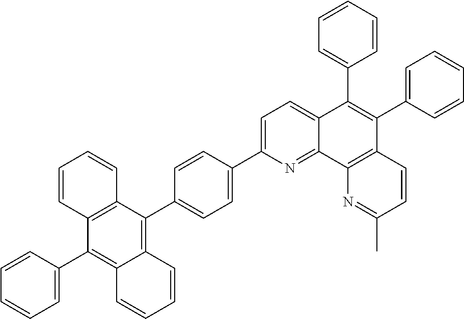 [SMILES: Cc1ccc2c(-c3ccccc3)c(-c3ccccc3)c3ccc(-c4ccc(-c5c6ccccc6c(-c6ccccc6)c6ccccc56)cc4)nc3c2n1]

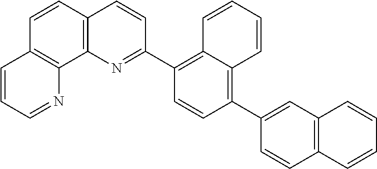 [SMILES: c1ccc2cc(-c3ccc(-c4ccc5ccc6cccnc6c5n4)c4ccccc34)ccc2c1]

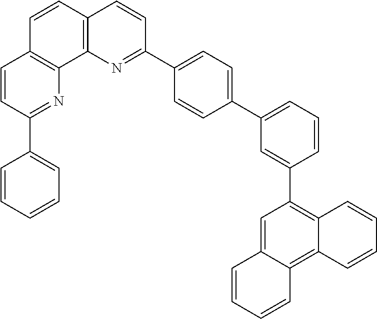 [SMILES: c1ccc(-c2ccc3ccc4ccc(-c5ccc(-c6cccc(-c7cc8ccccc8c8ccccc78)c6)cc5)nc4c3n2)cc1]

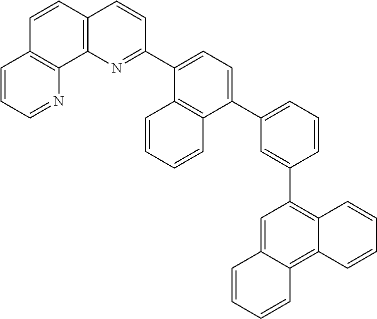 [SMILES: c1cc(-c2ccc(-c3ccc4ccc5cccnc5c4n3)c3ccccc23)cc(-c2cc3ccccc3c3ccccc23)c1]

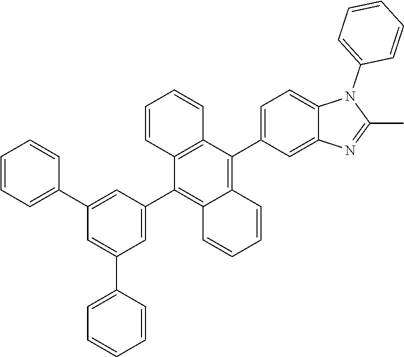 [SMILES: Cc1nc2cc(-c3c4ccccc4c(-c4cc(-c5ccccc5)cc(-c5ccccc5)c4)c4ccccc34)ccc2n1-c1ccccc1]

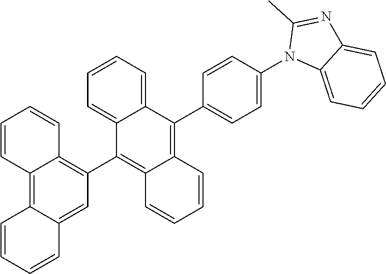 [SMILES: Cc1nc2ccccc2n1-c1ccc(-c2c3ccccc3c(-c3cc4ccccc4c4ccccc34)c3ccccc23)cc1]

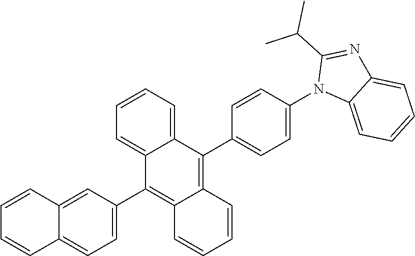 [SMILES: CC(C)c1nc2ccccc2n1-c1ccc(-c2c3ccccc3c(-c3ccc4ccccc4c3)c3ccccc23)cc1]

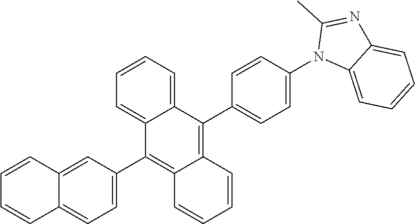 [SMILES: Cc1nc2ccccc2n1-c1ccc(-c2c3ccccc3c(-c3ccc4ccccc4c3)c3ccccc23)cc1]

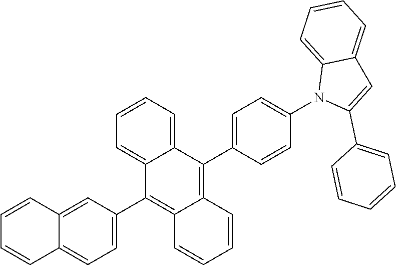 [SMILES: c1ccc(-c2cc3ccccc3n2-c2ccc(-c3c4ccccc4c(-c4ccc5ccccc5c4)c4ccccc34)cc2)cc1]

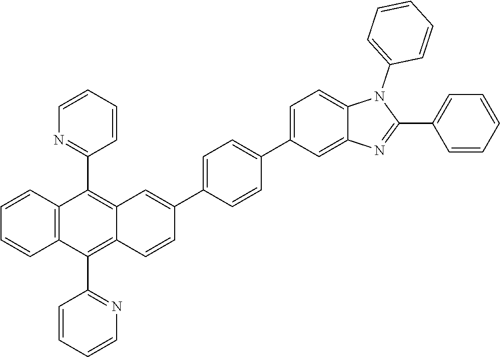 [SMILES: c1ccc(-c2nc3cc(-c4ccc(-c5ccc6c(-c7ccccn7)c7ccccc7c(-c7ccccn7)c6c5)cc4)ccc3n2-c2ccccc2)cc1]

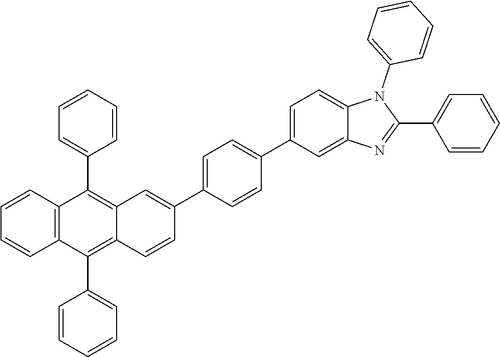 [SMILES: c1ccc(-c2c3ccccc3c(-c3ccccc3)c3cc(-c4ccc(-c5ccc6c(c5)nc(-c5ccccc5)n6-c5ccccc5)cc4)ccc23)cc1]

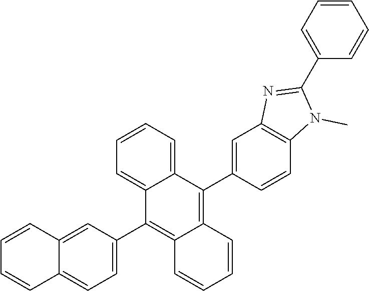 [SMILES: Cn1c(-c2ccccc2)nc2cc(-c3c4ccccc4c(-c4ccc5ccccc5c4)c4ccccc34)ccc21]

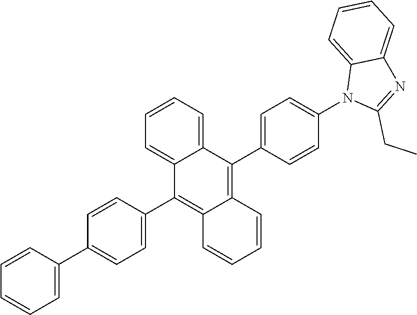 [SMILES: CCc1nc2ccccc2n1-c1ccc(-c2c3ccccc3c(-c3ccc(-c4ccccc4)cc3)c3ccccc23)cc1]

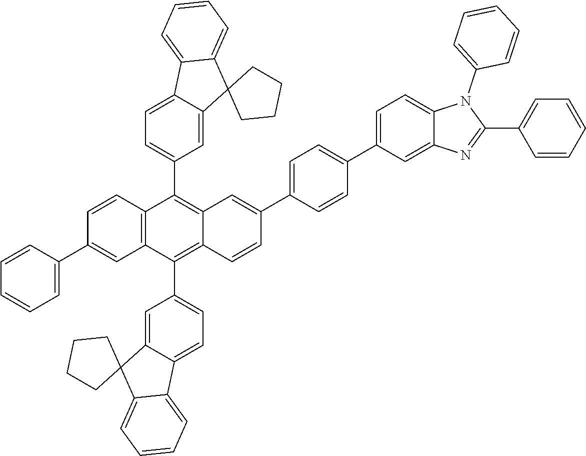 [SMILES: c1ccc(-c2ccc3c(-c4ccc5c(c4)C4(CCCC4)c4ccccc4-5)c4cc(-c5ccc(-c6ccc7c(c6)nc(-c6ccccc6)n7-c6ccccc6)cc5)ccc4c(-c4ccc5c(c4)C4(CCCC4)c4ccccc4-5)c3c2)cc1]

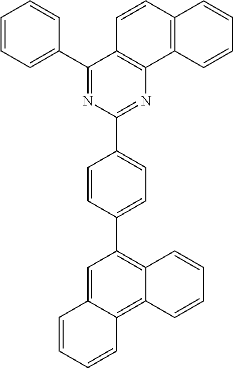 [SMILES: c1ccc(-c2nc(-c3ccc(-c4cc5ccccc5c5ccccc45)cc3)nc3c2ccc2ccccc23)cc1]

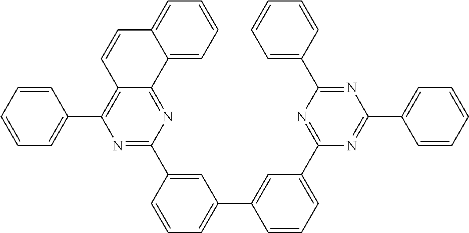 [SMILES: c1ccc(-c2nc(-c3ccccc3)nc(-c3cccc(-c4cccc(-c5nc(-c6ccccc6)c6ccc7ccccc7c6n5)c4)c3)n2)cc1]

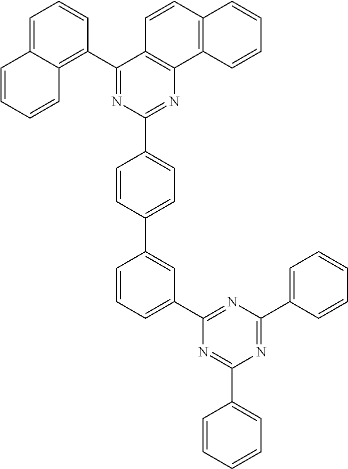 [SMILES: c1ccc(-c2nc(-c3ccccc3)nc(-c3cccc(-c4ccc(-c5nc(-c6cccc7ccccc67)c6ccc7ccccc7c6n5)cc4)c3)n2)cc1]

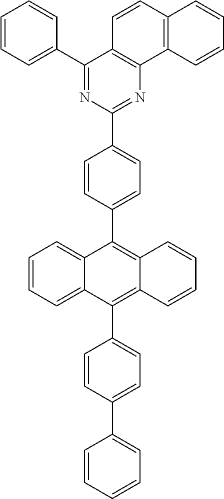 [SMILES: c1ccc(-c2ccc(-c3c4ccccc4c(-c4ccc(-c5nc(-c6ccccc6)c6ccc7ccccc7c6n5)cc4)c4ccccc34)cc2)cc1]

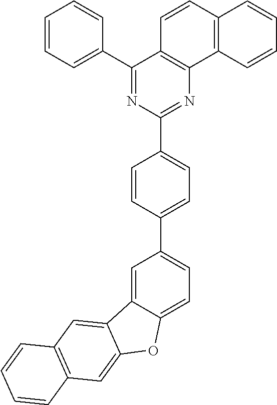 [SMILES: c1ccc(-c2nc(-c3ccc(-c4ccc5oc6cc7ccccc7cc6c5c4)cc3)nc3c2ccc2ccccc23)cc1]

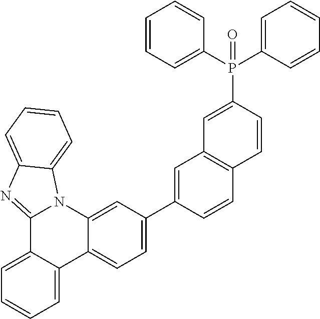 [SMILES: O=P(c1ccccc1)(c1ccccc1)c1ccc2ccc(-c3ccc4c5ccccc5c5nc6ccccc6n5c4c3)cc2c1]

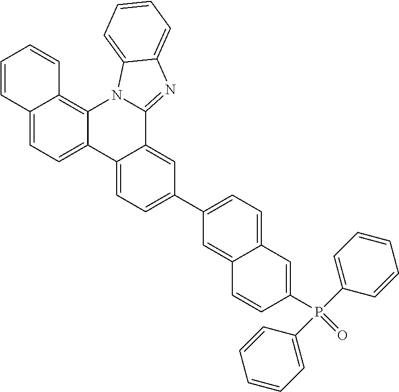 [SMILES: O=P(c1ccccc1)(c1ccccc1)c1ccc2cc(-c3ccc4c(c3)c3nc5ccccc5n3c3c5ccccc5ccc43)ccc2c1]

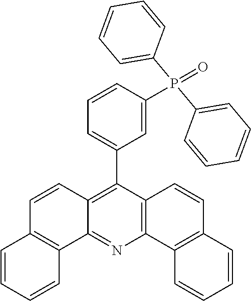 [SMILES: O=P(c1ccccc1)(c1ccccc1)c1cccc(-c2c3ccc4ccccc4c3nc3c2ccc2ccccc23)c1]

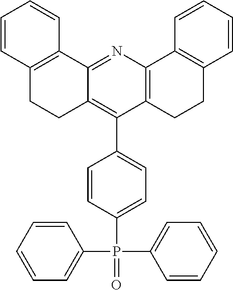 [SMILES: O=P(c1ccccc1)(c1ccccc1)c1ccc(-c2c3c(nc4c2CCc2ccccc2-4)-c2ccccc2CC3)cc1]

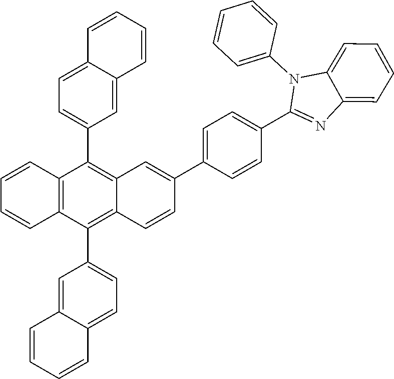 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

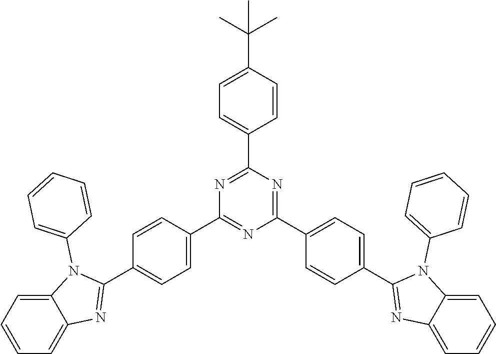 [SMILES: CC(C)(C)c1ccc(-c2nc(-c3ccc(-c4nc5ccccc5n4-c4ccccc4)cc3)nc(-c3ccc(-c4nc5ccccc5n4-c4ccccc4)cc3)n2)cc1]

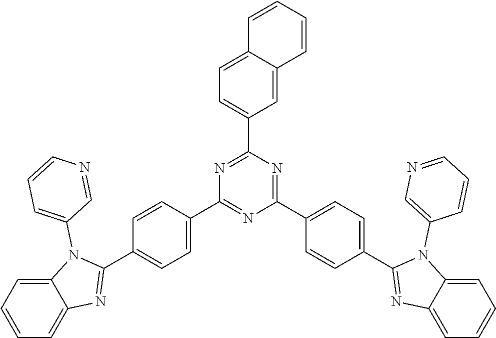 [SMILES: c1cncc(-n2c(-c3ccc(-c4nc(-c5ccc(-c6nc7ccccc7n6-c6cccnc6)cc5)nc(-c5ccc6ccccc6c5)n4)cc3)nc3ccccc32)c1]

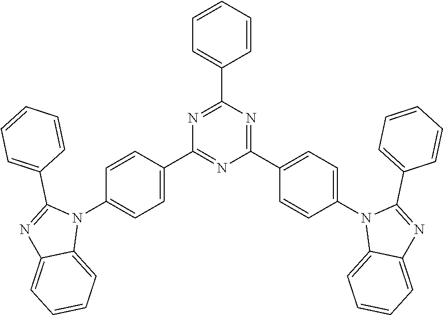 [SMILES: c1ccc(-c2nc(-c3ccc(-n4c(-c5ccccc5)nc5ccccc54)cc3)nc(-c3ccc(-n4c(-c5ccccc5)nc5ccccc54)cc3)n2)cc1]

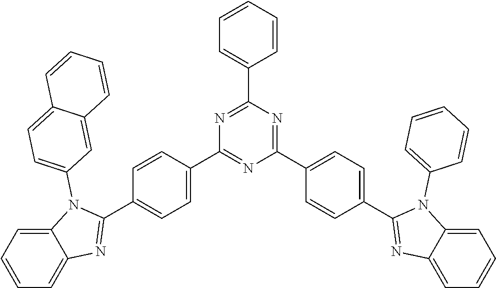 [SMILES: c1ccc(-c2nc(-c3ccc(-c4nc5ccccc5n4-c4ccccc4)cc3)nc(-c3ccc(-c4nc5ccccc5n4-c4ccc5ccccc5c4)cc3)n2)cc1]

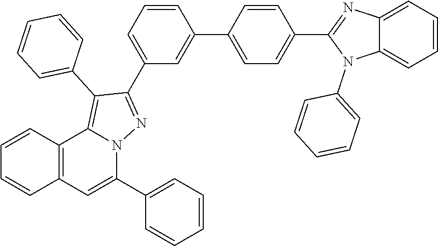 [SMILES: c1ccc(-c2c(-c3cccc(-c4ccc(-c5nc6ccccc6n5-c5ccccc5)cc4)c3)nn3c(-c4ccccc4)cc4ccccc4c23)cc1]

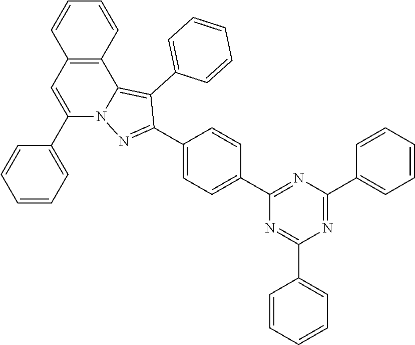 [SMILES: c1ccc(-c2nc(-c3ccccc3)nc(-c3ccc(-c4nn5c(-c6ccccc6)cc6ccccc6c5c4-c4ccccc4)cc3)n2)cc1]

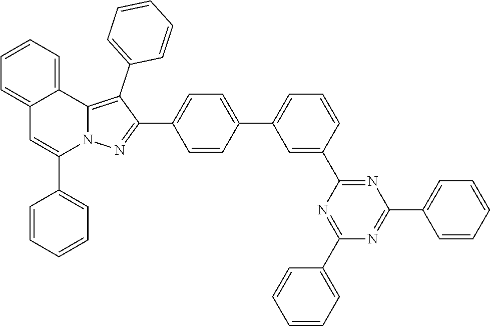 [SMILES: c1ccc(-c2nc(-c3ccccc3)nc(-c3cccc(-c4ccc(-c5nn6c(-c7ccccc7)cc7ccccc7c6c5-c5ccccc5)cc4)c3)n2)cc1]

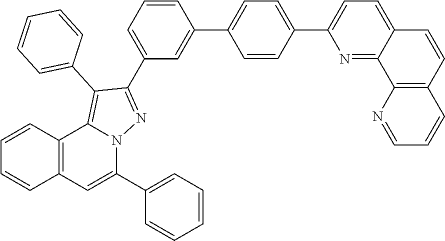 [SMILES: c1ccc(-c2c(-c3cccc(-c4ccc(-c5ccc6ccc7cccnc7c6n5)cc4)c3)nn3c(-c4ccccc4)cc4ccccc4c23)cc1]

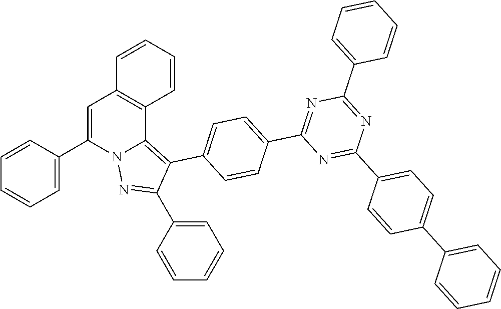 [SMILES: c1ccc(-c2ccc(-c3nc(-c4ccccc4)nc(-c4ccc(-c5c(-c6ccccc6)nn6c(-c7ccccc7)cc7ccccc7c56)cc4)n3)cc2)cc1]

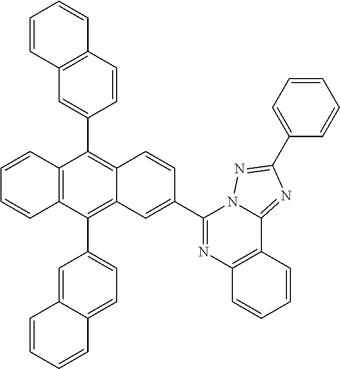 [SMILES: c1ccc(-c2nc3c4ccccc4nc(-c4ccc5c(-c6ccc7ccccc7c6)c6ccccc6c(-c6ccc7ccccc7c6)c5c4)n3n2)cc1]

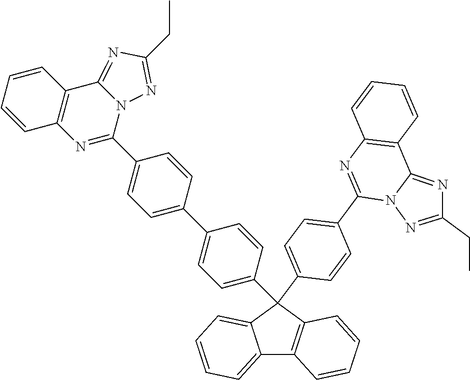 [SMILES: CCc1nc2c3ccccc3nc(-c3ccc(-c4ccc(C5(c6ccc(-c7nc8ccccc8c8nc(CC)nn78)cc6)c6ccccc6-c6ccccc65)cc4)cc3)n2n1]

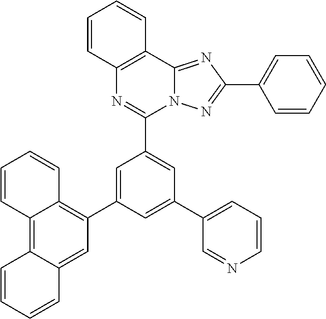 [SMILES: c1ccc(-c2nc3c4ccccc4nc(-c4cc(-c5cccnc5)cc(-c5cc6ccccc6c6ccccc56)c4)n3n2)cc1]

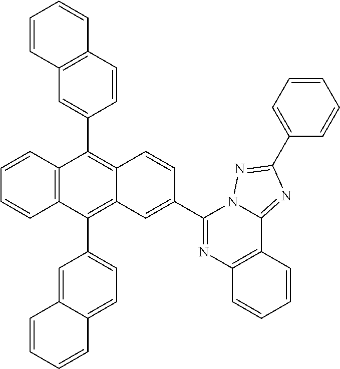 [SMILES: c1ccc(-c2nc3c4ccccc4nc(-c4ccc5c(-c6ccc7ccccc7c6)c6ccccc6c(-c6ccc7ccccc7c6)c5c4)n3n2)cc1]

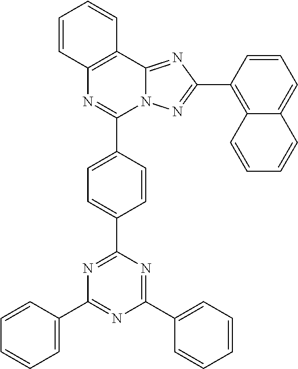 [SMILES: c1ccc(-c2nc(-c3ccccc3)nc(-c3ccc(-c4nc5ccccc5c5nc(-c6cccc7ccccc67)nn45)cc3)n2)cc1]

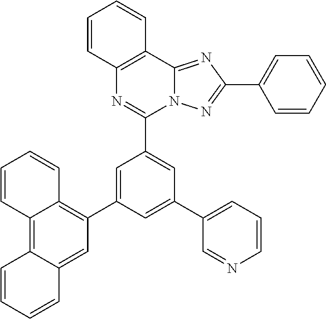 [SMILES: c1ccc(-c2nc3c4ccccc4nc(-c4cc(-c5cccnc5)cc(-c5cc6ccccc6c6ccccc56)c4)n3n2)cc1]

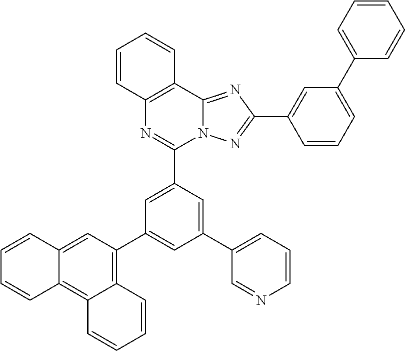 [SMILES: c1ccc(-c2cccc(-c3nc4c5ccccc5nc(-c5cc(-c6cccnc6)cc(-c6cc7ccccc7c7ccccc67)c5)n4n3)c2)cc1]

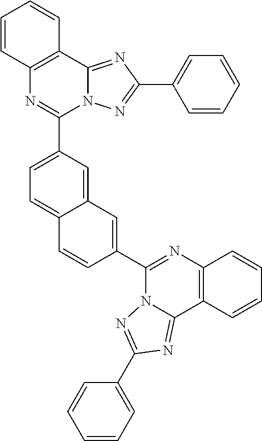 [SMILES: c1ccc(-c2nc3c4ccccc4nc(-c4ccc5ccc(-c6nc7ccccc7c7nc(-c8ccccc8)nn67)cc5c4)n3n2)cc1]

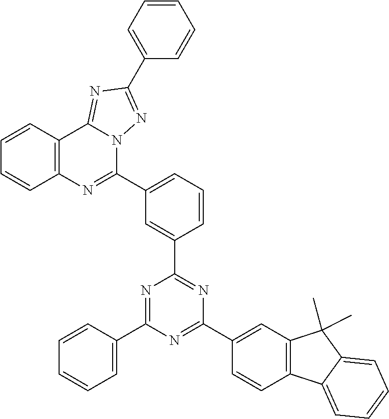 [SMILES: CC1(C)c2ccccc2-c2ccc(-c3nc(-c4ccccc4)nc(-c4cccc(-c5nc6ccccc6c6nc(-c7ccccc7)nn56)c4)n3)cc21]

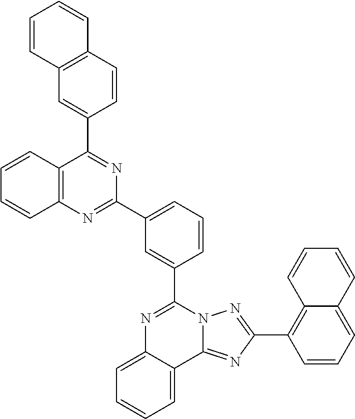 [SMILES: c1cc(-c2nc(-c3ccc4ccccc4c3)c3ccccc3n2)cc(-c2nc3ccccc3c3nc(-c4cccc5ccccc45)nn23)c1]

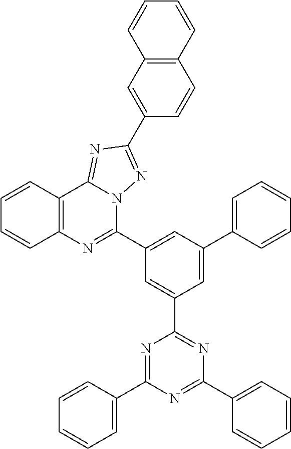 [SMILES: c1ccc(-c2cc(-c3nc(-c4ccccc4)nc(-c4ccccc4)n3)cc(-c3nc4ccccc4c4nc(-c5ccc6ccccc6c5)nn34)c2)cc1]

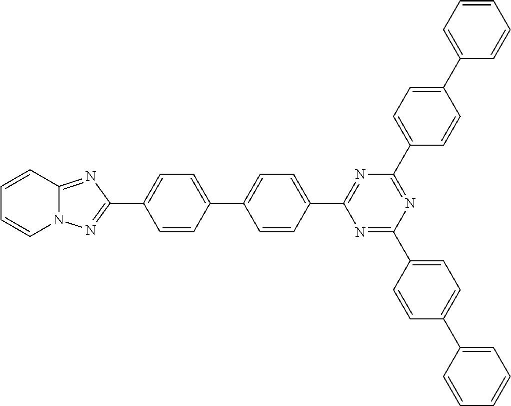 [SMILES: c1ccc(-c2ccc(-c3nc(-c4ccc(-c5ccccc5)cc4)nc(-c4ccc(-c5ccc(-c6nc7ccccn7n6)cc5)cc4)n3)cc2)cc1]

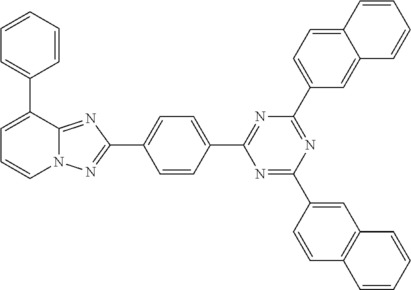 [SMILES: c1ccc(-c2cccn3nc(-c4ccc(-c5nc(-c6ccc7ccccc7c6)nc(-c6ccc7ccccc7c6)n5)cc4)nc23)cc1]

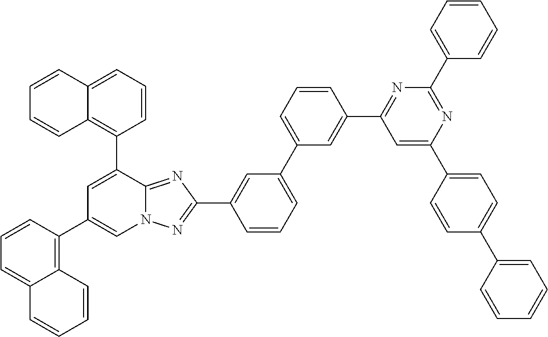 [SMILES: c1ccc(-c2ccc(-c3cc(-c4cccc(-c5cccc(-c6nc7c(-c8cccc9ccccc89)cc(-c8cccc9ccccc89)cn7n6)c5)c4)nc(-c4ccccc4)n3)cc2)cc1]

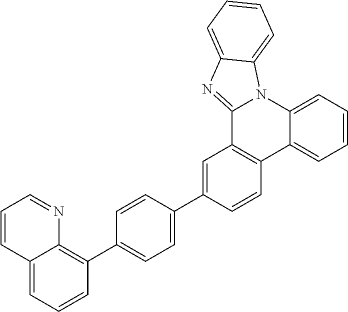 [SMILES: c1cnc2c(-c3ccc(-c4ccc5c6ccccc6n6c7ccccc7nc6c5c4)cc3)cccc2c1]

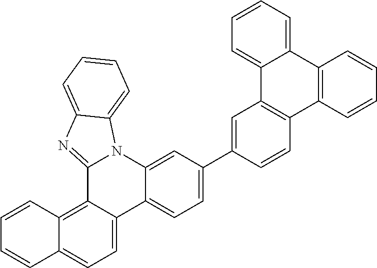 [SMILES: c1ccc2c(c1)ccc1c3ccc(-c4ccc5c6ccccc6c6ccccc6c5c4)cc3n3c4ccccc4nc3c21]

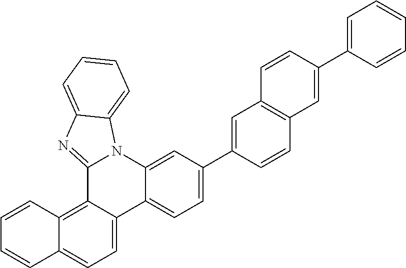 [SMILES: c1ccc(-c2ccc3cc(-c4ccc5c6ccc7ccccc7c6c6nc7ccccc7n6c5c4)ccc3c2)cc1]

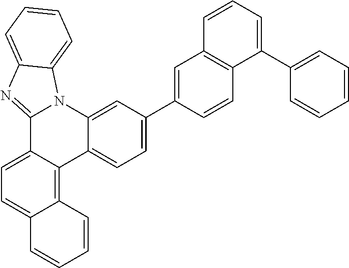 [SMILES: c1ccc(-c2cccc3cc(-c4ccc5c6c7ccccc7ccc6c6nc7ccccc7n6c5c4)ccc23)cc1]

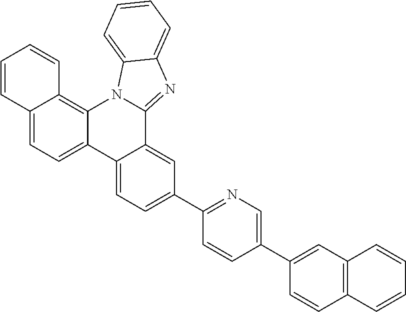 [SMILES: c1ccc2cc(-c3ccc(-c4ccc5c(c4)c4nc6ccccc6n4c4c6ccccc6ccc54)nc3)ccc2c1]

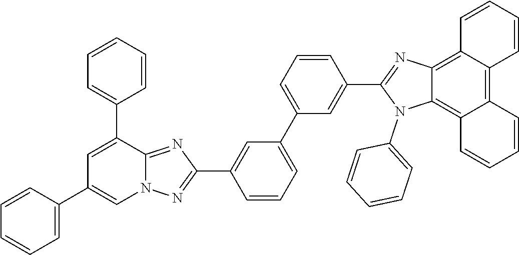 [SMILES: c1ccc(-c2cc(-c3ccccc3)c3nc(-c4cccc(-c5cccc(-c6nc7c8ccccc8c8ccccc8c7n6-c6ccccc6)c5)c4)nn3c2)cc1]

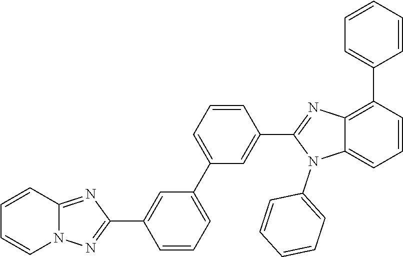 [SMILES: c1ccc(-c2cccc3c2nc(-c2cccc(-c4cccc(-c5nc6ccccn6n5)c4)c2)n3-c2ccccc2)cc1]

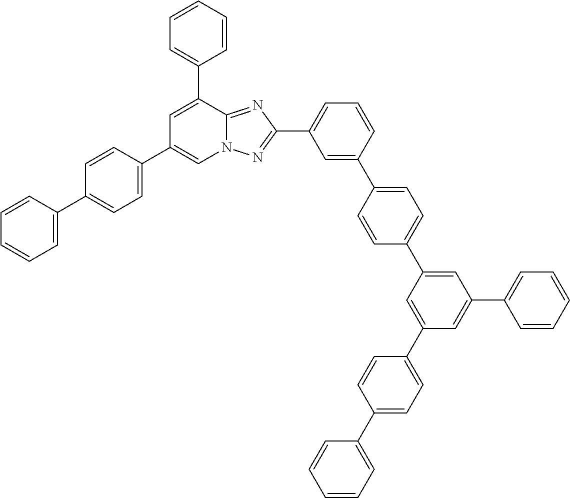 [SMILES: c1ccc(-c2ccc(-c3cc(-c4ccccc4)cc(-c4ccc(-c5cccc(-c6nc7c(-c8ccccc8)cc(-c8ccc(-c9ccccc9)cc8)cn7n6)c5)cc4)c3)cc2)cc1]

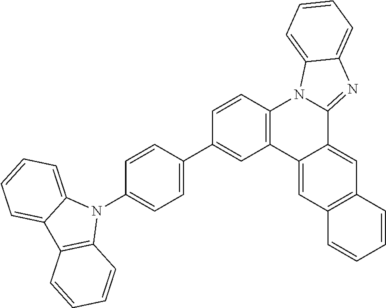 [SMILES: c1ccc2cc3c(cc2c1)c1cc(-c2ccc(-n4c5ccccc5c5ccccc54)cc2)ccc1n1c2ccccc2nc31]

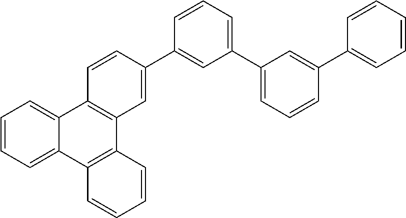 [SMILES: c1ccc(-c2cccc(-c3cccc(-c4ccc5c6ccccc6c6ccccc6c5c4)c3)c2)cc1]

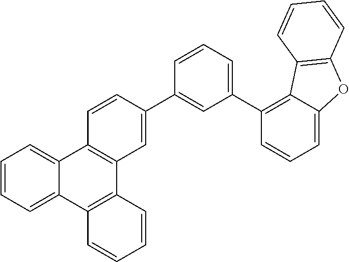 [SMILES: c1cc(-c2ccc3c4ccccc4c4ccccc4c3c2)cc(-c2cccc3oc4ccccc4c23)c1]

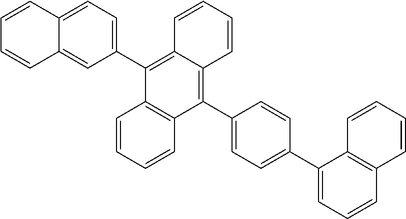 [SMILES: c1ccc2cc(-c3c4ccccc4c(-c4ccc(-c5cccc6ccccc56)cc4)c4ccccc34)ccc2c1]

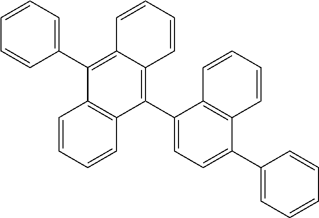 [SMILES: c1ccc(-c2ccc(-c3c4ccccc4c(-c4ccccc4)c4ccccc34)c3ccccc23)cc1]

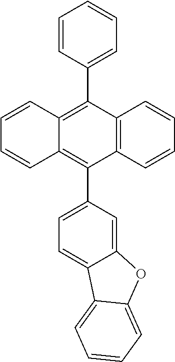 [SMILES: c1ccc(-c2c3ccccc3c(-c3ccc4c(c3)oc3ccccc34)c3ccccc23)cc1]

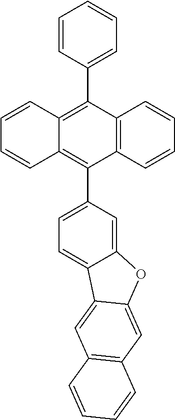 [SMILES: c1ccc(-c2c3ccccc3c(-c3ccc4c(c3)oc3cc5ccccc5cc34)c3ccccc23)cc1]

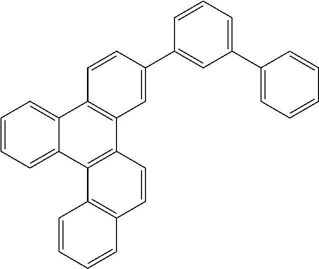 [SMILES: c1ccc(-c2cccc(-c3ccc4c5ccccc5c5c6ccccc6ccc5c4c3)c2)cc1]

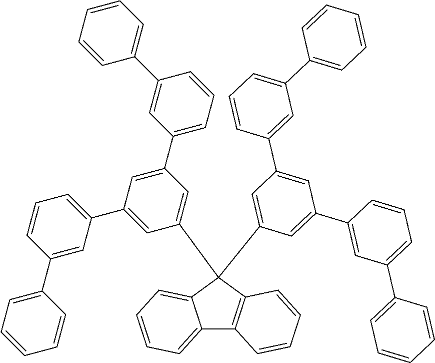 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1]

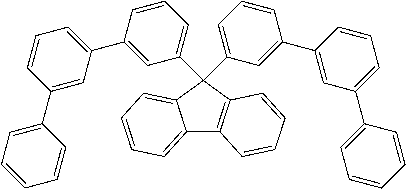 [SMILES: c1ccc(-c2cccc(-c3cccc(C4(c5cccc(-c6cccc(-c7ccccc7)c6)c5)c5ccccc5-c5ccccc54)c3)c2)cc1]

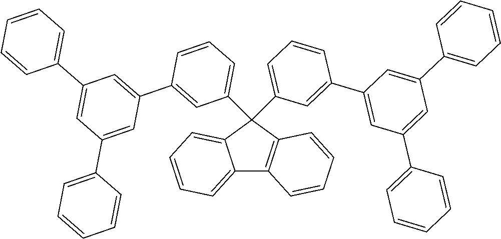 [SMILES: c1ccc(-c2cc(-c3ccccc3)cc(-c3cccc(C4(c5cccc(-c6cc(-c7ccccc7)cc(-c7ccccc7)c6)c5)c5ccccc5-c5ccccc54)c3)c2)cc1]

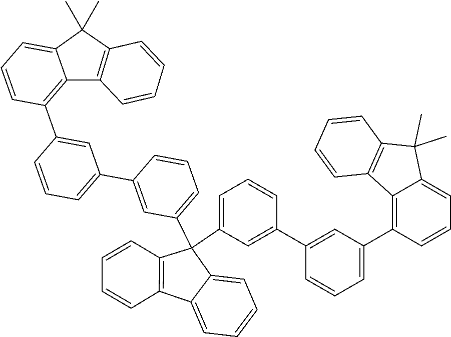 [SMILES: CC1(C)c2ccccc2-c2c(-c3cccc(-c4cccc(C5(c6cccc(-c7cccc(-c8cccc9c8-c8ccccc8C9(C)C)c7)c6)c6ccccc6-c6ccccc65)c4)c3)cccc21]

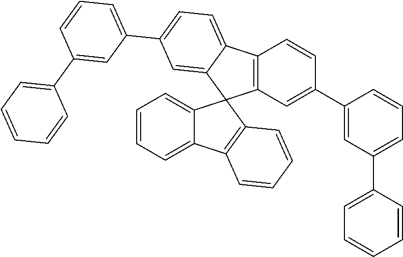 [SMILES: c1ccc(-c2cccc(-c3ccc4c(c3)C3(c5ccccc5-c5ccccc53)c3cc(-c5cccc(-c6ccccc6)c5)ccc3-4)c2)cc1]

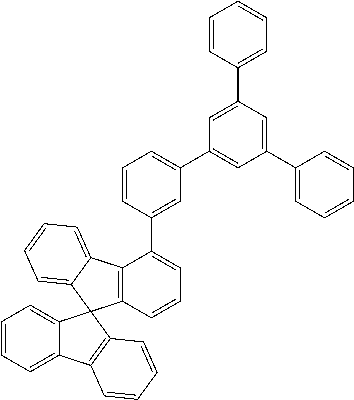 [SMILES: c1ccc(-c2cc(-c3ccccc3)cc(-c3cccc(-c4cccc5c4-c4ccccc4C54c5ccccc5-c5ccccc54)c3)c2)cc1]

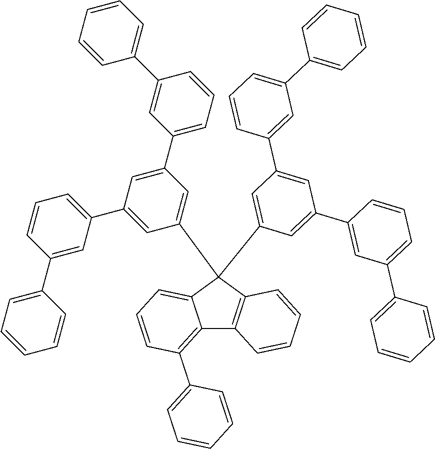 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5c(-c6ccccc6)cccc54)c3)c2)cc1]

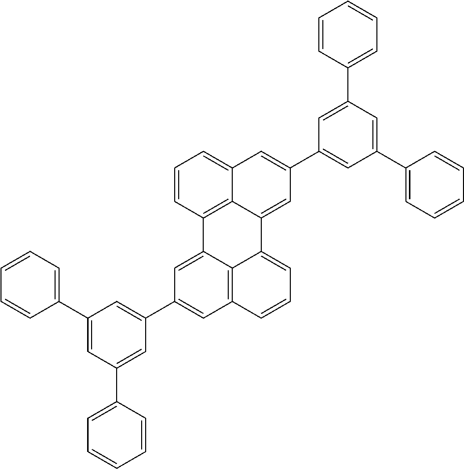 [SMILES: c1ccc(-c2cc(-c3ccccc3)cc(-c3cc4cccc5c6cc(-c7cc(-c8ccccc8)cc(-c8ccccc8)c7)cc7cccc(c(c3)c45)c76)c2)cc1]

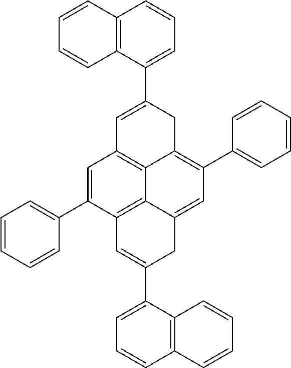 [SMILES: C1=C(c2cccc3ccccc23)Cc2cc(-c3ccccc3)c3c4c(cc(-c5ccccc5)c1c24)C=C(c1cccc2ccccc12)C3]

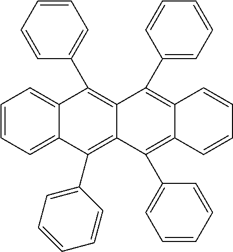 [SMILES: c1ccc(-c2c3ccccc3c(-c3ccccc3)c3c(-c4ccccc4)c4ccccc4c(-c4ccccc4)c23)cc1]

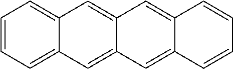 [SMILES: c1ccc2cc3cc4ccccc4cc3cc2c1]

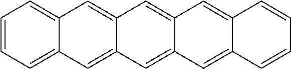 [SMILES: c1ccc2cc3cc4cc5ccccc5cc4cc3cc2c1]

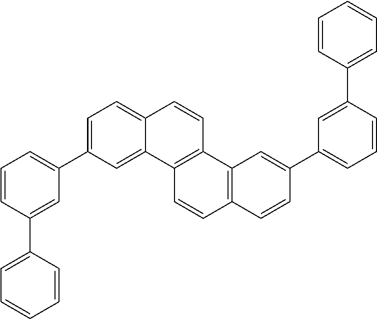 [SMILES: c1ccc(-c2cccc(-c3ccc4ccc5c6cc(-c7cccc(-c8ccccc8)c7)ccc6ccc5c4c3)c2)cc1]

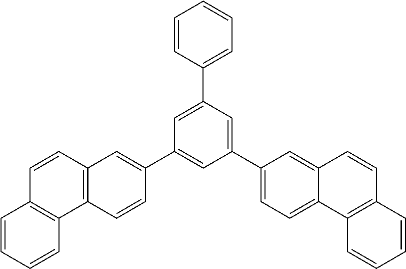 [SMILES: c1ccc(-c2cc(-c3ccc4c(ccc5ccccc54)c3)cc(-c3ccc4c(ccc5ccccc54)c3)c2)cc1]

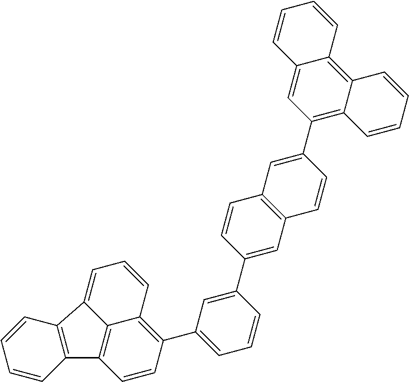 [SMILES: c1cc(-c2ccc3cc(-c4cc5ccccc5c5ccccc45)ccc3c2)cc(-c2ccc3c4c(cccc24)-c2ccccc2-3)c1]

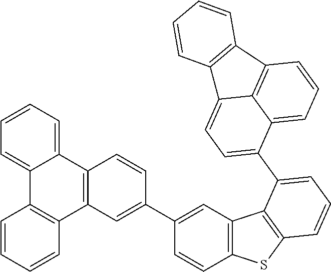 [SMILES: c1ccc2c(c1)-c1cccc3c(-c4cccc5sc6ccc(-c7ccc8c9ccccc9c9ccccc9c8c7)cc6c45)ccc-2c13]

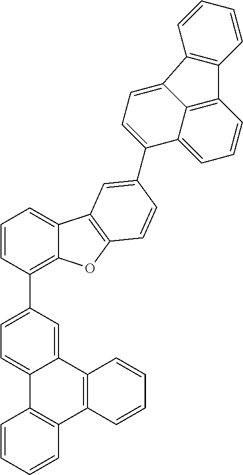 [SMILES: c1ccc2c(c1)-c1cccc3c(-c4ccc5oc6c(-c7ccc8c9ccccc9c9ccccc9c8c7)cccc6c5c4)ccc-2c13]

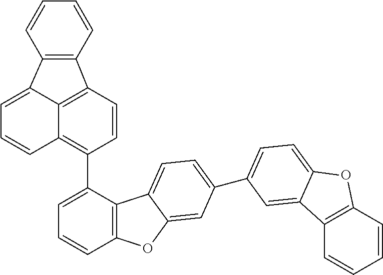 [SMILES: c1ccc2c(c1)-c1cccc3c(-c4cccc5oc6cc(-c7ccc8oc9ccccc9c8c7)ccc6c45)ccc-2c13]

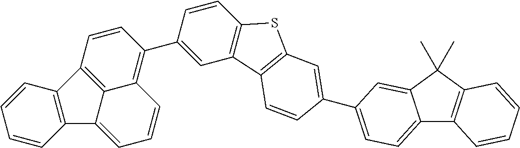 [SMILES: CC1(C)c2ccccc2-c2ccc(-c3ccc4c(c3)sc3ccc(-c5ccc6c7c(cccc57)-c5ccccc5-6)cc34)cc21]

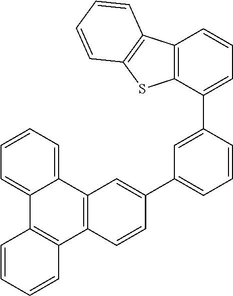 [SMILES: c1cc(-c2ccc3c4ccccc4c4ccccc4c3c2)cc(-c2cccc3c2sc2ccccc23)c1]

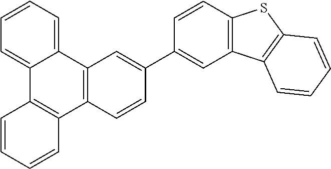 [SMILES: c1ccc2c(c1)sc1ccc(-c3ccc4c5ccccc5c5ccccc5c4c3)cc12]

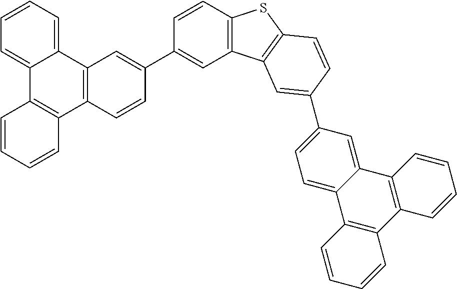 [SMILES: c1ccc2c(c1)c1ccccc1c1cc(-c3ccc4sc5ccc(-c6ccc7c8ccccc8c8ccccc8c7c6)cc5c4c3)ccc21]

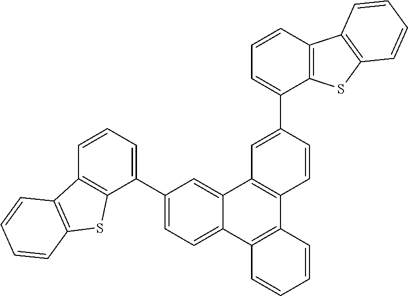 [SMILES: c1ccc2c(c1)sc1c(-c3ccc4c5ccccc5c5ccc(-c6cccc7c6sc6ccccc67)cc5c4c3)cccc12]

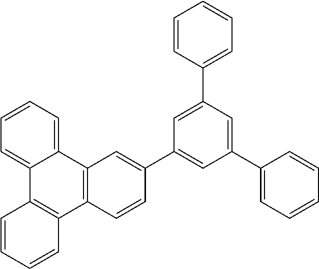 [SMILES: c1ccc(-c2cc(-c3ccccc3)cc(-c3ccc4c5ccccc5c5ccccc5c4c3)c2)cc1]

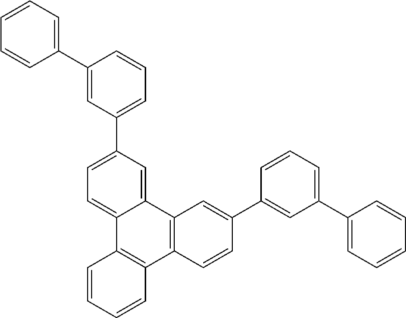 [SMILES: c1ccc(-c2cccc(-c3ccc4c5ccccc5c5ccc(-c6cccc(-c7ccccc7)c6)cc5c4c3)c2)cc1]

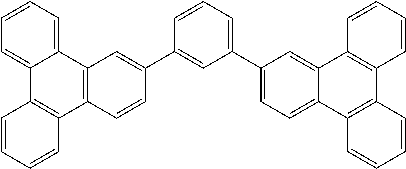 [SMILES: c1cc(-c2ccc3c4ccccc4c4ccccc4c3c2)cc(-c2ccc3c4ccccc4c4ccccc4c3c2)c1]

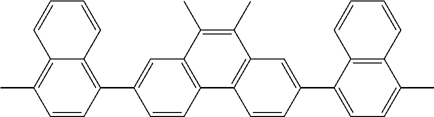

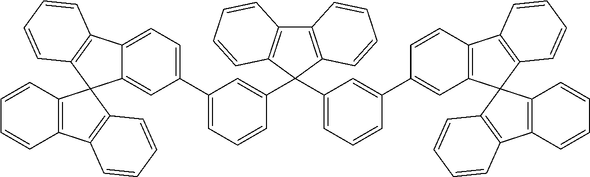 [SMILES: c1cc(-c2ccc3c(c2)C2(c4ccccc4-c4ccccc42)c2ccccc2-3)cc(C2(c3cccc(-c4ccc5c(c4)C4(c6ccccc6-c6ccccc64)c4ccccc4-5)c3)c3ccccc3-c3ccccc32)c1]

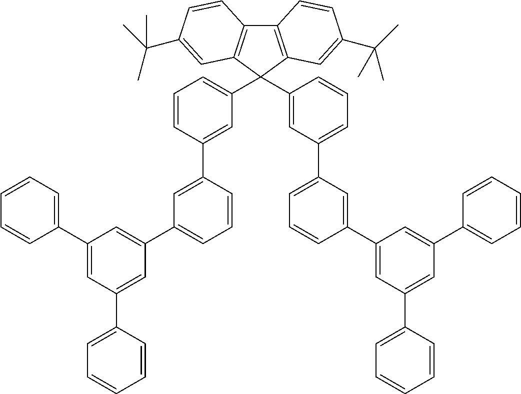 [SMILES: CC(C)(C)c1ccc2c(c1)C(c1cccc(-c3cccc(-c4cc(-c5ccccc5)cc(-c5ccccc5)c4)c3)c1)(c1cccc(-c3cccc(-c4cc(-c5ccccc5)cc(-c5ccccc5)c4)c3)c1)c1cc(C(C)(C)C)ccc1-2]

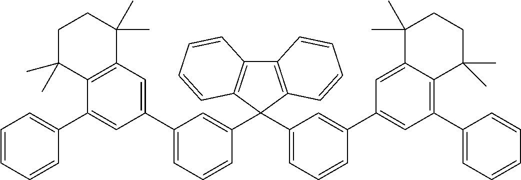 [SMILES: CC1(C)CCC(C)(C)c2c(-c3ccccc3)cc(-c3cccc(C4(c5cccc(-c6cc(-c7ccccc7)c7c(c6)C(C)(C)CCC7(C)C)c5)c5ccccc5-c5ccccc54)c3)cc21]

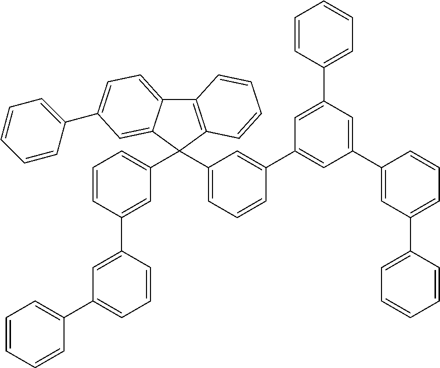 [SMILES: c1ccc(-c2cccc(-c3cc(-c4ccccc4)cc(-c4cccc(C5(c6cccc(-c7cccc(-c8ccccc8)c7)c6)c6ccccc6-c6ccc(-c7ccccc7)cc65)c4)c3)c2)cc1]

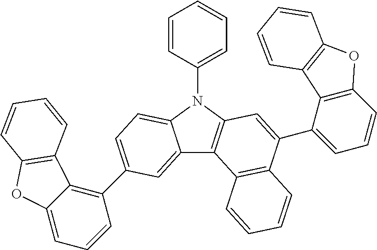 [SMILES: c1ccc(-n2c3ccc(-c4cccc5oc6ccccc6c45)cc3c3c4ccccc4c(-c4cccc5oc6ccccc6c45)cc32)cc1]

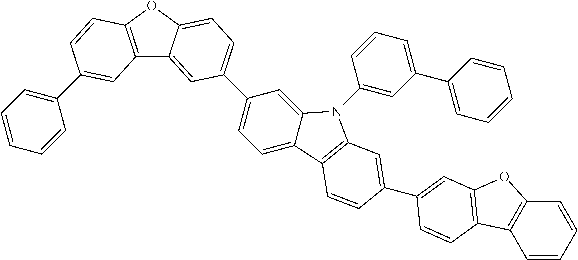 [SMILES: c1ccc(-c2cccc(-n3c4cc(-c5ccc6c(c5)oc5ccccc56)ccc4c4ccc(-c5ccc6oc7ccc(-c8ccccc8)cc7c6c5)cc43)c2)cc1]

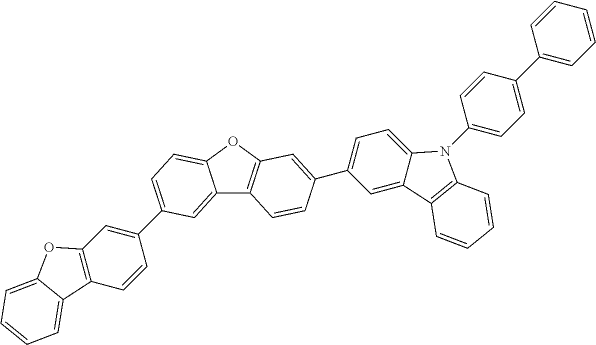 [SMILES: c1ccc(-c2ccc(-n3c4ccccc4c4cc(-c5ccc6c(c5)oc5ccc(-c7ccc8c(c7)oc7ccccc78)cc56)ccc43)cc2)cc1]

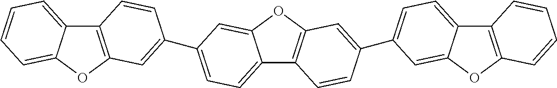 [SMILES: c1ccc2c(c1)oc1cc(-c3ccc4c(c3)oc3cc(-c5ccc6c(c5)oc5ccccc56)ccc34)ccc12]

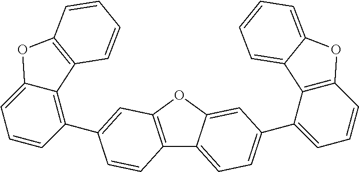 [SMILES: c1ccc2c(c1)oc1cccc(-c3ccc4c(c3)oc3cc(-c5cccc6oc7ccccc7c56)ccc34)c12]

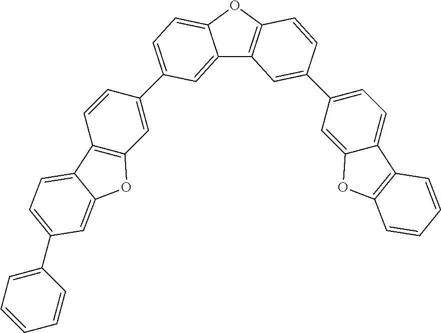 [SMILES: c1ccc(-c2ccc3c(c2)oc2cc(-c4ccc5oc6ccc(-c7ccc8c(c7)oc7ccccc78)cc6c5c4)ccc23)cc1]

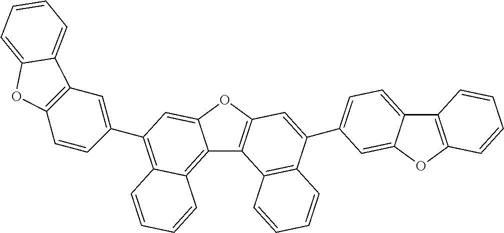 [SMILES: c1ccc2c(c1)oc1cc(-c3cc4oc5cc(-c6ccc7oc8ccccc8c7c6)c6ccccc6c5c4c4ccccc34)ccc12]

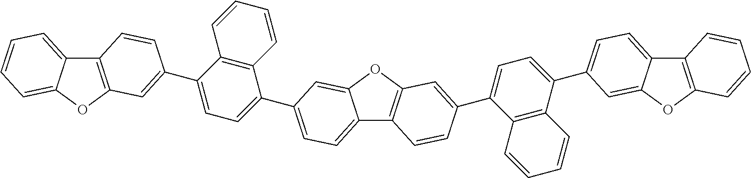 [SMILES: c1ccc2c(c1)oc1cc(-c3ccc(-c4ccc5c(c4)oc4cc(-c6ccc(-c7ccc8c(c7)oc7ccccc78)c7ccccc67)ccc45)c4ccccc34)ccc12]

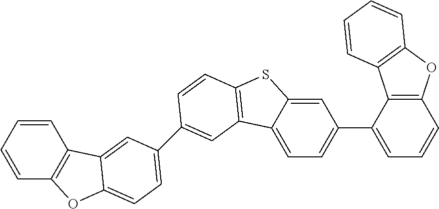 [SMILES: c1ccc2c(c1)oc1ccc(-c3ccc4sc5cc(-c6cccc7oc8ccccc8c67)ccc5c4c3)cc12]

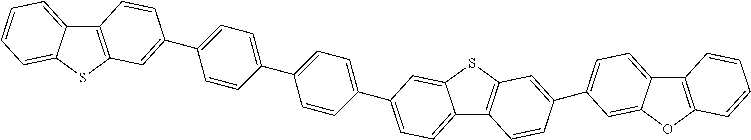 [SMILES: c1ccc2c(c1)oc1cc(-c3ccc4c(c3)sc3cc(-c5ccc(-c6ccc(-c7ccc8c(c7)sc7ccccc78)cc6)cc5)ccc34)ccc12]

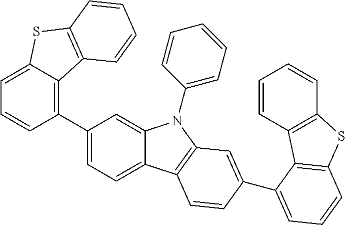 [SMILES: c1ccc(-n2c3cc(-c4cccc5sc6ccccc6c45)ccc3c3ccc(-c4cccc5sc6ccccc6c45)cc32)cc1]

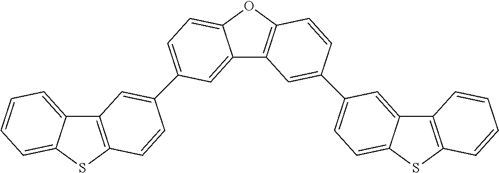 [SMILES: c1ccc2c(c1)sc1ccc(-c3ccc4oc5ccc(-c6ccc7sc8ccccc8c7c6)cc5c4c3)cc12]

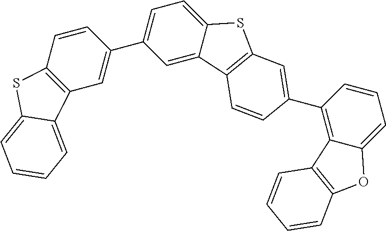 [SMILES: c1ccc2c(c1)oc1cccc(-c3ccc4c(c3)sc3ccc(-c5ccc6sc7ccccc7c6c5)cc34)c12]

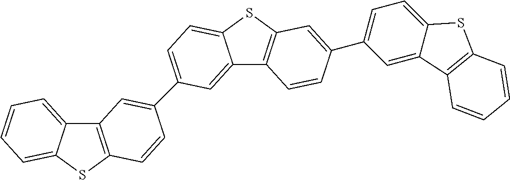 [SMILES: c1ccc2c(c1)sc1ccc(-c3ccc4c(c3)sc3ccc(-c5ccc6sc7ccccc7c6c5)cc34)cc12]

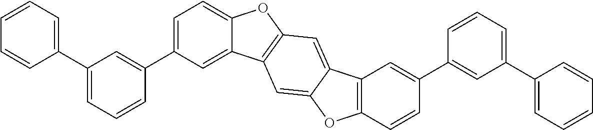 [SMILES: c1ccc(-c2cccc(-c3ccc4oc5cc6c(cc5c4c3)oc3ccc(-c4cccc(-c5ccccc5)c4)cc36)c2)cc1]

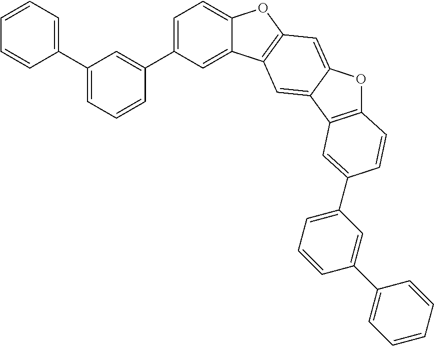 [SMILES: c1ccc(-c2cccc(-c3ccc4oc5cc6oc7ccc(-c8cccc(-c9ccccc9)c8)cc7c6cc5c4c3)c2)cc1]

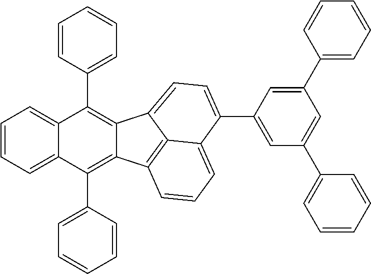 [SMILES: c1ccc(-c2cc(-c3ccccc3)cc(-c3ccc4c5c(cccc35)-c3c-4c(-c4ccccc4)c4ccccc4c3-c3ccccc3)c2)cc1]

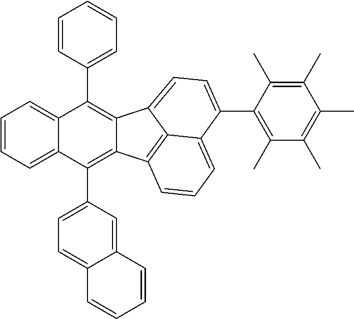 [SMILES: Cc1c(C)c(C)c(-c2ccc3c4c(cccc24)-c2c-3c(-c3ccccc3)c3ccccc3c2-c2ccc3ccccc3c2)c(C)c1C]

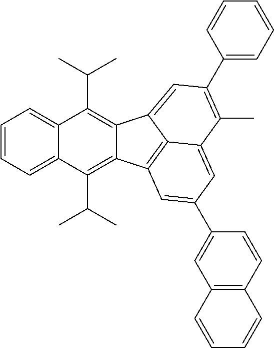 [SMILES: Cc1c(-c2ccccc2)cc2c3c(cc(-c4ccc5ccccc5c4)cc13)-c1c-2c(C(C)C)c2ccccc2c1C(C)C]

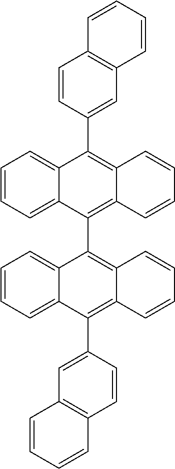 [SMILES: c1ccc2cc(-c3c4ccccc4c(-c4c5ccccc5c(-c5ccc6ccccc6c5)c5ccccc45)c4ccccc34)ccc2c1]

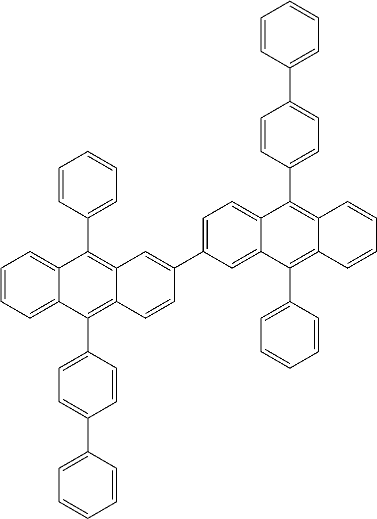 [SMILES: c1ccc(-c2ccc(-c3c4ccccc4c(-c4ccccc4)c4cc(-c5ccc6c(-c7ccc(-c8ccccc8)cc7)c7ccccc7c(-c7ccccc7)c6c5)ccc34)cc2)cc1]

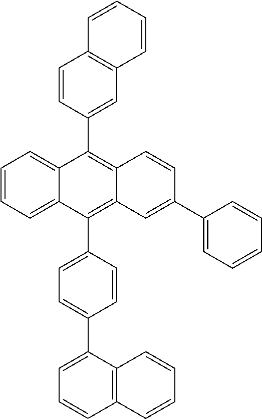 [SMILES: c1ccc(-c2ccc3c(-c4ccc5ccccc5c4)c4ccccc4c(-c4ccc(-c5cccc6ccccc56)cc4)c3c2)cc1]

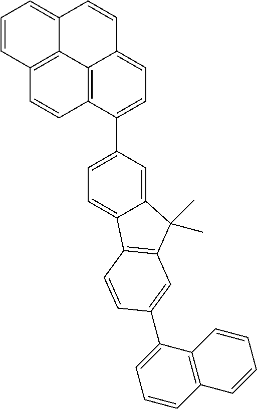 [SMILES: CC1(C)c2cc(-c3cccc4ccccc34)ccc2-c2ccc(-c3ccc4ccc5cccc6ccc3c4c56)cc21]

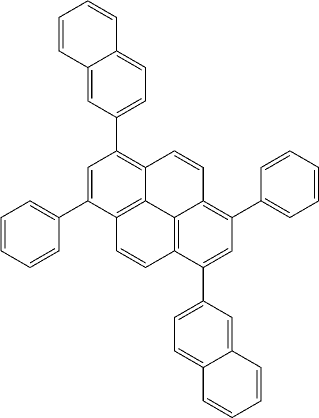 [SMILES: c1ccc(-c2cc(-c3ccc4ccccc4c3)c3ccc4c(-c5ccccc5)cc(-c5ccc6ccccc6c5)c5ccc2c3c45)cc1]

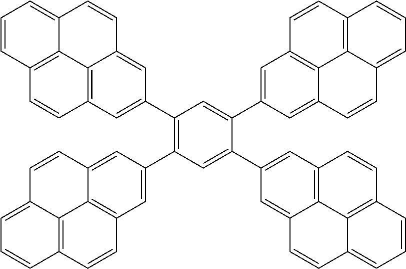 [SMILES: c1cc2ccc3cc(-c4cc(-c5cc6ccc7cccc8ccc(c5)c6c78)c(-c5cc6ccc7cccc8ccc(c5)c6c78)cc4-c4cc5ccc6cccc7ccc(c4)c5c67)cc4ccc(c1)c2c34]

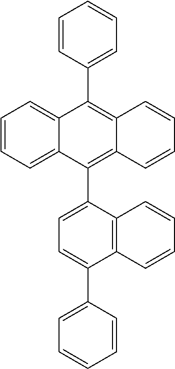 [SMILES: c1ccc(-c2ccc(-c3c4ccccc4c(-c4ccccc4)c4ccccc34)c3ccccc23)cc1]

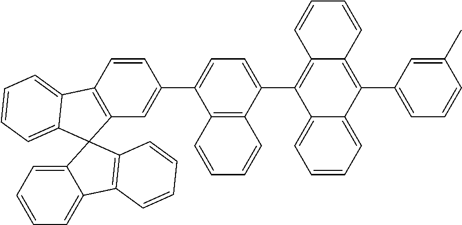 [SMILES: Cc1cccc(-c2c3ccccc3c(-c3ccc(-c4ccc5c(c4)C4(c6ccccc6-c6ccccc64)c4ccccc4-5)c4ccccc34)c3ccccc23)c1]

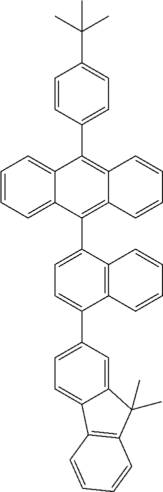 [SMILES: CC(C)(C)c1ccc(-c2c3ccccc3c(-c3ccc(-c4ccc5c(c4)C(C)(C)c4ccccc4-5)c4ccccc34)c3ccccc23)cc1]

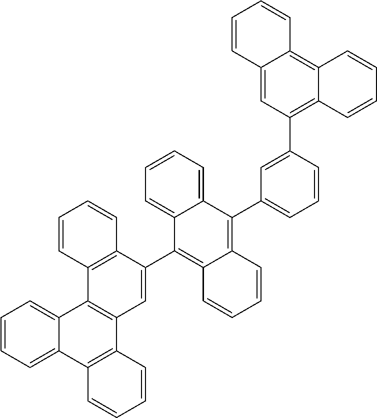 [SMILES: c1cc(-c2c3ccccc3c(-c3cc4c5ccccc5c5ccccc5c4c4ccccc34)c3ccccc23)cc(-c2cc3ccccc3c3ccccc23)c1]

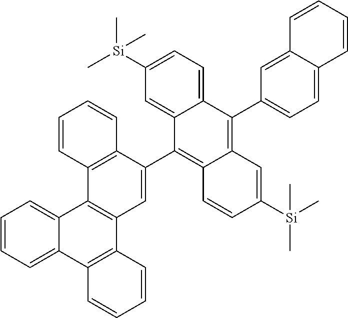 [SMILES: C[Si](C)(C)c1ccc2c(-c3cc4c5ccccc5c5ccccc5c4c4ccccc34)c3cc([Si](C)(C)C)ccc3c(-c3ccc4ccccc4c3)c2c1]

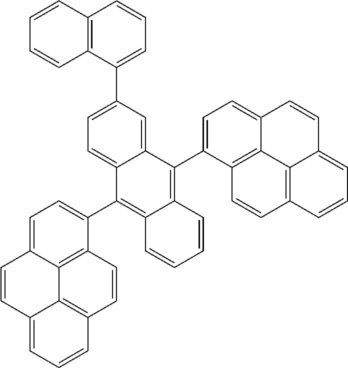 [SMILES: c1ccc2c(-c3ccc4c(-c5ccc6ccc7cccc8ccc5c6c78)c5ccccc5c(-c5ccc6ccc7cccc8ccc5c6c78)c4c3)cccc2c1]

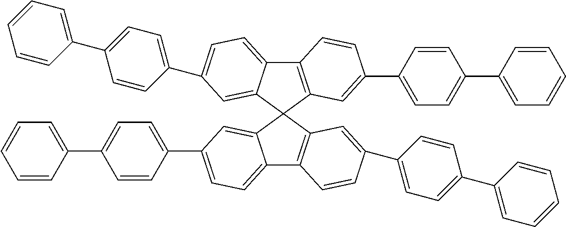 [SMILES: c1ccc(-c2ccc(-c3ccc4c(c3)C3(c5cc(-c6ccc(-c7ccccc7)cc6)ccc5-4)c4cc(-c5ccc(-c6ccccc6)cc5)ccc4-c4ccc(-c5ccc(-c6ccccc6)cc5)cc43)cc2)cc1]

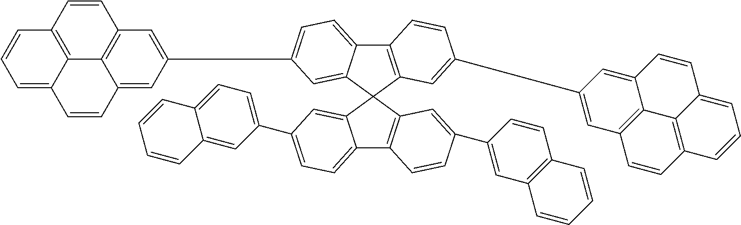 [SMILES: c1ccc2cc(-c3ccc4c(c3)C3(c5cc(-c6ccc7ccccc7c6)ccc5-4)c4cc(-c5cc6ccc7cccc8ccc(c5)c6c78)ccc4-c4ccc(-c5cc6ccc7cccc8ccc(c5)c6c78)cc43)ccc2c1]

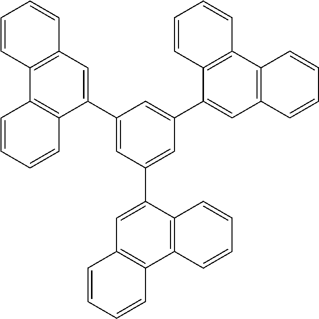 [SMILES: c1ccc2c(c1)cc(-c1cc(-c3cc4ccccc4c4ccccc34)cc(-c3cc4ccccc4c4ccccc34)c1)c1ccccc12]

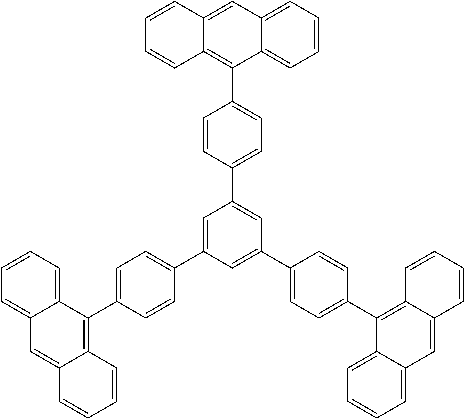 [SMILES: c1ccc2c(-c3ccc(-c4cc(-c5ccc(-c6c7ccccc7cc7ccccc67)cc5)cc(-c5ccc(-c6c7ccccc7cc7ccccc67)cc5)c4)cc3)c3ccccc3cc2c1]

The compound C2 preferably has a molar weight of 400 g/mol or higher, more preferably between 500 g/mol and 1200 g/mol. Furthermore, preferably, the compounds C2 has a glass transition temperature T_{g}>100° C. The glass transition temperature (Tg) is determined using a technique called differential scanning calorimetry (DSC), which is well established and known in the art. The glass transition is characterized by a step in the heat flow-temperature curve. The temperature at which this transition occurs is the glass transition temperature (Tg) of the material.

Compound C3 is a p-dopant. It has the function of p-doping the layer A. P-dopants are preferably understood to be organic compounds which are electron acceptor compounds, and which are capable of oxidizing one or more of the other compounds that are present together with them in mixture in the layer, in particular capable of oxidizing the compound C1 in the layer A of the device according to the invention. P-dopants such as compound C3 preferably have a LUMO, which has an energy which is not more than 1.0 eV, preferably not more than 0.5 eV higher than the other components of the layer, in particular the compound C1. More preferred is that the LUMO of the p-dopant such as C3 has a lower energy level than the energy level of the HOMO of the other components of the layer, in particular the compound C1. LUMO values of compounds according to the present application are determined by quantum chemical calculation, as described in the section E) of the examples of the present application. “Higher” and “lower” is understood for LUMO values in the same way as described above for HOMO values.

P-dopants such as compound C3 are preferably present in substantially homogeneous distribution in the layer. This can be achieved, for example, by co-evaporation of the p-dopant and the other compounds present in the layer, which is preferred. Or, it can be achieved by application of a solution comprising the p-dopant and the other components of the layer A, to form a layer A. The p-dopant, in particular the compound C3, is preferably present in a proportion of 1% to 10%, preferably 3% to 8%, in the p-doped layer. The ratio is determined by volume in the case that the compound is applied from vapor, and by weight, if the compound is applied from solution. Preferably, the compound is applied from vapor, and the ratio is determined by volume.

Compounds C3 are preferably metal organic electron acceptor compounds or organic electron acceptor compounds. Preferably they are organic electron acceptor compounds. Compounds C3 are preferably selected from aromatic or heteroaromatic condensed rings, in particular those substituted with electron-withdrawing groups; quinodimethanes, in particular para-quinodimethanes, in particular di-cyano-quinodimethanes; conjugated diones, in particular conjugated cyclic diones; indenofluorenediones; azaindenofluorenediones; azaphenalenes, in particular hepta-aza-phenalenes; azatriphenylenes, in particular hexa-aza-triphenylenes; azines, preferably triazines, pyrimidines and pyridines; boron compounds, in particular boronic acid esters or triarylboron derivatives; trimethylene-cyclopropanes, in particular hexacyano-trimethylene-cyclopropanes; 12; metal halides, preferably transition metal halides; metal oxides, preferably metal oxides comprising at least one transition metal or a metal from main group 3, more preferably transition metal oxides, even more preferably oxides of rhenium, molybdenum and tungsten, even more preferably Re₂O₇, MoO₃, WO₃ and ReO₃; transition metal complexes, preferably complexes of Cu, Co, Fe, Ni, Pd and Pt, preferably with ligands containing at least one oxygen atom as binding site, such as preferably CO ligands or ligands containing at least one carboxyl group, or cyclopentadienyl ligands; and main group metal complexes.

Preferred compounds C3 are those listed below:
1) Complexes of main group metals and transition metals, as disclosed inter alia in WO2021/151959, DE 102018118278 A1, WO 2021/048044 A1, U.S. Pat. No. 9,166,178 B2, DE 102012209523 A1, US 2018/108849 A1 and WO 2009/106068 A1. “Cp” in the following stands for cyclopentadienyl.

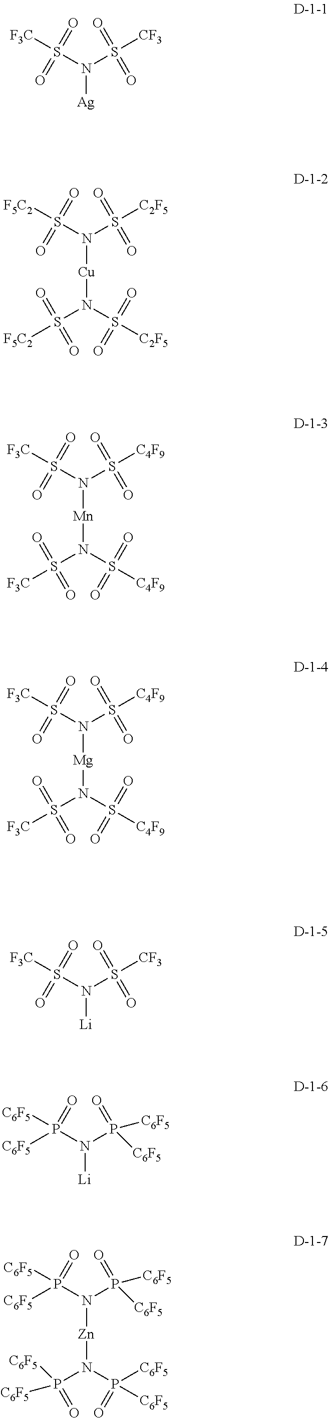

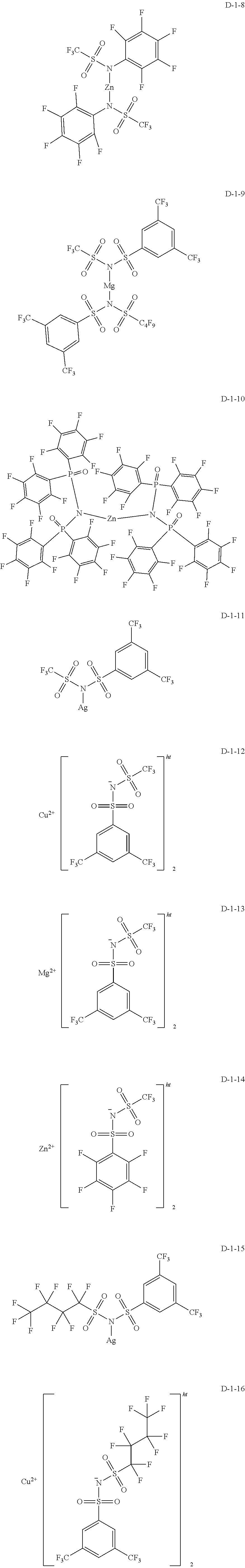

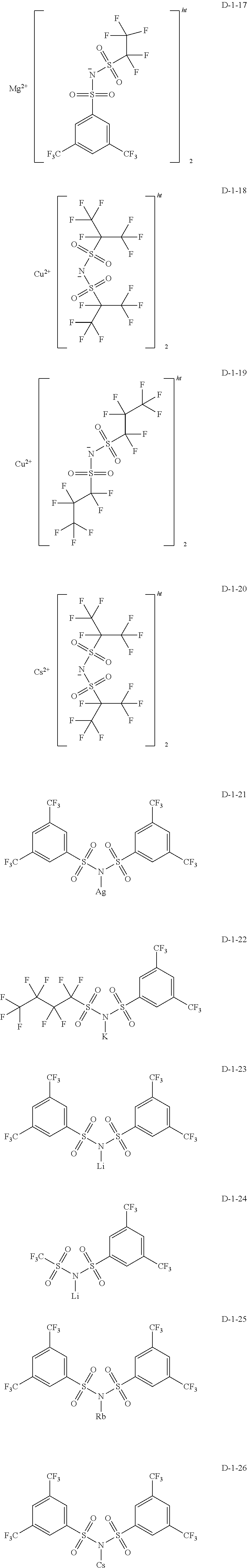

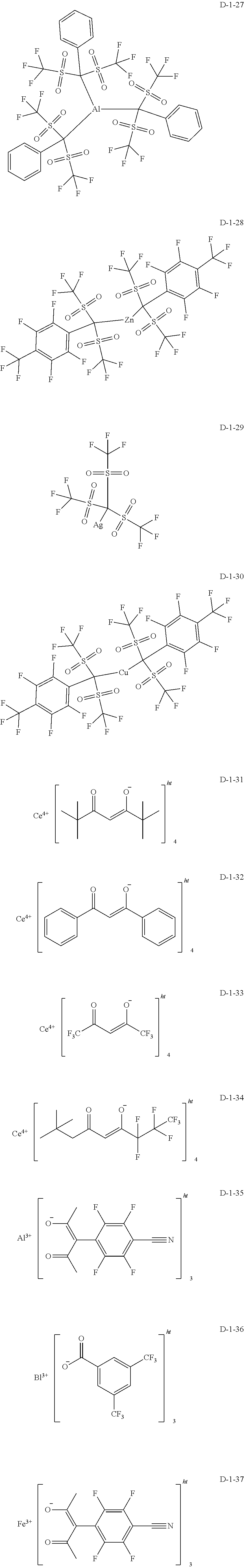

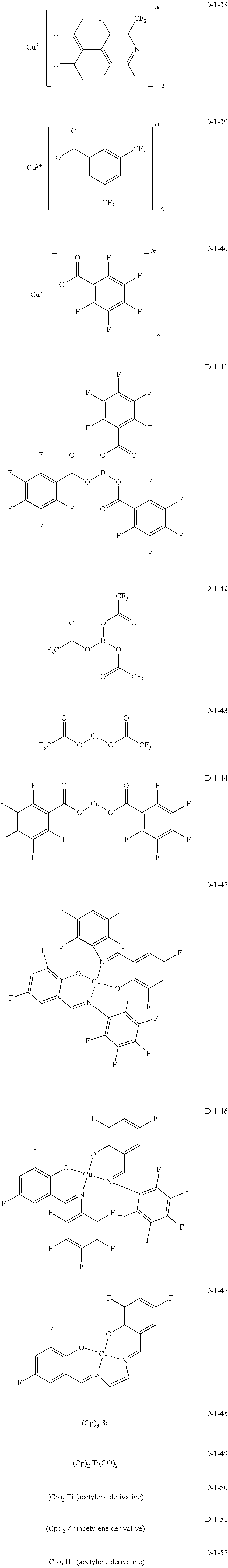

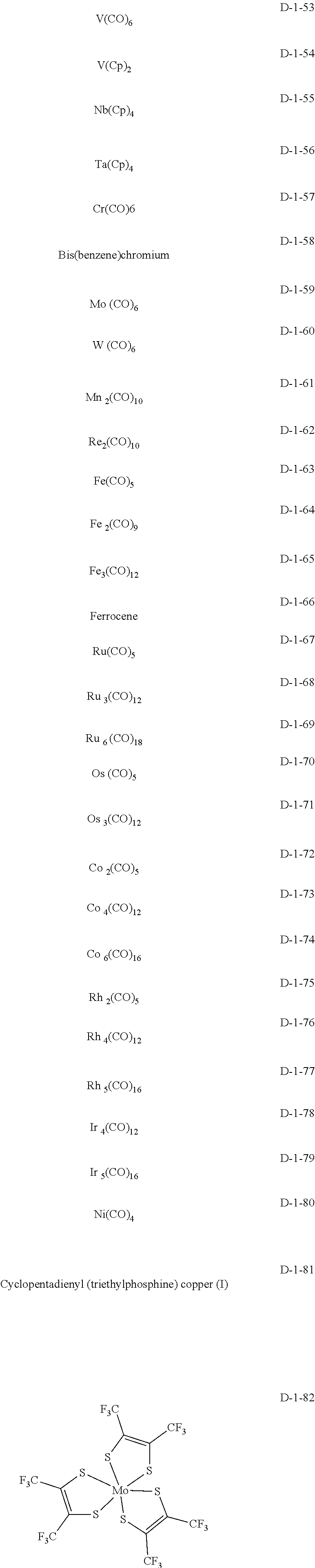

2) Azines, cyclic diones, quinodimethanes, dicyano-quinodimethanes, and boron compounds, as disclosed inter alia in US2021/050527, WO2022/010068, US2017/040536, US2003/008174, CN110483529, WO2012/031735, KR2017-0114778, US2020/235304, KR102230986, US2021/202858, US2022/123217, US2022/238814, US2022/231231, US2020/144552, US2018/331297, US2018/086775, US2018/309057, US2020/127207, U.S. Pat. No. 8,481,177, US2014/001461, US2021/119162, US2019/058128, WO2009/003455, US2019/088896, KR2018-0051356, CN110383518, US2009/152535, CN110383518, WO2010/097433, US2021/280795, US2022/020935, DE102020104604, US2020/087311, CN115207254, US2019/131548, US2020/091430, US2005-139810, and US2003/006411:

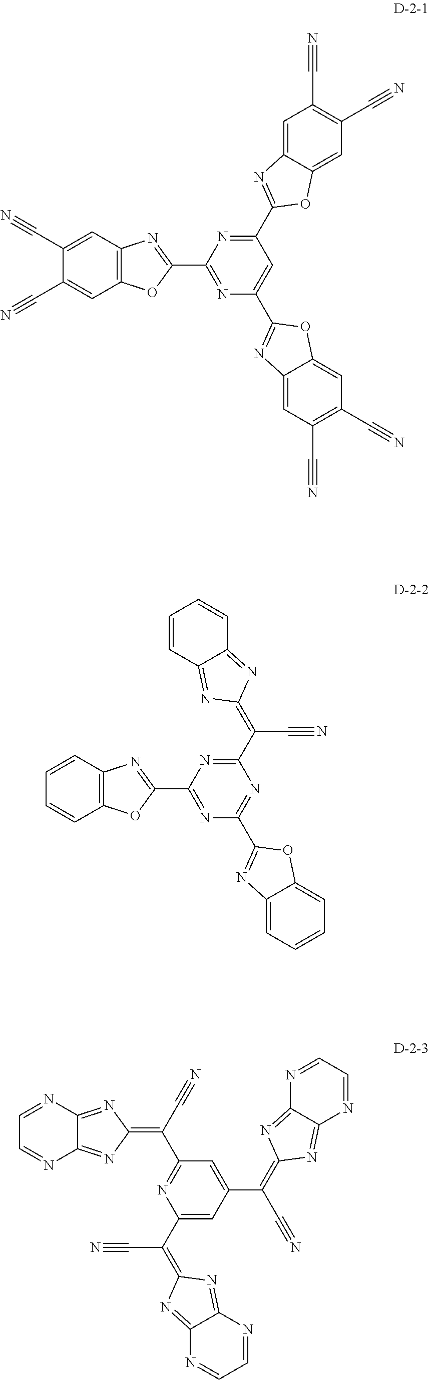 [SMILES: N#Cc1cc2nc(-c3cc(-c4nc5cc(C#N)c(C#N)cc5o4)nc(-c4nc5cc(C#N)c(C#N)cc5o4)n3)oc2cc1C#N ; N#CC(=C1N=c2ccccc2=N1)c1nc(-c2nc3ccccc3o2)nc(-c2nc3ccccc3o2)n1 ; N#CC(=C1N=c2nccnc2=N1)c1cc(C(C#N)=C2N=c3nccnc3=N2)nc(C(C#N)=C2N=c3nccnc3=N2)c1]

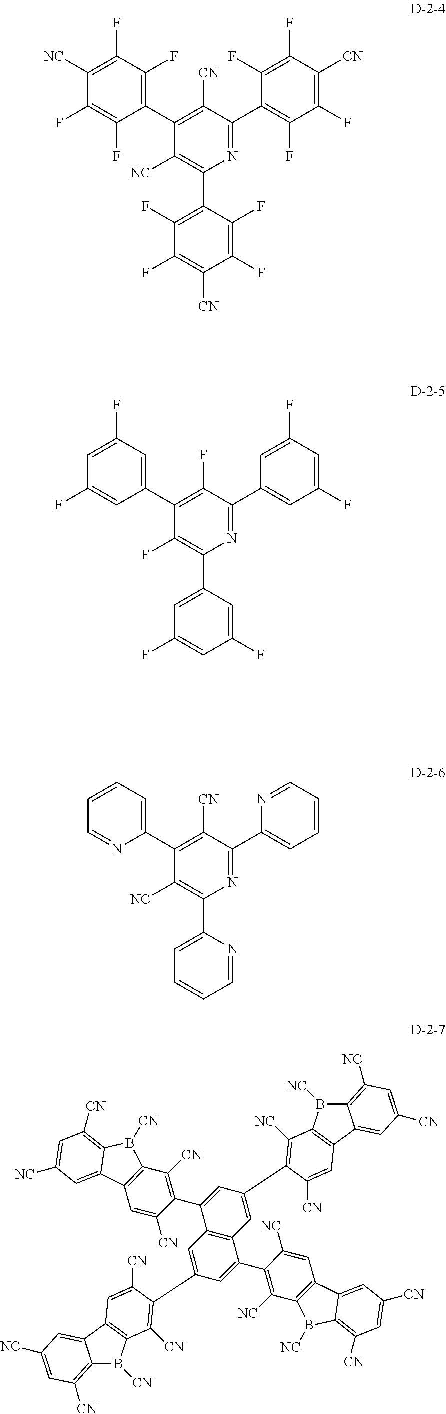 [SMILES: N#Cc1c(F)c(F)c(-c2nc(-c3c(F)c(F)c(C#N)c(F)c3F)c(C#N)c(-c3c(F)c(F)c(C#N)c(F)c3F)c2C#N)c(F)c1F ; Fc1cc(F)cc(-c2nc(-c3cc(F)cc(F)c3)c(F)c(-c3cc(F)cc(F)c3)c2F)c1 ; N#Cc1c(-c2ccccn2)nc(-c2ccccn2)c(C#N)c1-c1ccccn1 ; N#CB1c2c(C#N)cc(C#N)cc2-c2cc(C#N)c(-c3cc(-c4c(C#N)cc5c(c4C#N)B(C#N)c4c(C#N)cc(C#N)cc4-5)c4cc(-c5c(C#N)cc6c(c5C#N)B(C#N)c5c(C#N)cc(C#N)cc5-6)cc(-c5c(C#N)cc6c(c5C#N)B(C#N)c5c(C#N)cc(C#N)cc5-6)c4c3)c(C#N)c21]

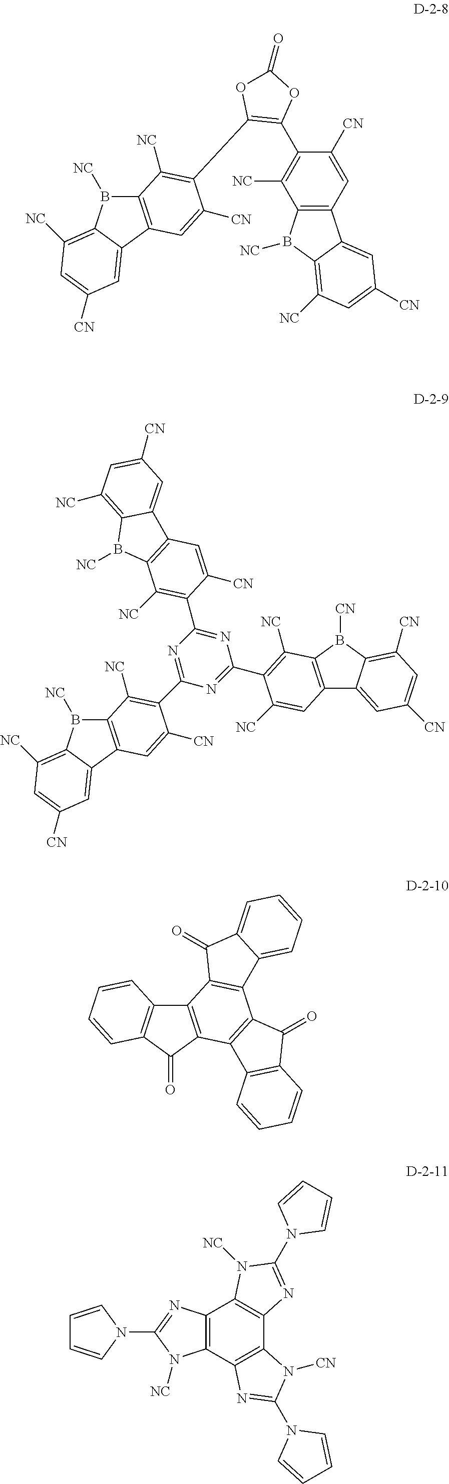 [SMILES: N#CB1c2c(C#N)cc(C#N)cc2-c2cc(C#N)c(-c3oc(=O)oc3-c3c(C#N)cc4c(c3C#N)B(C#N)c3c(C#N)cc(C#N)cc3-4)c(C#N)c21 ; N#CB1c2c(C#N)cc(C#N)cc2-c2cc(C#N)c(-c3nc(-c4c(C#N)cc5c(c4C#N)B(C#N)c4c(C#N)cc(C#N)cc4-5)nc(-c4c(C#N)cc5c(c4C#N)B(C#N)c4c(C#N)cc(C#N)cc4-5)n3)c(C#N)c21 ; O=c1c2ccccc2c2c1c1c3ccccc3c(=O)c1c1c3ccccc3c(=O)c21 ; N#Cn1c(-n2cccc2)nc2c1c1nc(-n3cccc3)n(C#N)c1c1nc(-n3cccc3)n(C#N)c21]

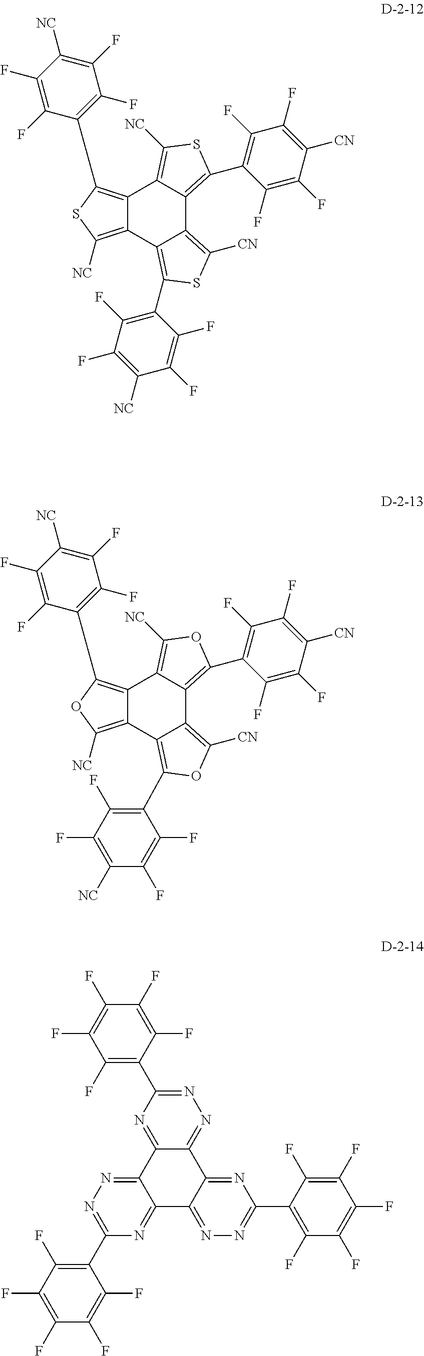 [SMILES: N#Cc1c(F)c(F)c(-c2sc(C#N)c3c2c2c(C#N)sc(-c4c(F)c(F)c(C#N)c(F)c4F)c2c2c(C#N)sc(-c4c(F)c(F)c(C#N)c(F)c4F)c32)c(F)c1F ; N#Cc1c(F)c(F)c(-c2oc(C#N)c3c2c2c(C#N)oc(-c4c(F)c(F)c(C#N)c(F)c4F)c2c2c(C#N)oc(-c4c(F)c(F)c(C#N)c(F)c4F)c32)c(F)c1F ; Fc1c(F)c(F)c(-c2nnc3c(n2)c2nnc(-c4c(F)c(F)c(F)c(F)c4F)nc2c2nnc(-c4c(F)c(F)c(F)c(F)c4F)nc32)c(F)c1F]

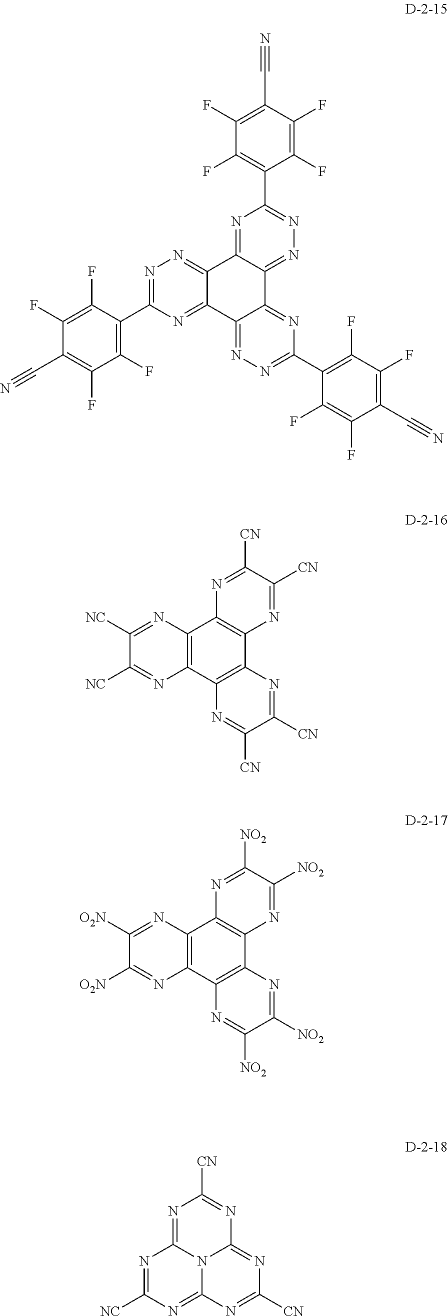 [SMILES: N#Cc1c(F)c(F)c(-c2nnc3c(n2)c2nnc(-c4c(F)c(F)c(C#N)c(F)c4F)nc2c2nnc(-c4c(F)c(F)c(C#N)c(F)c4F)nc32)c(F)c1F ; N#Cc1nc2c3nc(C#N)c(C#N)nc3c3nc(C#N)c(C#N)nc3c2nc1C#N ; O=[N+]([O-])c1nc2c3nc([N+](=O)[O-])c([N+](=O)[O-])nc3c3nc([N+](=O)[O-])c([N+](=O)[O-])nc3c2nc1[N+](=O)[O-] ; N#CC1=NC2=NC(C#N)=NC3=NC(C#N)=NC(=N1)N23]

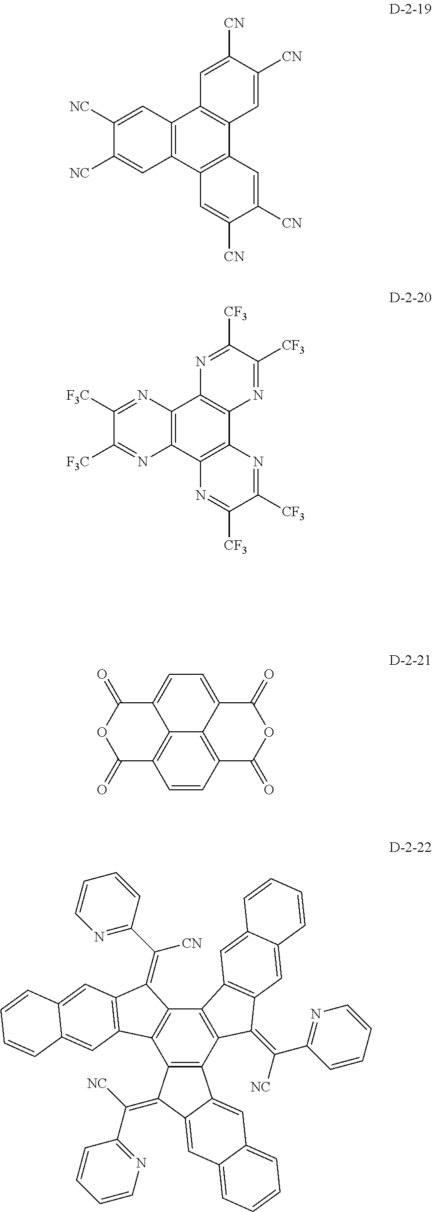 [SMILES: N#Cc1cc2c3cc(C#N)c(C#N)cc3c3cc(C#N)c(C#N)cc3c2cc1C#N ; FC(F)(F)c1nc2c3nc(C(F)(F)F)c(C(F)(F)F)nc3c3nc(C(F)(F)F)c(C(F)(F)F)nc3c2nc1C(F)(F)F ; O=C1OC(=O)c2ccc3c4c(ccc1c24)C(=O)OC3=O ; N#C/C(=C1/c2cc3ccccc3cc2-c2c1c1c(c3c2/C(=C(\C#N)c2ccccn2)c2cc4ccccc4cc2-3)/C(=C(\C#N)c2ccccn2)c2cc3ccccc3cc2-1)c1ccccn1]

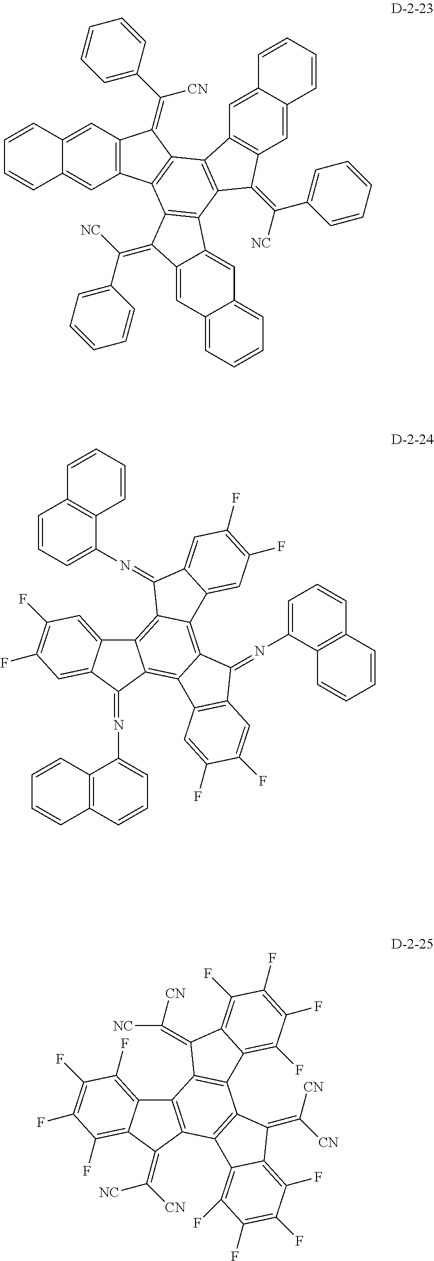 [SMILES: N#C/C(=C1/c2cc3ccccc3cc2-c2c1c1c(c3c2/C(=C(\C#N)c2ccccc2)c2cc4ccccc4cc2-3)/C(=C(\C#N)c2ccccc2)c2cc3ccccc3cc2-1)c1ccccc1 ; Fc1cc2c(=Nc3cccc4ccccc34)c3c(c2cc1F)c1c(=Nc2cccc4ccccc24)c2cc(F)c(F)cc2c1c1c(=Nc2cccc4ccccc24)c2cc(F)c(F)cc2c31 ; N#CC(C#N)=C1c2c(F)c(F)c(F)c(F)c2-c2c1c1c(c3c2C(=C(C#N)C#N)c2c(F)c(F)c(F)c(F)c2-3)C(=C(C#N)C#N)c2c(F)c(F)c(F)c(F)c2-1]

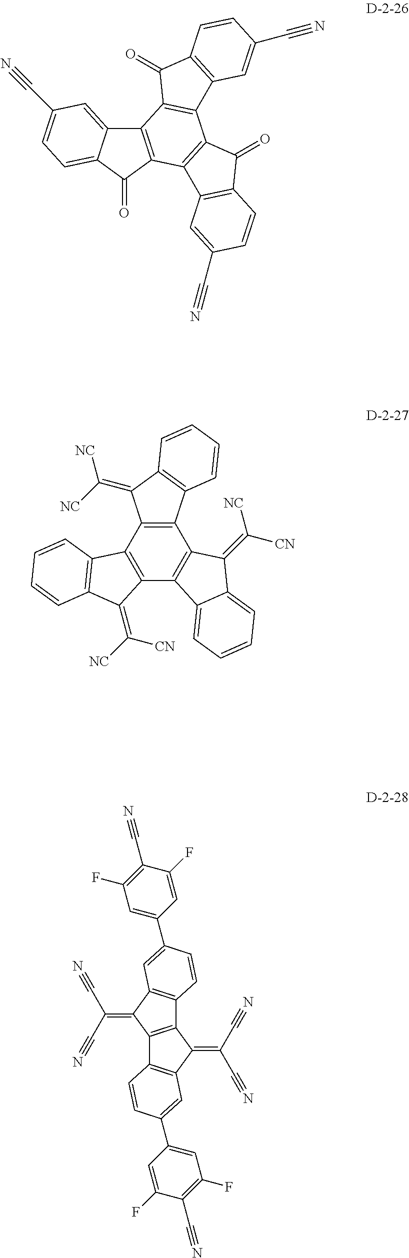 [SMILES: N#Cc1ccc2c(=O)c3c(c2c1)c1c(=O)c2ccc(C#N)cc2c1c1c(=O)c2ccc(C#N)cc2c31 ; N#CC(C#N)=C1c2ccccc2-c2c1c1c(c3c2C(=C(C#N)C#N)c2ccccc2-3)C(=C(C#N)C#N)c2ccccc2-1 ; N#CC(C#N)=C1C2=C(C(=C(C#N)C#N)c3cc(-c4cc(F)c(C#N)c(F)c4)ccc32)c2ccc(-c3cc(F)c(C#N)c(F)c3)cc21]

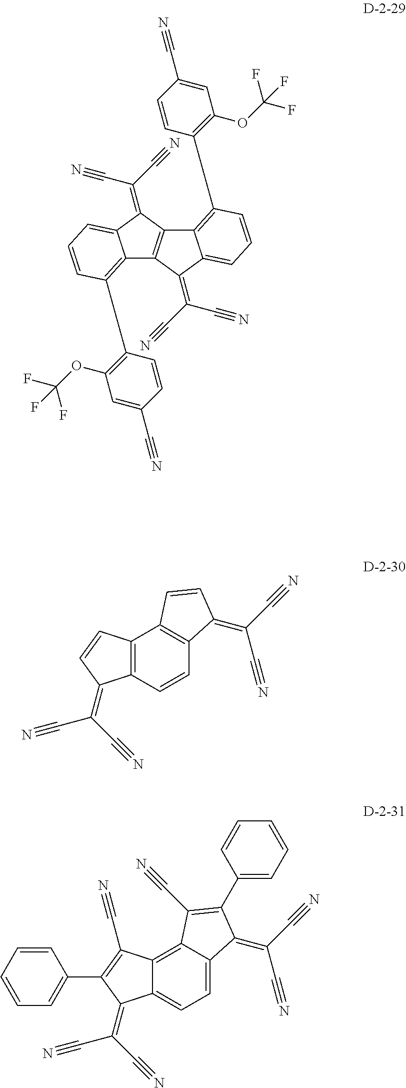 [SMILES: N#CC(C#N)=C1C2=C(C(=C(C#N)C#N)c3cccc(-c4ccc(C#N)cc4OC(F)(F)F)c32)c2c1cccc2-c1ccc(C#N)cc1OC(F)(F)F ; N#CC(C#N)=C1C=Cc2c1ccc1c2C=CC1=C(C#N)C#N ; N#CC(C#N)=C1C(c2ccccc2)=C(C#N)c2c1ccc1c2C(C#N)=C(c2ccccc2)C1=C(C#N)C#N]

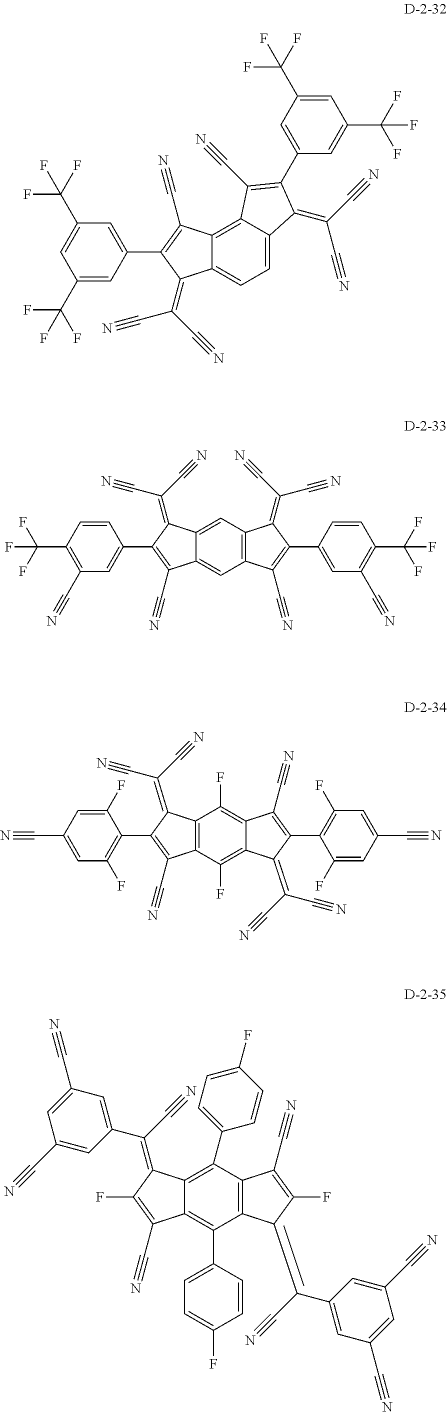 [SMILES: N#CC(C#N)=C1C(c2cc(C(F)(F)F)cc(C(F)(F)F)c2)=C(C#N)c2c1ccc1c2C(C#N)=C(c2cc(C(F)(F)F)cc(C(F)(F)F)c2)C1=C(C#N)C#N ; N#CC(C#N)=C1C(c2ccc(C(F)(F)F)c(C#N)c2)=C(C#N)c2cc3c(cc21)C(=C(C#N)C#N)C(c1ccc(C(F)(F)F)c(C#N)c1)=C3C#N ; N#CC(C#N)=C1C(c2c(F)cc(C#N)cc2F)=C(C#N)c2c(F)c3c(c(F)c21)C(C#N)=C(c1c(F)cc(C#N)cc1F)C3=C(C#N)C#N ; N#CC1=C(F)/C(=C(/C#N)c2cc(C#N)cc(C#N)c2)c2c1c(-c1ccc(F)cc1)c1c(c2-c2ccc(F)cc2)C(C#N)=C(F)/C1=C(/C#N)c1cc(C#N)cc(C#N)c1]

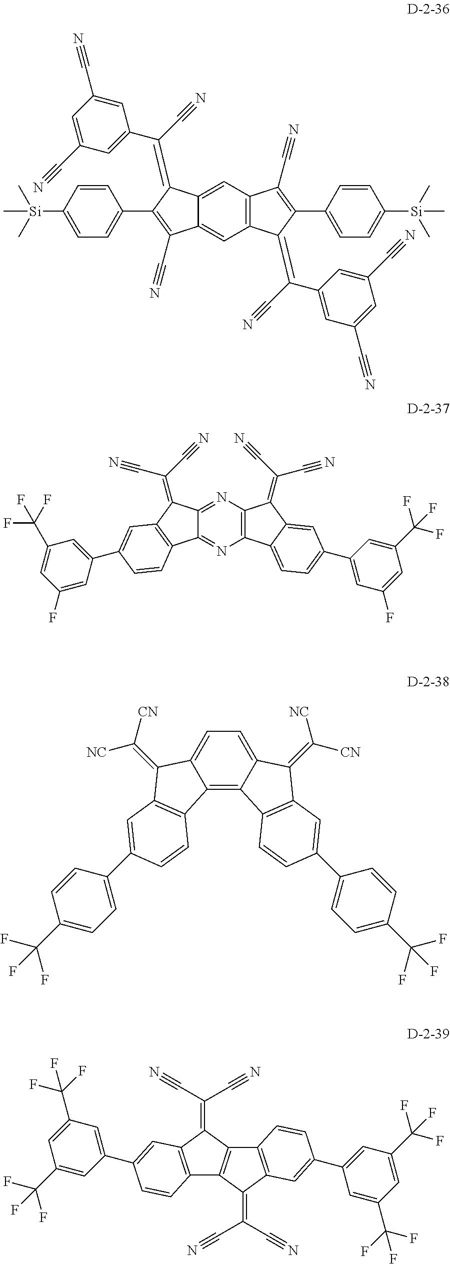

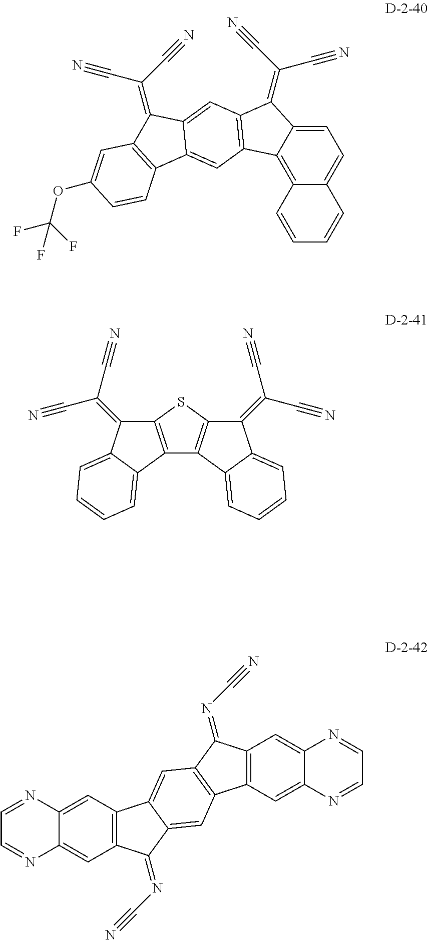 [SMILES: N#CC(C#N)=C1c2cc(OC(F)(F)F)ccc2-c2cc3c(cc21)C(=C(C#N)C#N)c1ccc2ccccc2c1-3 ; N#CC(C#N)=C1c2ccccc2-c2c1sc1c2-c2ccccc2C1=C(C#N)C#N ; N#C/N=c1\c2cc3nccnc3cc2c2cc3/c(=N/C#N)c4cc5nccnc5cc4c3cc12]

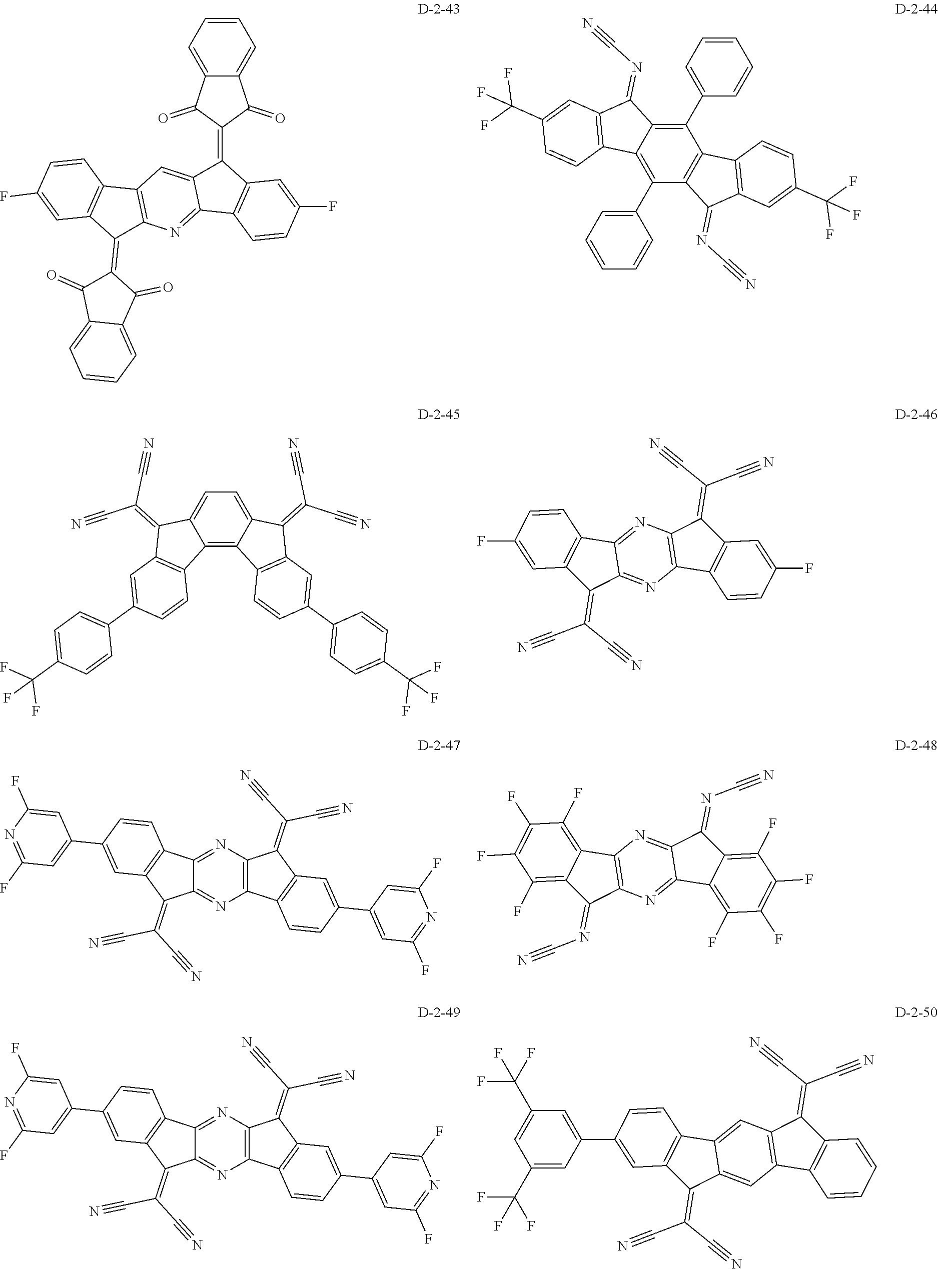

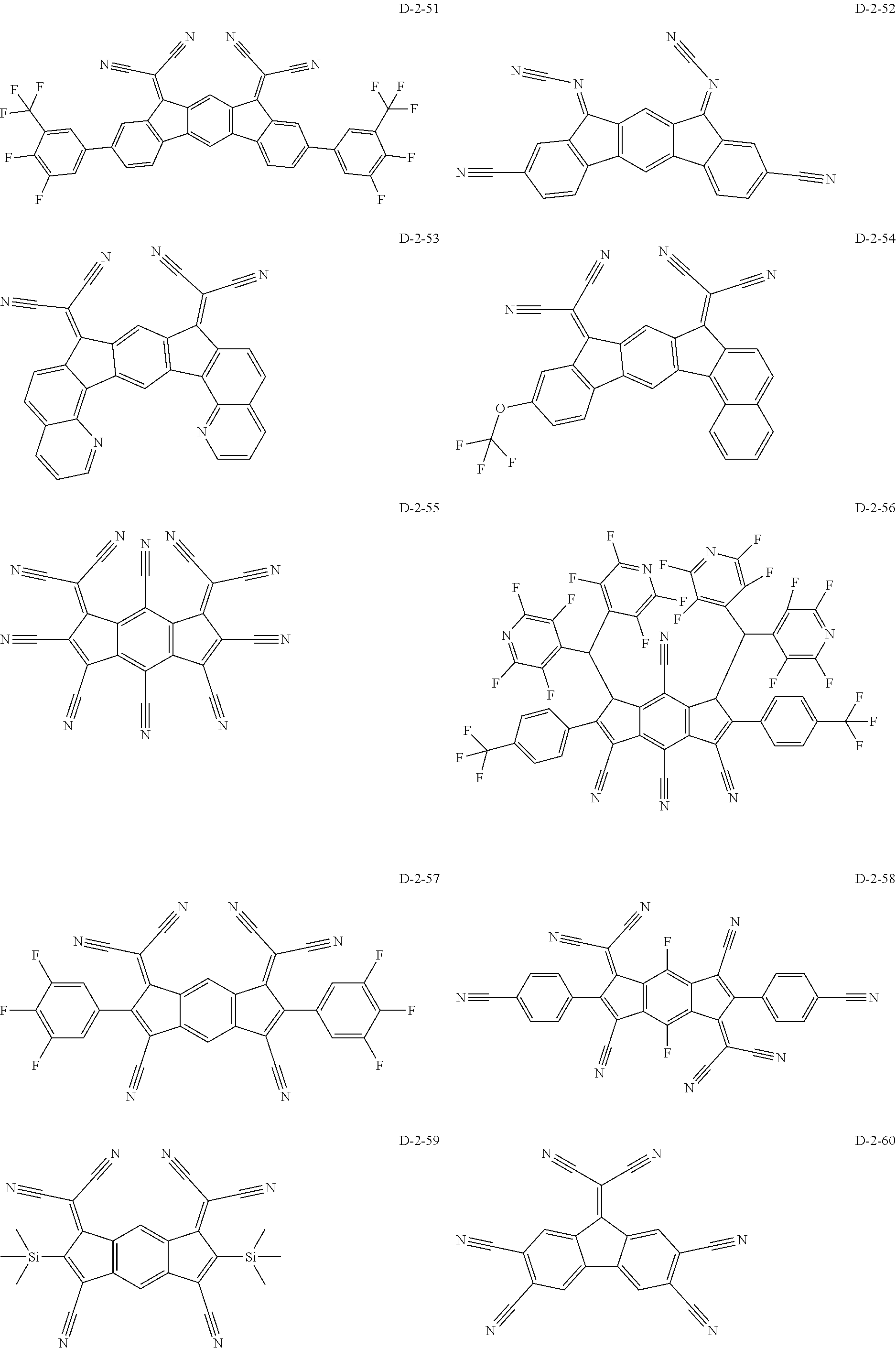

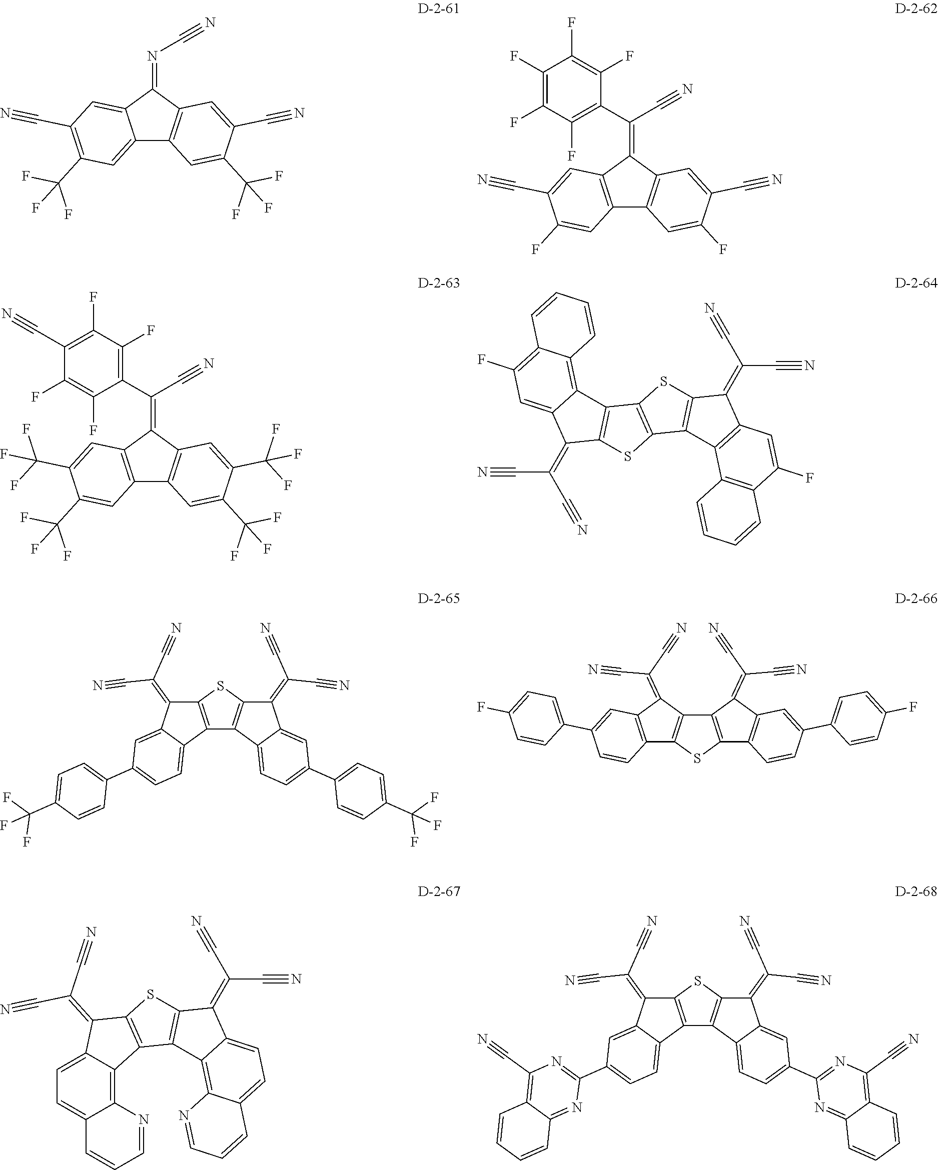

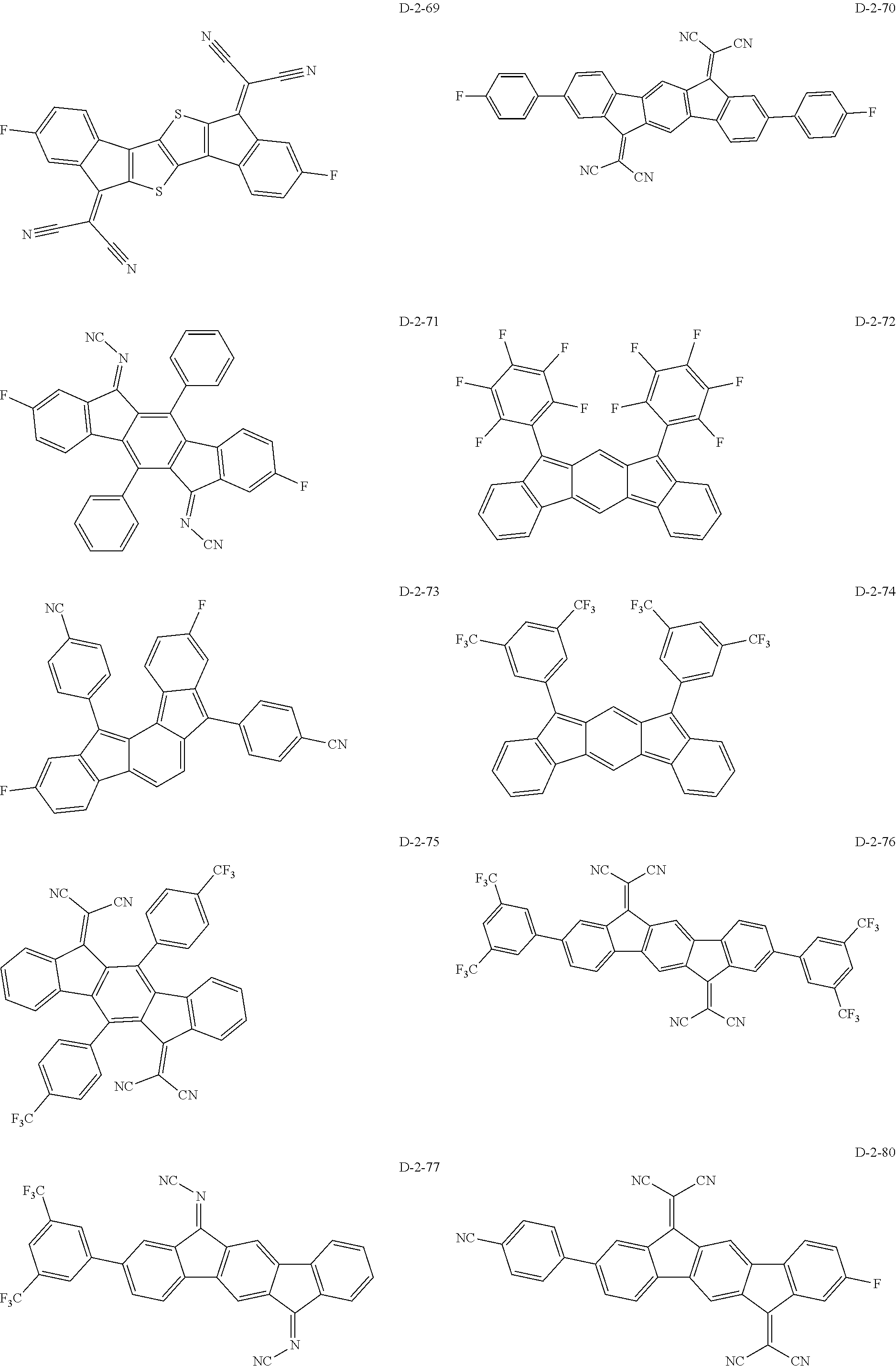

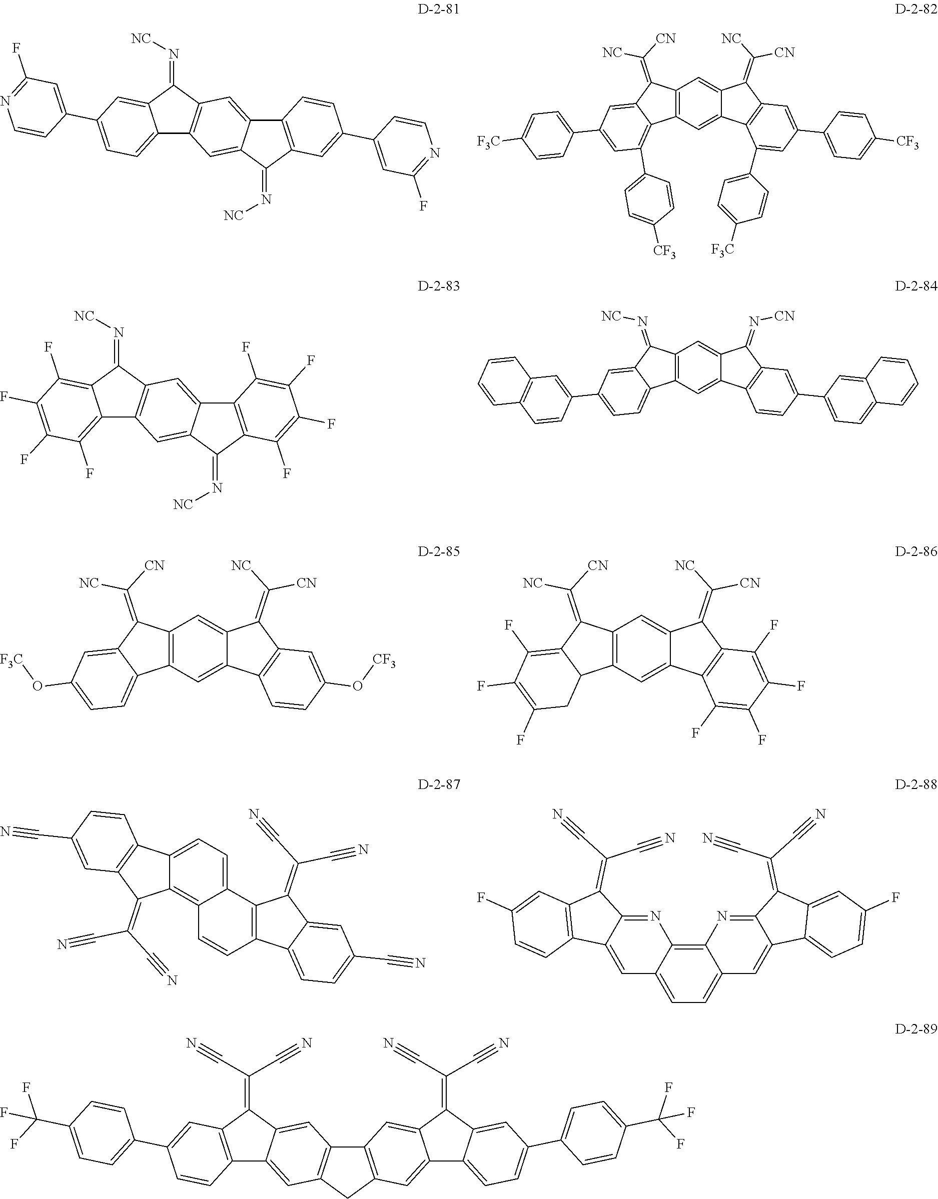

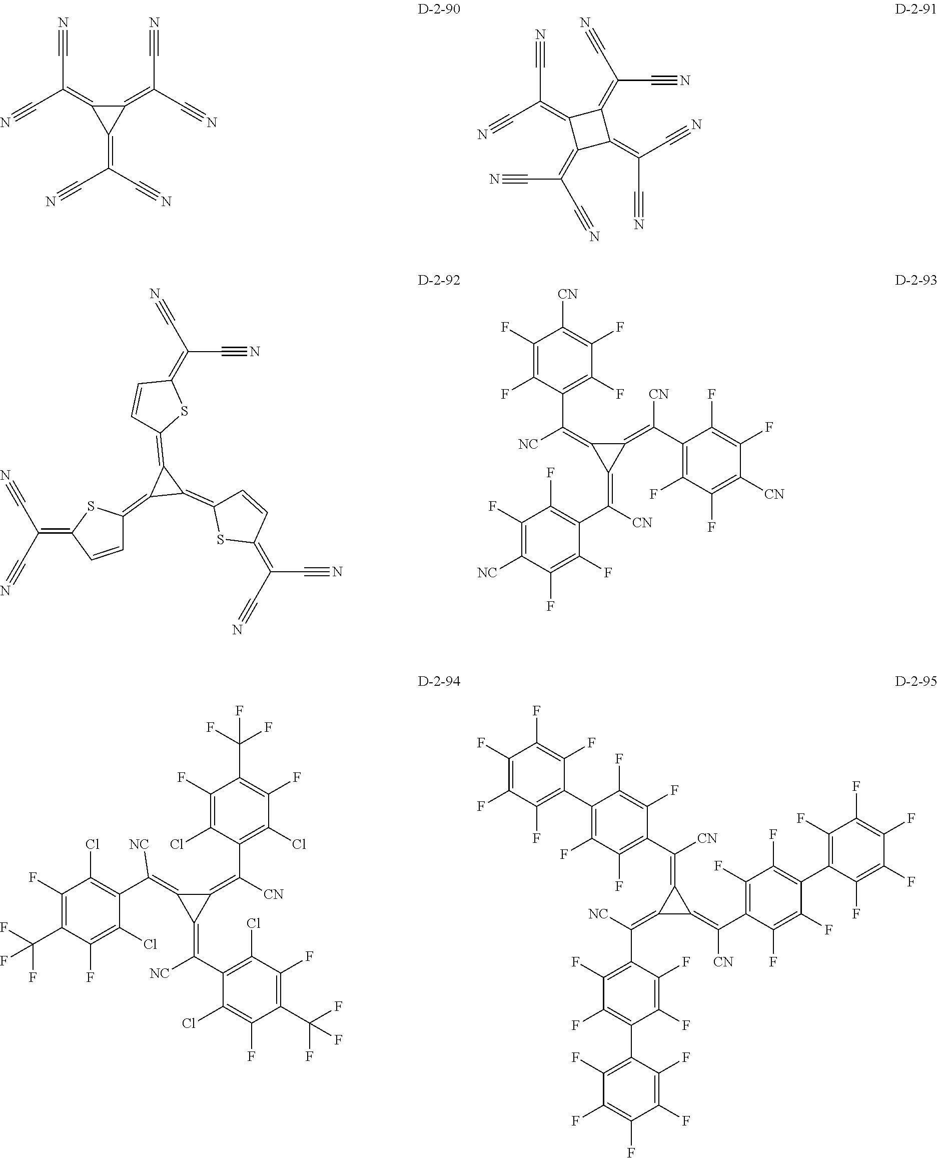

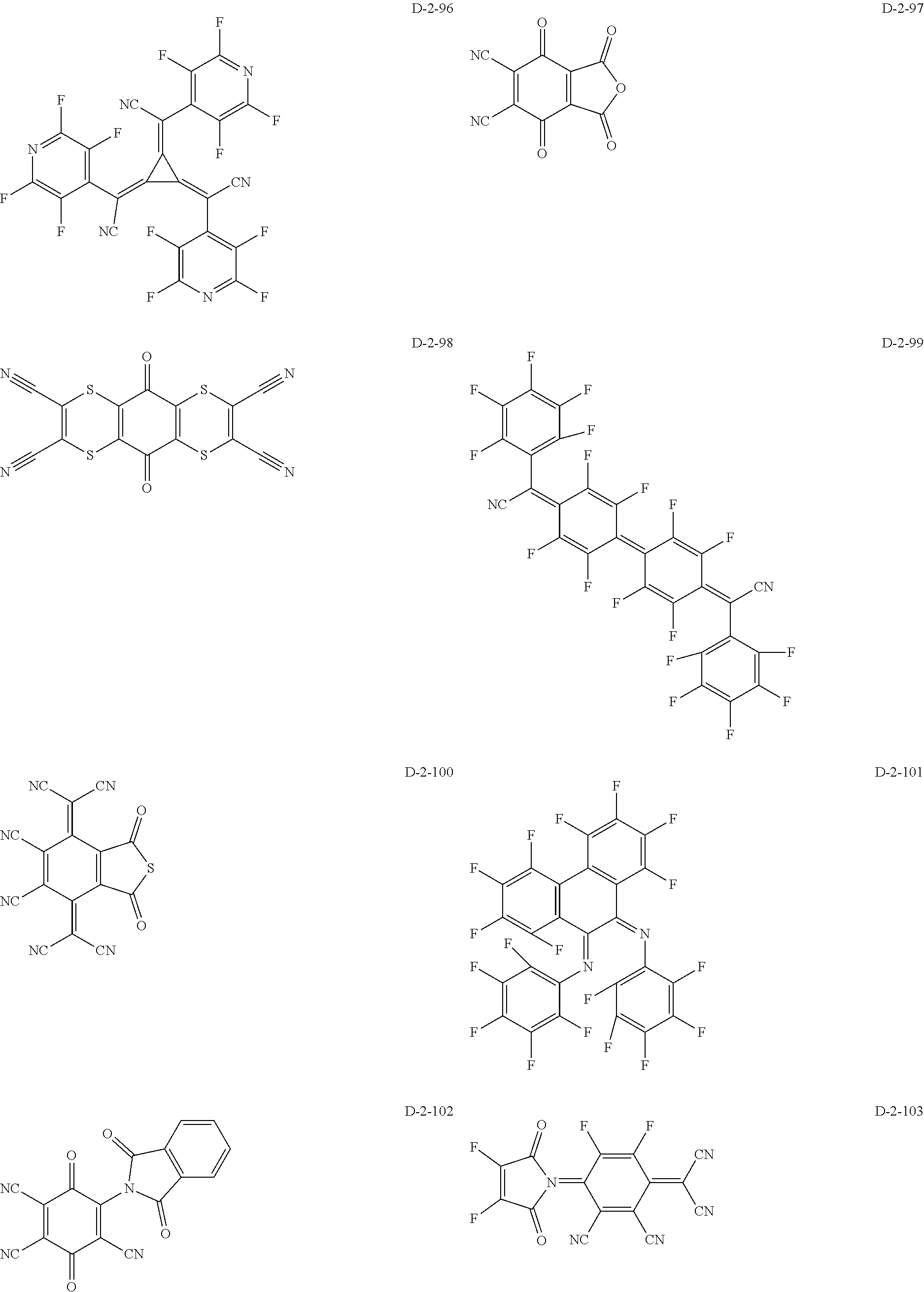

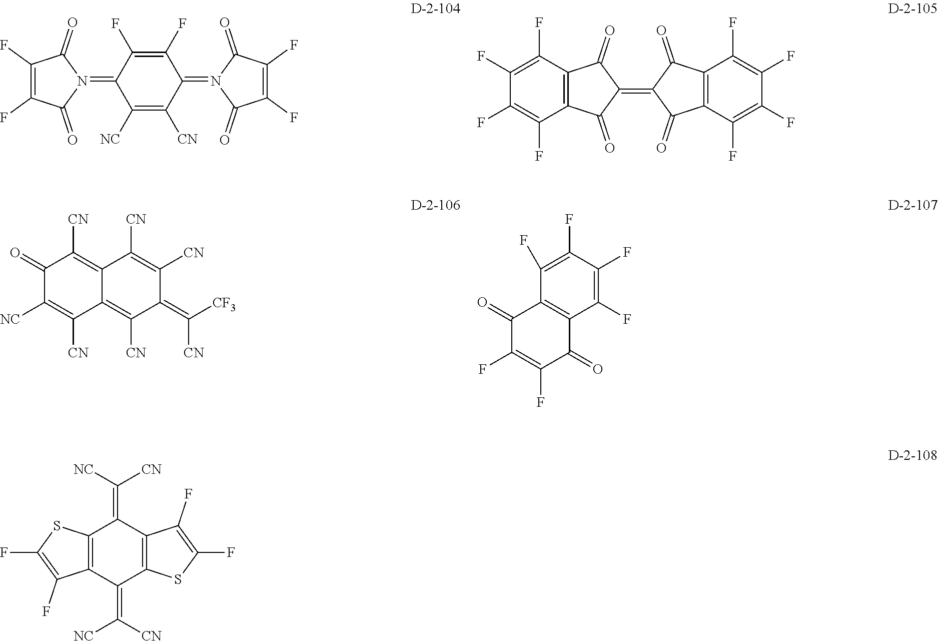

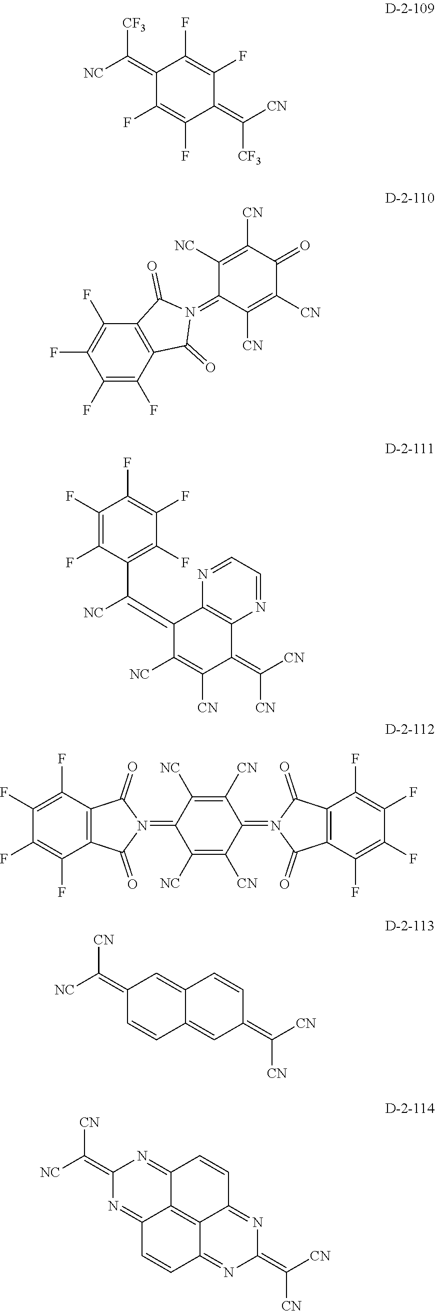

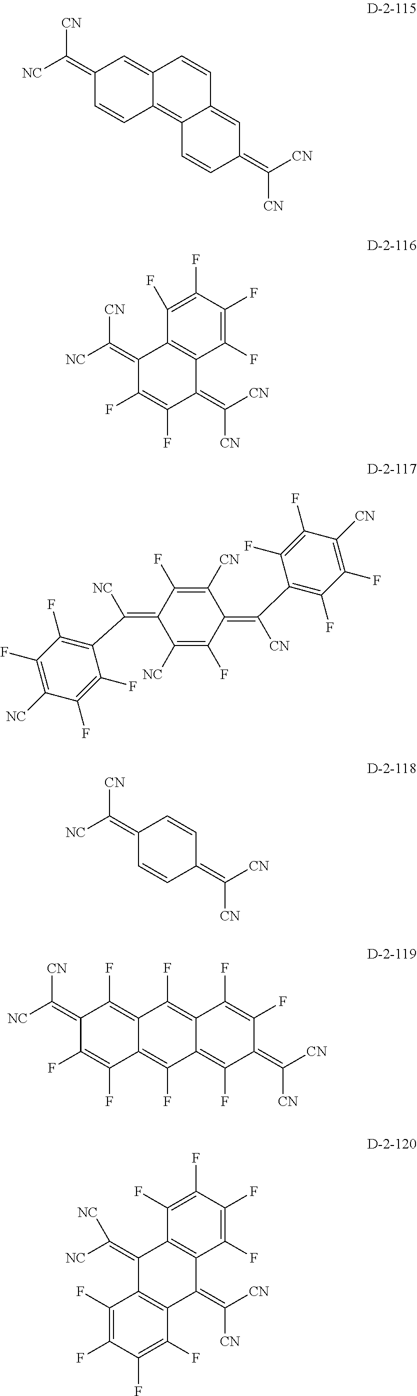 [SMILES: N#CC(C#N)=c1ccc2c(ccc3cc(=C(C#N)C#N)ccc32)c1 ; N#CC(C#N)=c1c(F)c(F)c(=C(C#N)C#N)c2c(F)c(F)c(F)c(F)c12 ; N#C/C(c1c(F)c(F)c(C#N)c(F)c1F)=c1\c(F)c(C#N)/c(=C(/C#N)c2c(F)c(F)c(C#N)c(F)c2F)c(F)c1C#N ; N#CC(C#N)=c1ccc(=C(C#N)C#N)cc1 ; N#CC(C#N)=c1c(F)c(F)c2c(F)c3c(F)c(=C(C#N)C#N)c(F)c(F)c3c(F)c2c1F ; N#CC(C#N)=c1c2c(F)c(F)c(F)c(F)c2c(=C(C#N)C#N)c2c(F)c(F)c(F)c(F)c12]

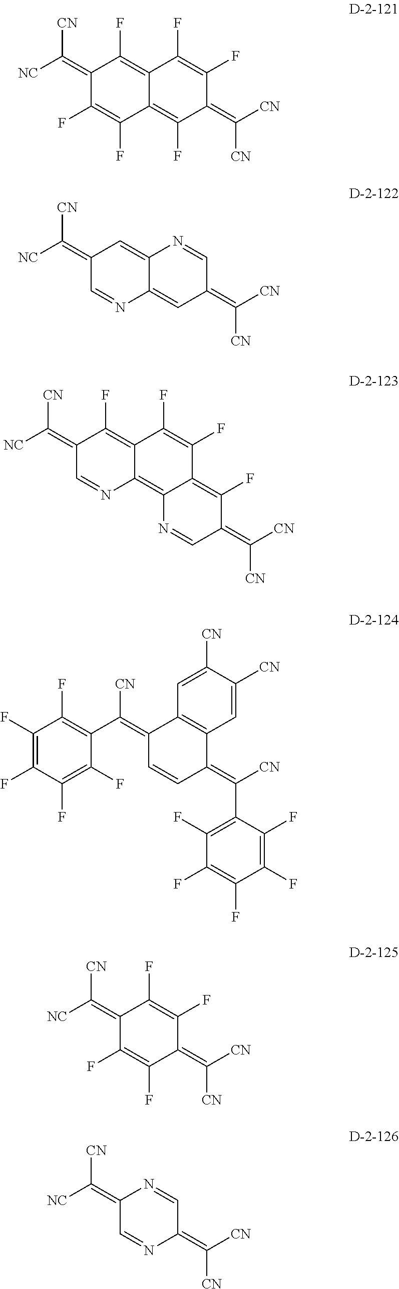 [SMILES: N#CC(C#N)=c1c(F)c(F)c2c(F)c(=C(C#N)C#N)c(F)c(F)c2c1F ; N#CC(C#N)=c1cnc2cc(=C(C#N)C#N)cnc2c1 ; N#CC(C#N)=c1cnc2c(c(F)c(F)c3c(F)c(=C(C#N)C#N)cnc32)c1F ; N#C/C(c1c(F)c(F)c(F)c(F)c1F)=c1/cc/c(=C(/C#N)c2c(F)c(F)c(F)c(F)c2F)c2cc(C#N)c(C#N)cc12 ; N#CC(C#N)=c1c(F)c(F)c(=C(C#N)C#N)c(F)c1F ; N#CC(C#N)=c1cnc(=C(C#N)C#N)cn1]

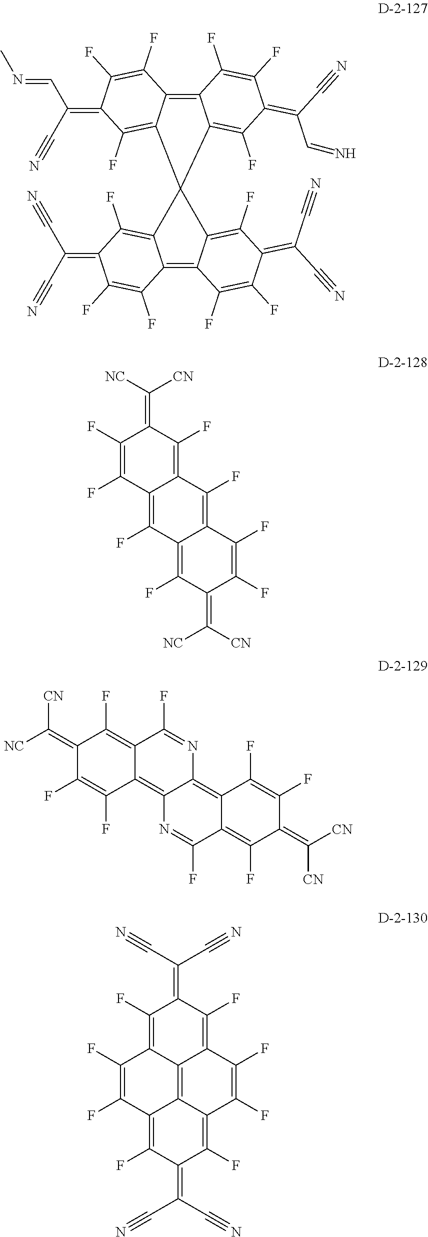 [SMILES: C/N=C/C(C#N)=c1\c(F)c(F)c2c(c1F)C1(c3c(F)c(=C(C#N)C#N)c(F)c(F)c3=c3c(F)c(F)c(=C(C#N)C#N)c(F)c31)c1c(F)/c(=C(/C#N)C=N)c(F)c(F)c1=2 ; N#CC(C#N)=c1c(F)c(F)c2c(F)c3c(F)c(=C(C#N)C#N)c(F)c(F)c3c(F)c2c1F ; N#CC(C#N)=c1c(F)c(F)c2c(c(F)nc3c2nc(F)c2c(F)c(=C(C#N)C#N)c(F)c(F)c23)c1F ; N#CC(C#N)=c1c(F)c2c(F)c(F)c3c(F)c(=C(C#N)C#N)c(F)c4c(F)c(F)c(c1F)c2c34]

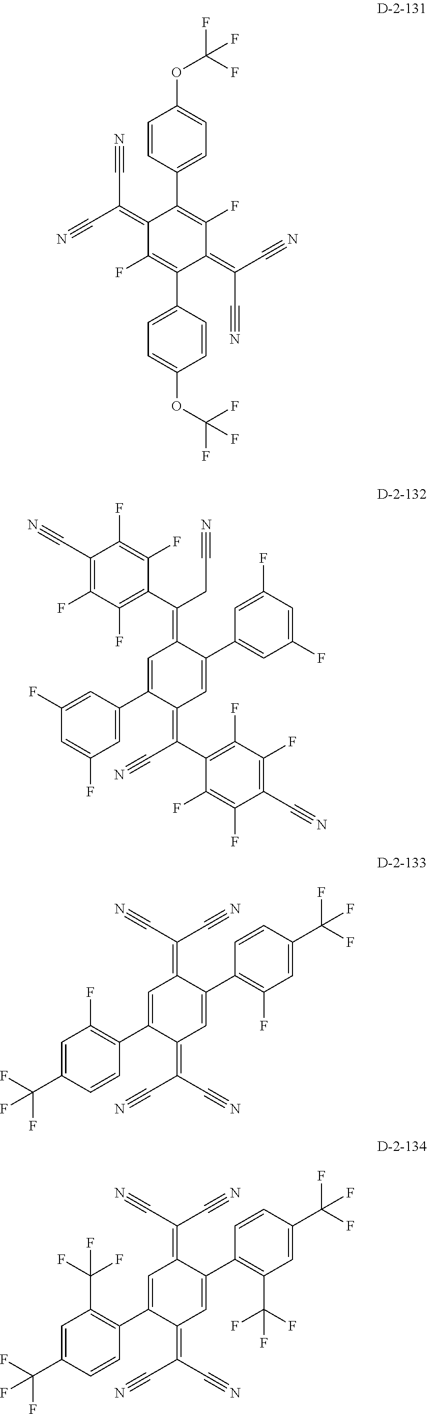 [SMILES: N#CC(C#N)=c1c(F)c(-c2ccc(OC(F)(F)F)cc2)c(=C(C#N)C#N)c(F)c1-c1ccc(OC(F)(F)F)cc1 ; N#CC/C(c1c(F)c(F)c(C#N)c(F)c1F)=c1/cc(-c2cc(F)cc(F)c2)/c(=C(\C#N)c2c(F)c(F)c(C#N)c(F)c2F)cc1-c1cc(F)cc(F)c1 ; N#CC(C#N)=c1cc(-c2ccc(C(F)(F)F)cc2F)c(=C(C#N)C#N)cc1-c1ccc(C(F)(F)F)cc1F ; N#CC(C#N)=c1cc(-c2ccc(C(F)(F)F)cc2C(F)(F)F)c(=C(C#N)C#N)cc1-c1ccc(C(F)(F)F)cc1C(F)(F)F]

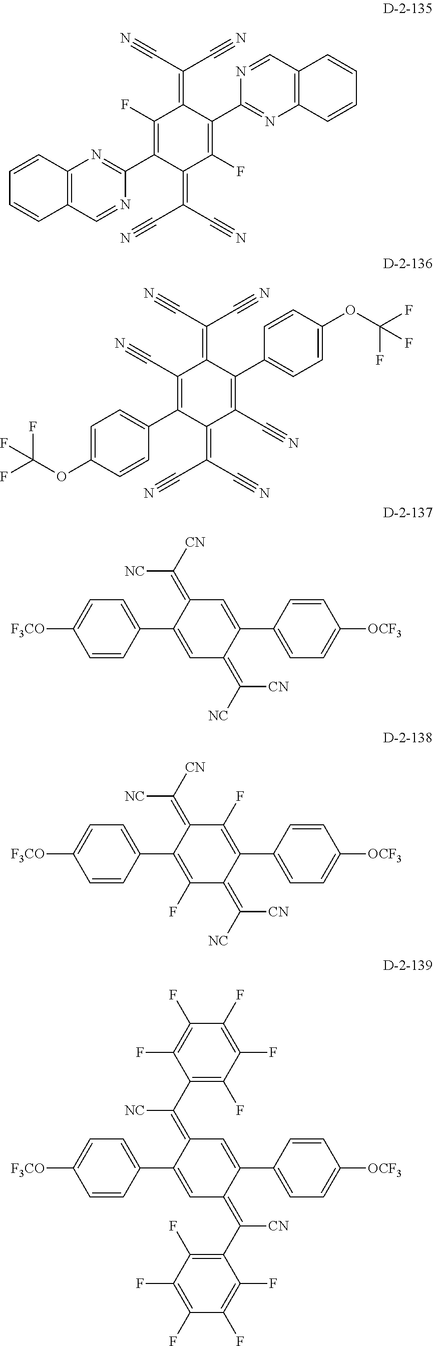 [SMILES: N#CC(C#N)=c1c(F)c(-c2ncc3ccccc3n2)c(=C(C#N)C#N)c(F)c1-c1ncc2ccccc2n1 ; N#CC(C#N)=c1c(C#N)c(-c2ccc(OC(F)(F)F)cc2)c(=C(C#N)C#N)c(C#N)c1-c1ccc(OC(F)(F)F)cc1 ; N#CC(C#N)=c1cc(-c2ccc(OC(F)(F)F)cc2)c(=C(C#N)C#N)cc1-c1ccc(OC(F)(F)F)cc1 ; N#CC(C#N)=c1c(F)c(-c2ccc(OC(F)(F)F)cc2)c(=C(C#N)C#N)c(F)c1-c1ccc(OC(F)(F)F)cc1 ; N#C/C(c1c(F)c(F)c(F)c(F)c1F)=c1/cc(-c2ccc(OC(F)(F)F)cc2)/c(=C(\C#N)c2c(F)c(F)c(F)c(F)c2F)cc1-c1ccc(OC(F)(F)F)cc1]

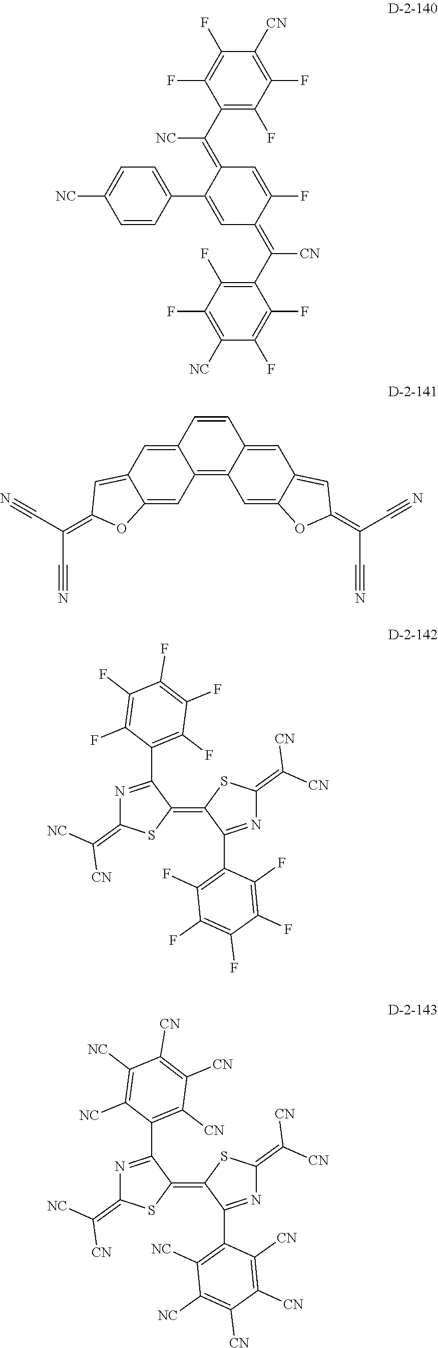 [SMILES: N#C/C(c1c(F)c(F)c(C#N)c(F)c1F)=c1/cc(-c2ccc(C#N)cc2)/c(=C(\C#N)c2c(F)c(F)c(C#N)c(F)c2F)cc1F ; N#CC(C#N)=c1cc2cc3ccc4cc5cc(=C(C#N)C#N)oc5cc4c3cc2o1 ; N#CC(C#N)=c1nc(-c2c(F)c(F)c(F)c(F)c2F)/c(=c2\sc(=C(C#N)C#N)nc2-c2c(F)c(F)c(F)c(F)c2F)s1 ; N#CC(C#N)=c1nc(-c2c(C#N)c(C#N)c(C#N)c(C#N)c2C#N)/c(=c2\sc(=C(C#N)C#N)nc2-c2c(C#N)c(C#N)c(C#N)c(C#N)c2C#N)s1]

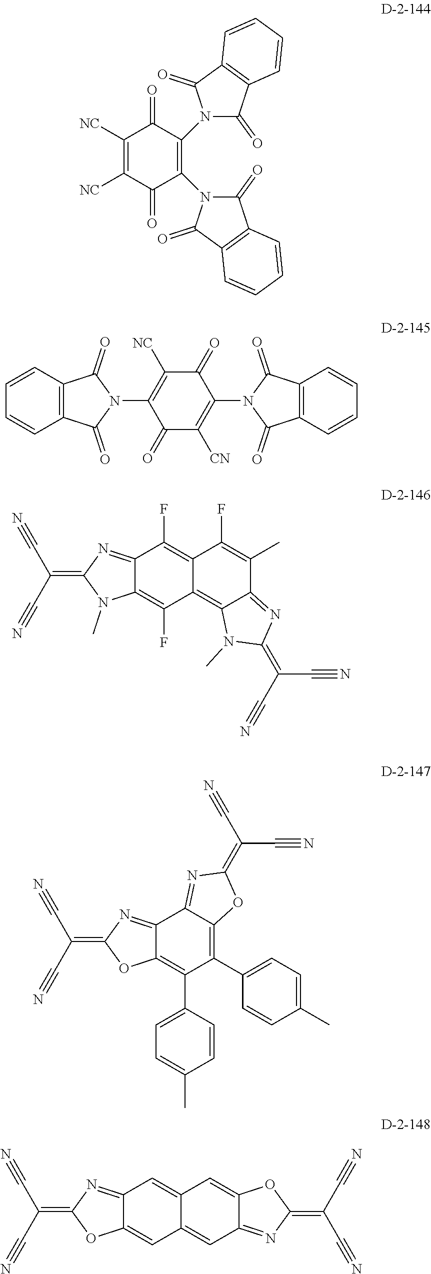 [SMILES: N#CC1=C(C#N)C(=O)C(N2C(=O)c3ccccc3C2=O)=C(N2C(=O)c3ccccc3C2=O)C1=O ; N#CC1=C(N2C(=O)c3ccccc3C2=O)C(=O)C(C#N)=C(N2C(=O)c3ccccc3C2=O)C1=O ; Cc1c(F)c2c(F)c3nc(=C(C#N)C#N)n(C)c3c(F)c2c2c1nc(=C(C#N)C#N)n2C ; Cc1ccc(-c2c(-c3ccc(C)cc3)c3oc(=C(C#N)C#N)nc3c3nc(=C(C#N)C#N)oc23)cc1 ; N#CC(C#N)=c1nc2cc3cc4oc(=C(C#N)C#N)nc4cc3cc2o1]

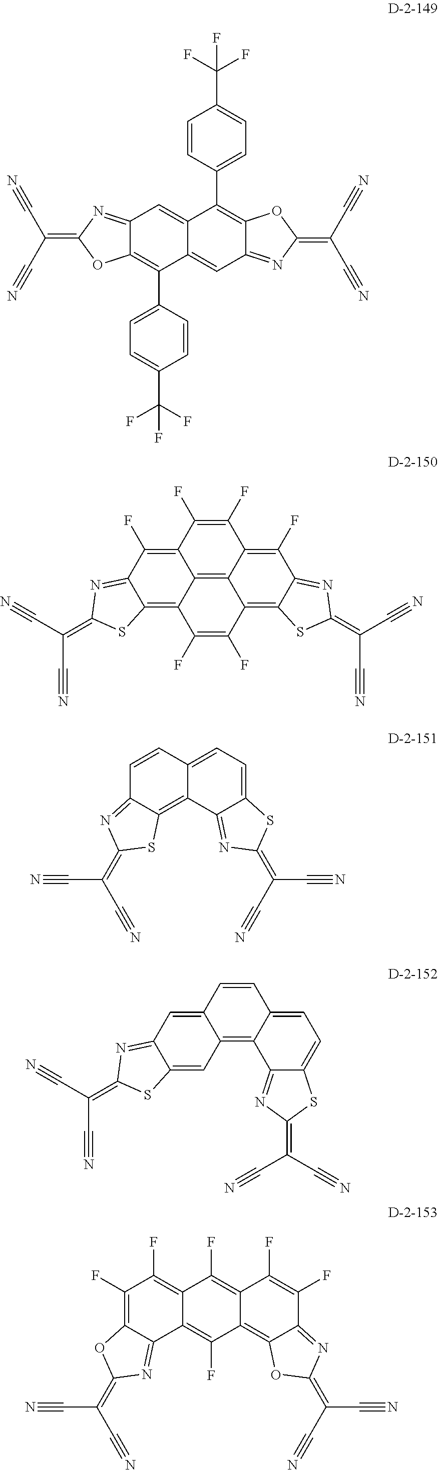 [SMILES: N#CC(C#N)=c1nc2cc3c(-c4ccc(C(F)(F)F)cc4)c4oc(=C(C#N)C#N)nc4cc3c(-c3ccc(C(F)(F)F)cc3)c2o1 ; N#CC(C#N)=c1nc2c(F)c3c(F)c(F)c4c(F)c5nc(=C(C#N)C#N)sc5c5c(F)c(F)c(c2s1)c3c45 ; N#CC(C#N)=c1nc2c(ccc3ccc4nc(=C(C#N)C#N)sc4c32)s1 ; N#CC(C#N)=c1nc2cc3ccc4ccc5sc(=C(C#N)C#N)nc5c4c3cc2s1 ; N#CC(C#N)=c1nc2c(o1)c(F)c(F)c1c(F)c3c(F)c(F)c4nc(=C(C#N)C#N)oc4c3c(F)c12]

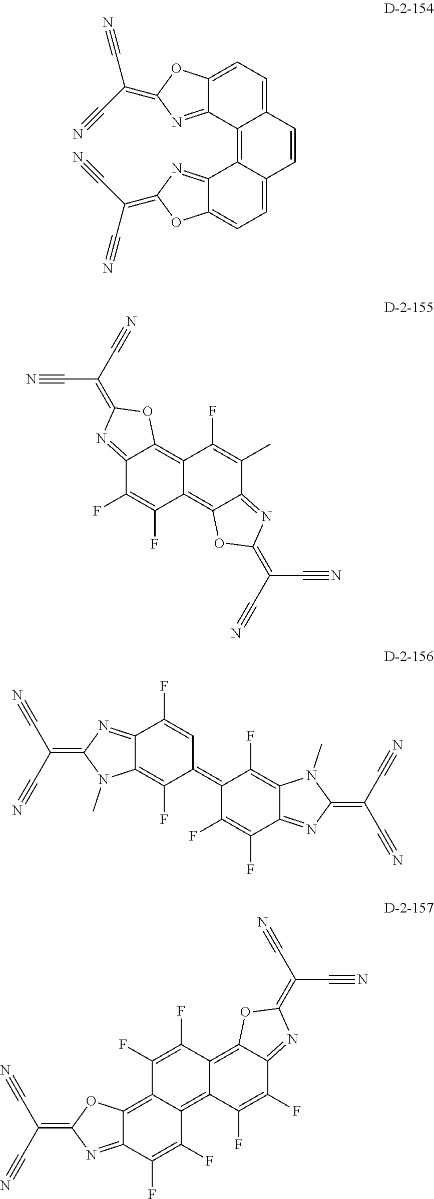 [SMILES: N#CC(C#N)=c1nc2c(ccc3ccc4ccc5oc(=C(C#N)C#N)nc5c4c32)o1 ; Cc1c(F)c2c3oc(=C(C#N)C#N)nc3c(F)c(F)c2c2oc(=C(C#N)C#N)nc12 ; Cn1c(=C(C#N)C#N)nc2c(F)c/c(=c3/c(F)c(F)c4nc(=C(C#N)C#N)n(C)c4c3F)c(F)c21 ; N#CC(C#N)=c1nc2c(F)c(F)c3c(c(F)c(F)c4c5oc(=C(C#N)C#N)nc5c(F)c(F)c43)c2o1]

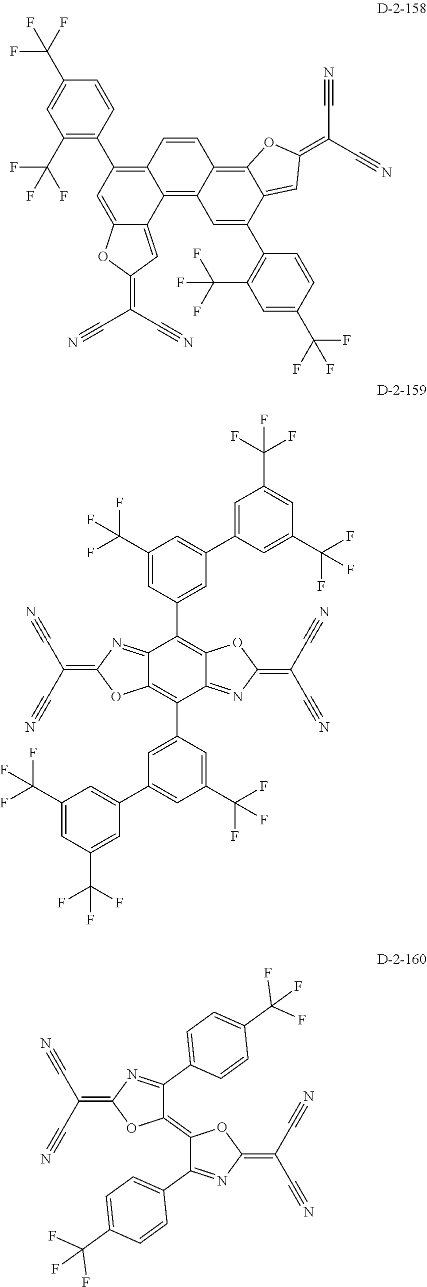 [SMILES: N#CC(C#N)=c1cc2c(cc(-c3ccc(C(F)(F)F)cc3C(F)(F)F)c3ccc4c(cc(-c5ccc(C(F)(F)F)cc5C(F)(F)F)c5cc(=C(C#N)C#N)oc54)c32)o1 ; N#CC(C#N)=c1nc2c(-c3cc(-c4cc(C(F)(F)F)cc(C(F)(F)F)c4)cc(C(F)(F)F)c3)c3oc(=C(C#N)C#N)nc3c(-c3cc(-c4cc(C(F)(F)F)cc(C(F)(F)F)c4)cc(C(F)(F)F)c3)c2o1 ; N#CC(C#N)=c1nc(-c2ccc(C(F)(F)F)cc2)/c(=c2\oc(=C(C#N)C#N)nc2-c2ccc(C(F)(F)F)cc2)o1]

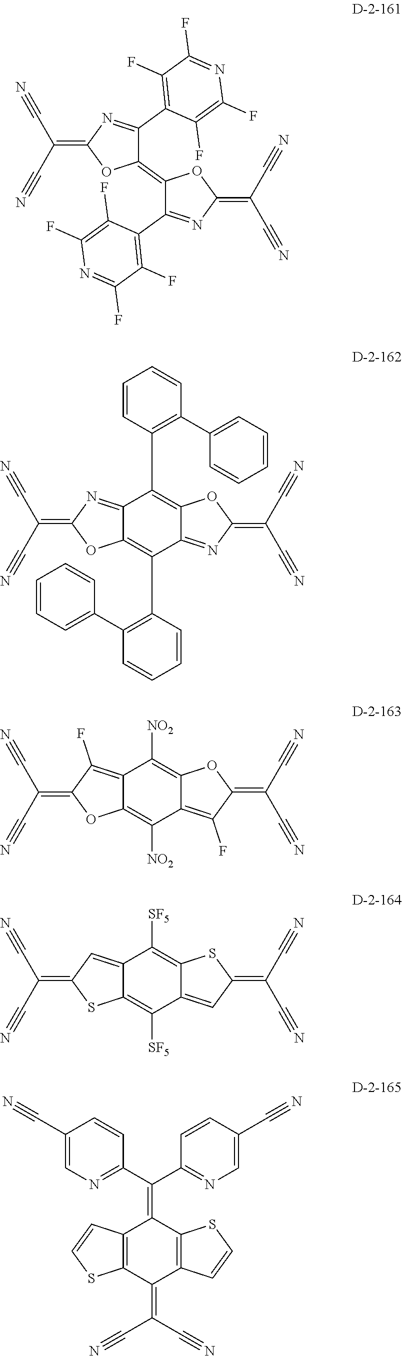

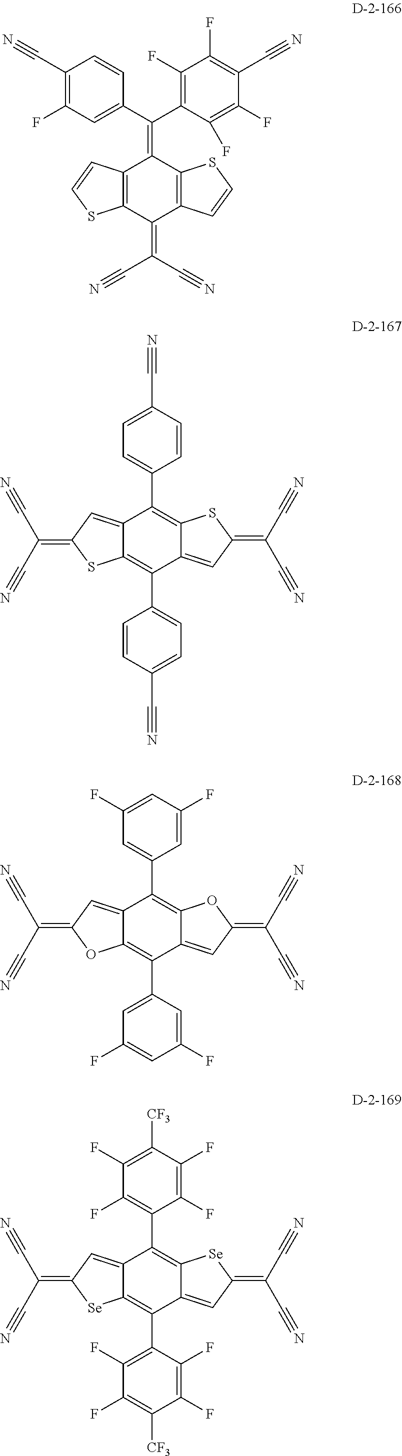 [SMILES: N#CC(C#N)=c1c2ccsc2/c(=C(/c2ccc(C#N)c(F)c2)c2c(F)c(F)c(C#N)c(F)c2F)c2ccsc12 ; N#CC(C#N)=c1cc2c(-c3ccc(C#N)cc3)c3sc(=C(C#N)C#N)cc3c(-c3ccc(C#N)cc3)c2s1 ; N#CC(C#N)=c1cc2c(-c3cc(F)cc(F)c3)c3oc(=C(C#N)C#N)cc3c(-c3cc(F)cc(F)c3)c2o1 ; N#CC(C#N)=c1cc2c(-c3c(F)c(F)c(C(F)(F)F)c(F)c3F)c3[se]c(=C(C#N)C#N)cc3c(-c3c(F)c(F)c(C(F)(F)F)c(F)c3F)c2[se]1]

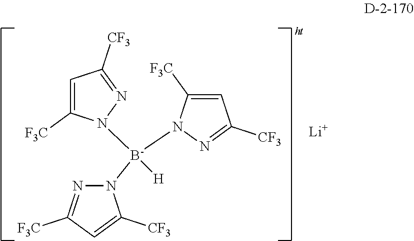

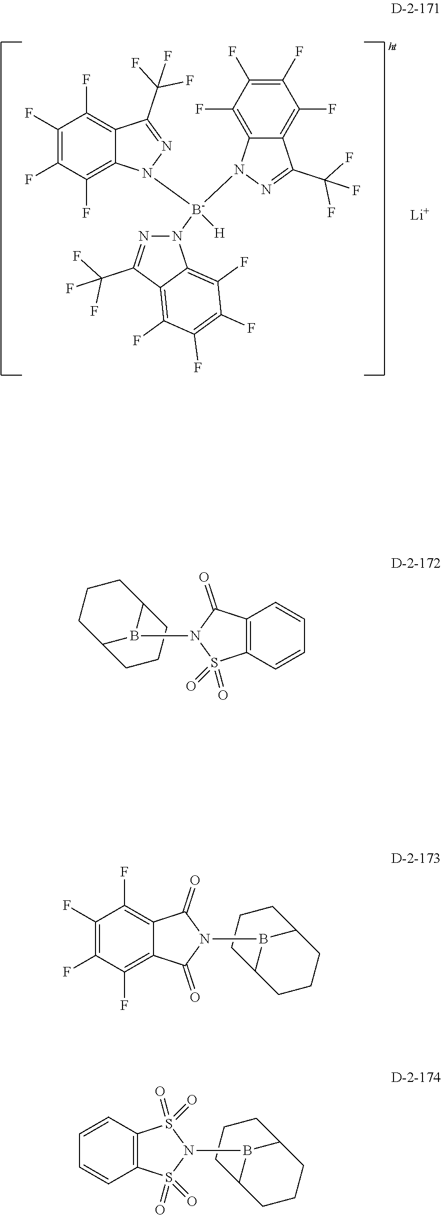

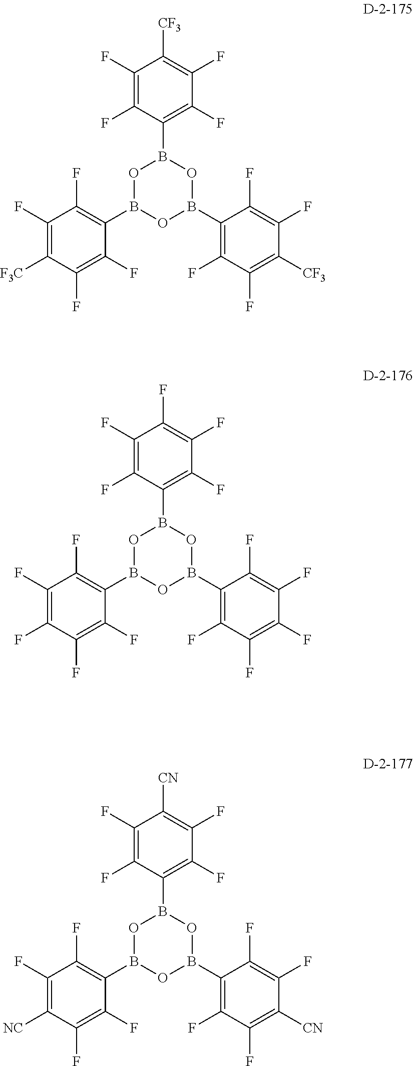 [SMILES: Fc1c(F)c(C(F)(F)F)c(F)c(F)c1B1OB(c2c(F)c(F)c(C(F)(F)F)c(F)c2F)OB(c2c(F)c(F)c(C(F)(F)F)c(F)c2F)O1 ; Fc1c(F)c(F)c(B2OB(c3c(F)c(F)c(F)c(F)c3F)OB(c3c(F)c(F)c(F)c(F)c3F)O2)c(F)c1F ; N#Cc1c(F)c(F)c(B2OB(c3c(F)c(F)c(C#N)c(F)c3F)OB(c3c(F)c(F)c(C#N)c(F)c3F)O2)c(F)c1F]

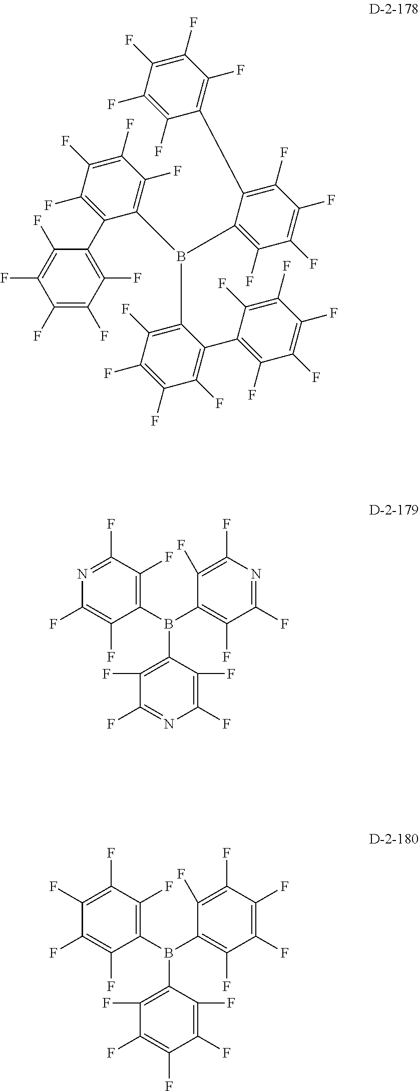 [SMILES: Fc1c(F)c(F)c(-c2c(F)c(F)c(F)c(F)c2B(c2c(F)c(F)c(F)c(F)c2-c2c(F)c(F)c(F)c(F)c2F)c2c(F)c(F)c(F)c(F)c2-c2c(F)c(F)c(F)c(F)c2F)c(F)c1F ; Fc1nc(F)c(F)c(B(c2c(F)c(F)nc(F)c2F)c2c(F)c(F)nc(F)c2F)c1F ; Fc1c(F)c(F)c(B(c2c(F)c(F)c(F)c(F)c2F)c2c(F)c(F)c(F)c(F)c2F)c(F)c1F]

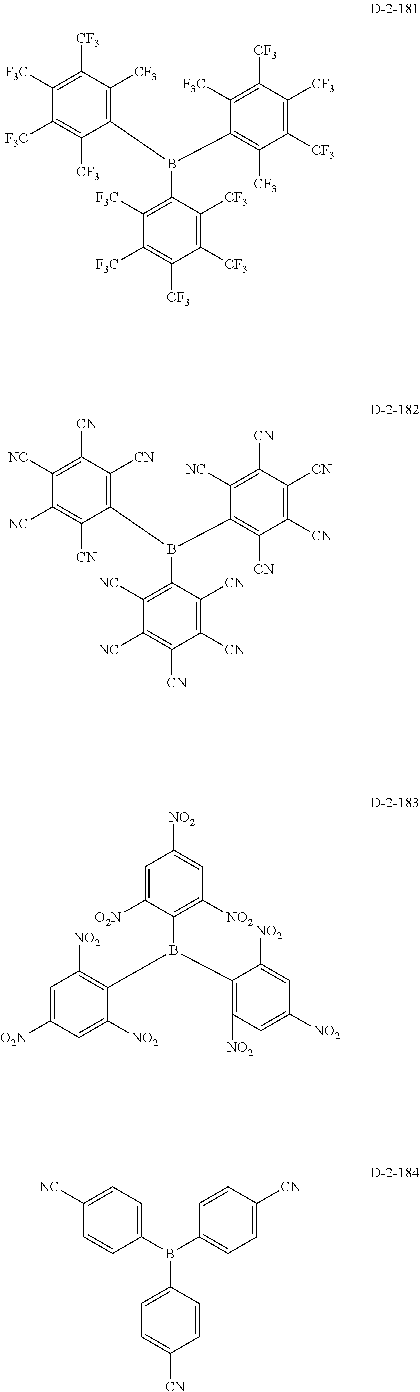 [SMILES: FC(F)(F)c1c(B(c2c(C(F)(F)F)c(C(F)(F)F)c(C(F)(F)F)c(C(F)(F)F)c2C(F)(F)F)c2c(C(F)(F)F)c(C(F)(F)F)c(C(F)(F)F)c(C(F)(F)F)c2C(F)(F)F)c(C(F)(F)F)c(C(F)(F)F)c(C(F)(F)F)c1C(F)(F)F ; N#Cc1c(C#N)c(C#N)c(B(c2c(C#N)c(C#N)c(C#N)c(C#N)c2C#N)c2c(C#N)c(C#N)c(C#N)c(C#N)c2C#N)c(C#N)c1C#N ; O=[N+]([O-])c1cc([N+](=O)[O-])c(B(c2c([N+](=O)[O-])cc([N+](=O)[O-])cc2[N+](=O)[O-])c2c([N+](=O)[O-])cc([N+](=O)[O-])cc2[N+](=O)[O-])c([N+](=O)[O-])c1 ; N#Cc1ccc(B(c2ccc(C#N)cc2)c2ccc(C#N)cc2)cc1]

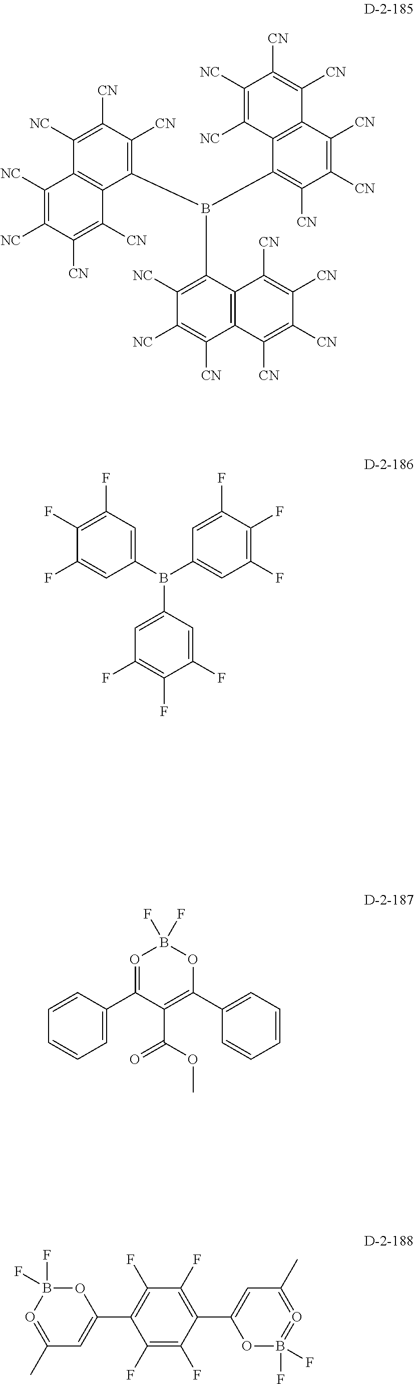

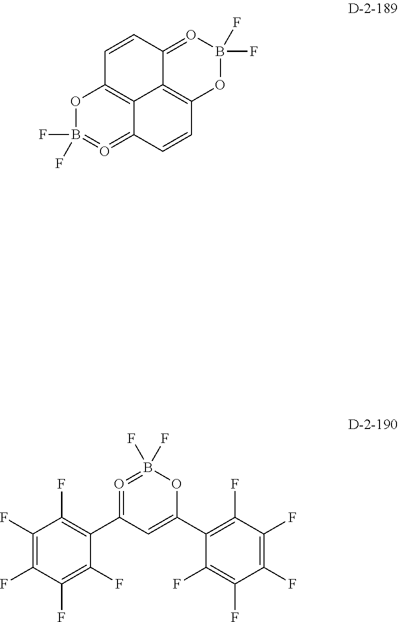

In the layer A which is preferably a layer A1, the ratio of compound C1 to compound C2 is preferably between 99:1 and 1:99, more preferably between 90:10 and 10:90, most preferably between 80:20 and 20:80, and with highest preference between 35:65 and 65:35. The ratio is determined by volume, in volume percent, in the case that the compounds are applied from vapor using different evaporation sources. The ratio is determined by weight, in weight percent, if the compounds are applied, or if they are applied from solution. Preferably, the compounds are applied as a premixture from vapor, and the ratio is determined by volume.

Preferably, the compound C2 is present in the layer A which is preferably a layer A1 in a proportion of at least 30%, preferably in a proportion of at least 40%, most preferably in a proportion of at least 50%. Regarding determination of proportions, the same as above applies.

In such embodiment, the layer A is a layer A1, which is a hole-injection layer, and which is adjacent to the anode. In such case, it is further preferred that there is a hole transport layer adjacent to the layer A1 on its cathode side, and there is an electron blocking layer between the hole transport layer and the emitting layer, which is adjacent to the emitting layer on the anode side of the emitting layer. There can be further layers present between the hole transport layer and the electron blocking layer. Preferably, there are no layers between the hole transport layer and the electron blocking layer, so that they are adjacent to each other. Further, preferably, there is a hole blocking layer adjacent to the emitting layer on the cathode side of the emitting layer. Further, preferably, there is an electron transport layer to the cathode side of the hole blocking layer. Further, preferably, there is an electron injection layer adjacent to the electron transport layer, on the cathode side of the electron transport layer, and the electron injection layer is preferably adjacent to the cathode. There can optionally be further layers between the hole blocking layer and the electron transport layer. Preferably, the hole blocking layer and the electron transport layer are adjacent to each other.

The sequence of layers in the stack of layers of the electronic device is preferably as follows, in the below sequence, from the anode to the cathode:
anode
layer A, as a hole injection layer
hole transporting layer
optionally further hole transport layer(s)
electron blocking layer
emitting layer
hole blocking layer
electron transport layer
optional further electron transport layer(s)
electron injection layer
cathode.

A pixel defining layer (PDL) is preferably applied in the electronic device comprising a plurality of stacks of layers, after application of the anode, preferably by a lithographic method.

Further layers may be present in the stack, selected from the known layers for use in OLEDs, which are hole blocking layers, electron transport layers, electron injection layers, electron blocking layers, exciton blocking layers, interlayers, charge generation layers, outcoupling layers, emitting layers, pixel defining layers, and/or organic or inorganic p/n junctions.

Such sequence of layers is particularly preferred for the stack of layers which is a blue fluorescent stack of layers. It is particularly preferred for the stack of layers which has the highest onset voltage.

The layer sequence of the stacks of layers of the electronic device can be the same or different between the different stacks of layer, preferably it is different. Preferably, the layers which are described as common layers are present in all stacks of layers.

According to a preferred embodiment, the stacks of layers of the electronic device each comprise two further layers between the the layer A1 and the light-emitting layer, which are adjacent to each other and which are, in that order, from the anode-nearest to the anode-farthest:
a hole-transporting layer, and
an electron-blocking layer.

According to a preferred embodiment, the hole transporting layer comprises the compound C1, more preferably it consists of the compound C1. Preferably, the compound C1 of the layer A1 and the compound of the hole transporting layer are identical. In this case, it is preferred if the compound C1 present in the hole transporting layer has a high hole mobility. According to a further preferred embodiment, the hole transporting layer comprises only a single compound. According to a further preferred embodiment, the hole transporting layer is not p-doped. Further, it is preferred that the hole transporting layer is shared by the two stacks of layers.

It is understood that the hole transporting layer itself can have either a high or a low lateral current. Generally, it is preferred that the hole transporting layer has a low lateral current. The technical effect of the present invention is achieved regardless of whether the hole transporting layer alone has a high or a low lateral current. However, the absolute value of the lateral current exhibited by the device is generally lower if the hole transporting layer has a low lateral current, which is why it is generally preferable to select a material for the hole transporting layer which has a low lateral current, if obtaining the lowest possible lateral current is of high priority in designing the device.

For the anode of the stacks of layers of the electronic device, materials having a high work function are preferred. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable the emission of light. Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

Preferred cathodes of of the stacks of layers of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

The emitting layer of the stacks of layers of the electronic device may be a phosphorescent emitting layer, or it may be a fluorescent emitting layer. A phosphorescent emitting layer preferably contains at least one matrix material, more preferably two matrix materials, and at least one phosphorescent emitter. A fluorescent emitting layer preferably contains at least one matrix material and at least one fluorescent emitter.

In a preferred embodiment of the invention, the emitting layer of the stacks of layers of the electronic device are selected from a blue-fluorescing emitting layer, a green-phosphorescing layer and a red-phosphorescing layer. Correspondingly, the emitting layer of the electronic device in the first case contains a blue-fluorescing emitter compound, and in the second case contains a green-phosphorescing emitter compound, and in the third case contains a red-phosphorescing emitter compound. It is preferred that the electronic device comprises a set comprising three stacks of layers, a first one of them comprising a red phosphorescent emitting layer and being a red light emitting stack, a second one of them comprising a green phosphorescent emitting layer and being a green light emitting stack, and a third one of them comprising a blue fluorescent emitting layer and being a blue light emitting stack.

An emitting layer of the electronic device preferably comprises a plurality of matrix materials (mixed matrix systems). An emitting layer of the electronic device may according to a preferred embodiment comprise a plurality of emitting compounds. In the case of a phosphorescent emitting layer, it is preferable that this layer contains two or more, preferably exactly two, different matrix materials.

Mixed matrix systems preferably comprise two or three different matrix materials, more preferably two different matrix materials. Preferably, in this case, one of the two materials is a material having hole-transporting properties and the other material is a material having electron-transporting properties. It is further preferable when one of the materials is selected from compounds having a large energy differential between HOMO and LUMO (wide-bandgap materials). The two different matrix materials may be present in a ratio of 1:50 to 1:1, preferably 1:20 to 1:1, more preferably 1:10 to 1:1 and most preferably 1:4 to 1:1. The desired electron-transporting and hole-transporting properties of the mixed matrix components may, however, also be combined mainly or entirely in a single mixed matrix component, in which case the further mixed matrix component(s) fulfil(s) other functions.

Preference is given to using the following material classes in emitting layers of the electronic device:

### Phosphorescent Emitters:

The term “phosphorescent emitters” typically encompasses compounds where the emission of light is effected through a spin-forbidden transition, for example a transition from an excited triplet state or a state having a higher spin quantum number, for example a quintet state.

Suitable phosphorescent emitters are especially compounds which, when suitably excited, emit light, preferably in the visible region, and also contain at least one atom of atomic number greater than 20, preferably greater than 38, and less than 84, more preferably greater than 56 and less than 80. Preference is given to using, as phosphorescent emitters, compounds containing copper, molybdenum, tungsten, rhenium, ruthenium, osmium, rhodium, iridium, palladium, platinum, silver, gold or europium, especially compounds containing iridium, platinum or copper.

In the context of the present invention, all luminescent iridium, platinum or copper complexes are considered to be phosphorescent compounds.

In general, all phosphorescent complexes as used for phosphorescent OLEDs according to the prior art and as known to those skilled in the art in the field of organic electroluminescent devices are suitable for use in the devices according to the application. Particularly preferred phosphorescent emitters are those explicitly depicted in the following list:

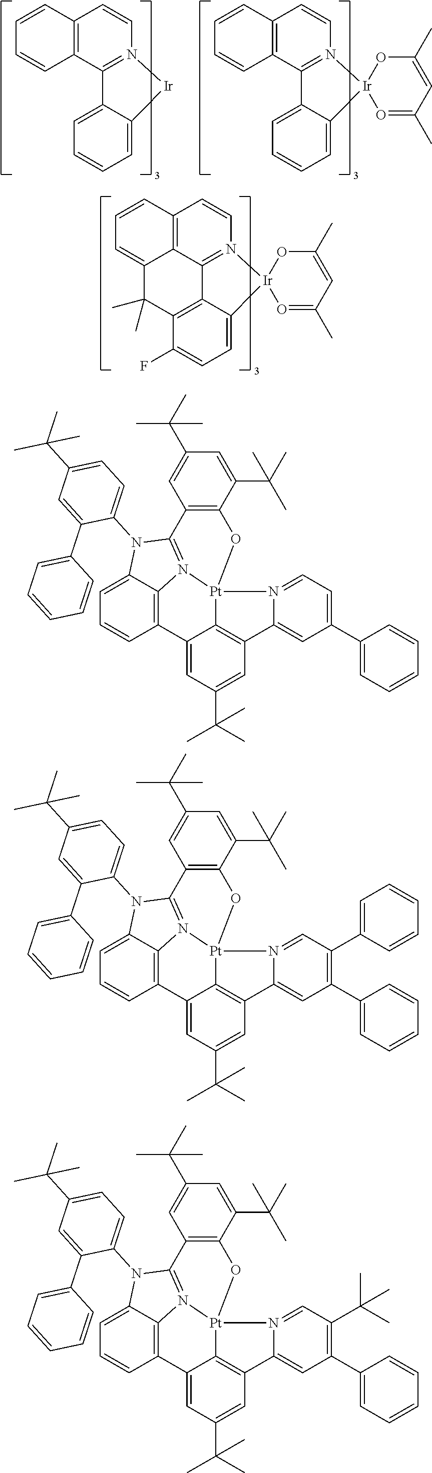

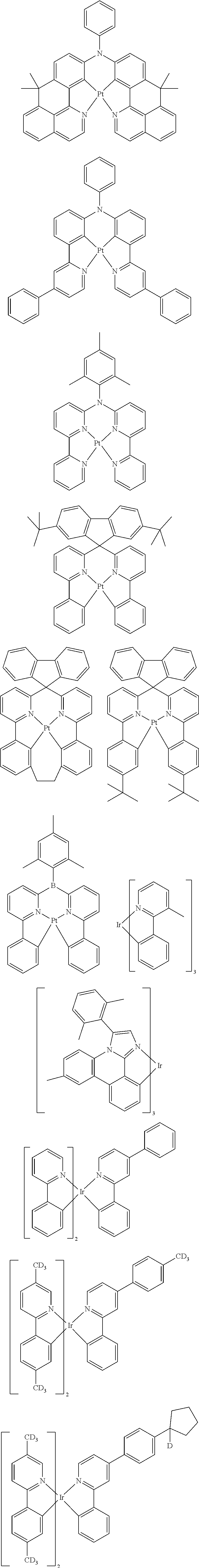

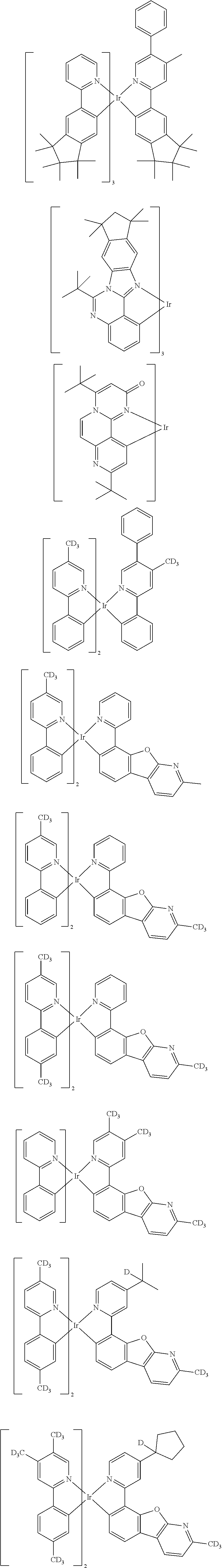

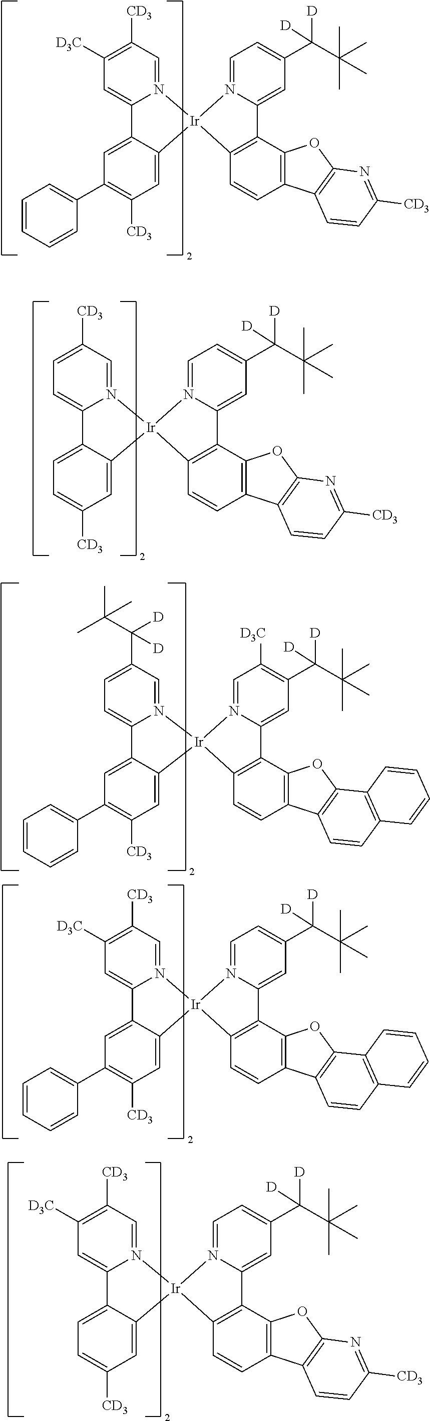

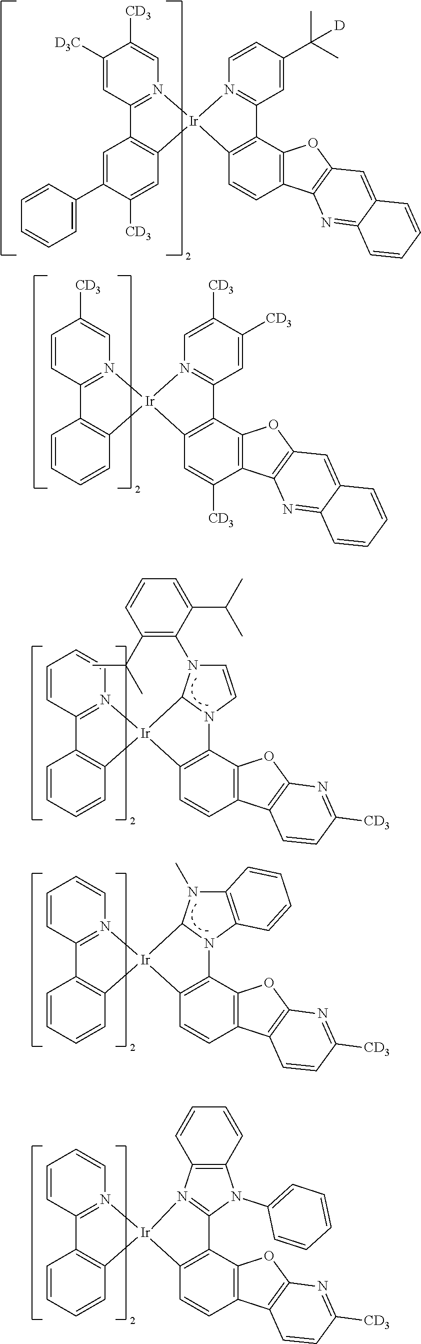

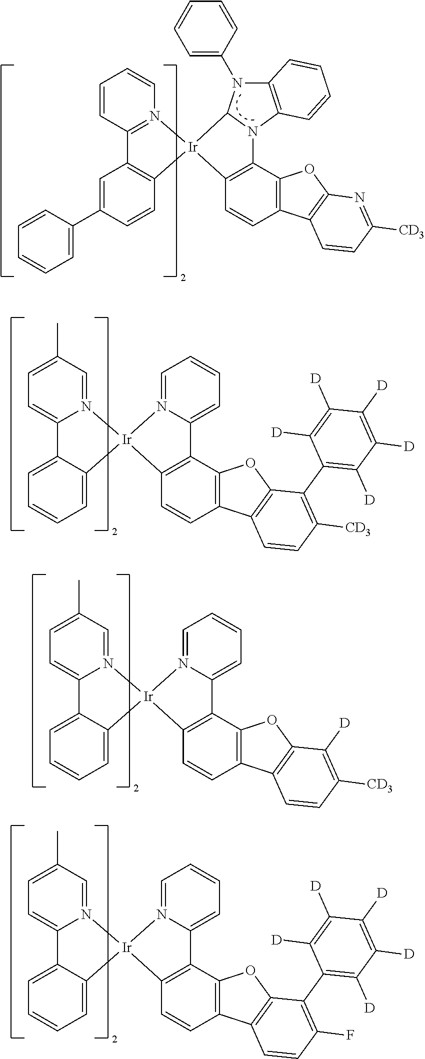

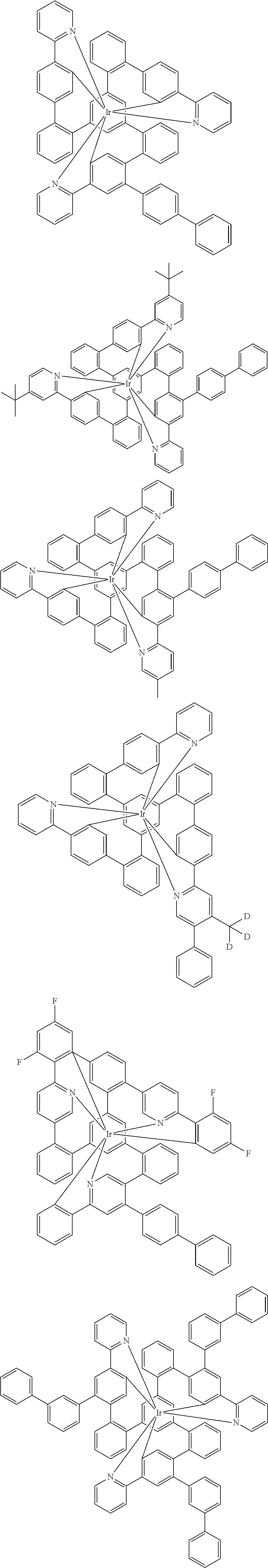

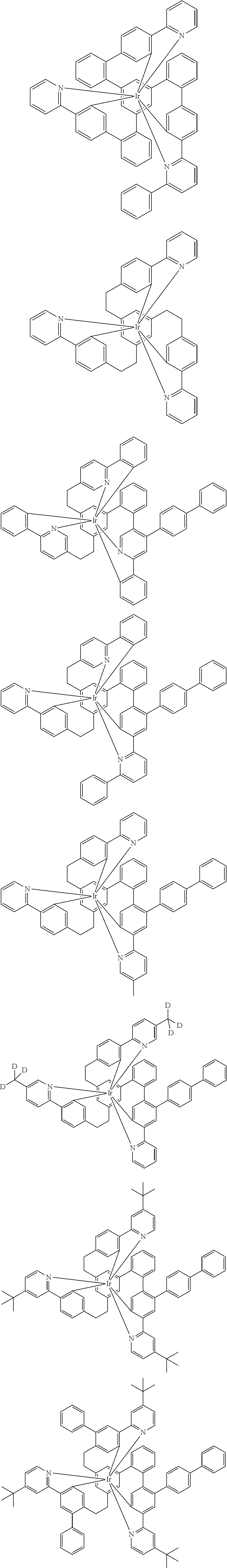

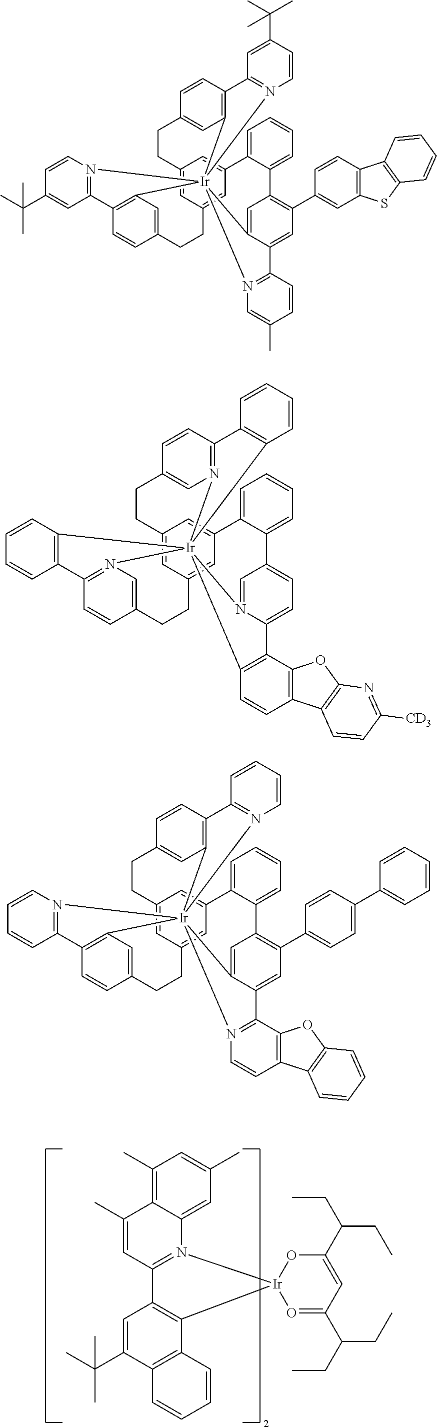

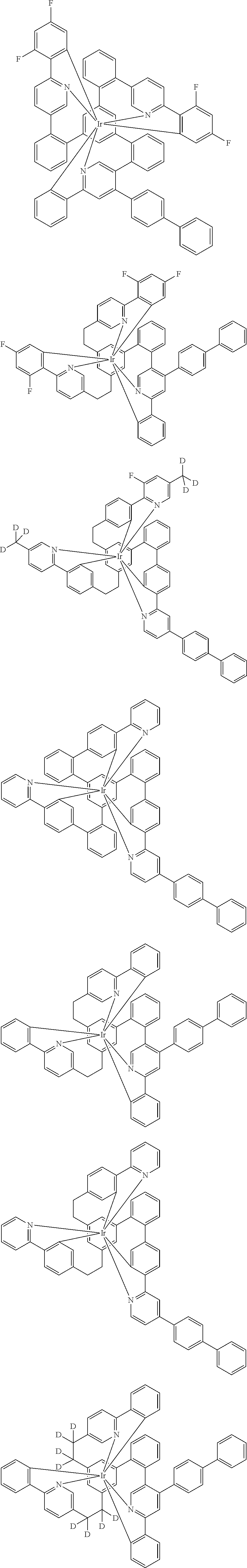

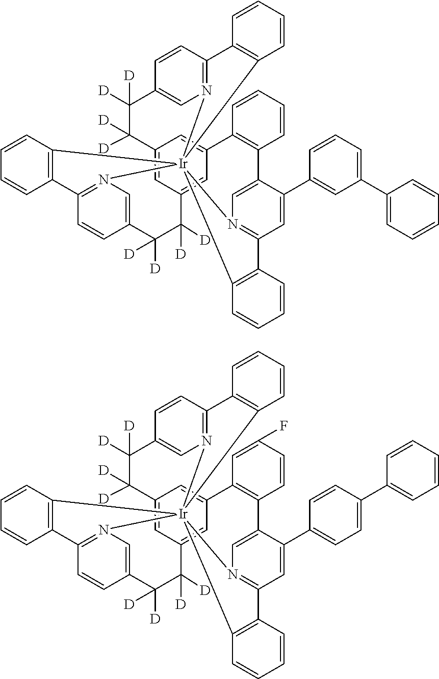

### Fluorescent Emitters:

Preferred fluorescent emitting compounds are selected from the class of the arylamines. An arylamine or an aromatic amine in the context of this invention is understood to mean a compound containing three substituted or unsubstituted aromatic or heteroaromatic ring systems bonded directly to the nitrogen. Preferably, at least one of these aromatic or heteroaromatic ring systems is a fused ring system, more preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyreneamines, pyrenediamines, chryseneamines and chrysenediamines are defined analogously, where the diarylamino groups are bonded to the pyrene preferably in the 1 position or 1,6 positions. Further preferred emitting compounds are indenofluoreneamines or -diamines, benzoindenofluoreneamines or -diamines, and dibenzoindenofluoreneamines or -diamines, and indenofluorene derivatives having fused aryl groups. Likewise preferred are pyrenearylamines. Likewise preferred are benzoindenofluoreneamines, benzofluoreneamines, extended benzoindenofluorenes, phenoxazines, and fluorene derivatives joined to furan units or to thiophene units.

### Matrix Materials for Fluorescent Emitters:

Preferred matrix materials for fluorescent emitters are selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides and sulfoxides; the atropisomers, the boronic acid derivatives or the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

### Matrix Materials for Phosphorescent Emitters:

Preferred matrix materials for phosphorescent emitters are aromatic ketones, aromatic phosphine oxides or aromatic sulfoxides or sulfones, triarylamines, carbazole derivatives, e.g. CBP (N,N-biscarbazolylbiphenyl), indolocarbazole derivatives, indenocarbazole derivatives, azacarbazole derivatives, bipolar matrix materials, silanes, azaboroles or boronic esters, triazine derivatives, zinc complexes, diazasilole or tetraazasilole derivatives, diazaphosphole derivatives, bridged carbazole derivatives, triphenylene derivatives, or lactams.

In addition to the above-mentioned layers, the stacks of layers of the electronic device may comprise further layers. These are selected, for example, from in each case one or more hole injection layers, hole transport layers, hole blocking layers, electron transport layers, electron injection layers, electron blocking layers, exciton blocking layers, interlayers, charge generation layers, outcoupling layers, emitting layers and/or organic or inorganic p/n junctions. However, it should be pointed out that not every one of these layers need necessarily be present and the choice of layers always depends on the compounds used and especially also on whether the device is a fluorescent or phosphorescent electroluminescent device.

In a preferred embodiment, the electron transport layer of the stacks of layers contains a triazine derivative and lithium quinolinate. In a preferred embodiment, the electron injection layer contains a triazine derivative and lithium quinolinate. In a particularly preferred embodiment, the electron transport layer and/or the electron injection layer, most preferably the electron transport layer and the electron injection layer, contain a triazine derivative and lithium quinolinate (LiQ).

The hole blocking layer preferably has hole-blocking and electron-transporting properties, and directly adjoins this emitting layer on the cathode side.

Suitable electron-transporting materials are, for example, the compounds disclosed in Y. Shirota et al., Chem. Rev. 2007, 107(4), 953-1010, or other materials used in these layers according to the prior art.

Materials used for the electron transport, electron injection and hole blocking layer may be any materials that are used as electron transport materials in the electron transport layer according to the prior art. Especially suitable are aluminium complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Particularly preferred materials for the electron transport, electron injection and hole blocking layer are those which are explicitly depicted in the table of p. 73-75 of WO2020/109434A1.

The electronic device may be used as a display device or as part of a display device, as light source in lighting applications, and as light source in medical and/or cosmetic applications.

Detailed Description of Electronic Device Comprising Two or More Stacks of Layers which are in Close Proximity to Each Other, where at Least One of them is a Tandem Stack

In such design of electronic device, there is preferably a multitude of stacks of layers, each one being in close proximity to its adjacent ones, where the layers of the stacks are preferably parallel to each other. Preferably, these stacks of layers are all composed identically. According to one preferred embodiment, these stacks of layers all have the same emission color, which is preferably white or blue. According to an alternative preferred embodiment, the stacks of layers have different emission color, for example in a triplet of tandem stacks of layer, a first one has blue emission color, a second one has green emission color, and a third one has red emission color. Therefore, the electronic device comprising side-by-side stacks of different color of emitted light, as described in the section above, can also comprise tandem stacks of layer, for example in a RGB-side-by-side setup.

Thereby, the embodiment described in the section above and the embodiment described in the present section can be combined in one embodiment.

The stacks of layers in this design of the electronic device are preferably tandem stacks. The basic structure of a tandem stack is shown in FIG. 2A, as described in detail above.

In such design of the electronic device according to the present application, the layer A is present preferably as a layer A1 or as a layer A2, or both as a layer A1 and a layer A2. FIG. 2B shows the case in which there is a layer A as a layer A1 which is a hole injection layer, as described in detail above. FIG. 2C shows the case in which there is a layer A as a layer A2 which is a charge generation layer or a sub-layer of a charge generation layer of a tandem stack, as described in detail above. FIG. 2D shows the case in which there is a layer A both as a layer A1 which is a hole injection layer, and as a layer A2 which is a charge generation layer or a sub-layer of a charge generation layer, as described in detail above.

For the case that there is a layer A present in the electronic device which is a layer A1, the same preferred embodiments regarding the layer and its components as detailed out above for the case of the electronic device which has a multi-color side-by-side design, apply.

In the case of the layer A2, this layer is preferably present in each case between two emitting layers of the stack of layers. Preferably, in the case where there are two emitting layers, there is therefore one layer A2, positioned between these emitting layers. Preferably, in the case where there are three emitting layers, there are therefore two layers A2 present in the electronic device, a first layer A2 between a first one of the three emitting layers and a second one of the three emitting layers, and a second layer A2 between a second one of the three emitting layers, and a third one of the three emitting layers. Preferably, in the case where there are four emitting layers, there are therefore three layers A2 present in the electronic device, a first layer A2 between a first one of the four emitting layers and a second one of the four emitting layers, and a second layer A2 between a second one of the four emitting layers and a third one of the four emitting layers, and a third layer A2 between a third one of the four emitting layers and a fourth one of the four emitting layers.

In the case there are three emitting layers in the stack of layers, it is preferred that a first one of them comprises a blue light emitting layer, a second of them comprises a green light emitting layer, and a third one of them comprises an orange or red, preferably red light emitting layer.

The preferred sequence of layers of the stack of layers in such design of the electronic device is, in this sequence, from the anode to the cathode:
anode
first hole injection layer, preferably layer A
first hole transport layer
first electron blocking layer
first emitting layer
first hole blocking layer
first electron transporting layer
first charge generation layer, preferably layer A
second hole transport layer
second electron blocking layer
second emitting layer
second hole blocking layer
second electron transporting layer
second charge generation layer, preferably layer A
third hole transport layer
third electron blocking layer
third emitting layer
third hole blocking layer
third electron transporting layer
third electron injection layer
cathode.

A pixel defining layer (PDL) is preferably applied in the electronic device comprising a plurality of stacks of layers, after application of the anode, preferably by a lithographic method.

Further layers may be present in the stack, selected from the known layers for use in OLEDs, which are listed above.

The charge generation layers are preferably selected from layers A. If they are not selected from layers A, they are preferably composed as described on p. 360-362, section 3.2, of N. Amaroli, H. J. Bolink (editors), Photoluminescent Materials and Electroluminescent Devices, Topics in Current Chemistry Collections, Springer, 2017.

According to a preferred embodiment, the charge generation layer is composed of two sublayers, a first one of these sublayers being a layer A, and a second one of these sublayers being a layer comprising an electron transport material and a n-dopant. The two sublayers preferably have a combined thickness of between 10 and 40 nm.

The layer A2 is preferably a charge generation layer or a sub-layer of a charge generation layer, as described above.

Regarding the composition of the layer A2, the same preferred embodiments apply as for the case of the layer A1, described above. Preferably, the proportion of the compound C3 in the layer A2 is between 5% and 20%. Percentage is preferably determined by volume.

Aside from the layer A, the stack of layers is preferably composed as known in the art. In particular it is preferred that the respective functional layers have the composition as detailed above as preferred, in regard to the multi-color side-by-side electronic device.

The electronic device according to such design of device is preferably used as a display device or as part of a display device, as light source in lighting applications, and as light source in medical and/or cosmetic applications.

### Detailed Description of Method of Making the Electronic Device, in Particular Method of Applying the Layer A

In a preferred embodiment, the electronic device is characterized in that one or more layers are applied by a sublimation process. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar. Preferably, the layer A of the electronic device is applied by vapor deposition.

Further aspect of the present application is a method of making an electronic device as defined above, characterized in that the compound C1 and the compound C2 are first mixed, and the resulting mixture is then used for the preparation of the layer A by vapor deposition. In such case, preferably, the mixture of compounds C1 and compound C2 is used as one source of the vapor deposition process, and compound C3 is applied from a different source.

In one embodiment of the present invention, the mixture of compound C1 and compound C2 does not comprise any further constituents, i.e. functional materials, aside from the compound C1 and the compound C2, meaning that the mixture consists of the compound C1 and the compound C2. These mixtures are also referred to as premixes or premix systems and can be used as one material for the vapor deposition of the layer A, where the second material is the compound C3. Preferably, these mixtures maintain their mixing ratio over the vapor deposition process, so that the proportion of the two compounds C1 and C2 in the layer A is the same or similar to the proportion of the compounds in the pre-mix. In this way, it is possible in a simple and rapid manner to achieve a mixed layer with a homogeneous distribution of the compounds C1 and C2, in a proportion which can be pre-determined, without the need for actuation of two different material sources in the vapor deposition process, as it is the case if compound C1 and compound C2 are applied as a mixed layer by co-evaporation.

Preference is likewise given to an electronic device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

Preference is additionally given to an electronic device, characterized in that one or more layers are produced from solution, for example by spin-coating, or by any printing method, for example screen printing, flexographic printing, nozzle printing or offset printing, but more preferably LITI (light-induced thermal imaging, thermal transfer printing) or inkjet printing. According to a preferred embodiment, the layer A is applied from solution, preferably by one of the above processes. In such case, the components of layer A need to be soluble in the solvent.

It is further preferable that an electronic device according to the application is produced by applying one or more layers from solution and one or more layers by a sublimation method.

After application of the layers, according to the use, the device is structured, contact-connected and finally sealed, in order to rule out damaging effects of water and air.

### Mixture of Compounds, for Preparation of Layer A

As described above, a mixture comprising at least one compound C1 and at least one compound C2 is preferably used for preparing the layer A of the electronic device according to the present application, preferably by a vapor deposition process. The preferred embodiments regarding proportions of compounds C1 and C2 relative to each other, and the preferred embodiments regarding the chemical structure and properties of compounds C1 and C2, as detailed above in connection with the electronic device, also apply to the mixture. Further, as described above, such mixture maintains its mixing ratio over the vapor deposition process, so that the proportion of the two compounds C1 and C2 in the layer A is the same or similar to the proportion of the compounds in the mixture. Use of such mixture for the vapor deposition of layer A is therefore also a subject of the present application.

A mixture comprising at least one compound C1, at least one compound C2 and at least one compound C3 is preferably used for preparing the layer A of the electronic device according to the present application, preferably by a solution based process. The preferred embodiments regarding proportions of compounds C1, C2 and C3 relative to each other, and the preferred embodiments regarding the chemical structure and properties of compounds C1, C2 and C3, as detailed above in connection with the electronic device, also apply to the mixture. Use of such mixture for the deposition of layer A by a solution based process is therefore also a subject of the present application.

### FIGURES

FIG. 1 shows an electronic device according to the present application, comprising two stacks of layers, each of them comprising a single light emitting layer, where the hole injection layer is a shared layer. The reference signs in the figure are explained as follows:
1 Electronic device
2a first stack of layers
2b second stack of layers
3 substrate layer
4a Anode of first stack of layers
4b Anode of second stack of layers
Hole injection layer as shared layer, preferably as a layer A
6a Light emitting layer of first stack of layers
6b Light emitting layer of second stack of layers
7 cathode

FIG. 2A shows a stack of layers which is a tandem stack of layers, comprising at least two light emitting layers and a charge generation layer between the two light emitting layers. The reference signs in the figure are explained as follows:
3 Substrate
4 Anode
5 Hole injection layer
6 Emitting layer
7 Cathode
8 Tandem stack of layers
9a First light emitting unit
9b Second light emitting unit
10 Charge generation layer
11 Hole transporting layer
12 Electron transporting layer
13 Electron injection layer

FIG. 2B shows an electronic device according to the present application, comprising two tandem stacks of layers, each of them comprising at least two light emitting layers and a charge generation layer between the two light emitting layers, where the hole injection layer is a shared layer and the charge generation layer is not a shared layer. The reference signs in the figure are explained as follows:
1 Electronic device
2a first stack of layers
2b second stack of layers
3 Substrate
4a Anode of first stack of layers
4b Anode of second stack of layers
5 Hole injection layer as shared layer, preferably as a layer A
6a Light emitting layer of first stack
6b Light emitting layer of second stack
7 Cathode
10a Charge generation layer of first stack
10b Charge generation layer of second stack
14a Second light emitting layer of first stack
14b Second light emitting layer of second stack

FIG. 2C shows an electronic device according to the present application, comprising two tandem stacks of layers, each of them comprising at least two light emitting layers and a charge generation layer between the two light emitting layers, where the hole injection layer is not a shared layer and the charge generation layer is a shared layer. The reference signs in the figure are explained as follows:
1 Electronic device
2a first stack of layers
2b second stack of layers
3 Substrate
4a Anode of first stack of layers
4b Anode of second stack of layers
5a Hole injection layer of first stack
5b Hole injection layer of second stack
6a Light emitting layer of first stack
6b Light emitting layer of second stack
7 Cathode
10 Charge generation layer as shared layer, preferably as a layer A
14a Second light emitting layer of first stack
14b Second light emitting layer of second stack

FIG. 2D shows an electronic device according to the present application, comprising two tandem stacks of layers, each of them comprising at least two light emitting layers and a charge generation layer between the two light emitting layers, where the hole injection layer and the charge generation layer are both shared layers. The reference signs in the figure are explained as follows:
1 Electronic device
2a first stack of layers
2b second stack of layers
3 Substrate
4a Anode of first stack of layers
4b Anode of second stack of layers
5 Hole injection layer as shared layer, preferably as a layer A
6a Light emitting layer of first stack
6b Light emitting layer of second stack
7 Cathode
10 Charge generation layer as shared layer, preferably as a layer A
14a Second light emitting layer of first stack
14b Second light emitting layer of second stack

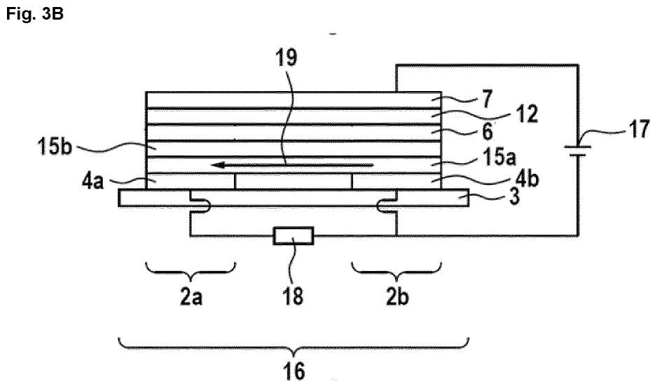

FIG. 3A shows a device for measuring the lateral current, taking place between two stacks which are in close proximity to each other, and which flows through the shared layer A. The reference signs in the figure are explained as follows:
2a First stack of layers
2b Second stack of layers
3 Substrate
4a Anode of first stack of layers
4b Anode of second stack of layers
6a Light emitting layer of first stack
6b Light emitting layer of second stack
7 Cathode
12 Electron transporting layer as shared layer
15a Hole injection layer as shared layer, corresponding to layer A
15b Hole transporting layer as shared layer
16 Device for measuring lateral current
17 Device for application of voltage
18 Device for measuring of electrical current
19 Lateral electrical current flow

FIG. 3B shows a device for measuring the lateral current which is the same as the device shown in FIG. 3A, but with the difference that the light emitting layer is a shared layer, and not two separate layers, reference number 6. The reference signs in the figure are explained as follows:
2a First stack of layers
2b Second stack of layers
3 Substrate
4a Anode of first stack of layers
4b Anode of second stack of layers
6 Light emitting layer as shared layer
7 Cathode
12 Electron transporting layer as shared layer
15a Hole injection layer as shared layer, corresponding to layer A
15b Hole transporting layer as shared layer
16 Device for measuring lateral current
17 Device for application of voltage
18 Device for measuring of electrical current
19 Lateral electrical current flow

### PATENT EXAMPLES

A) Lateral Current Reduction Obtained by Adding Compound with Low HOMO to a Hole Transporting Compound in the Hole Injection Layer

The examples presented are based on a state of the art OLED stack, consisting of 7 organic layers between an ITO anode and an aluminum cathode. Its layer composition is shown in table 1.

The examples show the effect of a hole injection layer consisting of three materials (a hole-transporting compound, a compound with a low HOMO and a p-dopant) on the lateral current, compared to a reference HIL consisting solely of a hole-transporting compound and a p-dopant. Combinations of four different HTMs (HTM-1, HTM-2, HTM-3 and HTM-4) and three different compounds having a low HOMO (ETM-2, ETM-3 and ETM-4) are used for the HILs of the OLEDs. The p-dopant is PDM-1 in all cases. The HTM comprised in the HTL can be the same as the HTM comprised in the HIL or different. In the examples of Table 2, it is the same. Table 2 shows the composition, mixing ratio and the thickness of the HIL and HTL layers of the electronic devices. Mixing ratios of compounds in mixed layers are given in %, such as e.g. the following in example 1-1: HTM-1:PDM-1:ETM-2 (45%:5%:50%). The chemical structures of the compounds used are shown in a Table below. HTM-4 is a fluorene having an amine in the 2-position, and having a substituent on one of the aromatic rings of the fluorene.

The stacks are prepared on two types of substrates: one substrate is for electro-optical measurement of the OLED device performance, and another substrate is specially designed for lateral current measurements.

TABLE 1
OLED layer composition

| Layer | Layer | | Ratio | Thickness |
|---|---|---|---|---|
| # | type | Material | (%) | (nm) |
| 1 | Anode | ITO | 100.0 | 120.0 |
| 2 | HIL | See table 2 | | 10.0 |
| 3 | HTL | | | 110.0 |
| 4 | EBL | EBM-1 | 100.0 | 5.0 |
| 5 | EML | SMB-1 | 97.0 | 20.0 |
| | | SEB-2 | 3.0 | |
| 6 | HBL | ETM-5 | 100.0 | 5.0 |
| 7 | ETL | ETM-3 | 50.0 | 30.0 |
| | | LiQ | 50.0 | |
| 8 | EIL | LiQ | 100.0 | 1.0 |
| 9 | Cathode | Al | 100.0 | 100.0 |

TABLE 2
OLED stacks: HIL and HTL composition

| | HIL ratio | HTL ratio |
|---|---|---|
| Exp. | thickness | thickness |
| 1-comp | HTM-1:PDM-1 | HTM-1 |
| | (95%:5%) | |
| | 10 nm | 110 nm |
| 1-1 | HTM-1:PDM-1:ETM-2 | HTM-1 |
| | (45%:5%:50%) | |
| | 10 nm | 110 nm |
| 1-2 | HTM-1:PDM-1:ETM-3 | HTM-1 |
| | (45%:5%:50%) | |
| | 10 nm | 110 nm |
| 1-3 | HTM-1:PDM-1:ETM-4 | HTM-1 |
| | (45%:5%:50%) | |
| | 10 nm | 110 nm |
| 2-comp | HTM-2:PDM-1 | HTM-2 |
| | (95%:5%) | |
| | 10 nm | 110 nm |
| 2-1 | HTM-2:PDM-1:ETM-2 | HTM-2 |
| | (45%:5%:50%) | |
| | 10 nm | 110 nm |
| 2-2 | HTM-2:PDM-1:ETM-3 | HTM-2 |
| | (45%:5%:50%) | |
| | 10 nm | 110 nm |
| 2-3 | HTM-2:PDM-1:ETM-4 | HTM-2 |
| | (45%:5%:50%) | |
| | 10 nm | 110 nm |
| 3-comp | HTM-3:PDM-1 | HTM-3 |
| | (95%:5%) | |
| | 10 nm | 110 nm |
| 3-1 | HTM-3:PDM-1:ETM-2 | HTM-3 |
| | (45%:5%:50%) | |
| | 10 nm | 110 nm |
| 3-2 | HTM-3:PDM-1:ETM-3 | HTM-3 |
| | (45%:5%:50%) | |
| | 10 nm | 110 nm |
| 3-3 | HTM-3:PDM-1:ETM-4 | HTM-3 |
| | (45%:5%:50%) | |
| | 10 nm | 110 nm |
| 4-comp | HTM-4:PDM-1 | HTM-4 |
| | (95%:5%) | |
| | 10 nm | 110 nm |
| 4-1 | HTM-4:PDM-1:ETM-2 | HTM-4 |
| | (45%:5%:50%) | |
| | 10 nm | 110 nm |
| 4-2 | HTM-4:PDM-1:ETM-3 | HTM-4 |
| | (45%:5%:50%) | |
| | 10 nm | 110 nm |
| 4-3 | HTM-4:PDM-1:ETM-4 | HTM-4 |
| | (45%:5%:50%) | |
| | 10 nm | 110 nm |

Lateral current is measured for the inventive OLEDs and the reference OLEDs described above.

The method used to measure the lateral current is described in section 2.1 and FIG. 1(d) of Matthias Diethelm et al., Quantitative analysis of pixel crosstalk in AMOLED displays, Journal of Information Display, vol. 19, p. 61-69, 2018. The measured device has a structure as shown in FIG. 3A or FIG. 3B, preferably FIG. 3B.

FIGS. 3A and 3B show the device 16 for measuring the lateral current, taking place between two stacks which are in close proximity to each other, and which flows through the shared layer A. The device comprises two stacks of layer 2a and 2b, both applied to a common substrate 3. The second stack is the operated stack, where a voltage is applied through a device 17. The first stack is the measured stack, where the lateral current 19 is measured by a device 18. The two stacks of layers 2a and 2b each comprise separate anodes 4a and 4b, separate light emitting layers 6a and 6b in the case of FIG. 3A and a shared light emitting layer in the case of FIG. 3B, a shared hole injection layer 15a, a shared hole transport layer 15b, and a shared electron transporting layer 12. When voltage is applied at the second stack 2b with the device 17, a lateral current 19 which flows through the shared layer 15a, which is preferably a layer A, can be measured with the device 18.

On the OLED devices for measuring lateral current there are two pixels with interdigitated ITO electrode arrays covered by an organic pixel defining layer (PDL). In the PDL, there are precise openings to the ITO electrodes, so that the gap between two electrodes has a width of 20 μm. On top of this structure, the OLED stack is evaporated as common layers covering the interdigitated electrode array. A voltage source connects one of the electrodes and the common cathode, connected to ground. The other electrode is connected via a current meter connected to ground. The meter measures the lateral current collected by the interdigitated electrode. In Table 4, the values for the lateral current measured are listed. The measurements are performed at a voltage of 4 V.

TABLE 3
Data of lateral current of the OLED devices

| | Lateral Current | |
|---|---|---|
| | density at U = | |
| | 4 V | Lateral Current at U = 4 V |
| Exp. | (μA/cm²) | (relative to reference.) |
| 1-comp | 58.0 | 100% |
| 1-1 | 20.5 | 36% |
| 1-2 | 14.3 | 25% |
| 1-3 | 8.7 | 15% |
| 2-comp | 9.3 | 100% |
| 2-1 | 2.0 | 21% |
| 2-2 | 0.9 | 10% |
| 2-3 | 0.6 | 7% |
| 3-comp | 6.2 | 100% |
| 3-1 | 1.3 | 21% |
| 3-2 | 0.6 | 10% |
| 3-3 | 0.4 | 7% |
| 4-comp | 45.1 | 100% |
| 4-1 | 20.7 | 46% |
| 4-2 | 14.7 | 33% |
| 4-3 | 8.5 | 19% |

The results show that the mixing of the compound having a low HOMO with the HTM in the HIL is effective in strongly reducing the lateral current. The other OLED device parameters remain meanwhile mostly unchanged, as shown in the following.

Unexpectedly, if any of the three compounds having a low HOMO which are used, is mixed into HTM-1 or HTM-2, this even results in a significant increase of lifetime, in addition to the improvement in performance.

In addition, the general OLED performance data lifetime, efficiency and voltage are investigated. The following Table 3 shows the performance data in terms of lifetime, efficiency and operating voltage for the above-described OLEDs.

The OLED devices are characterized as follows: Spectrum of the electroluminescence, operating voltage, lifetime and external quantum efficiency (EQE, given in percent) are determined. In table 3, the values at a luminescence of 1000 cd/m² are listed. Lifetime (LT) measurement is carried out at a constant current density of 30 mA/cm² until the luminance decreased to 95% of the starting value.

TABLE 4
Data of OLED devices

| | Current | | | | LT |
|---|---|---|---|---|---|
| | density | U | EQE | LT | (relative to |
| Exp. | (mA/cm²) | (V) | (%) | (h) | reference) |
| 1-comp | 11.7 | 3.4 | 9.3 | 217 | 100% |
| 1-1 | 11.6 | 3.4 | 9.4 | 217 | 100% |
| 1-2 | 11.6 | 3.4 | 9.4 | 224 | 103% |
| 1-3 | 11.7 | 3.4 | 9.4 | 222 | 102% |
| 2-comp | 11.2 | 3.6 | 9.2 | 177 | 100% |
| 2-1 | 11.2 | 3.6 | 9.3 | 188 | 106% |
| 2-2 | 11.2 | 3.7 | 9.3 | 198 | 112% |
| 2-3 | 11.1 | 3.7 | 9.3 | 193 | 109% |
| 3-comp | 11.5 | 3.6 | 9.1 | 230 | 100% |
| 3-1 | 11.5 | 3.7 | 9.2 | 239 | 104% |
| 3-2 | 11.4 | 3.8 | 9.2 | 238 | 103% |
| 3-3 | 11.3 | 3.9 | 9.3 | 215 | 93% |
| 4-comp | 11.5 | 3.5 | 9.3 | 207 | 100% |
| 4-1 | 11.5 | 3.5 | 9.3 | 201 | 97% |
| 4-2 | 11.5 | 3.5 | 9.4 | 208 | 100% |
| 4-3 | 11.5 | 3.5 | 9.4 | 201 | 97% |

The results show that for the OLEDs according to the invention and the reference OLEDs, very similar performance parameters regarding lifetime, efficiency and voltage are obtained, in parallel to the strong improvement in lateral current shown for the OLEDs according to the invention.

B) Comparison of Effects Obtained from Increasing Proportion of Low-HOMO Material, Compared to Effects Obtained from Decreasing Proportion of p-Dopant
B-1) Variation of p-Dopant and Proportion of p-Dopant

In the examples of this section, the dopant itself and the dopant concentration in the HIL is varied for the case of hole transport material HTM-1. Tables 5 to 7 summarize the results. Clearly and independent of the used p-dopant, the lateral current decreases with decreasing dopant ratio while the operating voltage (U) increases with decreasing dopant ratio in a nonlinear way. Lifetime remains on comparable level in all experiments. Similar results would occur in case ETM-1 is omitted, and only HTM-1 and one of PDM-1 to PDM-3 would be present in the HIL.

TABLE 5
OLED stacks: HIL with variation of p-dopant and ratio

| | HIL | HTL |
|---|---|---|
| | ratio | ratio |
| Exp. | thickness | thickness |
| 5-1 | HTM-1:ETM-1:PDM-1 | HTM-1 |
| | (48.5%:50%:1.5%) | 110 nm |
| | 10 nm | |
| 5-2 | HTM-1:ETM-1:PDM-1 | HTM-1 |
| | (47%:50%:3%) | 110 nm |
| | 10 nm | |
| 5-3 | HTM-1:ETM-1:PDM-1 | HTM-1 |
| | (46%:50%:4%) | 110 nm |
| | 10 nm | |
| 5-4 | HTM-1:ETM-1:PDM-1 | HTM-1 |
| | (45%:50%:5%) | 110 nm |
| | 10 nm | |
| 6-1 | HTM-1:ETM-1:PDM-2 | HTM-1 |
| | (47%:50%:3%) | 110 nm |
| | 10 nm | |
| 6-2 | HTM-1:ETM-1:PDM-2 | HTM-1 |
| | (46%:50%:4%) | 110 nm |
| | 10 nm | |
| 6-3 | HTM-1:ETM-1:PDM-2 | HTM-1 |
| | (45%:50%:5%) | 110 nm |
| | 10 nm | |
| 7-1 | HTM-1:ETM-1:PDM-3 | HTM-1 |
| | (47%:50%:3%) | 110 nm |
| | 10 nm | |
| 7-2 | HTM-1:ETM-1:PDM-3 | HTM-1 |
| | (46%:50%:4%) | 110 nm |
| | 10 nm | |
| 7-3 | HTM-1:ETM-1:PDM-3 | HTM-1 |
| | (45%:50%:5%) | 110 nm |
| | 10 nm | |

TABLE 6
Data of OLED devices with variation of HIL p-dopant and ratio

| | Luminance | current | U | EQE |
|---|---|---|---|---|
| Exp. | (cd/m²) | (mA/cm²) | (V) | (%) |
| 5-1 | 1000 | 11.2 | 4.2 | 10.0 |
| 5-2 | 1000 | 11.2 | 3.5 | 9.8 |
| 5-3 | 1000 | 11.4 | 3.5 | 9.68 |
| 5-4 | 1000 | 11.4 | 3.4 | 9.6 |
| 6-1 | 1000 | 12.5 | 4.1 | 9.2 |
| 6-2 | 1000 | 12.3 | 3.9 | 9.0 |
| 6-3 | 1000 | 12.4 | 3.8 | 8.9 |
| 7-1 | 1000 | 12.7 | 4.0 | 9.1 |
| 7-2 | 1000 | 12.6 | 3.9 | 8.9 |
| 7-3 | 1000 | 12.6 | 3.7 | 8.9 |

TABLE 7
Data of lateral current (LC) of the OLED devices
with variation of HIL p-dopant and ratio

| Exp. | LC measured at U = 4 V (nA) |
|---|---|
| 5-1 | 0.4 |
| 5-2 | 2.1 |
| 5-3 | 4.6 |
| 5-4 | 8.9 |
| 6-1 | 0.8 |
| 6-2 | 1.5 |
| 6-3 | 2.0 |
| 7-1 | 0.7 |
| 7-2 | 1.6 |
| 7-3 | 2.5 |

### B-2) Variation of Proportion of Low-HOMO Material

In the examples of this section, the proportion of the low-HOMO material is increased, while the proportion of the p-dopant is remained constant. It is shown that the lateral current decreases with increasing low HOMO material proportion, while the operating voltage (U) can increase with increasing low-HOMO material ratio, however only slightly or even not at all. Lifetime remains on comparable level in all experiments.

TABLE 8
OLED stacks: HIL with variation of low HOMO material ratio

| | HIL | HTL |
|---|---|---|
| | ratio | ratio |
| Exp. | thickness | thickness |
| 8-1 | HTM-1:ETM-1:PDM-1 | HTM-1 |
| | (45%:50%:5%) | 110 nm |
| | 10 nm | |
| 8-2 | HTM-1:ETM-1:PDM-1 | HTM-1 |
| | (35%:60%:5%) | 110 nm |
| | 10 nm | |
| 8-3 | HTM-1:ETM-1:PDM-1 | HTM-1 |
| | (25%:70%:5%) | 110 nm |
| | 10 nm | |
| 9-1 | HTM-1:ETM-6:PDM-1 | HTM-1 |
| | (70%:25%:5%) | 110 nm |
| | 10 nm | |
| 9-2 | HTM-1:ETM-6:PDM-1 | HTM-1 |
| | (45%:50%:5%) | 110 nm |
| | 10 nm | |
| 9-3 | HTM-1:ETM-6:PDM-1 | HTM-1 |
| | (35%:60%:5%) | 110 nm |
| | 10 nm | |
| 10-1 | HTM-1:ETM-4:PDM-1 | HTM-1 |
| | (70%:25%:5%) | 110 nm |
| | 10 nm | |
| 10-2 | HTM-1:ETM-4:PDM-1 | HTM-1 |
| | (45%:50%:5%) | 110 nm |
| | 10 nm | |
| 10-3 | HTM-1:ETM-4:PDM-1 | HTM-1 |
| | (35%:60%:5%) | 110 nm |
| | 10 nm | |
| 11-1 | HTM-7:ETM-4:PDM-1 | HTM-7 |
| | (70%:25%:5%) | 110 nm |
| | 10 nm | |
| 11-2 | HTM-7:ETM-4:PDM-1 | HTM-7 |
| | (45%:50%:5%) | 110 nm |
| | 10 nm | |
| 12-1 | HTM-9:ETM-4:PDM-1 | HTM-9 |
| | (70%:25%:5%) | 110 nm |
| | 10 nm | |
| 12-2 | HTM-9:ETM-4:PDM-1 | HTM-9 |
| | (45%:50%:5%) | 110 nm |
| | 10 nm | |
| 12-3 | HTM-9:ETM-4:PDM-1 | HTM-9 |
| | (3%:60%:5%) | 110 nm |
| | 10 nm | |
| 13-1 | HTM-10:ETM-4:PDM-1 | HTM-10 |
| | (70%:25%:5%) | 110 nm |
| | 10 nm | |
| 13-2 | HTM-10:ETM-4:PDM-1 | HTM-10 |
| | (45%:50%:5%) | 110 nm |
| | 10 nm | |
| 13-3 | HTM-10:ETM-4:PDM-1 | HTM-10 |
| | (35%:60%:5%) | 110 nm |
| | 10 nm | |
| 14-1 | HTM-11:ETM-4:PDM-1 | HTM-11 |
| | (70%:25%:5%) | 110 nm |
| | 10 nm | |
| 14-2 | HTM-11:ETM-4:PDM-1 | HTM-11 |
| | (45%:50%:5%) | 110 nm |
| | 10 nm | |
| 14-3 | HTM-11:ETM-4:PDM-1 | HTM-11 |
| | (35%:60%:5%) | 110 nm |
| | 10 nm | |

TABLE 9
Data of OLED devices with variation
of low-HOMO material ratio in HIL

| | Luminance | current | U | EQE |
|---|---|---|---|---|
| Exp. | (cd/m²) | (mA/cm²) | (V) | (%) |
| 8-1 | 1000 | 11.4 | 3.4 | 9.6 |
| 8-2 | 1000 | 11.7 | 3.5 | 9.5 |
| 8-3 | 1000 | 11.7 | 3.6 | 9.5 |
| 9-1 | 1000 | 12.0 | 3.5 | 9.2 |
| 9-2 | 1000 | 11.9 | 3.5 | 9.3 |
| 9-3 | 1000 | 11.9 | 3.5 | 9.3 |
| 10-1 | 1000 | 11.6 | 3.4 | 9.4 |
| 10-2 | 1000 | 11.6 | 3.4 | 9.4 |
| 10-3 | 1000 | 11.6 | 3.4 | 9.4 |
| 11-1 | 1000 | 10.2 | 3.5 | 10.8 |
| 11-2 | 1000 | 10.1 | 3.5 | 10.8 |
| 12-1 | 1000 | 10.3 | 3.6 | 10.4 |
| 12-2 | 1000 | 10.4 | 3.6 | 10.4 |
| 12-3 | 1000 | 10.4 | 3.6 | 10.4 |
| 13-1 | 1000 | 10.8 | 3.6 | 9.8 |
| 13-2 | 1000 | 10.8 | 3.5 | 9.7 |
| 13-3 | 1000 | 10.8 | 3.5 | 9.7 |
| 14-1 | 1000 | 12.8 | 3.5 | 8.5 |
| 14-2 | 1000 | 12.8 | 3.5 | 8.5 |
| 14-3 | 1000 | 12.8 | 3.5 | 8.5 |

TABLE 10
Data of lateral current of the OLED devices with
variation of low-HOMO material ratio in HIL

| Exp. | Lateral Current density measured at U = 4 V (μA/cm²) |
|---|---|
| 8-1 | 1.8 |
| 8-2 | 1.6 |
| 8-3 | 1.5 |
| 9-1 | 19.1 |
| 9-2 | 10.1 |
| 9-3 | 9.1 |
| 10-1 | 16.3 |
| 10-2 | 8.8 |
| 10-3 | 7.5 |
| 11-1 | 13.1 |
| 11-2 | 7.2 |
| 12-1 | 22.8 |
| 12-2 | 14.5 |
| 12-3 | 12.1 |
| 13-1 | 21.9 |
| 13-2 | 13.4 |
| 13-3 | 13.1 |
| 14-1 | 20.9 |
| 14-2 | 11.3 |
| 14-3 | 9.9 |

The results obtained show that by increasing the proportion of the low-HOMO material in the HIL, the lateral current can be reduced while the operating voltage is only slightly or not increased at all. The low-HOMO material thus enables obtain both low operating voltage and low lateral current. This cannot be reached by varying the p-dopant ratio in the HIL, as shown by the examples above.

C) Testing of Devices where the HTM Comprised in the HTL is Different from the HTM Comprised in the HIL

### C1) Variation of HTM Material in HIL and HTL

In the examples shown in this section, various state-of-the-art HTM materials in the HIL, mixed with low HOMO material of different concentrations, are combined with an HTM in the HTL layer which is different to the HTM in the HIL. The chemical structures of the compounds used are shown in a Table below. HTM-5 is a fluorene having an amine in the 2-position, and having a substituent on one of the aromatic rings of the fluorene.

TABLE 11
OLED stacks: HIL and HTL composition

| | HIL | |
|---|---|---|
| | ratio | HTL |
| Exp. | thickness | thickness |
| 15-1 | HTM-1:PDM-1:ETM-4 | HTM-5 |
| | (70%:5%:25%) | 110 nm |
| | 10 nm | |
| 15-2 | HTM-1:PDM-1:ETM-4 | HTM-6 |
| | (45%:5%:50%) | 110 nm |
| | 10 nm | |
| 16-1 | HTM-5:PDM-1:ETM-4 | HTM-1 |
| | (70%:5%:25%) | 110 nm |
| | 10 nm | |
| 16-2 | HTM-5:PDM-1:ETM-4 | HTM-6 |
| | (45%:5%:50%) | 110 nm |
| | 10 nm | |
| 17-1 | HTM-2:PDM-1:ETM-4 | HTM-5 |
| | (70%:5%:25%) | 110 nm |
| | 10 nm | |
| 17-2 | HTM-2:PDM-1:ETM-4 | HTM-6 |
| | (45%:5%:50%) | 110 nm |
| | 10 nm | |

TABLE 12
Data of OLED devices with the HTM comprised in the
HTL is different to the HTM comprised in the HIL

| | Luminance | Current density | U | EQE |
|---|---|---|---|---|
| Exp. | (cd/m²) | (mA/cm²) | (V) | (%) |
| 15-1 | 1000 | 11.1 | 3.5 | 9.8 |
| 15-2 | 1000 | 12.2 | 3.5 | 8.9 |
| 16-1 | 1000 | 11.6 | 3.5 | 9.2 |
| 16-2 | 1000 | 12.2 | 3.5 | 9.0 |
| 17-1 | 1000 | 11.2 | 3.5 | 9.8 |
| 17-2 | 1000 | 12.0 | 3.7 | 9.1 |

TABLE 13
Data of lateral current of the OLED devices with the HTM comprised
in the HTL is different to the HTM comprised in the HIL

| Exp. | Lateral Current density@4 V (μA/cm²) |
|---|---|
| 15-1 | 16.4 |
| 15-2 | 4.1 |
| 16-1 | 10.1 |
| 16-2 | 3.2 |
| 17-1 | 13.4 |
| 17-2 | 4.8 |

### C2) Comparison of Same and Different HTM Material in HIL and HTL

The following examples show a direct comparison of HTM materials in the HIL, mixed with low HOMO material, with either an HTM in the HTL layer which is different to the HTM in the HIL or which is same to the HTM in the HIL.

TABLE 14
OLED stacks: HIL and HTL composition

| | HIL | |
|---|---|---|
| | ratio | HTL |
| Exp. | thickness | thickness |
| 18-1 | HTM-1:PDM-1:ETM-4 | HTM-1 |
| | (60%:5%:25%) | 110 nm |
| | 10 nm | |
| 18-2 | HTM-1:PDM-1:ETM-4 | HTM-5 |
| | (60%:5%:25%) | 110 nm |
| | 10 nm | |
| 19-1 | HTM-5:PDM-1:ETM-4 | HTM-5 |
| | (45%:5%:50%) | 110 nm |
| | 10 nm | |
| 19-2 | HTM-5:PDM-1:ETM-4 | HTM-6 |
| | (45%:5%:50%) | 110 nm |
| | 10 nm | |
| 20-1 | HTM-2:PDM-1:ETM-4 | HTM-2 |
| | (35%:5%:60%) | 110 nm |
| | 10 nm | |

TABLE 15
Data of OLED devices

| | Current | | | Lateral Current |
|---|---|---|---|---|
| | density | U | EQE | density@4 V |
| Exp. | (mA/cm²) | (V) | (%) | (μA/cm²) |
| 18-1 | 11.4 | 3.45 | 9.0 | 14.9 |
| 18-2 | 11.1 | 3.49 | 9.8 | 16.4 |
| 19-1 | 11.1 | 3.49 | 9.8 | 4.9 |
| 19-2 | 12.2 | 3.52 | 9.0 | 3.2 |
| 20-1 | 11.2 | 4.38 | 9.9 | 0.3 |

The above data show that a further positive impact can be generated on the lateral current density, if compound C1 of the HIL and the compound of the adjacent HTL are combined in an appropriate way.

D) Further Examples for Effects Obtained from Increasing the Proportion of the Low-HOMO Material (Compound C2)

Analog to the examples in section B-2, in this section the type and proportion of a low-HOMO material is increased, while the proportion of the p-dopant is remained constant. It is shown that the lateral current decreases with increasing low HOMO material proportion, while the operating voltage (U) can increase with increasing low-HOMO material ratio, however only slightly. Efficiency remains on comparable level in all experiments.

TABLE 16
OLED stacks: HIL with variation of low HOMO material and ratio

| | HIL | |
|---|---|---|
| | ratio | HTL |
| Exp. | thickness | thickness |
| 21-1 | HTM-1:TMM-1:PDM-1 | HTM-1 |
| | (70%:25%:5%) | 110 nm |
| | 10 nm | |
| 21-2 | HTM-1:TMM-1:PDM-1 | HTM-1 |
| | (45%:50%:5%) | 110 nm |
| | 10 nm | |
| 21-3 | HTM-1:TMM-1:PDM-1 | HTM-1 |
| | (35%:60%:5%) | 110 nm |
| | 10 nm | |
| 22-1 | HTM-1:TMM-2:PDM-1 | HTM-1 |
| | (70%:25%:5%) | 110 nm |
| | 10 nm | |
| 22-2 | HTM-1:TMM-2:PDM-1 | HTM-1 |
| | (45%:50%:5%) | 110 nm |
| | 10 nm | |
| 22-3 | HTM-1:TMM-2:PDM-1 | HTM-1 |
| | (35%:60%:5%) | 110 nm |
| | 10 nm | |
| 23-1 | HTM-1:ETM-9:PDM-1 | HTM-1 |
| | (70%:25%:5%) | 110 nm |
| | 10 nm | |
| 23-2 | HTM-1:ETM-9:PDM-1 | HTM-1 |
| | (45%:50%:5%) | 110 nm |
| | 10 nm | |
| 23-3 | HTM-1:ETM-9:PDM-1 | HTM-1 |
| | (35%:60%:5%) | 110 nm |
| | 10 nm | |
| 24-1 | HTM-1:TMM-3:PDM-1 | HTM-1 |
| | (70%:25%:5%) | 110 nm |
| | 10 nm | |
| 24-2 | HTM-1:TMM-3:PDM-1 | HTM-1 |
| | (45%:50%:5%) | 110 nm |
| | 10 nm | |
| 24-3 | HTM-1:TMM-3:PDM-1 | HTM-1 |
| | (35%:60%:5%) | 110 nm |
| | 10 nm | |
| 25-1 | HTM-1:TMM-4:PDM-1 | HTM-1 |
| | (70%:25%:5%) | 110 nm |
| | 10 nm | |
| 25-2 | HTM-1:TMM-4:PDM-1 | HTM-1 |
| | (45%:50%:5%) | 110 nm |
| | 10 nm | |
| 25-3 | HTM-1:TMM-4:PDM-1 | HTM-1 |
| | (35%:60%:5%) | 110 nm |
| | 10 nm | |
| 26-1 | HTM-1:TMM-5:PDM-1 | HTM-1 |
| | (70%:25%:5%) | 110 nm |
| | 10 nm | |
| 26-2 | HTM-1:TMM-5:PDM-1 | HTM-1 |
| | (45%:50%:5%) | 110 nm |
| | 10 nm | |
| 26-3 | HTM-1:TMM-5:PDM-1 | HTM-1 |
| | (35%:60%:5%) | 110 nm |
| | 10 nm | |
| 27-1 | HTM-1:ETM-7:PDM-1 | HTM-1 |
| | (70%:25%:5%) | 110 nm |
| | 10 nm | |
| 27-2 | HTM-1:ETM-7:PDM-1 | HTM-1 |
| | (45%:50%:5%) | 110 nm |
| | 10 nm | |
| 27-3 | HTM-1:ETM-7:PDM-1 | HTM-1 |
| | (35%:60%:5%) | 110 nm |
| | 10 nm | |
| 28-1 | HTM-1:ETM-8:PDM-1 | HTM-1 |
| | (70%:25%:5%) | 110 nm |
| | 10 nm | |
| 28-2 | HTM-1:ETM-8:PDM-1 | HTM-1 |
| | (45%:50%:5%) | 110 nm |
| | 10 nm | |
| 28-3 | HTM-1:ETM-8:PDM-1 | HTM-1 |
| | (35%:60%:5%) | 110 nm |
| | 10 nm | |

TABLE 17
Data of OLED devices with variation
of low-HOMO material and ratio in HIL

| | Luminance | current | U | EQE |
|---|---|---|---|---|
| Exp. | (cd/m²) | (mA/cm²) | (V) | (%) |
| 21-1 | 1000 | 11.8 | 3.46 | 9.4 |
| 21-2 | 1000 | 11.8 | 3.54 | 9.3 |
| 21-3 | 1000 | 11.9 | 3.64 | 9.3 |
| 22-1 | 1000 | 11.7 | 3.46 | 9.4 |
| 22-2 | 1000 | 11.8 | 3.51 | 9.3 |
| 22-3 | 1000 | 11.6 | 3.55 | 9.5 |
| 23-1 | 1000 | 11.6 | 3.46 | 9.4 |
| 23-2 | 1000 | 11.6 | 3.55 | 9.4 |
| 23-3 | 1000 | 11.5 | 3.85 | 9.5 |
| 24-1 | 1000 | 11.6 | 3.43 | 9.5 |
| 24-2 | 1000 | 11.6 | 3.44 | 9.5 |
| 24-3 | 1000 | 11.5 | 3.45 | 9.5 |
| 25-1 | 1000 | 11.2 | 3.43 | 9.5 |
| 25-2 | 1000 | 11.4 | 3.45 | 9.5 |
| 25-3 | 1000 | 11.4 | 3.45 | 9.5 |
| 26-1 | 1000 | 11.6 | 3.46 | 9.5 |
| 26-2 | 1000 | 11.4 | 3.70 | 9.6 |
| 26-3 | 1000 | 11.3 | 3.86 | 9.7 |
| 27-1 | 1000 | 11.6 | 3.45 | 9.5 |
| 27-2 | 1000 | 11.6 | 3.51 | 9.4 |
| 27-3 | 1000 | 11.5 | 3.70 | 9.5 |
| 28-1 | 1000 | 11.6 | 3.46 | 9.4 |
| 28-2 | 1000 | 11.5 | 3.58 | 9.5 |
| 28-3 | 1000 | 11.4 | 3.74 | 9.5 |

TABLE 18
Data of lateral current of the OLED devices with
variation of low-HOMO material and ratio in HIL

| Exp. | Lateral Current density measured at 4 V (μA/cm²) |
|---|---|
| 21-1 | 2.7 |
| 21-2 | 0.9 |
| 21-3 | 0.8 |
| 22-1 | 6.9 |
| 22-2 | 1.6 |
| 22-3 | 1.1 |
| 23-1 | 7.9 |
| 23-2 | 1.8 |
| 23-3 | 1.0 |
| 24-1 | 18.3 |
| 24-2 | 8.0 |
| 24-3 | 7.0 |
| 25-1 | 20.7 |
| 25-2 | 6.4 |
| 25-3 | 4.1 |
| 26-1 | 6.5 |
| 26-2 | 0.8 |
| 26-3 | 0.3 |
| 27-1 | 8.0 |
| 27-2 | 2.2 |
| 27-3 | 1.5 |
| 28-1 | 7.1 |
| 28-2 | 0.8 |
| 28-3 | 0.4 |

### E) Determination of HOMO Values of Compounds

Preferably, according to the present application, the HOMO energies are determined via quantum-chemical calculations. For this purpose, the software package “Gaussian16 (Rev. B.01)” (Gaussian Inc.) is used. The neutral singlet ground state is optimized at the B3LYP/6-31G(d) level. HOMO values are determined at the B3LYP/6-31G(d) level for the B3LYP/6-31G(d)-optimized ground state energy. Then TD-DFT singlet and triplet excitations (vertical excitations) are calculated by the same method (B3LYP/6-31G(d)) and with the optimized ground state geometry. The standard settings for SCF and gradient convergence are used.

The energy calculation gives the HOMO as the last orbital occupied by two electrons (Alpha occ. eigenvalues) in Hartree units, where HEh represents the HOMO energy in Hartree units. This is used to determine the HOMO value in electron-volts, as follows:

$$HOMO ( eV ) = ( HEh ⋆ 27.212 )$$

Alternatively, according to the following method, the HOMO value in electron-volts can be obtained via quantum-chemical calculations as described above, and then calibrated by cyclic voltammetry measurements, as follows:

$$HOMO ( eV ) = ( HEh ⋆ 27.212 ) ⋆ 0.8308 - 1.118$$

The HOMO values of the compounds used in the hole injection layer of the present examples are as follows:

| Compound | HOMO |
|---|---|
| ETM-1 | −5.44 eV |
| ETM-2 | −5.67 eV |
| ETM-3 | −5.71 eV |
| ETM-4 | −5.86 eV |
| ETM-5 | −5.57 eV |
| ETM-6 | −5.49 eV |
| ETM-7 | −5.74 eV |
| ETM-8 | −5.50 eV |
| ETM-9 | −5.29 eV |
| TMM-1 | −5.60 eV |
| TMM-2 | −5.70 eV |
| TMM-3 | −5.81 eV |
| TMM-4 | −5.23 eV |
| TMM-5 | −5.18 eV |
| HTM-1 | −4.73 eV |
| HTM-2 | −4.80 eV |
| HTM-3 | −4.79 eV |
| HTM-4 | −4.70 eV |
| HTM-5 | −4.71 eV |
| HTM-6 | −4.70 eV |
| HTM-7 | −4.72 eV |
| HTM-9 | −4.68 eV |
| HTM-10 | −4.71 eV |
| HTM-11 | −4.73 eV |

The LUMO energy levels can be obtained in analogous manner as mentioned above for the HOMO energy levels.

TABLE 19
Chemical structures:

| Name | Structure |
|---|---|
| ETM-1 | 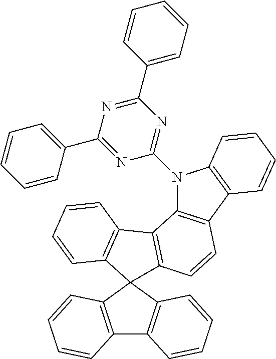 [SMILES: c1ccc(-c2nc(-c3ccccc3)nc(-n3c4ccccc4c4ccc5c(c43)-c3ccccc3C53c4ccccc4-c4ccccc43)n2)cc1] |
| ETM-2 | 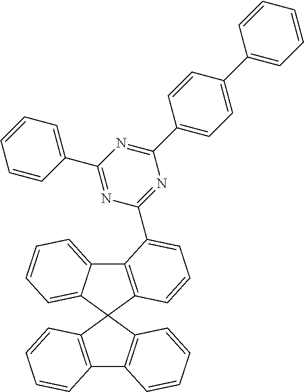 [SMILES: c1ccc(-c2ccc(-c3nc(-c4ccccc4)nc(-c4cccc5c4-c4ccccc4C54c5ccccc5-c5ccccc54)n3)cc2)cc1] |
| ETM-3 | 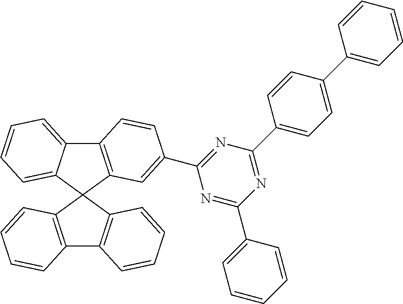 [SMILES: c1ccc(-c2ccc(-c3nc(-c4ccccc4)nc(-c4ccc5c(c4)C4(c6ccccc6-c6ccccc64)c4ccccc4-5)n3)cc2)cc1] |
| ETM-4 | 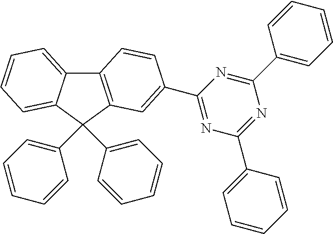 [SMILES: c1ccc(-c2nc(-c3ccccc3)nc(-c3ccc4c(c3)C(c3ccccc3)(c3ccccc3)c3ccccc3-4)n2)cc1] |
| ETM-5 | 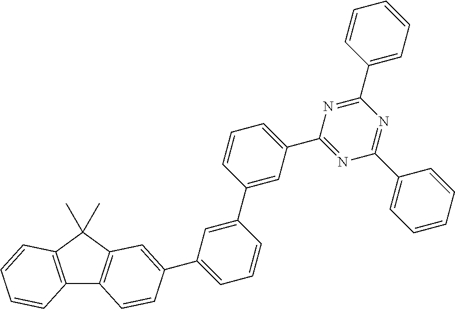 [SMILES: CC1(C)c2ccccc2-c2ccc(-c3cccc(-c4cccc(-c5nc(-c6ccccc6)nc(-c6ccccc6)n5)c4)c3)cc21] |
| ETM-6 | 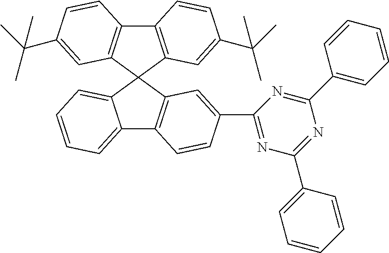 [SMILES: CC(C)(C)c1ccc2c(c1)C1(c3ccccc3-c3ccc(-c4nc(-c5ccccc5)nc(-c5ccccc5)n4)cc31)c1cc(C(C)(C)C)ccc1-2] |
| ETM-7 | 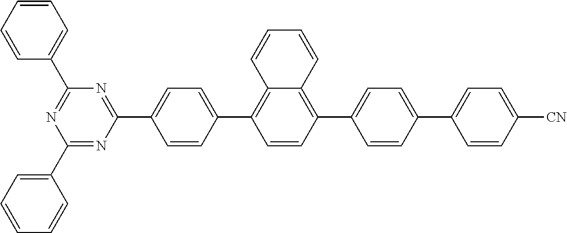 [SMILES: N#Cc1ccc(-c2ccc(-c3ccc(-c4ccc(-c5nc(-c6ccccc6)nc(-c6ccccc6)n5)cc4)c4ccccc34)cc2)cc1] |
| ETM-8 | 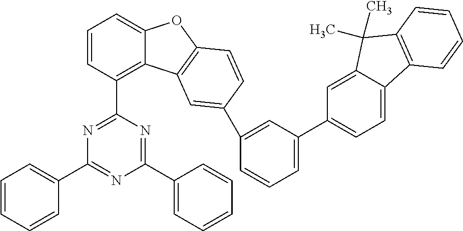 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21] |
| ETM-9 | 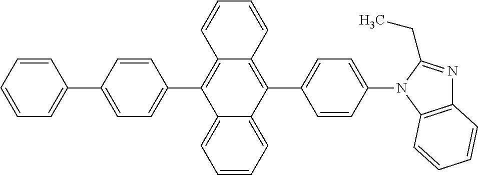 [SMILES: CCc1nc2ccccc2n1-c1ccc(-c2c3ccccc3c(-c3ccc(-c4ccccc4)cc3)c3ccccc23)cc1] |
| TMM-1 | 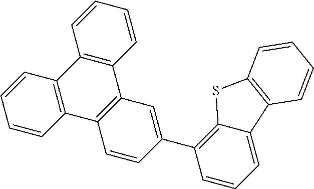 [SMILES: c1ccc2c(c1)sc1c(-c3ccc4c5ccccc5c5ccccc5c4c3)cccc12] |
| TMM-2 | 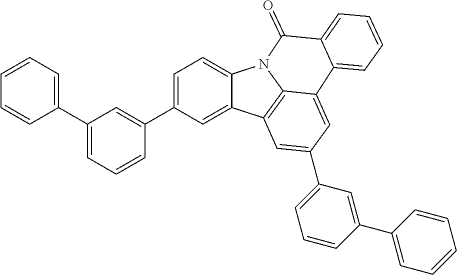 [SMILES: O=c1c2ccccc2c2cc(-c3cccc(-c4ccccc4)c3)cc3c4cc(-c5cccc(-c6ccccc6)c5)ccc4n1c23] |
| TMM-3 | 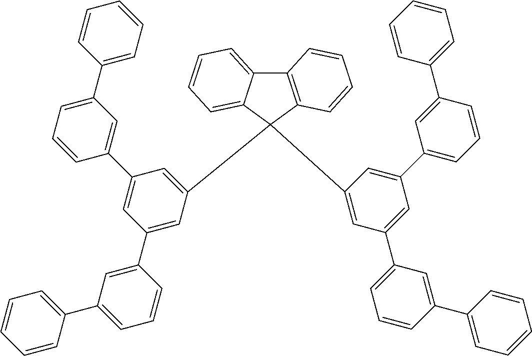 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1] |
| TMM-4 | 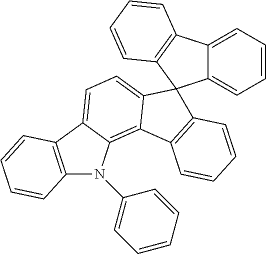 [SMILES: c1ccc(-n2c3ccccc3c3ccc4c(c32)-c2ccccc2C42c3ccccc3-c3ccccc32)cc1] |
| TMM-5 | 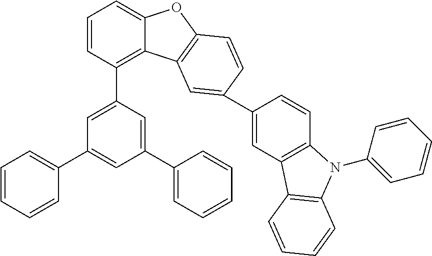 [SMILES: c1ccc(-c2cc(-c3ccccc3)cc(-c3cccc4oc5ccc(-c6ccc7c(c6)c6ccccc6n7-c6ccccc6)cc5c34)c2)cc1] |
| ETM-1 | 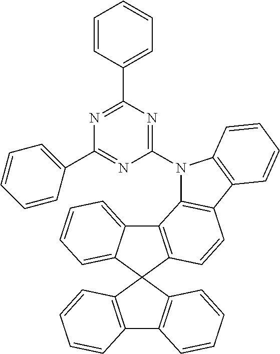 [SMILES: c1ccc(-c2nc(-c3ccccc3)nc(-n3c4ccccc4c4ccc5c(c43)-c3ccccc3C53c4ccccc4-c4ccccc43)n2)cc1] |
| HTM-1 | 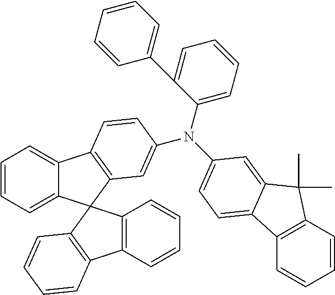 [SMILES: CC1(C)c2ccccc2-c2ccc(N(c3ccc4c(c3)C3(c5ccccc5-c5ccccc53)c3ccccc3-4)c3ccccc3-c3ccccc3)cc21] |
| HTM-2 | 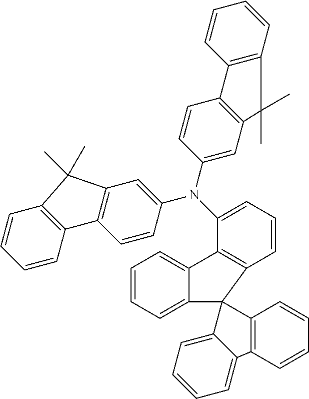 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21] |
| HTM-3 | 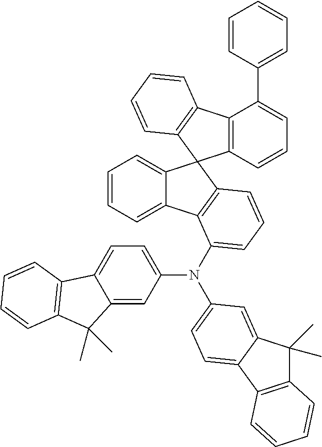 [SMILES: CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21] |
| HTM-6 | 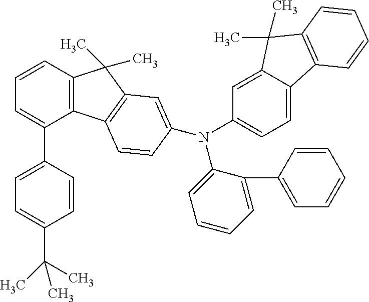 [SMILES: CC(C)(C)c1ccc(-c2cccc3c2-c2ccc(N(c4ccc5c(c4)C(C)(C)c4ccccc4-5)c4ccccc4-c4ccccc4)cc2C3(C)C)cc1] |
| HTM-7 | 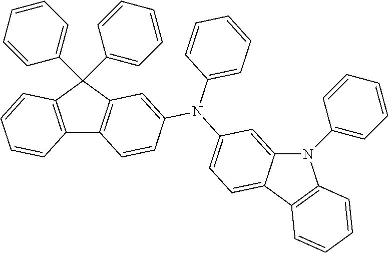 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| HTM-9 | 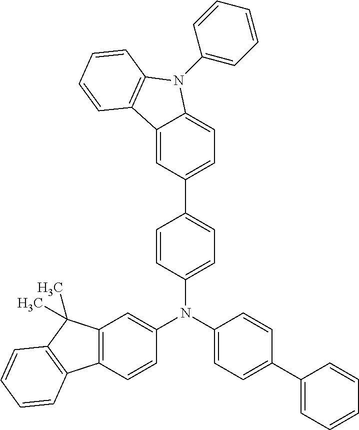 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HTM-10 | 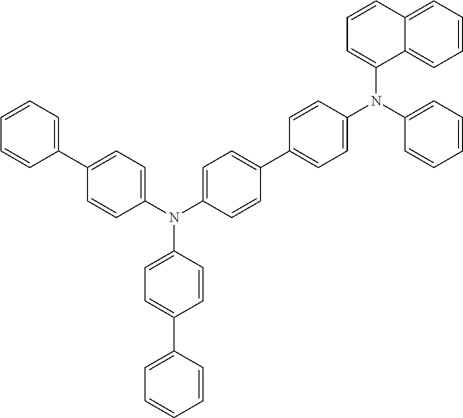 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1] |
| HTM-11 | 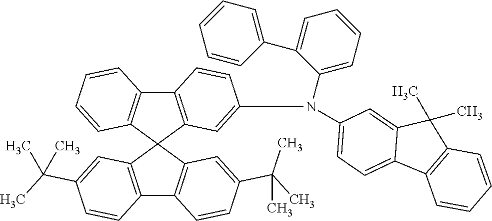 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2] |
| PDM-1 | 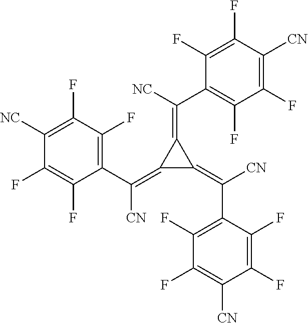 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| PDM-2 (HATCN) | 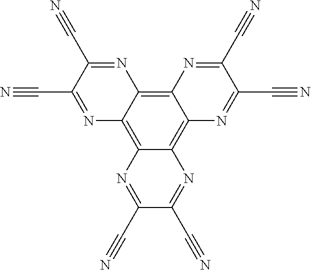 [SMILES: N#Cc1nc2c3nc(C#N)c(C#N)nc3c3nc(C#N)c(C#N)nc3c2nc1C#N] |
| PDM-3 (F4TCN Q) | 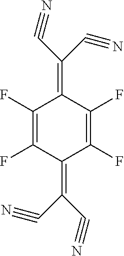 [SMILES: N#CC(C#N)=c1c(F)c(F)c(=C(C#N)C#N)c(F)c1F] |
| EBM-1 | 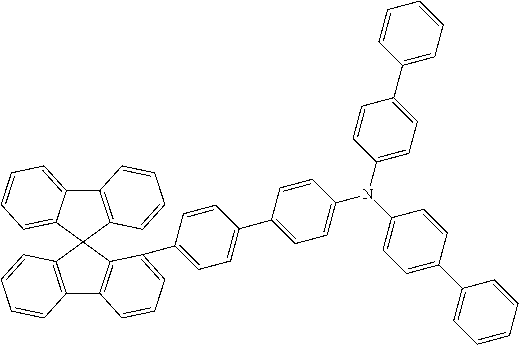 [SMILES: c1ccc(-c2ccc(N(c3ccc(-c4ccccc4)cc3)c3ccc(-c4ccc(-c5cccc6c5C5(c7ccccc7-c7ccccc75)c5ccccc5-6)cc4)cc3)cc2)cc1] |
| SMB-1 | 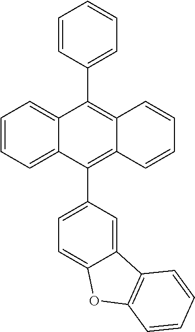 [SMILES: c1ccc(-c2c3ccccc3c(-c3ccc4oc5ccccc5c4c3)c3ccccc23)cc1] |
| SEB-1 | 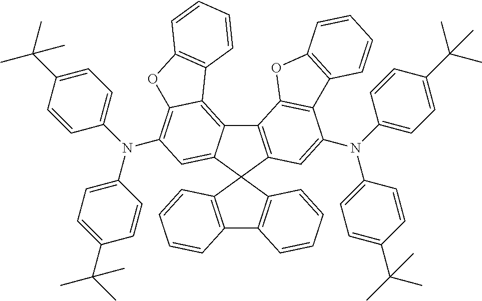 [SMILES: CC(C)(C)c1ccc(N(c2ccc(C(C)(C)C)cc2)c2cc3c(c4c2oc2ccccc24)-c2c(cc(N(c4ccc(C(C)(C)C)cc4)c4ccc(C(C)(C)C)cc4)c4c2oc2ccccc24)C32c3ccccc3-c3ccccc32)cc1] |
| LiQ | 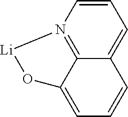 |

1. Electronic device, comprising a first stack of layers, and a second stack of layers which is in close proximity to the first stack of layers, each of the first and second stack comprising anode, cathode, and positioned between anode and cathode, a layer A and a light emitting layer, where the layer A is shared by the two stacks of layers, and where the layer A comprises
at least one compound C1, which has hole transporting property,
at least one compound C2, which has a HOMO of less than −5.1 eV, and
at least one compound C3, which is a p-dopant.

2. Electronic device according to claim 1, characterized in that the first stack of layers and the second stack of layers are distanced by 5 μm to 40 μm, where the distance is measured from the side of the anode of the first stack which is closest to the second stack, to the side of the anode of the second stack which is closest to the first stack.

3. Electronic device according to claim 1, characterized in that at least one of the first and the second stack of layers of the electronic device is a tandem stack.

4. Electronic device according to claim 1, characterized in that each of the first stack of layers and the second stack of layers represents a pixel of the electronic device, and the electronic device is a display.

5. Electronic device according to claim 1, characterized in that layer A is selected from a hole injection layer and a charge generation layer.

6. Electronic device according to claim 1, characterized in that layer A is a hole injection layer which is directly adjacent to the anode, and which has a thickness of 5 nm to 20 nm.

7. Electronic device according to claim 1, characterized in that compounds C1, C2 and C3 each have a molecular weight of less than 2000 g/mol.

8. Electronic device according to claim 1, characterized in that compounds C1 is selected from mono-triarylamines, di-triarylamines, and carbazole amines.

9. Electronic device according to claim 1, characterized in that compound C1 conforms to a formula which is selected from the following formulae 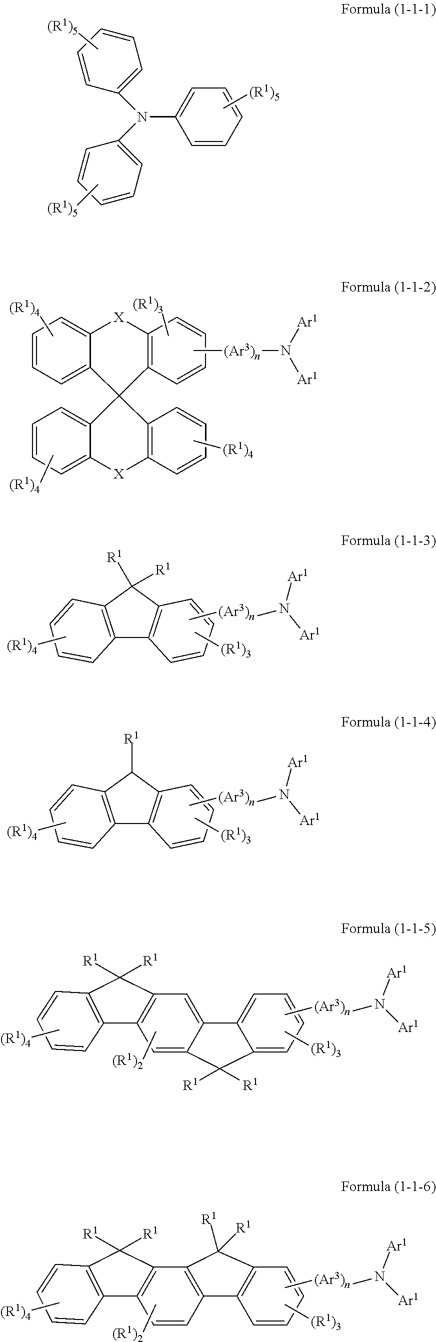 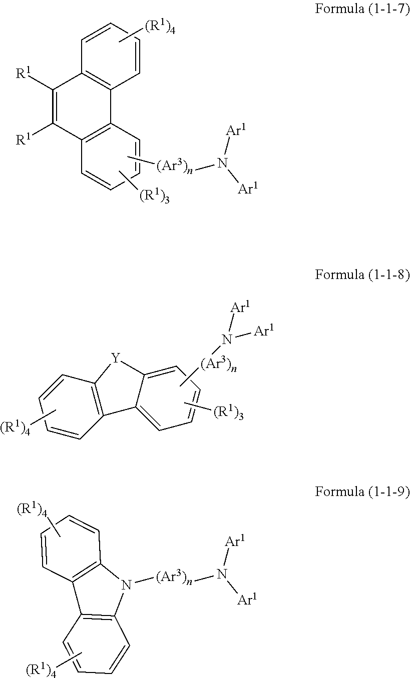
where the variable groups and indices are defined as follows:
Ar¹ is at each occurrence, identically or differently, selected from aromatic ring systems having 6 to 50 aromatic ring atoms, which are substituted by radicals R¹, and heteroaromatic ring systems having 5 to 40 aromatic ring atoms, which are substituted by radicals R¹;
R¹ is selected, identically or differently at each occurrence, from H, D, F, C(═O)R², CN, Si(R²)₃, N(R²)₂, P(═O)(R²)₂, OR², S(═O)R², S(═O)₂R², straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms; where two or more radicals R¹ may be connected to each other to form a ring; where the said alkyl, alkoxy, alkenyl and alkynyl groups and the said aromatic and heteroaromatic ring systems are substituted by radicals R², and where one or more CH₂ groups in the said alkyl, alkoxy, alkenyl and alkynyl groups may in each case be replaced by —R²C═CR²—, —C≡C—, Si(R²)₂, C═O, C═NR², —C(═O)O—, —C(═O)NR²—, NR², P(═O)(R²), —O—, —S—, SO or SO₂;
R² is selected, identically or differently at each occurrence, from H, D, F, C(═O)R³, CN, Si(R³)₃, N(R³)₂, P(═O)(R³)₂, OR³, S(═O)R³, S(═O)₂R³, straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms; where two or more radicals R² may be connected to each other to form a ring; where the said alkyl, alkoxy, alkenyl and alkynyl groups and the said aromatic and heteroaromatic ring systems are substituted by radicals R³, and where one or more CH₂ groups in the said alkyl, alkoxy, alkenyl and alkynyl groups may in each case be replaced by —R³C═CR³—, —C≡C—, Si(R³)₂, C═O, C═NR³, —C(═O)O—, —C(═O)NR³—, NR³, P(═O)(R³), —O—, —S—, SO or SO₂;
R³ is selected, identically or differently at each occurrence, from H, D, F, Cl, Br, I, CN, alkyl groups having 1 to 20 C atoms, aromatic ring systems having 6 to 40 C atoms, and heteroaromatic ring systems having 5 to 40 aromatic ring atoms; where two or more radicals R³ may be connected to each other to form a ring; and where the said alkyl groups, aromatic ring systems and heteroaromatic ring systems may be substituted by one or more radicals selected from F and CN;
Ar³ is selected from aromatic ring systems having 6 to 13 aromatic ring atoms, which are substituted with radicals R¹, and heteroaromatic ring systems having 5 to 13 aromatic ring atoms, which are substituted with radicals R¹;
X is selected, identically or differently on each occurrence, from a bond, O, S, NR¹, and C(R¹)₂;
Y is selected from O and S;
n is 0 or 1, where for n=0, the group with index n is not present, and the groups bonded to the group with index n are directly connected to each other, with the proviso that n is not 0 in the case of formula (1-1-9).

10. Electronic device according to claim 1, characterized in that compound C2 conforms to a formula which is selected from the following formulae 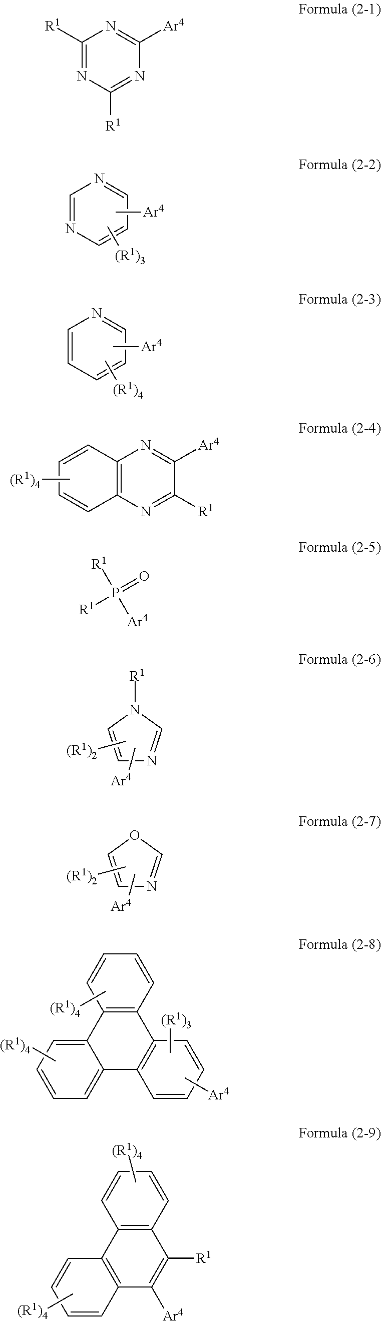 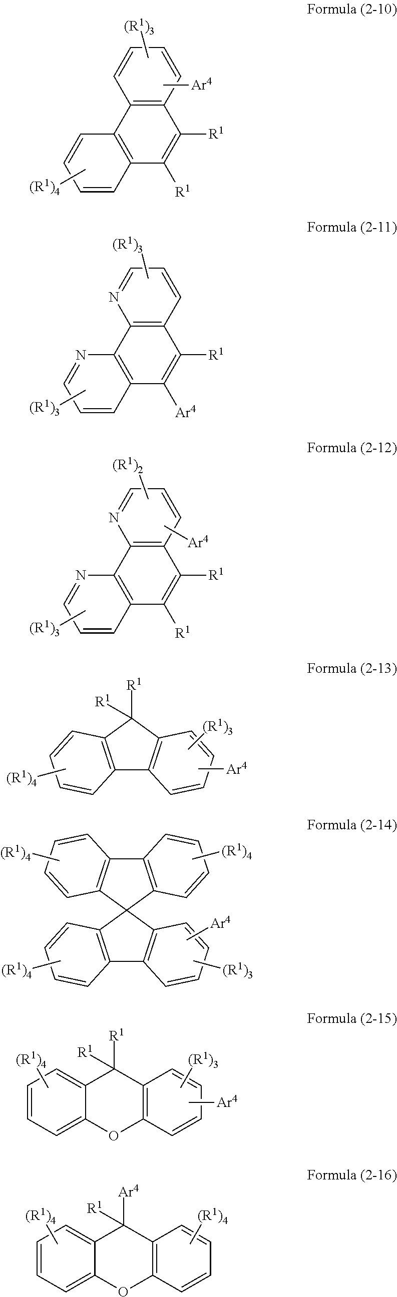 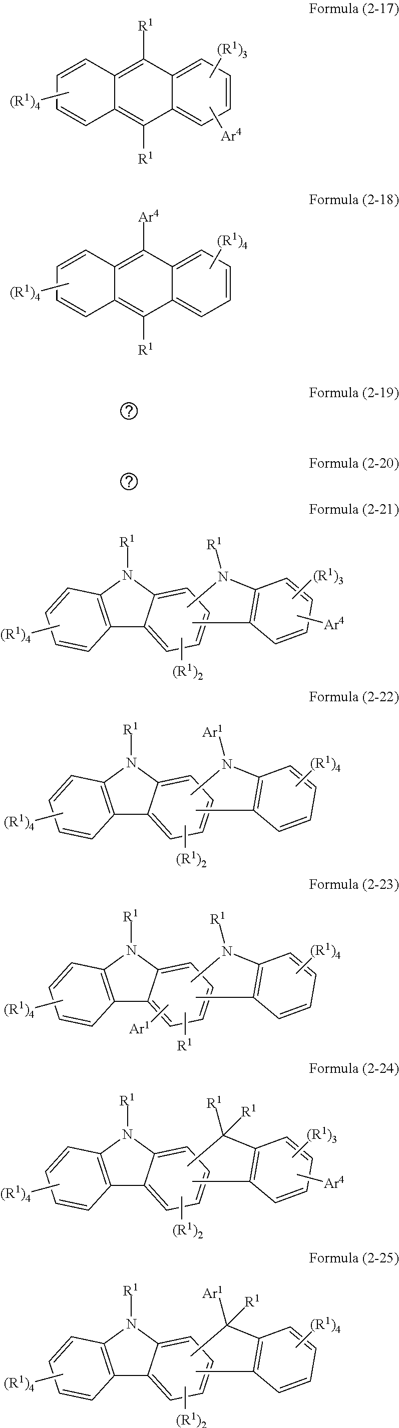 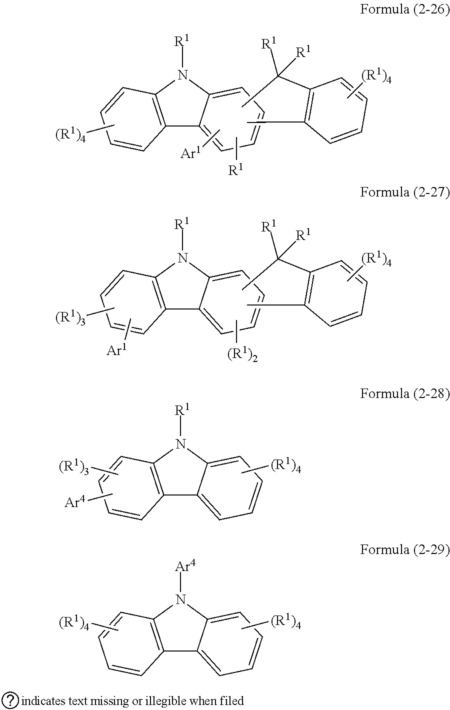
where
R¹ is selected, identically or differently at each occurrence, from H, D, F, C(═O)R², CN, Si(R²)₃, N(R²)₂, P(═O)(R²)₂, OR², S(═O)R², S(═O)₂R², straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms: where two or more radicals R¹ may be connected to each other to form a ring; where the said alkyl, alkoxy, alkenyl and alkynyl groups and the said aromatic and heteroaromatic ring systems are substituted by radicals R², and where one or more CH₂ groups in the said alkyl, alkoxy, alkenyl and alkynyl groups may in each case be replaced by —R²C═CR²—, —C≡C—, Si(R²)₂, C═O, C═NR², —C(═O)O—, —C(═O)NR²—, NR², P(═O)(R²), —O—, —S—, SO or SO₂;
R² is selected, identically or differently at each occurrence, from H, D, F, C(═O)R³, CN, Si(R³)₃, N(R³)₂, P(═O)(R³)₂, OR³, S(═O)R³, S(═O)₂R³, straight-chain alkyl or alkoxy groups having 1 to 20 C atoms, branched or cyclic alkyl or alkoxy groups having 3 to 20 C atoms, alkenyl or alkynyl groups having 2 to 20 C atoms, aromatic ring systems having 6 to 40 aromatic ring atoms, and heteroaromatic ring systems having 5 to 40 aromatic ring atoms: where two or more radicals R² may be connected to each other to form a ring; where the said alkyl, alkoxy, alkenyl and alkynyl groups and the said aromatic and heteroaromatic ring systems are substituted by radicals R³, and where one or more CH₂ groups in the said alkyl, alkoxy, alkenyl and alkynyl groups may in each case be replaced by —R³C═CR³—, —C≡C—, Si(R³)₂, C═O, C═NR³, —C(═O)O—, —C(═O)NR³—, NR³, P(═O)(R³), —O—, —S—, SO or SO₂;
R³ is selected, identically or differently at each occurrence, from H, D, F, Cl, Br, I, CN, alkyl groups having 1 to 20 C atoms, aromatic ring systems having 6 to 40 C atoms, and heteroaromatic ring systems having 5 to 40 aromatic ring atoms: where two or more radicals R³ may be connected to each other to form a ring; and where the said alkyl groups, aromatic ring systems and heteroaromatic ring systems may be substituted by one or more radicals selected from F and CN; and
Ar⁴ is selected from aromatic ring systems having 6 to 50 aromatic ring atoms, which are substituted with radicals R¹, and heteroaromatic ring systems having 5 to 50 aromatic ring atoms, which are substituted with radicals R¹.

11. Electronic device according to claim 1, characterized in that the compound C3 is present in a proportion of 1% to 10% in the layer A if the layer A is a hole injection layer, and in a proportion of 5% to 20% if the layer A is a charge generation layer.

12. Electronic device according to claim 1, characterized in that the compound C3 is selected from aromatic or heteroaromatic condensed rings; quinodimethanes; conjugated diones; indenofluorenediones; azaindenofluorenediones; azaphenalenes; azatriphenylenes; azines; boron compounds; trimethylene-cyclopropanes; I₂; metal halides; metal oxides; transition metal complexes; and main group metal complexes.

13. Electronic device according to claim 1, characterized in that the ratio of compound C1 to compound C2 in the layer A is between 80:20 and 20:80.

14. Electronic device according to claim 1, characterized in that at least one of the first and the second stack of layers comprises a hole transporting layer, which is adjacent to the layer A as a hole injection layer, where the hole transporting layer comprises the same compound C1 as the layer A.

15. Method of making an electronic device according to claim 1, characterized in that the compound C1 and the compound C2 are first mixed, and the resulting mixture is then used for the preparation of the layer A by vapor deposition.

16. Use of a mixture comprising at least one compound C1, which has hole transporting property, and at least one compound C2, which has a HOMO of less than −5.1 eV, for the preparation of a layer A of an electronic device according to claim 1.
